(19) United States
(12) Patent Application Publication
(10) Pub. No.: US 2025/0185453 A1
(43) Pub. Date: Jun. 5, 2025

(54) ORGANIC LIGHT-EMITTING DEVICE

(71) Applicant: LG CHEM, LTD., Seoul (KR)

(72) Inventors: Ji Young CHOI, Daejeon (KR); Sujeong GEUM, Daejeon (KR); Woo Jin CHO, Daejeon (KR); Yongbum CHA, Daejeon (KR); Jae Seung HA, Daejeon (KR); Sunghyun HWANG, Daejeon (KR); Woochul LEE, Daejeon (KR)

(21) Appl. No.: 18/842,775

(22) PCT Filed: Oct. 23, 2023
(86) PCT No.: PCT/KR2023/016438

§ 371 Date: Aug. 29, 2024

(30) Foreign Application Priority Data
Nov. 2, 2022 (KR) 10-2022-0144670

(51) Int. Cl. H10K 50/12; H10K 50/15; H10K 50/16; H10K 50/17; H10K 50/18; H10K 85/60; H10K 101/00

(52) U.S. Cl. CPC H10K 50/12; H10K 85/622; H10K 85/631; H10K 85/654; H10K 85/6572; H10K 85/6574; H10K 85/6576; H10K 85/658; H10K 50/156; H10K 50/166; H10K 50/171; H10K 50/181; H10K 2101/90

(57) ABSTRACT

An organic light-emitting device including a compound of Chemical Formula 1 and a compound of Chemical Formula 2:

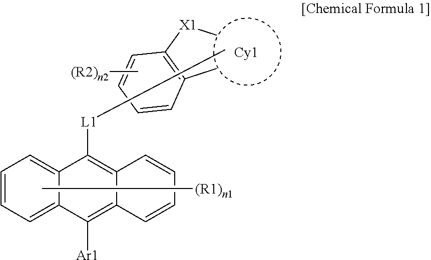

wherein: X1 is O or S; Cy1 is a substituted or unsubstituted dibenzofuran or a substituted or unsubstituted dibenzothiophene; Ar1 is a substituted or unsubstituted aryl group or a substituted or unsubstituted heteroaryl group; and the other substituents are as defined in the specification;

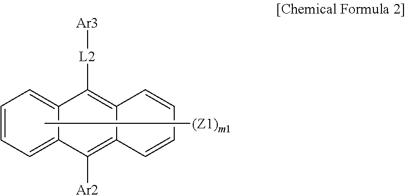

where Ar2 is a substituted or unsubstituted aryl group or a substituted or unsubstituted heteroaryl group; Ar3 is Chemical Formula A, and Z10 or Z11 of Chemical Formula A is linked to L2 of Chemical Formula 2:

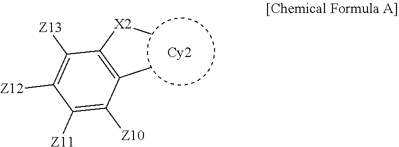

where X2 is O or S; Cy2 is a substituted or unsubstituted benzene or a substituted or unsubstituted naphthalene; and the other substituents are as defined in the specification.

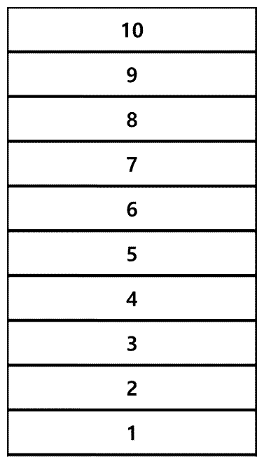

### CROSS-REFERENCE TO RELATED APPLICATION(S)

This application is a National Stage Application of International Application No. PCT/KR2023/016438 filed on Oct. 23, 2023, which claims priority to and the benefit of Korean Patent Application No. 10-2022-0144670 filed in the Korean Intellectual Property Office on Nov. 2, 2022, the entire contents of which are incorporated herein by reference.

### TECHNICAL FIELD

The present specification relates to an organic light emitting device.

### BACKGROUND

An organic light emission phenomenon generally refers to a phenomenon converting electrical energy to light energy using an organic material. An organic light emitting device using the organic light emitting phenomenon usually has a structure comprising an anode, a cathode, and an organic material layer interposed therebetween. Here, the organic material layer has in many cases a multi-layered structure composed of different materials in order to improve the efficiency and stability of the organic light emitting device, and for example, may be composed of a hole injection layer, a hole transport layer, a light emitting layer, an electron transport layer, an electron injection layer, and the like. In the structure of the organic light emitting device, if a voltage is applied between two electrodes, holes are injected from an anode into the organic material layer and electrons are injected from a cathode into the organic material layer, and when the injected holes and electrons meet each other, an exciton is formed, and light is emitted when the exciton falls down again to a ground state.

There is a continuous need for developing a new material for the aforementioned organic light emitting device.

### BRIEF DESCRIPTION

### Technical Problem

The present specification has been made in an effort to provide an organic light emitting device.

### Technical Solution

An exemplary embodiment of the present specification provides an organic light emitting device comprising: an anode; a cathode; and a first organic material layer provided between the anode and the cathode, in which the first organic material layer comprises a compound of the following Chemical Formula 1 and a compound of the following Chemical Formula 2.

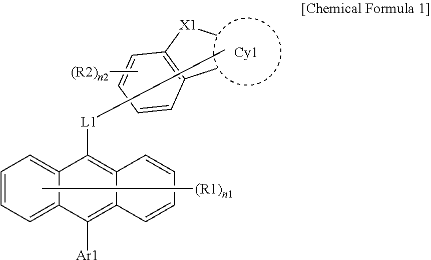

In Chemical Formula 1,
X1 is O or S,
Cy1 is a substituted or unsubstituted dibenzofuran; or a substituted or unsubstituted dibenzothiophene,
L1 is a direct bond or a substituted or unsubstituted arylene group,
Ar is a substituted or unsubstituted aryl group or a substituted or unsubstituted heteroaryl group,
R1 and R2 are the same as or different from each other, and are each independently hydrogen, deuterium, a substituted or unsubstituted aryl group, or a substituted or unsubstituted heteroaryl group,
n1 is an integer from 0 to 8, and when n1 is 2 or higher, two or more R1s are the same as or different from each other, and
n2 is an integer from 0 to 4, and when n2 is 2 or higher, two or more R2s are the same as or different from each other.

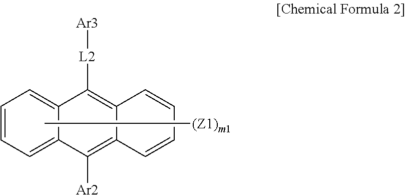

in Chemical Formula 2,
L2 is a direct bond or a substituted or unsubstituted arylene group,
Ar2 is a substituted or unsubstituted aryl group or a substituted or unsubstituted heteroaryl group,
Z1 is hydrogen, deuterium, a substituted or unsubstituted cycloalkyl group, a substituted or unsubstituted aryl group, or a substituted or unsubstituted heteroaryl group,
m1 is an integer from 0 to 8, and when m1 is 2 or higher, two or more Z1s are the same as or different from each other, and
Ar3 is the following Chemical Formula A, and Z10 or Z11 of the following Chemical Formula A is linked to L2 of Chemical Formula 2:

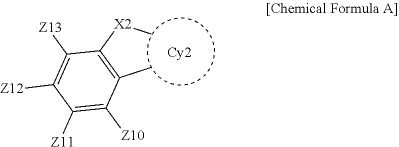

wherein in Chemical Formula A,
X2 is O or S,
Cy2 is a substituted or unsubstituted benzene or a substituted or unsubstituted naphthalene, and
of Z10 and Z11, a group which is not linked to L2 in Chemical Formula 2, Z12, and Z13 are the same as or different from each other, and are each independently hydrogen, deuterium, a substituted or unsubstituted aryl group, or a substituted or unsubstituted heteroaryl group.

### Advantageous Effects

The organic light emitting device described in the present specification has effects of low driving voltage, high efficiency and/or long service life by including both a compound of Chemical Formula 1 and a compound of Chemical Formula 2 in the first organic material layer.

### BRIEF DESCRIPTION OF THE DRAWINGS

The FIGURE illustrates an example of an organic light emitting device in which a substrate 1, an anode 2, a hole injection layer 3, a hole transport layer 4, an electron blocking layer 5, a light emitting layer 6, a hole blocking layer 7, an electron transport layer 8, an electron injection layer 9, and a cathode 10 are sequentially stacked.

### EXPLANATION OF REFERENCE NUMERALS AND SYMBOLS

1: Substrate
2: Anode
3: Hole injection layer
4: Hole transport layer
5: Electron blocking layer
6: Light emitting layer
7: Hole blocking layer
8: Electron transport layer
9: Electron injection layer
10: Cathode

### DETAILED DESCRIPTION

Hereinafter, the present specification will be described in more detail.

When one part “comprises” one constituent element in the present specification, unless otherwise specifically described, this does not mean that another constituent element is excluded, but means that another constituent element may be further comprised.

When one member is disposed “on” another member in the present specification, this comprises not only a case where the one member is brought into contact with another member, but also a case where still another member is present between the two members.

In the present specification, the deuterium substitution rate of a compound may be understood by a method of calculating the substitution rate based on the max. value of the distribution which molecular weights form at the end point of a reaction using thin-layer chromatography/mass spectrometry (TLC-MS) or a quantitative analysis method using NMR, and a method of adding DMF as an internal standard and calculating the D-substitution rate from the integrated amount of the total peak using the integration rate on 1H NMR.

In the present specification, “energy level” means a size of energy. Therefore, the energy level is interpreted to mean the absolute value of the corresponding energy value. For example, a low or deep energy level means that the absolute value increases in the negative direction from the vacuum level.

In the present specification, the highest occupied molecular orbital (HOMO) means a molecular orbital (highest occupied molecular orbital) in the highest energy region in regions in which electrons can participate in bonding, the lowest unoccupied molecular orbital (LUMO) means the molecular orbital (lowest unoccupied molecular orbital) in which electrons are present in the lowest energy region among the semi-bonded regions, and the HOMO energy level means the distance from the vacuum level to the HOMO. Furthermore, the LUMO energy level means the distance from the vacuum level to the LUMO.

In the present specification, a bandgap means a difference in energy level between HOMO and LUMO, that is, a HOMO-LUMO gap (Gap).

In the present specification, the HOMO energy level may be measured using a photoelectron spectrometer under the atmosphere (manufactured by RIKEN KEIKI Co., Ltd.: AC3), and the LUMO energy level may be calculated from wavelength values measured through photoluminescence (PL).

Examples of the substituents in the present specification will be described below, but are not limited thereto.

The term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present invention, the term “substituted or unsubstituted” can mean being substituted with one or two or more substituents selected from the group consisting of deuterium, a halogen group, a cyano group (—CN), a nitro group, a hydroxyl group, an alkyl group, a cycloalkyl group, an alkoxy group, a phosphine oxide group, an aryloxy group, an alkylthioxy group, an arylthioxy group, an alkylsulfoxy group, an arylsulfoxy group, an alkenyl group, a silyl group, a boron group, an amine group, an aryl group, or a heterocyclic group, being substituted with a substituent in which two or more substituents among the exemplified substituents are linked together, or having no substituent. For example, “the substituent in which two or more substituents are linked together” may be a biphenyl group. That is, the biphenyl group may also be an aryl group, and may be interpreted as a substituent to which two phenyl groups are linked together.

In the present specification, the term “substituted or unsubstituted” can mean being substituted with one or two or more substituents selected from the group consisting of deuterium, a halogen group, a cyano group, a silyl group, an alkoxy group, an aryloxy group, an alkyl group, an aryl group, and a heterocyclic group, being substituted with a substituent in which two or more substituents among the exemplified substituents are linked together, or having no substituent.

In the present specification, the term “substituted or unsubstituted” can mean being substituted with one or two or more substituents selected from the group consisting of deuterium, an alkyl group, an aryl group, and a heterocyclic group, being substituted with a substituent in which two or more substituents among the exemplified substituents are linked together, or having no substituent.

Examples of the substituents will be described below, but are not limited thereto.

In the present specification, examples of a halogen group comprise fluorine (—F), chlorine (—Cl), bromine (—Br) or iodine (—I).

In the present specification, a silyl group may be represented by the formula —SiYaYbYc, and Ya, Yb, and Ye may be each hydrogen, a substituted or unsubstituted alkyl group, or a substituted or unsubstituted aryl group. Specific examples of the silyl group comprise a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but are not limited thereto.

In the present specification, a boron group may be represented by the formula BYdYe, and Yd and Ye may be each hydrogen, a substituted or unsubstituted alkyl group, or a substituted or unsubstituted aryl group. Specific examples of the boron group comprise a trimethylboron group, a triethylboron group, a t-butyldimethylboron group, a triphenylboron group, a phenylboron group, and the like, but are not limited thereto.

In the present specification, the alkyl group may be straight-chained or branched, and the number of carbon atoms thereof is not particularly limited, but is preferably 1 to 60. According to an exemplary embodiment, the number of carbon atoms of the alkyl group is 1 to 30. According to another exemplary embodiment, the number of carbon atoms of the alkyl group is 1 to 20. According to still another exemplary embodiment, the number of carbon atoms of the alkyl group is 1 to 10. Specific examples of the alkyl group comprise a methyl group, an ethyl group, a propyl group, an n-propyl group, an isopropyl group, a butyl group, an n-butyl group, an isobutyl group, a tert-butyl group, a pentyl group, an n-pentyl group, a hexyl group, an n-hexyl group, a heptyl group, an n-heptyl group, an octyl group, an n-octyl group, and the like, but are not limited thereto.

In the present specification, the above-described description of the alkyl group may be applied to an arylalkyl group, except that the arylalkyl group is substituted with an aryl group.

In the present specification, the alkoxy group may be straight-chained, branched, or cyclic. The number of carbon atoms of the alkoxy group is not particularly limited, but is preferably 1 to 20. Specific examples thereof comprise methoxy, ethoxy, n-propoxy, isopropoxy, i-propyloxy, n-butoxy, isobutoxy, t-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, and the like, but are not limited thereto.

Substituents comprising an alkyl group, an alkoxy group, and other alkyl group moieties described in the present specification comprise both a straight-chained form and a branched form.

In the present specification, an alkenyl group may be straight-chained or branched, and the number of carbon atoms thereof is not particularly limited, but is preferably 2 to 40. According to an exemplary embodiment, the number of carbon atoms of the alkenyl group is 2 to 20. According to another exemplary embodiment, the number of carbon atoms of the alkenyl group is 2 to 10. According to still another exemplary embodiment, the number of carbon atoms of the alkenyl group is 2 to 6. Specific examples thereof comprise vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present specification, the alkynyl group may be straight-chained or branched as a substituent comprising a triple bond between a carbon atom and a carbon atom, and the number of carbon atoms thereof is not particularly limited, but is preferably 2 to 40. According to an exemplary embodiment, the number of carbon atoms of the alkenyl group is 2 to 20. According to another exemplary embodiment, the number of carbon atoms of the alkenyl group is 2 to 10.

In the present specification, a cycloalkyl group is not particularly limited, but has preferably 3 to 60 carbon atoms, and according to an exemplary embodiment, the number of carbon atoms of the cycloalkyl group is 3 to 30. According to another exemplary embodiment, the number of carbon atoms of the cycloalkyl group is 3 to 20. According to still another exemplary embodiment, the number of carbon atoms of the cycloalkyl group is 3 to 6. Specific examples thereof comprise a cyclopropyl group, a cyclobutyl group, a cyclopentyl group, a cyclohexyl group, a cycloheptyl group, a cyclooctyl group, and the like, but are not limited thereto.

In the present specification, an amine group is —NH₂, and the amine group may be substituted with the above-described alkyl group, aryl group, heterocyclic group, alkenyl group, cycloalkyl group, a combination thereof, and the like. The number of carbon atoms of the substituted amine group is not particularly limited, but is preferably 1 to 30. According to an exemplary embodiment, the number of carbon atoms of the amine group is 1 to 20. According to an exemplary embodiment, the number of carbon atoms of the amine group is 1 to 10. Specific examples of the substituted amine group comprise a methylamine group, a dimethylamine group, an ethylamine group, a diethylamine group, a phenylamine group, a 9,9-dimethylfluorenylphenylamine group, a pyridylphenylamine group, a diphenylamine group, a phenylpyridylamine group, a naphthylamine group, a biphenylamine group, an anthracenylamine group, a dibenzofuranylphenylamine group, a 9-methylanthracenylamine group, a diphenylamine group, a phenylnaphthylamine group, a ditolylamine group, a phenyltolylamine group, a diphenylamine group, and the like, but are not limited thereto.

In the present specification, an aryl group is not particularly limited, but has preferably 6 to 60 carbon atoms, and may be a monocyclic aryl group or a polycyclic aryl group. According to an exemplary embodiment, the number of carbon atoms of the aryl group is 6 to 30. According to an exemplary embodiment, the number of carbon atoms of the aryl group is 6 to 20. Examples of the monocyclic aryl group comprise a phenyl group, a biphenyl group, a terphenyl group, a quaterphenyl group, and the like, but are not limited thereto. Examples of the polycyclic aryl group comprise a naphthyl group, an anthracenyl group, a phenanthrenyl group, a pyrenyl group, a perylenyl group, a chrysenyl group, a fluorenyl group, a triphenylenyl group, and the like, but are not limited thereto.

In the present specification, a fluorenyl group may be substituted, and two substituents may be bonded to each other to form a spiro structure.

When the fluorenyl group is substituted, the substituent may be a spirofluorenyl group such as

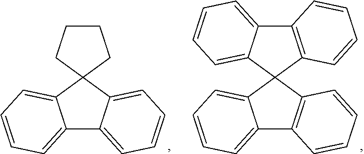

and a substituted fluorenyl group such as

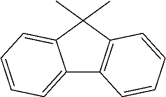

(a 9,9-dimethylfluorenyl group) and

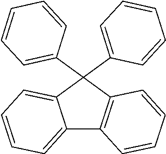 [SMILES: c1ccc(C2(c3ccccc3)c3ccccc3-c3ccccc32)cc1]

(a 9,9-diphenylfluorenyl group). However, the fluorenyl group is not limited thereto.

In the present specification, the above-described description of the aryl group may be applied to an aryl group in an aryloxy group.

In the present specification, a heterocyclic group is a cyclic group comprising one or more of N, O, P, S, Si, and Se as a heteroatom, and the number of carbon atoms thereof is not particularly limited, but is preferably 2 to 60. According to an exemplary embodiment, the number of carbon atoms of the heterocyclic group is 2 to 30. According to an exemplary embodiment, the number of carbon atoms of the heterocyclic group is 2 to 20. Examples of the heterocyclic group comprise a pyridine group, a pyrrole group, a pyrimidine group, a quinoline group, a pyridazinyl group, a furan group, a thiophene group, an imidazole group, a pyrazole group, a dibenzofuran group, a dibenzothiophene group, a carbazole group, a benzocarbazole group, a naphthobenzofuran group, a benzonaphthothiophene group, an indenocarbazole group, a triazinyl group, and the like, but are not limited thereto.

In the present specification, the above-described description of the heterocyclic group may be applied to a heteroaryl group except for an aromatic heteroaryl group.

In the present specification, the description of the aryl group may be applied to an arylene group except for a divalent arylene group.

In the present specification, the hydrocarbon ring may be an aromatic ring, an aliphatic ring, or a fused ring of the aromatic ring and the aliphatic ring, and may be selected from the examples of the cycloalkyl group or the aryl group.

In the present specification, the aliphatic hydrocarbon ring means a ring composed only of carbon and hydrogen atoms as a non-aromatic ring. Examples of the aliphatic hydrocarbon ring comprise cyclopropane, cyclobutane, cyclobutene, cyclopentane, cyclopentene, cyclohexane, cyclohexene, 1,4-cyclohexadiene, cycloheptane, cycloheptene, cyclooctane, cyclooctene, and the like, but are not limited thereto.

In the present specification, an aromatic hydrocarbon ring means an aromatic ring composed only of carbon and hydrogen atoms. Examples of the aromatic hydrocarbon ring comprise benzene, naphthalene, anthracene, phenanthrene, perylene, fluoranthene, triphenylene, phenalene, pyrene, tetracene, chrysene, pentacene, fluorene, indene, acenaphthylene, benzofluorene, spirofluorene, and the like, but are not limited thereto. In the present specification, the aromatic hydrocarbon ring may be interpreted to have the same meaning as the aryl group.

In the present specification, an aliphatic hetero ring means an aliphatic ring comprising one or more of hetero atoms. Examples of the aliphatic hetero ring comprise oxirane, tetrahydrofuran, 1,4-dioxane, pyrrolidine, piperidine, morpholine, oxepane, azocane, thiocane, and the like, but are not limited thereto.

In the present specification, an aromatic hetero ring means an aromatic ring comprising one or more of hetero atoms. Examples of the aromatic hetero ring comprise pyridine, pyrrole, pyrimidine, pyridazine, furan, thiophene, imidazole, pyrazole, oxazole, isoxazole, thiazole, isothiazole, triazole, oxadiazole, thiadiazole, dithiazole, tetrazole, pyran, thiopyran, diazine, oxazine, thiazine, dioxine, triazine, tetrazine, isoquinoline, quinoline, quinone, quinazoline, quinoxaline, naphthyridine, acridine, phenanthridine, diaza naphthalene, triazaindene, indole, indolizine, benzothiazole, benzoxazole, benzoimidazole, benzothiophene, benzofuran, dibenzothiophene, dibenzofuran, carbazole, benzocarbazole, dibenzocarbazole, phenazine, imidazopyridine, phenoxazine, indolocarbazole, indenocarbazole, and the like, but are not limited thereto.

Hereinafter, preferred exemplary embodiments of the present invention will be described in detail. However, the exemplary embodiments of the present invention may be modified into various other forms, and the scope of the present invention is not limited to the exemplary embodiments which will be described below.

The organic light emitting device of the present invention is characterized by comprising a first organic material layer comprising both a compound of Chemical Formula 1 and a compound of Chemical Formula 2. Since the compound of Chemical Formula 1 has an effect of improving the injection of electrons, the compound exhibits an effect of improving a driving voltage when applied to a device, and since the compound of Chemical Formula 2 has high efficiency characteristics when applied to a device, it is possible to obtain an effect of improving both the driving voltage and the efficiency when both the compound of Chemical Formula 1 and the compound of Chemical Formula 2 are used.

Hereinafter, Chemical Formula 1 will be described in detail.

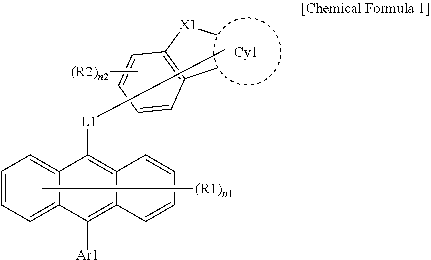

In Chemical Formula 1,
X1 is O or S,
Cy1 is a substituted or unsubstituted dibenzofuran or a substituted or unsubstituted dibenzothiophene,
L1 is a direct bond or a substituted or unsubstituted arylene group,
Ar is a substituted or unsubstituted aryl group or a substituted or unsubstituted heteroaryl group,
R1 and R2 are the same as or different from each other, and are each independently hydrogen, deuterium, a substituted or unsubstituted aryl group, or a substituted or unsubstituted heteroaryl group,
n1 is an integer from 0 to 8, and when n1 is 2 or higher, two or more R1s are the same as or different from each other, and
n2 is an integer from 0 to 4, and when n2 is 2 or higher, two or more R2s are the same as or different from each other.

According to an exemplary embodiment of the present specification, X1 is O or S.

According to an exemplary embodiment of the present specification, Cy1 is a substituted or unsubstituted dibenzofuran.

In another exemplary embodiment, Cy1 is a dibenzofuran that is unsubstituted or substituted with deuterium.

According to an exemplary embodiment of the present specification, Cy1 is a substituted or unsubstituted dibenzothiophene.

In an exemplary embodiment of the present specification, Cy1 is a dibenzothiophene that is unsubstituted or substituted with deuterium.

In an exemplary embodiment of the present specification, Chemical Formula 1 is any one of the following Chemical Formulae 1-1 to 1-6.

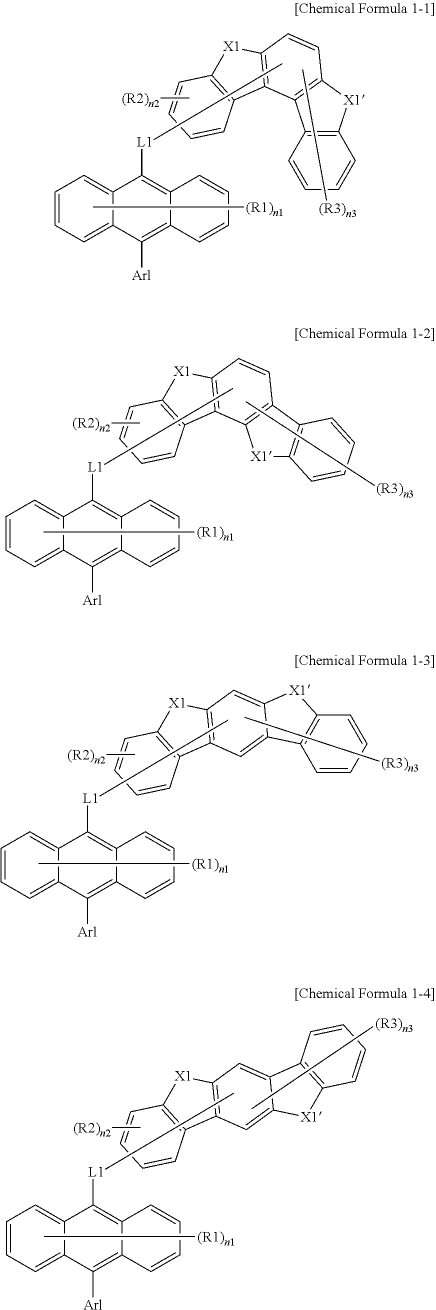

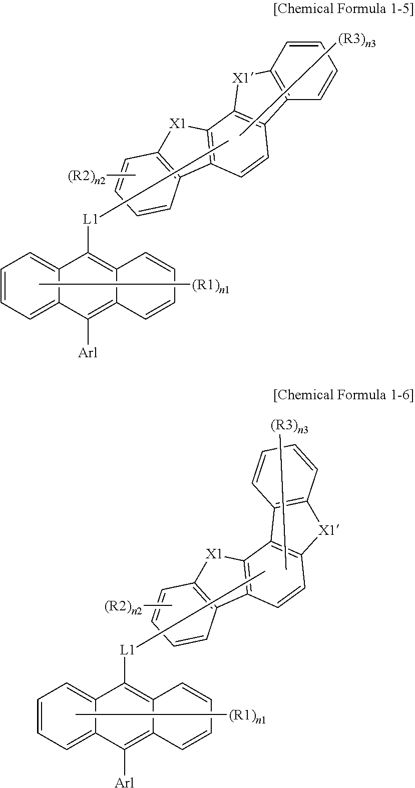

In Chemical Formulae 1-1 to 1-6,
the definitions of X1, R1, R2, n1, n2, L1 and Ar1 are the same as the definitions in Chemical Formula 1,
X1′ is O or S,
R3 is hydrogen, deuterium, a substituted or unsubstituted alkyl group, a substituted or unsubstituted cycloalkyl group, a substituted or unsubstituted aryl group, or a substituted or unsubstituted heteroaryl group, and
n3 is an integer from 0 to 6, and when n3 is 2 or higher, two or more R3s are the same as or different from each other.

According to an exemplary embodiment of the present specification, X1′ is O or S.

According to an exemplary embodiment of the present specification, L1 is a direct bond or a substituted or unsubstituted arylene group having 6 to 60 carbon atoms.

According to another exemplary embodiment, L1 is a direct bond or a substituted or unsubstituted arylene group having 6 to 30 carbon atoms.

According to still another exemplary embodiment, L1 is a direct bond.

In an exemplary embodiment of the present specification, Ar is a substituted or unsubstituted aryl group having 6 to 60 carbon atoms, or a substituted or unsubstituted heteroaryl group having 2 to 60 carbon atoms.

According to another exemplary embodiment, Ar is a substituted or unsubstituted aryl group having 6 to 30 carbon atoms, or a substituted or unsubstituted heteroaryl group having 2 to 30 carbon atoms.

According to still another exemplary embodiment, Ar1 is an aryl group having 6 to 30 carbon atoms, which is unsubstituted or substituted with deuterium; or a heteroaryl group having 2 to 30 carbon atoms, which is unsubstituted or substituted with deuterium.

According to yet another exemplary embodiment, Ar is a substituted or unsubstituted aryl group having 6 to 60 carbon atoms.

In another exemplary embodiment, Ar is a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted fluorene group, a substituted or unsubstituted fluoranthene group, a substituted or unsubstituted triphenylene group, a substituted or unsubstituted benzofuran group, a substituted or unsubstituted benzothiophene group, a substituted or unsubstituted dibenzofuran group, a substituted or unsubstituted naphthobenzofuran group, a substituted or unsubstituted carbazole group; or a combination thereof.

In another exemplary embodiment, Ar is a substituted or unsubstituted phenyl group, a substituted or unsubstituted biphenyl group, a substituted or unsubstituted terphenyl group, a substituted or unsubstituted naphthyl group, a substituted or unsubstituted phenanthrene group, a substituted or unsubstituted fluorene group, a substituted or unsubstituted fluoranthene group, a substituted or unsubstituted triphenylene group, a substituted or unsubstituted benzofuran group, a substituted or unsubstituted benzothiophene group, a substituted or unsubstituted dibenzofuran group, a substituted or unsubstituted naphthobenzofuran group, a substituted or unsubstituted carbazole group, or a combination thereof. In this case, the substituents may be unsubstituted or substituted with deuterium.

According to an exemplary embodiment of the present specification, R1 and R2 are the same as or different from each other, and are each independently hydrogen, deuterium, a substituted or unsubstituted aryl group having 6 to 60 carbon atoms, or a substituted or unsubstituted heteroaryl group having 2 to 60 carbon atoms.

According to another exemplary embodiment, R1 and R2 are the same as or different from each other, and are each independently hydrogen, deuterium, a substituted or unsubstituted aryl group having 6 to 30 carbon atoms, or a substituted or unsubstituted heteroaryl group having 2 to 30 carbon atoms.

According to still another exemplary embodiment, R1 and R2 are the same as or different from each other, and are each independently hydrogen or deuterium.

According to an exemplary embodiment of the present specification, the R3s are the same as or different from each other, and are each independently hydrogen, deuterium, a substituted or unsubstituted aryl group having 6 to 60 carbon atoms, or a substituted or unsubstituted heteroaryl group having 2 to 60 carbon atoms.

According to another exemplary embodiment, the R3s are the same as or different from each other, and are each independently hydrogen, deuterium, a substituted or unsubstituted aryl group having 6 to 30 carbon atoms, or a substituted or unsubstituted heteroaryl group having 2 to 30 carbon atoms.

According to still another exemplary embodiment, the R3s are the same as or different from each other, and are each independently hydrogen or deuterium.

According to an exemplary embodiment of the present specification, n1 is an integer from 0 to 8, and when n1 is 2 or higher, two or more R1s are the same as or different from each other.

According to an exemplary embodiment of the present specification, n2 is an integer from 0 to 4, and when n2 is 2 or higher, two or more R2s are the same as or different from each other.

According to an exemplary embodiment of the present specification, n3 is an integer from 0 to 6, and when n3 is 2 or higher, two or more R3s are the same as or different from each other.

In an exemplary embodiment of the present specification, the compound of Chemical Formula 1 is any one of the following compounds.

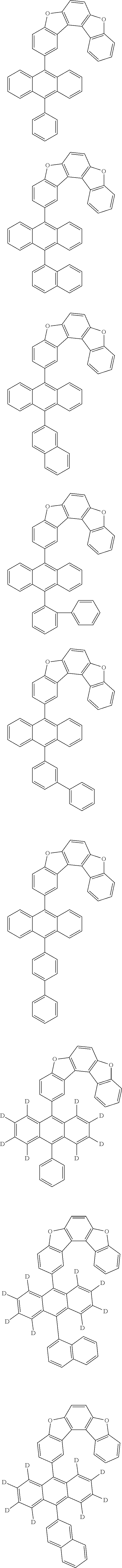

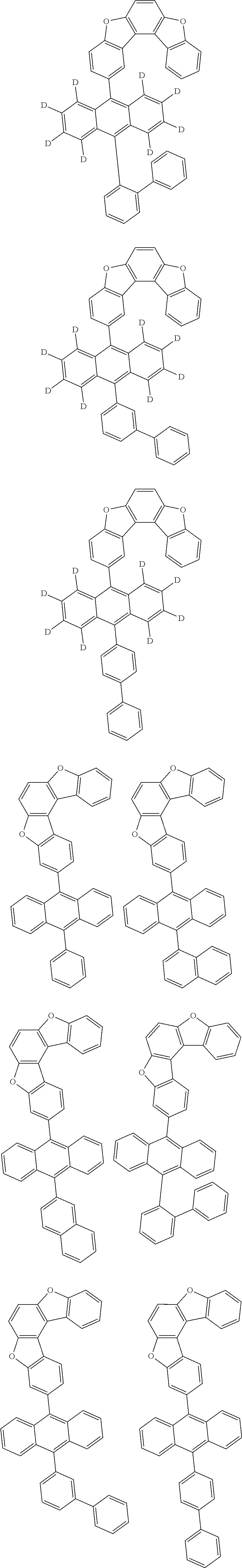

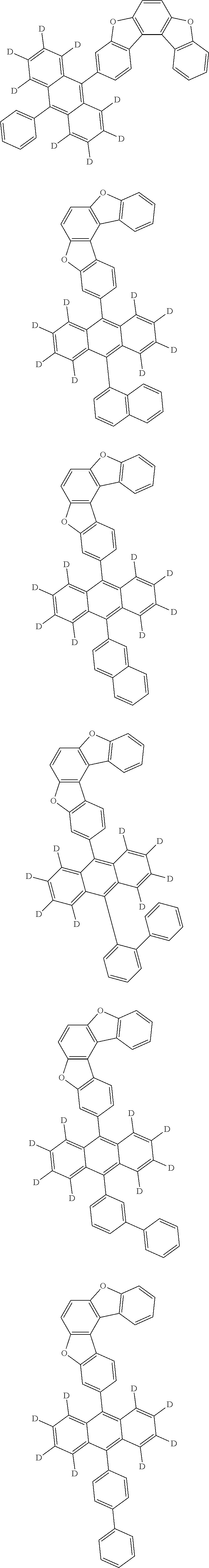

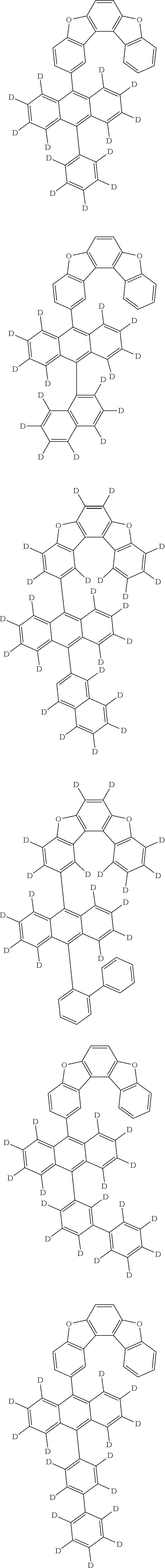

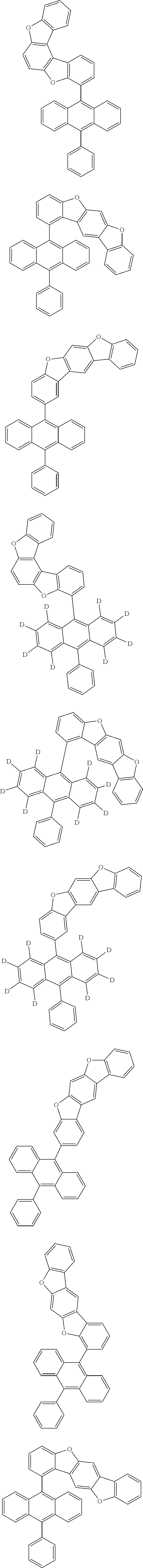

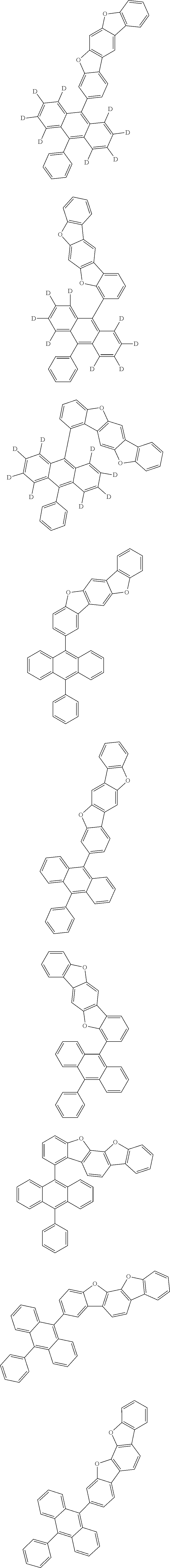

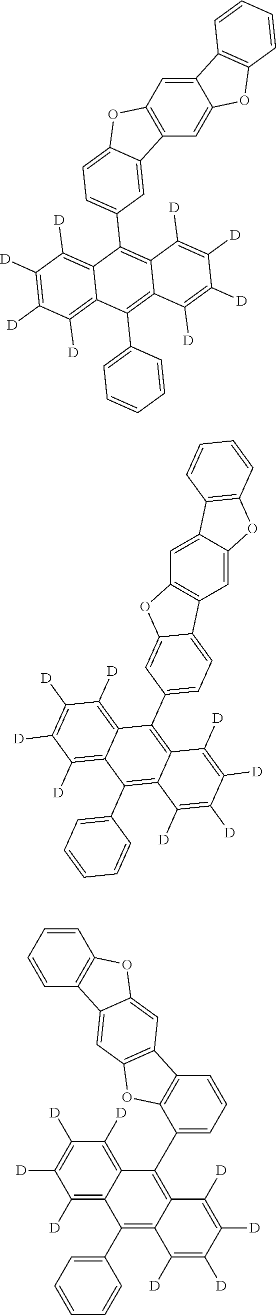 [SMILES: [2H]c1c([2H])c([2H])c2c(-c3ccc4oc5cc6c(cc5c4c3)oc3ccccc36)c3c([2H])c([2H])c([2H])c([2H])c3c(-c3ccccc3)c2c1[2H] ; [2H]c1c([2H])c([2H])c2c(-c3ccc4c(c3)oc3cc5c(cc34)oc3ccccc35)c3c([2H])c([2H])c([2H])c([2H])c3c(-c3ccccc3)c2c1[2H] ; [2H]c1c([2H])c([2H])c2c(-c3cccc4c3oc3cc5c(cc34)oc3ccccc35)c3c([2H])c([2H])c([2H])c([2H])c3c(-c3ccccc3)c2c1[2H]]

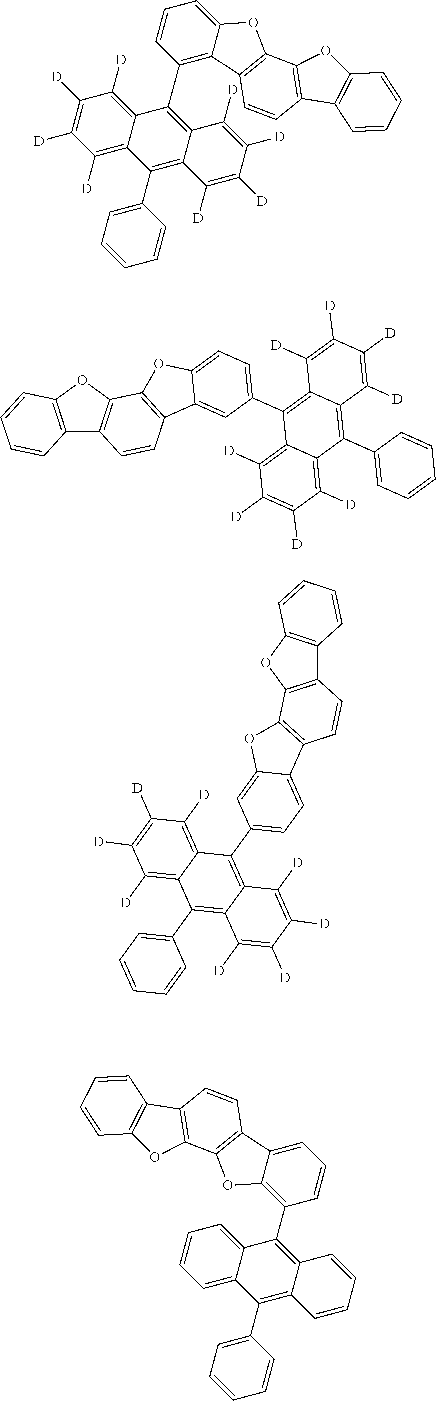

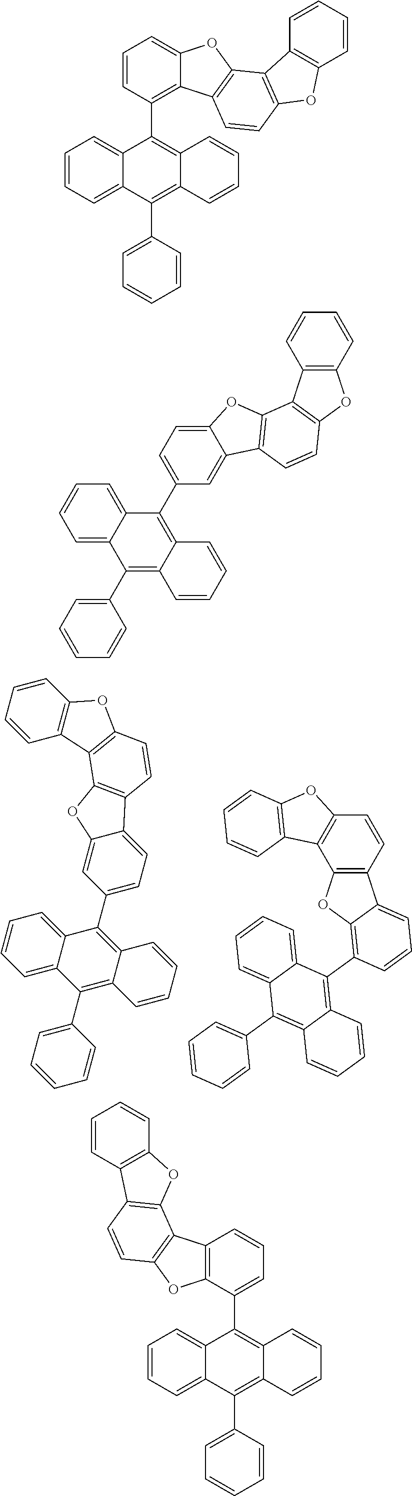

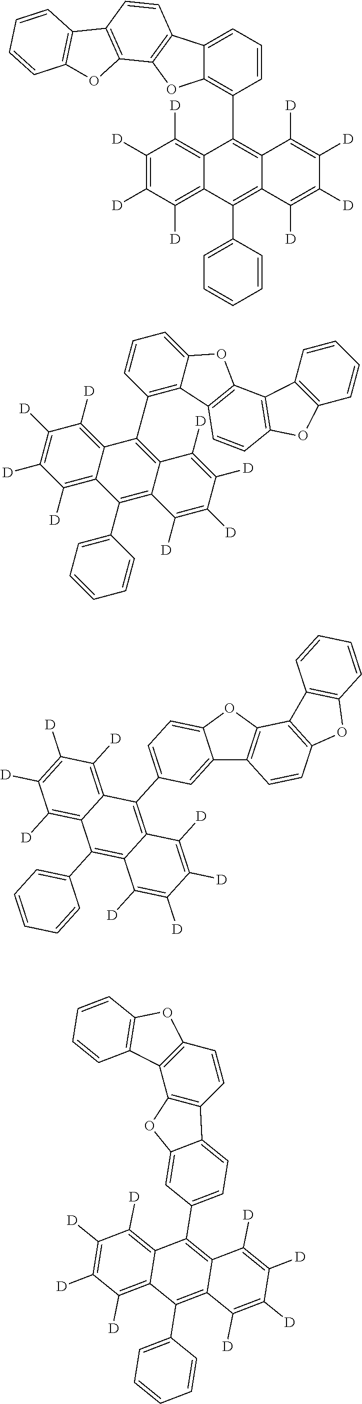 [SMILES: [2H]c1c([2H])c([2H])c2c(-c3cccc4c3oc3c4ccc4c5ccccc5oc43)c3c([2H])c([2H])c([2H])c([2H])c3c(-c3ccccc3)c2c1[2H] ; [2H]c1c([2H])c([2H])c2c(-c3cccc4oc5c(ccc6oc7ccccc7c65)c34)c3c([2H])c([2H])c([2H])c([2H])c3c(-c3ccccc3)c2c1[2H] ; [2H]c1c([2H])c([2H])c2c(-c3ccc4oc5c(ccc6oc7ccccc7c65)c4c3)c3c([2H])c([2H])c([2H])c([2H])c3c(-c3ccccc3)c2c1[2H] ; [2H]c1c([2H])c([2H])c2c(-c3ccc4c(c3)oc3c4ccc4oc5ccccc5c43)c3c([2H])c([2H])c([2H])c([2H])c3c(-c3ccccc3)c2c1[2H]]

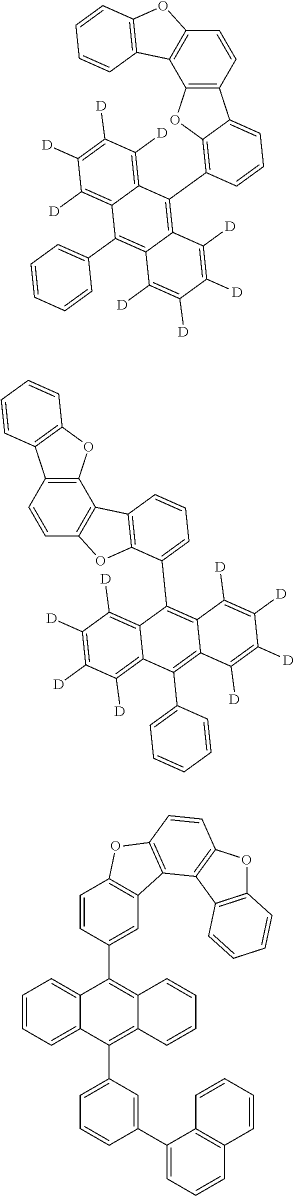

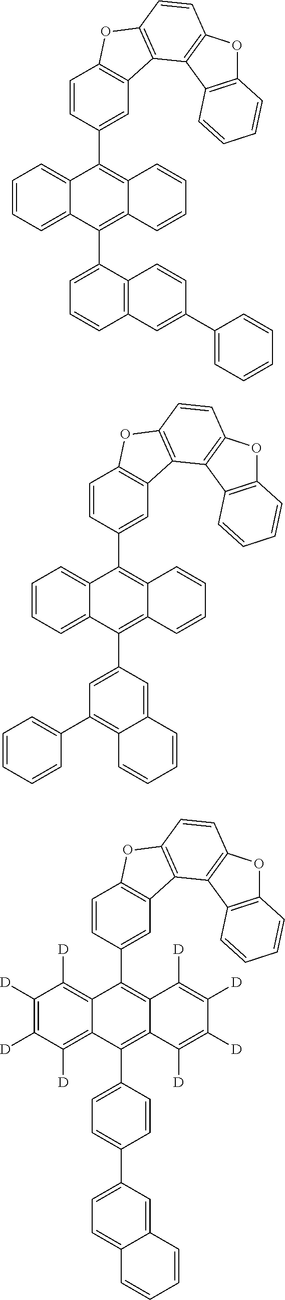

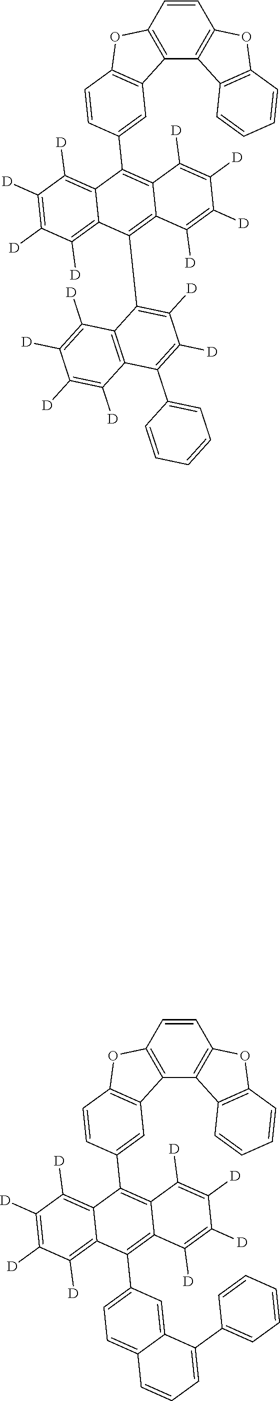 [SMILES: [2H]c1c([2H])c([2H])c2c(-c3c4c([2H])c([2H])c([2H])c([2H])c4c(-c4ccc5oc6ccc7oc8ccccc8c7c6c5c4)c4c([2H])c([2H])c([2H])c([2H])c34)c([2H])c([2H])c(-c3ccccc3)c2c1[2H] ; [2H]c1c([2H])c([2H])c2c(-c3ccc4oc5ccc6oc7ccccc7c6c5c4c3)c3c([2H])c([2H])c([2H])c([2H])c3c(-c3ccc4cccc(-c5ccccc5)c4c3)c2c1[2H]]

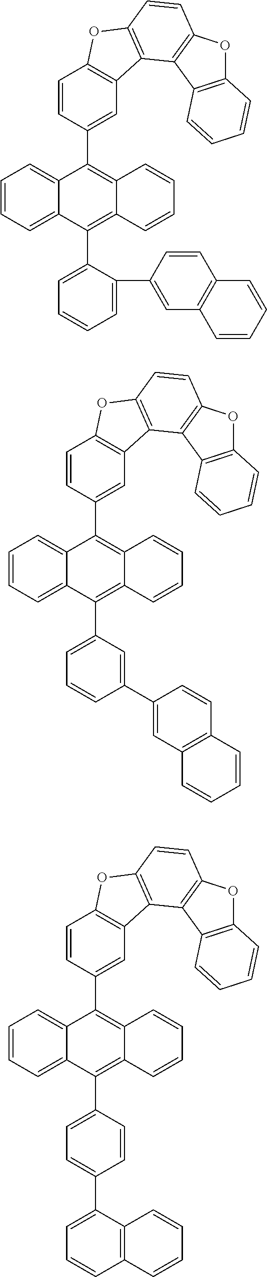 [SMILES: c1ccc(-c2c3ccccc3c(-c3ccc4oc5ccc6oc7ccccc7c6c5c4c3)c3ccccc23)c(-c2ccc3ccccc3c2)c1 ; c1cc(-c2ccc3ccccc3c2)cc(-c2c3ccccc3c(-c3ccc4oc5ccc6oc7ccccc7c6c5c4c3)c3ccccc23)c1 ; c1ccc2c(-c3ccc(-c4c5ccccc5c(-c5ccc6oc7ccc8oc9ccccc9c8c7c6c5)c5ccccc45)cc3)cccc2c1]

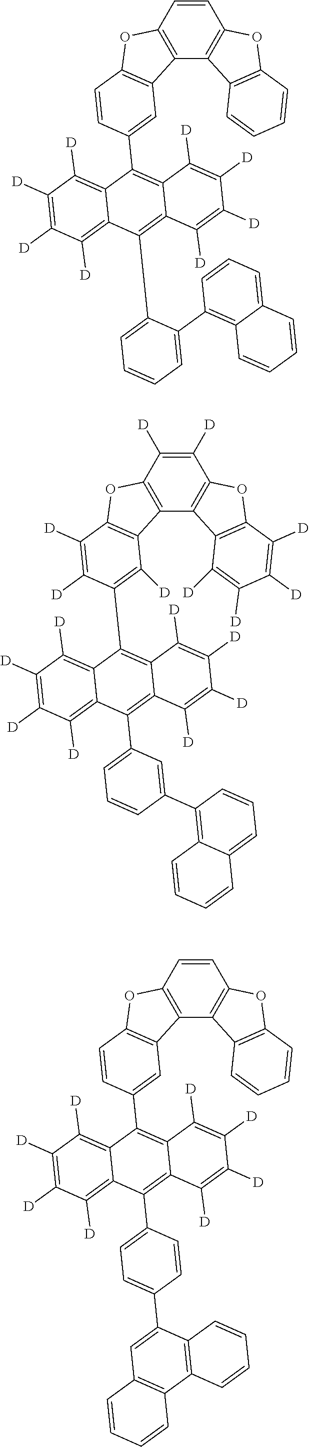

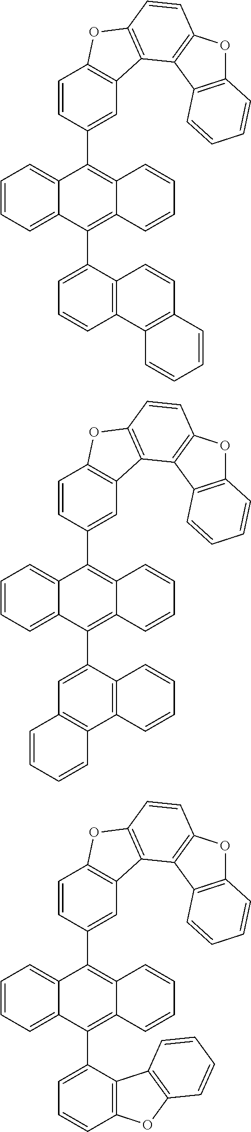

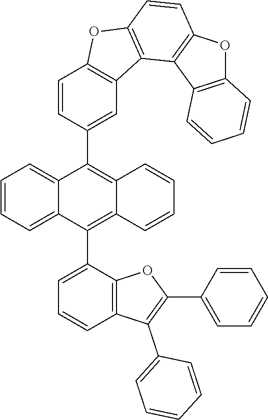 [SMILES: c1ccc(-c2oc3c(-c4c5ccccc5c(-c5ccc6oc7ccc8oc9ccccc9c8c7c6c5)c5ccccc45)cccc3c2-c2ccccc2)cc1]

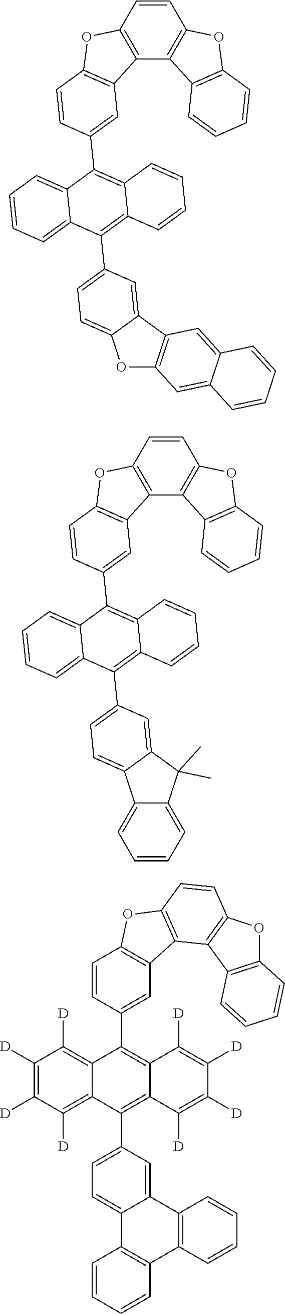

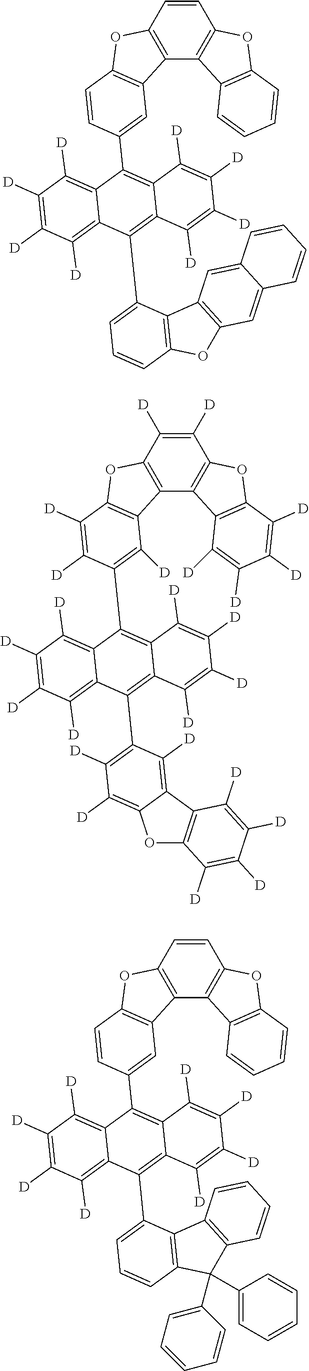

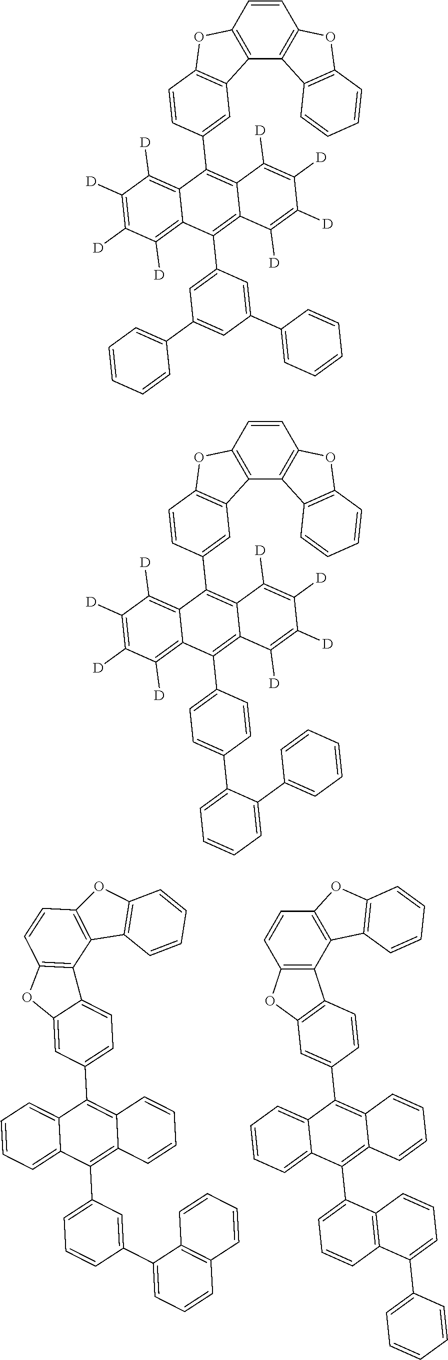 [SMILES: [2H]c1c([2H])c([2H])c2c(-c3ccc4oc5ccc6oc7ccccc7c6c5c4c3)c3c([2H])c([2H])c([2H])c([2H])c3c(-c3cc(-c4ccccc4)cc(-c4ccccc4)c3)c2c1[2H] ; [2H]c1c([2H])c([2H])c2c(-c3ccc4oc5ccc6oc7ccccc7c6c5c4c3)c3c([2H])c([2H])c([2H])c([2H])c3c(-c3ccc(-c4ccccc4-c4ccccc4)cc3)c2c1[2H] ; c1cc(-c2cccc3ccccc23)cc(-c2c3ccccc3c(-c3ccc4c(c3)oc3ccc5oc6ccccc6c5c34)c3ccccc23)c1 ; c1ccc(-c2cccc3c(-c4c5ccccc5c(-c5ccc6c(c5)oc5ccc7oc8ccccc8c7c56)c5ccccc45)cccc23)cc1]

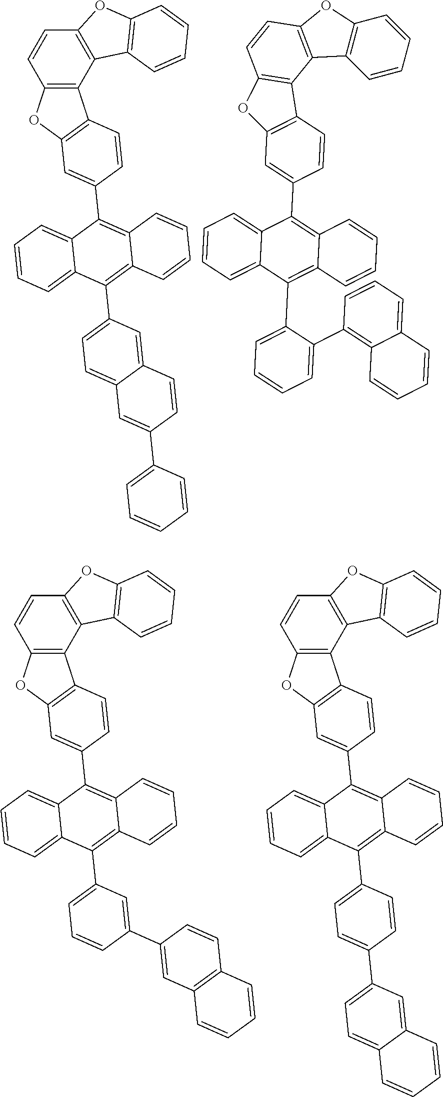

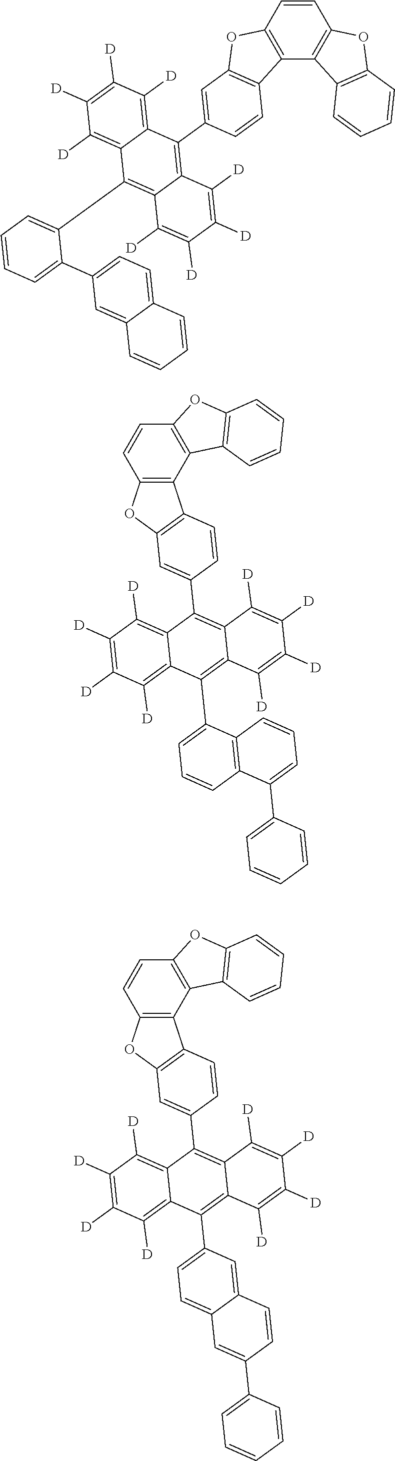

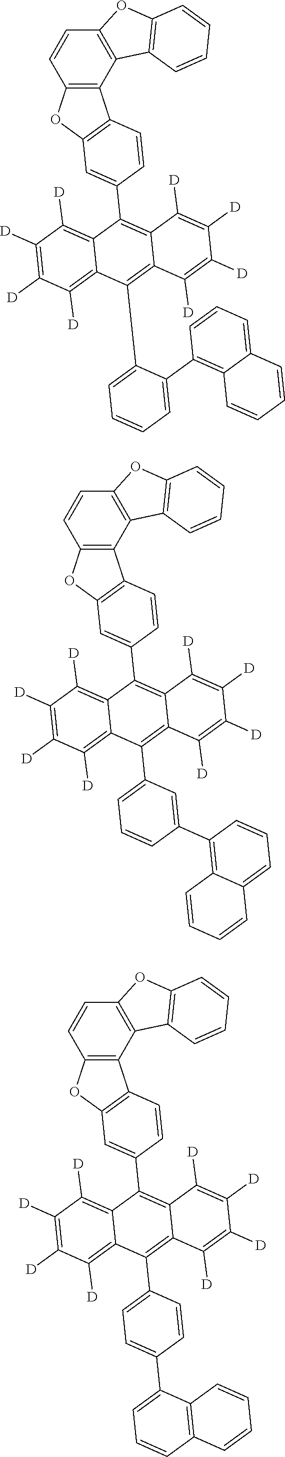

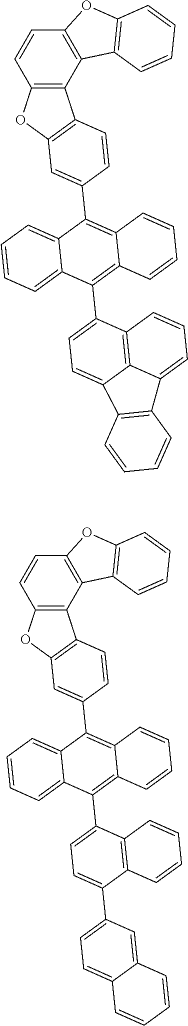 [SMILES: c1ccc2c(c1)-c1cccc3c(-c4c5ccccc5c(-c5ccc6c(c5)oc5ccc7oc8ccccc8c7c56)c5ccccc45)ccc-2c13 ; c1ccc2cc(-c3ccc(-c4c5ccccc5c(-c5ccc6c(c5)oc5ccc7oc8ccccc8c7c56)c5ccccc45)c4ccccc34)ccc2c1]

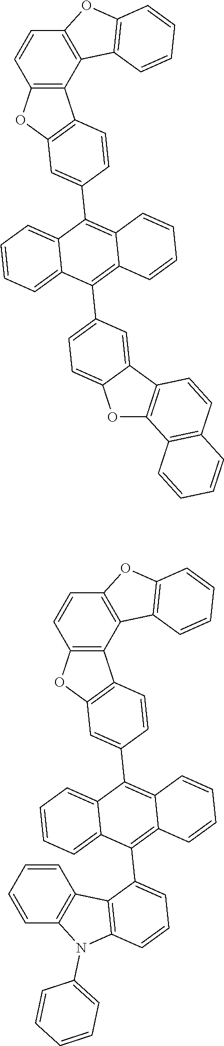 [SMILES: c1ccc2c(c1)ccc1c3cc(-c4c5ccccc5c(-c5ccc6c(c5)oc5ccc7oc8ccccc8c7c56)c5ccccc45)ccc3oc21 ; c1ccc(-n2c3ccccc3c3c(-c4c5ccccc5c(-c5ccc6c(c5)oc5ccc7oc8ccccc8c7c56)c5ccccc45)cccc32)cc1]

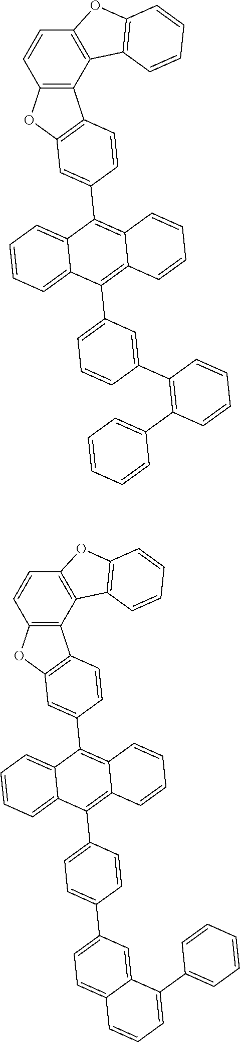 [SMILES: c1ccc(-c2ccccc2-c2cccc(-c3c4ccccc4c(-c4ccc5c(c4)oc4ccc6oc7ccccc7c6c45)c4ccccc34)c2)cc1 ; c1ccc(-c2cccc3ccc(-c4ccc(-c5c6ccccc6c(-c6ccc7c(c6)oc6ccc8oc9ccccc9c8c67)c6ccccc56)cc4)cc23)cc1]

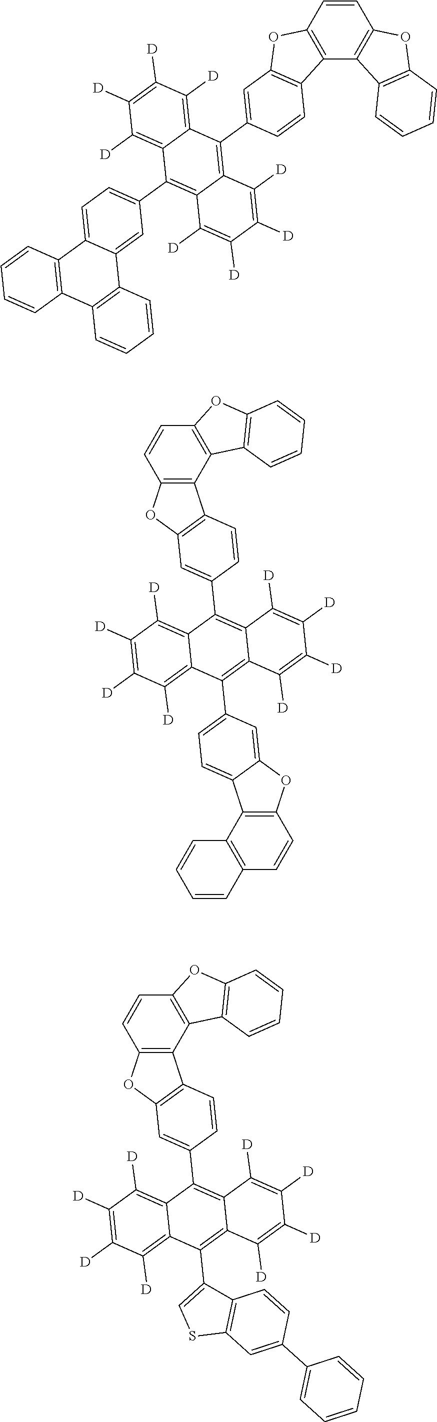 [SMILES: [2H]c1c([2H])c([2H])c2c(-c3ccc4c5ccccc5c5ccccc5c4c3)c3c([2H])c([2H])c([2H])c([2H])c3c(-c3ccc4c(c3)oc3ccc5oc6ccccc6c5c34)c2c1[2H] ; [2H]c1c([2H])c([2H])c2c(-c3ccc4c(c3)oc3ccc5oc6ccccc6c5c34)c3c([2H])c([2H])c([2H])c([2H])c3c(-c3ccc4c(c3)oc3ccc5ccccc5c34)c2c1[2H] ; [2H]c1c([2H])c([2H])c2c(-c3csc4cc(-c5ccccc5)ccc34)c3c([2H])c([2H])c([2H])c([2H])c3c(-c3ccc4c(c3)oc3ccc5oc6ccccc6c5c34)c2c1[2H]]

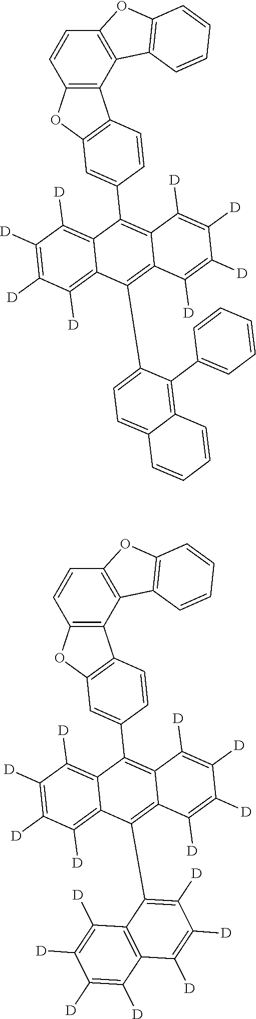 [SMILES: [2H]c1c([2H])c([2H])c2c(-c3ccc4ccccc4c3-c3ccccc3)c3c([2H])c([2H])c([2H])c([2H])c3c(-c3ccc4c(c3)oc3ccc5oc6ccccc6c5c34)c2c1[2H] ; [2H]c1c([2H])c([2H])c2c(-c3c4c([2H])c([2H])c([2H])c([2H])c4c(-c4ccc5c(c4)oc4ccc6oc7ccccc7c6c45)c4c([2H])c([2H])c([2H])c([2H])c34)c([2H])c([2H])c([2H])c2c1[2H]]

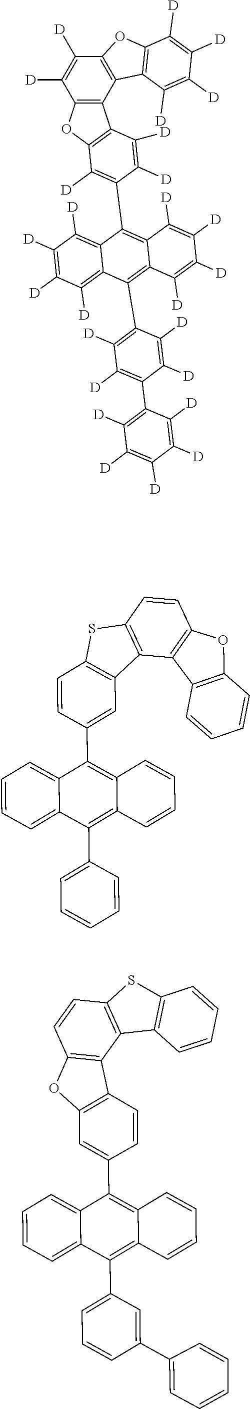 [SMILES: [2H]c1c([2H])c([2H])c(-c2c([2H])c([2H])c(-c3c4c([2H])c([2H])c([2H])c([2H])c4c(-c4c([2H])c([2H])c5c(oc6c([2H])c([2H])c7oc8c([2H])c([2H])c([2H])c([2H])c8c7c65)c4[2H])c4c([2H])c([2H])c([2H])c([2H])c34)c([2H])c2[2H])c([2H])c1[2H] ; c1ccc(-c2c3ccccc3c(-c3ccc4sc5ccc6oc7ccccc7c6c5c4c3)c3ccccc23)cc1 ; c1ccc(-c2cccc(-c3c4ccccc4c(-c4ccc5c(c4)oc4ccc6sc7ccccc7c6c45)c4ccccc34)c2)cc1]

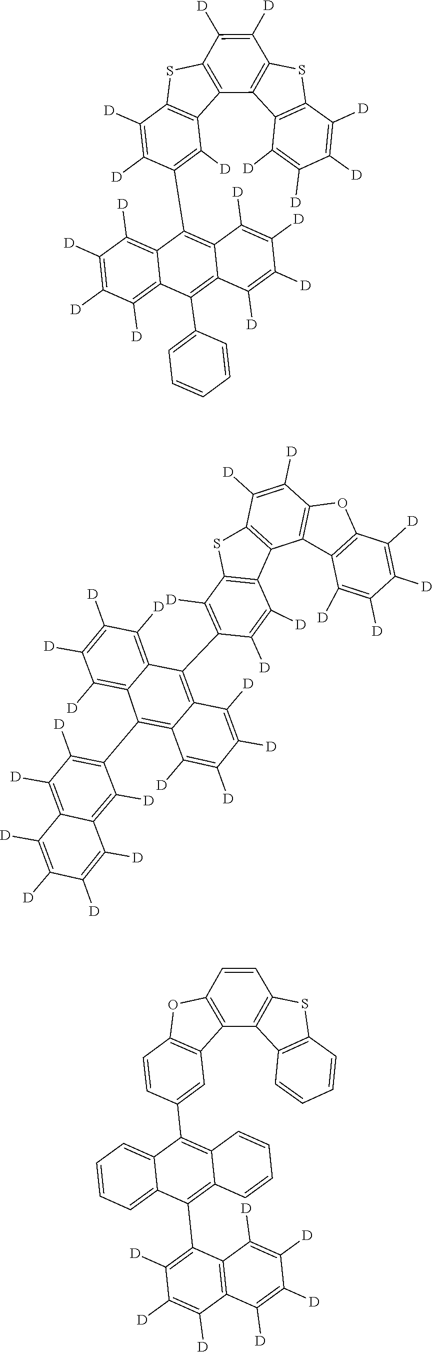 [SMILES: [2H]c1c([2H])c([2H])c2c(sc3c([2H])c([2H])c4sc5c([2H])c([2H])c(-c6c7c([2H])c([2H])c([2H])c([2H])c7c(-c7ccccc7)c7c([2H])c([2H])c([2H])c([2H])c67)c([2H])c5c4c32)c1[2H] ; [2H]c1c([2H])c([2H])c2c(oc3c([2H])c([2H])c4sc5c([2H])c(-c6c7c([2H])c([2H])c([2H])c([2H])c7c(-c7c([2H])c([2H])c8c([2H])c([2H])c([2H])c([2H])c8c7[2H])c7c([2H])c([2H])c([2H])c([2H])c67)c([2H])c([2H])c5c4c32)c1[2H] ; [2H]c1c([2H])c([2H])c2c(-c3c4ccccc4c(-c4ccc5oc6ccc7sc8ccccc8c7c6c5c4)c4ccccc34)c([2H])c([2H])c([2H])c2c1[2H]]

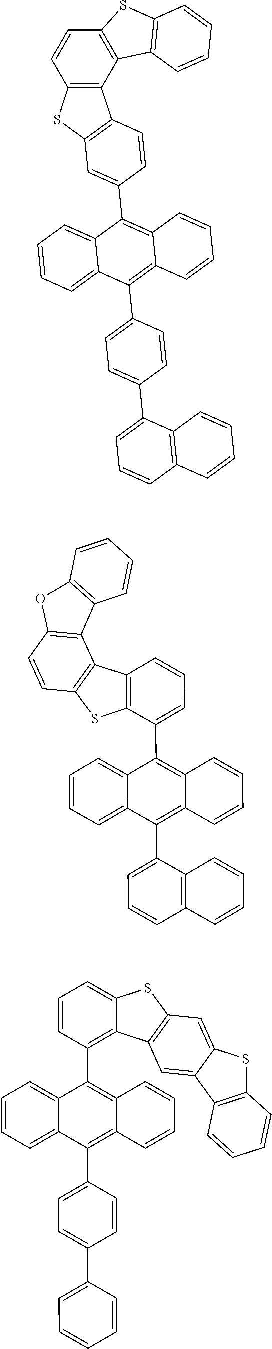 [SMILES: c1ccc2c(-c3ccc(-c4c5ccccc5c(-c5ccc6c(c5)sc5ccc7sc8ccccc8c7c56)c5ccccc45)cc3)cccc2c1 ; c1ccc2c(-c3c4ccccc4c(-c4cccc5c4sc4ccc6oc7ccccc7c6c45)c4ccccc34)cccc2c1 ; c1ccc(-c2ccc(-c3c4ccccc4c(-c4cccc5sc6cc7sc8ccccc8c7cc6c45)c4ccccc34)cc2)cc1]

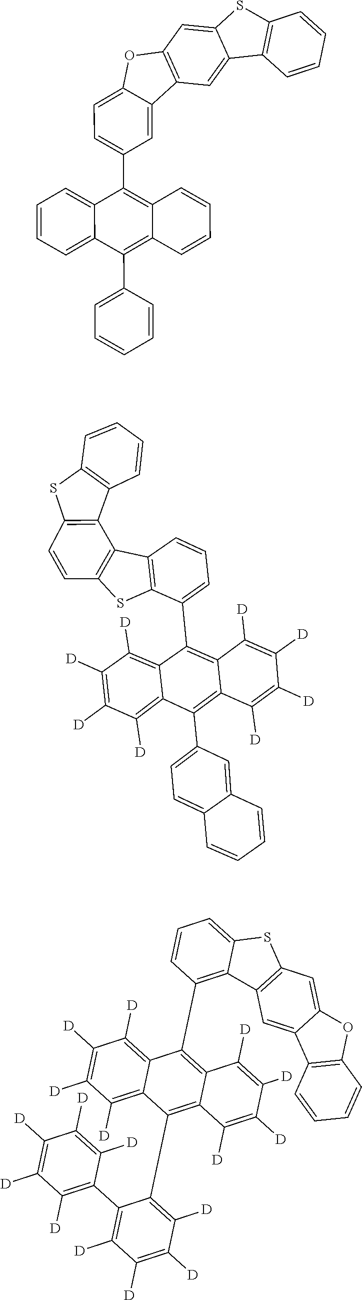 [SMILES: c1ccc(-c2c3ccccc3c(-c3ccc4oc5cc6sc7ccccc7c6cc5c4c3)c3ccccc23)cc1 ; [2H]c1c([2H])c([2H])c2c(-c3cccc4c3sc3ccc5sc6ccccc6c5c34)c3c([2H])c([2H])c([2H])c([2H])c3c(-c3ccc4ccccc4c3)c2c1[2H] ; [2H]c1c([2H])c([2H])c(-c2c([2H])c([2H])c([2H])c([2H])c2-c2c3c([2H])c([2H])c([2H])c([2H])c3c(-c3cccc4sc5cc6oc7ccccc7c6cc5c34)c3c([2H])c([2H])c([2H])c([2H])c23)c([2H])c1[2H]]

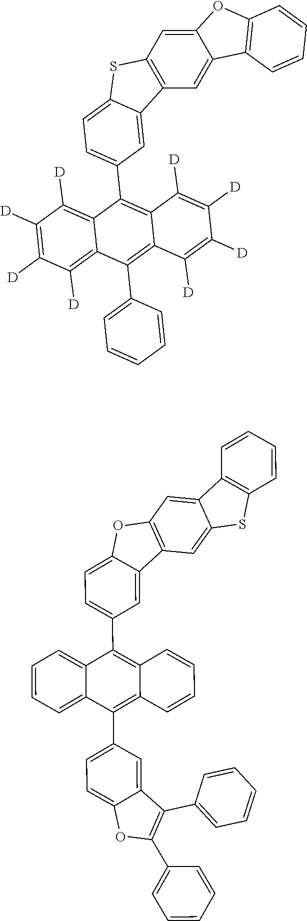 [SMILES: [2H]c1c([2H])c([2H])c2c(-c3ccc4sc5cc6oc7ccccc7c6cc5c4c3)c3c([2H])c([2H])c([2H])c([2H])c3c(-c3ccccc3)c2c1[2H] ; c1ccc(-c2oc3ccc(-c4c5ccccc5c(-c5ccc6oc7cc8c(cc7c6c5)sc5ccccc58)c5ccccc45)cc3c2-c2ccccc2)cc1]

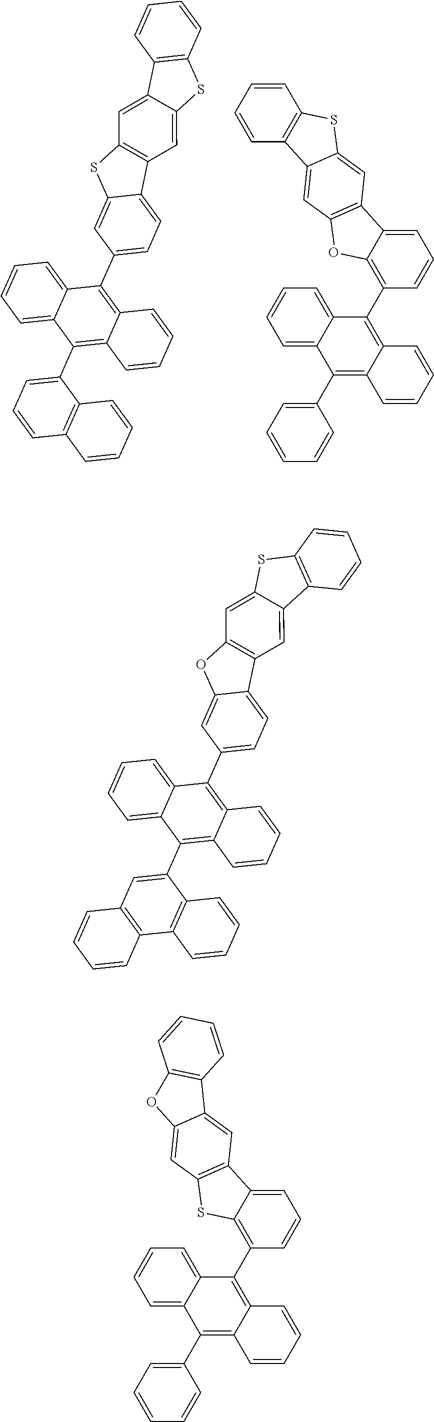

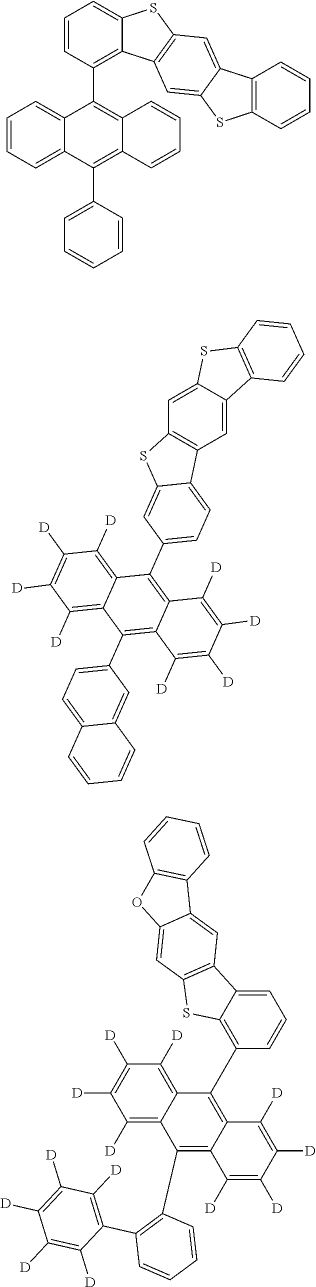 [SMILES: c1ccc(-c2c3ccccc3c(-c3cccc4sc5cc6c(cc5c34)sc3ccccc36)c3ccccc23)cc1 ; [2H]c1c([2H])c([2H])c2c(-c3ccc4c(c3)sc3cc5sc6ccccc6c5cc34)c3c([2H])c([2H])c([2H])c([2H])c3c(-c3ccc4ccccc4c3)c2c1[2H] ; [2H]c1c([2H])c([2H])c(-c2ccccc2-c2c3c([2H])c([2H])c([2H])c([2H])c3c(-c3cccc4c3sc3cc5oc6ccccc6c5cc34)c3c([2H])c([2H])c([2H])c([2H])c23)c([2H])c1[2H]]

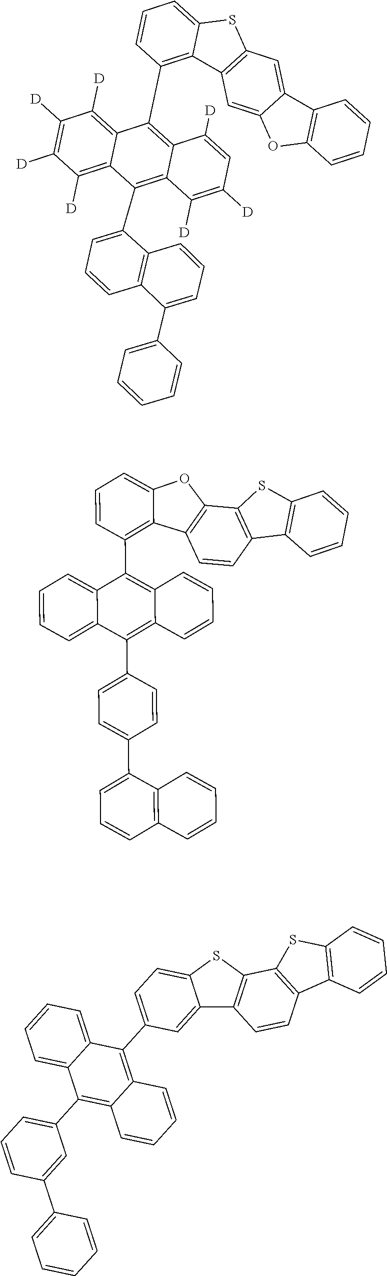 [SMILES: [2H]c1cc([2H])c2c(-c3cccc4sc5cc6c(cc5c34)oc3ccccc36)c3c([2H])c([2H])c([2H])c([2H])c3c(-c3cccc4c(-c5ccccc5)cccc34)c2c1[2H] ; c1ccc2c(-c3ccc(-c4c5ccccc5c(-c5cccc6oc7c(ccc8c9ccccc9sc87)c56)c5ccccc45)cc3)cccc2c1 ; c1ccc(-c2cccc(-c3c4ccccc4c(-c4ccc5sc6c(ccc7c8ccccc8sc76)c5c4)c4ccccc34)c2)cc1]

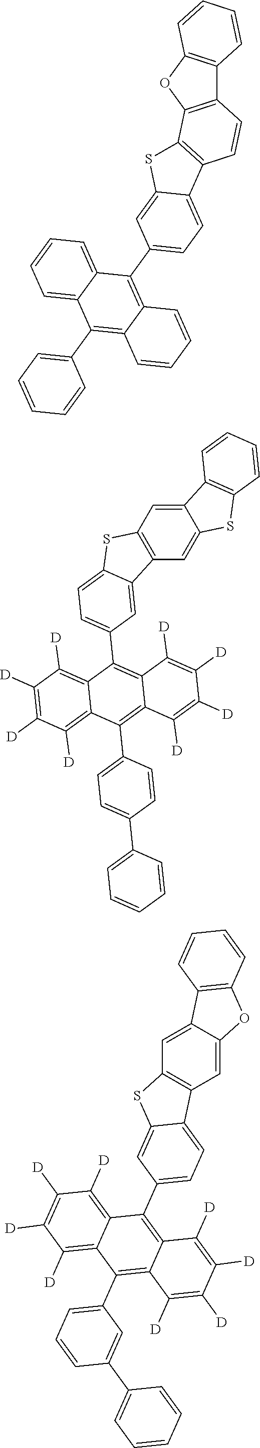 [SMILES: c1ccc(-c2c3ccccc3c(-c3ccc4c(c3)sc3c4ccc4c5ccccc5oc43)c3ccccc23)cc1 ; [2H]c1c([2H])c([2H])c2c(-c3ccc4sc5cc6c(cc5c4c3)sc3ccccc36)c3c([2H])c([2H])c([2H])c([2H])c3c(-c3ccc(-c4ccccc4)cc3)c2c1[2H] ; [2H]c1c([2H])c([2H])c2c(-c3ccc4c(c3)sc3cc5c(cc34)oc3ccccc35)c3c([2H])c([2H])c([2H])c([2H])c3c(-c3cccc(-c4ccccc4)c3)c2c1[2H]]

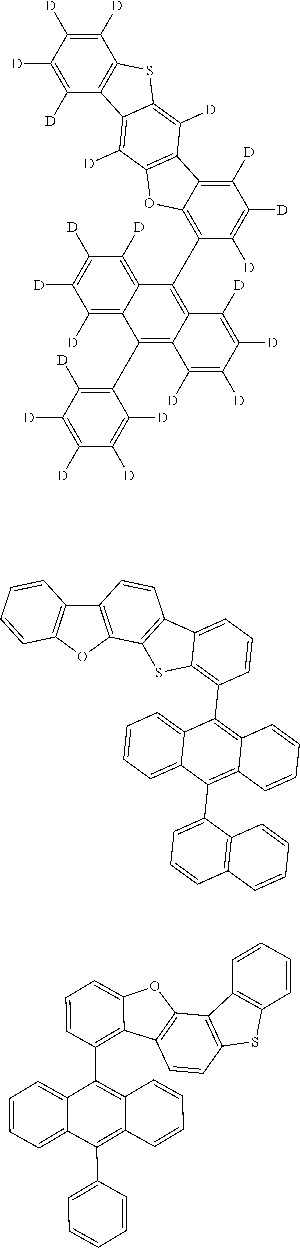 [SMILES: [2H]c1c([2H])c([2H])c(-c2c3c([2H])c([2H])c([2H])c([2H])c3c(-c3c([2H])c([2H])c([2H])c4c3oc3c([2H])c5c(sc6c([2H])c([2H])c([2H])c([2H])c65)c([2H])c34)c3c([2H])c([2H])c([2H])c([2H])c23)c([2H])c1[2H] ; c1ccc2c(-c3c4ccccc4c(-c4cccc5c4sc4c5ccc5c6ccccc6oc54)c4ccccc34)cccc2c1 ; c1ccc(-c2c3ccccc3c(-c3cccc4oc5c(ccc6sc7ccccc7c65)c34)c3ccccc23)cc1]

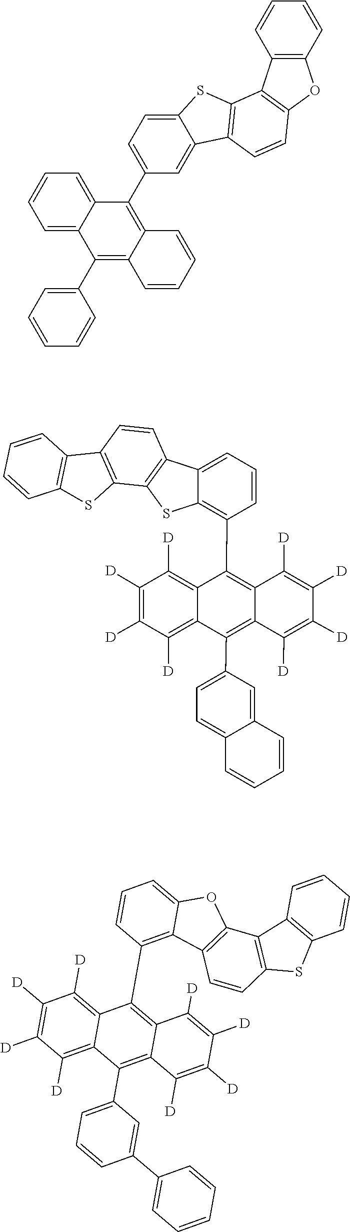 [SMILES: c1ccc(-c2c3ccccc3c(-c3ccc4sc5c(ccc6oc7ccccc7c65)c4c3)c3ccccc23)cc1 ; [2H]c1c([2H])c([2H])c2c(-c3cccc4c3sc3c4ccc4c5ccccc5sc43)c3c([2H])c([2H])c([2H])c([2H])c3c(-c3ccc4ccccc4c3)c2c1[2H] ; [2H]c1c([2H])c([2H])c2c(-c3cccc4oc5c(ccc6sc7ccccc7c65)c34)c3c([2H])c([2H])c([2H])c([2H])c3c(-c3cccc(-c4ccccc4)c3)c2c1[2H]]

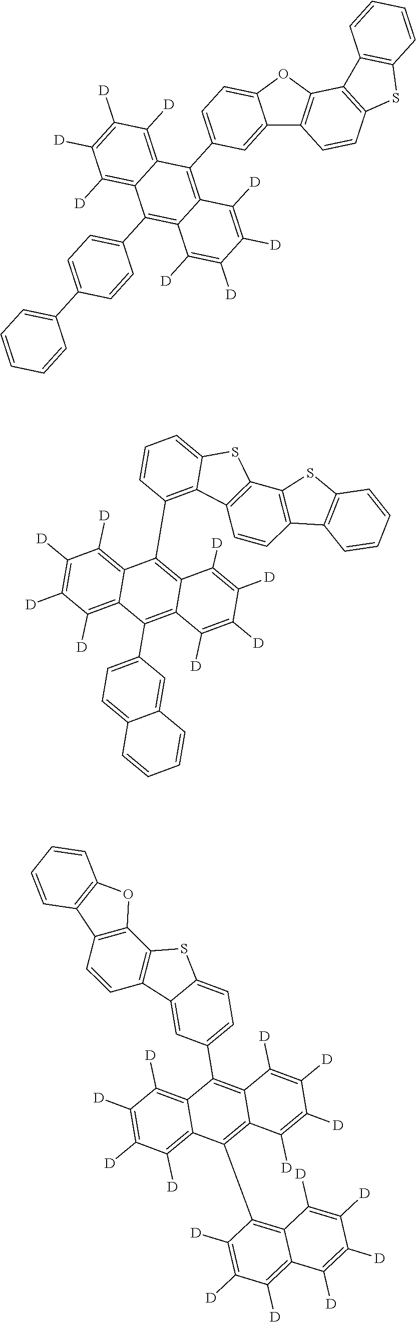 [SMILES: [2H]c1c([2H])c([2H])c2c(-c3ccc4oc5c(ccc6sc7ccccc7c65)c4c3)c3c([2H])c([2H])c([2H])c([2H])c3c(-c3ccc(-c4ccccc4)cc3)c2c1[2H] ; [2H]c1c([2H])c([2H])c2c(-c3cccc4sc5c(ccc6c7ccccc7sc65)c34)c3c([2H])c([2H])c([2H])c([2H])c3c(-c3ccc4ccccc4c3)c2c1[2H] ; [2H]c1c([2H])c([2H])c2c(-c3c4c([2H])c([2H])c([2H])c([2H])c4c(-c4ccc5sc6c(ccc7c8ccccc8oc76)c5c4)c4c([2H])c([2H])c([2H])c([2H])c34)c([2H])c([2H])c([2H])c2c1[2H]]

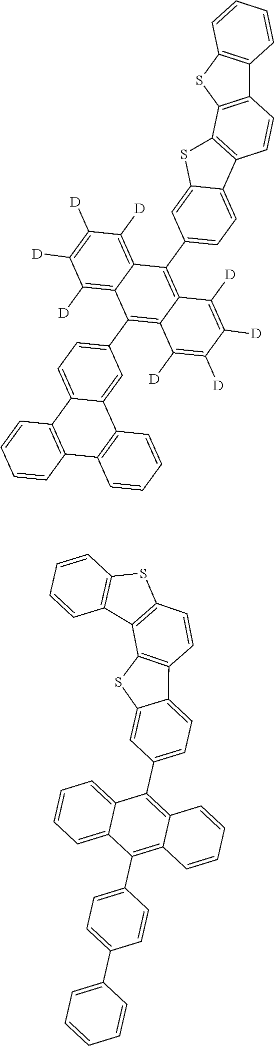 [SMILES: [2H]c1c([2H])c([2H])c2c(-c3ccc4c5ccccc5c5ccccc5c4c3)c3c([2H])c([2H])c([2H])c([2H])c3c(-c3ccc4c(c3)sc3c4ccc4c5ccccc5sc43)c2c1[2H] ; c1ccc(-c2ccc(-c3c4ccccc4c(-c4ccc5c(c4)sc4c5ccc5sc6ccccc6c54)c4ccccc34)cc2)cc1]

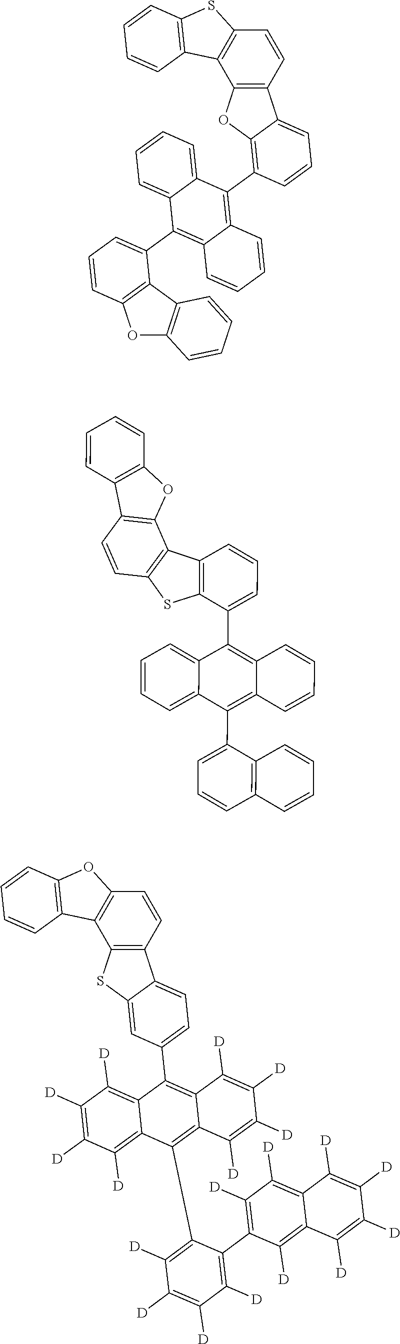 [SMILES: c1ccc2c(c1)oc1cccc(-c3c4ccccc4c(-c4cccc5c4oc4c5ccc5sc6ccccc6c54)c4ccccc34)c12 ; c1ccc2c(-c3c4ccccc4c(-c4cccc5c4sc4ccc6c7ccccc7oc6c45)c4ccccc34)cccc2c1 ; [2H]c1c([2H])c([2H])c(-c2c3c([2H])c([2H])c([2H])c([2H])c3c(-c3ccc4c(c3)sc3c4ccc4oc5ccccc5c43)c3c([2H])c([2H])c([2H])c([2H])c23)c(-c2c([2H])c([2H])c3c([2H])c([2H])c([2H])c([2H])c3c2[2H])c1[2H]]

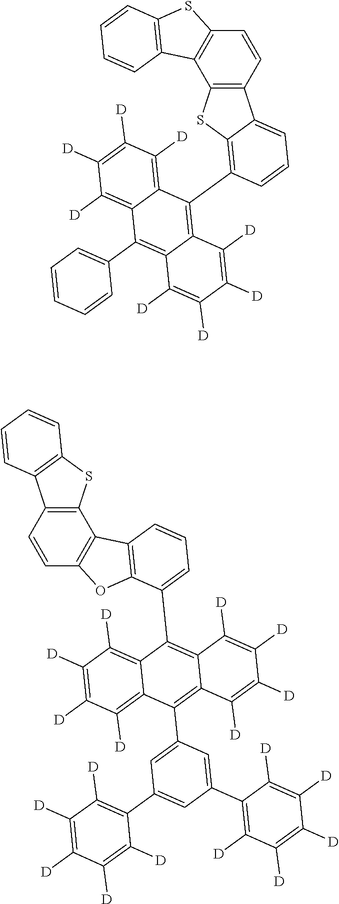 [SMILES: [2H]c1c([2H])c([2H])c2c(-c3cccc4c3sc3c4ccc4sc5ccccc5c43)c3c([2H])c([2H])c([2H])c([2H])c3c(-c3ccccc3)c2c1[2H] ; [2H]c1c([2H])c([2H])c(-c2cc(-c3c([2H])c([2H])c([2H])c([2H])c3[2H])cc(-c3c4c([2H])c([2H])c([2H])c([2H])c4c(-c4cccc5c4oc4ccc6c7ccccc7sc6c45)c4c([2H])c([2H])c([2H])c([2H])c34)c2)c([2H])c1[2H]]

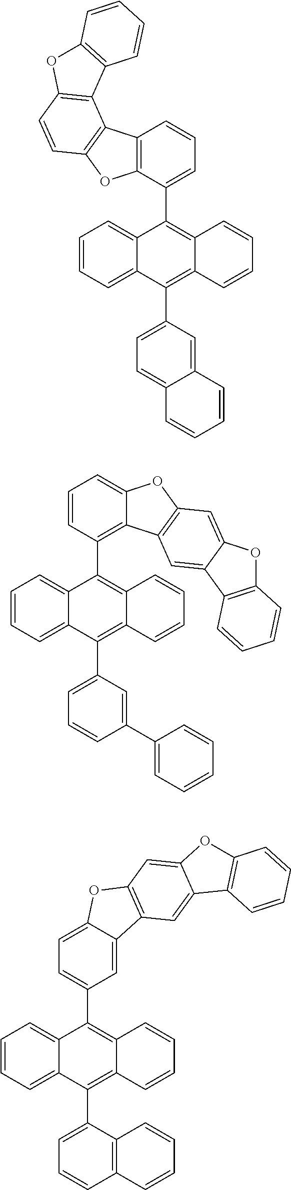 [SMILES: c1ccc2cc(-c3c4ccccc4c(-c4cccc5c4oc4ccc6oc7ccccc7c6c45)c4ccccc34)ccc2c1 ; c1ccc(-c2cccc(-c3c4ccccc4c(-c4cccc5oc6cc7oc8ccccc8c7cc6c45)c4ccccc34)c2)cc1 ; c1ccc2c(-c3c4ccccc4c(-c4ccc5oc6cc7oc8ccccc8c7cc6c5c4)c4ccccc34)cccc2c1]

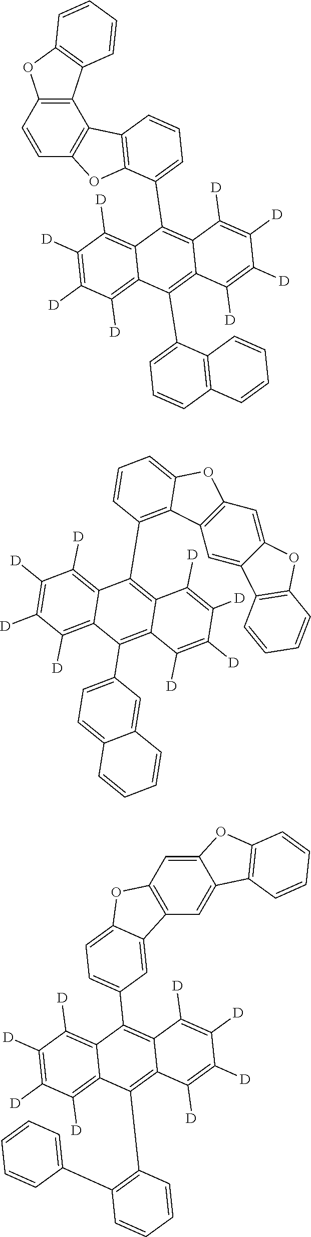 [SMILES: [2H]c1c([2H])c([2H])c2c(-c3cccc4c3oc3ccc5oc6ccccc6c5c34)c3c([2H])c([2H])c([2H])c([2H])c3c(-c3cccc4ccccc34)c2c1[2H] ; [2H]c1c([2H])c([2H])c2c(-c3cccc4oc5cc6oc7ccccc7c6cc5c34)c3c([2H])c([2H])c([2H])c([2H])c3c(-c3ccc4ccccc4c3)c2c1[2H] ; [2H]c1c([2H])c([2H])c2c(-c3ccccc3-c3ccccc3)c3c([2H])c([2H])c([2H])c([2H])c3c(-c3ccc4oc5cc6oc7ccccc7c6cc5c4c3)c2c1[2H]]

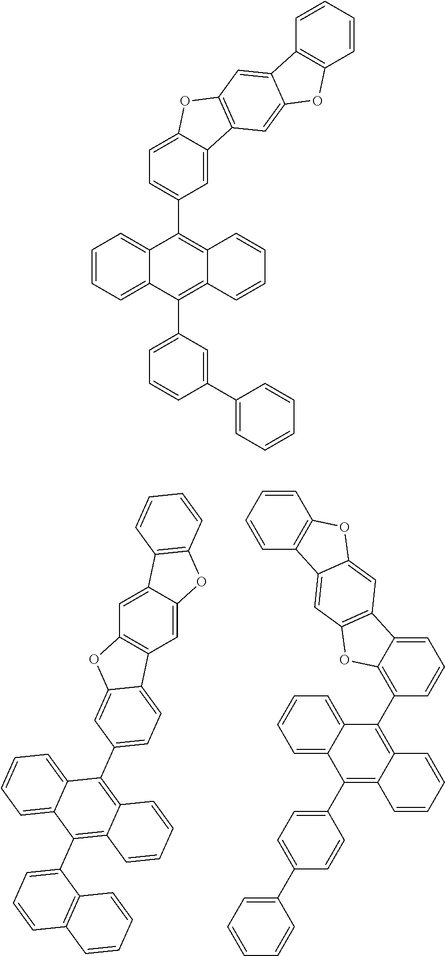

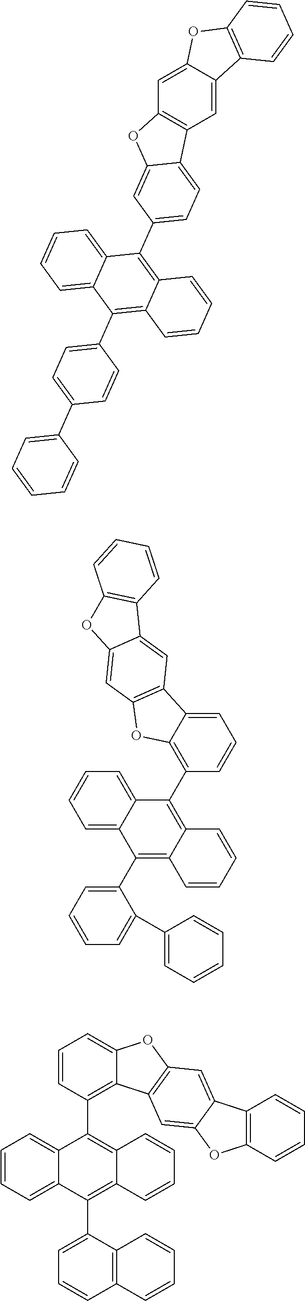 [SMILES: c1ccc(-c2ccc(-c3c4ccccc4c(-c4ccc5c(c4)oc4cc6oc7ccccc7c6cc45)c4ccccc34)cc2)cc1 ; c1ccc(-c2ccccc2-c2c3ccccc3c(-c3cccc4c3oc3cc5oc6ccccc6c5cc34)c3ccccc23)cc1 ; c1ccc2c(-c3c4ccccc4c(-c4cccc5oc6cc7c(cc6c45)oc4ccccc47)c4ccccc34)cccc2c1]

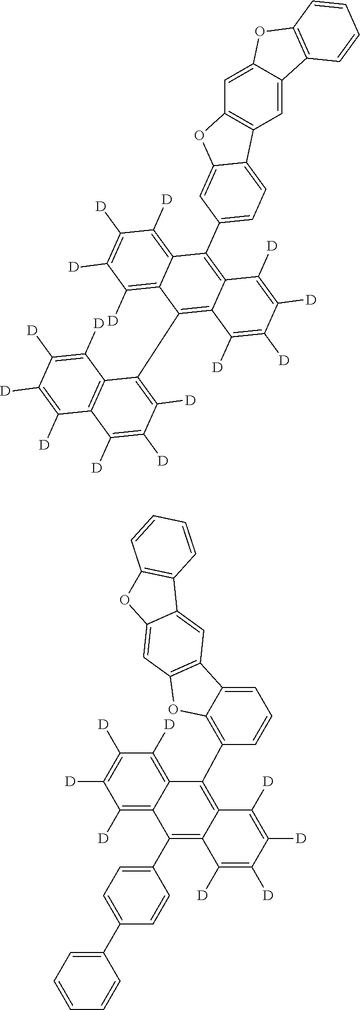 [SMILES: [2H]c1c([2H])c([2H])c2c(-c3c4c([2H])c([2H])c([2H])c([2H])c4c(-c4ccc5c(c4)oc4cc6oc7ccccc7c6cc45)c4c([2H])c([2H])c([2H])c([2H])c34)c([2H])c([2H])c([2H])c2c1[2H] ; [2H]c1c([2H])c([2H])c2c(-c3cccc4c3oc3cc5oc6ccccc6c5cc34)c3c([2H])c([2H])c([2H])c([2H])c3c(-c3ccc(-c4ccccc4)cc3)c2c1[2H]]

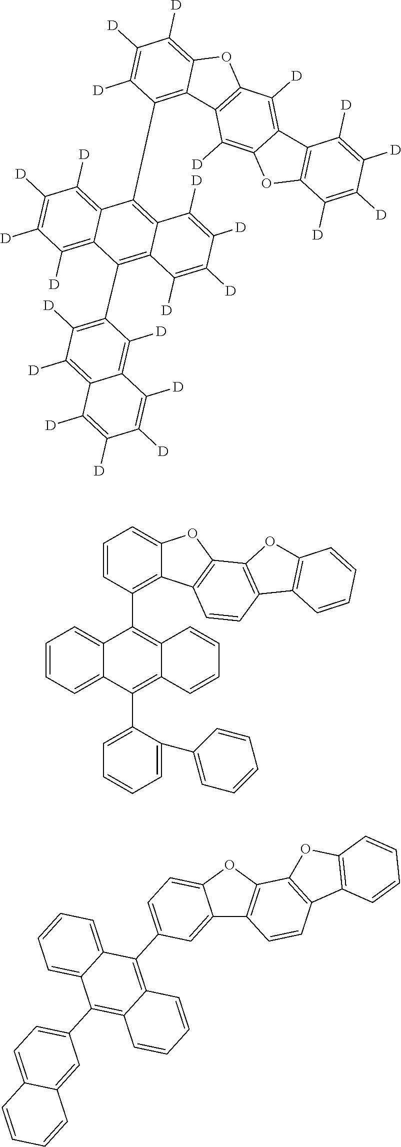 [SMILES: [2H]c1c([2H])c([2H])c2c(oc3c([2H])c4c(oc5c([2H])c([2H])c([2H])c(-c6c7c([2H])c([2H])c([2H])c([2H])c7c(-c7c([2H])c([2H])c8c([2H])c([2H])c([2H])c([2H])c8c7[2H])c7c([2H])c([2H])c([2H])c([2H])c67)c54)c([2H])c32)c1[2H] ; c1ccc(-c2ccccc2-c2c3ccccc3c(-c3cccc4oc5c(ccc6c7ccccc7oc65)c34)c3ccccc23)cc1 ; c1ccc2cc(-c3c4ccccc4c(-c4ccc5oc6c(ccc7c8ccccc8oc76)c5c4)c4ccccc34)ccc2c1]

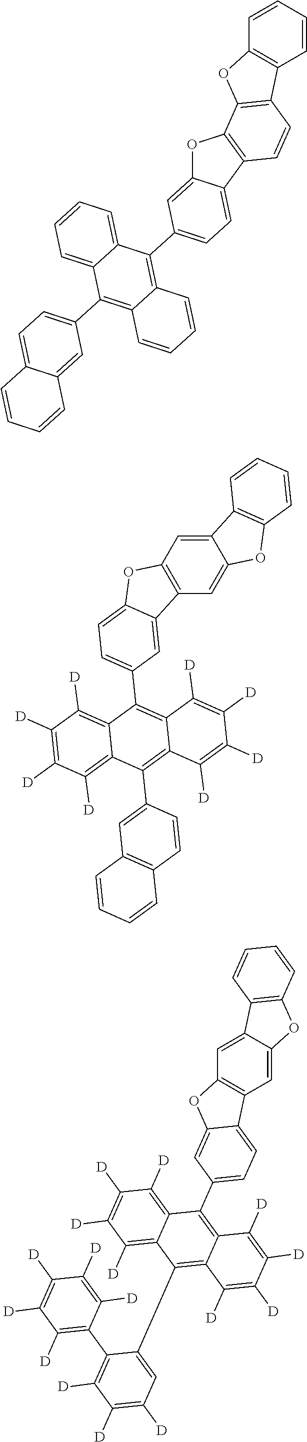 [SMILES: c1ccc2cc(-c3c4ccccc4c(-c4ccc5c(c4)oc4c5ccc5c6ccccc6oc54)c4ccccc34)ccc2c1 ; [2H]c1c([2H])c([2H])c2c(-c3ccc4oc5cc6c(cc5c4c3)oc3ccccc36)c3c([2H])c([2H])c([2H])c([2H])c3c(-c3ccc4ccccc4c3)c2c1[2H] ; [2H]c1cc(-c2c3c([2H])c([2H])c([2H])c([2H])c3c(-c3ccc4c(c3)oc3cc5c(cc34)oc3ccccc35)c3c([2H])c([2H])c([2H])c([2H])c23)c(-c2c([2H])c([2H])c([2H])c([2H])c2[2H])c([2H])c1[2H]]

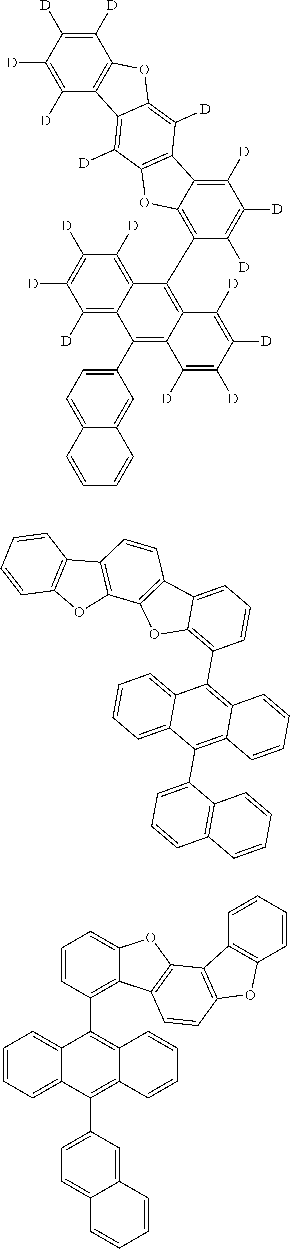

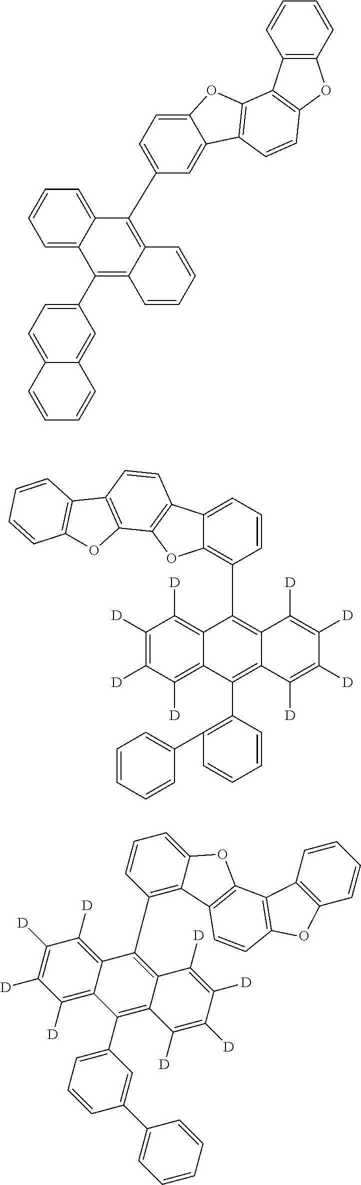

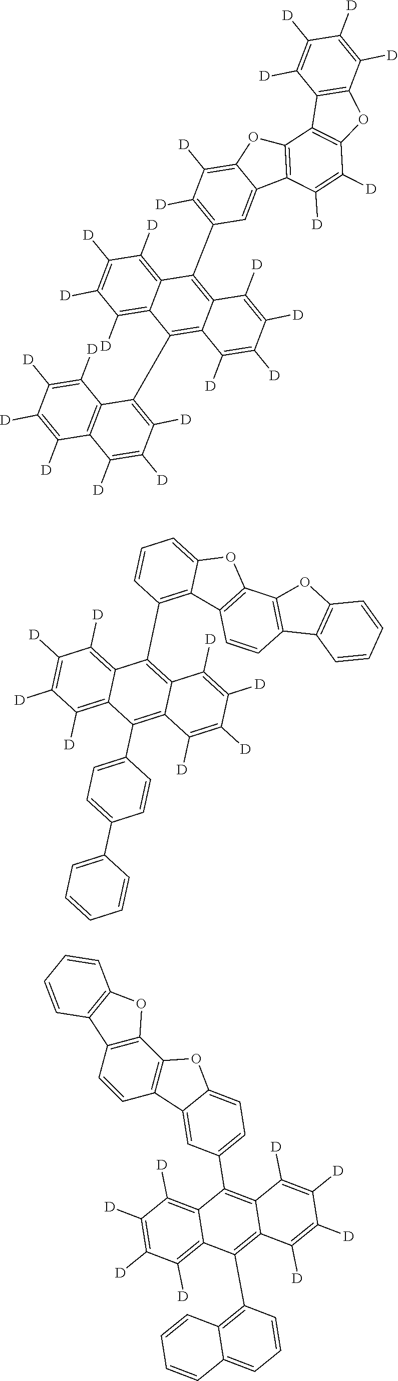

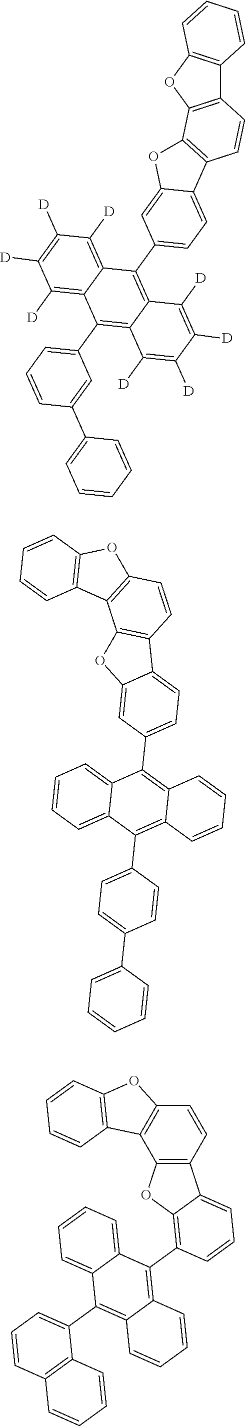 [SMILES: [2H]c1c([2H])c([2H])c2c(-c3ccc4c(c3)oc3c4ccc4c5ccccc5oc43)c3c([2H])c([2H])c([2H])c([2H])c3c(-c3cccc(-c4ccccc4)c3)c2c1[2H] ; c1ccc(-c2ccc(-c3c4ccccc4c(-c4ccc5c(c4)oc4c5ccc5oc6ccccc6c54)c4ccccc34)cc2)cc1 ; c1ccc2c(-c3c4ccccc4c(-c4cccc5c4oc4c5ccc5oc6ccccc6c54)c4ccccc34)cccc2c1]

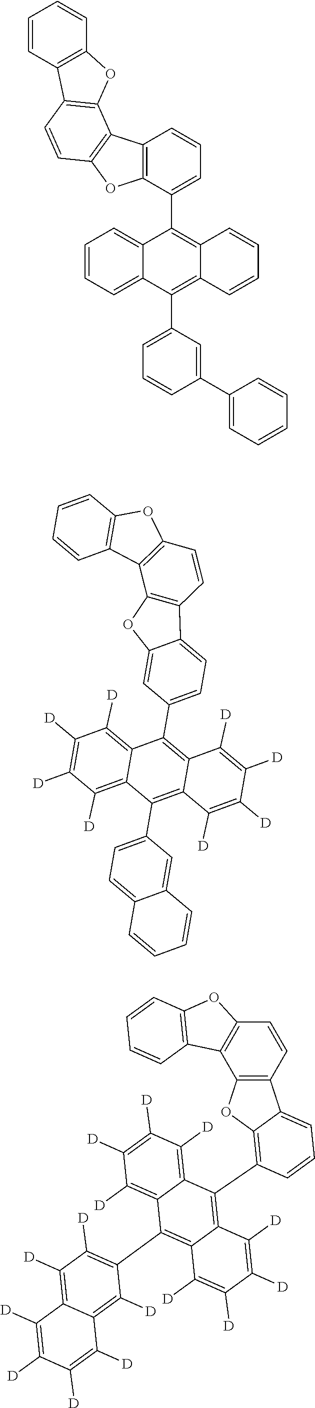

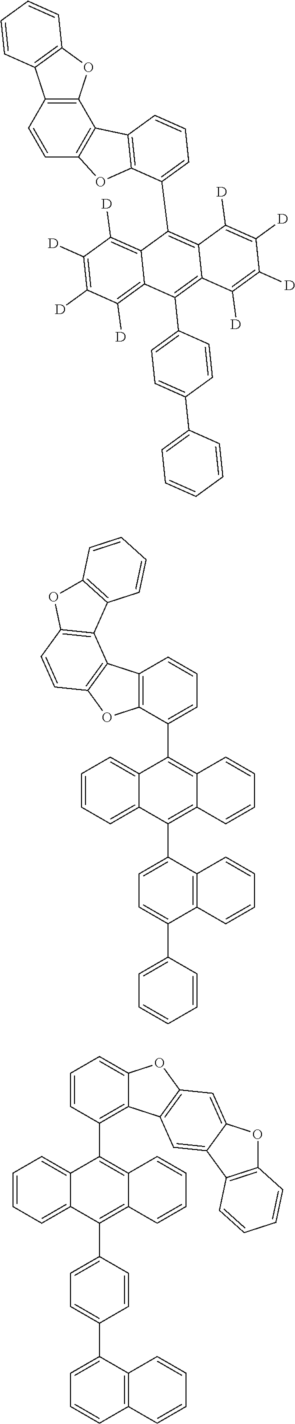

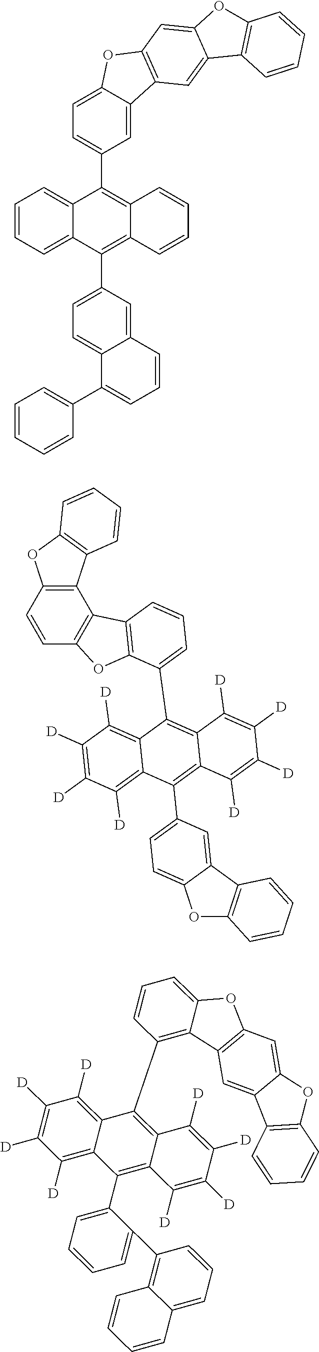 [SMILES: c1ccc(-c2cccc3cc(-c4c5ccccc5c(-c5ccc6oc7cc8oc9ccccc9c8cc7c6c5)c5ccccc45)ccc23)cc1 ; [2H]c1c([2H])c([2H])c2c(-c3cccc4c3oc3ccc5oc6ccccc6c5c34)c3c([2H])c([2H])c([2H])c([2H])c3c(-c3ccc4oc5ccccc5c4c3)c2c1[2H] ; [2H]c1c([2H])c([2H])c2c(-c3cccc4oc5cc6oc7ccccc7c6cc5c34)c3c([2H])c([2H])c([2H])c([2H])c3c(-c3ccccc3-c3cccc4ccccc34)c2c1[2H]]

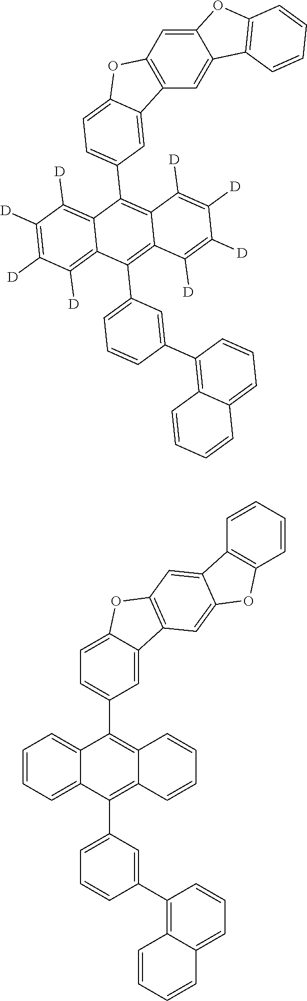 [SMILES: [2H]c1c([2H])c([2H])c2c(-c3ccc4oc5cc6oc7ccccc7c6cc5c4c3)c3c([2H])c([2H])c([2H])c([2H])c3c(-c3cccc(-c4cccc5ccccc45)c3)c2c1[2H] ; c1cc(-c2cccc3ccccc23)cc(-c2c3ccccc3c(-c3ccc4oc5cc6c(cc5c4c3)oc3ccccc36)c3ccccc23)c1]

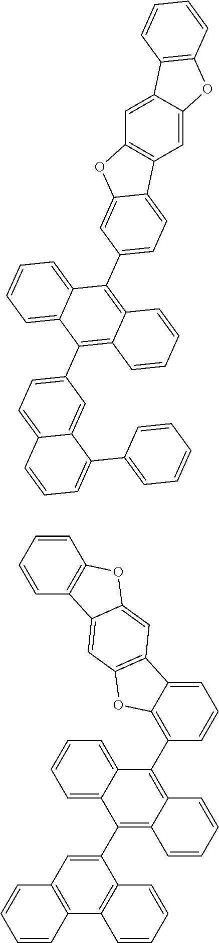

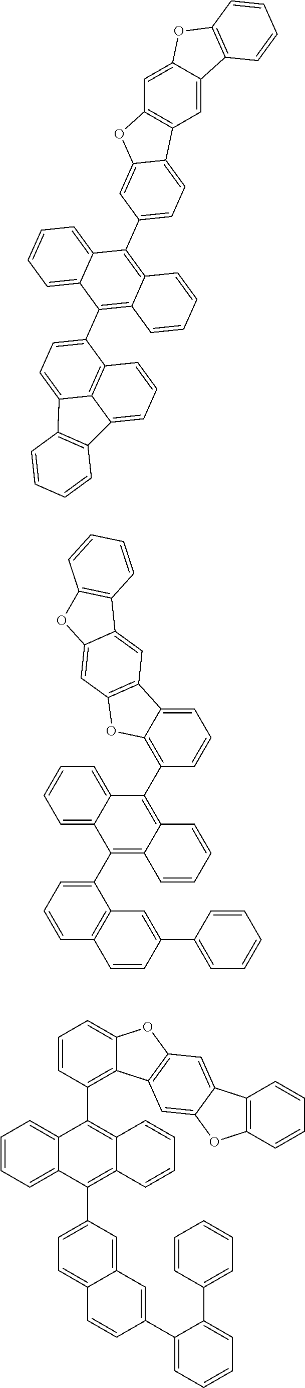

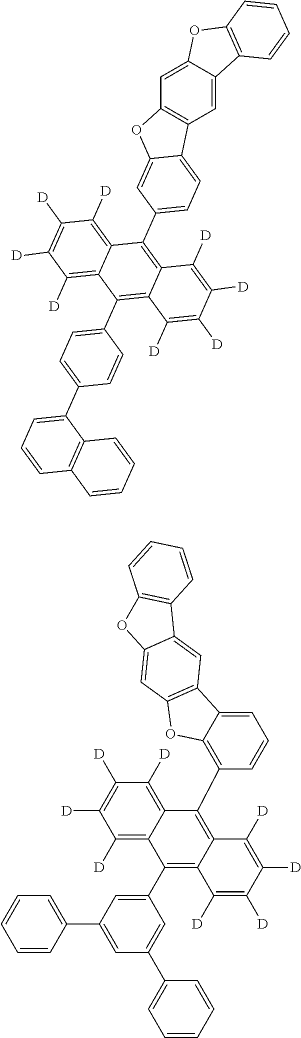 [SMILES: [2H]c1c([2H])c([2H])c2c(-c3ccc4c(c3)oc3cc5oc6ccccc6c5cc34)c3c([2H])c([2H])c([2H])c([2H])c3c(-c3ccc(-c4cccc5ccccc45)cc3)c2c1[2H] ; [2H]c1c([2H])c([2H])c2c(-c3cccc4c3oc3cc5oc6ccccc6c5cc34)c3c([2H])c([2H])c([2H])c([2H])c3c(-c3cc(-c4ccccc4)cc(-c4ccccc4)c3)c2c1[2H]]

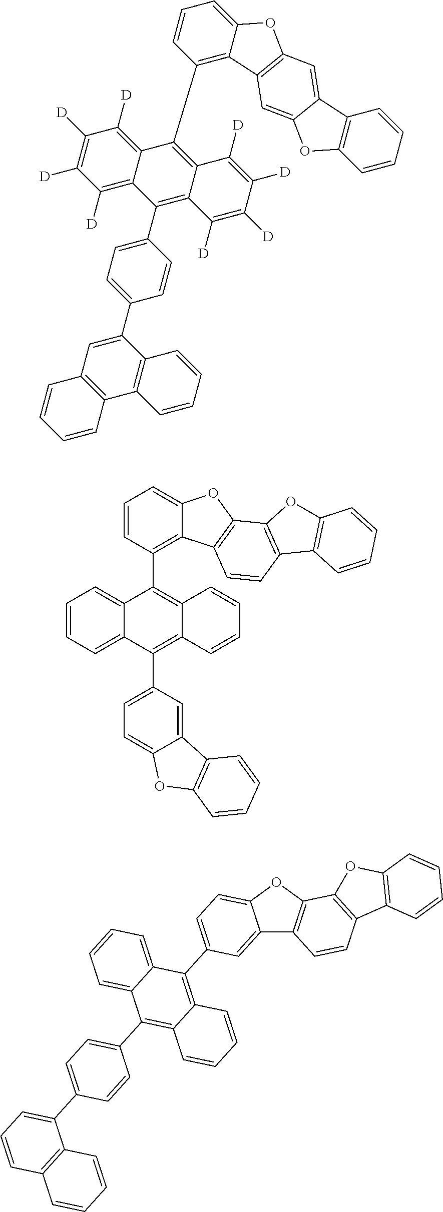 [SMILES: [2H]c1c([2H])c([2H])c2c(-c3cccc4oc5cc6c(cc5c34)oc3ccccc36)c3c([2H])c([2H])c([2H])c([2H])c3c(-c3ccc(-c4cc5ccccc5c5ccccc45)cc3)c2c1[2H] ; c1ccc2c(c1)oc1ccc(-c3c4ccccc4c(-c4cccc5oc6c(ccc7c8ccccc8oc76)c45)c4ccccc34)cc12 ; c1ccc2c(-c3ccc(-c4c5ccccc5c(-c5ccc6oc7c(ccc8c9ccccc9oc87)c6c5)c5ccccc45)cc3)cccc2c1]

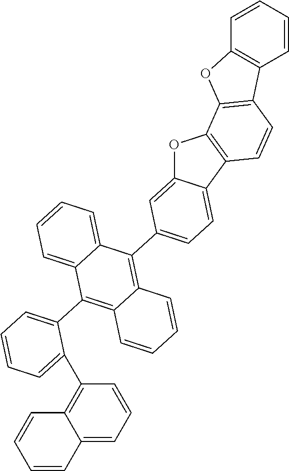 [SMILES: c1ccc(-c2c3ccccc3c(-c3ccc4c(c3)oc3c4ccc4c5ccccc5oc43)c3ccccc23)c(-c2cccc3ccccc23)c1]

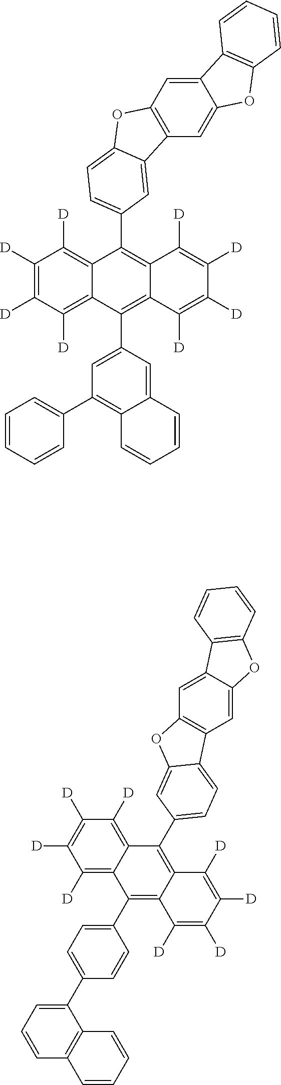 [SMILES: [2H]c1c([2H])c([2H])c2c(-c3ccc4oc5cc6c(cc5c4c3)oc3ccccc36)c3c([2H])c([2H])c([2H])c([2H])c3c(-c3cc(-c4ccccc4)c4ccccc4c3)c2c1[2H] ; [2H]c1c([2H])c([2H])c2c(-c3ccc4c(c3)oc3cc5c(cc34)oc3ccccc35)c3c([2H])c([2H])c([2H])c([2H])c3c(-c3ccc(-c4cccc5ccccc45)cc3)c2c1[2H]]

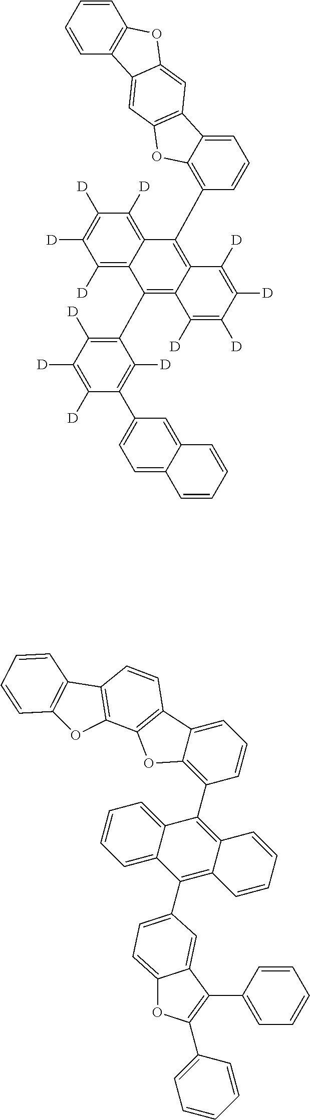 [SMILES: [2H]c1c([2H])c(-c2ccc3ccccc3c2)c([2H])c(-c2c3c([2H])c([2H])c([2H])c([2H])c3c(-c3cccc4c3oc3cc5c(cc34)oc3ccccc35)c3c([2H])c([2H])c([2H])c([2H])c23)c1[2H] ; c1ccc(-c2oc3ccc(-c4c5ccccc5c(-c5cccc6c5oc5c6ccc6c7ccccc7oc65)c5ccccc45)cc3c2-c2ccccc2)cc1]

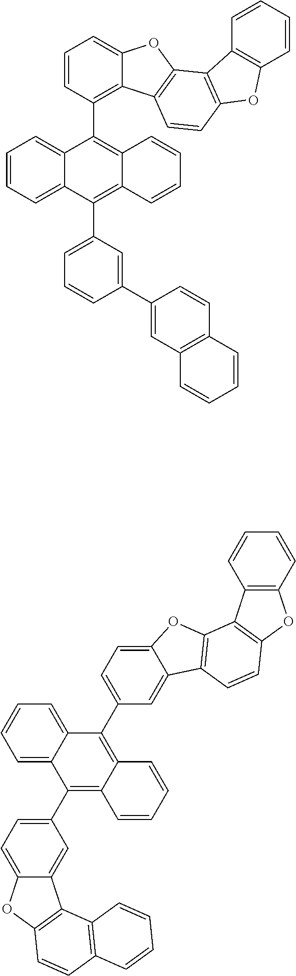 [SMILES: c1cc(-c2ccc3ccccc3c2)cc(-c2c3ccccc3c(-c3cccc4oc5c(ccc6oc7ccccc7c65)c34)c3ccccc23)c1 ; c1ccc2c(c1)ccc1oc3ccc(-c4c5ccccc5c(-c5ccc6oc7c(ccc8oc9ccccc9c87)c6c5)c5ccccc45)cc3c12]

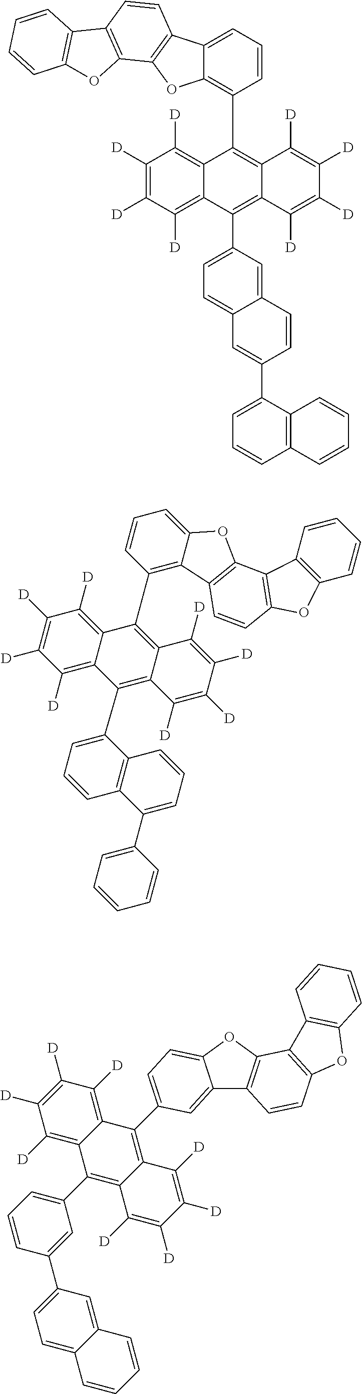 [SMILES: [2H]c1c([2H])c([2H])c2c(-c3cccc4c3oc3c4ccc4c5ccccc5oc43)c3c([2H])c([2H])c([2H])c([2H])c3c(-c3ccc4cc(-c5cccc6ccccc56)ccc4c3)c2c1[2H] ; [2H]c1c([2H])c([2H])c2c(-c3cccc4oc5c(ccc6oc7ccccc7c65)c34)c3c([2H])c([2H])c([2H])c([2H])c3c(-c3cccc4c(-c5ccccc5)cccc34)c2c1[2H] ; [2H]c1c([2H])c([2H])c2c(-c3ccc4oc5c(ccc6oc7ccccc7c65)c4c3)c3c([2H])c([2H])c([2H])c([2H])c3c(-c3cccc(-c4ccc5ccccc5c4)c3)c2c1[2H]]

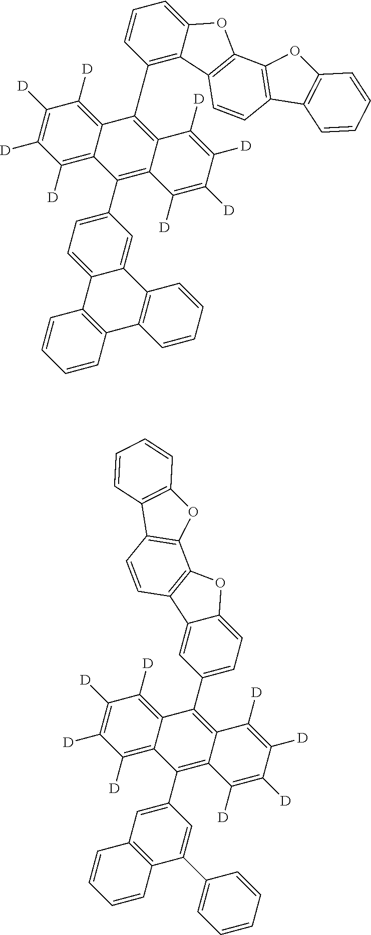 [SMILES: [2H]c1c([2H])c([2H])c2c(-c3cccc4oc5c(ccc6c7ccccc7oc65)c34)c3c([2H])c([2H])c([2H])c([2H])c3c(-c3ccc4c5ccccc5c5ccccc5c4c3)c2c1[2H] ; [2H]c1c([2H])c([2H])c2c(-c3ccc4oc5c(ccc6c7ccccc7oc65)c4c3)c3c([2H])c([2H])c([2H])c([2H])c3c(-c3cc(-c4ccccc4)c4ccccc4c3)c2c1[2H]]

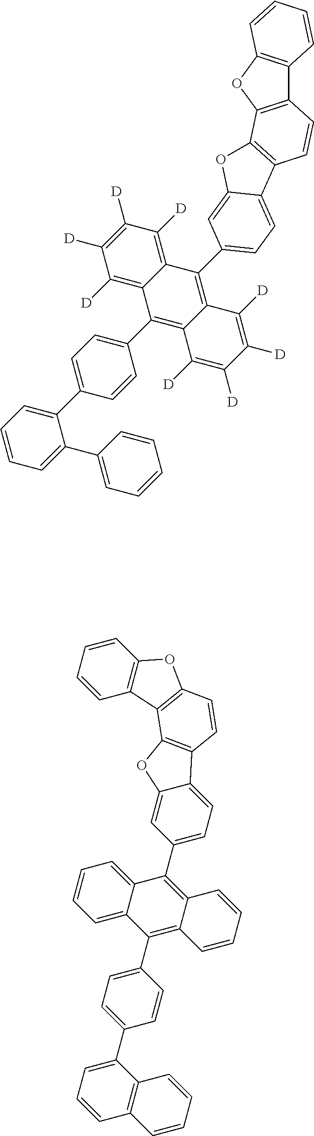 [SMILES: [2H]c1c([2H])c([2H])c2c(-c3ccc4c(c3)oc3c4ccc4c5ccccc5oc43)c3c([2H])c([2H])c([2H])c([2H])c3c(-c3ccc(-c4ccccc4-c4ccccc4)cc3)c2c1[2H] ; c1ccc2c(-c3ccc(-c4c5ccccc5c(-c5ccc6c(c5)oc5c6ccc6oc7ccccc7c65)c5ccccc45)cc3)cccc2c1]

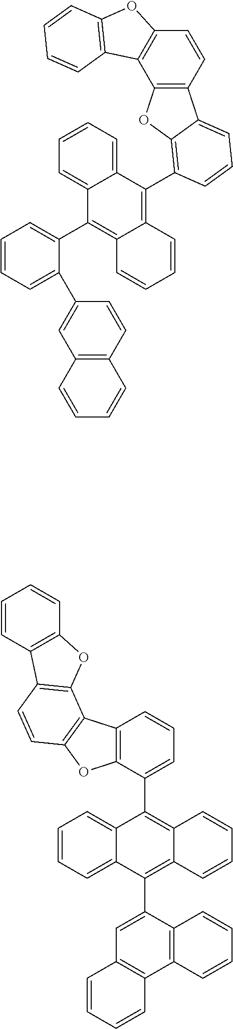 [SMILES: c1ccc(-c2c3ccccc3c(-c3cccc4c3oc3c4ccc4oc5ccccc5c43)c3ccccc23)c(-c2ccc3ccccc3c2)c1 ; c1ccc2c(c1)cc(-c1c3ccccc3c(-c3cccc4c3oc3ccc5c6ccccc6oc5c34)c3ccccc13)c1ccccc12]

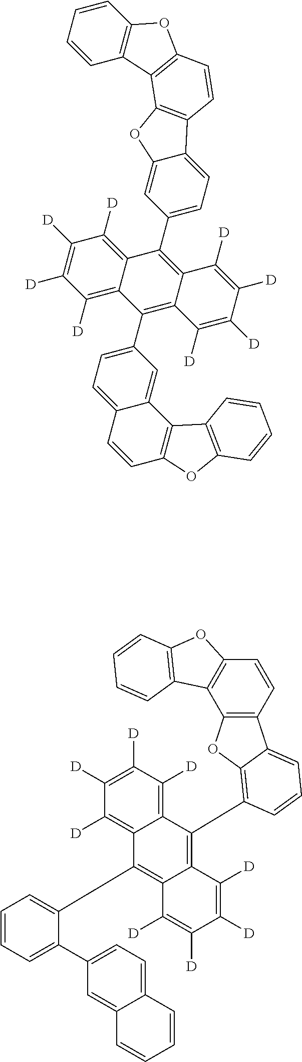 [SMILES: [2H]c1c([2H])c([2H])c2c(-c3ccc4ccc5oc6ccccc6c5c4c3)c3c([2H])c([2H])c([2H])c([2H])c3c(-c3ccc4c(c3)oc3c4ccc4oc5ccccc5c43)c2c1[2H] ; [2H]c1c([2H])c([2H])c2c(-c3cccc4c3oc3c4ccc4oc5ccccc5c43)c3c([2H])c([2H])c([2H])c([2H])c3c(-c3ccccc3-c3ccc4ccccc4c3)c2c1[2H]]

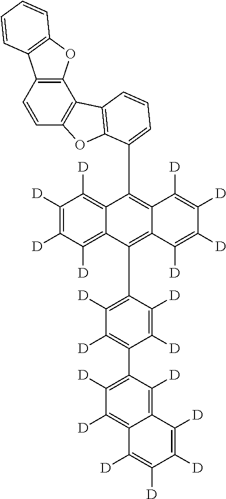 [SMILES: [2H]c1c([2H])c(-c2c3c([2H])c([2H])c([2H])c([2H])c3c(-c3cccc4c3oc3ccc5c6ccccc6oc5c34)c3c([2H])c([2H])c([2H])c([2H])c23)c([2H])c([2H])c1-c1c([2H])c([2H])c2c([2H])c([2H])c([2H])c([2H])c2c1[2H]]

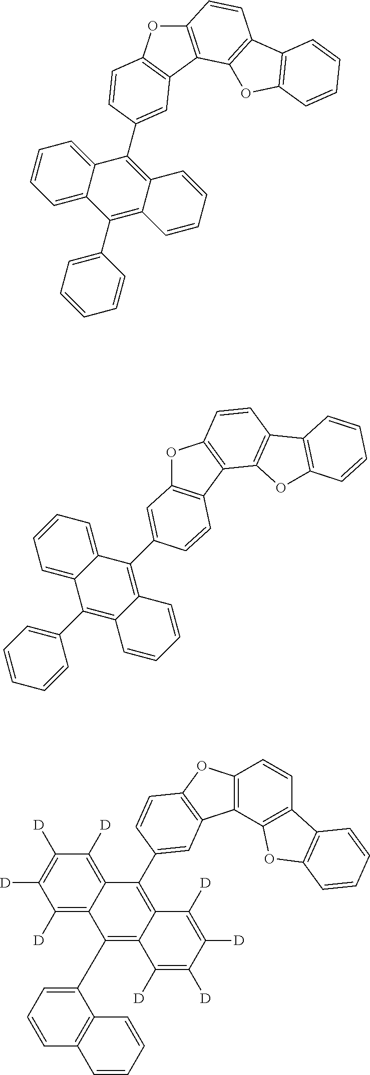 [SMILES: c1ccc(-c2c3ccccc3c(-c3ccc4oc5ccc6c7ccccc7oc6c5c4c3)c3ccccc23)cc1 ; c1ccc(-c2c3ccccc3c(-c3ccc4c(c3)oc3ccc5c6ccccc6oc5c34)c3ccccc23)cc1 ; [2H]c1c([2H])c([2H])c2c(-c3cccc4ccccc34)c3c([2H])c([2H])c([2H])c([2H])c3c(-c3ccc4oc5ccc6c7ccccc7oc6c5c4c3)c2c1[2H]]

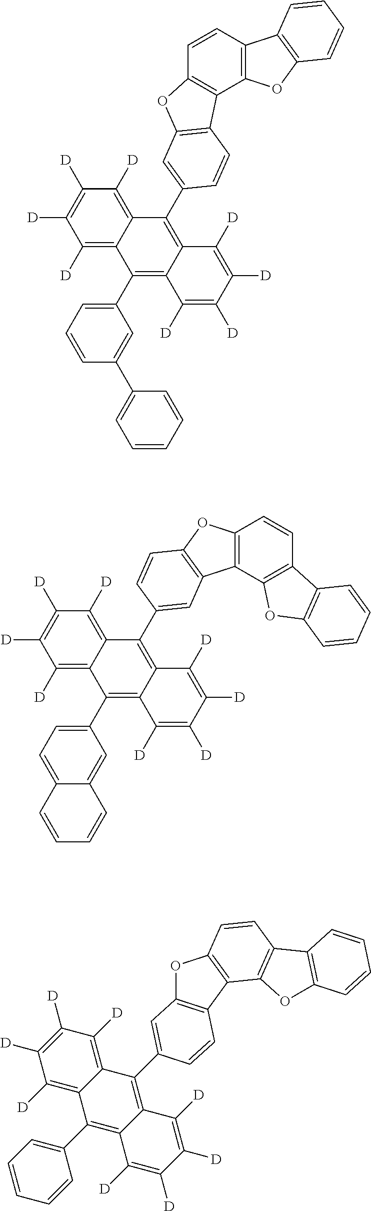 [SMILES: [2H]c1c([2H])c([2H])c2c(-c3ccc4c(c3)oc3ccc5c6ccccc6oc5c34)c3c([2H])c([2H])c([2H])c([2H])c3c(-c3cccc(-c4ccccc4)c3)c2c1[2H] ; [2H]c1c([2H])c([2H])c2c(-c3ccc4oc5ccc6c7ccccc7oc6c5c4c3)c3c([2H])c([2H])c([2H])c([2H])c3c(-c3ccc4ccccc4c3)c2c1[2H] ; [2H]c1c([2H])c([2H])c2c(-c3ccc4c(c3)oc3ccc5c6ccccc6oc5c34)c3c([2H])c([2H])c([2H])c([2H])c3c(-c3ccccc3)c2c1[2H]]

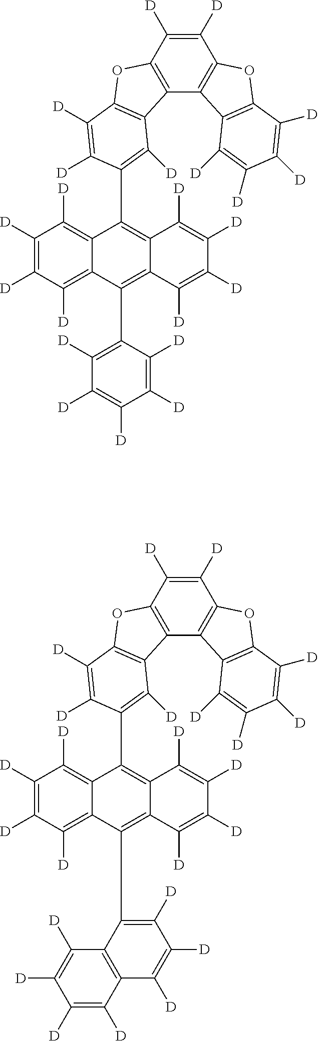 [SMILES: [2H]c1c([2H])c([2H])c(-c2c3c([2H])c([2H])c([2H])c([2H])c3c(-c3c([2H])c([2H])c4oc5c([2H])c([2H])c6oc7c([2H])c([2H])c([2H])c([2H])c7c6c5c4c3[2H])c3c([2H])c([2H])c([2H])c([2H])c23)c([2H])c1[2H] ; [2H]c1c([2H])c([2H])c2c(oc3c([2H])c([2H])c4oc5c([2H])c([2H])c(-c6c7c([2H])c([2H])c([2H])c([2H])c7c(-c7c([2H])c([2H])c([2H])c8c([2H])c([2H])c([2H])c([2H])c78)c7c([2H])c([2H])c([2H])c([2H])c67)c([2H])c5c4c32)c1[2H]]

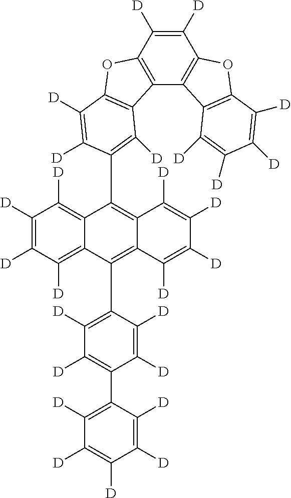 [SMILES: [2H]c1c([2H])c([2H])c(-c2c([2H])c([2H])c(-c3c4c([2H])c([2H])c([2H])c([2H])c4c(-c4c([2H])c([2H])c5oc6c([2H])c([2H])c7oc8c([2H])c([2H])c([2H])c([2H])c8c7c6c5c4[2H])c4c([2H])c([2H])c([2H])c([2H])c34)c([2H])c2[2H])c([2H])c1[2H]]

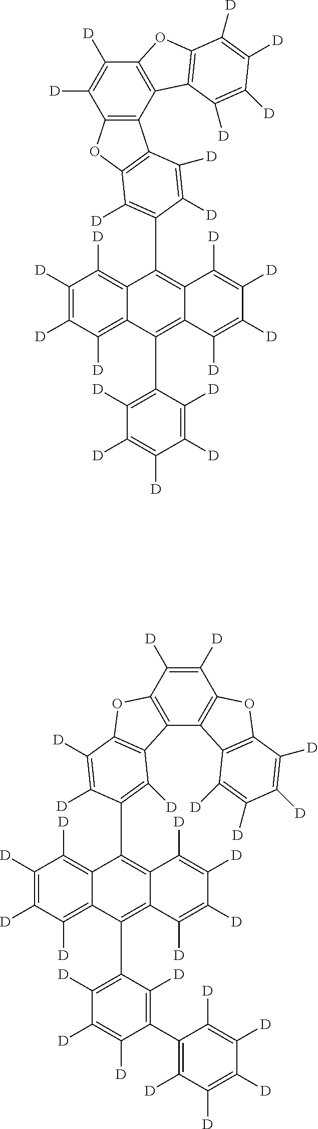 [SMILES: [2H]c1c([2H])c([2H])c(-c2c3c([2H])c([2H])c([2H])c([2H])c3c(-c3c([2H])c([2H])c4c(oc5c([2H])c([2H])c6oc7c([2H])c([2H])c([2H])c([2H])c7c6c54)c3[2H])c3c([2H])c([2H])c([2H])c([2H])c23)c([2H])c1[2H] ; [2H]c1c([2H])c([2H])c(-c2c([2H])c([2H])c([2H])c(-c3c4c([2H])c([2H])c([2H])c([2H])c4c(-c4c([2H])c([2H])c5oc6c([2H])c([2H])c7oc8c([2H])c([2H])c([2H])c([2H])c8c7c6c5c4[2H])c4c([2H])c([2H])c([2H])c([2H])c34)c2[2H])c([2H])c1[2H]]

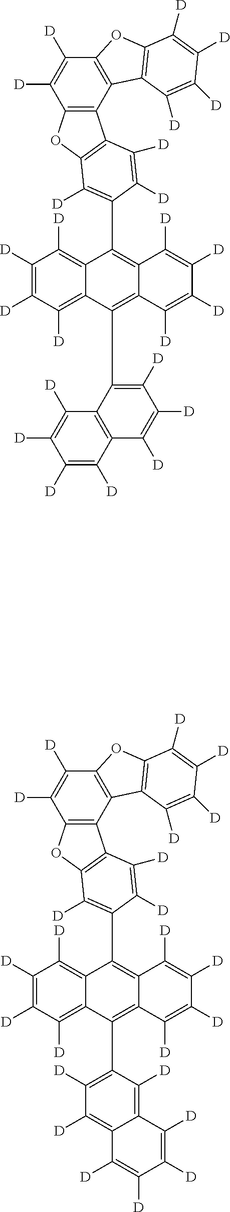 [SMILES: [2H]c1c([2H])c([2H])c2c(oc3c([2H])c([2H])c4oc5c([2H])c(-c6c7c([2H])c([2H])c([2H])c([2H])c7c(-c7c([2H])c([2H])c([2H])c8c([2H])c([2H])c([2H])c([2H])c78)c7c([2H])c([2H])c([2H])c([2H])c67)c([2H])c([2H])c5c4c32)c1[2H] ; [2H]c1c([2H])c([2H])c2c(oc3c([2H])c([2H])c4oc5c([2H])c(-c6c7c([2H])c([2H])c([2H])c([2H])c7c(-c7c([2H])c([2H])c8c([2H])c([2H])c([2H])c([2H])c8c7[2H])c7c([2H])c([2H])c([2H])c([2H])c67)c([2H])c([2H])c5c4c32)c1[2H]]

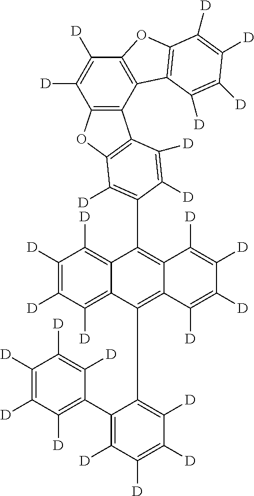 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c4c(oc5c([2H])c([2H])c6oc7c([2H])c([2H])c([2H])c([2H])c7c6c54)c3[2H])c3c([2H])c([2H])c([2H])c([2H])c23)c([2H])c1[2H]]

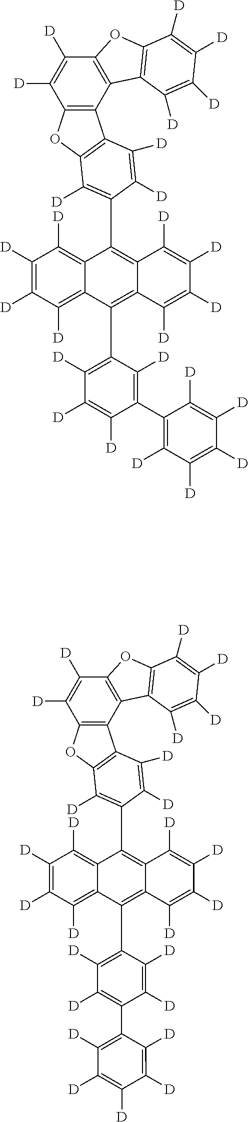 [SMILES: [2H]c1c([2H])c([2H])c(-c2c([2H])c([2H])c([2H])c(-c3c4c([2H])c([2H])c([2H])c([2H])c4c(-c4c([2H])c([2H])c5c(oc6c([2H])c([2H])c7oc8c([2H])c([2H])c([2H])c([2H])c8c7c65)c4[2H])c4c([2H])c([2H])c([2H])c([2H])c34)c2[2H])c([2H])c1[2H] ; [2H]c1c([2H])c([2H])c(-c2c([2H])c([2H])c(-c3c4c([2H])c([2H])c([2H])c([2H])c4c(-c4c([2H])c([2H])c5c(oc6c([2H])c([2H])c7oc8c([2H])c([2H])c([2H])c([2H])c8c7c65)c4[2H])c4c([2H])c([2H])c([2H])c([2H])c34)c([2H])c2[2H])c([2H])c1[2H]]

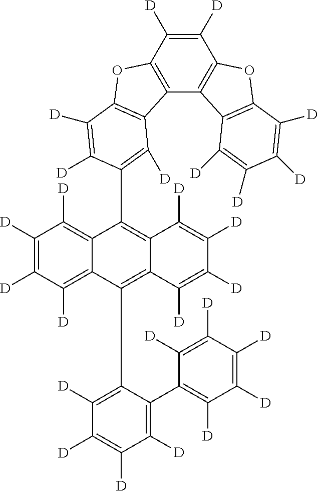 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c4oc5c([2H])c([2H])c6oc7c([2H])c([2H])c([2H])c([2H])c7c6c5c4c3[2H])c3c([2H])c([2H])c([2H])c([2H])c23)c([2H])c1[2H]]

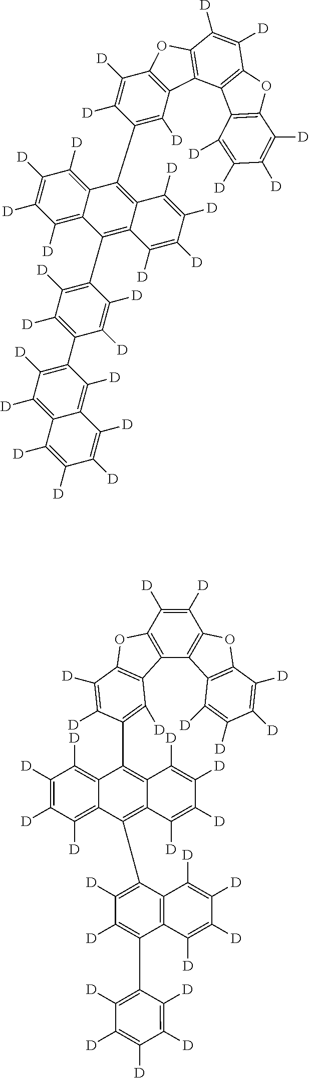 [SMILES: [2H]c1c([2H])c(-c2c3c([2H])c([2H])c([2H])c([2H])c3c(-c3c([2H])c([2H])c4oc5c([2H])c([2H])c6oc7c([2H])c([2H])c([2H])c([2H])c7c6c5c4c3[2H])c3c([2H])c([2H])c([2H])c([2H])c23)c([2H])c([2H])c1-c1c([2H])c([2H])c2c([2H])c([2H])c([2H])c([2H])c2c1[2H] ; [2H]c1c([2H])c([2H])c(-c2c([2H])c([2H])c(-c3c4c([2H])c([2H])c([2H])c([2H])c4c(-c4c([2H])c([2H])c5oc6c([2H])c([2H])c7oc8c([2H])c([2H])c([2H])c([2H])c8c7c6c5c4[2H])c4c([2H])c([2H])c([2H])c([2H])c34)c3c([2H])c([2H])c([2H])c([2H])c23)c([2H])c1[2H]]

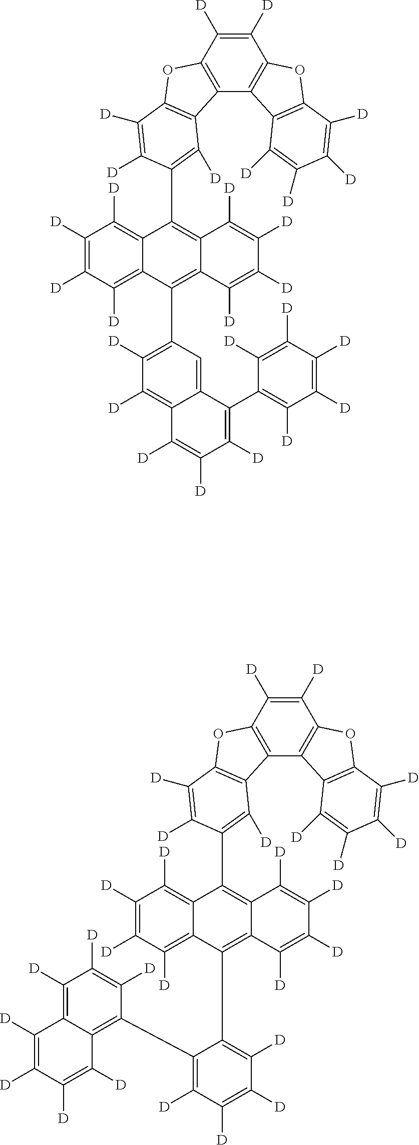 [SMILES: [2H]c1c([2H])c([2H])c(-c2c([2H])c([2H])c([2H])c3c([2H])c([2H])c(-c4c5c([2H])c([2H])c([2H])c([2H])c5c(-c5c([2H])c([2H])c6oc7c([2H])c([2H])c8oc9c([2H])c([2H])c([2H])c([2H])c9c8c7c6c5[2H])c5c([2H])c([2H])c([2H])c([2H])c45)cc23)c([2H])c1[2H] ; [2H]c1c([2H])c([2H])c(-c2c3c([2H])c([2H])c([2H])c([2H])c3c(-c3c([2H])c([2H])c4oc5c([2H])c([2H])c6oc7c([2H])c([2H])c([2H])c([2H])c7c6c5c4c3[2H])c3c([2H])c([2H])c([2H])c([2H])c23)c(-c2c([2H])c([2H])c([2H])c3c([2H])c([2H])c([2H])c([2H])c23)c1[2H]]

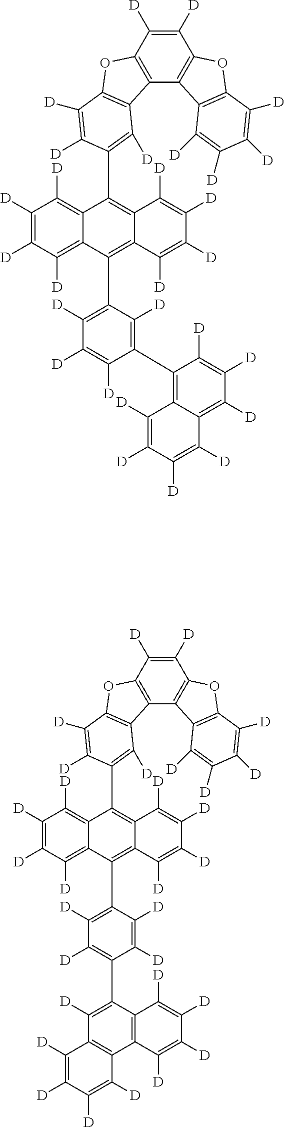

Hereinafter, Chemical Formula 2 will be described in detail.

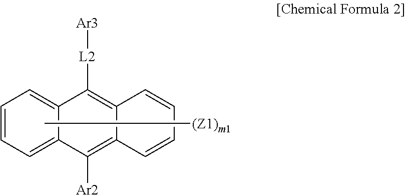

In Chemical Formula 2,
L2 is a direct bond or a substituted or unsubstituted arylene group,
Ar2 is a substituted or unsubstituted aryl group or a substituted or unsubstituted heteroaryl group,
Z1 is hydrogen, deuterium, a substituted or unsubstituted cycloalkyl group, a substituted or unsubstituted aryl group, or a substituted or unsubstituted heteroaryl group,
m1 is an integer from 0 to 8, and when m1 is 2 or higher, two or more Z1s are the same as or different from each other, and
Ar3 is the following Chemical Formula A, and Z10 or Z11 of the following Chemical Formula A is linked to L2 of Chemical Formula 2:

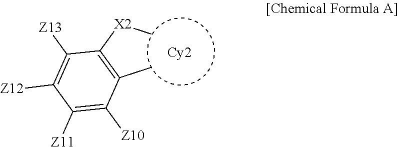

in Chemical Formula A,
X2 is O or S,
Cy2 is a substituted or unsubstituted benzene or a substituted or unsubstituted naphthalene, and
of Z10 and Z11, a group which is not linked to L2 in Chemical Formula 2, Z12, and Z13 are the same as or different from each other, and are each independently hydrogen, deuterium, a substituted or unsubstituted aryl group, or a substituted or unsubstituted heteroaryl group.

According to an exemplary embodiment of the present specification, Ar3 is Chemical Formula A, and Z10 or Z11 of Chemical Formula A is linked to L2 of Chemical Formula 2.

According to an exemplary embodiment of the present specification, X2 is O or S.

According to an exemplary embodiment of the present specification, Chemical Formula 2 is the following Chemical Formula 2-1 or 2-2.

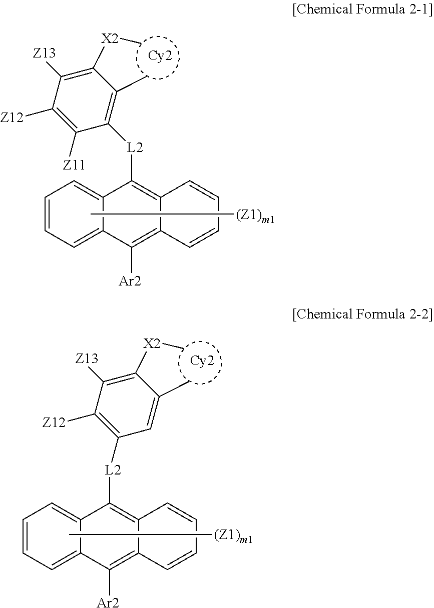

In Chemical Formulae 2-1 and 2-2,
the definitions of Z1, m1, L2, and Ar2 are the same as the definitions in Chemical Formula 2, and the definitions of X2, Z10 to Z13, and Cy2 are the same as the definitions in Chemical Formula A.

In an exemplary embodiment of the present specification, Chemical Formula 2 is any one of the following Chemical Formulae 2-1-1 to 2-1-4.

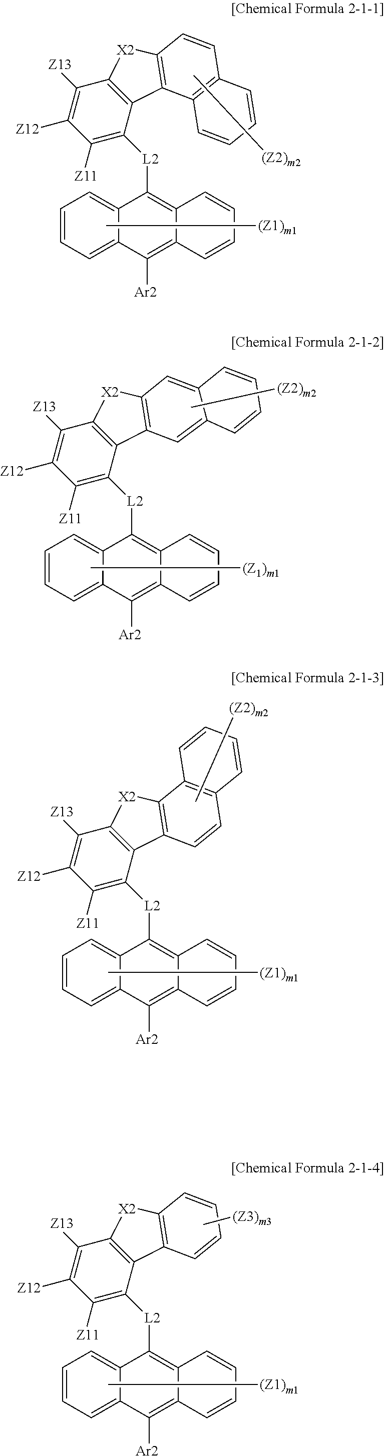

In Chemical Formulae 2-1-1 to 2-1-4,
the definitions of Z1, m1, L2, and Ar2 are the same as the definitions in Chemical Formula 2, and the definitions of X2 and Z10 to Z13 are the same as the definitions in Chemical Formula A,
Z2 and Z3 are the same as or different from each other, and are each independently hydrogen, deuterium, a substituted or unsubstituted alkyl group, a substituted or unsubstituted cycloalkyl group, a substituted or unsubstituted aryl group, or a substituted or unsubstituted heteroaryl group,
m2 is an integer from 0 to 6, and when m2 is 2 or higher, two or more Z2s are the same as or different from each other, and
m3 is an integer from 0 to 4, and when m3 is 2 or higher, two or more Z3s are the same as or different from each other.

In an exemplary embodiment of the present specification, Chemical Formula 2 is any one of the following Chemical Formulae 2-2-1 to 2-2-4.

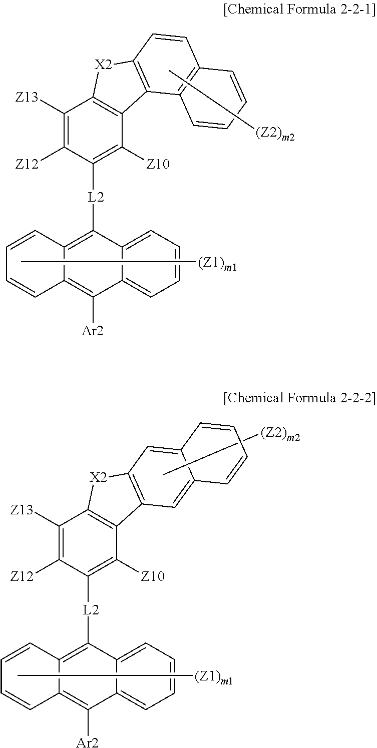

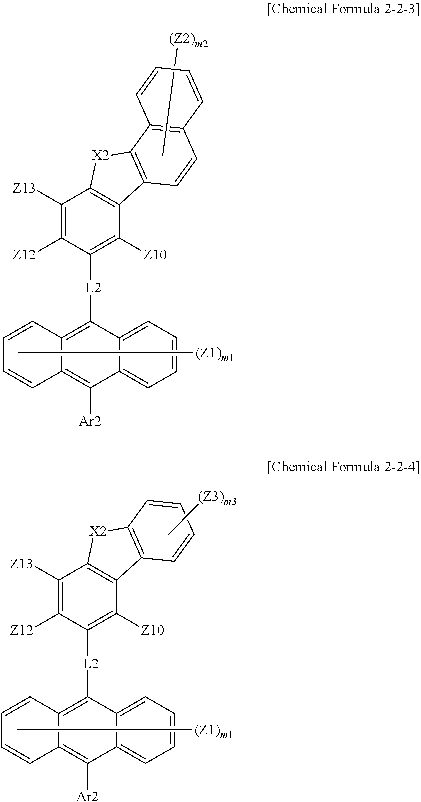

In Chemical Formulae 2-2-1 to 2-2-4,
the definitions of Z1, m1, L2, and Ar2 are the same as the definitions in Chemical Formula 2, and the definitions of X2, Z10, Z12, and Z13 are the same as the definitions in Chemical Formula A,
Z2 and Z3 are the same as or different from each other, and are each independently hydrogen, deuterium, a substituted or unsubstituted alkyl group, a substituted or unsubstituted cycloalkyl group, a substituted or unsubstituted aryl group, or a substituted or unsubstituted heteroaryl group,
m2 is an integer from 0 to 6, and when m2 is 2 or higher, two or more Z2s are the same as or different from each other, and
m3 is an integer from 0 to 4, and when m3 is 2 or higher, two or more Z3s are the same as or different from each other.

According to an exemplary embodiment of the present specification, L2 is a direct bond or a substituted or unsubstituted arylene group having 6 to 60 carbon atoms.

According to another exemplary embodiment, L2 is a direct bond or a substituted or unsubstituted arylene group having 6 to 30 carbon atoms.

According to still another exemplary embodiment, L2 is a direct bond, a substituted or unsubstituted phenylene group, a substituted or unsubstituted biphenylylene group, or a substituted or unsubstituted naphthylene group.

According to yet another embodiment, L2 is a direct bond; a phenylene group that is unsubstituted or substituted with deuterium; a biphenylylene group that is unsubstituted or substituted with deuterium; or a naphthylene group that is unsubstituted or substituted with deuterium.

In an exemplary embodiment of the present specification, Ar2 is a substituted or unsubstituted aryl group having 6 to 60 carbon atoms, or a substituted or unsubstituted heteroaryl group having 2 to 60 carbon atoms.

According to still yet another exemplary embodiment, Ar2 is a substituted or unsubstituted aryl group having 6 to 30 carbon atoms, or a substituted or unsubstituted heteroaryl group having 2 to 30 carbon atoms.

According to a further exemplary embodiment, Ar2 is an aryl group having 6 to 30 carbon atoms, which is unsubstituted or substituted with one or more selected from the group consisting of deuterium and an aryl group; or a heteroaryl group having 2 to 30 carbon atoms, which is unsubstituted or substituted with one or more selected from the group consisting of deuterium and an aryl group.

According to another further exemplary embodiment, Ar2 is a substituted or unsubstituted aryl group having 6 to 60 carbon atoms.

According to still another further exemplary embodiment, Ar2 is an aryl group having 6 to 60 carbon atoms, which is unsubstituted or substituted with one or more selected from the group consisting of deuterium and an aryl group.

According to yet another further exemplary embodiment, Ar2 is an aryl group having 6 to 60 carbon atoms, which is unsubstituted or substituted with one or more selected from the group consisting of deuterium and an aryl group having 6 to 30 carbon atoms.

In another exemplary embodiment, Ar2 is a substituted or unsubstituted phenyl group, a substituted or unsubstituted naphthyl group, a substituted or unsubstituted biphenyl group, a substituted or unsubstituted terphenyl group, a substituted or unsubstituted fluorenyl group, a substituted or unsubstituted triphenylene group, a substituted or unsubstituted phenanthrene group, a substituted or unsubstituted pyrene group, a substituted or unsubstituted dibenzofuran group, a substituted or unsubstituted benzofuran group, a substituted or unsubstituted benzothiophene group, a substituted or unsubstituted dibenzothiophene group, a substituted or unsubstituted fluoranthene group, a substituted or unsubstituted benzophenanthrene group, a substituted or unsubstituted tetrahydronaphthalene, a substituted or unsubstituted carbazole group, or a combination thereof. In this case, the substituents may be unsubstituted or substituted with deuterium.

According to an exemplary embodiment of the present specification, Z1 is hydrogen, deuterium, a substituted or unsubstituted cycloalkyl group having 3 to 30 carbon atoms, a substituted or unsubstituted aryl group having 6 to 60 carbon atoms, or a substituted or unsubstituted heteroaryl group having 2 to 60 carbon atoms.

According to another exemplary embodiment, Z1 is hydrogen, deuterium, a halogen group, a substituted or unsubstituted cycloalkyl group having 3 to 20 carbon atoms, a substituted or unsubstituted aryl group having 6 to 30 carbon atoms, or a substituted or unsubstituted heteroaryl group having 2 to 30 carbon atoms.

According to still another exemplary embodiment, Z1 is hydrogen, deuterium, or a substituted or unsubstituted pentyl group.

In an exemplary embodiment of the present specification, m1 is an integer from 0 to 8, and when m1 is 2 or higher, two or more Z1s are the same as or different from each other.

In an exemplary embodiment of the present specification, of Z10 and Z11, a group which is not linked to L2 in Chemical Formula 2, Z12, and Z13 are the same as or different from each other, and are each independently hydrogen, deuterium, a substituted or unsubstituted aryl group having 6 to 60 carbon atoms, or a substituted or unsubstituted heteroaryl group having 2 to 60 carbon atoms.

According to an exemplary embodiment of the present specification, of Z10 and Z11, a group which is not linked to L2 in Chemical Formula 2, Z12, and Z13 are the same as or different from each other, and are each independently hydrogen, deuterium, a substituted or unsubstituted aryl group having 6 to 30 carbon atoms, or a substituted or unsubstituted heteroaryl group having 2 to 30 carbon atoms.

According to an exemplary embodiment of the present specification, of Z10 and Z11, a group which is not linked to L2 in Chemical Formula 2, Z12, and Z13 are the same as or different from each other, and are each independently hydrogen, deuterium, or a substituted or unsubstituted aryl group having 6 to 30 carbon atoms.

According to an exemplary embodiment of the present specification, of Z10 and Z11, a group which is not linked to L2 in Chemical Formula 2, Z12, and Z13 are the same as or different from each other, and are each independently hydrogen, deuterium, or a substituted or unsubstituted phenyl group.

In an exemplary embodiment of the present specification, Z2 and Z3 are the same as or different from each other, and are each independently hydrogen, deuterium, a substituted or unsubstituted aryl group having 6 to 60 carbon atoms, or a substituted or unsubstituted heteroaryl group having 2 to 60 carbon atoms.

According to an exemplary embodiment of the present specification, Z2 and Z3 are the same as or different from each other, and are each independently hydrogen, deuterium, a substituted or unsubstituted aryl group having 6 to 30 carbon atoms, or a substituted or unsubstituted heteroaryl group having 2 to 30 carbon atoms.

According to an exemplary embodiment of the present specification, Z2 and Z3 are the same as or different from each other, and are each independently hydrogen, deuterium, or a substituted or unsubstituted aryl group having 6 to 30 carbon atoms.

According to an exemplary embodiment of the present specification, Z2 and Z3 are the same as or different from each other, and are each independently hydrogen, deuterium, a substituted or unsubstituted phenyl group, a substituted or unsubstituted biphenyl group, a substituted or unsubstituted naphthyl group, or a combination thereof.

According to an exemplary embodiment of the present specification, m2 is an integer from 0 to 6, and when m2 is 2 or higher, two or more Z2s are the same as or different from each other.

According to an exemplary embodiment of the present specification, m3 is an integer from 0 to 4, and when m3 is 2 or higher, two or more Z3s are the same as or different from each other.

In an exemplary embodiment of the present specification, the compound of Chemical Formula 2 is any one of the following compounds.

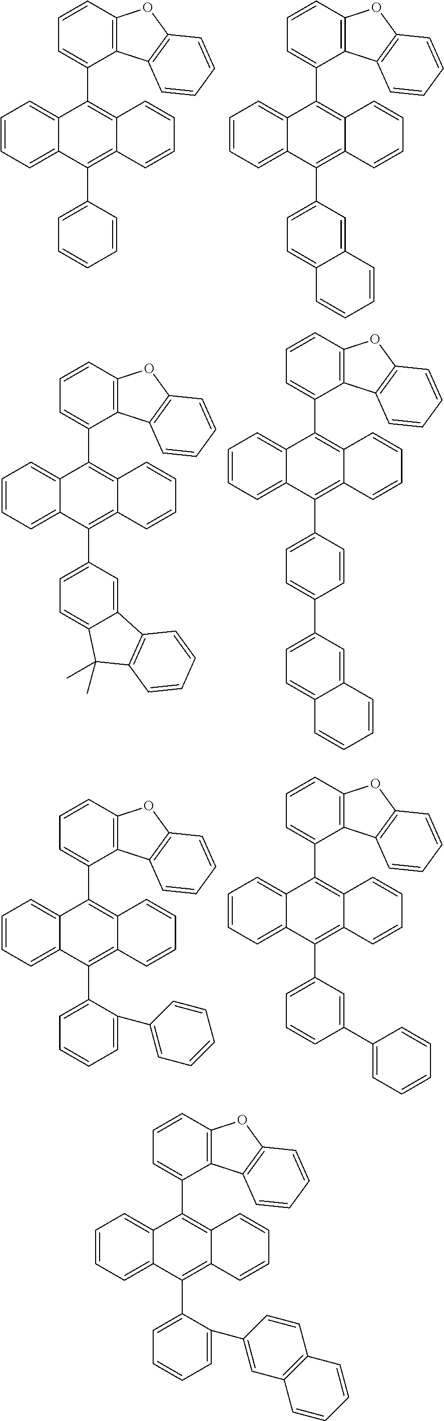

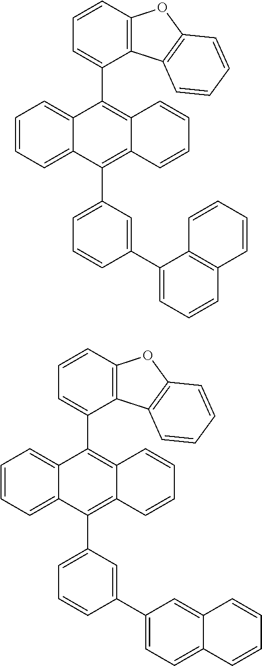 [SMILES: c1cc(-c2cccc3ccccc23)cc(-c2c3ccccc3c(-c3cccc4oc5ccccc5c34)c3ccccc23)c1 ; c1cc(-c2ccc3ccccc3c2)cc(-c2c3ccccc3c(-c3cccc4oc5ccccc5c34)c3ccccc23)c1]

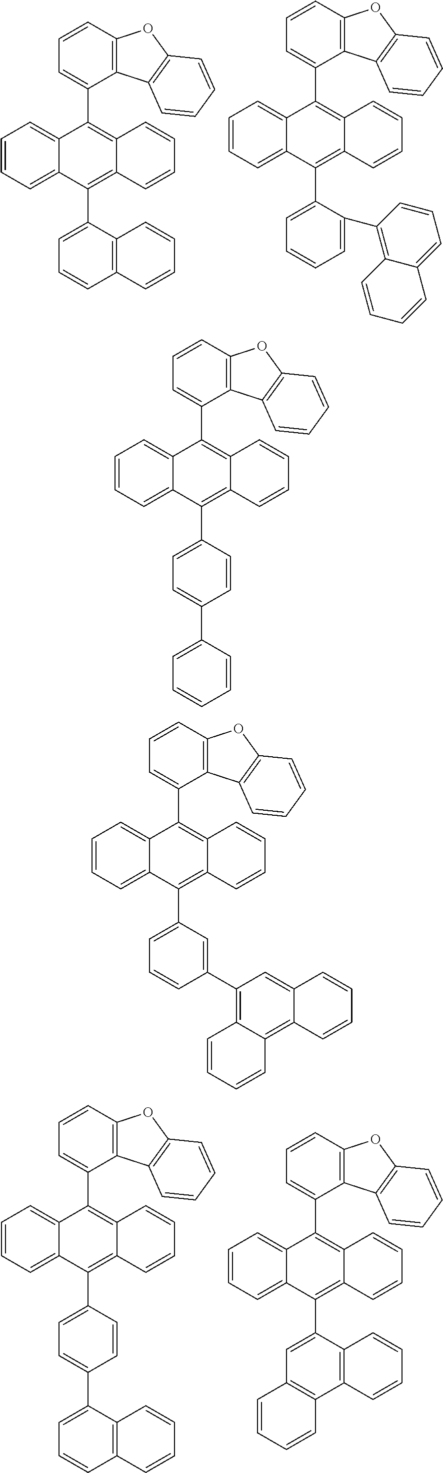

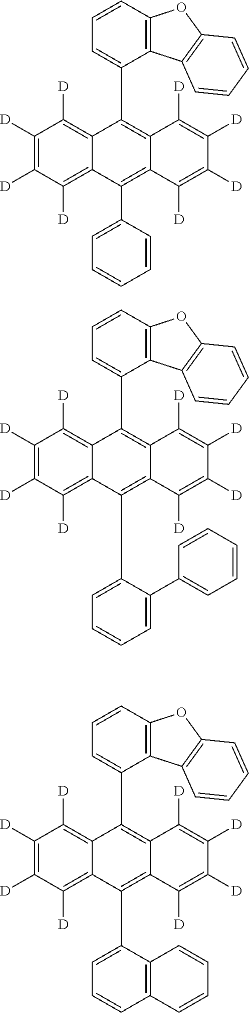

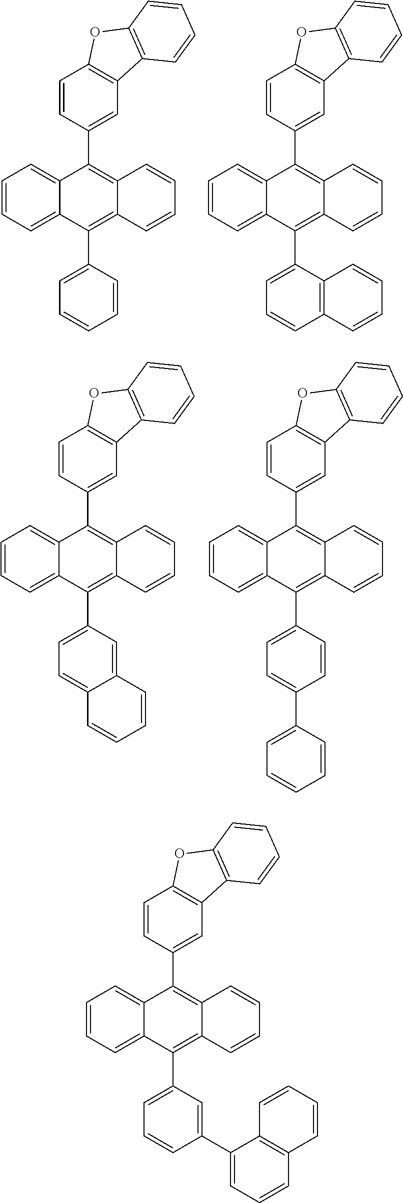

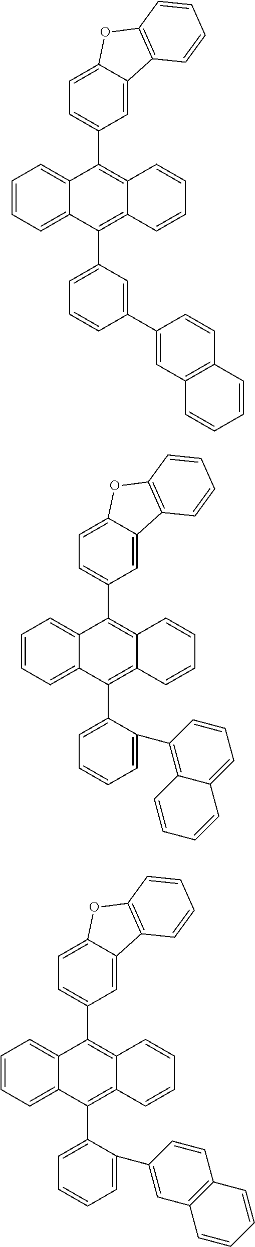

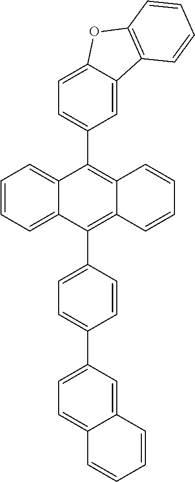 [SMILES: c1ccc2cc(-c3ccc(-c4c5ccccc5c(-c5ccc6oc7ccccc7c6c5)c5ccccc45)cc3)ccc2c1]

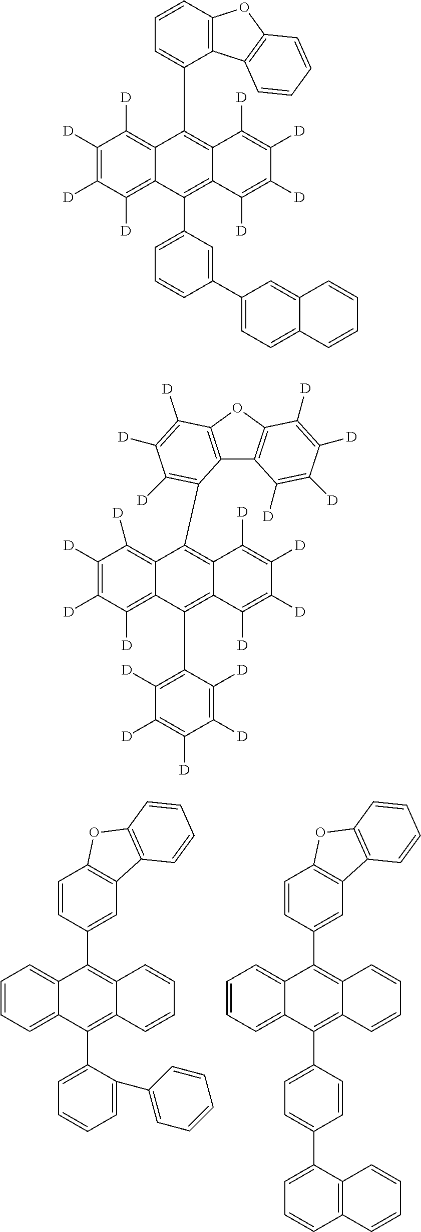

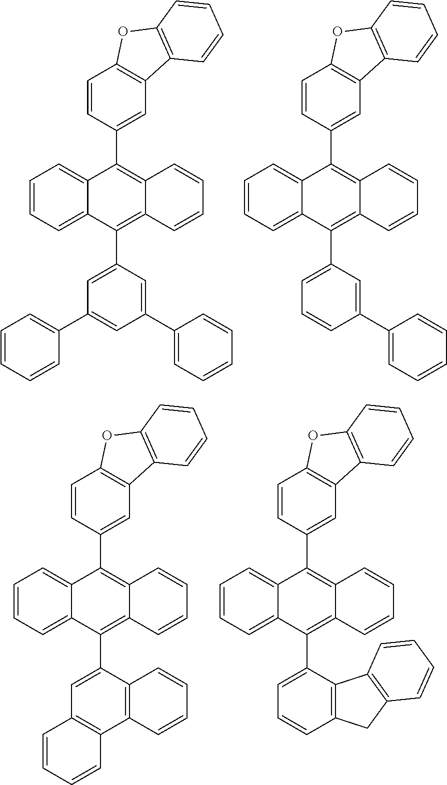

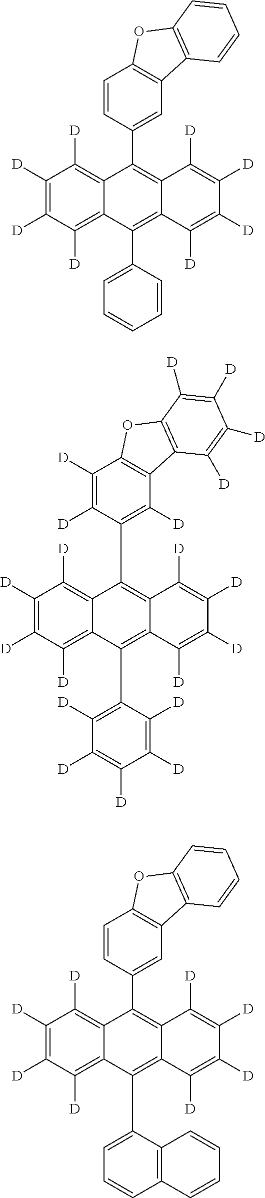 [SMILES: [2H]c1c([2H])c([2H])c2c(-c3ccc4oc5ccccc5c4c3)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H] ; [2H]c1c([2H])c([2H])c2c(-c3cccc4ccccc34)c3c([2H])c([2H])c([2H])c([2H])c3c(-c3ccc4oc5ccccc5c4c3)c2c1[2H]]

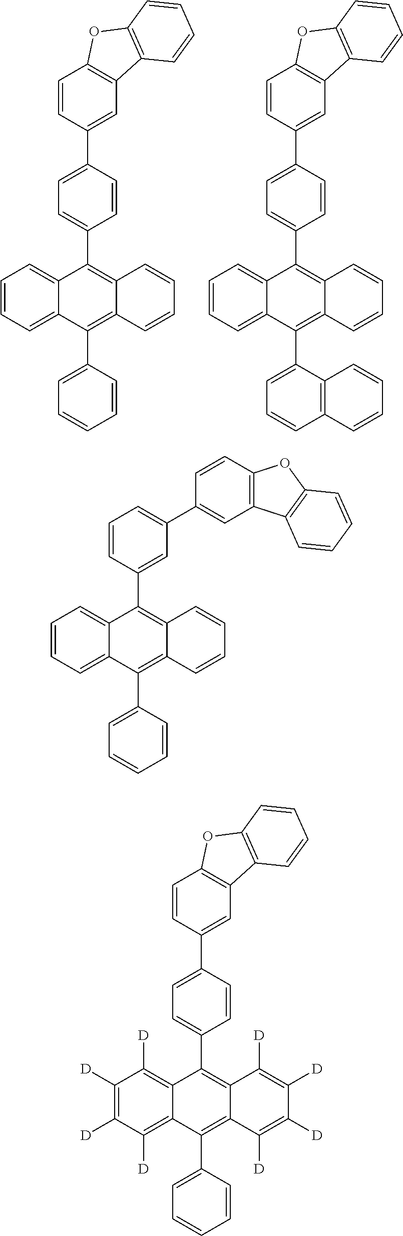

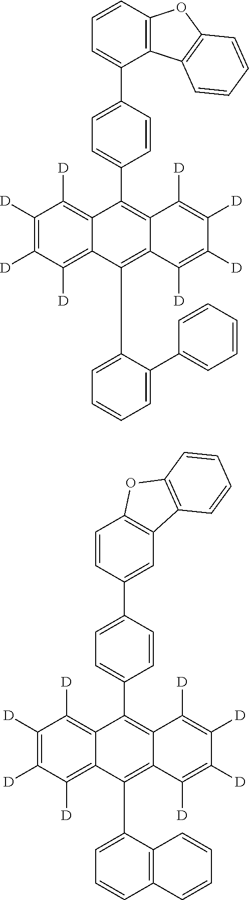 [SMILES: [2H]c1c([2H])c([2H])c2c(-c3ccccc3-c3ccccc3)c3c([2H])c([2H])c([2H])c([2H])c3c(-c3ccc(-c4cccc5oc6ccccc6c45)cc3)c2c1[2H] ; [2H]c1c([2H])c([2H])c2c(-c3cccc4ccccc34)c3c([2H])c([2H])c([2H])c([2H])c3c(-c3ccc(-c4ccc5oc6ccccc6c5c4)cc3)c2c1[2H]]

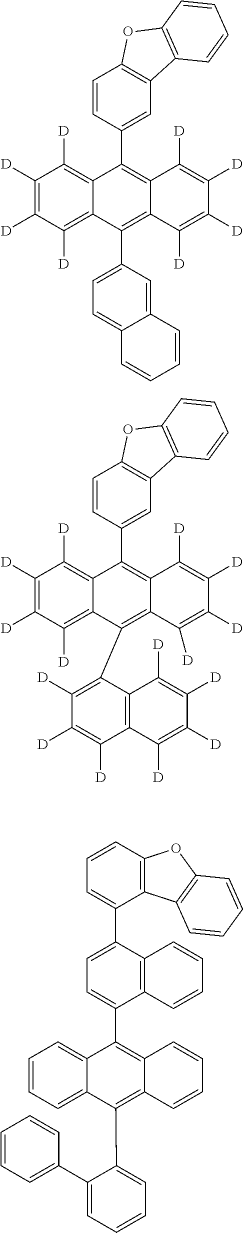

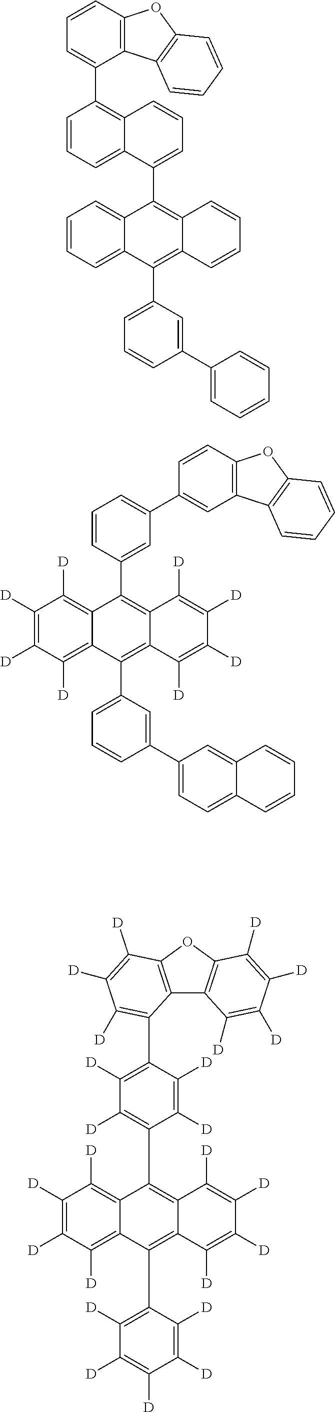

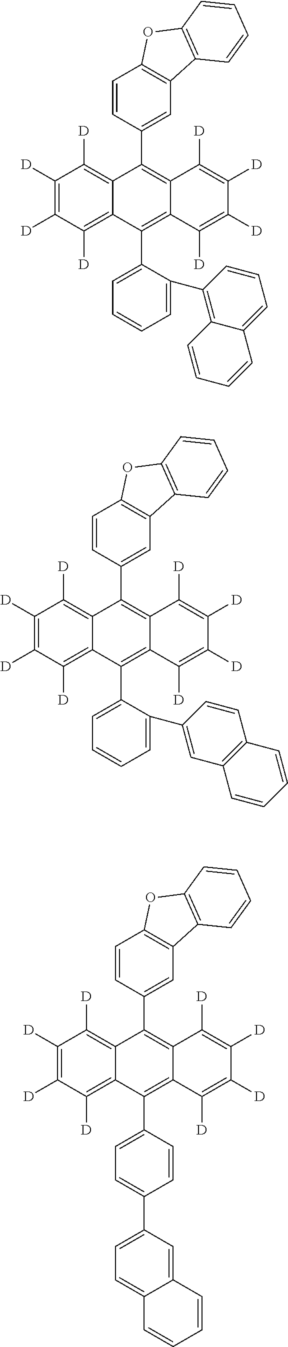 [SMILES: [2H]c1c([2H])c([2H])c2c(-c3ccccc3-c3cccc4ccccc34)c3c([2H])c([2H])c([2H])c([2H])c3c(-c3ccc4oc5ccccc5c4c3)c2c1[2H] ; [2H]c1c([2H])c([2H])c2c(-c3ccccc3-c3ccc4ccccc4c3)c3c([2H])c([2H])c([2H])c([2H])c3c(-c3ccc4oc5ccccc5c4c3)c2c1[2H] ; [2H]c1c([2H])c([2H])c2c(-c3ccc4oc5ccccc5c4c3)c3c([2H])c([2H])c([2H])c([2H])c3c(-c3ccc(-c4ccc5ccccc5c4)cc3)c2c1[2H]]

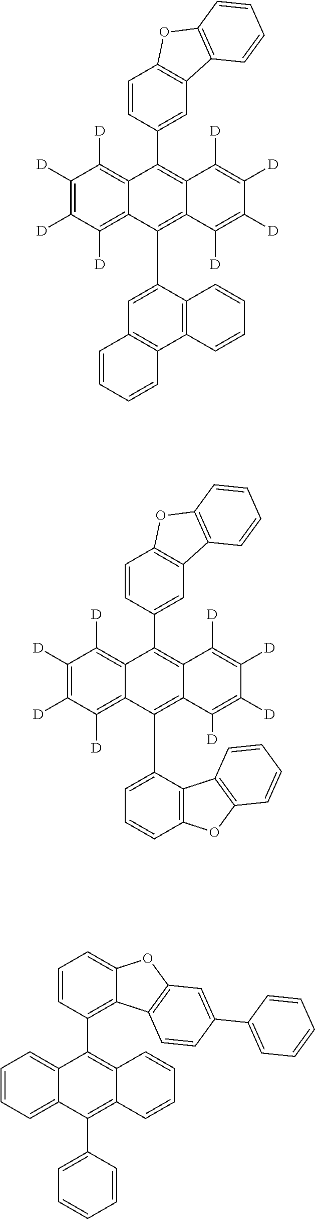 [SMILES: [2H]c1c([2H])c([2H])c2c(-c3cc4ccccc4c4ccccc34)c3c([2H])c([2H])c([2H])c([2H])c3c(-c3ccc4oc5ccccc5c4c3)c2c1[2H] ; [2H]c1c([2H])c([2H])c2c(-c3cccc4oc5ccccc5c34)c3c([2H])c([2H])c([2H])c([2H])c3c(-c3ccc4oc5ccccc5c4c3)c2c1[2H] ; c1ccc(-c2ccc3c(c2)oc2cccc(-c4c5ccccc5c(-c5ccccc5)c5ccccc45)c23)cc1]

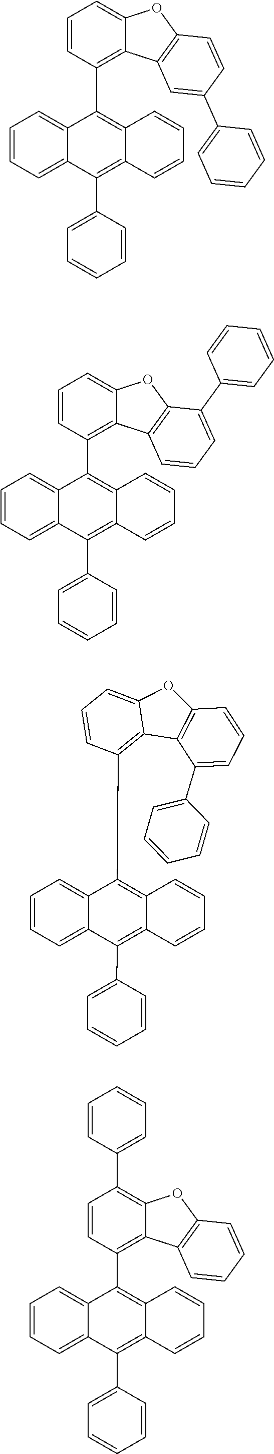

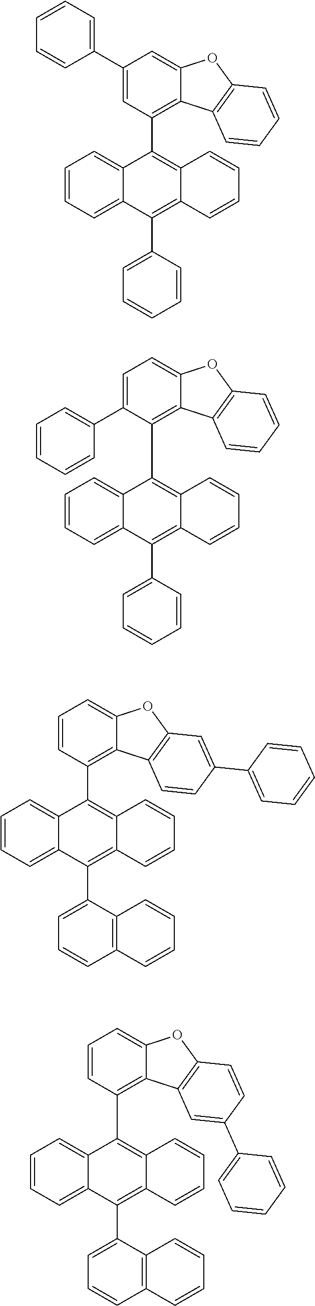

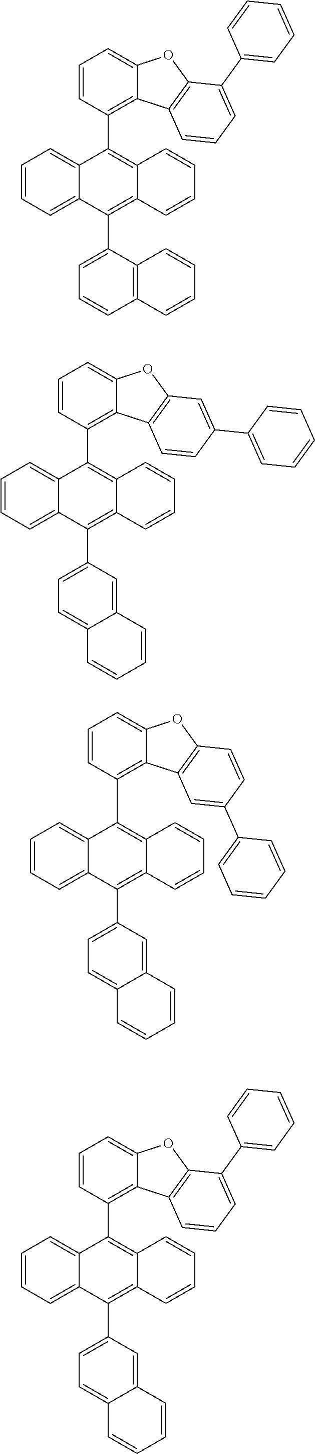

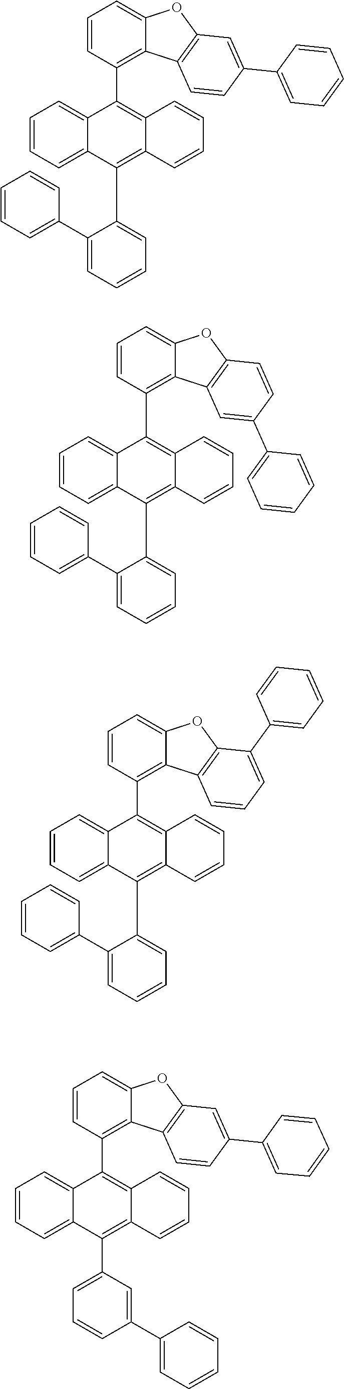 [SMILES: c1ccc(-c2ccc3c(c2)oc2cccc(-c4c5ccccc5c(-c5ccccc5-c5ccccc5)c5ccccc45)c23)cc1 ; c1ccc(-c2ccc3oc4cccc(-c5c6ccccc6c(-c6ccccc6-c6ccccc6)c6ccccc56)c4c3c2)cc1 ; c1ccc(-c2ccccc2-c2c3ccccc3c(-c3cccc4oc5c(-c6ccccc6)cccc5c34)c3ccccc23)cc1 ; c1ccc(-c2cccc(-c3c4ccccc4c(-c4cccc5oc6cc(-c7ccccc7)ccc6c45)c4ccccc34)c2)cc1]

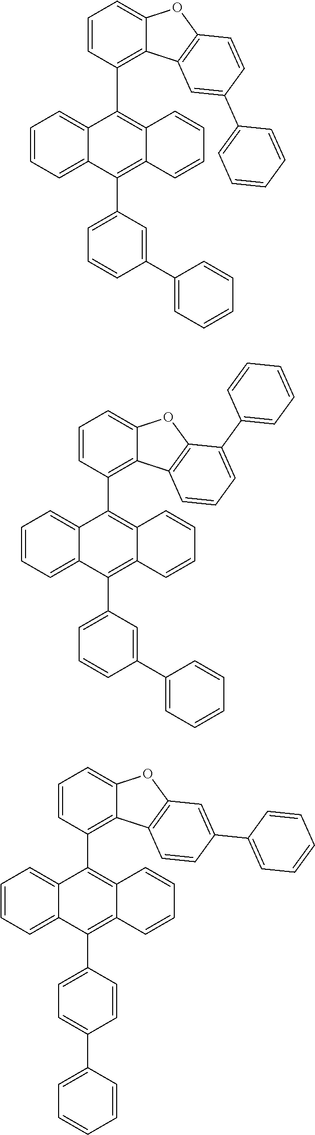 [SMILES: c1ccc(-c2cccc(-c3c4ccccc4c(-c4cccc5oc6ccc(-c7ccccc7)cc6c45)c4ccccc34)c2)cc1 ; c1ccc(-c2cccc(-c3c4ccccc4c(-c4cccc5oc6c(-c7ccccc7)cccc6c45)c4ccccc34)c2)cc1 ; c1ccc(-c2ccc(-c3c4ccccc4c(-c4cccc5oc6cc(-c7ccccc7)ccc6c45)c4ccccc34)cc2)cc1]

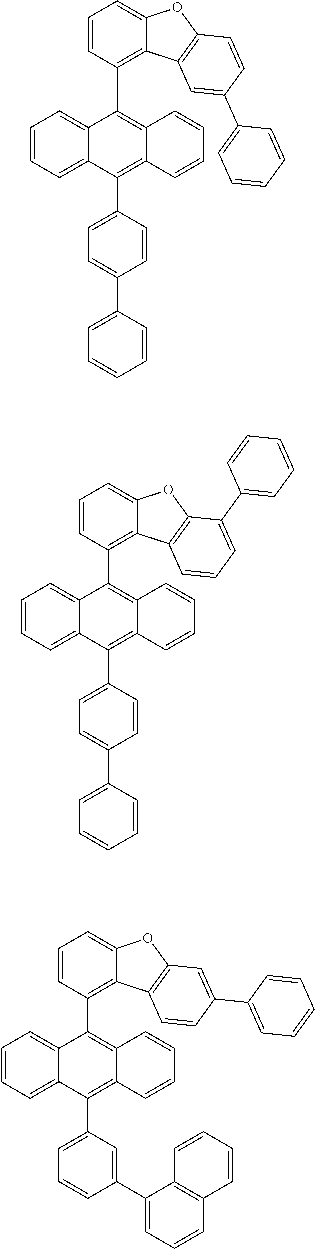 [SMILES: c1ccc(-c2ccc(-c3c4ccccc4c(-c4cccc5oc6ccc(-c7ccccc7)cc6c45)c4ccccc34)cc2)cc1 ; c1ccc(-c2ccc(-c3c4ccccc4c(-c4cccc5oc6c(-c7ccccc7)cccc6c45)c4ccccc34)cc2)cc1 ; c1ccc(-c2ccc3c(c2)oc2cccc(-c4c5ccccc5c(-c5cccc(-c6cccc7ccccc67)c5)c5ccccc45)c23)cc1]

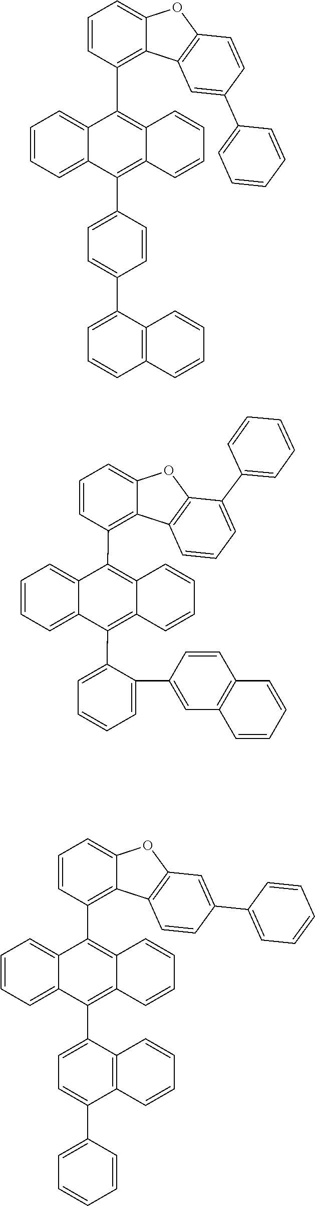 [SMILES: c1ccc(-c2ccc3oc4cccc(-c5c6ccccc6c(-c6ccc(-c7cccc8ccccc78)cc6)c6ccccc56)c4c3c2)cc1 ; c1ccc(-c2cccc3c2oc2cccc(-c4c5ccccc5c(-c5ccccc5-c5ccc6ccccc6c5)c5ccccc45)c23)cc1 ; c1ccc(-c2ccc3c(c2)oc2cccc(-c4c5ccccc5c(-c5ccc(-c6ccccc6)c6ccccc56)c5ccccc45)c23)cc1]

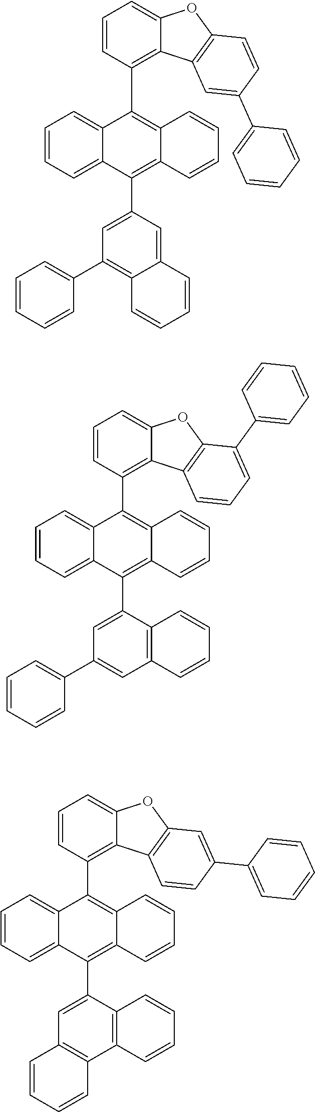 [SMILES: c1ccc(-c2ccc3oc4cccc(-c5c6ccccc6c(-c6cc(-c7ccccc7)c7ccccc7c6)c6ccccc56)c4c3c2)cc1 ; c1ccc(-c2cc(-c3c4ccccc4c(-c4cccc5oc6c(-c7ccccc7)cccc6c45)c4ccccc34)c3ccccc3c2)cc1 ; c1ccc(-c2ccc3c(c2)oc2cccc(-c4c5ccccc5c(-c5cc6ccccc6c6ccccc56)c5ccccc45)c23)cc1]

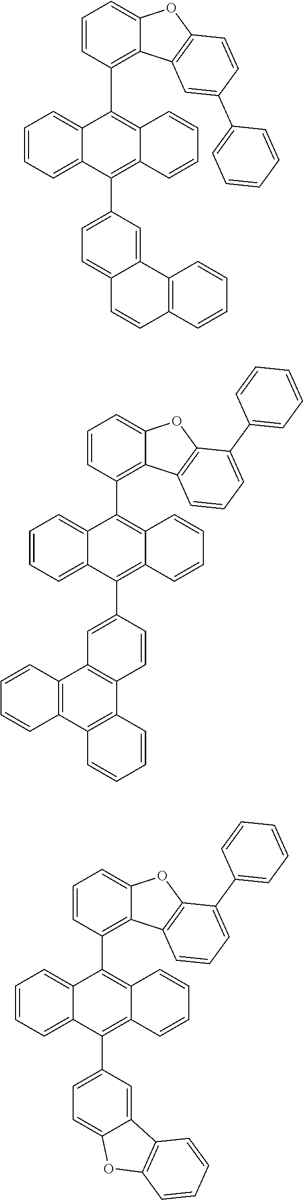 [SMILES: c1ccc(-c2ccc3oc4cccc(-c5c6ccccc6c(-c6ccc7ccc8ccccc8c7c6)c6ccccc56)c4c3c2)cc1 ; c1ccc(-c2cccc3c2oc2cccc(-c4c5ccccc5c(-c5ccc6c7ccccc7c7ccccc7c6c5)c5ccccc45)c23)cc1 ; c1ccc(-c2cccc3c2oc2cccc(-c4c5ccccc5c(-c5ccc6oc7ccccc7c6c5)c5ccccc45)c23)cc1]

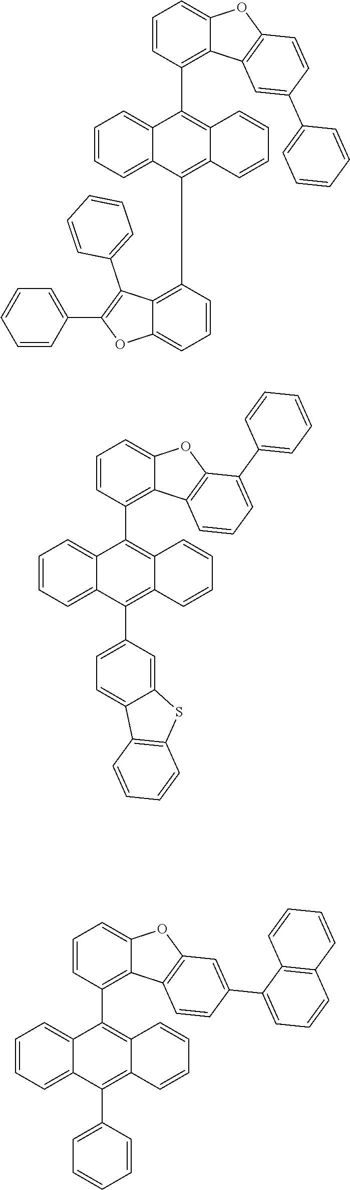 [SMILES: c1ccc(-c2ccc3oc4cccc(-c5c6ccccc6c(-c6cccc7oc(-c8ccccc8)c(-c8ccccc8)c67)c6ccccc56)c4c3c2)cc1 ; c1ccc(-c2cccc3c2oc2cccc(-c4c5ccccc5c(-c5ccc6c(c5)sc5ccccc56)c5ccccc45)c23)cc1 ; c1ccc(-c2c3ccccc3c(-c3cccc4oc5cc(-c6cccc7ccccc67)ccc5c34)c3ccccc23)cc1]

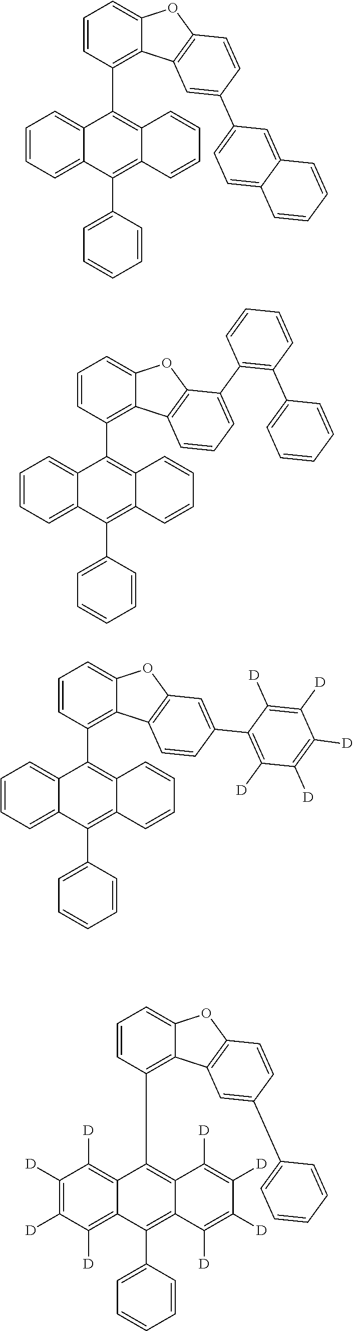

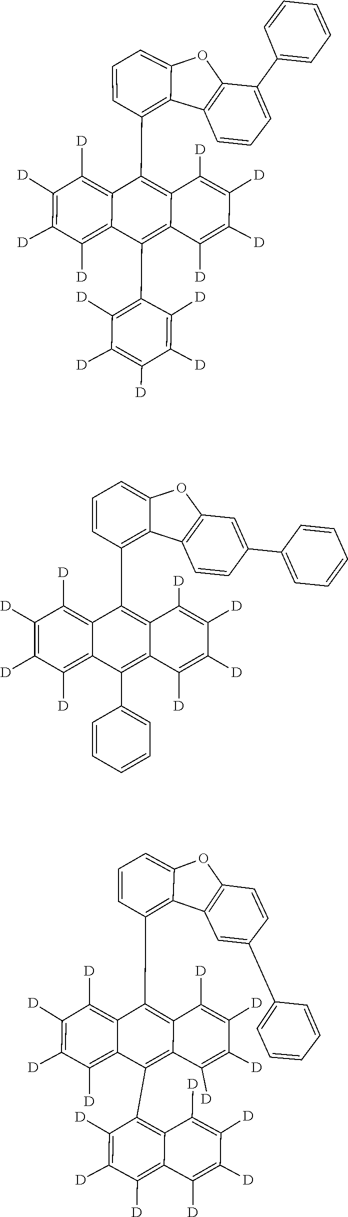 [SMILES: [2H]c1c([2H])c([2H])c(-c2c3c([2H])c([2H])c([2H])c([2H])c3c(-c3cccc4oc5c(-c6ccccc6)cccc5c34)c3c([2H])c([2H])c([2H])c([2H])c23)c([2H])c1[2H] ; [2H]c1c([2H])c([2H])c2c(-c3cccc4oc5cc(-c6ccccc6)ccc5c34)c3c([2H])c([2H])c([2H])c([2H])c3c(-c3ccccc3)c2c1[2H] ; [2H]c1c([2H])c([2H])c2c(-c3c4c([2H])c([2H])c([2H])c([2H])c4c(-c4cccc5oc6ccc(-c7ccccc7)cc6c45)c4c([2H])c([2H])c([2H])c([2H])c34)c([2H])c([2H])c([2H])c2c1[2H]]

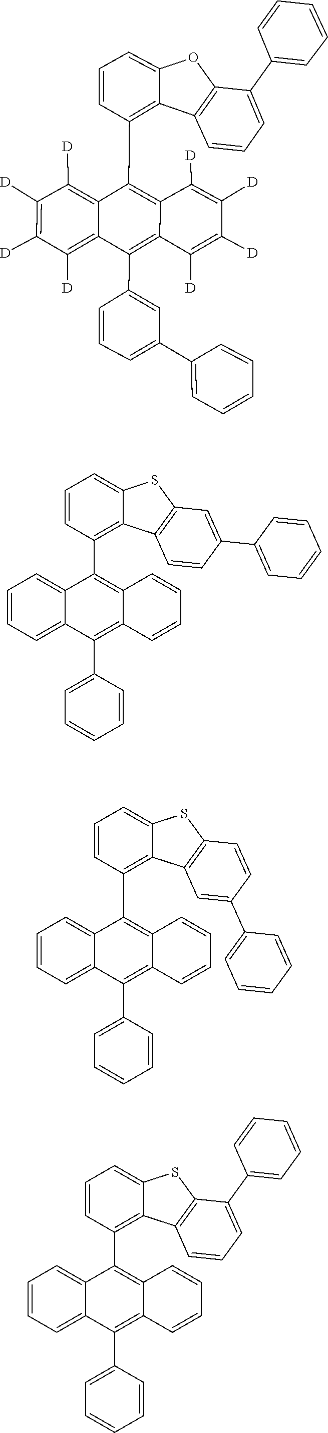 [SMILES: [2H]c1c([2H])c([2H])c2c(-c3cccc4oc5c(-c6ccccc6)cccc5c34)c3c([2H])c([2H])c([2H])c([2H])c3c(-c3cccc(-c4ccccc4)c3)c2c1[2H] ; c1ccc(-c2ccc3c(c2)sc2cccc(-c4c5ccccc5c(-c5ccccc5)c5ccccc45)c23)cc1 ; c1ccc(-c2ccc3sc4cccc(-c5c6ccccc6c(-c6ccccc6)c6ccccc56)c4c3c2)cc1 ; c1ccc(-c2c3ccccc3c(-c3cccc4sc5c(-c6ccccc6)cccc5c34)c3ccccc23)cc1]

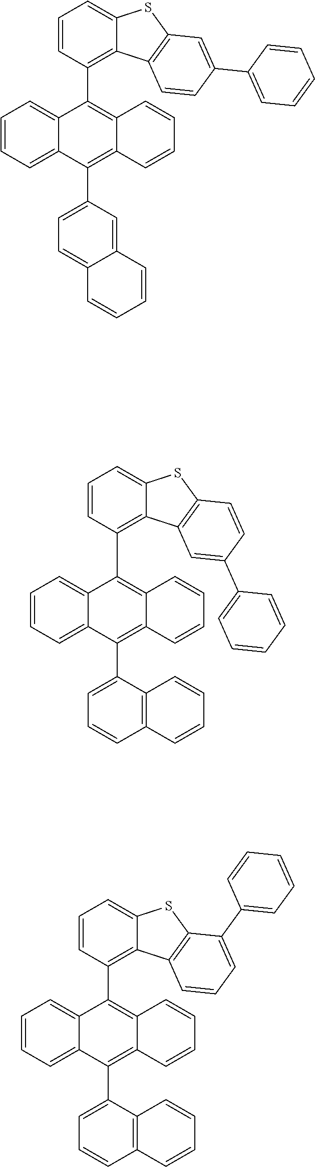 [SMILES: c1ccc(-c2ccc3c(c2)sc2cccc(-c4c5ccccc5c(-c5ccc6ccccc6c5)c5ccccc45)c23)cc1 ; c1ccc(-c2ccc3sc4cccc(-c5c6ccccc6c(-c6cccc7ccccc67)c6ccccc56)c4c3c2)cc1 ; c1ccc(-c2cccc3c2sc2cccc(-c4c5ccccc5c(-c5cccc6ccccc56)c5ccccc45)c23)cc1]

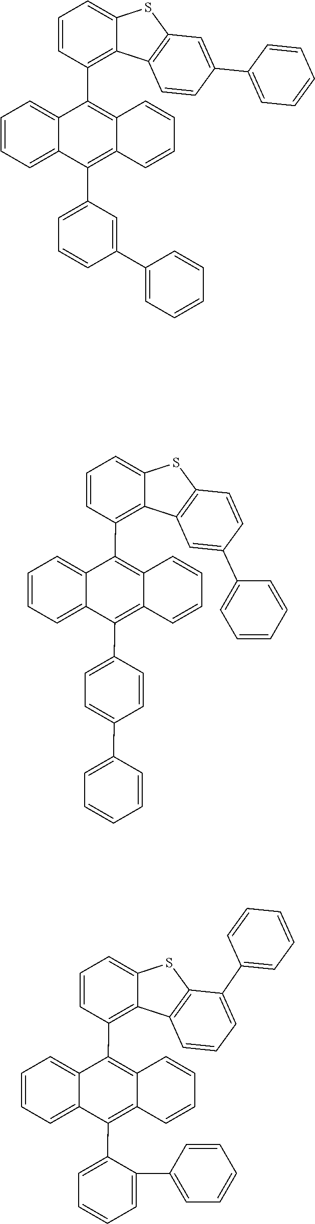 [SMILES: c1ccc(-c2cccc(-c3c4ccccc4c(-c4cccc5sc6cc(-c7ccccc7)ccc6c45)c4ccccc34)c2)cc1 ; c1ccc(-c2ccc(-c3c4ccccc4c(-c4cccc5sc6ccc(-c7ccccc7)cc6c45)c4ccccc34)cc2)cc1 ; c1ccc(-c2ccccc2-c2c3ccccc3c(-c3cccc4sc5c(-c6ccccc6)cccc5c34)c3ccccc23)cc1]

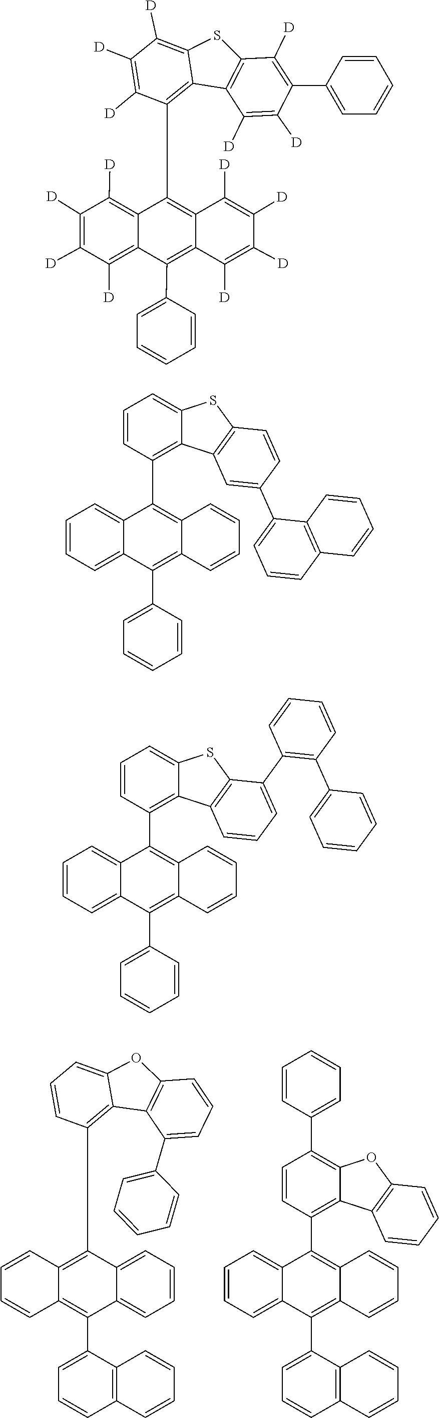

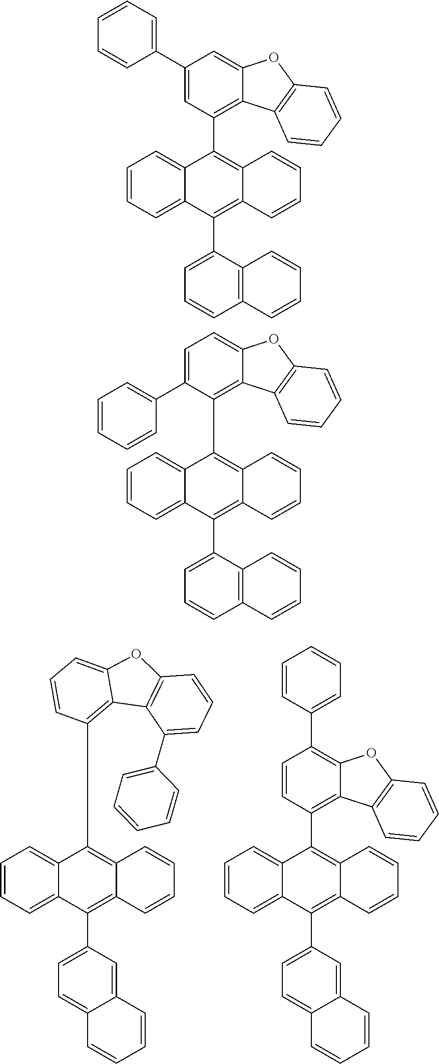

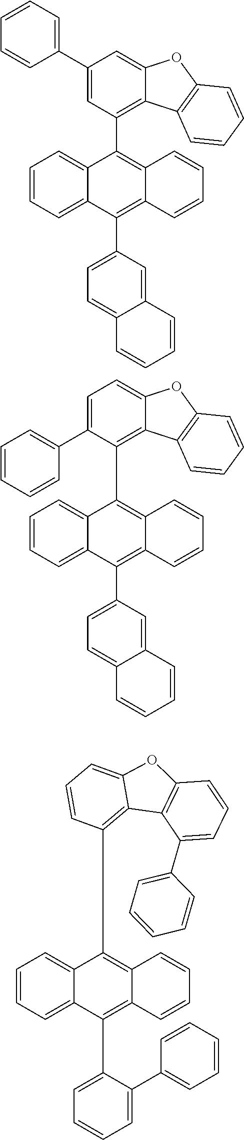

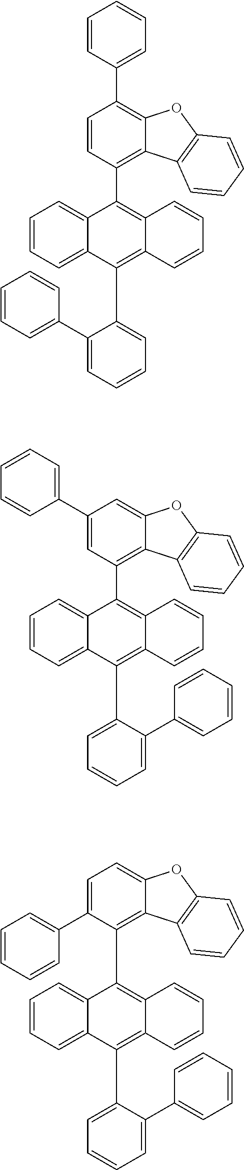 [SMILES: c1ccc(-c2ccccc2-c2c3ccccc3c(-c3ccc(-c4ccccc4)c4oc5ccccc5c34)c3ccccc23)cc1 ; c1ccc(-c2cc(-c3c4ccccc4c(-c4ccccc4-c4ccccc4)c4ccccc34)c3c(c2)oc2ccccc23)cc1 ; c1ccc(-c2ccccc2-c2c3ccccc3c(-c3c(-c4ccccc4)ccc4oc5ccccc5c34)c3ccccc23)cc1]

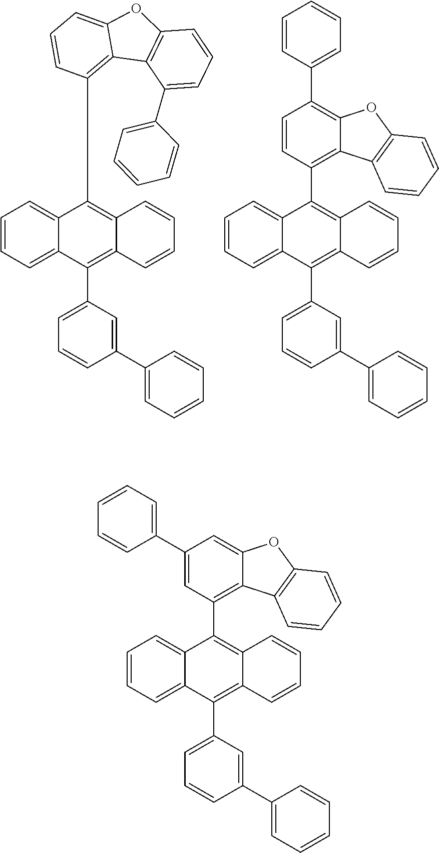 [SMILES: c1ccc(-c2cccc(-c3c4ccccc4c(-c4cccc5oc6cccc(-c7ccccc7)c6c45)c4ccccc34)c2)cc1 ; c1ccc(-c2cccc(-c3c4ccccc4c(-c4ccc(-c5ccccc5)c5oc6ccccc6c45)c4ccccc34)c2)cc1 ; c1ccc(-c2cccc(-c3c4ccccc4c(-c4cc(-c5ccccc5)cc5oc6ccccc6c45)c4ccccc34)c2)cc1]

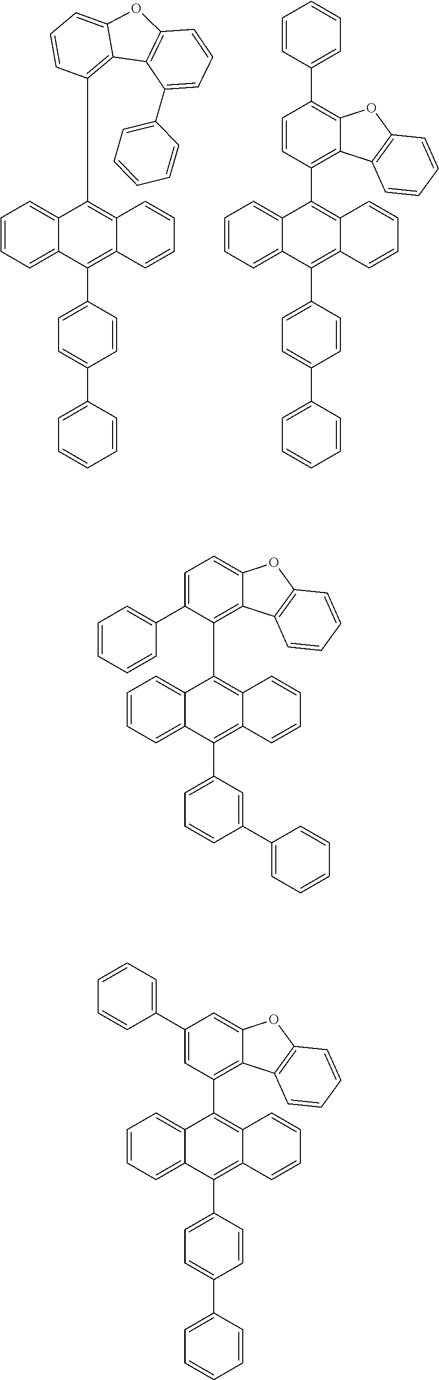 [SMILES: c1ccc(-c2ccc(-c3c4ccccc4c(-c4cccc5oc6cccc(-c7ccccc7)c6c45)c4ccccc34)cc2)cc1 ; c1ccc(-c2ccc(-c3c4ccccc4c(-c4ccc(-c5ccccc5)c5oc6ccccc6c45)c4ccccc34)cc2)cc1 ; c1ccc(-c2cccc(-c3c4ccccc4c(-c4c(-c5ccccc5)ccc5oc6ccccc6c45)c4ccccc34)c2)cc1 ; c1ccc(-c2ccc(-c3c4ccccc4c(-c4cc(-c5ccccc5)cc5oc6ccccc6c45)c4ccccc34)cc2)cc1]

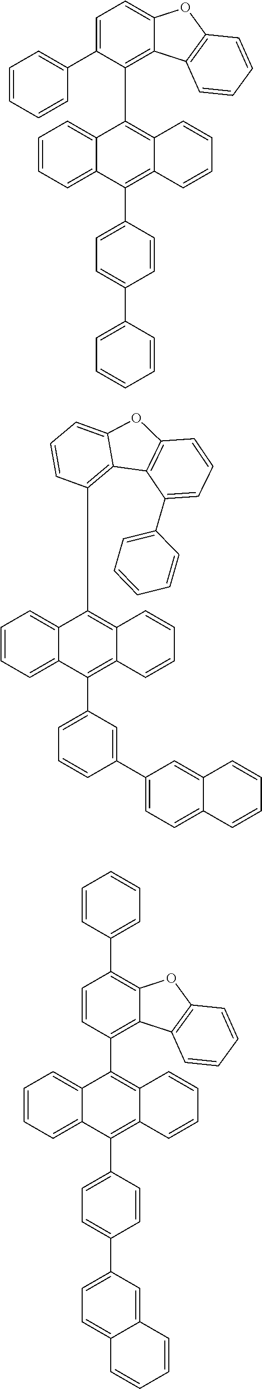

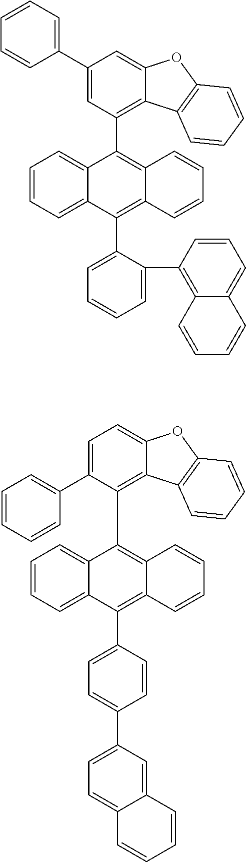 [SMILES: c1ccc(-c2cc(-c3c4ccccc4c(-c4ccccc4-c4cccc5ccccc45)c4ccccc34)c3c(c2)oc2ccccc23)cc1 ; c1ccc(-c2ccc3oc4ccccc4c3c2-c2c3ccccc3c(-c3ccc(-c4ccc5ccccc5c4)cc3)c3ccccc23)cc1]

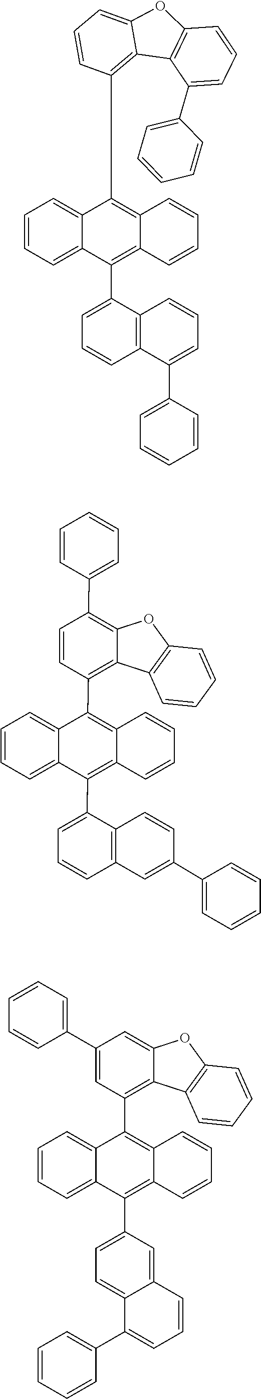 [SMILES: c1ccc(-c2cccc3c(-c4c5ccccc5c(-c5cccc6oc7cccc(-c8ccccc8)c7c56)c5ccccc45)cccc23)cc1 ; c1ccc(-c2ccc3c(-c4c5ccccc5c(-c5ccc(-c6ccccc6)c6oc7ccccc7c56)c5ccccc45)cccc3c2)cc1 ; c1ccc(-c2cc(-c3c4ccccc4c(-c4ccc5c(-c6ccccc6)cccc5c4)c4ccccc34)c3c(c2)oc2ccccc23)cc1]

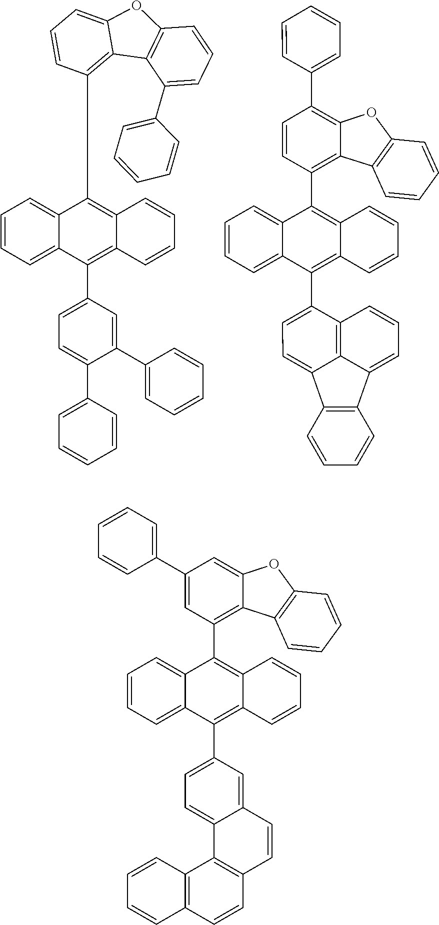 [SMILES: c1ccc(-c2ccc(-c3c4ccccc4c(-c4cccc5oc6cccc(-c7ccccc7)c6c45)c4ccccc34)cc2-c2ccccc2)cc1 ; c1ccc(-c2ccc(-c3c4ccccc4c(-c4ccc5c6c(cccc46)-c4ccccc4-5)c4ccccc34)c3c2oc2ccccc23)cc1 ; c1ccc(-c2cc(-c3c4ccccc4c(-c4ccc5c(ccc6ccc7ccccc7c65)c4)c4ccccc34)c3c(c2)oc2ccccc23)cc1]

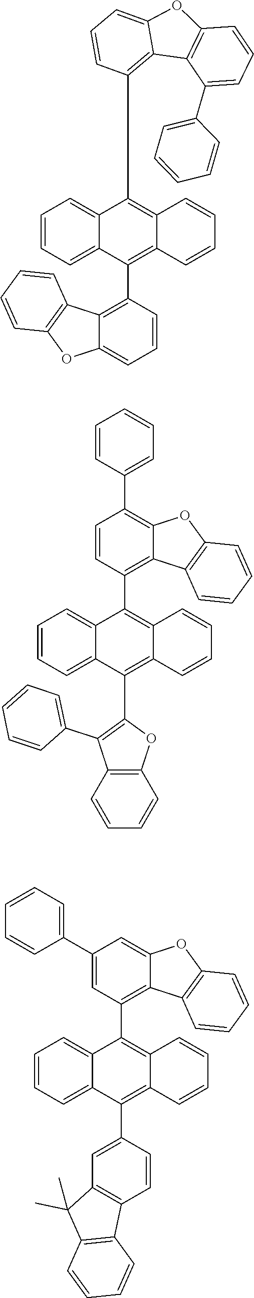

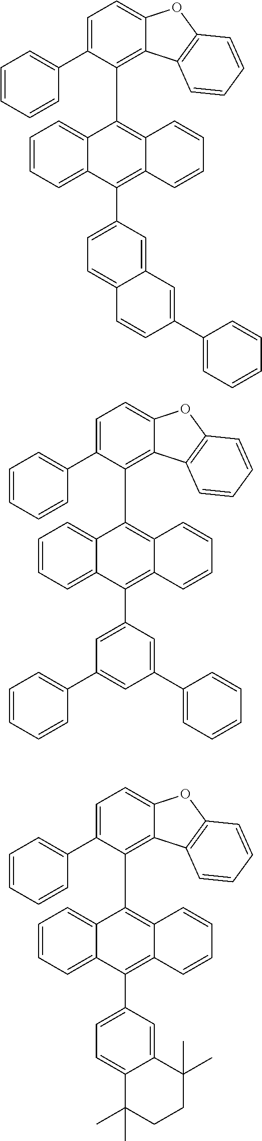

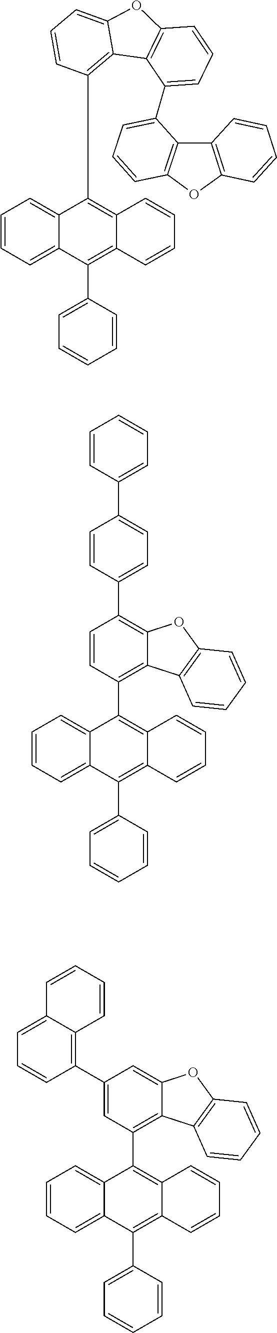 [SMILES: c1ccc(-c2c3ccccc3c(-c3cccc4oc5cccc(-c6cccc7oc8ccccc8c67)c5c34)c3ccccc23)cc1 ; c1ccc(-c2ccc(-c3ccc(-c4c5ccccc5c(-c5ccccc5)c5ccccc45)c4c3oc3ccccc34)cc2)cc1 ; c1ccc(-c2c3ccccc3c(-c3cc(-c4cccc5ccccc45)cc4oc5ccccc5c34)c3ccccc23)cc1]

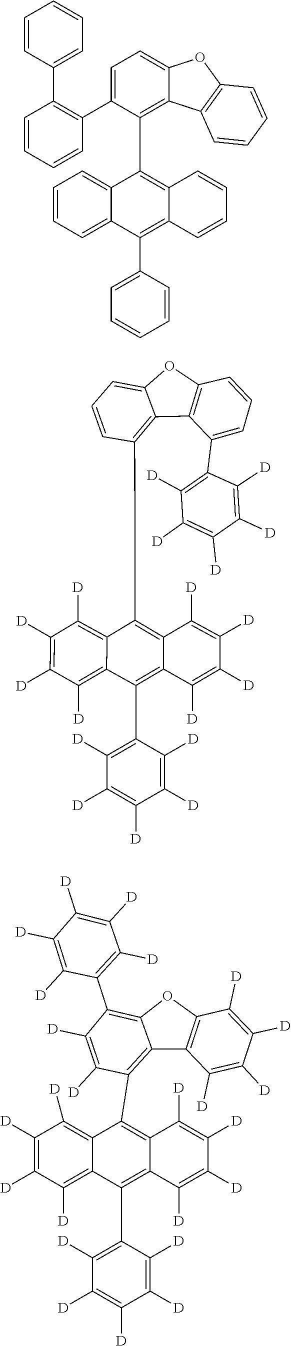

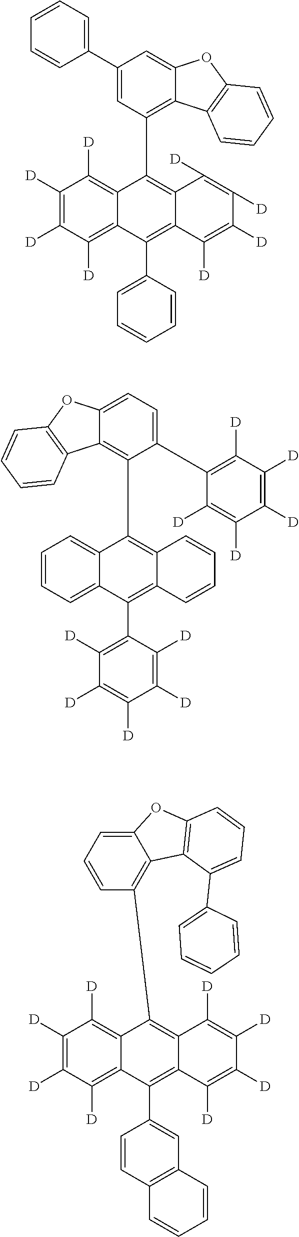 [SMILES: [2H]c1c([2H])c([2H])c2c(-c3cc(-c4ccccc4)cc4oc5ccccc5c34)c3c([2H])c([2H])c([2H])c([2H])c3c(-c3ccccc3)c2c1[2H] ; [2H]c1c([2H])c([2H])c(-c2ccc3oc4ccccc4c3c2-c2c3ccccc3c(-c3c([2H])c([2H])c([2H])c([2H])c3[2H])c3ccccc23)c([2H])c1[2H] ; [2H]c1c([2H])c([2H])c2c(-c3cccc4oc5cccc(-c6ccccc6)c5c34)c3c([2H])c([2H])c([2H])c([2H])c3c(-c3ccc4ccccc4c3)c2c1[2H]]

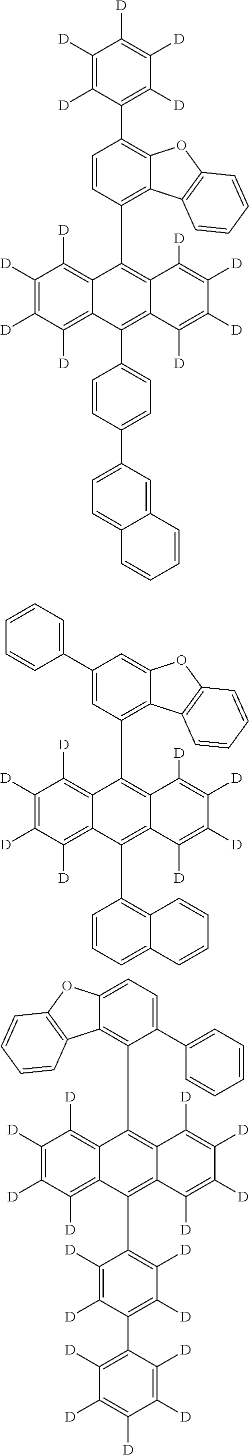

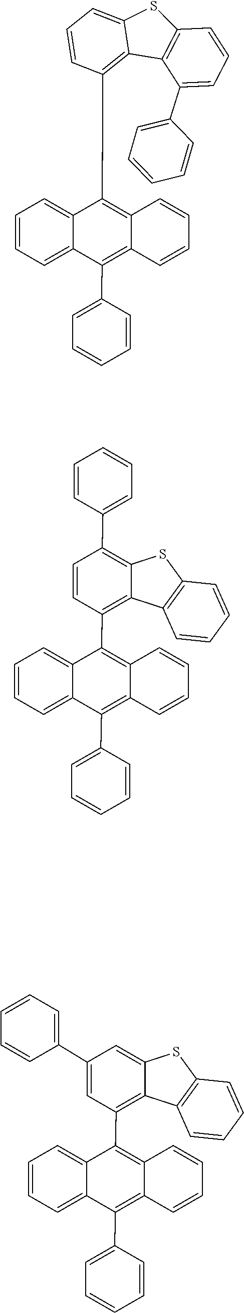 [SMILES: c1ccc(-c2c3ccccc3c(-c3cccc4sc5cccc(-c6ccccc6)c5c34)c3ccccc23)cc1 ; c1ccc(-c2c3ccccc3c(-c3ccc(-c4ccccc4)c4sc5ccccc5c34)c3ccccc23)cc1 ; c1ccc(-c2cc(-c3c4ccccc4c(-c4ccccc4)c4ccccc34)c3c(c2)sc2ccccc23)cc1]

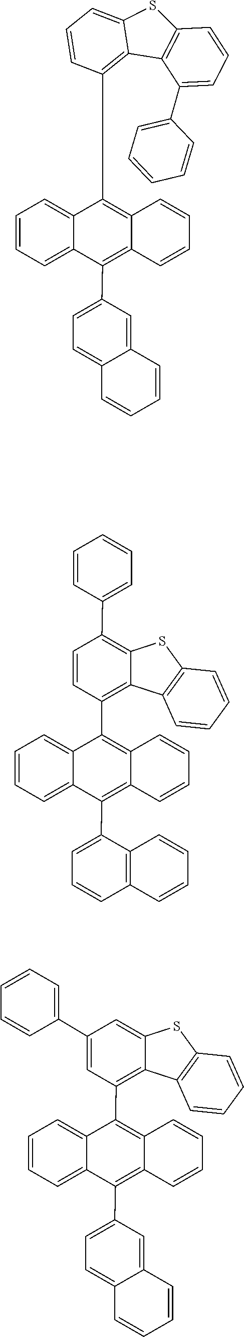 [SMILES: c1ccc(-c2cccc3sc4cccc(-c5c6ccccc6c(-c6ccc7ccccc7c6)c6ccccc56)c4c23)cc1 ; c1ccc(-c2ccc(-c3c4ccccc4c(-c4cccc5ccccc45)c4ccccc34)c3c2sc2ccccc23)cc1 ; c1ccc(-c2cc(-c3c4ccccc4c(-c4ccc5ccccc5c4)c4ccccc34)c3c(c2)sc2ccccc23)cc1]

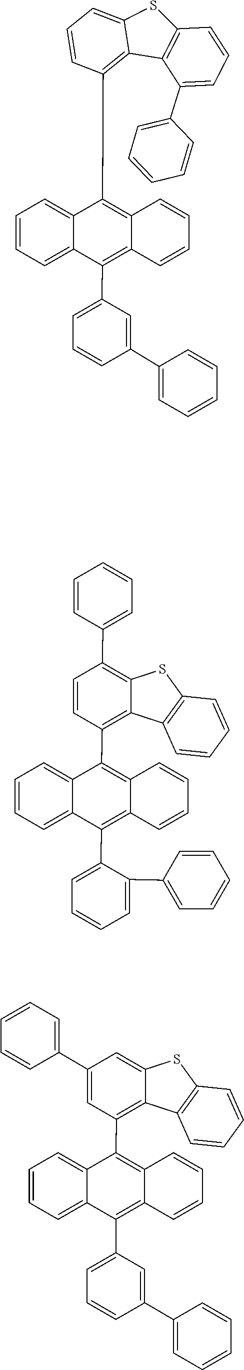 [SMILES: c1ccc(-c2cccc(-c3c4ccccc4c(-c4cccc5sc6cccc(-c7ccccc7)c6c45)c4ccccc34)c2)cc1 ; c1ccc(-c2ccccc2-c2c3ccccc3c(-c3ccc(-c4ccccc4)c4sc5ccccc5c34)c3ccccc23)cc1 ; c1ccc(-c2cccc(-c3c4ccccc4c(-c4cc(-c5ccccc5)cc5sc6ccccc6c45)c4ccccc34)c2)cc1]

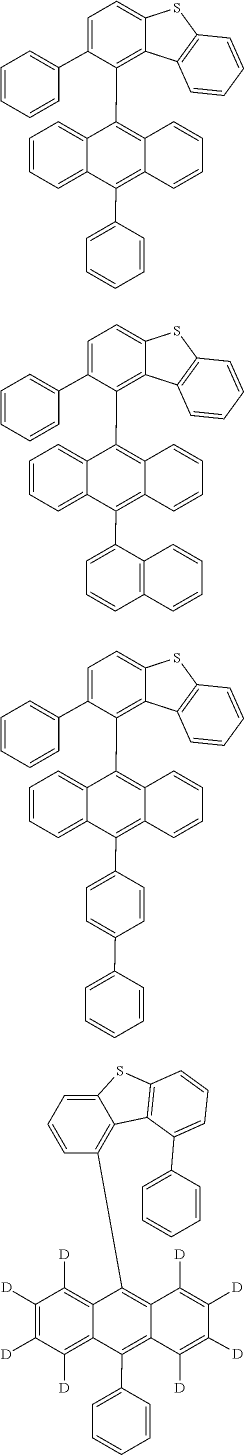

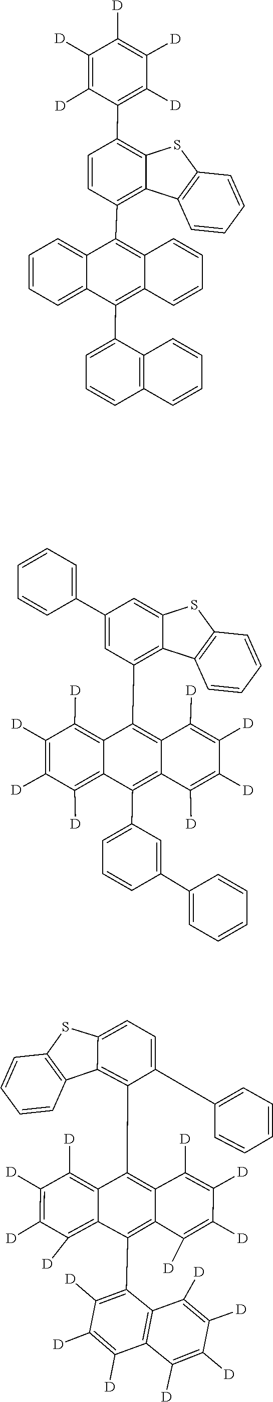 [SMILES: [2H]c1c([2H])c([2H])c(-c2ccc(-c3c4ccccc4c(-c4cccc5ccccc45)c4ccccc34)c3c2sc2ccccc23)c([2H])c1[2H] ; [2H]c1c([2H])c([2H])c2c(-c3cc(-c4ccccc4)cc4sc5ccccc5c34)c3c([2H])c([2H])c([2H])c([2H])c3c(-c3cccc(-c4ccccc4)c3)c2c1[2H] ; [2H]c1c([2H])c([2H])c2c(-c3c4c([2H])c([2H])c([2H])c([2H])c4c(-c4c(-c5ccccc5)ccc5sc6ccccc6c45)c4c([2H])c([2H])c([2H])c([2H])c34)c([2H])c([2H])c([2H])c2c1[2H]]

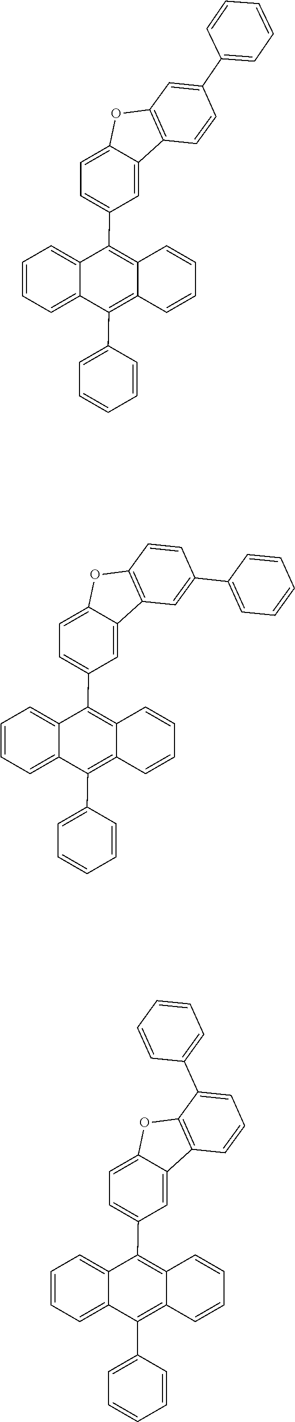 [SMILES: c1ccc(-c2ccc3c(c2)oc2ccc(-c4c5ccccc5c(-c5ccccc5)c5ccccc45)cc23)cc1 ; c1ccc(-c2ccc3oc4ccc(-c5c6ccccc6c(-c6ccccc6)c6ccccc56)cc4c3c2)cc1 ; c1ccc(-c2c3ccccc3c(-c3ccc4oc5c(-c6ccccc6)cccc5c4c3)c3ccccc23)cc1]

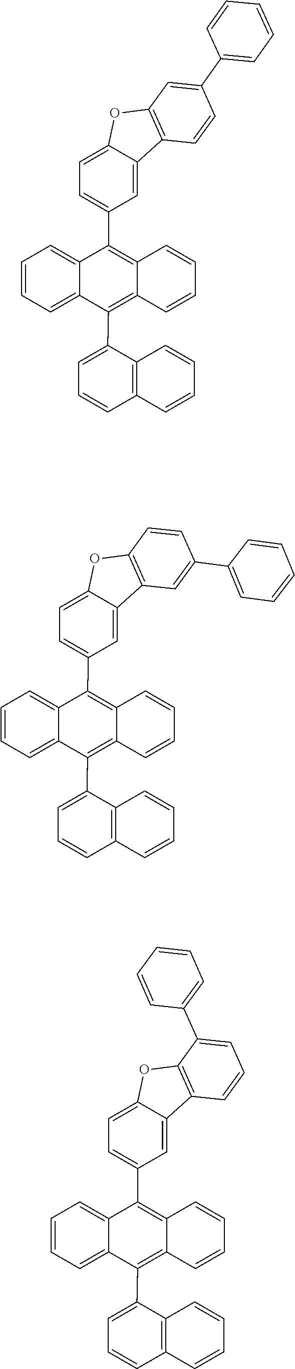 [SMILES: c1ccc(-c2ccc3c(c2)oc2ccc(-c4c5ccccc5c(-c5cccc6ccccc56)c5ccccc45)cc23)cc1 ; c1ccc(-c2ccc3oc4ccc(-c5c6ccccc6c(-c6cccc7ccccc67)c6ccccc56)cc4c3c2)cc1 ; c1ccc(-c2cccc3c2oc2ccc(-c4c5ccccc5c(-c5cccc6ccccc56)c5ccccc45)cc23)cc1]

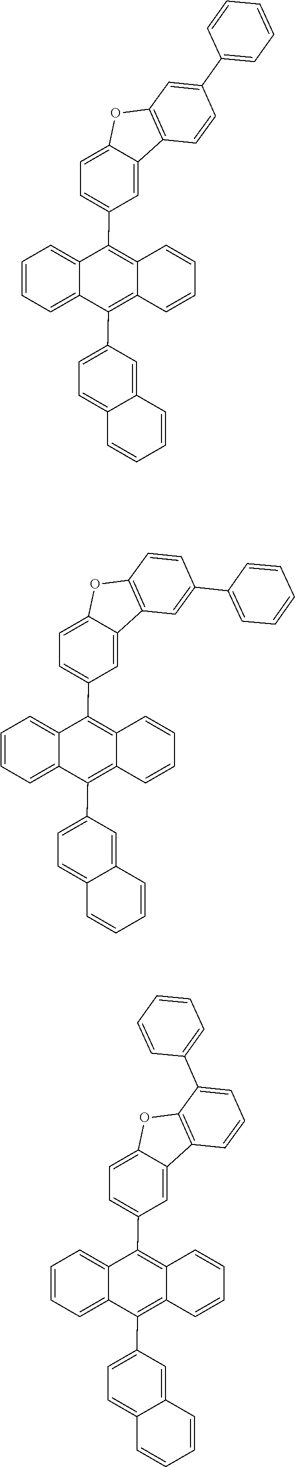 [SMILES: c1ccc(-c2ccc3c(c2)oc2ccc(-c4c5ccccc5c(-c5ccc6ccccc6c5)c5ccccc45)cc23)cc1 ; c1ccc(-c2ccc3oc4ccc(-c5c6ccccc6c(-c6ccc7ccccc7c6)c6ccccc56)cc4c3c2)cc1 ; c1ccc(-c2cccc3c2oc2ccc(-c4c5ccccc5c(-c5ccc6ccccc6c5)c5ccccc45)cc23)cc1]

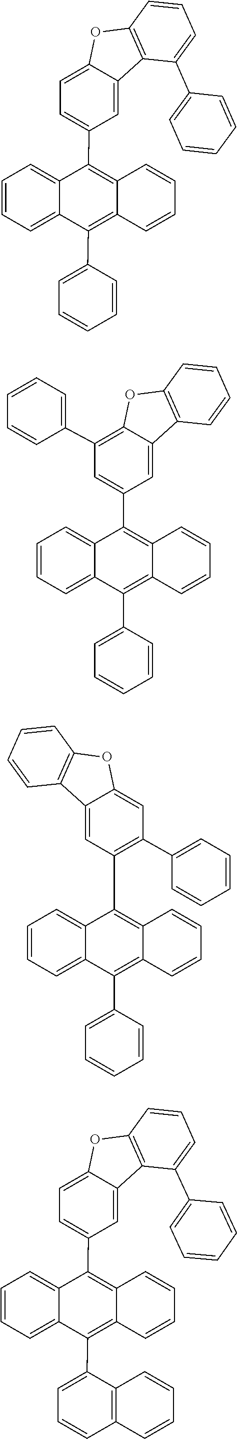 [SMILES: c1ccc(-c2c3ccccc3c(-c3ccc4oc5cccc(-c6ccccc6)c5c4c3)c3ccccc23)cc1 ; c1ccc(-c2c3ccccc3c(-c3cc(-c4ccccc4)c4oc5ccccc5c4c3)c3ccccc23)cc1 ; c1ccc(-c2cc3oc4ccccc4c3cc2-c2c3ccccc3c(-c3ccccc3)c3ccccc23)cc1 ; c1ccc(-c2cccc3oc4ccc(-c5c6ccccc6c(-c6cccc7ccccc67)c6ccccc56)cc4c23)cc1]

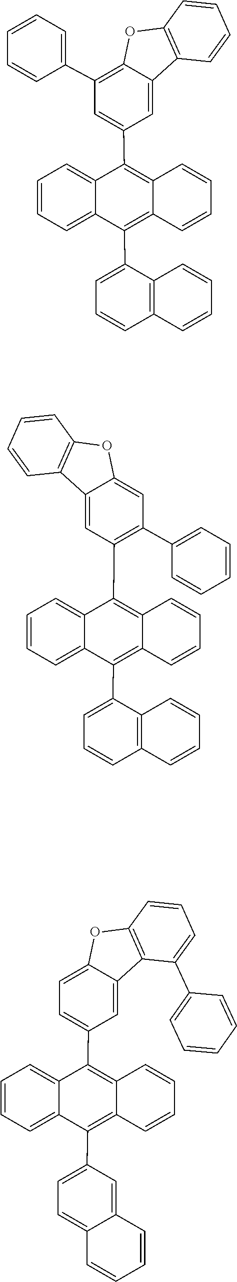 [SMILES: c1ccc(-c2cc(-c3c4ccccc4c(-c4cccc5ccccc45)c4ccccc34)cc3c2oc2ccccc23)cc1 ; c1ccc(-c2cc3oc4ccccc4c3cc2-c2c3ccccc3c(-c3cccc4ccccc34)c3ccccc23)cc1 ; c1ccc(-c2cccc3oc4ccc(-c5c6ccccc6c(-c6ccc7ccccc7c6)c6ccccc56)cc4c23)cc1]

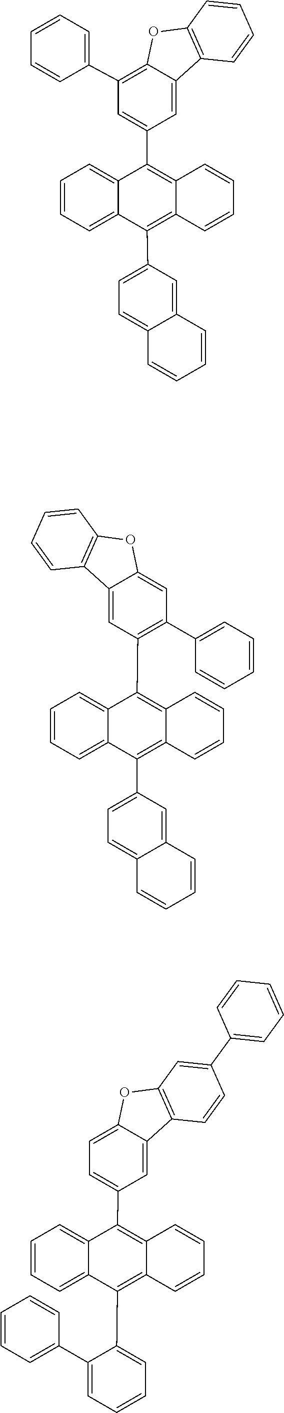 [SMILES: c1ccc(-c2cc(-c3c4ccccc4c(-c4ccc5ccccc5c4)c4ccccc34)cc3c2oc2ccccc23)cc1 ; c1ccc(-c2cc3oc4ccccc4c3cc2-c2c3ccccc3c(-c3ccc4ccccc4c3)c3ccccc23)cc1 ; c1ccc(-c2ccc3c(c2)oc2ccc(-c4c5ccccc5c(-c5ccccc5-c5ccccc5)c5ccccc45)cc23)cc1]

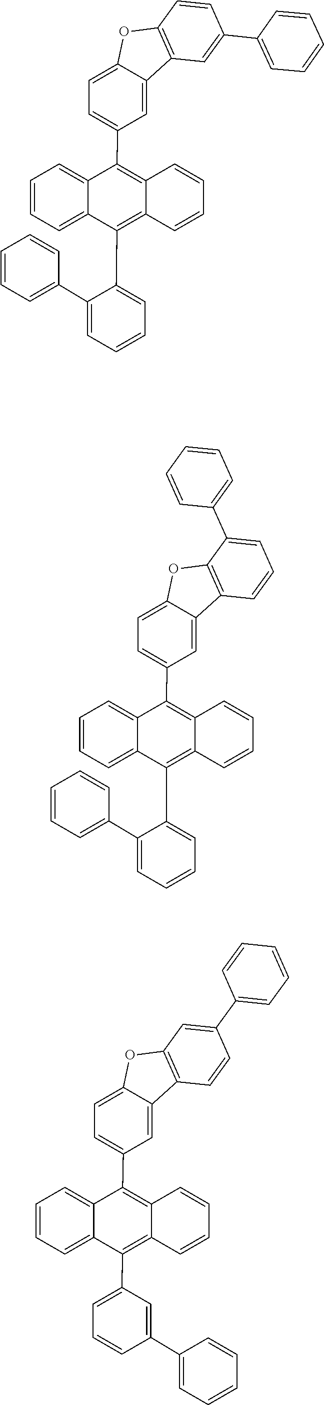 [SMILES: c1ccc(-c2ccc3oc4ccc(-c5c6ccccc6c(-c6ccccc6-c6ccccc6)c6ccccc56)cc4c3c2)cc1 ; c1ccc(-c2ccccc2-c2c3ccccc3c(-c3ccc4oc5c(-c6ccccc6)cccc5c4c3)c3ccccc23)cc1 ; c1ccc(-c2cccc(-c3c4ccccc4c(-c4ccc5oc6cc(-c7ccccc7)ccc6c5c4)c4ccccc34)c2)cc1]

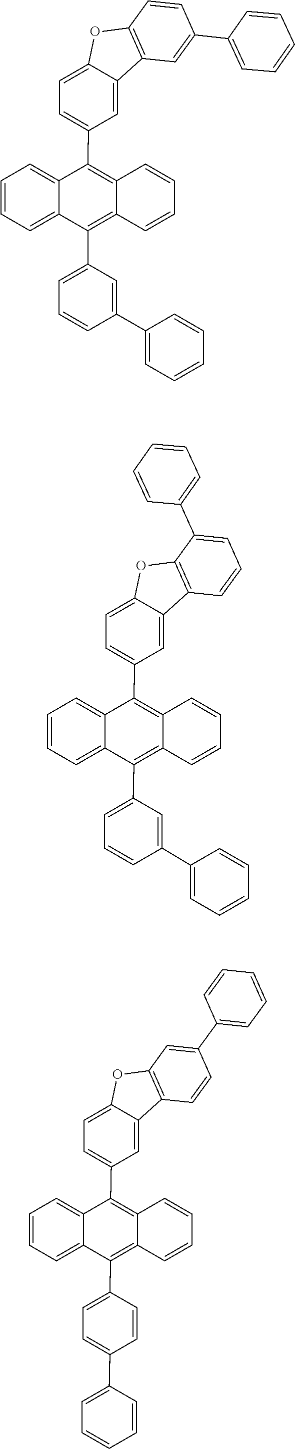 [SMILES: c1ccc(-c2cccc(-c3c4ccccc4c(-c4ccc5oc6ccc(-c7ccccc7)cc6c5c4)c4ccccc34)c2)cc1 ; c1ccc(-c2cccc(-c3c4ccccc4c(-c4ccc5oc6c(-c7ccccc7)cccc6c5c4)c4ccccc34)c2)cc1 ; c1ccc(-c2ccc(-c3c4ccccc4c(-c4ccc5oc6cc(-c7ccccc7)ccc6c5c4)c4ccccc34)cc2)cc1]

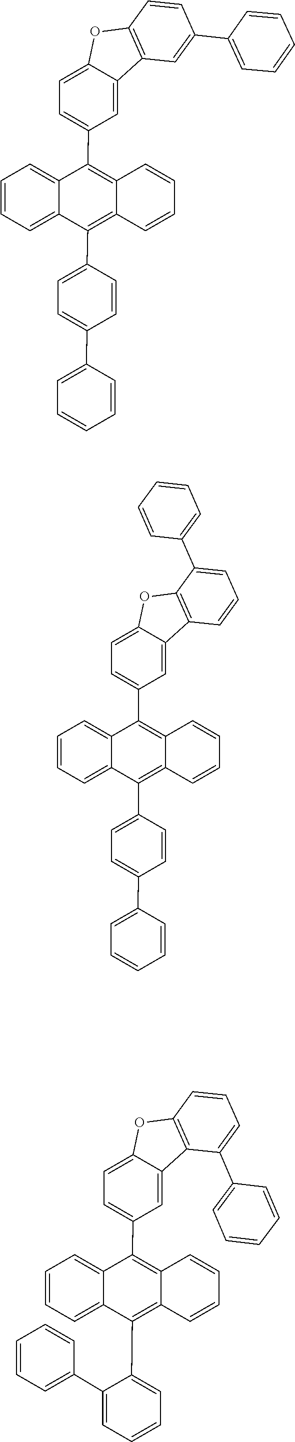 [SMILES: c1ccc(-c2ccc(-c3c4ccccc4c(-c4ccc5oc6ccc(-c7ccccc7)cc6c5c4)c4ccccc34)cc2)cc1 ; c1ccc(-c2ccc(-c3c4ccccc4c(-c4ccc5oc6c(-c7ccccc7)cccc6c5c4)c4ccccc34)cc2)cc1 ; c1ccc(-c2ccccc2-c2c3ccccc3c(-c3ccc4oc5cccc(-c6ccccc6)c5c4c3)c3ccccc23)cc1]

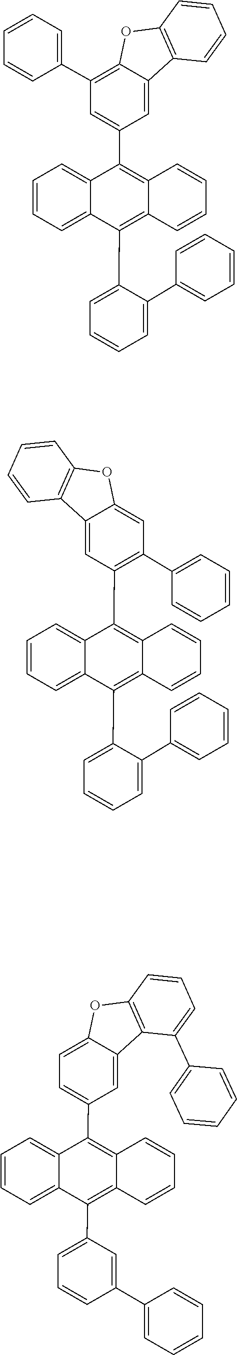 [SMILES: c1ccc(-c2ccccc2-c2c3ccccc3c(-c3cc(-c4ccccc4)c4oc5ccccc5c4c3)c3ccccc23)cc1 ; c1ccc(-c2ccccc2-c2c3ccccc3c(-c3cc4c(cc3-c3ccccc3)oc3ccccc34)c3ccccc23)cc1 ; c1ccc(-c2cccc(-c3c4ccccc4c(-c4ccc5oc6cccc(-c7ccccc7)c6c5c4)c4ccccc34)c2)cc1]

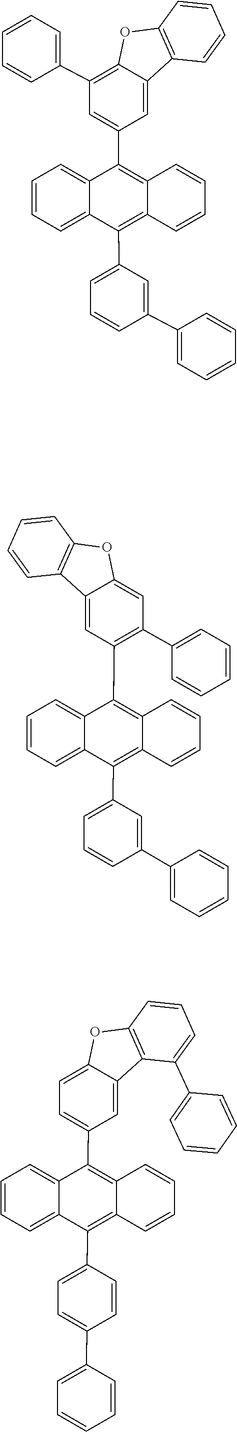 [SMILES: c1ccc(-c2cccc(-c3c4ccccc4c(-c4cc(-c5ccccc5)c5oc6ccccc6c5c4)c4ccccc34)c2)cc1 ; c1ccc(-c2cccc(-c3c4ccccc4c(-c4cc5c(cc4-c4ccccc4)oc4ccccc45)c4ccccc34)c2)cc1 ; c1ccc(-c2ccc(-c3c4ccccc4c(-c4ccc5oc6cccc(-c7ccccc7)c6c5c4)c4ccccc34)cc2)cc1]

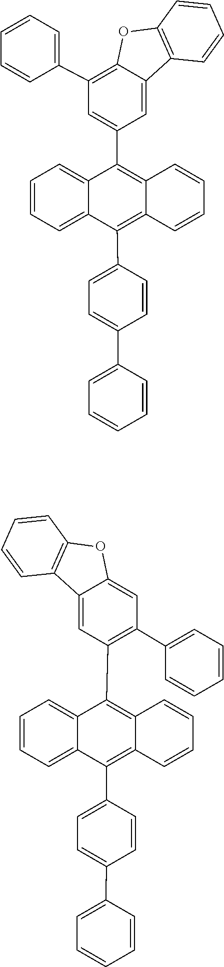 [SMILES: c1ccc(-c2ccc(-c3c4ccccc4c(-c4cc(-c5ccccc5)c5oc6ccccc6c5c4)c4ccccc34)cc2)cc1 ; c1ccc(-c2ccc(-c3c4ccccc4c(-c4cc5c(cc4-c4ccccc4)oc4ccccc45)c4ccccc34)cc2)cc1]

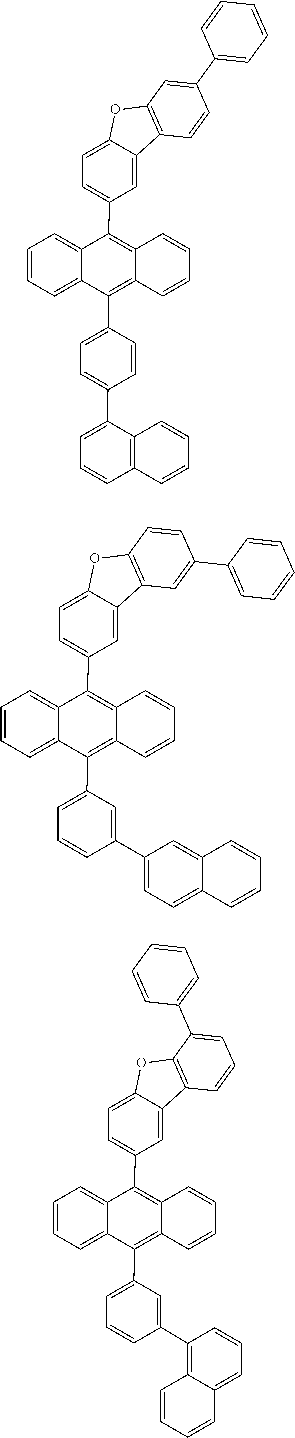

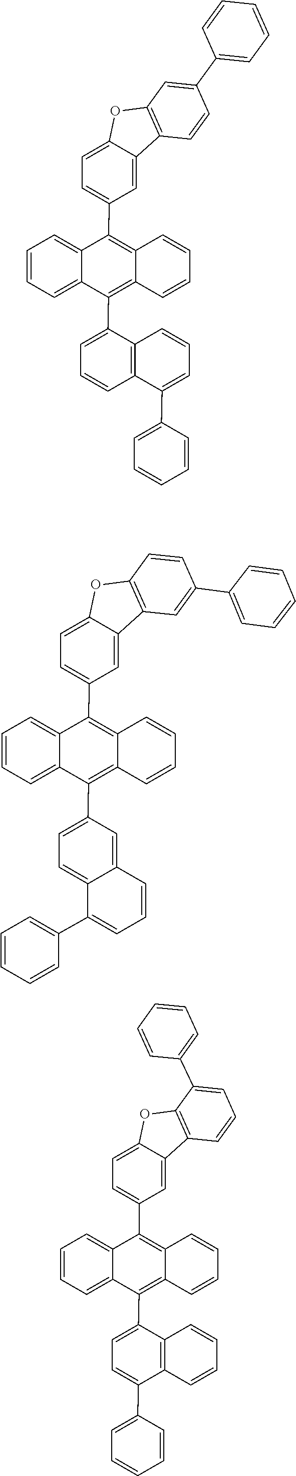 [SMILES: c1ccc(-c2ccc3c(c2)oc2ccc(-c4c5ccccc5c(-c5cccc6c(-c7ccccc7)cccc56)c5ccccc45)cc23)cc1 ; c1ccc(-c2ccc3oc4ccc(-c5c6ccccc6c(-c6ccc7c(-c8ccccc8)cccc7c6)c6ccccc56)cc4c3c2)cc1 ; c1ccc(-c2ccc(-c3c4ccccc4c(-c4ccc5oc6c(-c7ccccc7)cccc6c5c4)c4ccccc34)c3ccccc23)cc1]

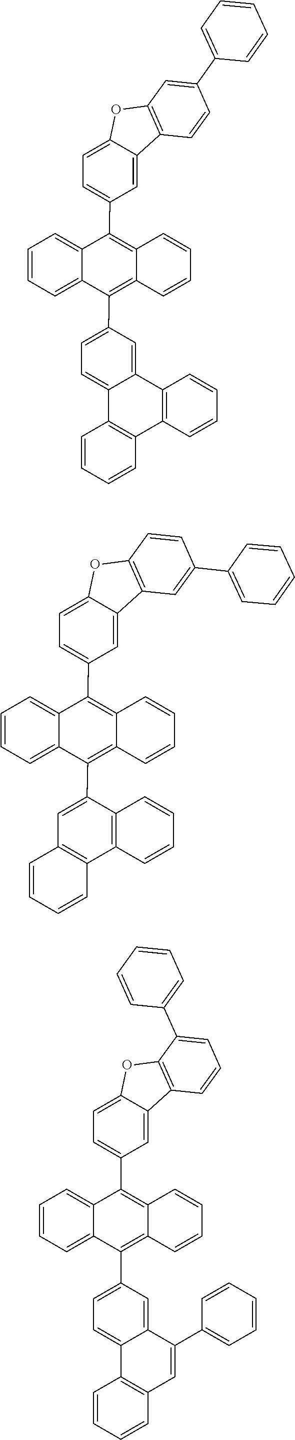 [SMILES: c1ccc(-c2ccc3c(c2)oc2ccc(-c4c5ccccc5c(-c5ccc6c7ccccc7c7ccccc7c6c5)c5ccccc45)cc23)cc1 ; c1ccc(-c2ccc3oc4ccc(-c5c6ccccc6c(-c6cc7ccccc7c7ccccc67)c6ccccc56)cc4c3c2)cc1 ; c1ccc(-c2cc3ccccc3c3ccc(-c4c5ccccc5c(-c5ccc6oc7c(-c8ccccc8)cccc7c6c5)c5ccccc45)cc23)cc1]

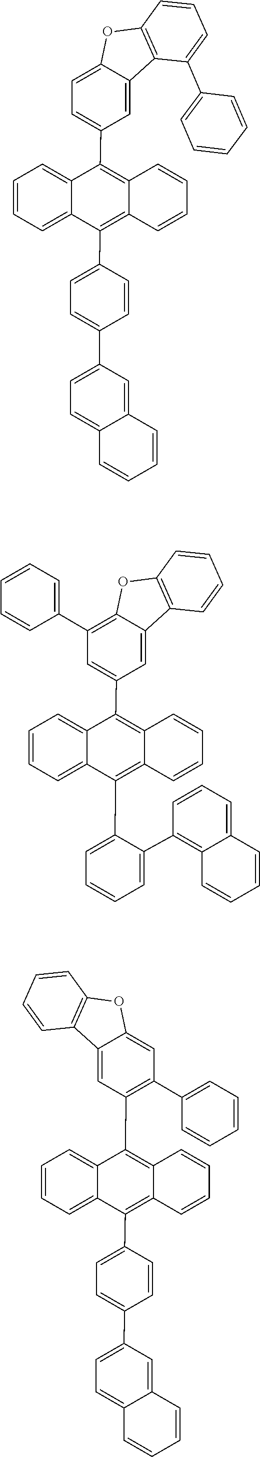 [SMILES: c1ccc(-c2cccc3oc4ccc(-c5c6ccccc6c(-c6ccc(-c7ccc8ccccc8c7)cc6)c6ccccc56)cc4c23)cc1 ; c1ccc(-c2cc(-c3c4ccccc4c(-c4ccccc4-c4cccc5ccccc45)c4ccccc34)cc3c2oc2ccccc23)cc1 ; c1ccc(-c2cc3oc4ccccc4c3cc2-c2c3ccccc3c(-c3ccc(-c4ccc5ccccc5c4)cc3)c3ccccc23)cc1]

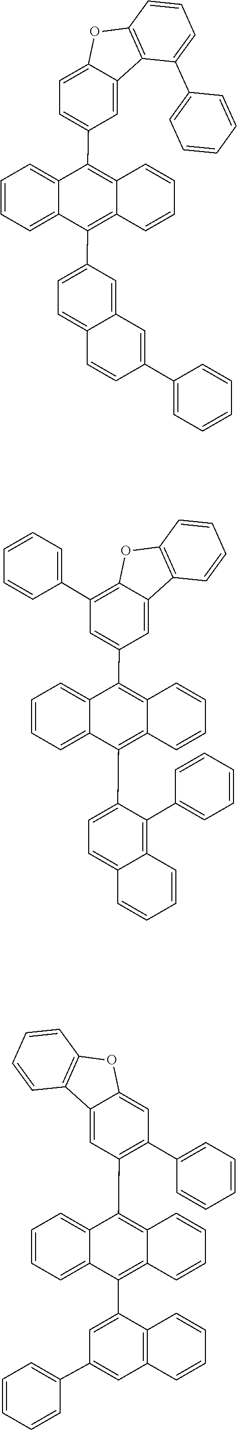 [SMILES: c1ccc(-c2ccc3ccc(-c4c5ccccc5c(-c5ccc6oc7cccc(-c8ccccc8)c7c6c5)c5ccccc45)cc3c2)cc1 ; c1ccc(-c2c(-c3c4ccccc4c(-c4cc(-c5ccccc5)c5oc6ccccc6c5c4)c4ccccc34)ccc3ccccc23)cc1 ; c1ccc(-c2cc(-c3c4ccccc4c(-c4cc5c(cc4-c4ccccc4)oc4ccccc45)c4ccccc34)c3ccccc3c2)cc1]

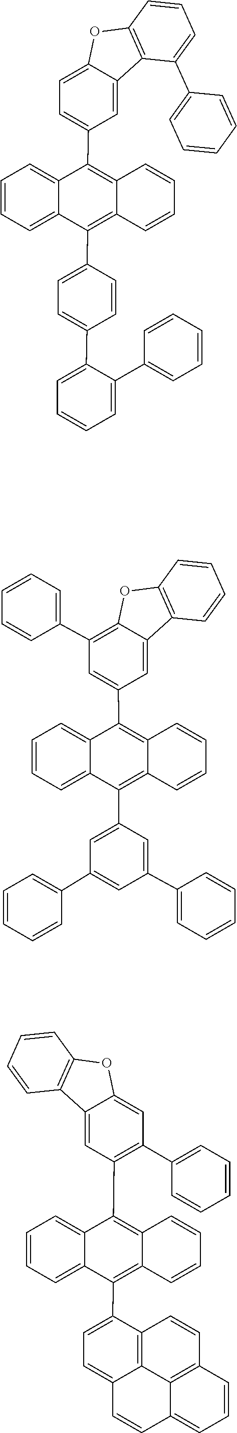 [SMILES: c1ccc(-c2ccccc2-c2ccc(-c3c4ccccc4c(-c4ccc5oc6cccc(-c7ccccc7)c6c5c4)c4ccccc34)cc2)cc1 ; c1ccc(-c2cc(-c3ccccc3)cc(-c3c4ccccc4c(-c4cc(-c5ccccc5)c5oc6ccccc6c5c4)c4ccccc34)c2)cc1 ; c1ccc(-c2cc3oc4ccccc4c3cc2-c2c3ccccc3c(-c3ccc4ccc5cccc6ccc3c4c56)c3ccccc23)cc1]

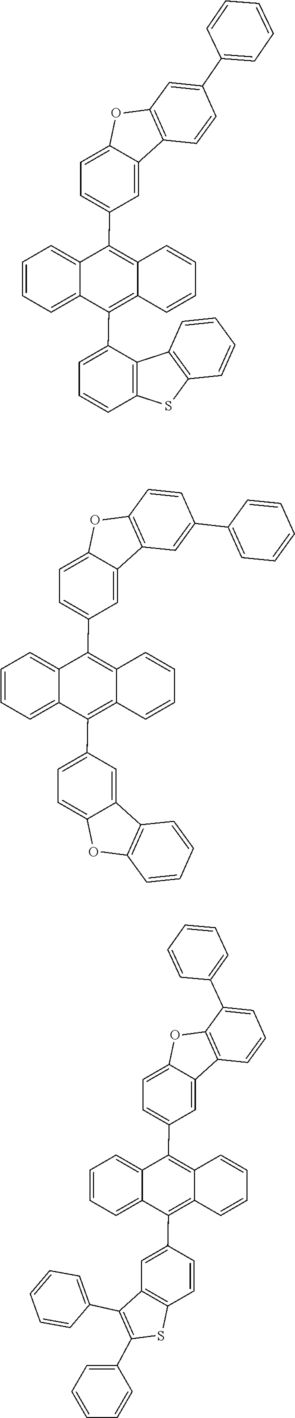

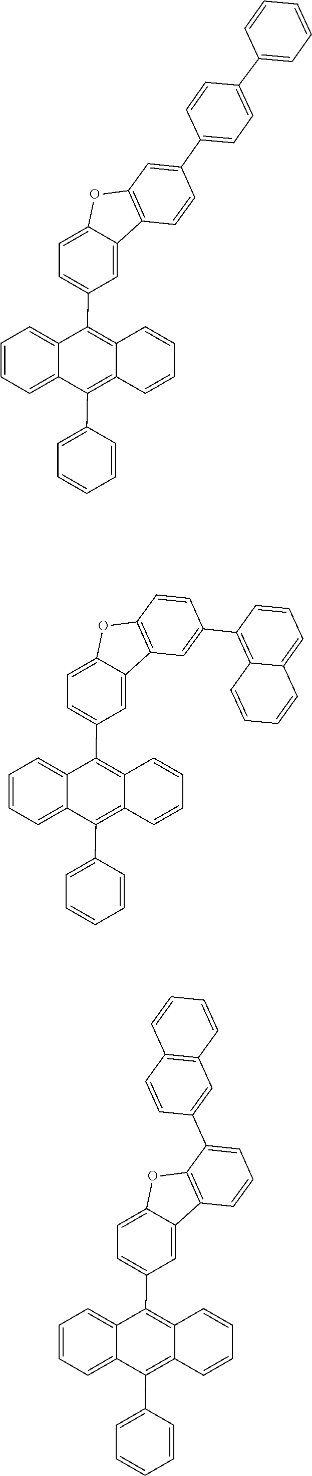 [SMILES: c1ccc(-c2ccc(-c3ccc4c(c3)oc3ccc(-c5c6ccccc6c(-c6ccccc6)c6ccccc56)cc34)cc2)cc1 ; c1ccc(-c2c3ccccc3c(-c3ccc4oc5ccc(-c6cccc7ccccc67)cc5c4c3)c3ccccc23)cc1 ; c1ccc(-c2c3ccccc3c(-c3ccc4oc5c(-c6ccc7ccccc7c6)cccc5c4c3)c3ccccc23)cc1]

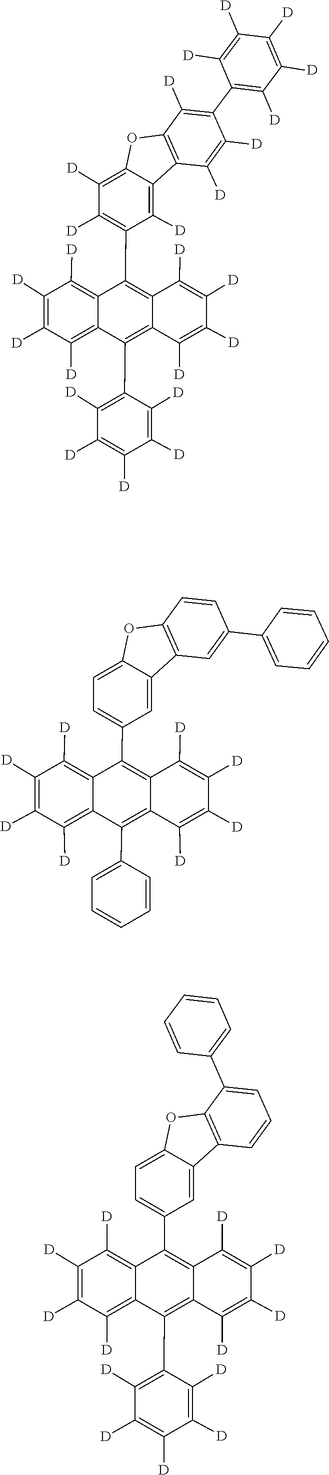 [SMILES: [2H]c1c([2H])c([2H])c(-c2c([2H])c([2H])c3c(oc4c([2H])c([2H])c(-c5c6c([2H])c([2H])c([2H])c([2H])c6c(-c6c([2H])c([2H])c([2H])c([2H])c6[2H])c6c([2H])c([2H])c([2H])c([2H])c56)c([2H])c43)c2[2H])c([2H])c1[2H] ; [2H]c1c([2H])c([2H])c2c(-c3ccc4oc5ccc(-c6ccccc6)cc5c4c3)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3ccc4oc5c(-c6ccccc6)cccc5c4c3)c3c([2H])c([2H])c([2H])c([2H])c23)c([2H])c1[2H]]

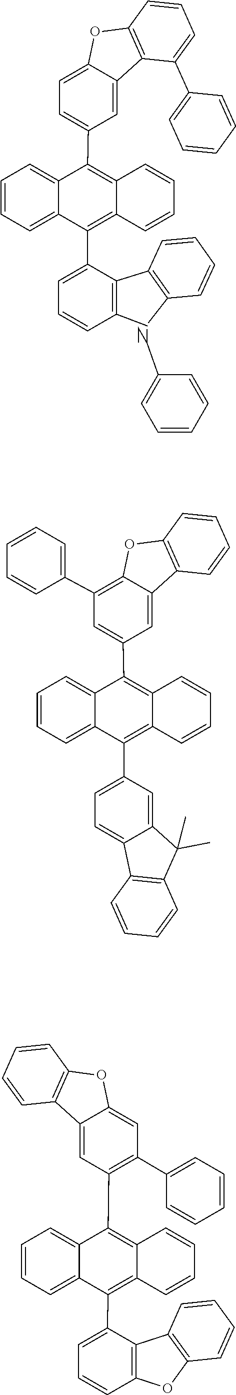 [SMILES: CCC(Cc1ccccc1-c1c(C)cccc1-c1c2ccccc2c(-c2ccc3oc4cccc(-c5ccccc5)c4c3c2)c2ccccc12)c1ccccc1 ; CC1(C)c2ccccc2-c2ccc(-c3c4ccccc4c(-c4cc(-c5ccccc5)c5oc6ccccc6c5c4)c4ccccc34)cc21 ; c1ccc(-c2cc3oc4ccccc4c3cc2-c2c3ccccc3c(-c3cccc4oc5ccccc5c34)c3ccccc23)cc1]

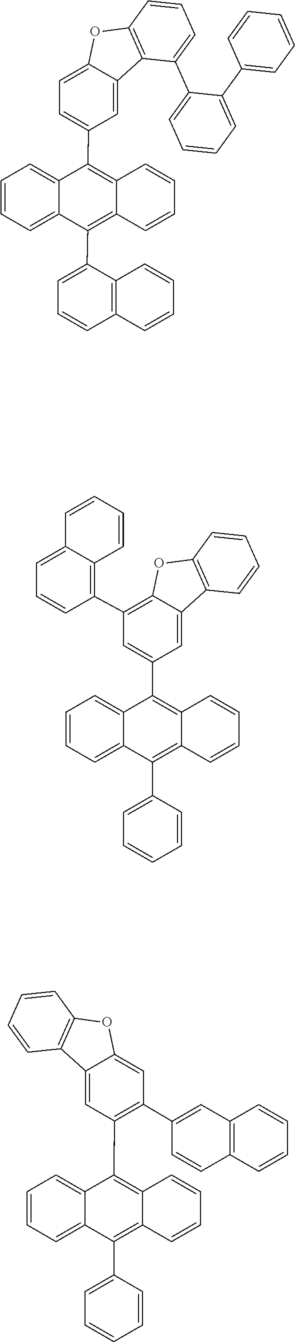 [SMILES: c1ccc(-c2ccccc2-c2cccc3oc4ccc(-c5c6ccccc6c(-c6cccc7ccccc67)c6ccccc56)cc4c23)cc1 ; c1ccc(-c2c3ccccc3c(-c3cc(-c4cccc5ccccc45)c4oc5ccccc5c4c3)c3ccccc23)cc1 ; c1ccc(-c2c3ccccc3c(-c3cc4c(cc3-c3ccc5ccccc5c3)oc3ccccc34)c3ccccc23)cc1]

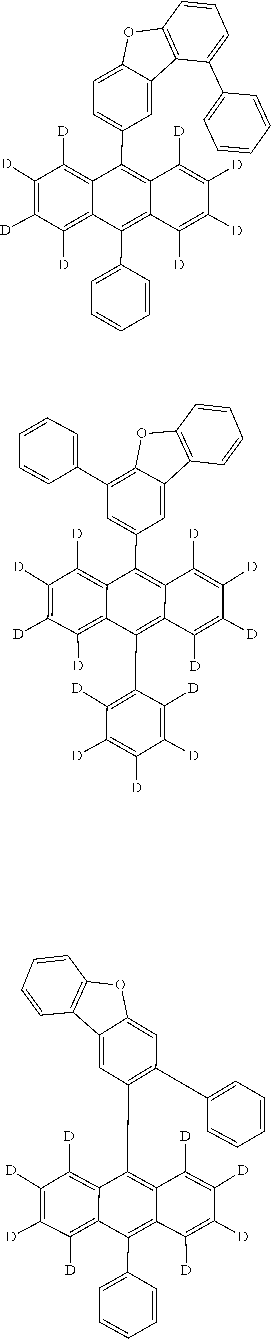 [SMILES: [2H]c1c([2H])c([2H])c2c(-c3ccc4oc5cccc(-c6ccccc6)c5c4c3)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3cc(-c4ccccc4)c4oc5ccccc5c4c3)c3c([2H])c([2H])c([2H])c([2H])c23)c([2H])c1[2H] ; [2H]c1c([2H])c([2H])c2c(-c3cc4c(cc3-c3ccccc3)oc3ccccc34)c3c([2H])c([2H])c([2H])c([2H])c3c(-c3ccccc3)c2c1[2H]]

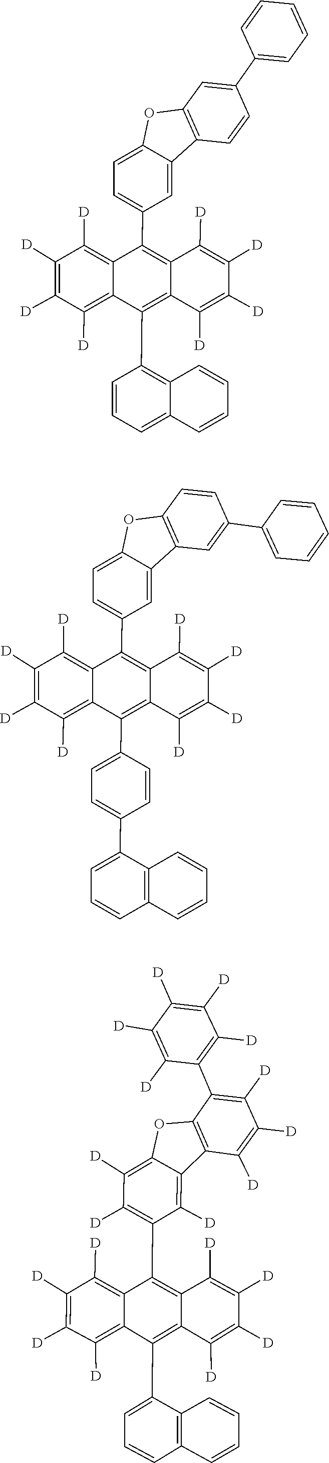 [SMILES: [2H]c1c([2H])c([2H])c2c(-c3cccc4ccccc34)c3c([2H])c([2H])c([2H])c([2H])c3c(-c3ccc4oc5cc(-c6ccccc6)ccc5c4c3)c2c1[2H] ; [2H]c1c([2H])c([2H])c2c(-c3ccc4oc5ccc(-c6ccccc6)cc5c4c3)c3c([2H])c([2H])c([2H])c([2H])c3c(-c3ccc(-c4cccc5ccccc45)cc3)c2c1[2H] ; [2H]c1c([2H])c([2H])c(-c2c([2H])c([2H])c([2H])c3c2oc2c([2H])c([2H])c(-c4c5c([2H])c([2H])c([2H])c([2H])c5c(-c5cccc6ccccc56)c5c([2H])c([2H])c([2H])c([2H])c45)c([2H])c23)c([2H])c1[2H]]

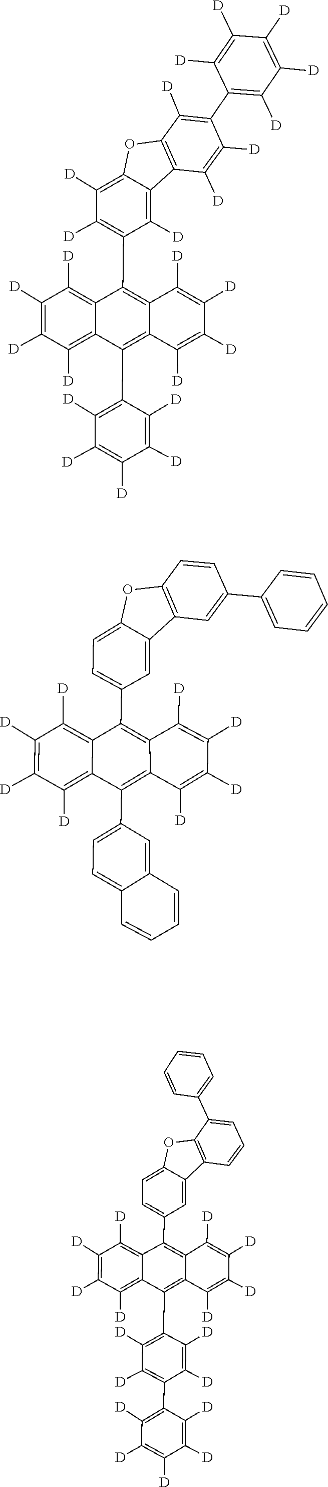 [SMILES: [2H]c1c([2H])c([2H])c(-c2c([2H])c([2H])c3c(oc4c([2H])c([2H])c(-c5c6c([2H])c([2H])c([2H])c([2H])c6c(-c6c([2H])c([2H])c([2H])c([2H])c6[2H])c6c([2H])c([2H])c([2H])c([2H])c56)c([2H])c43)c2[2H])c([2H])c1[2H] ; [2H]c1c([2H])c([2H])c2c(-c3ccc4oc5ccc(-c6ccccc6)cc5c4c3)c3c([2H])c([2H])c([2H])c([2H])c3c(-c3ccc4ccccc4c3)c2c1[2H] ; [2H]c1c([2H])c([2H])c(-c2c([2H])c([2H])c(-c3c4c([2H])c([2H])c([2H])c([2H])c4c(-c4ccc5oc6c(-c7ccccc7)cccc6c5c4)c4c([2H])c([2H])c([2H])c([2H])c34)c([2H])c2[2H])c([2H])c1[2H]]

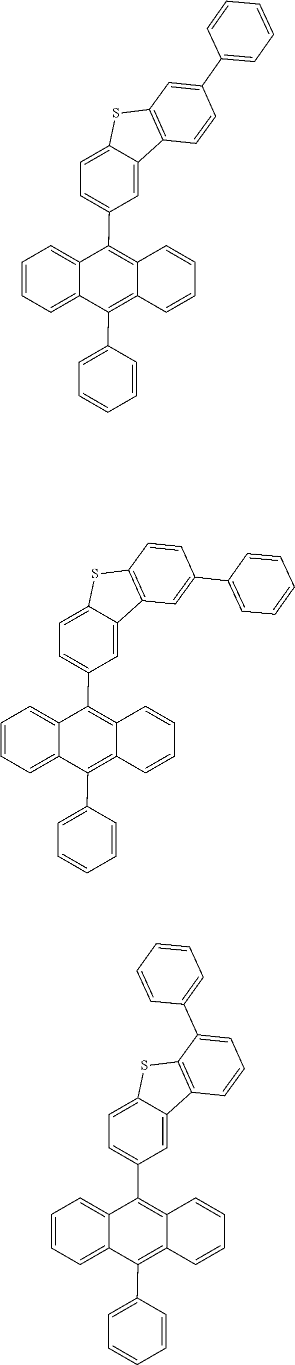 [SMILES: c1ccc(-c2ccc3c(c2)sc2ccc(-c4c5ccccc5c(-c5ccccc5)c5ccccc45)cc23)cc1 ; c1ccc(-c2ccc3sc4ccc(-c5c6ccccc6c(-c6ccccc6)c6ccccc56)cc4c3c2)cc1 ; c1ccc(-c2c3ccccc3c(-c3ccc4sc5c(-c6ccccc6)cccc5c4c3)c3ccccc23)cc1]

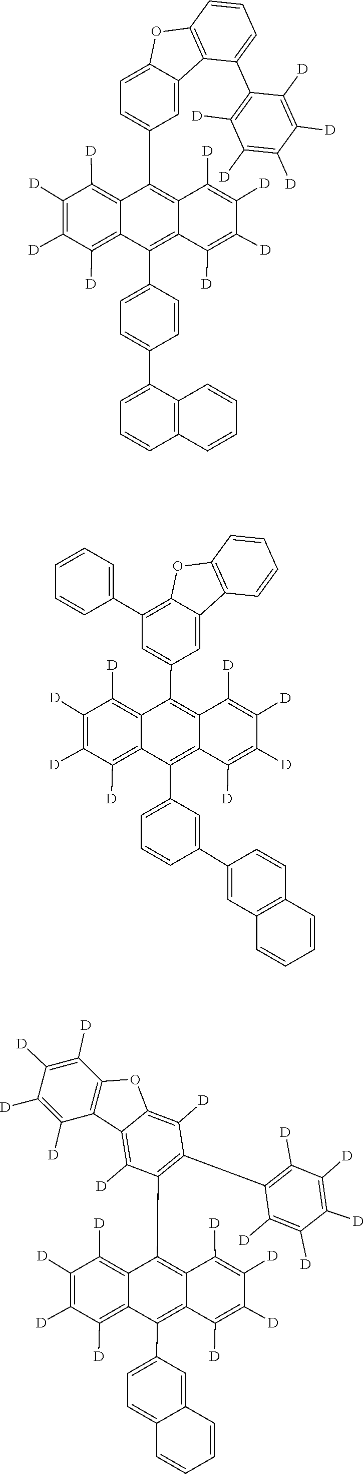 [SMILES: [2H]c1c([2H])c([2H])c(-c2cccc3oc4ccc(-c5c6c([2H])c([2H])c([2H])c([2H])c6c(-c6ccc(-c7cccc8ccccc78)cc6)c6c([2H])c([2H])c([2H])c([2H])c56)cc4c23)c([2H])c1[2H] ; [2H]c1c([2H])c([2H])c2c(-c3cc(-c4ccccc4)c4oc5ccccc5c4c3)c3c([2H])c([2H])c([2H])c([2H])c3c(-c3cccc(-c4ccc5ccccc5c4)c3)c2c1[2H] ; [2H]c1c([2H])c([2H])c(-c2c(-c3c4c([2H])c([2H])c([2H])c([2H])c4c(-c4ccc5ccccc5c4)c4c([2H])c([2H])c([2H])c([2H])c34)c([2H])c3c(oc4c([2H])c([2H])c([2H])c([2H])c43)c2[2H])c([2H])c1[2H]]

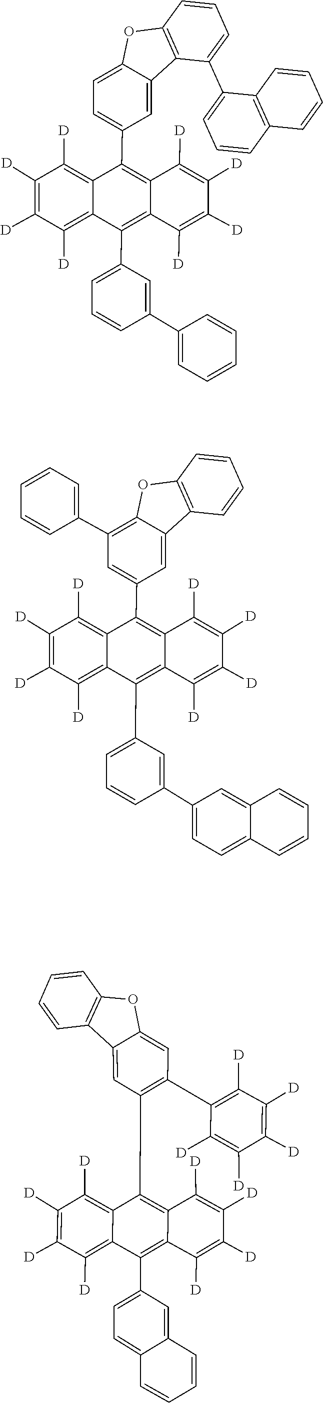 [SMILES: [2H]c1c([2H])c([2H])c2c(-c3ccc4oc5cccc(-c6cccc7ccccc67)c5c4c3)c3c([2H])c([2H])c([2H])c([2H])c3c(-c3cccc(-c4ccccc4)c3)c2c1[2H] ; [2H]c1c([2H])c([2H])c2c(-c3cc(-c4ccccc4)c4oc5ccccc5c4c3)c3c([2H])c([2H])c([2H])c([2H])c3c(-c3cccc(-c4ccc5ccccc5c4)c3)c2c1[2H] ; [2H]c1c([2H])c([2H])c(-c2cc3oc4ccccc4c3cc2-c2c3c([2H])c([2H])c([2H])c([2H])c3c(-c3ccc4ccccc4c3)c3c([2H])c([2H])c([2H])c([2H])c23)c([2H])c1[2H]]

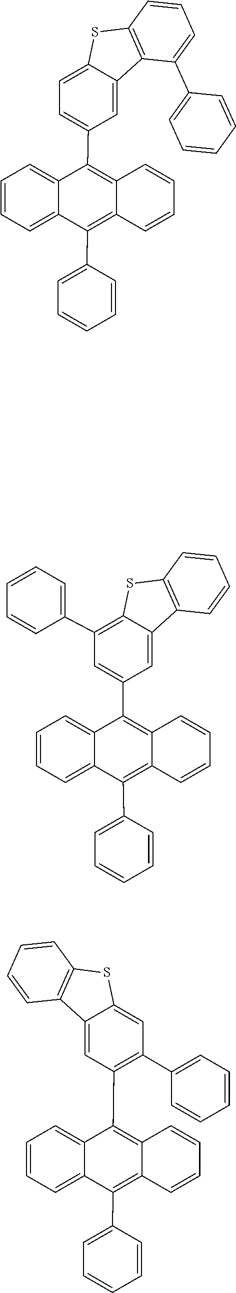 [SMILES: c1ccc(-c2c3ccccc3c(-c3ccc4sc5cccc(-c6ccccc6)c5c4c3)c3ccccc23)cc1 ; c1ccc(-c2c3ccccc3c(-c3cc(-c4ccccc4)c4sc5ccccc5c4c3)c3ccccc23)cc1 ; c1ccc(-c2cc3sc4ccccc4c3cc2-c2c3ccccc3c(-c3ccccc3)c3ccccc23)cc1]

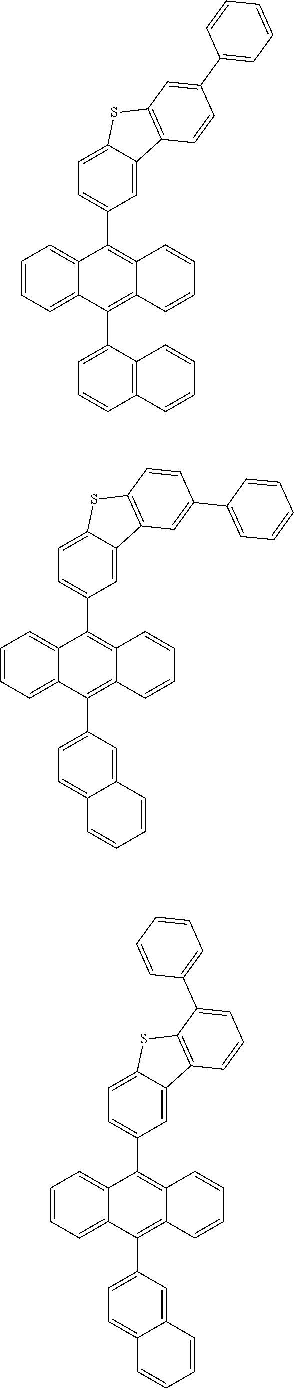 [SMILES: c1ccc(-c2ccc3c(c2)sc2ccc(-c4c5ccccc5c(-c5cccc6ccccc56)c5ccccc45)cc23)cc1 ; c1ccc(-c2ccc3sc4ccc(-c5c6ccccc6c(-c6ccc7ccccc7c6)c6ccccc56)cc4c3c2)cc1 ; c1ccc(-c2cccc3c2sc2ccc(-c4c5ccccc5c(-c5ccc6ccccc6c5)c5ccccc45)cc23)cc1]

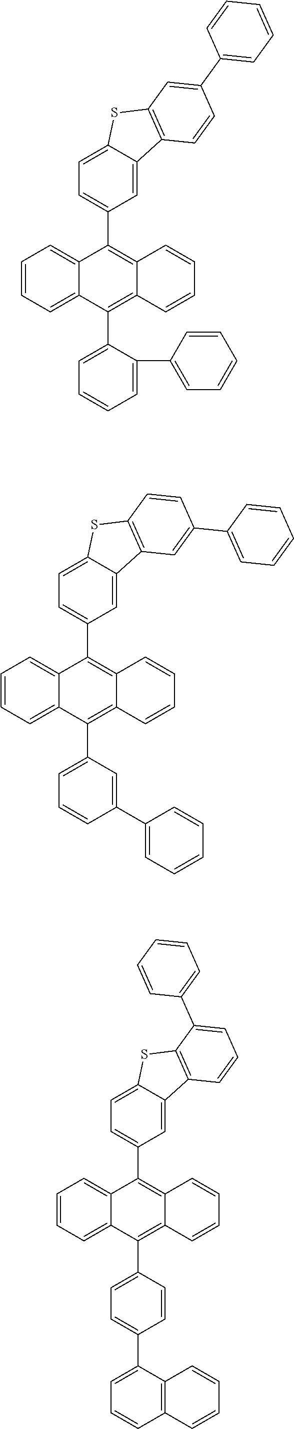 [SMILES: c1ccc(-c2ccc3c(c2)sc2ccc(-c4c5ccccc5c(-c5ccccc5-c5ccccc5)c5ccccc45)cc23)cc1 ; c1ccc(-c2cccc(-c3c4ccccc4c(-c4ccc5sc6ccc(-c7ccccc7)cc6c5c4)c4ccccc34)c2)cc1 ; c1ccc(-c2cccc3c2sc2ccc(-c4c5ccccc5c(-c5ccc(-c6cccc7ccccc67)cc5)c5ccccc45)cc23)cc1]

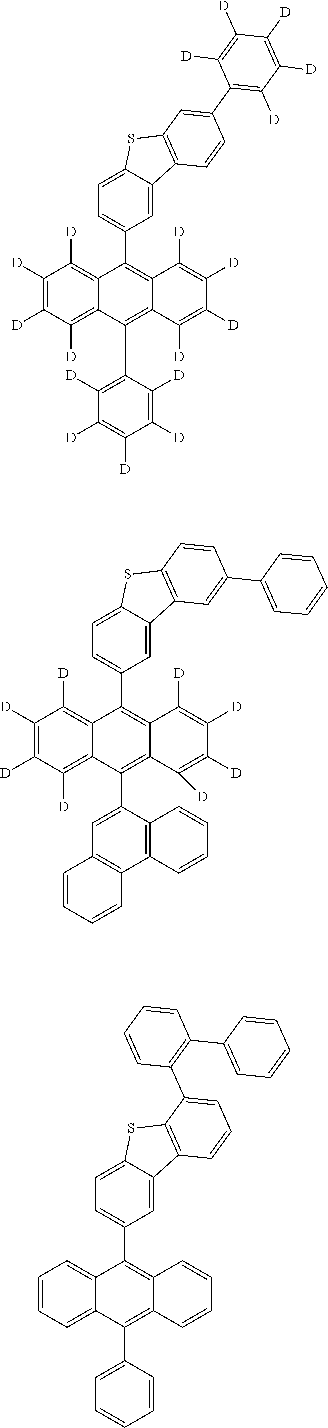 [SMILES: [2H]c1c([2H])c([2H])c(-c2ccc3c(c2)sc2ccc(-c4c5c([2H])c([2H])c([2H])c([2H])c5c(-c5c([2H])c([2H])c([2H])c([2H])c5[2H])c5c([2H])c([2H])c([2H])c([2H])c45)cc23)c([2H])c1[2H] ; [2H]c1c([2H])c([2H])c2c(-c3cc4ccccc4c4ccccc34)c3c([2H])c([2H])c([2H])c([2H])c3c(-c3ccc4sc5ccc(-c6ccccc6)cc5c4c3)c2c1[2H] ; c1ccc(-c2ccccc2-c2cccc3c2sc2ccc(-c4c5ccccc5c(-c5ccccc5)c5ccccc45)cc23)cc1]

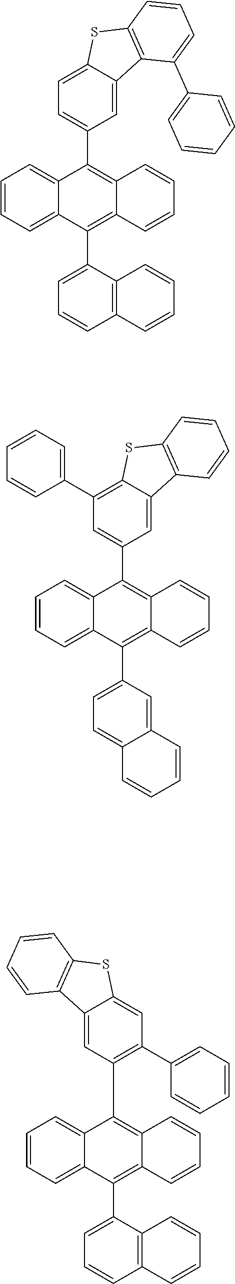 [SMILES: c1ccc(-c2cccc3sc4ccc(-c5c6ccccc6c(-c6cccc7ccccc67)c6ccccc56)cc4c23)cc1 ; c1ccc(-c2cc(-c3c4ccccc4c(-c4ccc5ccccc5c4)c4ccccc34)cc3c2sc2ccccc23)cc1 ; c1ccc(-c2cc3sc4ccccc4c3cc2-c2c3ccccc3c(-c3cccc4ccccc34)c3ccccc23)cc1]

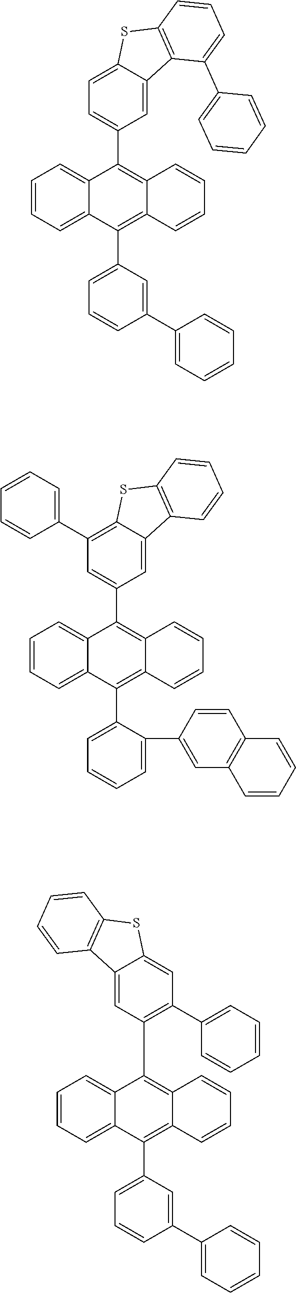 [SMILES: c1ccc(-c2cccc(-c3c4ccccc4c(-c4ccc5sc6cccc(-c7ccccc7)c6c5c4)c4ccccc34)c2)cc1 ; c1ccc(-c2cc(-c3c4ccccc4c(-c4ccccc4-c4ccc5ccccc5c4)c4ccccc34)cc3c2sc2ccccc23)cc1 ; c1ccc(-c2cccc(-c3c4ccccc4c(-c4cc5c(cc4-c4ccccc4)sc4ccccc45)c4ccccc34)c2)cc1]

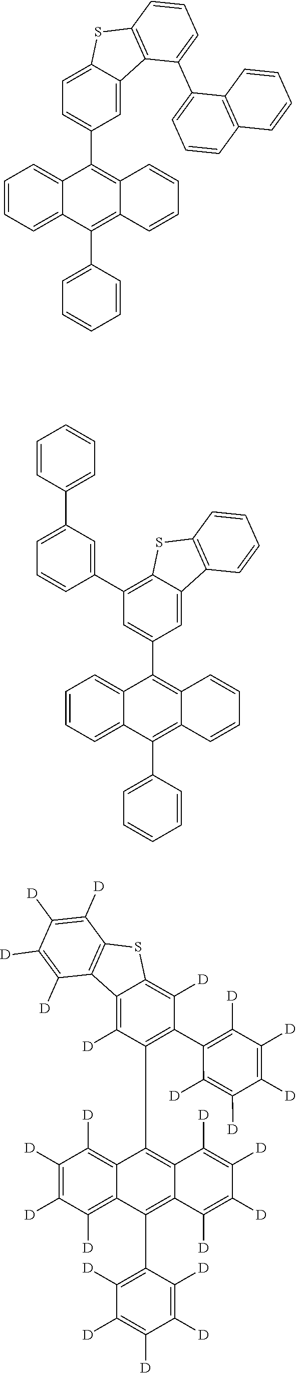 [SMILES: c1ccc(-c2c3ccccc3c(-c3ccc4sc5cccc(-c6cccc7ccccc67)c5c4c3)c3ccccc23)cc1 ; c1ccc(-c2cccc(-c3cc(-c4c5ccccc5c(-c5ccccc5)c5ccccc45)cc4c3sc3ccccc34)c2)cc1 ; [2H]c1c([2H])c([2H])c(-c2c(-c3c4c([2H])c([2H])c([2H])c([2H])c4c(-c4c([2H])c([2H])c([2H])c([2H])c4[2H])c4c([2H])c([2H])c([2H])c([2H])c34)c([2H])c3c(sc4c([2H])c([2H])c([2H])c([2H])c43)c2[2H])c([2H])c1[2H]]

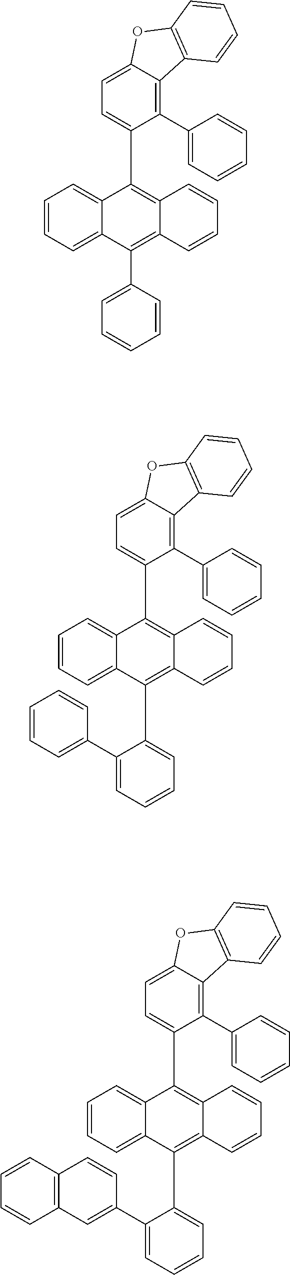 [SMILES: c1ccc(-c2c3ccccc3c(-c3ccc4oc5ccccc5c4c3-c3ccccc3)c3ccccc23)cc1 ; c1ccc(-c2ccccc2-c2c3ccccc3c(-c3ccc4oc5ccccc5c4c3-c3ccccc3)c3ccccc23)cc1 ; c1ccc(-c2c(-c3c4ccccc4c(-c4ccccc4-c4ccc5ccccc5c4)c4ccccc34)ccc3oc4ccccc4c23)cc1]

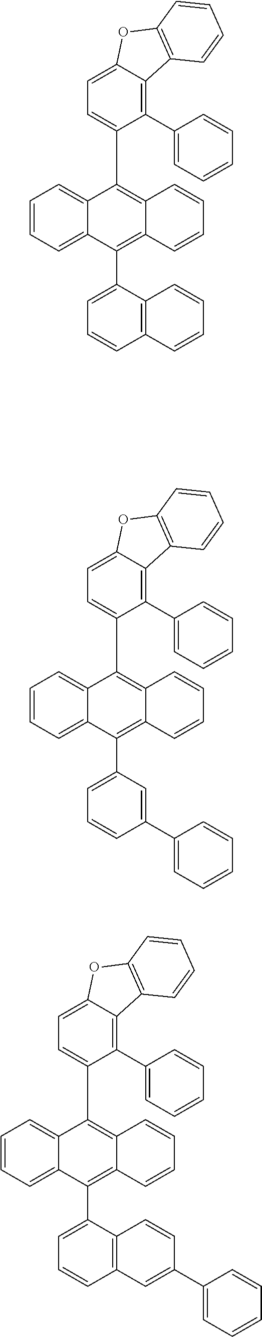 [SMILES: c1ccc(-c2c(-c3c4ccccc4c(-c4cccc5ccccc45)c4ccccc34)ccc3oc4ccccc4c23)cc1 ; c1ccc(-c2cccc(-c3c4ccccc4c(-c4ccc5oc6ccccc6c5c4-c4ccccc4)c4ccccc34)c2)cc1 ; c1ccc(-c2ccc3c(-c4c5ccccc5c(-c5ccc6oc7ccccc7c6c5-c5ccccc5)c5ccccc45)cccc3c2)cc1]

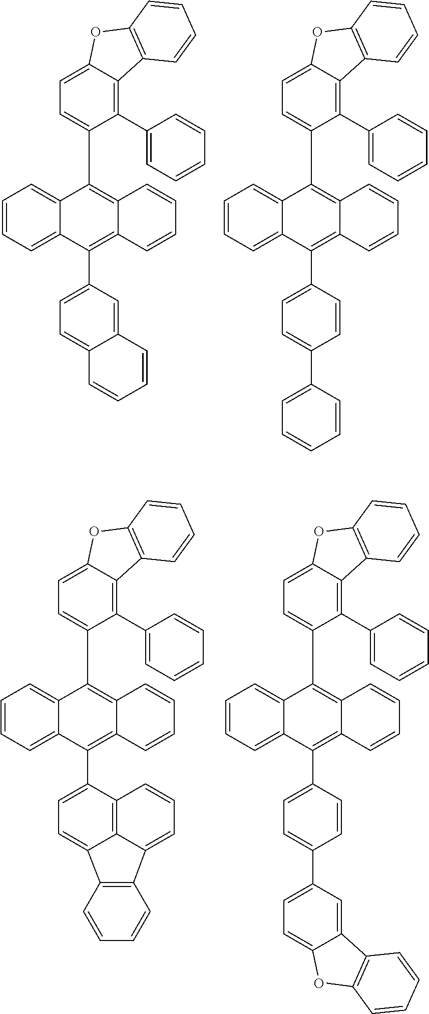

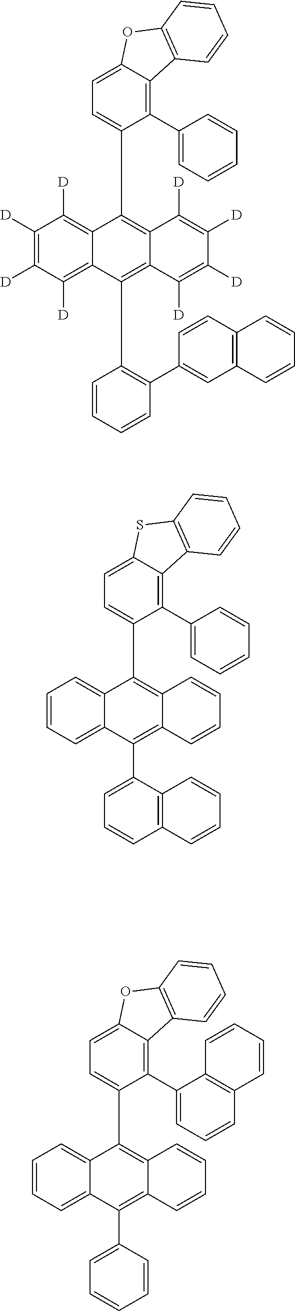 [SMILES: [2H]c1c([2H])c([2H])c2c(-c3ccc4oc5ccccc5c4c3-c3ccccc3)c3c([2H])c([2H])c([2H])c([2H])c3c(-c3ccccc3-c3ccc4ccccc4c3)c2c1[2H] ; c1ccc(-c2c(-c3c4ccccc4c(-c4cccc5ccccc45)c4ccccc34)ccc3sc4ccccc4c23)cc1 ; c1ccc(-c2c3ccccc3c(-c3ccc4oc5ccccc5c4c3-c3cccc4ccccc34)c3ccccc23)cc1]

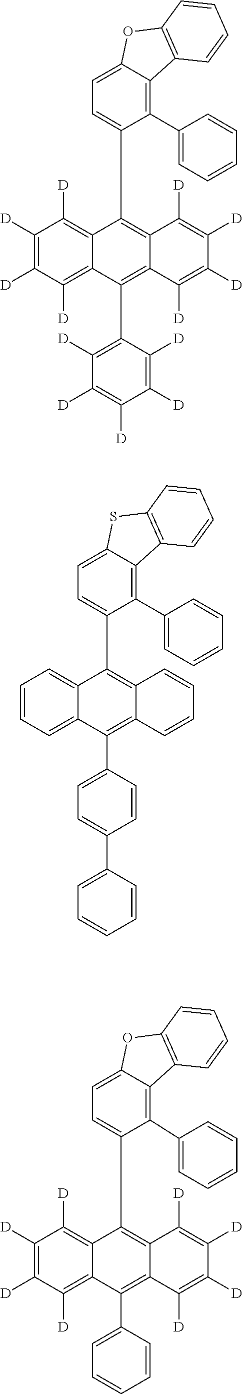 [SMILES: [2H]c1c([2H])c([2H])c(-c2c3c([2H])c([2H])c([2H])c([2H])c3c(-c3ccc4oc5ccccc5c4c3-c3ccccc3)c3c([2H])c([2H])c([2H])c([2H])c23)c([2H])c1[2H] ; c1ccc(-c2ccc(-c3c4ccccc4c(-c4ccc5sc6ccccc6c5c4-c4ccccc4)c4ccccc34)cc2)cc1 ; [2H]c1c([2H])c([2H])c2c(-c3ccc4oc5ccccc5c4c3-c3ccccc3)c3c([2H])c([2H])c([2H])c([2H])c3c(-c3ccccc3)c2c1[2H]]

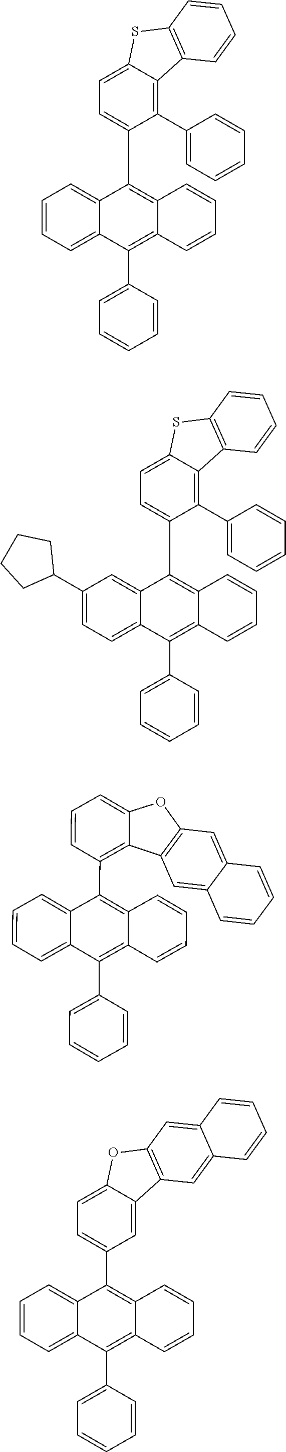 [SMILES: c1ccc(-c2c3ccccc3c(-c3ccc4sc5ccccc5c4c3-c3ccccc3)c3ccccc23)cc1 ; c1ccc(-c2c3ccccc3c(-c3ccc4sc5ccccc5c4c3-c3ccccc3)c3cc(C4CCCC4)ccc23)cc1 ; c1ccc(-c2c3ccccc3c(-c3cccc4oc5cc6ccccc6cc5c34)c3ccccc23)cc1 ; c1ccc(-c2c3ccccc3c(-c3ccc4oc5cc6ccccc6cc5c4c3)c3ccccc23)cc1]

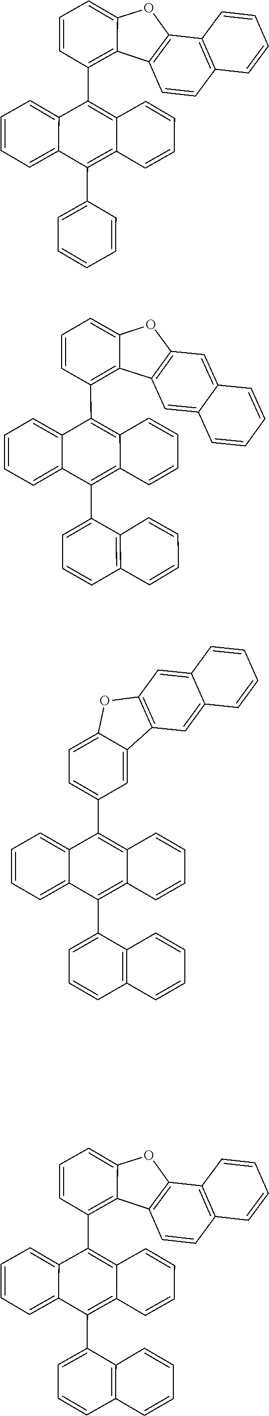 [SMILES: c1ccc(-c2c3ccccc3c(-c3cccc4oc5c6ccccc6ccc5c34)c3ccccc23)cc1 ; c1ccc2cc3c(cc2c1)oc1cccc(-c2c4ccccc4c(-c4cccc5ccccc45)c4ccccc24)c13 ; c1ccc2cc3c(cc2c1)oc1ccc(-c2c4ccccc4c(-c4cccc5ccccc45)c4ccccc24)cc13 ; c1ccc2c(-c3c4ccccc4c(-c4cccc5oc6c7ccccc7ccc6c45)c4ccccc34)cccc2c1]

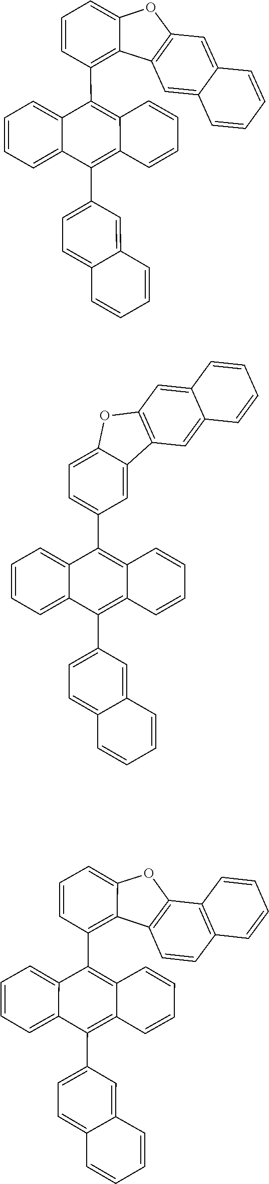 [SMILES: c1ccc2cc(-c3c4ccccc4c(-c4cccc5oc6cc7ccccc7cc6c45)c4ccccc34)ccc2c1 ; c1ccc2cc(-c3c4ccccc4c(-c4ccc5oc6cc7ccccc7cc6c5c4)c4ccccc34)ccc2c1 ; c1ccc2cc(-c3c4ccccc4c(-c4cccc5oc6c7ccccc7ccc6c45)c4ccccc34)ccc2c1]

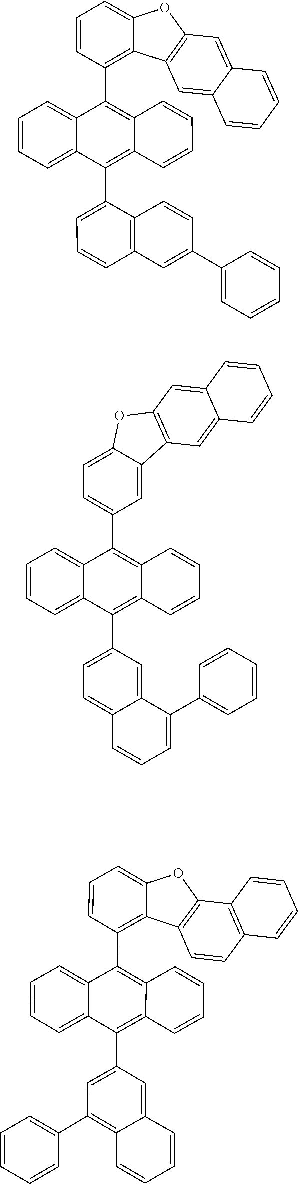 [SMILES: c1ccc(-c2ccc3c(-c4c5ccccc5c(-c5cccc6oc7cc8ccccc8cc7c56)c5ccccc45)cccc3c2)cc1 ; c1ccc(-c2cccc3ccc(-c4c5ccccc5c(-c5ccc6oc7cc8ccccc8cc7c6c5)c5ccccc45)cc23)cc1 ; c1ccc(-c2cc(-c3c4ccccc4c(-c4cccc5oc6c7ccccc7ccc6c45)c4ccccc34)cc3ccccc23)cc1]

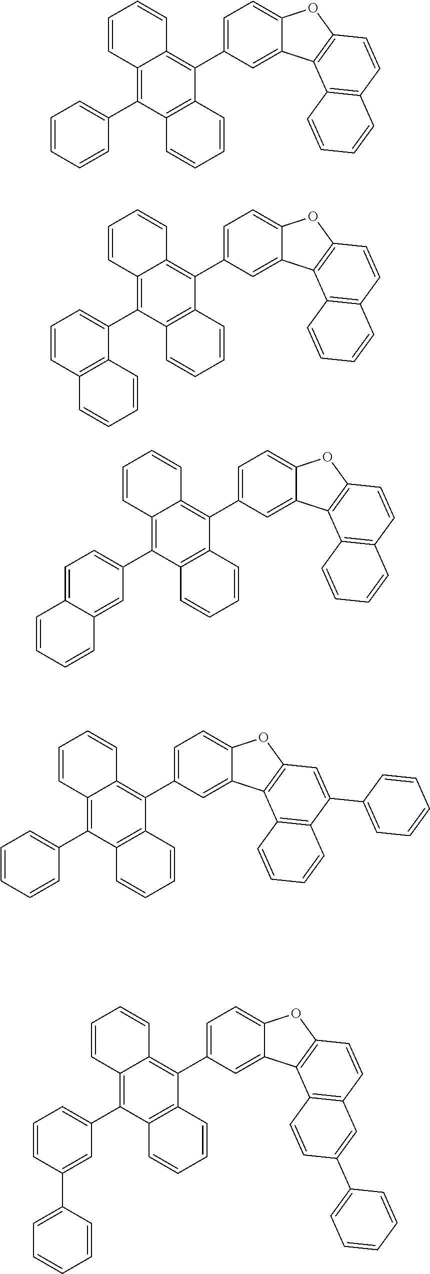

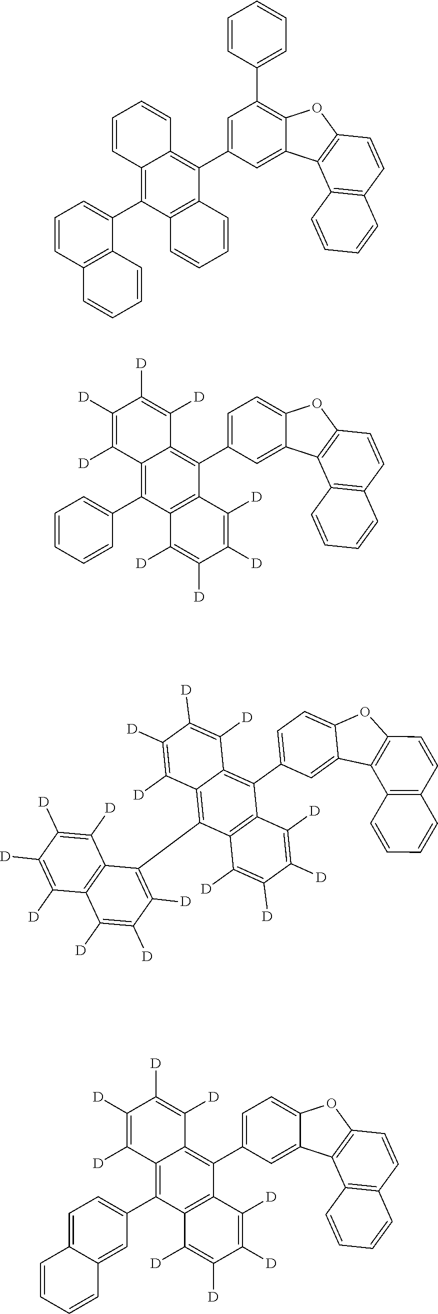 [SMILES: c1ccc(-c2cc(-c3c4ccccc4c(-c4cccc5ccccc45)c4ccccc34)cc3c2oc2ccc4ccccc4c23)cc1 ; [2H]c1c([2H])c([2H])c2c(-c3ccc4oc5ccc6ccccc6c5c4c3)c3c([2H])c([2H])c([2H])c([2H])c3c(-c3ccccc3)c2c1[2H] ; [2H]c1c([2H])c([2H])c2c(-c3c4c([2H])c([2H])c([2H])c([2H])c4c(-c4ccc5oc6ccc7ccccc7c6c5c4)c4c([2H])c([2H])c([2H])c([2H])c34)c([2H])c([2H])c([2H])c2c1[2H] ; [2H]c1c([2H])c([2H])c2c(-c3ccc4oc5ccc6ccccc6c5c4c3)c3c([2H])c([2H])c([2H])c([2H])c3c(-c3ccc4ccccc4c3)c2c1[2H]]

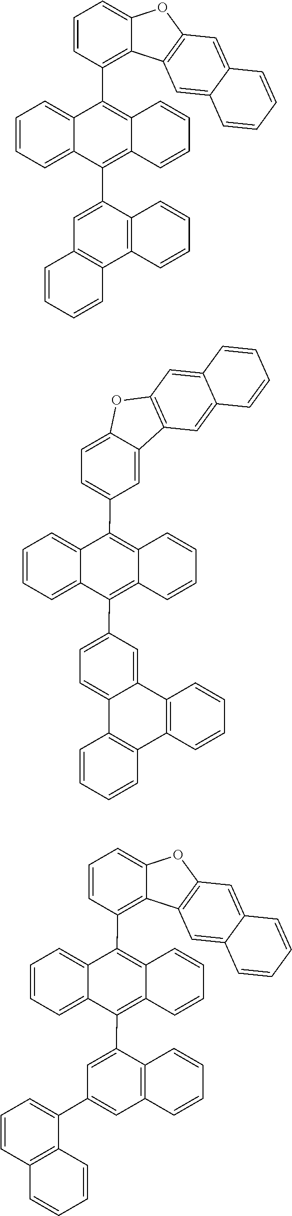 [SMILES: c1ccc2cc3c(cc2c1)oc1cccc(-c2c4ccccc4c(-c4cc5ccccc5c5ccccc45)c4ccccc24)c13 ; c1ccc2cc3c(cc2c1)oc1ccc(-c2c4ccccc4c(-c4ccc5c6ccccc6c6ccccc6c5c4)c4ccccc24)cc13 ; c1ccc2cc3c(cc2c1)oc1cccc(-c2c4ccccc4c(-c4cc(-c5cccc6ccccc56)cc5ccccc45)c4ccccc24)c13]

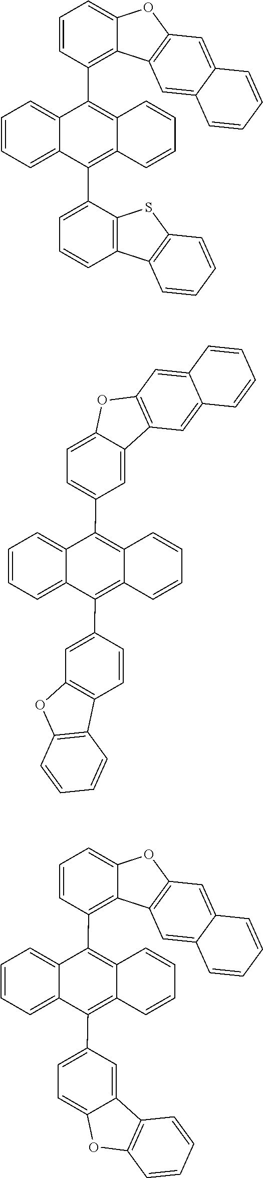 [SMILES: c1ccc2cc3c(cc2c1)oc1cccc(-c2c4ccccc4c(-c4cccc5c4sc4ccccc45)c4ccccc24)c13 ; c1ccc2cc3c(cc2c1)oc1ccc(-c2c4ccccc4c(-c4ccc5c(c4)oc4ccccc45)c4ccccc24)cc13 ; c1ccc2cc3c(cc2c1)oc1cccc(-c2c4ccccc4c(-c4ccc5oc6ccccc6c5c4)c4ccccc24)c13]

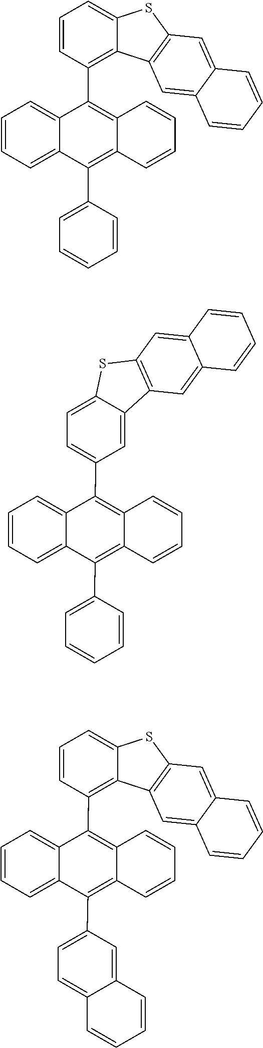 [SMILES: c1ccc(-c2c3ccccc3c(-c3cccc4sc5cc6ccccc6cc5c34)c3ccccc23)cc1 ; c1ccc(-c2c3ccccc3c(-c3ccc4sc5cc6ccccc6cc5c4c3)c3ccccc23)cc1 ; c1ccc2cc(-c3c4ccccc4c(-c4cccc5sc6cc7ccccc7cc6c45)c4ccccc34)ccc2c1]

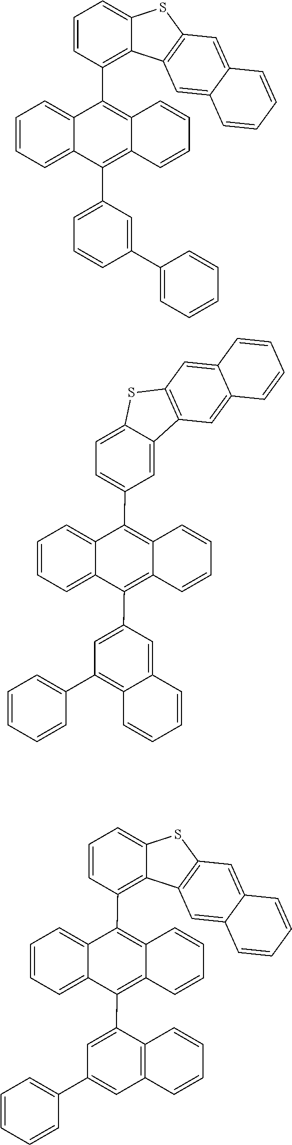

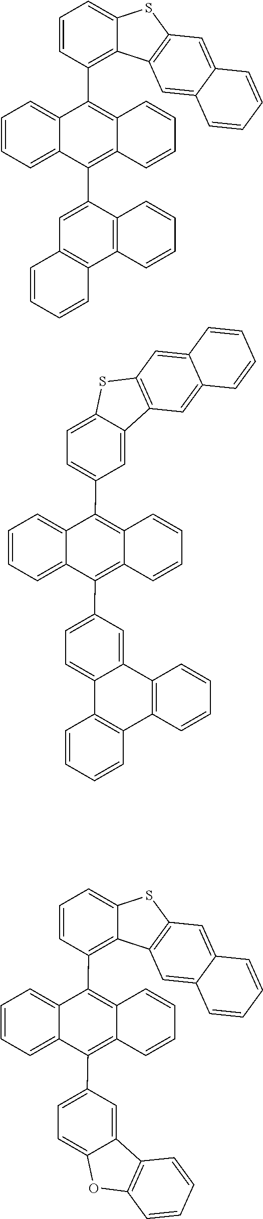 [SMILES: c1ccc2cc3c(cc2c1)sc1cccc(-c2c4ccccc4c(-c4cc5ccccc5c5ccccc45)c4ccccc24)c13 ; c1ccc2cc3c(cc2c1)sc1ccc(-c2c4ccccc4c(-c4ccc5c6ccccc6c6ccccc6c5c4)c4ccccc24)cc13 ; c1ccc2cc3c(cc2c1)sc1cccc(-c2c4ccccc4c(-c4ccc5oc6ccccc6c5c4)c4ccccc24)c13]

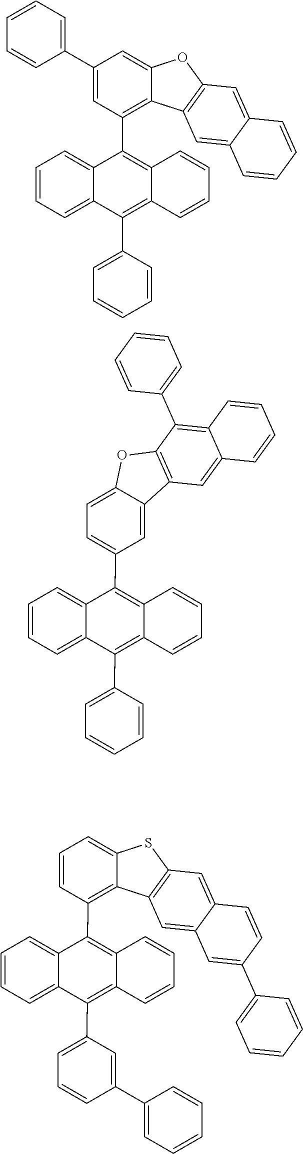

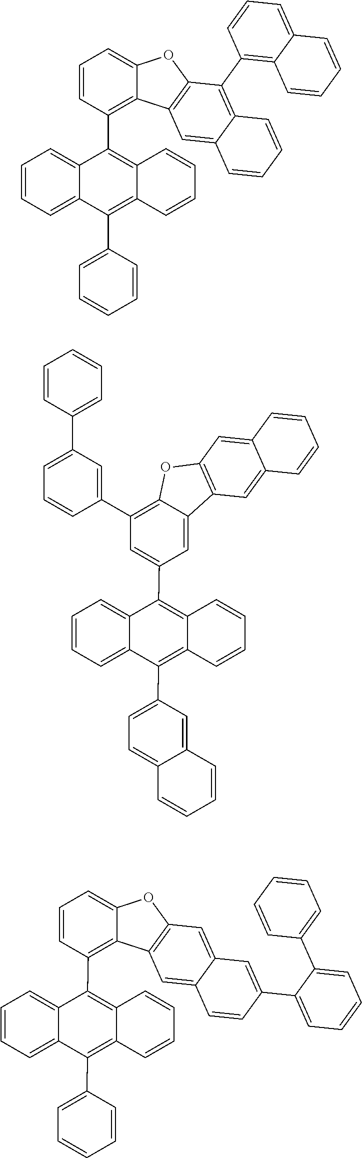 [SMILES: c1ccc(-c2c3ccccc3c(-c3cccc4oc5c(-c6cccc7ccccc67)c6ccccc6cc5c34)c3ccccc23)cc1 ; c1ccc(-c2cccc(-c3cc(-c4c5ccccc5c(-c5ccc6ccccc6c5)c5ccccc45)cc4c3oc3cc5ccccc5cc34)c2)cc1 ; c1ccc(-c2ccccc2-c2ccc3cc4c(cc3c2)oc2cccc(-c3c5ccccc5c(-c5ccccc5)c5ccccc35)c24)cc1]

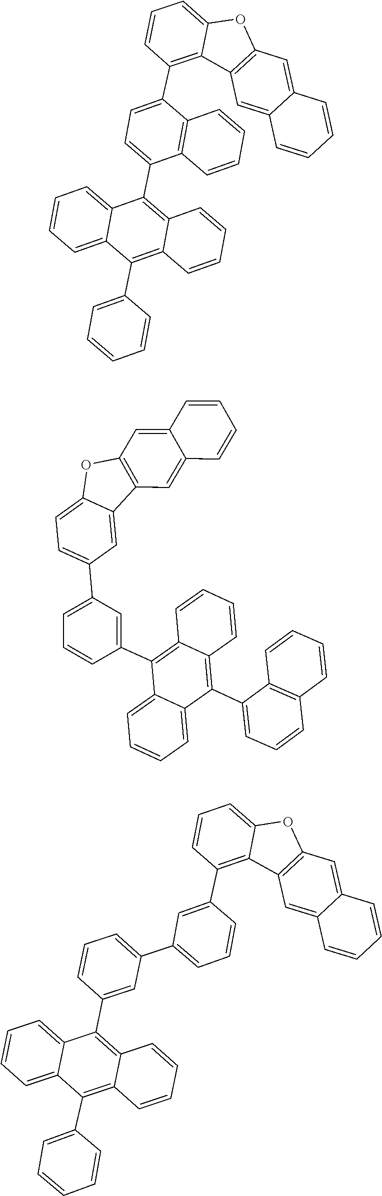 [SMILES: c1ccc(-c2c3ccccc3c(-c3ccc(-c4cccc5oc6cc7ccccc7cc6c45)c4ccccc34)c3ccccc23)cc1 ; c1cc(-c2ccc3oc4cc5ccccc5cc4c3c2)cc(-c2c3ccccc3c(-c3cccc4ccccc34)c3ccccc23)c1 ; c1ccc(-c2c3ccccc3c(-c3cccc(-c4cccc(-c5cccc6oc7cc8ccccc8cc7c56)c4)c3)c3ccccc23)cc1]

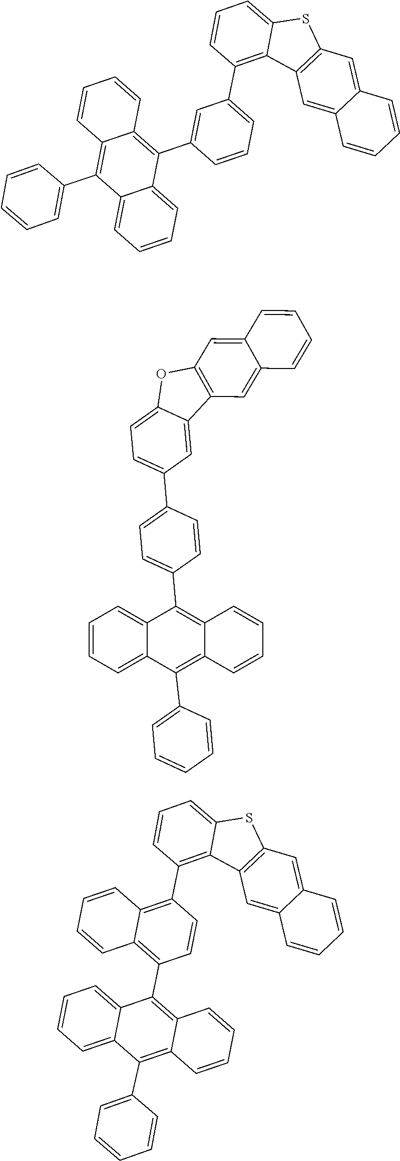

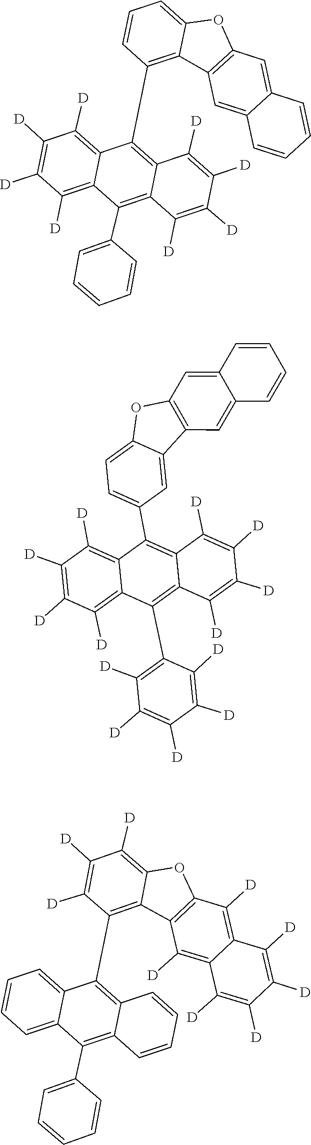 [SMILES: [2H]c1c([2H])c([2H])c2c(-c3cccc4oc5cc6ccccc6cc5c34)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3ccc4oc5cc6ccccc6cc5c4c3)c3c([2H])c([2H])c([2H])c([2H])c23)c([2H])c1[2H] ; [2H]c1c([2H])c(-c2c3ccccc3c(-c3ccccc3)c3ccccc23)c2c(oc3c([2H])c4c([2H])c([2H])c([2H])c([2H])c4c([2H])c32)c1[2H]]

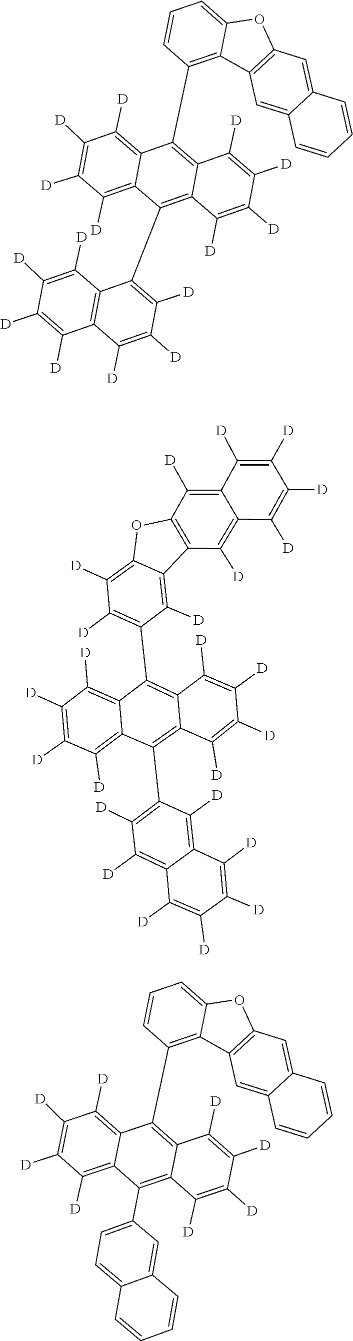

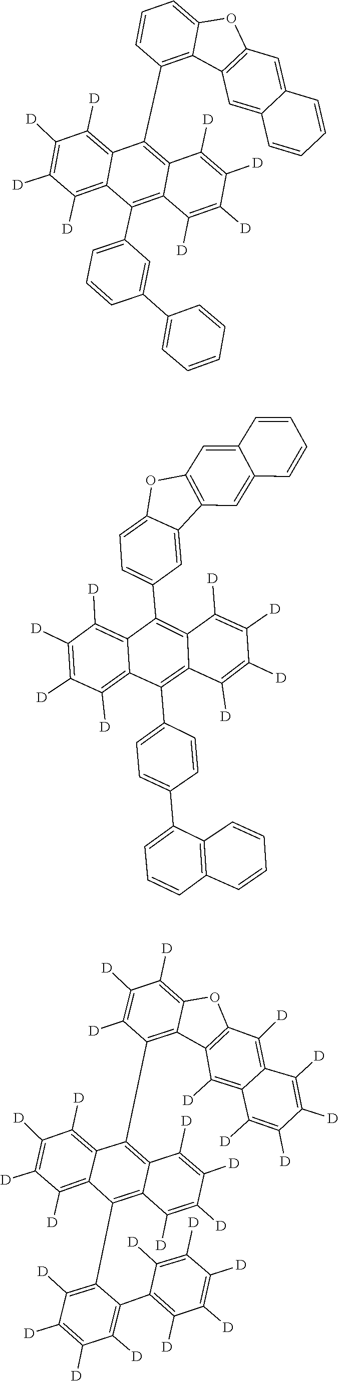 [SMILES: [2H]c1c([2H])c([2H])c2c(-c3cccc4oc5cc6ccccc6cc5c34)c3c([2H])c([2H])c([2H])c([2H])c3c(-c3cccc(-c4ccccc4)c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc(-c4cccc5ccccc45)cc3)c2c1[2H] ; [2H]c1c([2H])c([2H])c(-c2c([2H])c([2H])c([2H])c([2H])c2-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H]]

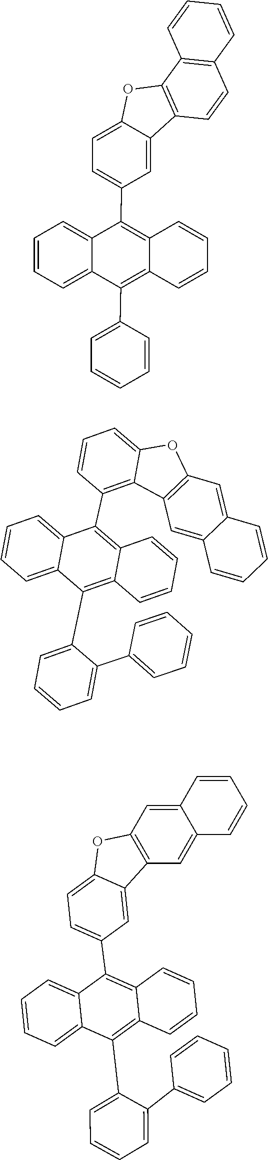

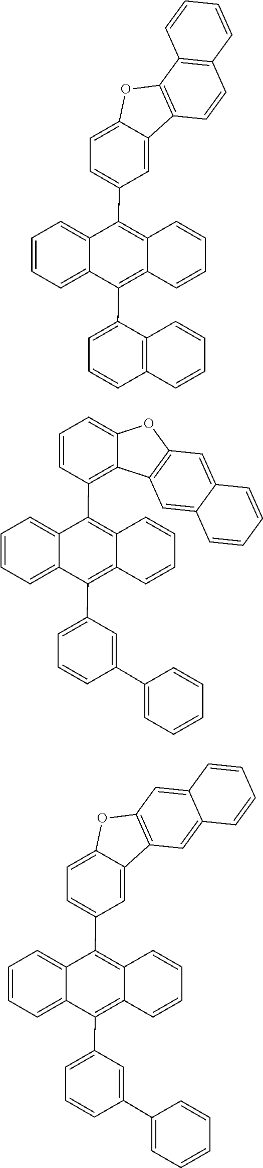

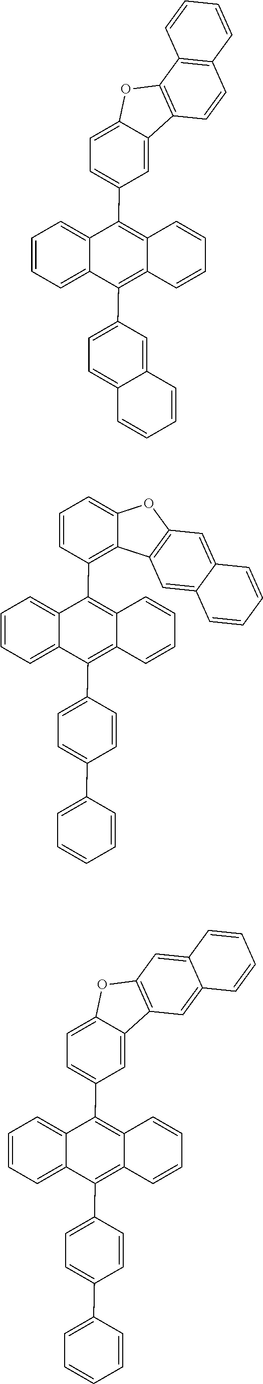 [SMILES: c1ccc2cc(-c3c4ccccc4c(-c4ccc5oc6c7ccccc7ccc6c5c4)c4ccccc34)ccc2c1 ; c1ccc(-c2ccc(-c3c4ccccc4c(-c4cccc5oc6cc7ccccc7cc6c45)c4ccccc34)cc2)cc1 ; c1ccc(-c2ccc(-c3c4ccccc4c(-c4ccc5oc6cc7ccccc7cc6c5c4)c4ccccc34)cc2)cc1]

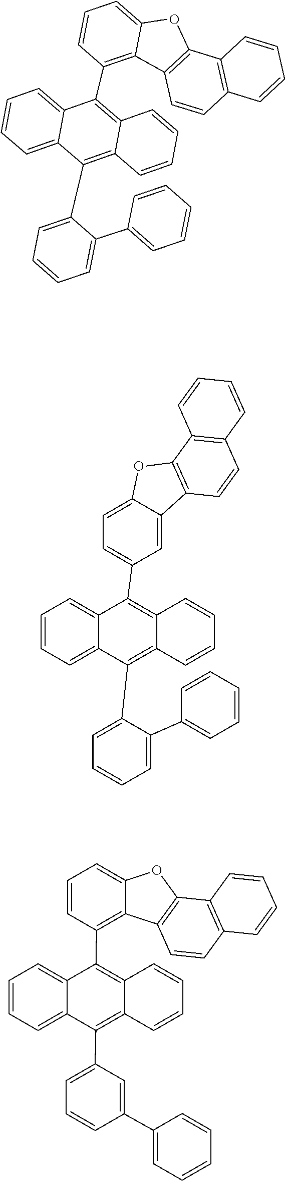 [SMILES: c1ccc(-c2ccccc2-c2c3ccccc3c(-c3cccc4oc5c6ccccc6ccc5c34)c3ccccc23)cc1 ; c1ccc(-c2ccccc2-c2c3ccccc3c(-c3ccc4oc5c6ccccc6ccc5c4c3)c3ccccc23)cc1 ; c1ccc(-c2cccc(-c3c4ccccc4c(-c4cccc5oc6c7ccccc7ccc6c45)c4ccccc34)c2)cc1]

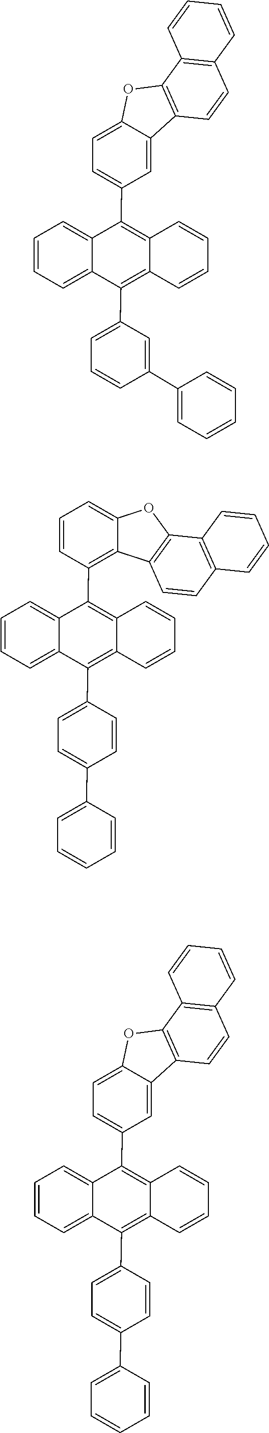 [SMILES: c1ccc(-c2cccc(-c3c4ccccc4c(-c4ccc5oc6c7ccccc7ccc6c5c4)c4ccccc34)c2)cc1 ; c1ccc(-c2ccc(-c3c4ccccc4c(-c4cccc5oc6c7ccccc7ccc6c45)c4ccccc34)cc2)cc1 ; c1ccc(-c2ccc(-c3c4ccccc4c(-c4ccc5oc6c7ccccc7ccc6c5c4)c4ccccc34)cc2)cc1]

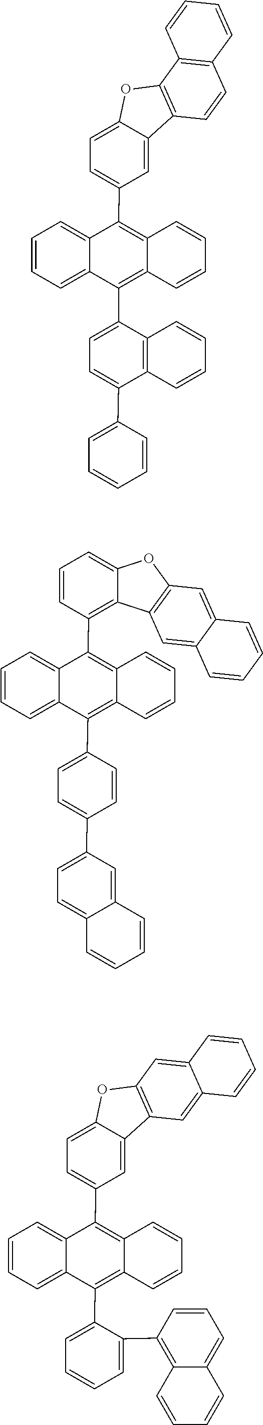 [SMILES: c1ccc(-c2ccc(-c3c4ccccc4c(-c4ccc5oc6c7ccccc7ccc6c5c4)c4ccccc34)c3ccccc23)cc1 ; c1ccc2cc(-c3ccc(-c4c5ccccc5c(-c5cccc6oc7cc8ccccc8cc7c56)c5ccccc45)cc3)ccc2c1 ; c1ccc(-c2c3ccccc3c(-c3ccc4oc5cc6ccccc6cc5c4c3)c3ccccc23)c(-c2cccc3ccccc23)c1]

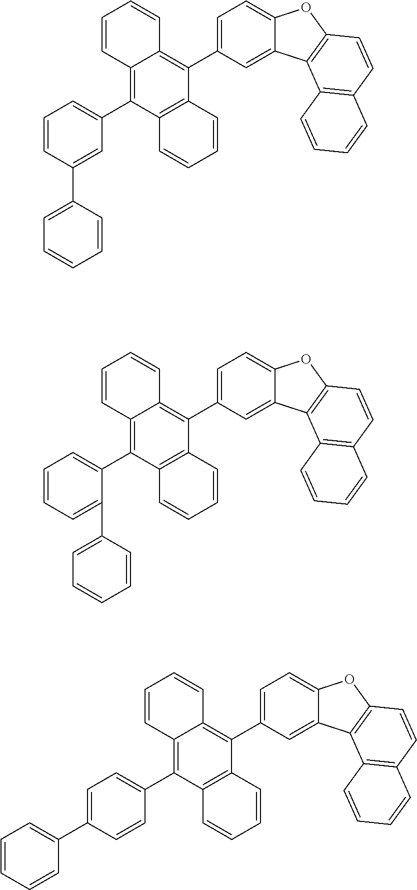 [SMILES: c1ccc(-c2cccc(-c3c4ccccc4c(-c4ccc5oc6ccc7ccccc7c6c5c4)c4ccccc34)c2)cc1 ; c1ccc(-c2ccccc2-c2c3ccccc3c(-c3ccc4oc5ccc6ccccc6c5c4c3)c3ccccc23)cc1 ; c1ccc(-c2ccc(-c3c4ccccc4c(-c4ccc5oc6ccc7ccccc7c6c5c4)c4ccccc34)cc2)cc1]

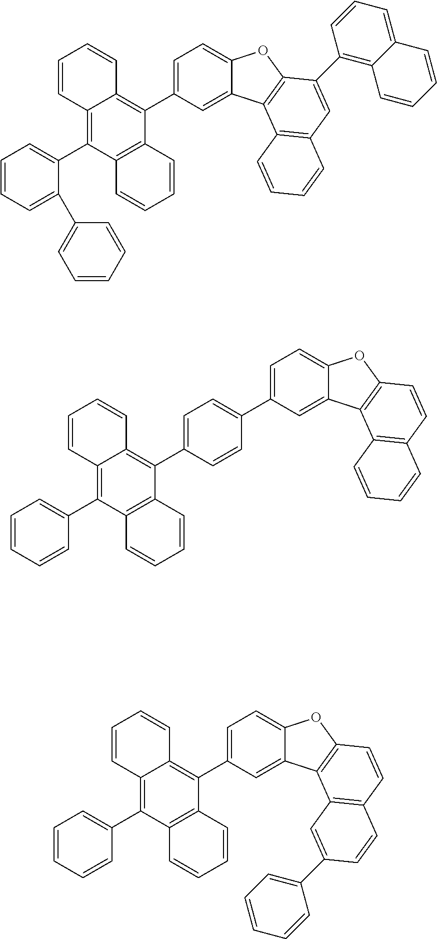 [SMILES: c1ccc(-c2ccccc2-c2c3ccccc3c(-c3ccc4oc5c(-c6cccc7ccccc67)cc6ccccc6c5c4c3)c3ccccc23)cc1 ; c1ccc(-c2c3ccccc3c(-c3ccc(-c4ccc5oc6ccc7ccccc7c6c5c4)cc3)c3ccccc23)cc1 ; c1ccc(-c2ccc3ccc4oc5ccc(-c6c7ccccc7c(-c7ccccc7)c7ccccc67)cc5c4c3c2)cc1]

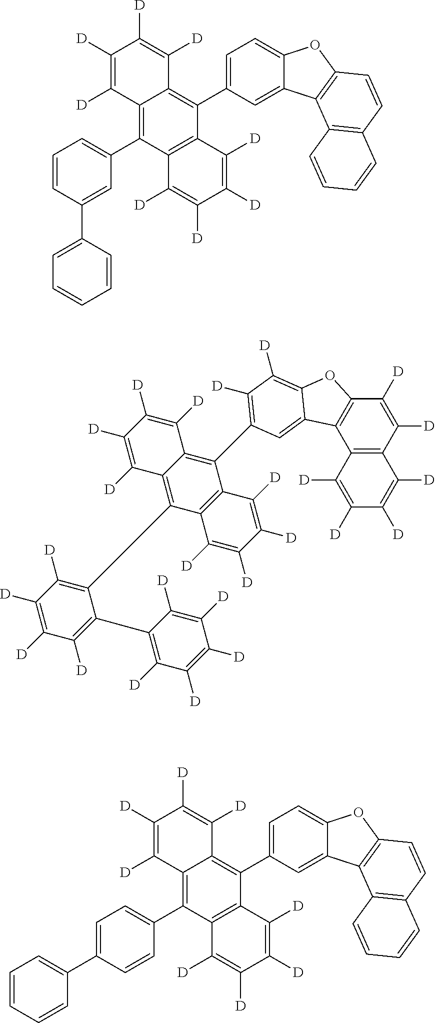 [SMILES: [2H]c1c([2H])c([2H])c2c(-c3ccc4oc5ccc6ccccc6c5c4c3)c3c([2H])c([2H])c([2H])c([2H])c3c(-c3cccc(-c4ccccc4)c3)c2c1[2H] ; [2H]c1c([2H])c([2H])c(-c2c([2H])c([2H])c([2H])c([2H])c2-c2c3c([2H])c([2H])c([2H])c([2H])c3c(-c3cc4c(oc5c([2H])c([2H])c6c([2H])c([2H])c([2H])c([2H])c6c54)c([2H])c3[2H])c3c([2H])c([2H])c([2H])c([2H])c23)c([2H])c1[2H] ; [2H]c1c([2H])c([2H])c2c(-c3ccc4oc5ccc6ccccc6c5c4c3)c3c([2H])c([2H])c([2H])c([2H])c3c(-c3ccc(-c4ccccc4)cc3)c2c1[2H]]

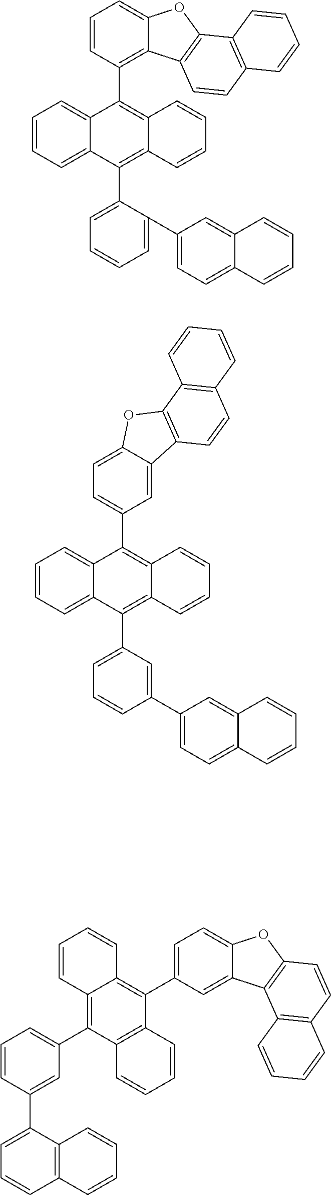

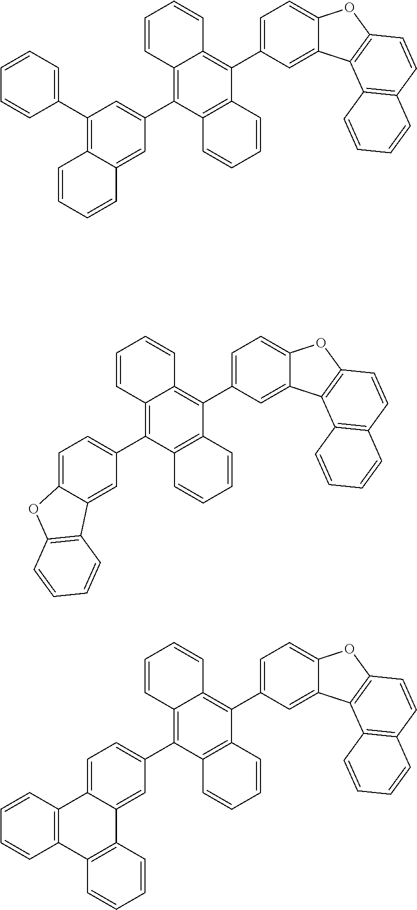 [SMILES: c1ccc(-c2cc(-c3c4ccccc4c(-c4ccc5oc6ccc7ccccc7c6c5c4)c4ccccc34)cc3ccccc23)cc1 ; c1ccc2c(c1)ccc1oc3ccc(-c4c5ccccc5c(-c5ccc6oc7ccccc7c6c5)c5ccccc45)cc3c12 ; c1ccc2c(c1)ccc1oc3ccc(-c4c5ccccc5c(-c5ccc6c7ccccc7c7ccccc7c6c5)c5ccccc45)cc3c12]

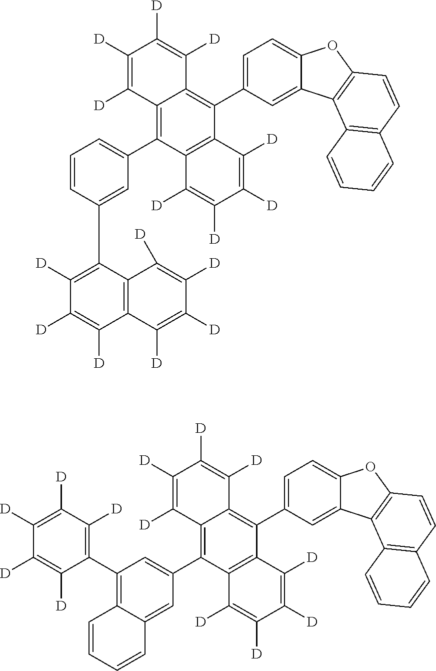 [SMILES: [2H]c1c([2H])c([2H])c2c(-c3cccc(-c4c5c([2H])c([2H])c([2H])c([2H])c5c(-c5ccc6oc7ccc8ccccc8c7c6c5)c5c([2H])c([2H])c([2H])c([2H])c45)c3)c([2H])c([2H])c([2H])c2c1[2H] ; [2H]c1c([2H])c([2H])c(-c2cc(-c3c4c([2H])c([2H])c([2H])c([2H])c4c(-c4ccc5oc6ccc7ccccc7c6c5c4)c4c([2H])c([2H])c([2H])c([2H])c34)cc3ccccc23)c([2H])c1[2H]]

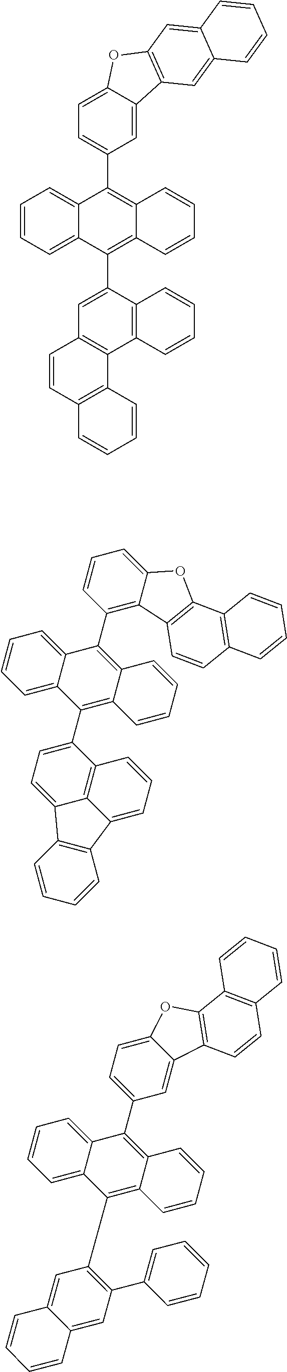 [SMILES: c1ccc2cc3c(cc2c1)oc1ccc(-c2c4ccccc4c(-c4cc5ccc6ccccc6c5c5ccccc45)c4ccccc24)cc13 ; c1ccc2c(c1)-c1cccc3c(-c4c5ccccc5c(-c5cccc6oc7c8ccccc8ccc7c56)c5ccccc45)ccc-2c13 ; c1ccc(-c2cc3ccccc3cc2-c2c3ccccc3c(-c3ccc4oc5c6ccccc6ccc5c4c3)c3ccccc23)cc1]

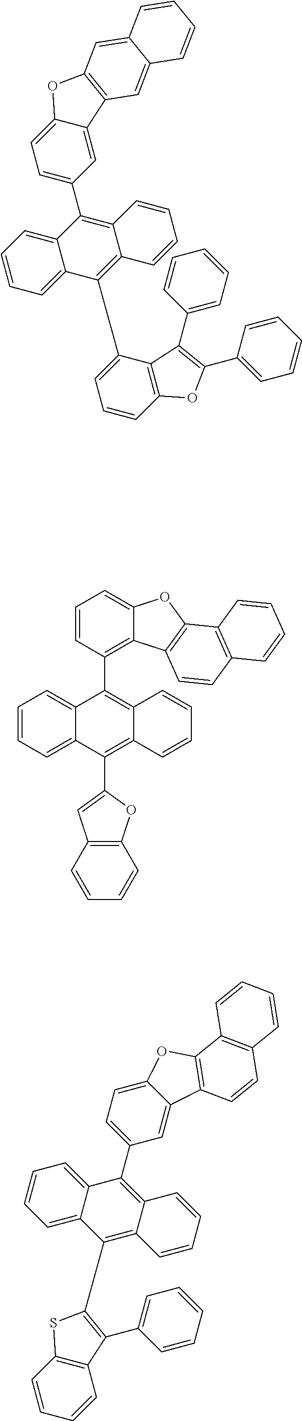 [SMILES: c1ccc(-c2oc3cccc(-c4c5ccccc5c(-c5ccc6oc7cc8ccccc8cc7c6c5)c5ccccc45)c3c2-c2ccccc2)cc1 ; c1ccc2oc(-c3c4ccccc4c(-c4cccc5oc6c7ccccc7ccc6c45)c4ccccc34)cc2c1 ; c1ccc(-c2c(-c3c4ccccc4c(-c4ccc5oc6c7ccccc7ccc6c5c4)c4ccccc34)sc3ccccc23)cc1]

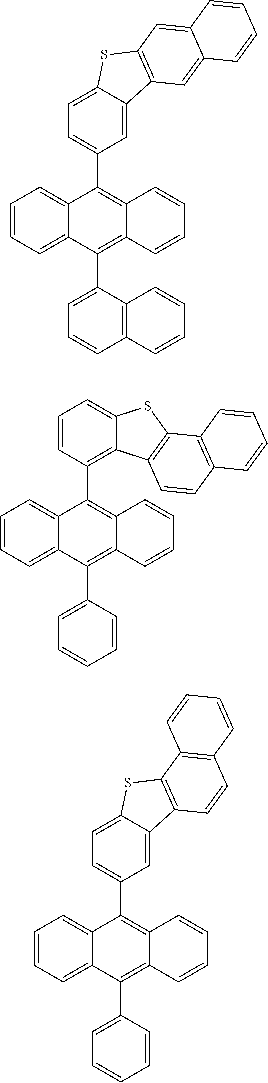 [SMILES: c1ccc2cc3c(cc2c1)sc1ccc(-c2c4ccccc4c(-c4cccc5ccccc45)c4ccccc24)cc13 ; c1ccc(-c2c3ccccc3c(-c3cccc4sc5c6ccccc6ccc5c34)c3ccccc23)cc1 ; c1ccc(-c2c3ccccc3c(-c3ccc4sc5c6ccccc6ccc5c4c3)c3ccccc23)cc1]

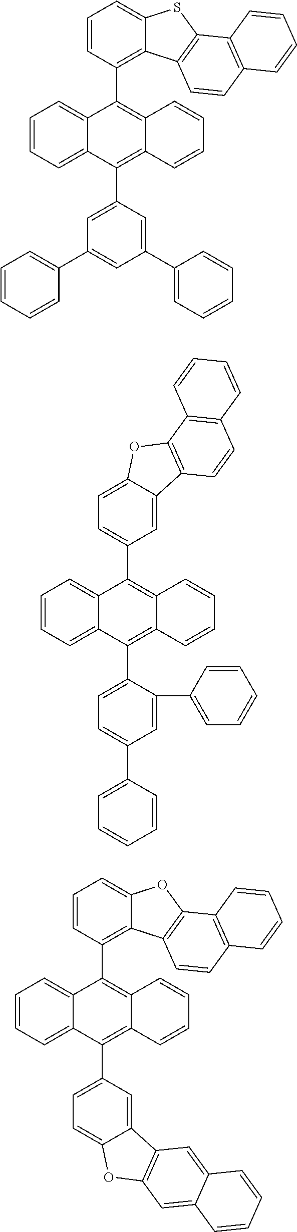

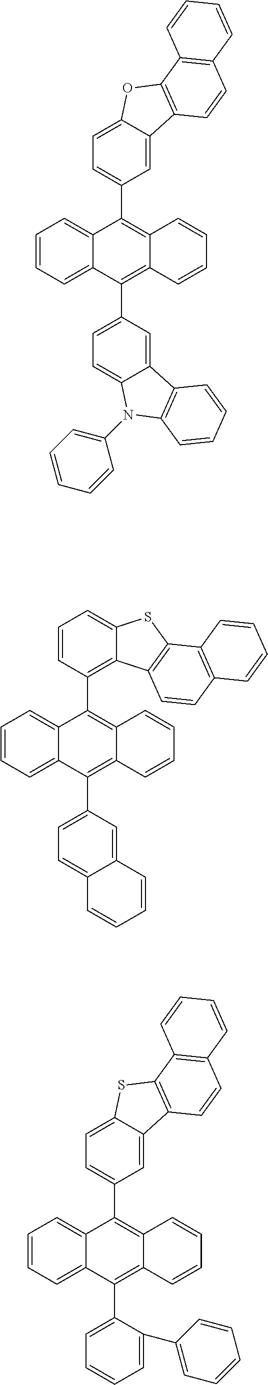 [SMILES: c1ccc(-n2c3ccccc3c3cc(-c4c5ccccc5c(-c5ccc6oc7c8ccccc8ccc7c6c5)c5ccccc45)ccc32)cc1 ; c1ccc2cc(-c3c4ccccc4c(-c4cccc5sc6c7ccccc7ccc6c45)c4ccccc34)ccc2c1 ; c1ccc(-c2ccccc2-c2c3ccccc3c(-c3ccc4sc5c6ccccc6ccc5c4c3)c3ccccc23)cc1]

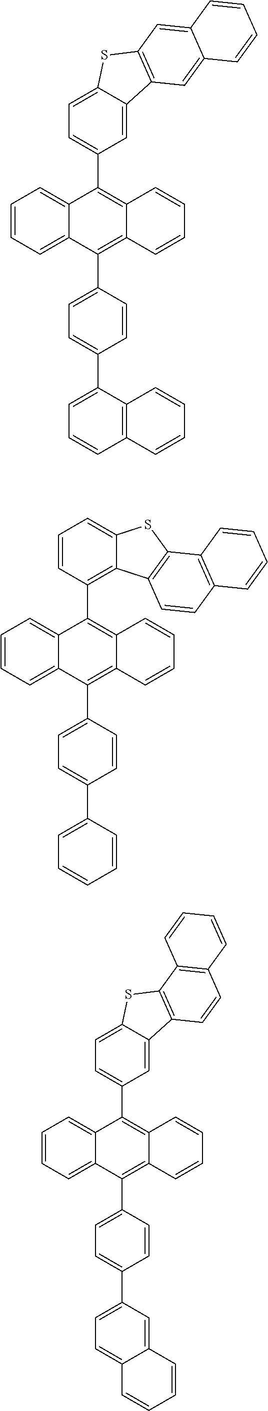 [SMILES: c1ccc2cc3c(cc2c1)sc1ccc(-c2c4ccccc4c(-c4ccc(-c5cccc6ccccc56)cc4)c4ccccc24)cc13 ; c1ccc(-c2ccc(-c3c4ccccc4c(-c4cccc5sc6c7ccccc7ccc6c45)c4ccccc34)cc2)cc1 ; c1ccc2cc(-c3ccc(-c4c5ccccc5c(-c5ccc6sc7c8ccccc8ccc7c6c5)c5ccccc45)cc3)ccc2c1]

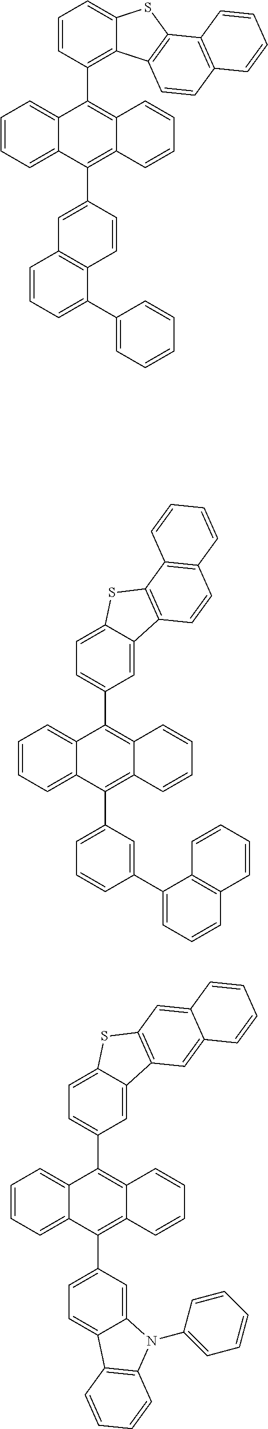

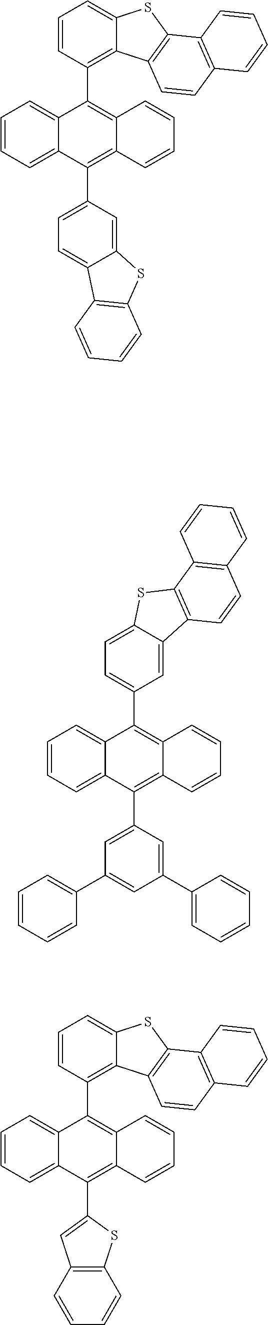 [SMILES: c1ccc2c(c1)ccc1c2sc2cccc(-c3c4ccccc4c(-c4ccc5c(c4)sc4ccccc45)c4ccccc34)c21 ; c1ccc(-c2cc(-c3ccccc3)cc(-c3c4ccccc4c(-c4ccc5sc6c7ccccc7ccc6c5c4)c4ccccc34)c2)cc1 ; c1ccc2sc(-c3c4ccccc4c(-c4cccc5sc6c7ccccc7ccc6c45)c4ccccc34)cc2c1]

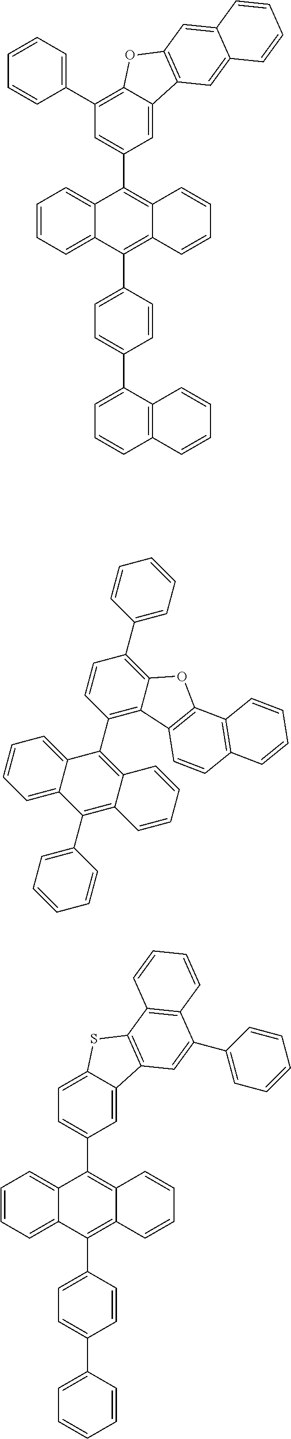 [SMILES: c1ccc(-c2cc(-c3c4ccccc4c(-c4ccc(-c5cccc6ccccc56)cc4)c4ccccc34)cc3c2oc2cc4ccccc4cc23)cc1 ; c1ccc(-c2c3ccccc3c(-c3ccc(-c4ccccc4)c4oc5c6ccccc6ccc5c34)c3ccccc23)cc1 ; c1ccc(-c2ccc(-c3c4ccccc4c(-c4ccc5sc6c7ccccc7c(-c7ccccc7)cc6c5c4)c4ccccc34)cc2)cc1]

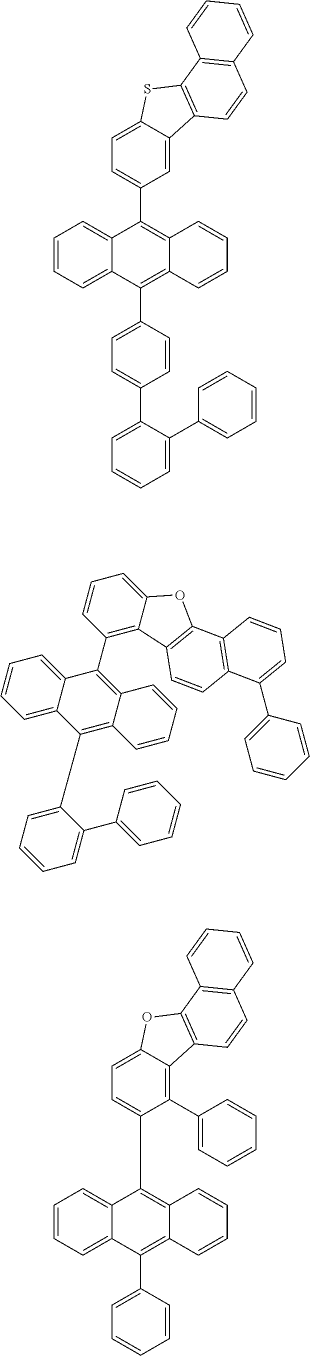 [SMILES: c1ccc(-c2ccccc2-c2ccc(-c3c4ccccc4c(-c4ccc5sc6c7ccccc7ccc6c5c4)c4ccccc34)cc2)cc1 ; c1ccc(-c2ccccc2-c2c3ccccc3c(-c3cccc4oc5c6cccc(-c7ccccc7)c6ccc5c34)c3ccccc23)cc1 ; c1ccc(-c2c3ccccc3c(-c3ccc4oc5c6ccccc6ccc5c4c3-c3ccccc3)c3ccccc23)cc1]

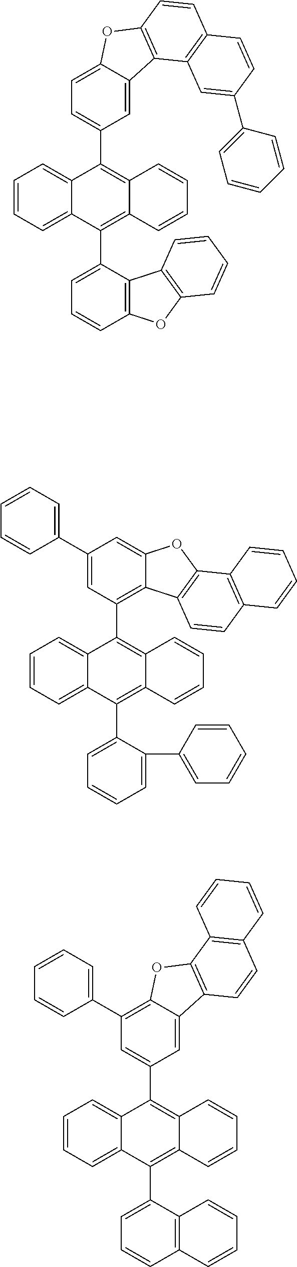 [SMILES: c1ccc(-c2ccc3ccc4oc5ccc(-c6c7ccccc7c(-c7cccc8oc9ccccc9c78)c7ccccc67)cc5c4c3c2)cc1 ; c1ccc(-c2cc(-c3c4ccccc4c(-c4ccccc4-c4ccccc4)c4ccccc34)c3c(c2)oc2c4ccccc4ccc23)cc1 ; c1ccc(-c2cc(-c3c4ccccc4c(-c4cccc5ccccc45)c4ccccc34)cc3c2oc2c4ccccc4ccc32)cc1]

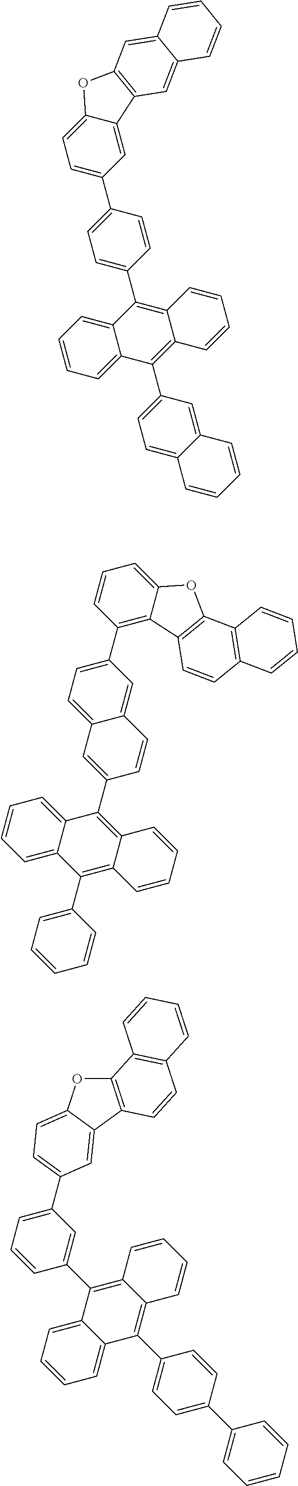 [SMILES: c1ccc2cc(-c3c4ccccc4c(-c4ccc(-c5ccc6oc7cc8ccccc8cc7c6c5)cc4)c4ccccc34)ccc2c1 ; c1ccc(-c2c3ccccc3c(-c3ccc4cc(-c5cccc6oc7c8ccccc8ccc7c56)ccc4c3)c3ccccc23)cc1 ; c1ccc(-c2ccc(-c3c4ccccc4c(-c4cccc(-c5ccc6oc7c8ccccc8ccc7c6c5)c4)c4ccccc34)cc2)cc1]

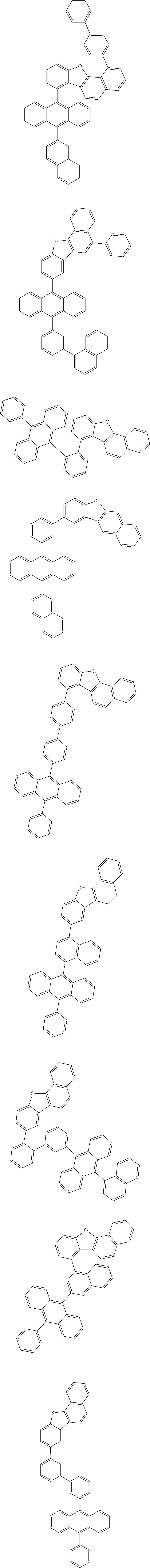

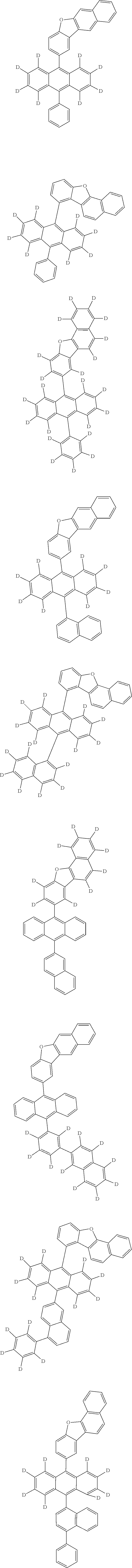

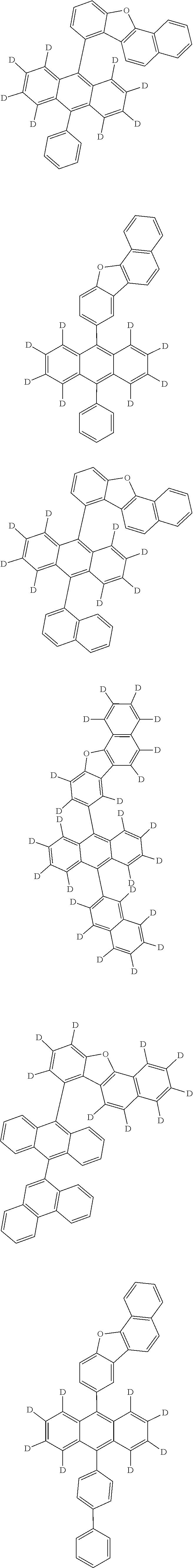

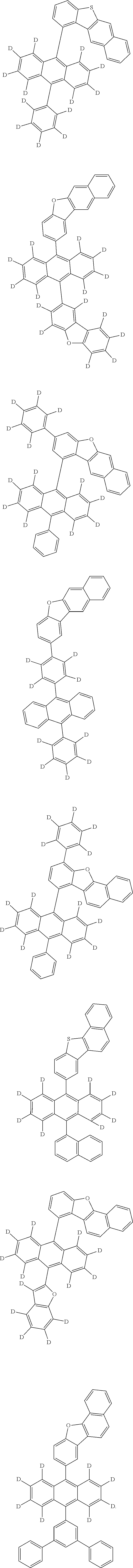

According to an exemplary embodiment of the present specification, Chemical Formula 1 is Chemical Formula 1-1, and Chemical Formula 2 is Chemical Formula 2-1-2.

According to an exemplary embodiment of the present specification, Chemical Formula 1 is Chemical Formula 1-1, and Chemical Formula 2 is Chemical Formula 2-1-3.

According to an exemplary embodiment of the present specification, Chemical Formula 1 is Chemical Formula 1-1, and Chemical Formula 2 is Chemical Formula 2-1-4.

According to an exemplary embodiment of the present specification, Chemical Formula 1 is Chemical Formula 1-1, and Chemical Formula 2 is Chemical Formula 2-2-4.

A core structure of the compounds of Chemical Formula 1 and Chemical Formula 2 according to an exemplary embodiment of the present specification may be prepared as in the method of the Preparation Example to be described below. The substituent may be bonded by a method known in the art, and the kind and position of the substituent or the number of substituents may be changed according to the technology known in the art.

In the present specification, compounds having various energy band gaps may be synthesized by introducing various substituents into the core structures of the compounds of Chemical Formula 1 and Chemical Formula 2. Further, in the present specification, various substituents may be introduced into the core structures having the structure described above to adjust the HOMO and LUMO energy levels of a compound.

Hereinafter, an organic light emitting device will be described.

When one member is disposed “on” another member in the present specification, this comprises not only a case where the one member is brought into contact with another member, but also a case where still another member is present between the two members.

When one part “comprises” one constituent element in the present specification, unless otherwise specifically described, this does not mean that another constituent element is excluded, but means that another constituent element may be further comprised.

The organic light emitting device is characterized by comprising: an anode; a cathode; and a first organic material layer provided between the anode and the cathode, in which the first organic material layer comprises a compound of Chemical Formula 1 and a compound of Chemical Formula 2.

The organic material layer of the organic light emitting device of the present specification may be composed of a single-layered structure, but may also be composed of a multi-layered structure in which two or more organic material layers are stacked. For example, the organic light emitting device of the present specification may have a structure comprising one or more layers of a hole injection layer, a hole transport layer, an electron blocking layer, a light emitting layer, a hole transport and injection layer, an electron transport layer, an electron injection layer, a hole blocking layer, and an electron transport and injection layer as organic material layers. However, the structure of the organic light emitting device of the present specification is not limited thereto, and may comprise a fewer or greater number of organic material layers.

In the organic light emitting device according to an exemplary embodiment of the present specification, the first organic material layer may be a hole transport layer, a hole injection layer, a hole transport and injection layer, or an electron blocking layer.

In the organic light emitting device according to an exemplary embodiment of the present specification, the first organic material layer may be a light emitting layer, and may further comprise a dopant material. In this case, the above-described compound of Chemical Formula 1 and the compound of Chemical Formula 2 are the hosts of the light emitting layer.

As an example of the dopant material, it is possible to use a phosphorescent material such as (4,6-F₂ppy)₂Irpic, or a fluorescent material such as spiro-DPVBi, spiro-6P, distyryl benzene (DSB), distyryl arylene (DSA), a PFO-based polymer, a PPV-based polymer, an anthracene-based compound, a pyrene-based compound, and a boron-based compound, but the dopant material is not limited thereto. In this case, the dopant in the light emitting layer is comprised in an amount of 1 part by weight to 50 parts by weight with respect to 100 parts by weight of a host.

In the organic light emitting device according to an exemplary embodiment of the present specification, the first organic material layer may be an electron transport layer, an electron injection layer, an electron transport and injection layer, or a hole blocking layer.

In the organic light emitting device of the present specification, an organic material layer having one or more layers is further provided between an anode and a cathode, and the organic material layer may further comprise one or more layers of a hole transport layer, a hole injection layer, a hole transport and injection layer, an electron blocking layer, a light emitting layer, an electron transport layer, an electron injection layer, an electron transport and injection layer, and a hole blocking layer.

In the organic light emitting device according to an exemplary embodiment of the present specification, the first organic material layer comprises both the above-described compound of Chemical Formula 1 and the above-described compound of Chemical Formula 2, and the mass ratio of the compound of Chemical Formula 1 and the compound of Chemical Formula 2 may be 90:10 to 10:90.

The structure of the organic light emitting device of the present specification may have a structure which is the same as that illustrated in the FIGURE, but is not limited thereto.

The FIGURE exemplifies a structure of an organic light emitting device in which a substrate 1, an anode 2, a hole injection layer 3, a hole transport layer 4, an electron blocking layer 5, a light emitting layer 6, a hole blocking layer 7, an electron transport layer 8, an electron injection layer 9, and a cathode 10 are sequentially stacked. In the structure as described above, the first organic material layer of the present specification may be the light emitting layer 6.

According to an exemplary embodiment of the present specification, the organic light emitting device may have a tandem structure in which two or more independent devices are connected in series. In an exemplary embodiment, the tandem structure may be in the form of each organic light emitting device joined by a charge generating layer. Since a device having a tandem structure can be driven with a current lower than that of a unit device based on the same brightness, there is an advantage in that the service life characteristic of the device is significantly improved.

When the organic light emitting device comprises a plurality of organic material layers, the organic material layer may be formed of the same material or different materials.

The organic light emitting device of the present invention may be manufactured by typical methods and materials for manufacturing an organic light emitting device, except that a first organic material layer is formed using the above-described compound of Chemical Formula 1 and the above-described compound of Chemical Formula 2.

According to an exemplary embodiment of the present specification, a first organic material layer comprising the compound of Chemical Formula 1 and the compound of Chemical Formula 2 may be formed by a vacuum deposition method or a solution application method.

According to an exemplary embodiment of the present specification, the first organic material layer may be formed by co-deposition using each deposition source; or by pre-mixed deposition using one deposition source. The co-deposition is to form the first organic material layer using a vapor deposition source comprising the compound of Chemical Formula 1 and a vapor deposition source comprising the compound of Chemical Formula 2, and the pre-mixed deposition is to form the first organic material layer by mixing the compound of Chemical Formula 1 and the compound of Chemical Formula 2, putting the resulting mixture into one deposition source, and using the mixed deposition source. When an organic material layer comprising the same compound is formed, pre-mixed deposition facilitates interaction between compounds compared to co-deposition, so that it is possible to obtain an effect in which processability is improved and the characteristics of the manufactured device are improved.

The compound may be formed as an organic material layer by not only a vacuum deposition method, but also a solution application method when the organic light emitting device of the present specification is manufactured. Here, the solution application method means spin coating, dip coating, inkjet printing, screen printing, a spray method, roll coating, and the like, but is not limited thereto.

For example, the organic light emitting device according to the present specification may be manufactured by depositing a metal or a metal oxide having conductivity, or an alloy thereof on a substrate to form an anode, forming an organic material layer comprising a hole injection layer, a hole transport layer, a light emitting layer, an electron blocking layer, an electron transport layer, an electron injection layer, and the like thereon, and then depositing a material, which may be used as a cathode, thereon, by using a physical vapor deposition (PVD) method such as sputtering or e-beam evaporation. In addition to the method described above, an organic light emitting device may also be made by sequentially depositing a cathode material, an organic material layer, and an anode material on a substrate.

The organic material layer may further comprise one or more layers of a hole transport layer, a hole injection layer, an electron blocking layer, an electron transport and injection layer, an electron transport layer, an electron injection layer, a hole blocking layer, and a hole transport and injection layer.

The anode is an electrode which injects holes, and as an anode material, materials having a high work function are usually preferred so as to facilitate the injection of holes into an organic material layer. Specific examples of the anode material which may be used in the present invention comprise: a metal, such as vanadium, chromium, copper, zinc, and gold, or an alloy thereof; a metal oxide, such as zinc oxide, indium oxide, indium tin oxide (ITO), and indium zinc oxide (IZO); a combination of a metal and an oxide, such as ZnO:Al or SnO₂:Sb; a conductive polymer, such as poly(3-methylthiophene), poly[3,4-(ethylene-1,2-dioxy)thiophene](PEDOT), polypyrrole, and polyaniline; and the like, but are not limited thereto.

The cathode is an electrode which injects electrons, and as a cathode material, materials having a low work function are usually preferred so as to facilitate the injection of electrons into an organic material layer. Specific examples of the cathode material comprise: a metal, such as magnesium, calcium, sodium, potassium, titanium, indium, yttrium, lithium, gadolinium, aluminum, silver, tin, and lead, or an alloy thereof; a multi-layered structural material, such as LiF/Al or LiO₂/Al; and the like, but are not limited thereto.

The hole injection layer is a layer which serves to facilitate the injection of holes from an anode to a light emitting layer, and a hole injection material is preferably a material which may proficiently accept holes from an anode at a low voltage, and the highest occupied molecular orbital (HOMO) of the hole injection material is preferably a value between the work function of the anode material and the HOMO of the neighboring organic material layer. Specific examples of the hole injection material comprise the above-described compounds or metal porphyrin, oligothiophene, arylamine-based organic materials, hexanitrile hexaazatriphenylene-based organic materials, quinacridone-based organic materials, perylene-based organic materials, anthraquinone, polyaniline-based and polythiophene-based conductive polymers, and the like, but are not limited thereto. The hole injection layer may have a thickness of 1 to 150 nm. When the hole injection layer has a thickness of 1 nm or more, there is an advantage in that it is possible to prevent hole injection characteristics from deteriorating, and when the hole injection layer has a thickness of 150 nm or less, there is an advantage in that it is possible to prevent the driving voltage from being increased in order to improve the movement of holes due to the too thick hole injection layer.

The hole transport layer may serve to facilitate the transport of holes. A hole transport material is suitably a material having high hole mobility which may accept holes from an anode or a hole injection layer and transfer the holes to a light emitting layer. Specific examples thereof comprise the above-described compounds or arylamine-based organic materials, conductive polymers, block copolymers having conjugated parts and non-conjugated parts together, and the like, but are not limited thereto.

A hole buffer layer may be additionally provided between the hole injection layer and the hole transport layer, and may comprise the above-described compounds or hole injection or transport materials known in the art.

An electron blocking layer may be provided between the hole transport layer and the light emitting layer. The electron blocking layer is a layer which may improve the service life and efficiency of a device by adjusting holes transported from a hole transport layer such that the holes are smoothly injected into a light emitting layer, and preventing electrons injected from an electron injection layer from passing through a light emitting layer and entering a hole injection layer. The above-described compound or a material known in the art may be used in the electron blocking layer. In particular, the electron blocking layer may comprise a compound in which a carbazole group and an arylamine group are linked to each other via an intermediate linker such as an arylene group or a heteroarylene group, and for example, it is more preferred that the electron blocking layer comprises a compound represented by the following Chemical Formula 3, but the electron blocking layer is not limited thereto.

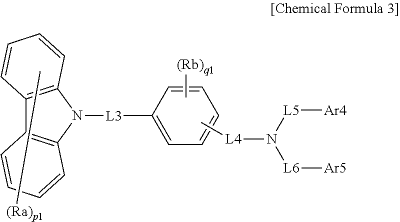

In Chemical Formula 3,
Ra and Rb are the same as or different from each other, and are each independently hydrogen, deuterium, an alkyl group, an alkenyl group, an alkynyl group, a cycloalkyl group, an alkoxy group, an alkylthio group, an aryloxy group, an arylthio group, an aralkyl group, Si(R101)(R102)(R103), —C(═O)R104, —COOR105, a halogen atom, a cyan group, a nitro group, a substituted or unsubstituted aryl group, or a substituted or unsubstituted heteroaryl group, and Ra and Rb may be each independently bonded to an adjacent group to form a substituted or unsubstituted hydrocarbon ring or hetero ring,
R101 to R105 are the same as or different from each other, and are each independently hydrogen, a substituted or unsubstituted alkyl group, a substituted or unsubstituted aryl group, or a substituted or unsubstituted heteroaryl group,
L3 to L6 are the same as or different from each other, and are each independently a direct bond, a substituted or unsubstituted alkylene group, a substituted or unsubstituted arylene group, or a substituted or unsubstituted heteroarylene group,
Ar4 and Ar5 are the same as or different from each other, and are each independently a substituted or unsubstituted aryl group, or a substituted or unsubstituted heteroaryl group,
p1 is an integer from 0 to 8, and when p1 is 2 or higher, two or more Ras are the same as or different from each other, and
q1 is an integer from 0 to 4, and when q1 is 2 or higher, two or more Rbs are the same as or different from each other.

The light emitting layer may emit red, green, or blue light, and may be composed of a phosphorescent material or a fluorescent material. The light emitting material is a material which may receive holes and electrons from a hole transport layer and an electron transport layer, respectively, and combine the holes and the electrons to emit light in a visible ray region, and is preferably a material having high quantum efficiency for fluorescence or phosphorescence. Specific examples thereof comprise: 8-hydroxy-quinoline aluminum complexes (Alq3); carbazole-based compounds; dimerized styryl compounds; BAlq; 10-hydroxybenzoquinoline-metal compounds; benzoxazole-based, benzothiazole-based and benzimidazole-based compounds; poly(p-phenylenevinylene) (PPV)-based polymers; spiro compounds; polyfluorene, rubrene, and the like, but are not limited thereto.

Examples of the host material for a light emitting layer comprise a fused aromatic ring derivative, a hetero ring-containing compound, or the like. Specifically, examples of the fused aromatic ring derivatives comprise anthracene derivatives, pyrene derivatives, naphthalene derivatives, pentacene derivatives, phenanthrene compounds, fluoranthene compounds, and the like, and examples of the hetero ring-containing compounds comprise carbazole derivatives, dibenzofuran derivatives, ladder-type furan compounds, pyrimidine derivatives, and the like, but the examples thereof are not limited thereto.

When the light emitting layer emits red light, it is possible to use a phosphorescent material such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr), or octaethylporphyrin platinum (PtOEP), or a fluorescent material such as tris(8-hydroxyquinolino)aluminum (Alq3) as a light emitting dopant, but the light emitting dopant is not limited thereto. When the light emitting layer emits green light, it is possible to use a phosphorescent material such as fac tris(2-phenylpyridine)iridium (Ir(ppy)3), or a fluorescent material such as tris(8-hydroxyquinolino)aluminum (Alq3), an anthracene-based compound, a pyrene-based compound, and a boron-based compound as a light emitting dopant, but the light emitting dopant is not limited thereto. When the light emitting layer emits blue light, it is possible to use a phosphorescent material such as (4,6-F₂ppy)₂Irpic, or a fluorescent material such as spiro-DPVBi, spiro-6P, distyryl benzene (DSB), distyryl arylene (DSA), a PFO-based polymer, a PPV-based polymer, an anthracene-based compound, a pyrene-based compound, and a boron-based compound as a light emitting dopant, but the light emitting dopant is not limited thereto.

A hole blocking layer may be provided between the electron transport layer and the light emitting layer. The hole blocking layer is a layer which may improve the service life and efficiency of a device by adjusting electrons transported from an electron transport layer such that the electrons are smoothly injected into a light emitting layer, and preventing holes injected from a hole injection layer from passing through a light emitting layer and entering an electron injection layer. The above-described compound or a material known in the art may be used in the hole blocking layer. In particular, it is more preferred that the hole blocking layer comprises a compound of the following Chemical Formula 4, but the hole blocking layer is not limited thereto.

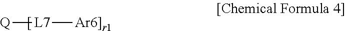

In Chemical Formula 4,
Q is the following Chemical Formula B or Chemical Formula C,
L7 is a direct bond, a substituted or unsubstituted arylene group, or a substituted or unsubstituted heteroarylene group,
Ar6 is the following Chemical Formula D or Chemical Formula E,
r1 is an integer from 1 to 4,

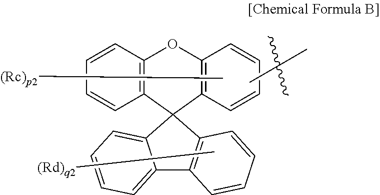

wherein in Chemical Formula B,
Rc and Rd are the same as or different from each other, and are each independently hydrogen, deuterium, a nitrile group, a nitro group, a hydroxyl group, a carbonyl group, an ester group, an imide group, an amide group, a substituted or unsubstituted alkyl group, a substituted or unsubstituted cycloalkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted alkylsulfoxy group, a substituted or unsubstituted arylsulfoxy group, a substituted or unsubstituted alkenyl group, a substituted or unsubstituted silyl group, a substituted or unsubstituted boron group, a substituted or unsubstituted amine group, a substituted or unsubstituted arylphosphine group, a substituted or unsubstituted phosphine oxide group, a substituted or unsubstituted aryl group, or a substituted or unsubstituted heteroaryl group,
p2 is an integer from 0 to 7, and when p2 is 2 or higher, two or more Rcs are the same as or different from each other,
q2 is an integer from 0 to 8, and when q2 is 2 or higher, two or more Rds are the same as or different from each other,

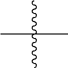

means a position bonded to Chemical Formula 4,

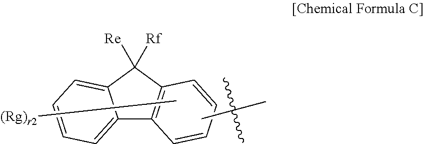

wherein in Chemical Formula C,
Re and Rf are the same as or different from each other, and are each independently hydrogen, a substituted or unsubstituted alkyl group, or a substituted or unsubstituted aryl group, or are bonded to each other to form a substituted or unsubstituted ring,
Rg is hydrogen, deuterium, a nitrile group, a nitro group, a hydroxy group, a carbonyl group, an ester group, an imide group, an amide group, a substituted or unsubstituted alkyl group, a substituted or unsubstituted cycloalkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted alkylsulfoxy group, a substituted or unsubstituted arylsulfoxy group, a substituted or unsubstituted alkenyl group, a substituted or unsubstituted silyl group, a substituted or unsubstituted boron group, a substituted or unsubstituted amine group, a substituted or unsubstituted arylphosphine group, a substituted or unsubstituted phosphine oxide group, a substituted or unsubstituted aryl group, or a substituted or unsubstituted heteroaryl group,
r2 is an integer from 0 to 7, and when r2 is 2 or higher, two or more Rgs are the same as or different from each other,

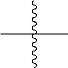

means a position bonded to Chemical Formula 4,

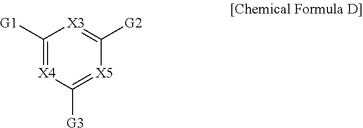

wherein in Chemical Formula D,
X3 is N or CR201, X4 is N or CR202, X5 is N or CR203, and at least two of X3 to X5 are N,
any one of G1 to G3 and R201 to R203 is a moiety bonded to L7 of Chemical Formula 4, and the others are the same as or different from each other, and are each independently hydrogen; an aryl group that is unsubstituted or substituted with an alkyl group, an aryl group, or a heteroaryl group; or a heteroaryl group,

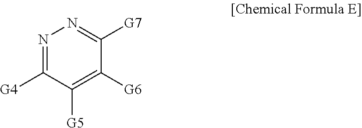

wherein in Chemical Formula E,
any one of G4 to G7 is a moiety bonded to L7 of Chemical Formula 4, and the others are the same as or different from each other, and are each independently hydrogen; an aryl group that is unsubstituted or substituted with an alkyl group, an aryl group, or a heteroaryl group; or a heteroaryl group.

The electron transport layer may serve to facilitate the transport of electrons. An electron transport material is suitably a material having high electron mobility which may proficiently accept electrons from a cathode and transfer the electrons to a light emitting layer. Specific examples thereof comprise: the Al complexes of 8-hydroxyquinoline; complexes comprising Alq3; organic radical compounds; hydroxyflavone-metal complexes; and the like, but are not limited thereto. The electron transport layer may have a thickness of 1 to 50 nm. When the electron transport layer has a thickness of 1 nm or more, there is an advantage in that it is possible to prevent electron transport characteristics from deteriorating, and when the electron transport layer has a thickness of 50 nm or less, there is an advantage in that it is possible to prevent the driving voltage from being increased in order to improve the movement of electrons due to the too thick electron transport layer. In particular, it is more preferred that the electron transport layer comprises a compound of the following Chemical Formula 5, but the electron transport layer is not limited thereto.

Ar8-(L8)ₚ-Ar7-(L9)_{q}-Ar9 [Chemical Formula 5]

In Chemical Formula 5,
L8 and L9 are the same as or different from each other, and are each independently an arylene group which is unsubstituted or substituted with an aryl group,
Ar7 is a substituted or unsubstituted arylene group,
Ar8 and Ar9 are the same as or different from each other, and are each independently the following Chemical Formula F,
p and q are each an integer from 1 to 3, and when p is 2 or higher, the L8s are the same as or different from each other, and when q is 2 or higher, the L9s are the same as or different from each other,

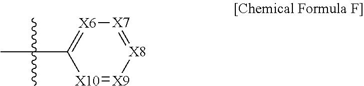

wherein in Chemical Formula F,
X6 is N or CR301, X7 is N or CR302, X8 is N or CR303, X9 is N or CR304, X10 is N or CR305, and at least two of X6 to X10 are N,
R301 to R305 are the same as or different from each other, and are each independently hydrogen; deuterium; an alkyl group that is unsubstituted or substituted with deuterium; a cycloalkyl group that is unsubstituted or substituted with deuterium, a cyano group, an alkyl group, an aryl group or a cycloalkyl group; an aryl group that is unsubstituted or substituted with deuterium, a cyano group, an alkyl group, an aryl group or a cycloalkyl group; or a heterocyclic group that is unsubstituted or substituted with deuterium, a cyano group, an alkyl group, an aryl group or a cycloalkyl group, or adjacent groups are bonded to each other to form an aromatic hydrocarbon ring that is unsubstituted or substituted with deuterium, a cyano group, an alkyl group, an aryl group or a cycloalkyl group, and

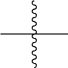

means a position bonded to Chemical Formula 4.

The electron injection layer may serve to facilitate the injection of electrons. An electron injection material is preferably a compound which has a capability of transporting electrons, an effect of injecting electrons from a cathode, and an excellent effect of injecting electrons into a light emitting layer or a light emitting material, prevents excitons produced from a light emitting layer from moving to a hole injection layer, and is also excellent in the ability to form a thin film. Specific examples thereof include fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, metal complex compounds, nitrogen-containing 5-membered ring derivatives, and the like, but are not limited thereto.

Examples of the metal complex compounds comprise 8-hydroxyquinolinato lithium, bis(8-hydroxyquinolinato) zinc, bis(8-hydroxyquinolinato) copper, bis(8-hydroxyquinolinato) manganese, tris(8-hydroxyquinolinato) aluminum, tris(2-methyl-8-hydroxyquinolinato) aluminum, tris(8-hydroxyquinolinato) gallium, bis(10-hydroxybenzo[h]quinolinato) beryllium, bis(10-hydroxybenzo[h]quinolinato) zinc, bis(2-methyl-8-quinolinato) chlorogallium, bis(2-methyl-8-quinolinato)(o-cresolato) gallium, bis(2-methyl-8-quinolinato)(1-naphtholato) aluminum, bis(2-methyl-8-quinolinato)(2-naphtholato) gallium, and the like, but are not limited thereto.

The hole blocking layer is a layer which blocks holes from reaching a cathode, and may be generally formed under the same conditions as those of the hole injection layer. Specific examples thereof comprise oxadiazole derivatives or triazole derivatives, phenanthroline derivatives, BCP, aluminum complexes, and the like, but are not limited thereto.

The organic light emitting device according to the present invention may be a top emission type, a bottom emission type, or a dual emission type according to the material to be used.

### EXAMPLES

Hereinafter, the present specification will be described in detail with reference to Examples for specifically describing the present specification. However, the Examples according to the present specification may be modified in various forms, and it is not interpreted that the scope of the present application is limited to the Examples described in detail below. The Examples of the present application are provided to explain the present specification more completely to a person with ordinary skill in the art.

### Synthesis Examples

### Synthesis Example 1-1. Synthesis of BH1-1

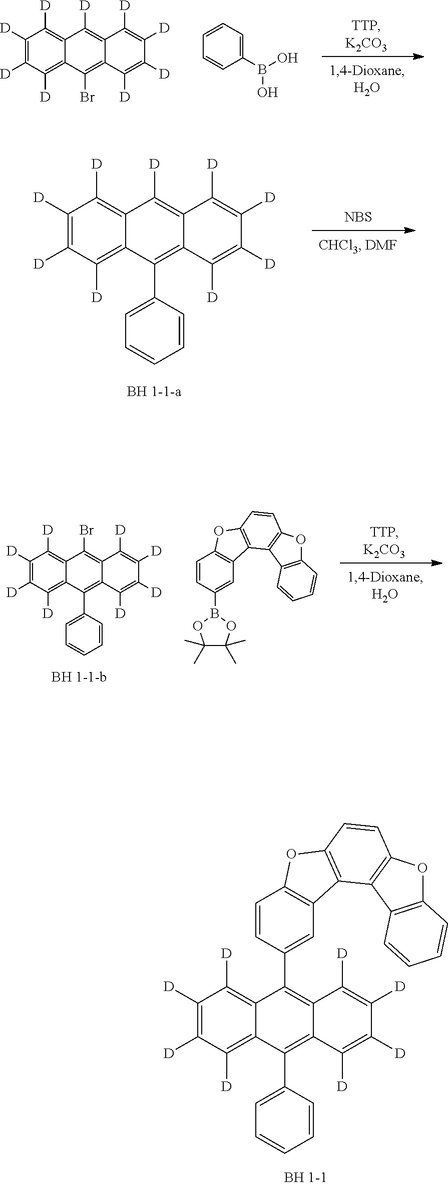

<1-1-a> Synthesis of Compound BH 1-1-a

After 9-bromoanthracene-1,2,3,4,5,6,7,8,10-d9 (50 g, 188 mmol) and phenylboronic acid (25.2 g, 20.6 mmol) were dissolved in 1,4-dioxane (500 ml), Pd(PPh₃)₄ (10.9 g, 9.4 mmol) and K₂CO₃ (52.2 g, 376 mmol) were dissolved in 150 ml of distilled water and added thereto, and the resulting mixture was stirred under reflux for 24 hours. The reaction solution was cooled, the aqueous layer was removed, and then 1,4-dioxane was removed by distillation under reduced pressure. After the residue was dissolved in chloroform, the resulting solution was put into a separatory funnel and washed three times with distilled water, and then the organic layer was dried over anhydrous magnesium sulfate. Thereafter, chloroform was removed under reduced pressure, and the residue was recrystallized with ethyl acetate (EA) to obtain Compound BH 1-1-a (45 g, yield 91%).

<1-1-b> Synthesis of Compound BH 1-1-b

After Compound BH 1-1-a (45 g, 171 mmol) was dispersed in 450 ml of chloroform, a solution of n-bromosuccinimide (30.4 g, 171 mmol) dissolved in 50 ml of dimethylformamide was slowly added dropwise thereto. Thereafter, after reaction at room temperature for 2 hours, 100 ml of a 20% aqueous Na₂S₂O₃ solution was added dropwise thereto, and an organic layer was separated using a separatory funnel, and then washed three times with distilled water. Thereafter, residual moisture was removed over anhydrous magnesium sulfate, chloroform was removed by distillation under reduced pressure, and the residue was recrystallized in ethyl acetate (EA) to obtain Compound BH 1-1-b (50 g, yield 86%).

<1-1-c> Synthesis of Compound BH 1-1

After Compound BH 1-1-b (50 g, 147 mmol) and 2-(4,4,5,5-tetramethyl-1,3,2-dioxaborolan-2-yl)benzo[1,2-b:4,3-b′]bisbenzofuran (62 g, 161 mmol) were dissolved in 1,4-dioxane (500 ml), Pd(PPh₃)₄ (8.46 g, 7.3 mmol) and K₂CO₃ (40.5 g, 293 mmol) were dissolved in 150 ml of distilled water and added thereto, and the resulting mixture was refluxed for 24 hours. The reaction solution was cooled, and the resulting solid was filtered, and then dissolved in chloroform, and then the resulting solution was put into a separatory funnel and washed three times with distilled water. Thereafter, the organic layer was dried over anhydrous magnesium sulfate, chloroform was removed under reduced pressure, and the residue was recrystallized with ethyl acetate (EA) to obtain Compound BH 1-1 (52 g, yield 68%). [M+H]=519.2

### Synthesis Example 1-2. Synthesis of BH 1-2

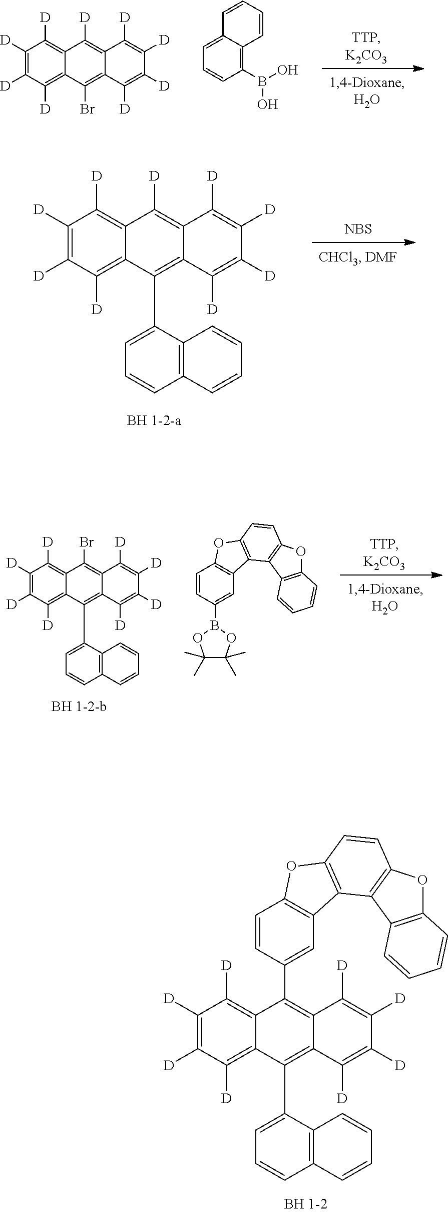

<1-2-a> Synthesis of Compound BH 1-2-a

Compound BH 1-2-a was obtained by performing synthesis in the same manner as in Synthesis Example 1-1-a, except that naphthalen-1-yl boronic acid was used instead of phenylboronic acid.

<1-2-b> Synthesis of Compound BH 1-2-b

BH 1-2-b was obtained by performing synthesis in the same manner as in Synthesis Example 1-1-b, except that Compound BH 1-2-a was used instead of Compound BH 1-1-a.

<1-2-c> Synthesis of Compound BH 1-2

BH 1-2 was obtained by performing synthesis in the same manner as in Synthesis Example 1-1-c, except that Compound BH 1-2-b was used instead of Compound BH 1-1-b. [M+H]=569.2

### Synthesis Example 1-3. Synthesis of Compound BH 1-3

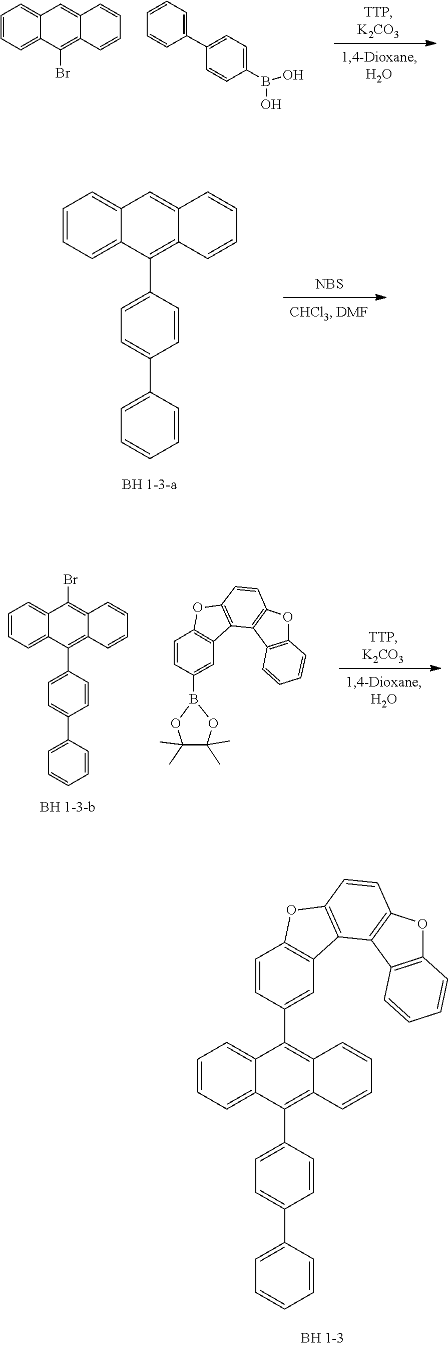

<1-3-a> Synthesis of Compound BH 1-3-a

Compound BH 1-3-a was obtained by performing synthesis in the same manner as in Synthesis Example 1-1-a, except that 9-bromoanthracene and [1,1′-biphenyl]-4-ylboronic acid were used instead of 9-bromoanthracene-1,2,3,4,5,6,7,8,10-d9 and phenylboronic acid, respectively.

<1-3-b> Synthesis of Compound BH 1-3-b

BH 1-3-b was obtained by performing synthesis in the same manner as in Synthesis Example 1-1-b, except that Compound BH 1-3-a was used instead of Compound BH 1-1-a.

<1-3-c> Synthesis of Compound BH 1-3

BH 1-3 was obtained by performing synthesis in the same manner as in Synthesis Example 1-1-c, except that Compound BH 1-3-b was used instead of Compound BH 1-1-b. [M+H]=587.2

### Synthesis Example 1-4. Synthesis of Compound BH 1-4

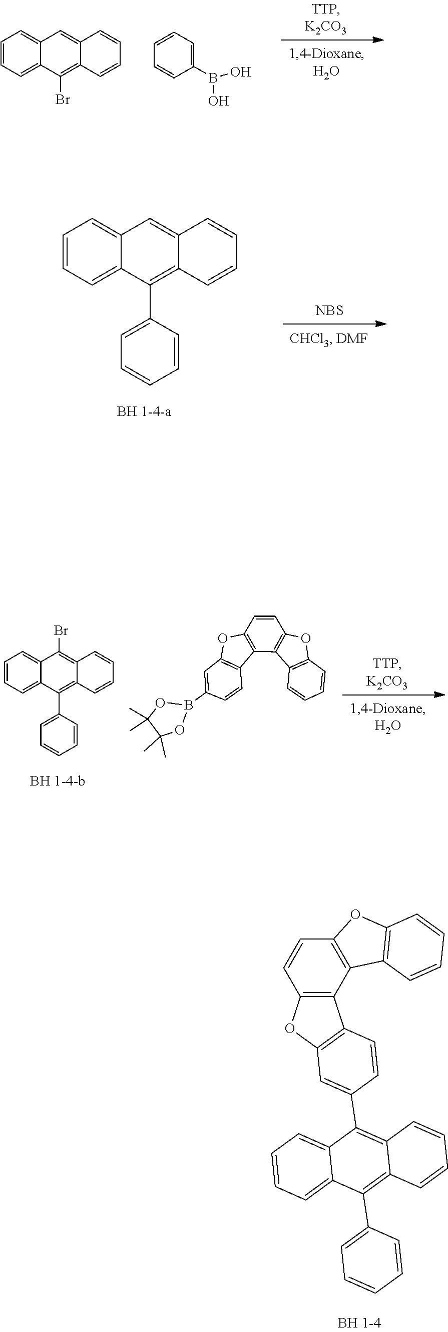

<1-4-a> Synthesis of Compound BH 1-4-a

Compound BH 1-4-a was obtained by performing synthesis in the same manner as in Synthesis Example 1-1-a, except that 9-bromoanthracene was used instead of 9-bromoanthracene-1,2,3,4,5,6,7,8,10-d9.

<1-4-b> Synthesis of Compound BH 1-4-b

BH 1-4-b was obtained by performing synthesis in the same manner as in Synthesis Example 1-1-b, except that Compound BH 1-4-a was used instead of Compound BH 1-1-a.

<1-4-c> Synthesis of Compound BH 1-4

BH 1-4 was obtained by performing synthesis in the same manner as in Synthesis Example 1-1-c, except that Compound BH 1-4-b and 3-(4,4,5,5-tetramethyl-1,3,2-dioxaborolan-2-yl)benzo[1,2-b:4,3-b′]bisbenzofuran were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=511.2

### Synthesis Example 1-5. Synthesis of Compound BH 1-5

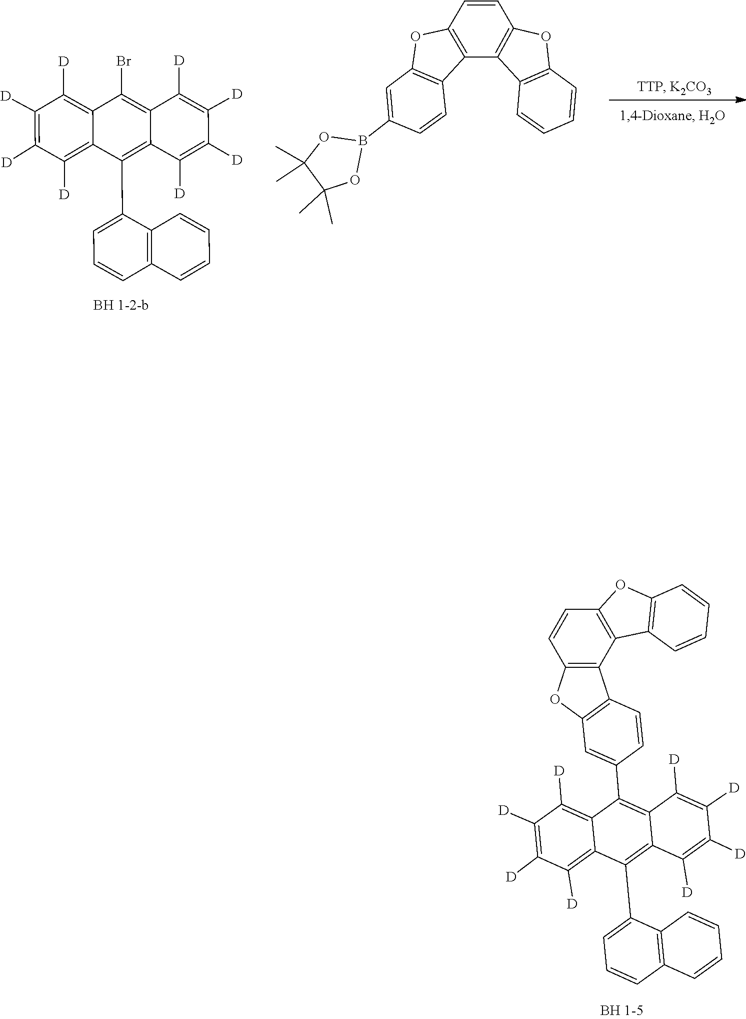

BH 1-5 was obtained by performing synthesis in the same manner as in Synthesis Example 1-1-c, except that Compound BH 1-2-b and 3-(4,4,5,5-tetramethyl-1,3,2-dioxaborolan-2-yl)benzo[1,2-b:4,3-b′]bisbenzofuran were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=569.2

### Synthesis Example 1-6. Synthesis of Compound BH 1-6

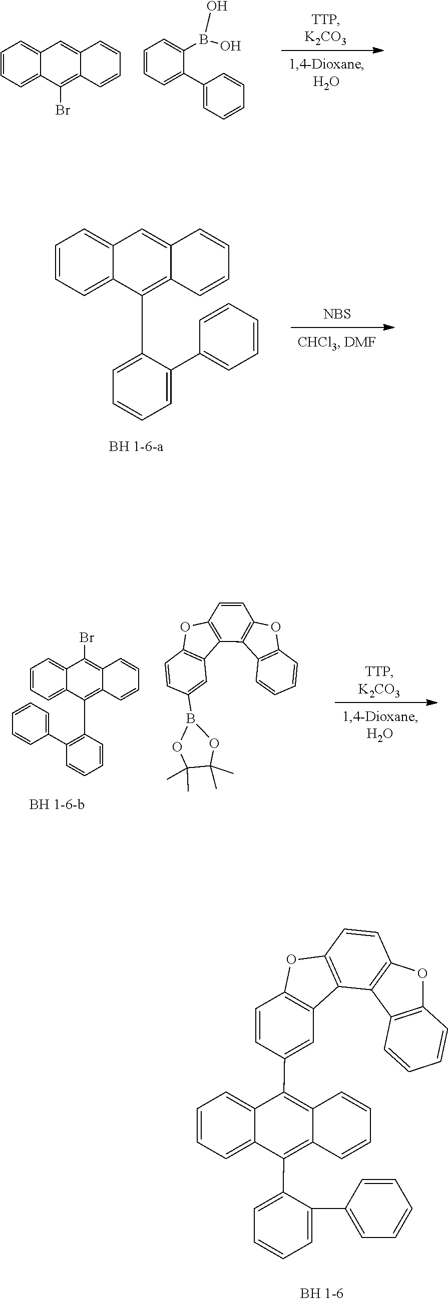

<1-6-a> Synthesis of Compound BH 1-6-a

Compound BH 1-6-a was obtained by performing synthesis in the same manner as in Synthesis Example 1-1-a, except that 9-bromoanthracene and [1,1′-biphenyl]-2-ylboronic acid were used instead of 9-bromoanthracene-1,2,3,4,5,6,7,8,10-d9 and phenylboronic acid, respectively.

<1-6-b> Synthesis of Compound BH 1-6-b

BH 1-6-b was obtained by performing synthesis in the same manner as in Synthesis Example 1-1-b, except that Compound BH 1-6-a was used instead of Compound BH 1-1-a.

<1-6-c> Synthesis of Compound BH 1-6

BH 1-6 was obtained by performing synthesis in the same manner as in Synthesis Example 1-1-c, except that Compound BH 1-6-b was used instead of Compound BH 1-1-b. [M+H]=587.2

### Synthesis Example 1-7. Synthesis of Compound BH 1-7

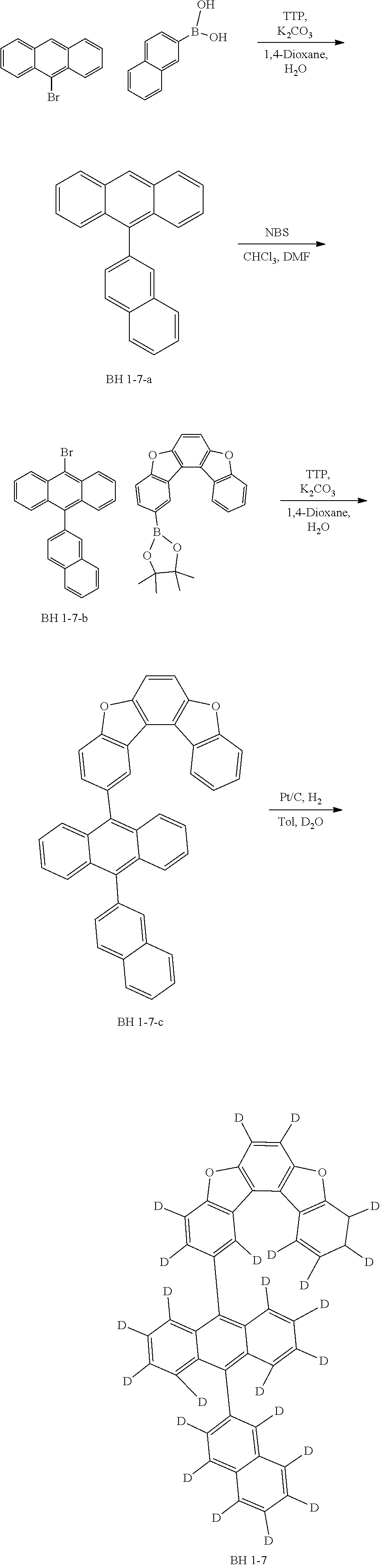

<1-7-a> Synthesis of Compound BH 1-7-a

Compound BH 1-7-a was obtained by performing synthesis in the same manner as in Synthesis Example 1-1-a, except that 9-bromoanthracene and naphthalen-2-ylboronic acid were used instead of 9-bromoanthracene-1,2,3,4,5,6,7,8,10-d9 and phenylboronic acid, respectively.

<1-7-b> Synthesis of Compound BH 1-7-b

BH 1-7-b was obtained by performing synthesis in the same manner as in Synthesis Example 1-1-b, except that Compound BH 1-7-a was used instead of Compound BH 1-1-a.

<1-7-c> Synthesis of Compound BH 1-7-c

BH 1-7-c was obtained by performing synthesis in the same manner as in Synthesis Example 1-1-c, except that Compound BH 1-7-b was used instead of Compound BH 1-1-b.

<1-7-d> Synthesis of Compound BH 1-7

After 50 g of Compound BH 1-7-c, 10 g of 5 wt. % Pt/C, 300 ml of toluene, and 700 ml of D20 were put into a high-pressure reactor, the reactor was filled with hydrogen. After the temperature was increased to 180° C., the reaction was carried out for 24 hours. After completion of the reaction, the catalyst was filtered through a celite pad and then extracted. 38 g of BH 1-7 was obtained through recrystallization with tetrahydrofuran/ethyl acetate (THF/EA). (Yield 73%). [M+H]=585.3

### Synthesis Example 1-8. Synthesis of Compound BH 1-8

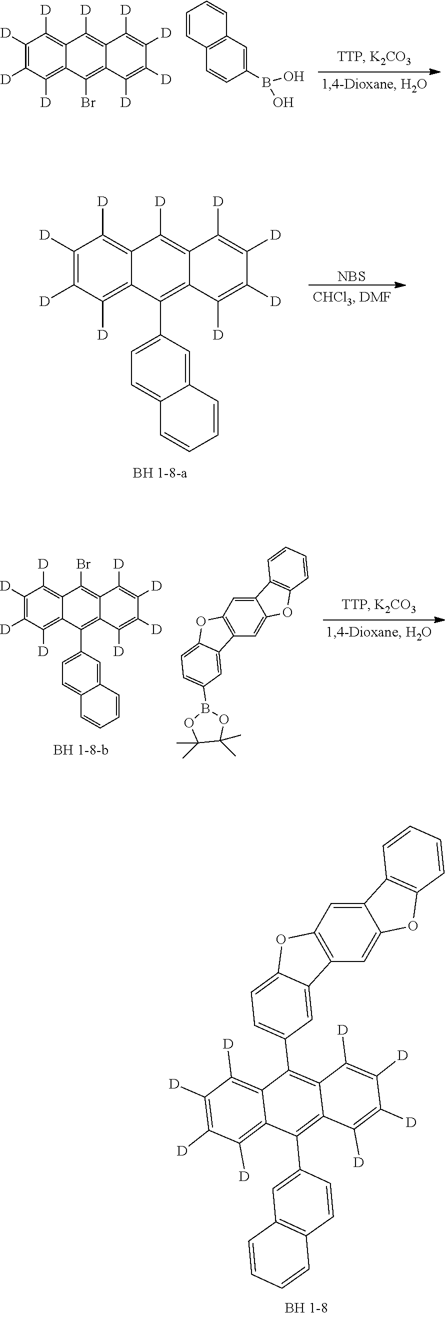

<1-8-a> Synthesis of Compound BH 1-8-a

Compound BH 1-8-a was obtained by performing synthesis in the same manner as in Synthesis Example 1-1-a, except that naphthalen-2-yl boronic acid was used instead of phenylboronic acid.

<1-8-b> Synthesis of Compound BH 1-8-b

BH 1-8-b was obtained by performing synthesis in the same manner as in Synthesis Example 1-1-b, except that Compound BH 1-8-a was used instead of Compound BH 1-1-a.

<1-8-c> Synthesis of Compound BH 1-8

BH 1-8 was obtained by performing synthesis in the same manner as in Synthesis Example 1-1-c, except that Compound BH 1-8-b and 2-(4,4,5,5-tetramethyl-1,3,2-dioxaborolan-2-yl)benzo[1,2-b:4,5-b′]bisbenzofuran were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=567.2

### Synthesis Example 1-9. Synthesis of Compound BH 1-9

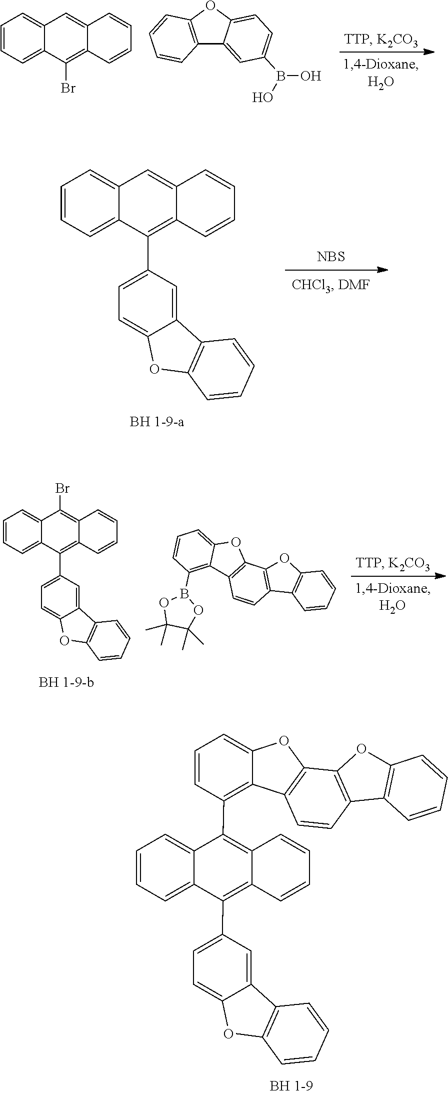

<1-9-a> Synthesis of Compound BH 1-9-a

Compound BH 1-9-a was obtained by performing synthesis in the same manner as in Synthesis Example 1-1-a, except that 9-bromoanthracene and dibenzo[b,c]furan-2-yl boronic acid were used instead of 9-bromoanthracene-1,2,3,4,5,6,7,8,10-d9 and phenylboronic acid, respectively.

<1-9-b> Synthesis of Compound BH 1-9-b

BH 1-9-b was obtained by performing synthesis in the same manner as in Synthesis Example 1-1-b, except that Compound BH 1-9-a was used instead of Compound BH 1-1-a.

<1-9-c> Synthesis of Compound BH 1-9

BH 1-9 was obtained by performing synthesis in the same manner as in Synthesis Example 1-1-c, except that Compound BH 1-9-b and 4-(4,4,5,5-tetramethyl-1,3,2-dioxaborolan-2-yl)benzo[2,1-b:3,4-b′]bisbenzofuran were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=601.2

### Synthesis Example 1-10. Synthesis of Compound BH 1-10

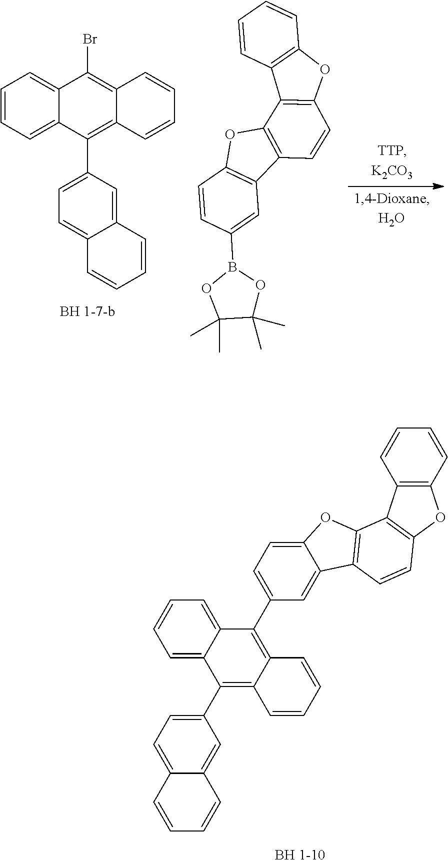 [SMILES: Brc1c2ccccc2c(-c2ccc3ccccc3c2)c2ccccc12 ; CC1(C)OB(c2ccc3oc4c(ccc5oc6ccccc6c54)c3c2)OC1(C)C ; c1ccc2cc(-c3c4ccccc4c(-c4ccc5oc6c(ccc7oc8ccccc8c76)c5c4)c4ccccc34)ccc2c1]

BH 1-10 was obtained by performing synthesis in the same manner as in Synthesis Example 1-1-c, except that Compound BH 1-7-b and 9-(4,4,5,5-tetramethyl-1,3,2-dioxaborolan-2-yl)benzo[2,1-b:3,4-b′]bisbenzofuran were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=561.2

### Synthesis Example 1-11. Synthesis of Compound BH 1-11

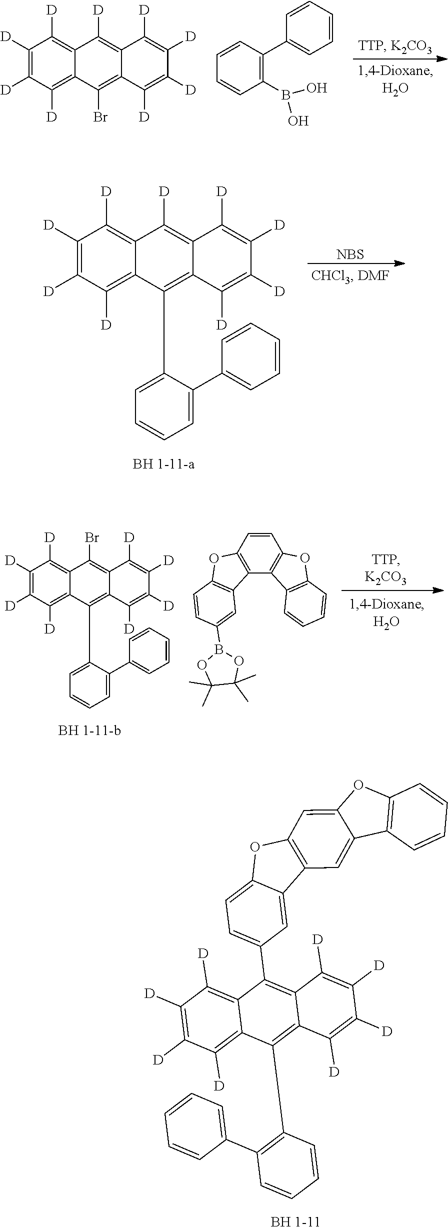

<1-11-a> Synthesis of Compound BH 1-11-a

Compound BH 1-11-a was obtained by performing synthesis in the same manner as in Synthesis Example 1-1-a, except that [1,1′-biphenyl]-2-ylboronic acid was used instead of phenylboronic acid.

<1-11-b> Synthesis of Compound BH 1-11-b

BH 1-11-b was obtained by performing synthesis in the same manner as in Synthesis Example 1-1-b, except that Compound BH 1-11-a was used instead of Compound BH 1-1-a.

<1-11-c> Synthesis of Compound BH 1-11

BH 1-11 was obtained by performing synthesis in the same manner as in Synthesis Example 1-1-c, except that Compound BH 1-11-b was used instead of Compound BH 1-1-b. [M+H]=595.2

### Synthesis Example 1-12. Synthesis of Compound BH 1-12

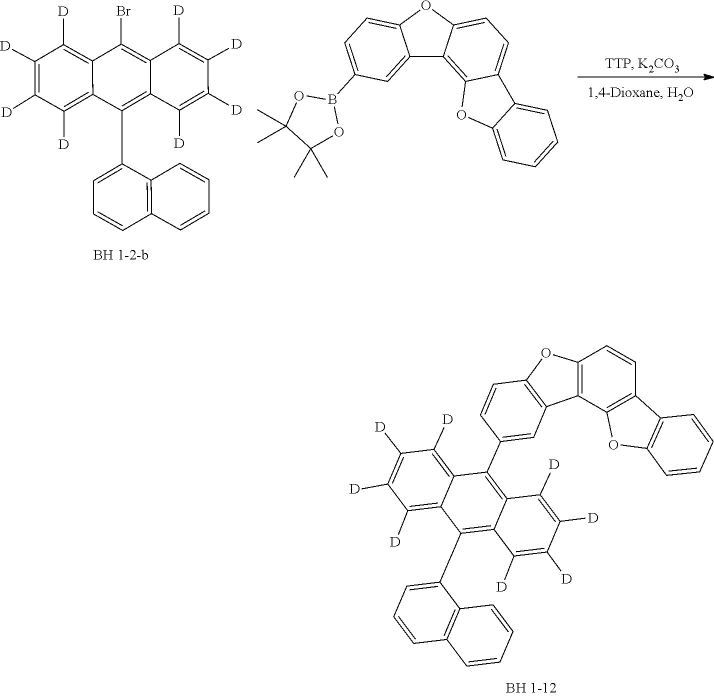

BH 1-12 was obtained by performing synthesis in the same manner as in Synthesis Example 1-1-c, except that Compound BH 1-2-b and 2-(4,4,5,5-tetramethyl-1,3,2-dioxaborolan-2-yl)benzo[1,2-b:3,4-b′]bisbenzofuran were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=569.2

### Synthesis Example 1-13. Synthesis of Compound BH 1-13

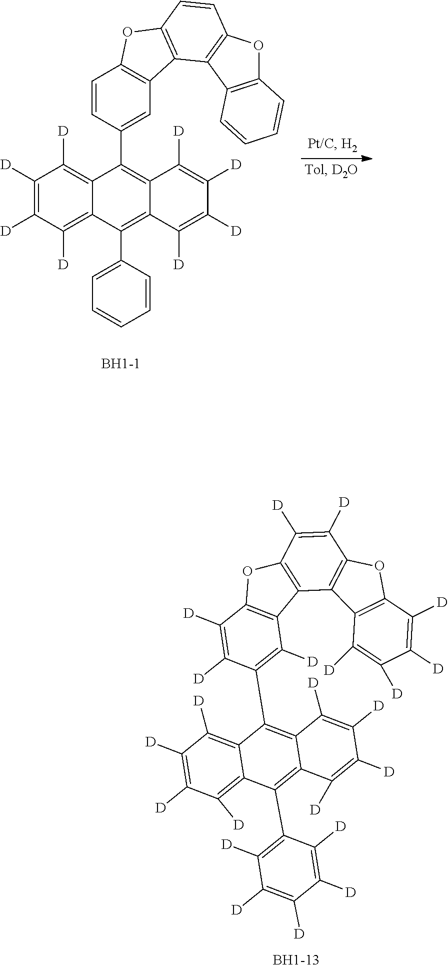

Compound BH 1-13 was obtained by performing synthesis in the same manner as in Synthesis Example 1-7-d, except that Compound BH 1-1 was used instead of Compound BH 1-7-c. [M+H]=533.3

### Synthesis Example 1-14. Synthesis of Compound BH 1-14

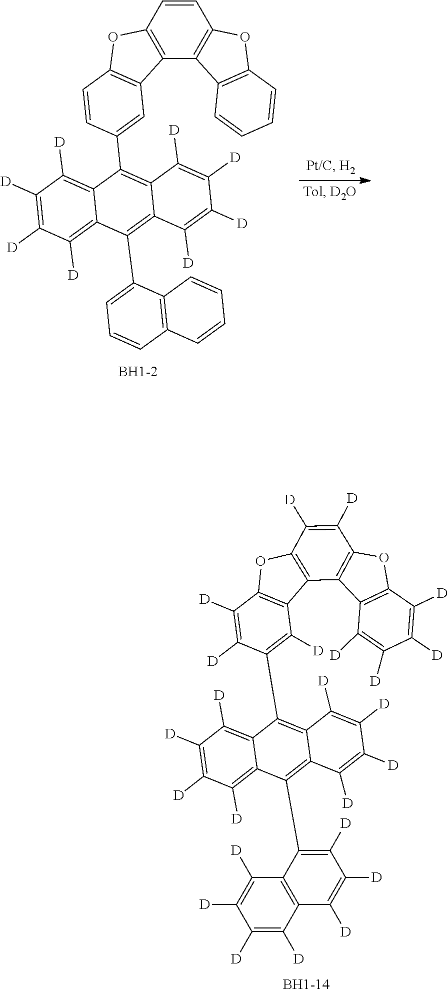

Compound BH 1-14 was obtained by performing synthesis in the same manner as in Synthesis Example 1-7-d, except that Compound BH 1-2 was used instead of Compound BH 1-7-c. [M+H]=585.3

### Synthesis Example 1-15. Synthesis of Compound BH 1-15

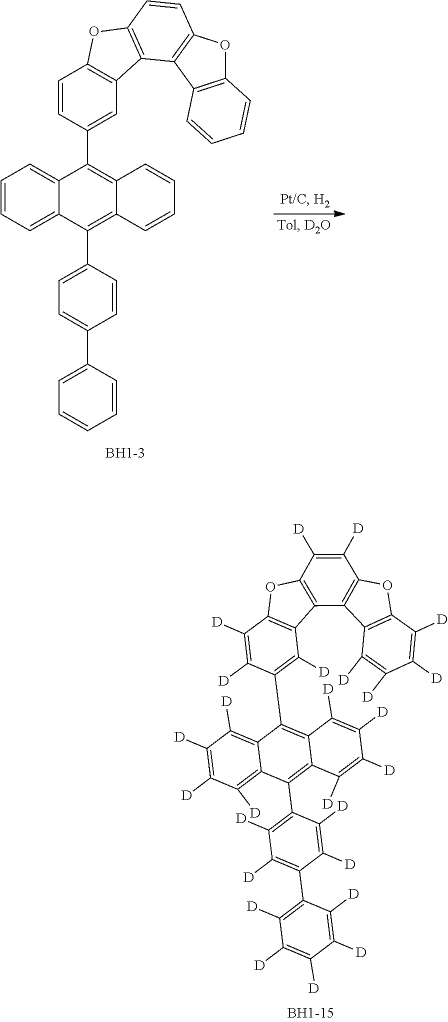

Compound BH 1-15 was obtained by performing synthesis in the same manner as in Synthesis Example 1-7-d, except that Compound BH 1-3 was used instead of Compound BH 1-7-c. [M+H]=613.4

### Synthesis Example 1-16. Synthesis of Compound BH 1-16

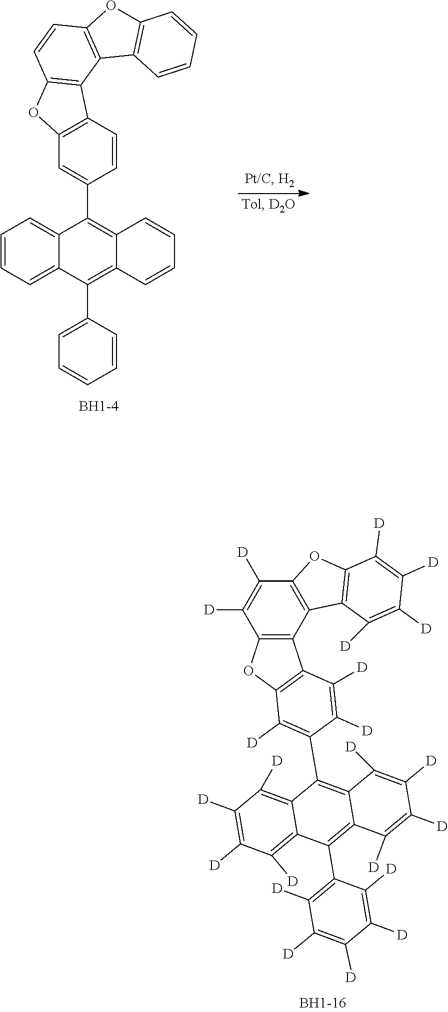

Compound BH 1-16 was obtained by performing synthesis in the same manner as in Synthesis Example 1-7-d, except that Compound BH 1-4 was used instead of Compound BH 1-7-c. [M+H]=533.3

### Synthesis Example 2-1. Synthesis of Compound BH 2-1

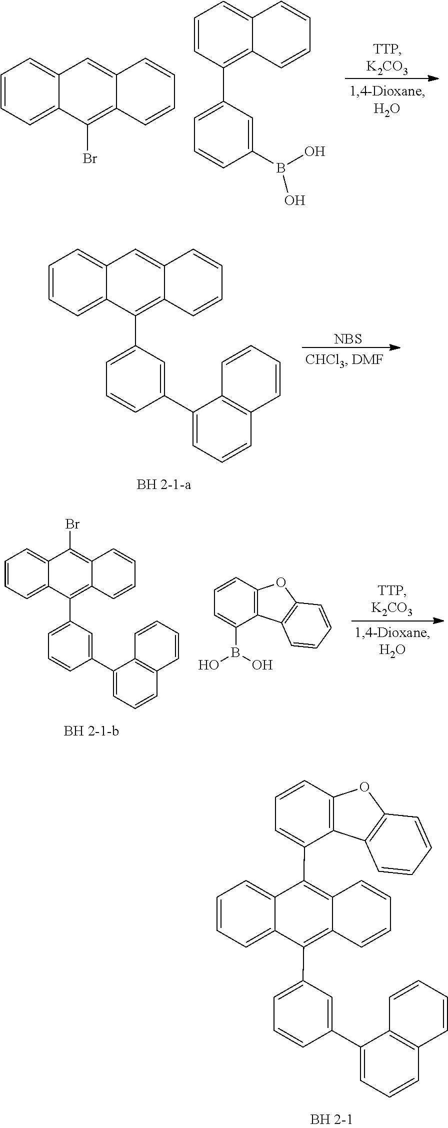

<2-1-a> Synthesis of Compound BH 2-1-a

Compound BH 1-1-a was obtained by performing synthesis in the same manner as in Synthesis Example 1-1-a, except that 9-bromoanthracene and (3-(naphthalen-1-yl)phenyl)boronic acid were used instead of 9-bromoanthracene-1,2,3,4,5,6,7,8,10-d9 and phenylboronic acid, respectively.

<2-1-b> Synthesis of Compound BH 2-1-b

BH 2-1-b was obtained by performing synthesis in the same manner as in Synthesis Example 1-1-b, except that Compound BH 2-1-a was used instead of Compound BH 1-1-a.

<2-1-c> Synthesis of Compound BH 2-1

BH 2-1 was obtained by performing synthesis in the same manner as in Synthesis Example 1-1-c, except that Compound BH 2-1-b and dibenzo[b,d]furan-1-ylboronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=547.2

### Synthesis Example 2-2. Synthesis of Compound BH 2-2

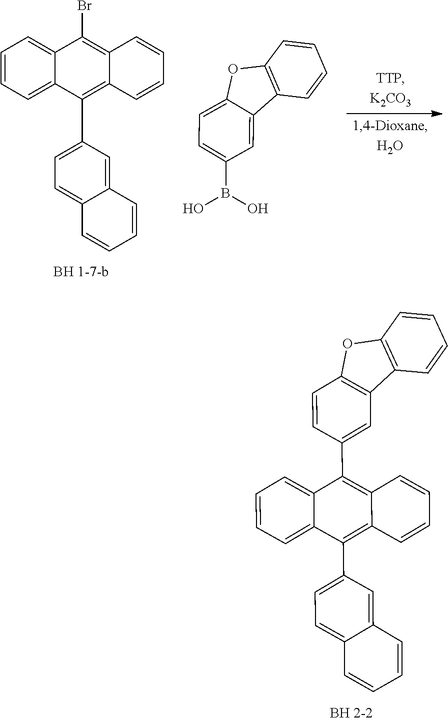 [SMILES: Brc1c2ccccc2c(-c2ccc3ccccc3c2)c2ccccc12 ; OB(O)c1ccc2oc3ccccc3c2c1 ; c1ccc2cc(-c3c4ccccc4c(-c4ccc5oc6ccccc6c5c4)c4ccccc34)ccc2c1]

BH 2-2 was obtained by performing synthesis in the same manner as in Synthesis Example 1-1-c, except that Compound BH 1-7-b and dibenzo[b,d]furan-2-ylboronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=471.2

### Synthesis Example 2-3. Synthesis of Compound BH 2-3

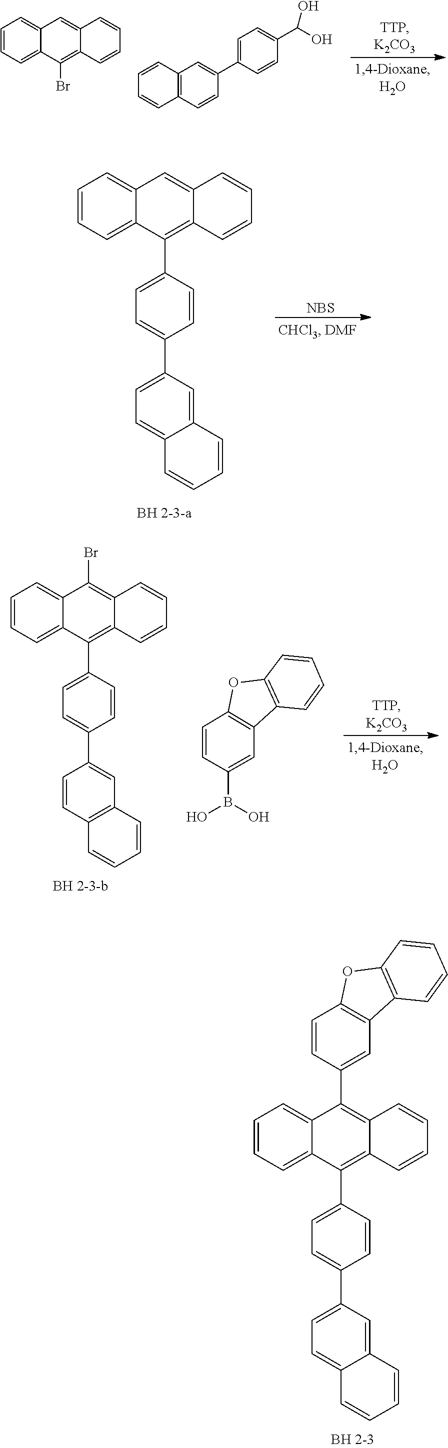

<2-3-a> Synthesis of Compound BH 2-3-a

Compound BH 2-3-a was obtained by performing synthesis in the same manner as in Synthesis Example 1-1-a, except that 9-bromoanthracene and (4-(naphthalen-2-yl)phenyl)boronic acid were used instead of 9-bromoanthracene-1,2,3,4,5,6,7,8,10-d9 and phenylboronic acid, respectively.

<2-3-b> Synthesis of Compound BH 2-3-b

BH 2-3-b was obtained by performing synthesis in the same manner as in Synthesis Example 1-1-b, except that Compound BH 2-3-a was used instead of Compound BH 1-1-a.

<2-3-c> Synthesis of Compound BH 2-3

BH 2-3 was obtained by performing synthesis in the same manner as in Synthesis Example 1-1-c, except that Compound BH 2-3-b and dibenzo[b,d]furan-2-ylboronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=547.2

### Synthesis Example 2-4. Synthesis of Compound BH 2-4

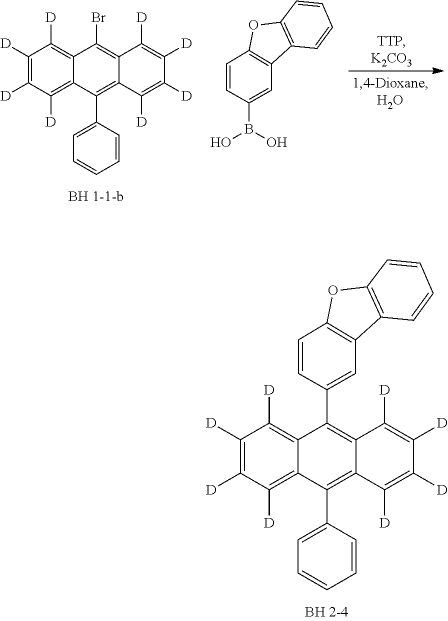 [SMILES: [2H]c1c([2H])c([2H])c2c(-c3ccccc3)c3c([2H])c([2H])c([2H])c([2H])c3c(Br)c2c1[2H] ; OB(O)c1ccc2oc3ccccc3c2c1 ; [2H]c1c([2H])c([2H])c2c(-c3ccc4oc5ccccc5c4c3)c3c([2H])c([2H])c([2H])c([2H])c3c(-c3ccccc3)c2c1[2H]]

BH 2-4 was obtained by performing synthesis in the same manner as in Synthesis Example 1-1-c, except that dibenzo[b,d]furan-2-ylboronic acid was used instead of 2-(4,4,5,5-tetramethyl-1,3,2-dioxaborolan-2-yl)benzo[1,2-b:4,3-b′]-bisbenzofuran. [M+H]=429.2

### Synthesis Example 2-5. Synthesis of Compound BH 2-5

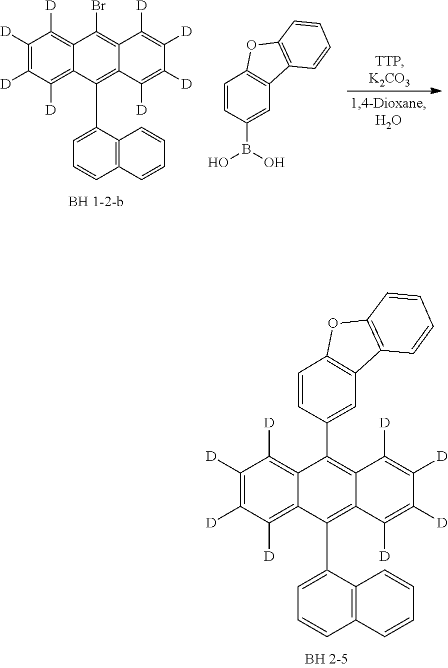

BH 2-5 was obtained by performing synthesis in the same manner as in Synthesis Example 1-1-c, except that Compound BH 1-2-b and dibenzo[b,d]furan-2-ylboronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=479.2

### Synthesis Example 2-6. Synthesis of Compound BH 2-6

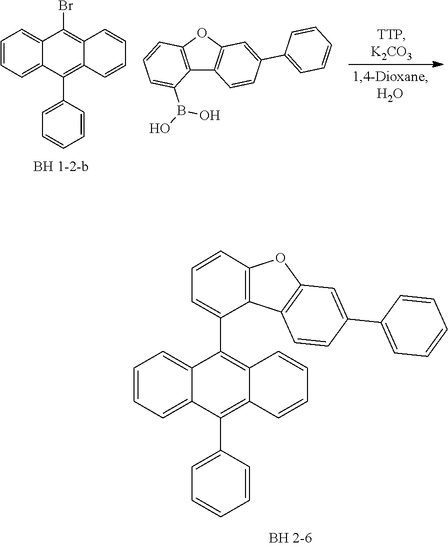

BH 2-6 was obtained by performing synthesis in the same manner as in Synthesis Example 1-1-c, except that Compound BH 1-4-b and (7-phenyldibenzo[b,d]furan-1-yl)boronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=497.2

### Synthesis Example 2-7. Synthesis of Compound BH 2-7

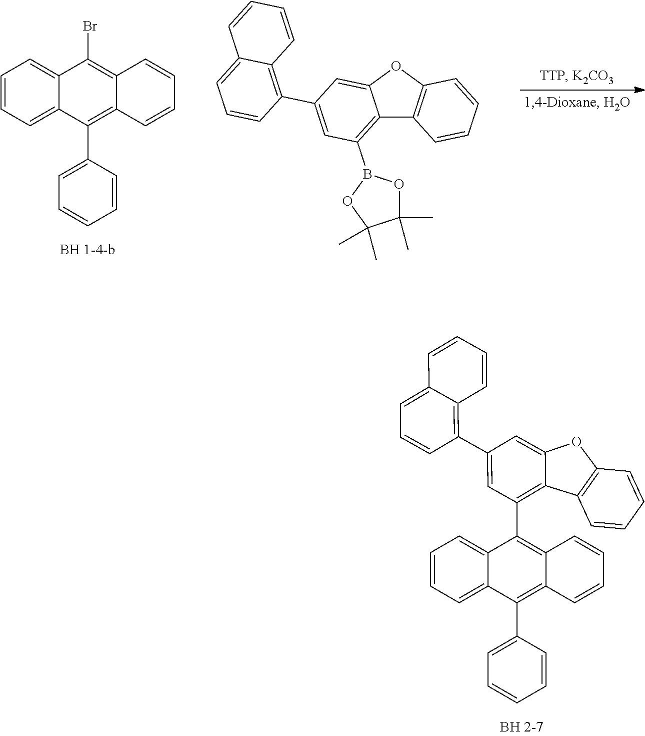

BH 2-7 was obtained by performing synthesis in the same manner as in Synthesis Example 1-1-c, except that Compound BH 1-4-b and 4,4,5,5-tetramethyl-2-(3-(naphthalen-1-yl)dibenzo[b,d]furan-1-yl-1,3,2-borolane were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=547.2

### Synthesis Example 2-8. Synthesis of Compound BH 2-8

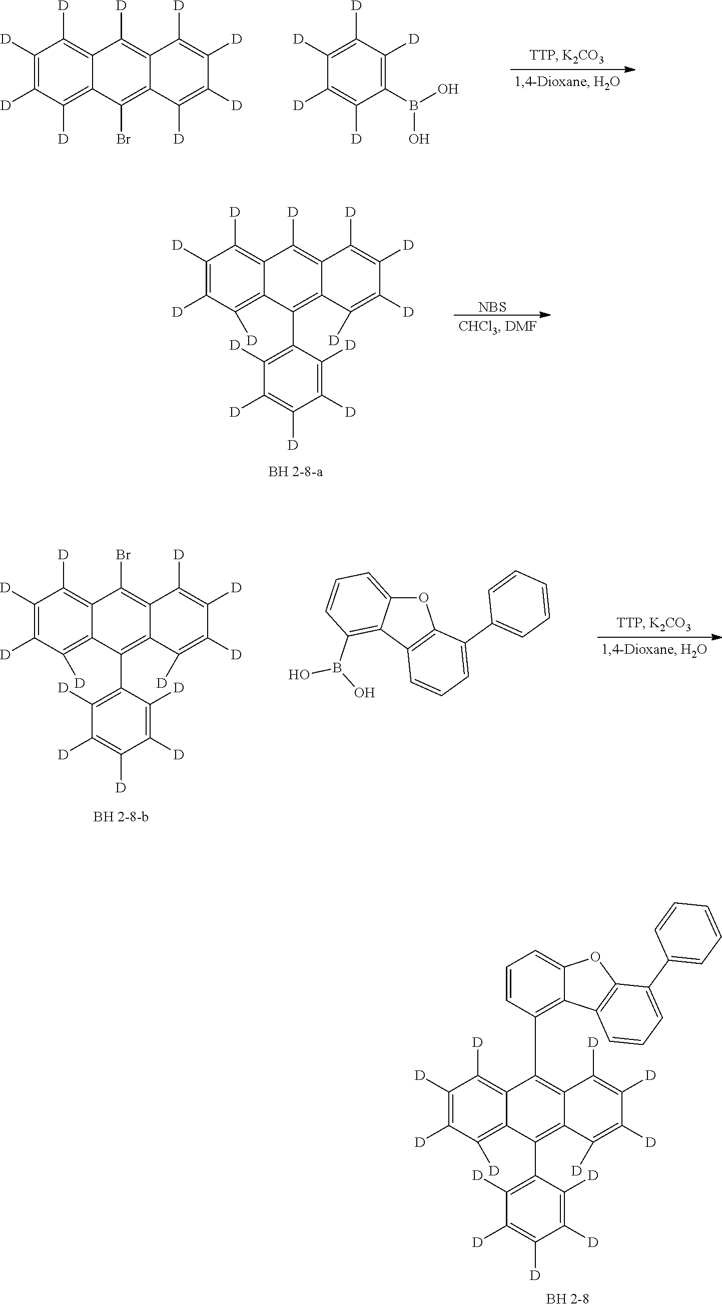

<2-8-a> Synthesis of Compound BH 2-8-a

Compound BH 2-8-a was obtained by performing synthesis in the same manner as in Synthesis Example 1-1-a, except that (phenyl-d5)boronic acid was used instead of phenylboronic acid.

<2-8-b> Synthesis of Compound BH 2-8-b

BH 2-8-b was obtained by performing synthesis in the same manner as in Synthesis Example 1-1-b, except that Compound BH 2-8-a was used instead of Compound BH 1-1-a.

<2-8-c> Synthesis of Compound BH 2-8

BH 2-8 was obtained by performing synthesis in the same manner as in Synthesis Example 1-1-c, except that Compound BH 2-8-b and (6-phenyldibenzo[b,d]furan-1-yl)boronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=510.3

### Synthesis Example 2-9. Synthesis of Compound BH 2-9

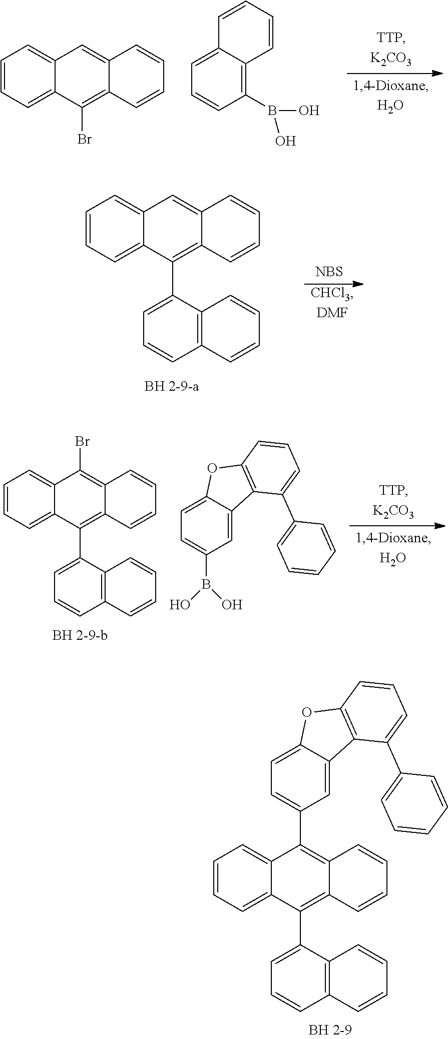

<2-9-a> Synthesis of Compound BH 2-3-a

Compound BH 2-9-a was obtained by performing synthesis in the same manner as in Synthesis Example 1-1-a, except that 9-bromoanthracene and naphthalen-1-ylboronic acid were used instead of 9-bromoanthracene-1,2,3,4,5,6,7,8,10-d9 and phenylboronic acid, respectively.

<2-9-b> Synthesis of Compound BH 2-9-b

BH 2-9-b was obtained by performing synthesis in the same manner as in Synthesis Example 1-1-b, except that Compound BH 2-9-a was used instead of Compound BH 1-1-a.

<2-9-c> Synthesis of Compound BH 2-9

BH 2-9 was obtained by performing synthesis in the same manner as in Synthesis Example 1-1-c, except that Compound BH 2-9-b and (9-phenyldibenzo[b,d]furan-2-yl)boronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=547.2

### Synthesis Example 2-10. Synthesis of Compound BH 2-10

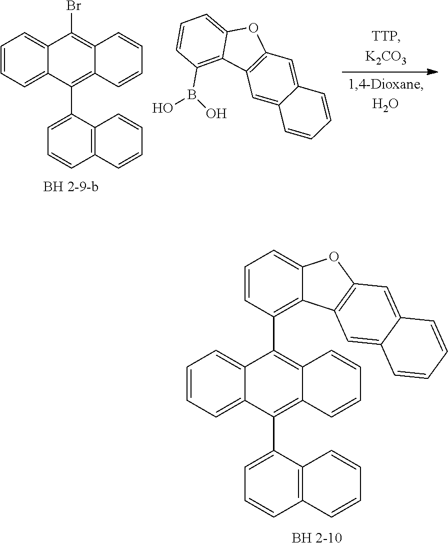

BH 2-10 was obtained by performing synthesis in the same manner as in Synthesis Example 1-1-c, except that Compound BH 2-9-b and naphtho[2,3-b]benzofuran-1-ylboronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=521.2

### Synthesis Example 2-11. Synthesis of Compound BH 2-11

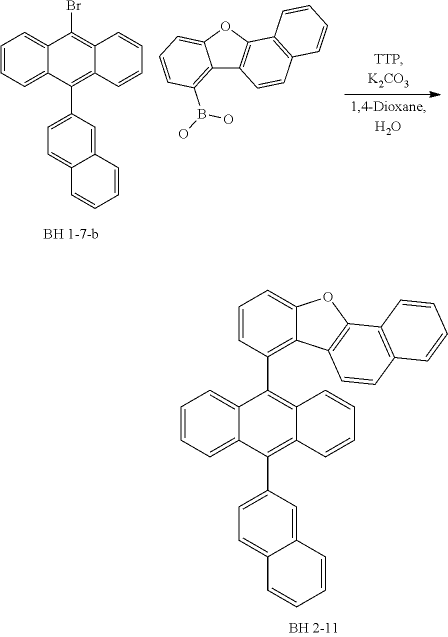

BH 2-11 was obtained by performing synthesis in the same manner as in Synthesis Example 1-1-c, except that Compound BH 1-7-b and naphtho[1,2-b]benzofuran-7-ylboronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=521.2

### Synthesis Example 2-12. Synthesis of Compound BH 2-12

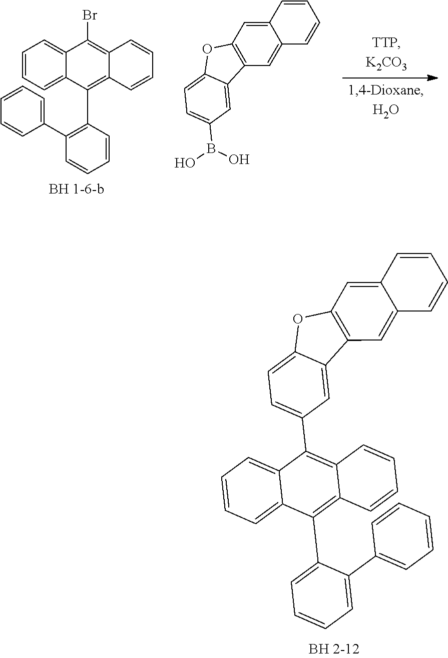

BH 2-12 was obtained by performing synthesis in the same manner as in Synthesis Example 1-1-c, except that Compound BH 1-6-b and naphtho[2,3-b]benzofuran-2-ylboronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=547.2

### Synthesis Example 2-13. Synthesis of Compound BH 2-13

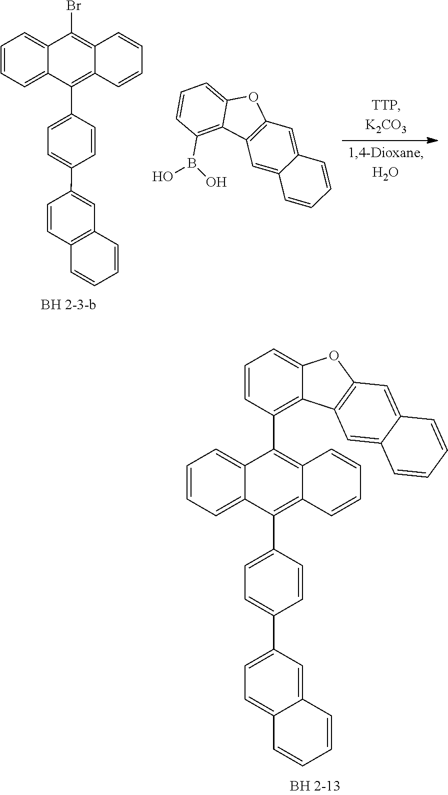 [SMILES: Brc1c2ccccc2c(-c2ccc(-c3ccc4ccccc4c3)cc2)c2ccccc12 ; OB(O)c1cccc2oc3cc4ccccc4cc3c12 ; c1ccc2cc(-c3ccc(-c4c5ccccc5c(-c5cccc6oc7cc8ccccc8cc7c56)c5ccccc45)cc3)ccc2c1]

BH 2-13 was obtained by performing synthesis in the same manner as in Synthesis Example 1-1-c, except that Compound BH 2-3-b and naphtho[2,3-b]benzofuran-1-ylboronic acid were used instead of Compound BH 1-1-b and 2-(4,4,5,5-tetramethyl-1,3,2-dioxaborolan-2-yl)benzo[1,2-b:4,3-b′]bisbenzofuran, respectively. [M+H]=597.2

### Synthesis Example 2-14. Synthesis of Compound BH 2-14

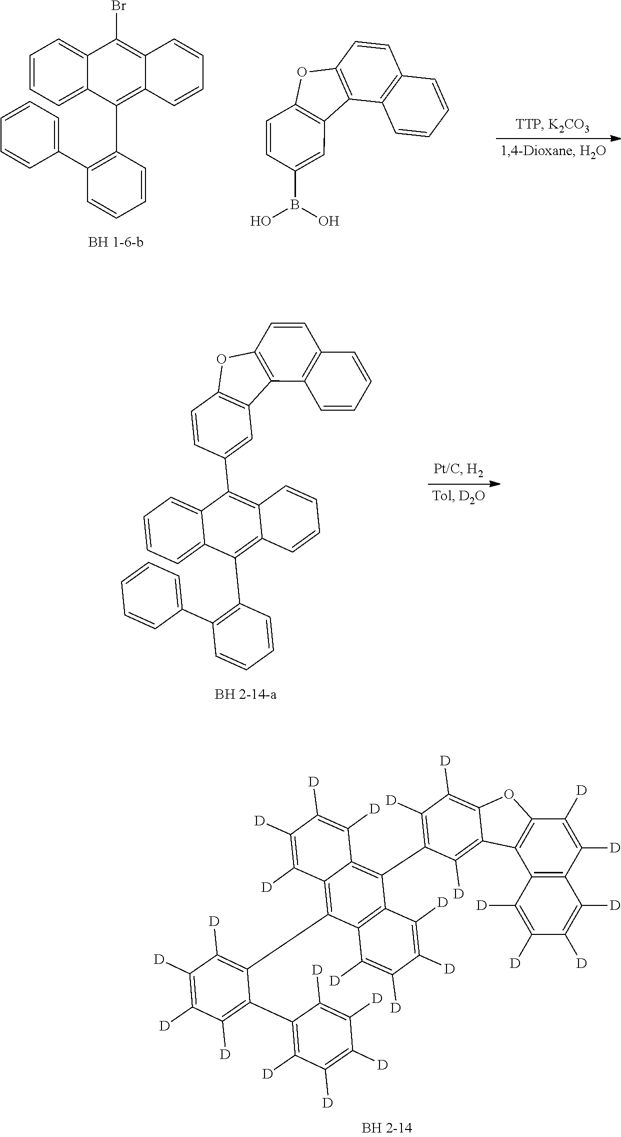 [SMILES: Brc1c2ccccc2c(-c2ccccc2-c2ccccc2)c2ccccc12 ; OB(O)c1ccc2oc3ccc4ccccc4c3c2c1 ; c1ccc(-c2ccccc2-c2c3ccccc3c(-c3ccc4oc5ccc6ccccc6c5c4c3)c3ccccc23)cc1 ; [2H]c1c([2H])c([2H])c(-c2c([2H])c([2H])c([2H])c([2H])c2-c2c3c([2H])c([2H])c([2H])c([2H])c3c(-c3c([2H])c([2H])c4oc5c([2H])c([2H])c6c([2H])c([2H])c([2H])c([2H])c6c5c4c3[2H])c3c([2H])c([2H])c([2H])c([2H])c23)c([2H])c1[2H]]

<2-14-a> Synthesis of Compound BH 2-14-a

BH 2-14-a was obtained by performing synthesis in the same manner as in Synthesis Example 1-1-c, except that Compound BH 1-6-b and naphtho[2,1-b]benzofuran-10-ylboronic acid were used instead of Compound BH 1-1-b and 2-(4,4,5,5-tetramethyl-1,3,2-dioxaborolan-2-yl)benzo[1,2-b:4,3-b′]bisbenzofuran, respectively.

<2-14-b> Synthesis of Compound BH 2-14

BH 2-14 was obtained by performing synthesis in the same manner as in Synthesis Example 1-7-d, except that Compound BH 2-14-a was used instead of Compound BH 1-7-c. [M+H]=572.4

### Synthesis Example 2-15. Synthesis of Compound BH 2-15

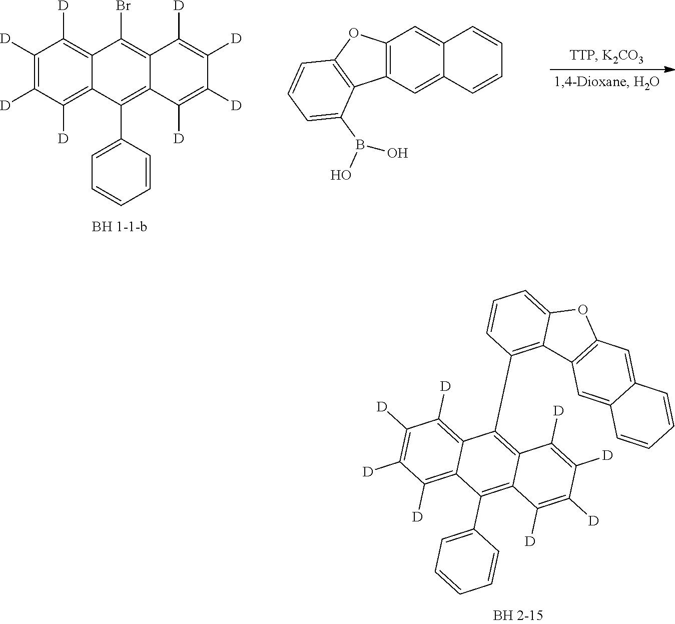 [SMILES: [2H]c1c([2H])c([2H])c2c(-c3ccccc3)c3c([2H])c([2H])c([2H])c([2H])c3c(Br)c2c1[2H] ; OB(O)c1cccc2oc3cc4ccccc4cc3c12 ; [2H]c1c([2H])c([2H])c2c(-c3cccc4oc5cc6ccccc6cc5c34)c3c([2H])c([2H])c([2H])c([2H])c3c(-c3ccccc3)c2c1[2H]]

BH 2-15 was obtained by performing synthesis in the same manner as in Synthesis Example 1-1-c, except that naphtho[2,3-b]benzofuran-1-ylboronic acid was used instead of 2-(4,4,5,5-tetramethyl-1,3,2-dioxaborolan-2-yl)benzo[1,2-b:4,3-b′]bisbenzofuran. [M+H]=479.2

### Synthesis Example 2-16. Synthesis of Compound BH 2-16

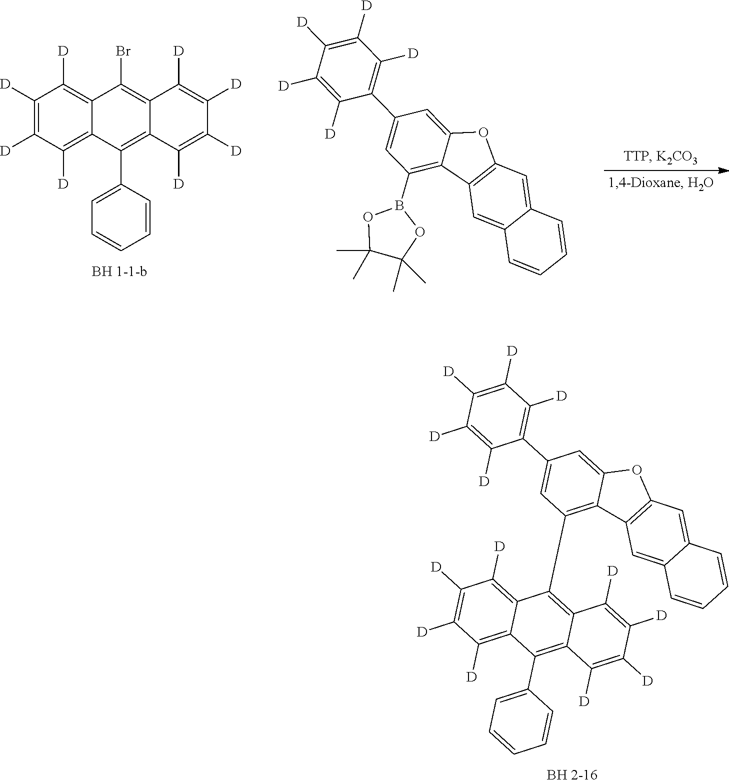 [SMILES: [2H]c1c([2H])c([2H])c2c(-c3ccccc3)c3c([2H])c([2H])c([2H])c([2H])c3c(Br)c2c1[2H] ; [2H]c1c([2H])c([2H])c(-c2cc(B3OC(C)(C)C(C)(C)O3)c3c(c2)oc2cc4ccccc4cc23)c([2H])c1[2H] ; [2H]c1c([2H])c([2H])c(-c2cc(-c3c4c([2H])c([2H])c([2H])c([2H])c4c(-c4ccccc4)c4c([2H])c([2H])c([2H])c([2H])c34)c3c(c2)oc2cc4ccccc4cc23)c([2H])c1[2H]]

BH 2-16 was obtained by performing synthesis in the same manner as in Synthesis Example 1-1-c, except that 4,4,5,5-tetramethyl-2-(3-phenyl-d5)naphtho[2,3-b]benzofuran-1-yl)-1,3,2-dioxaborolane was used instead of 2-(4,4,5,5-tetramethyl-1,3,2-dioxaborolan-2-yl)benzo[1,2-b:4,3-b′]bisbenzofuran. [M+H]=560.3

### Synthesis Example 2-17. Synthesis of Compound BH 2-17

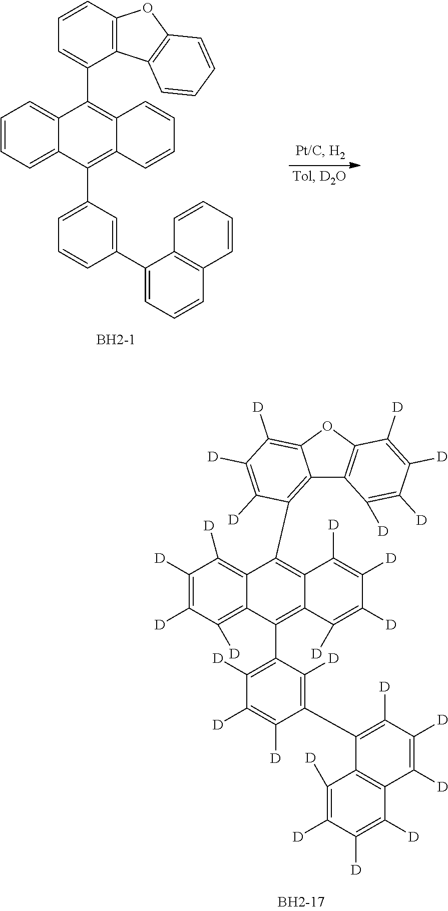

Compound BH 2-17 was obtained by performing synthesis in the same manner as in Synthesis Example 1-7-d, except that Compound BH 2-1 was used instead of Compound BH 1-7-c. [M+H]=573.4

### Synthesis Example 2-18. Synthesis of Compound BH 2-18

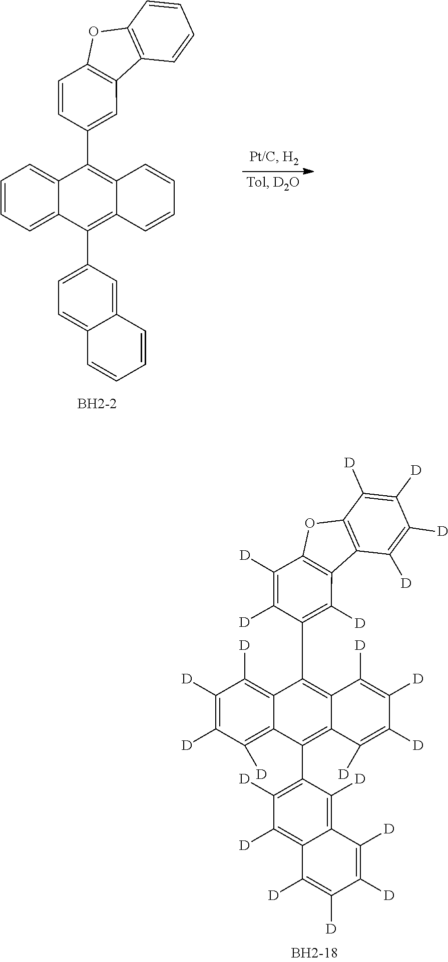

Compound BH 2-18 was obtained by performing synthesis in the same manner as in Synthesis Example 1-7-d, except that Compound BH 2-2 was used instead of Compound BH 1-7-c. [M+H]=493.3

### Synthesis Example 2-19. Synthesis of Compound BH 2-19

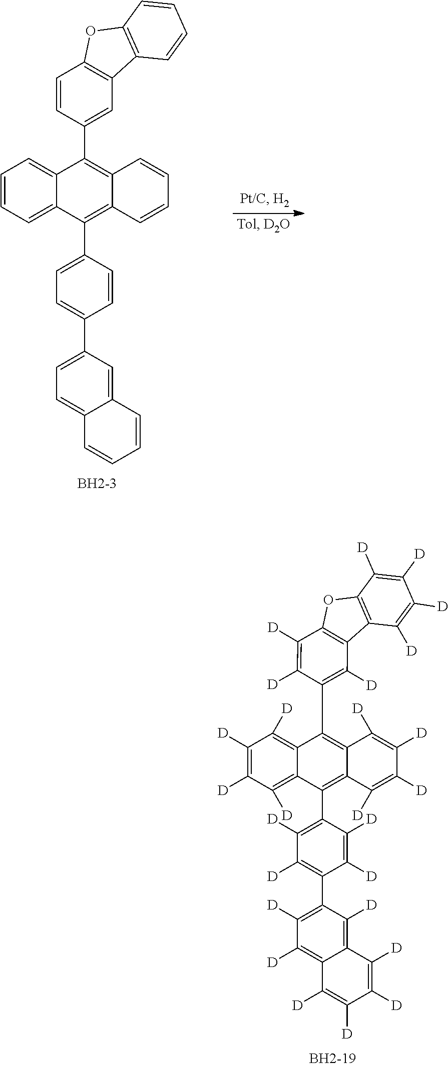

Compound BH 2-19 was obtained by performing synthesis in the same manner as in Synthesis Example 1-7-d, except that Compound BH 2-3 was used instead of Compound BH 1-7-c. [M+H]=573.4

### Synthesis Example 2-20. Synthesis of Compound BH 2-20

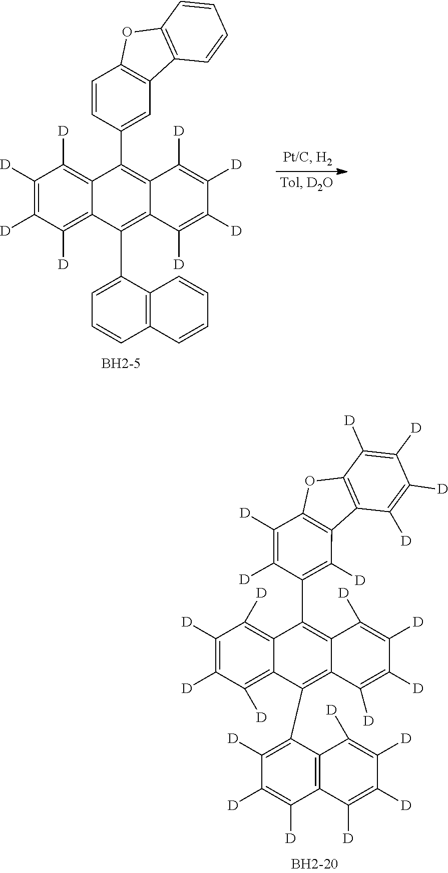

Compound BH 2-20 was obtained by performing synthesis in the same manner as in Synthesis Example 1-7-d, except that Compound BH 2-5 was used instead of Compound BH 1-7-c. [M+H]=493.3

### Experimental Examples

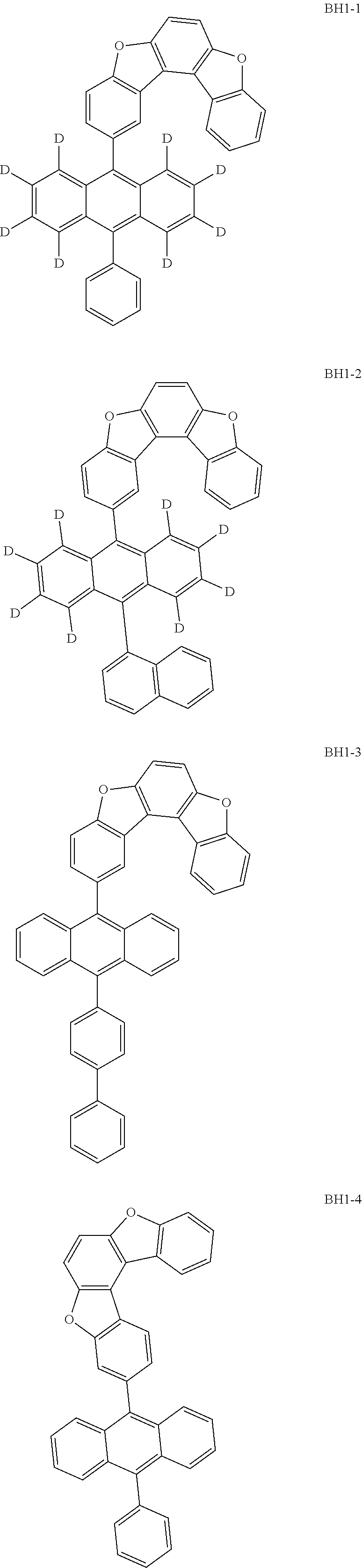 [SMILES: [2H]c1c([2H])c([2H])c2c(-c3ccc4oc5ccc6oc7ccccc7c6c5c4c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5ccc6oc7ccccc7c6c5c4c3)c2c1[2H] ; c1ccc(-c2ccc(-c3c4ccccc4c(-c4ccc5oc6ccc7oc8ccccc8c7c6c5c4)c4ccccc34)cc2)cc1 ; c1ccc(-c2c3ccccc3c(-c3ccc4c(c3)oc3ccc5oc6ccccc6c5c34)c3ccccc23)cc1]

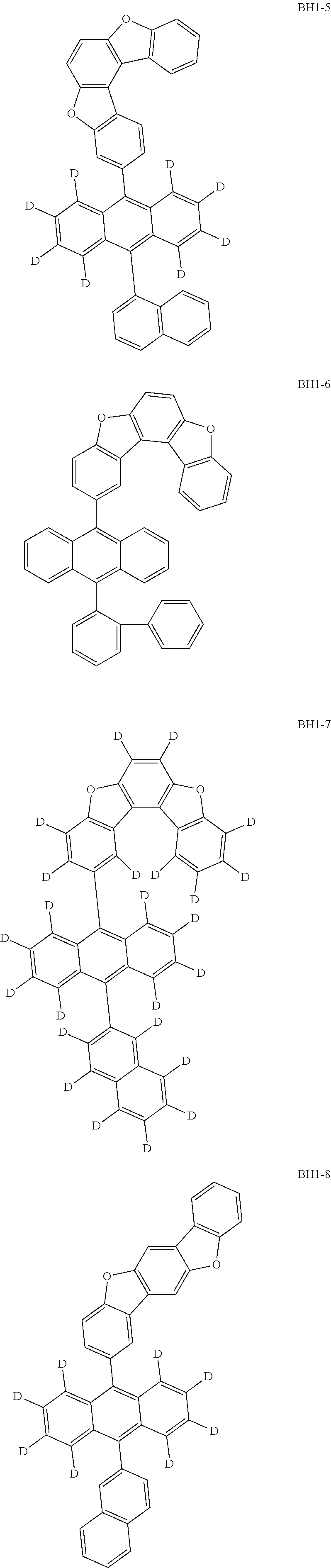

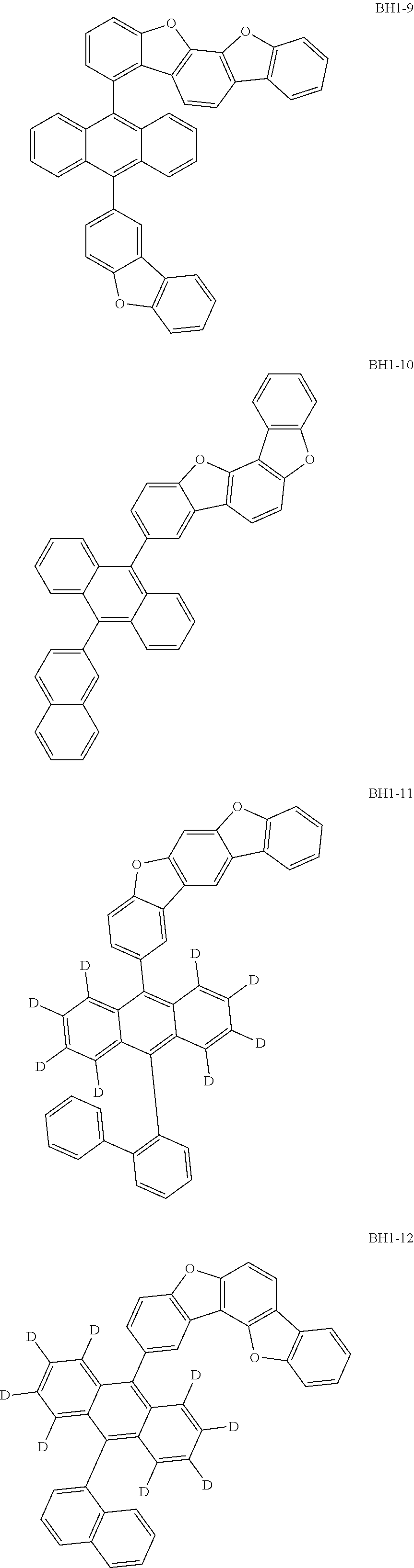 [SMILES: c1ccc2c(c1)oc1ccc(-c3c4ccccc4c(-c4cccc5oc6c(ccc7c8ccccc8oc76)c45)c4ccccc34)cc12 ; c1ccc2cc(-c3c4ccccc4c(-c4ccc5oc6c(ccc7oc8ccccc8c76)c5c4)c4ccccc34)ccc2c1 ; [2H]c1c([2H])c([2H])c2c(-c3ccccc3-c3ccccc3)c3c([2H])c([2H])c([2H])c([2H])c3c(-c3ccc4oc5cc6oc7ccccc7c6cc5c4c3)c2c1[2H] ; [2H]c1c([2H])c([2H])c2c(-c3cccc4ccccc34)c3c([2H])c([2H])c([2H])c([2H])c3c(-c3ccc4oc5ccc6c7ccccc7oc6c5c4c3)c2c1[2H]]

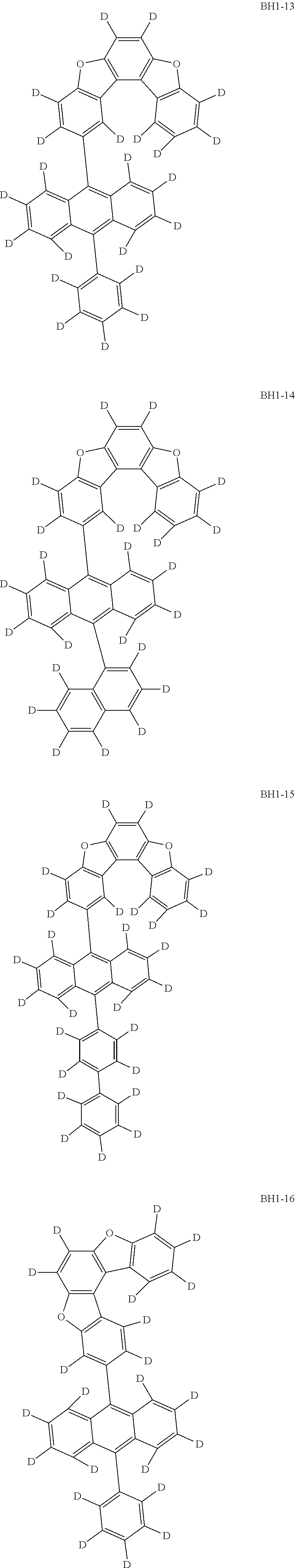

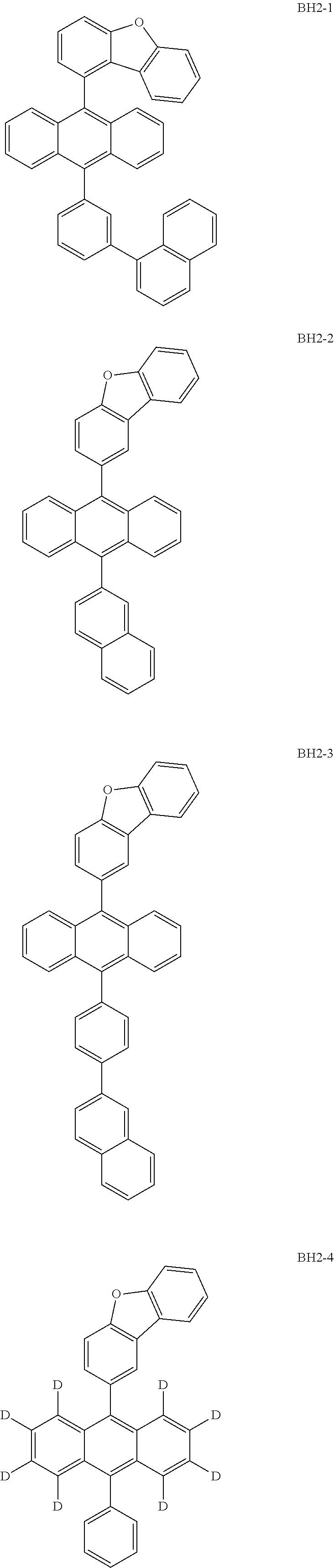

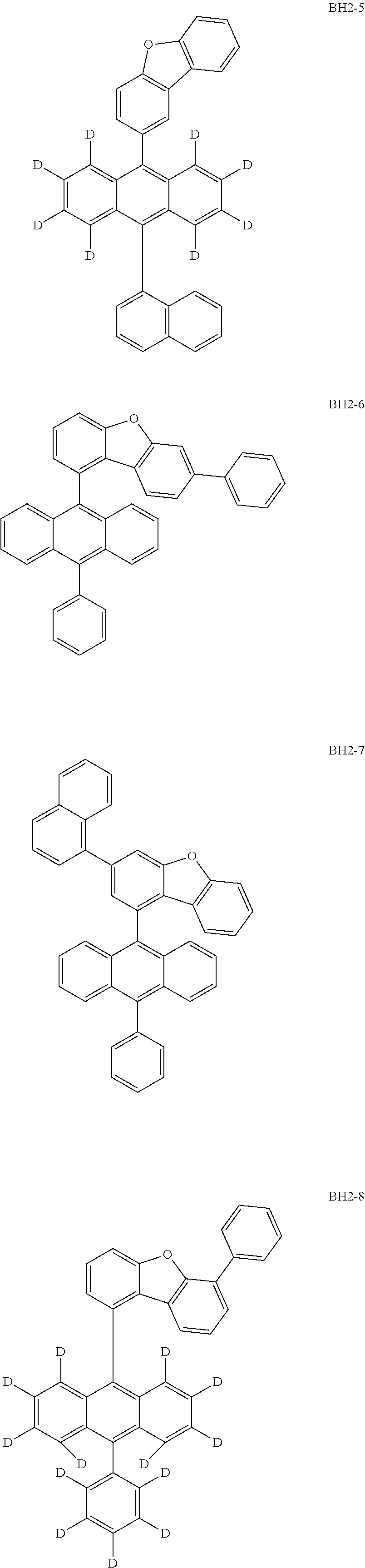 [SMILES: [2H]c1c([2H])c([2H])c2c(-c3cccc4ccccc34)c3c([2H])c([2H])c([2H])c([2H])c3c(-c3ccc4oc5ccccc5c4c3)c2c1[2H] ; c1ccc(-c2ccc3c(c2)oc2cccc(-c4c5ccccc5c(-c5ccccc5)c5ccccc45)c23)cc1 ; c1ccc(-c2c3ccccc3c(-c3cc(-c4cccc5ccccc45)cc4oc5ccccc5c34)c3ccccc23)cc1 ; [2H]c1c([2H])c([2H])c(-c2c3c([2H])c([2H])c([2H])c([2H])c3c(-c3cccc4oc5c(-c6ccccc6)cccc5c34)c3c([2H])c([2H])c([2H])c([2H])c23)c([2H])c1[2H]]

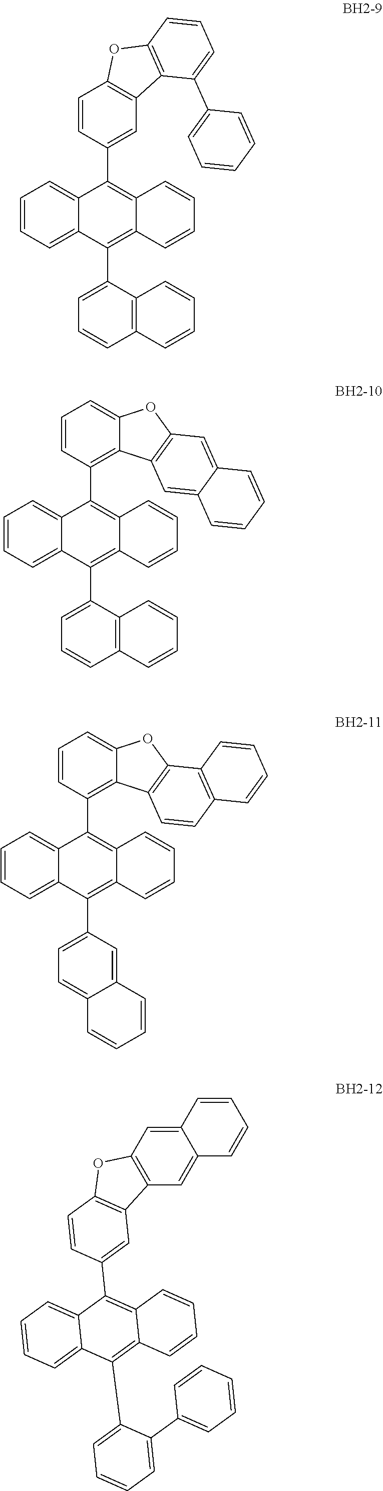 [SMILES: c1ccc(-c2cccc3oc4ccc(-c5c6ccccc6c(-c6cccc7ccccc67)c6ccccc56)cc4c23)cc1 ; c1ccc2cc3c(cc2c1)oc1cccc(-c2c4ccccc4c(-c4cccc5ccccc45)c4ccccc24)c13 ; c1ccc2cc(-c3c4ccccc4c(-c4cccc5oc6c7ccccc7ccc6c45)c4ccccc34)ccc2c1 ; c1ccc(-c2ccccc2-c2c3ccccc3c(-c3ccc4oc5cc6ccccc6cc5c4c3)c3ccccc23)cc1]

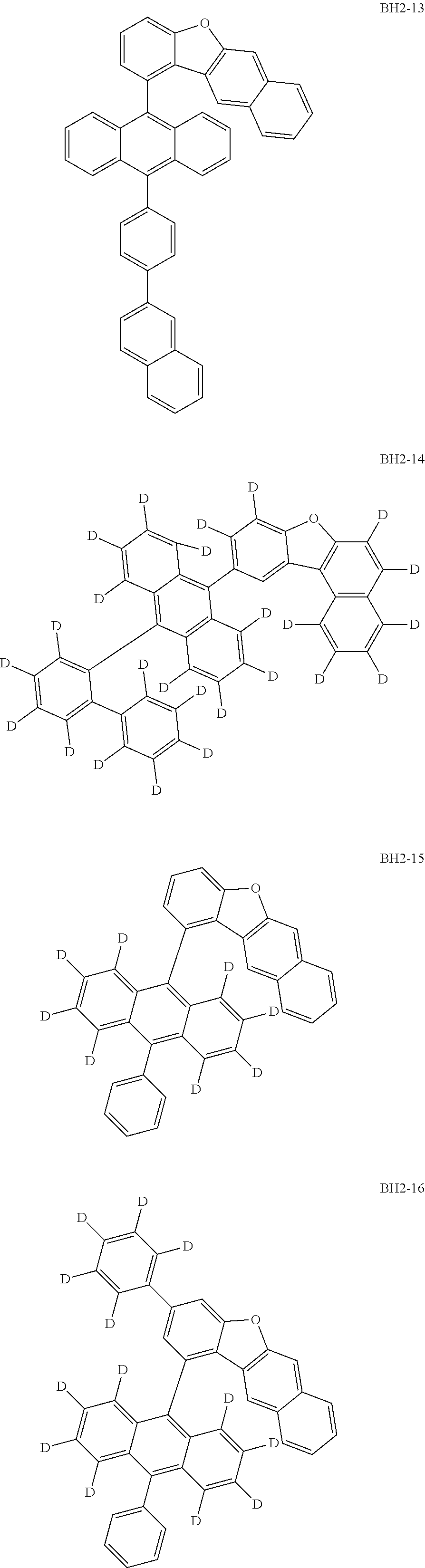

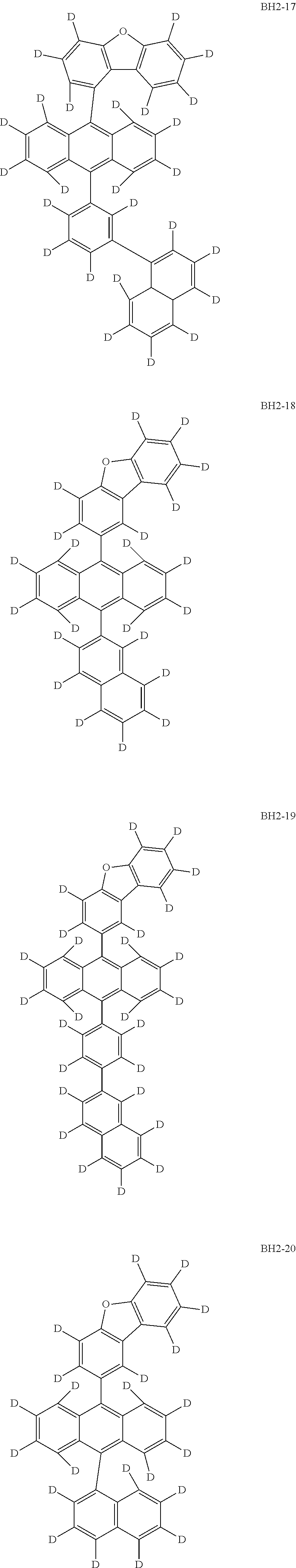

### Experimental Example 1

The evaporation temperatures of BH 1-1 to BH 1-16 and BH 2-1 to 2-20 prepared in the Preparation Examples were measured, and are shown in the following Table 1. The evaporation temperature was measured by thermal gravity analysis (TGA). The temperature at which a 1% weight loss of the sample occurs is called Td-1%, and deposition is performed at a temperature 60° C. to 80° C. lower than that temperature. The pressure at this time is within a range of 10⁻⁴ torr to 10⁻⁶ torr. The evaporation temperature may have fluidity within a scope which can be understood by those skilled in the art, and may comprise a variation range of ±10° C.

TABLE 1

| Compound | Evaporation Temperature (° C.) |
|---|---|
| BH 1-1 | 320 |
| BH 1-2 | 340 |
| BH 1-3 | 340 |
| BH 1-4 | 330 |
| BH 1-5 | 340 |
| BH 1-6 | 330 |
| BH 1-7 | 350 |
| BH 1-8 | 340 |
| BH 1-9 | 340 |
| BH 1-10 | 340 |
| BH 1-11 | 330 |
| BH 1-12 | 340 |
| BH 1-13 | 320 |
| BH 1-14 | 340 |
| BH 1-15 | 340 |
| BH 1-16 | 330 |
| BH 2-1 | 310 |
| BH 2-2 | 310 |
| BH 2-3 | 330 |
| BH 2-4 | 260 |
| BH 2-5 | 290 |
| BH 2-6 | 290 |
| BH 2-7 | 310 |
| BH 2-8 | 280 |
| BH 2-9 | 310 |
| BH 2-10 | 300 |
| BH 2-11 | 310 |
| BH 2-12 | 320 |
| BH 2-13 | 350 |
| BH 2-14 | 320 |
| BH 2-15 | 260 |
| BH 2-16 | 320 |
| BH 2-17 | 310 |
| BH 2-18 | 310 |
| BH 2-19 | 330 |
| BH 2-20 | 290 |

### Experimental Example 2

### Example 1

A substrate on which indium tin oxide (ITO)/Ag/ITO were deposited to have a thickness of 30 Å/1000 Å/70 Å as an anode was cut into a size of 50 mm×50 mm×0.5 mm, put in distilled water in which a detergent was dissolved, and ultrasonically cleaned. A product manufactured by Fischer Co., was used as the detergent, and distilled water twice filtered using a filter manufactured by Millipore Co., was used as the distilled water. After the ITO was washed for 30 minutes, ultrasonic washing was conducted twice repeatedly using distilled water for 10 minutes. After washing with distilled water, the substrate was ultrasonically washed using isopropyl alcohol, acetone, and methanol in this order, and then dried.

The following compound HAT-CN was thermally vacuum-deposited to have a thickness of 50 Å on the anode, thereby forming a hole injection layer, and the following compound HTL1 as a material which transports holes was vacuum-deposited to have a thickness of 1,150 Å thereon, thereby forming a hole transport layer. Then, an electron blocking layer was formed using the following compound HTL2 (150 Å). Subsequently, the following compound BD-1 as a dopant (2 mass % of the total weight of the light emitting layer) and the following compounds BH1-1 and BH2-1 as hosts (weight ratio 50:50) were deposited by a co-deposition method, thereby forming a light emitting layer having a thickness of 20 nm. Then, the following compound ETL2 was deposited to have a thickness of 50 Å, thereby forming a hole blocking layer, and the following compound ETL1 and lithium quinolate (Liq) were mixed at a ratio of 7:3, thereby forming an electron transport layer having a thickness of 250 Å. Subsequently, a film was formed as an electron injection layer using magnesium and lithium fluoride (LiF) with a thickness of 50 Å.

After a cathode was formed to have a thickness of 200 Å using magnesium and silver (1:4), the following compound CP1 was deposited to have a thickness of 600 Å, thereby completing a device. In the aforementioned procedure, the deposition rate of the organic material was maintained at 1 Å/sec.

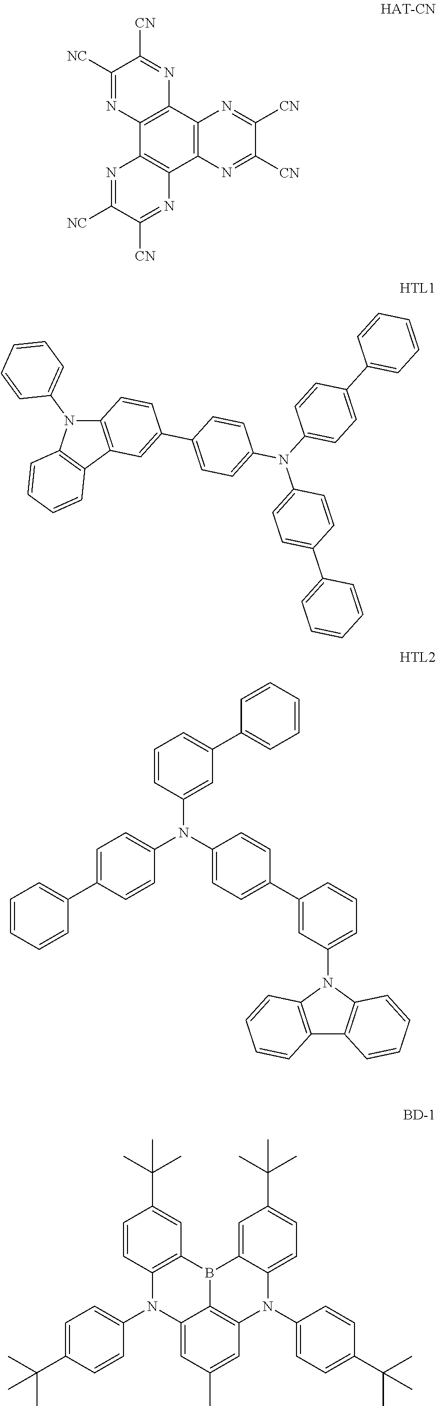 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(-c2ccc(N(c3ccc(-c4cccc(-n5c6ccccc6c6ccccc65)c4)cc3)c3cccc(-c4ccccc4)c3)cc2)cc1 ; Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

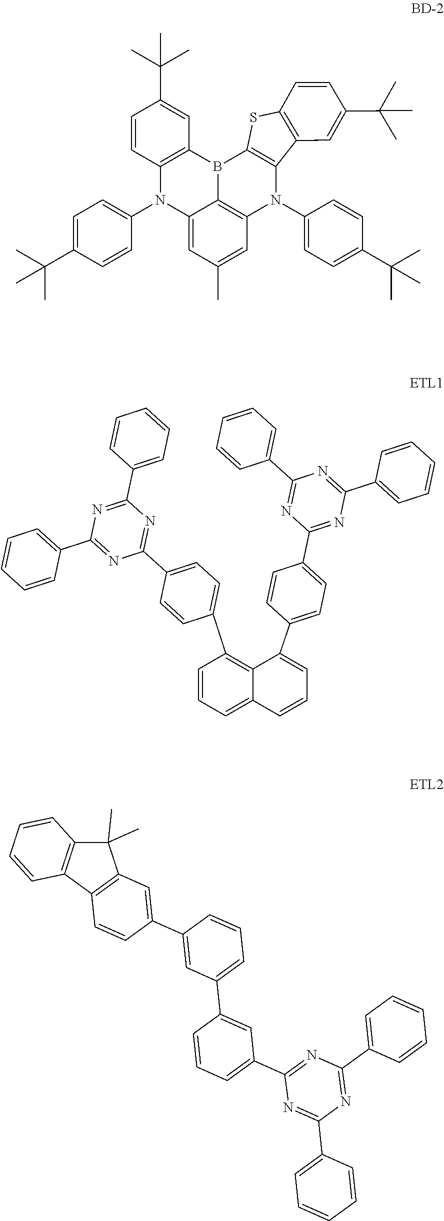 [SMILES: Cc1cc2c3c(c1)N(c1ccc(C(C)(C)C)cc1)c1c(sc4ccc(C(C)(C)C)cc14)B3c1cc(C(C)(C)C)ccc1N2c1ccc(C(C)(C)C)cc1 ; c1ccc(-c2nc(-c3ccccc3)nc(-c3ccc(-c4cccc5cccc(-c6ccc(-c7nc(-c8ccccc8)nc(-c8ccccc8)n7)cc6)c45)cc3)n2)cc1 ; CC1(C)c2ccccc2-c2ccc(-c3cccc(-c4cccc(-c5nc(-c6ccccc6)nc(-c6ccccc6)n5)c4)c3)cc21]

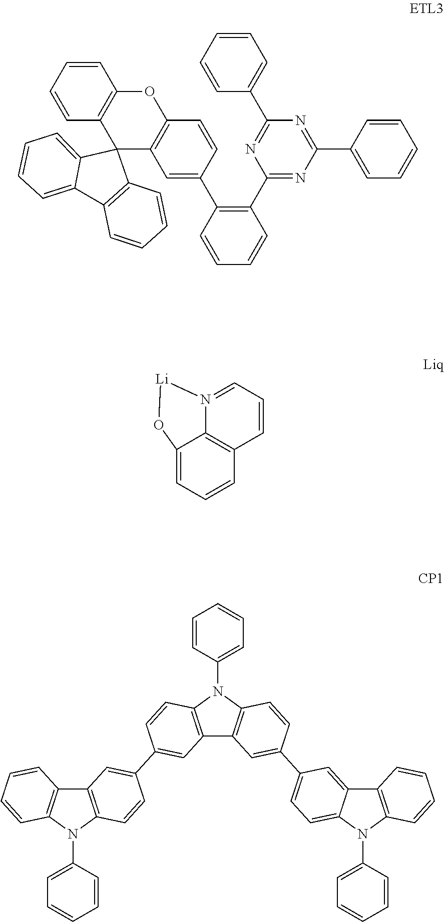

### Examples 2 to 64

A device was manufactured in the same manner as in Example 1, except that in Example 1, the compounds specified in the following Table 2 were used as materials for the light emitting layer, and the method (co-deposition or pre-mixing) of forming the light emitting layer, the mixing ratio, the light emitting dopant, and the hole blocking layer were varied. In Example 1, a light emitting layer was formed (co-deposited) using the compound of Chemical Formula 1 and the compound of Chemical Formula 2 through different deposition sources, and in the Examples and Comparative Examples in the following Table 1, in which the pre-mixed deposition method was used, the materials (hosts) were mixed in advance before the light emitting layer was formed, and the light emitting layer was formed through one deposition source.

### Comparative Examples 1 to 13

A device was manufactured in the same manner as in Example 1, except that in Example 1, the compounds specified in the following Table 2 were used as materials for the light emitting layer, and the method (co-deposition or pre-mixing) of forming the light emitting layer was varied.

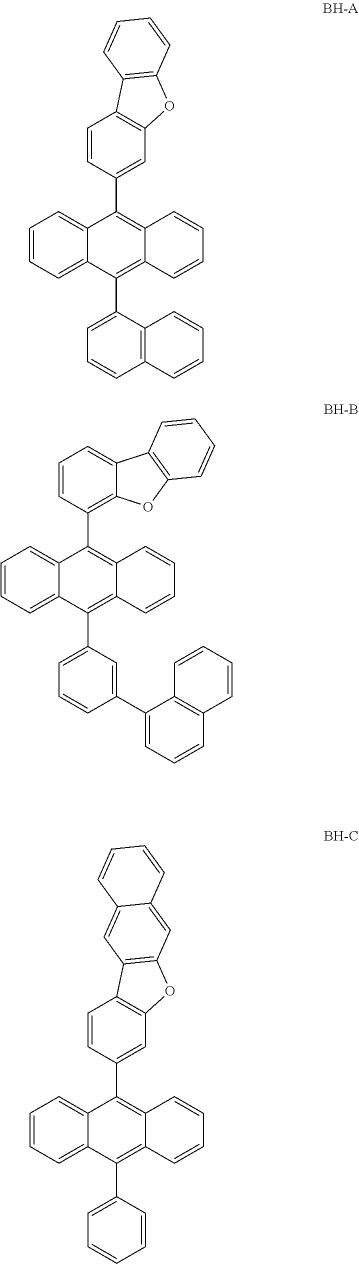

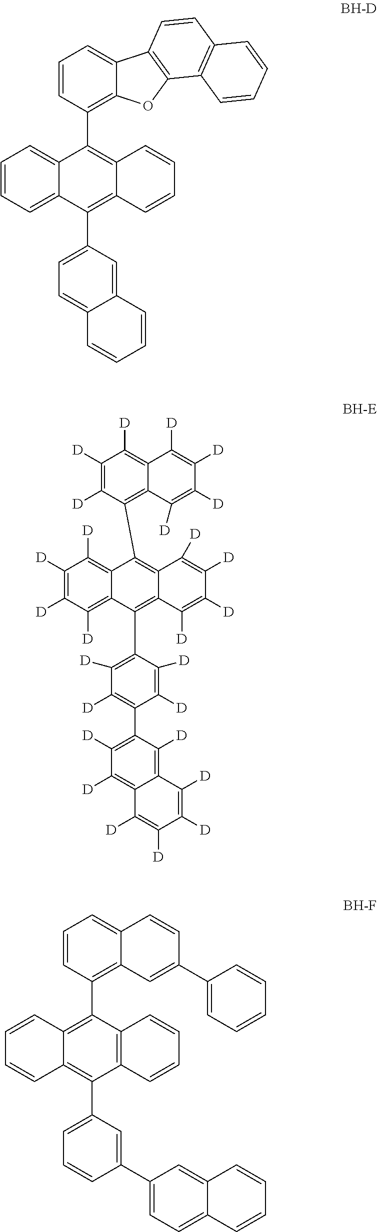

In the devices manufactured in Examples 1 to 64 and Comparative Examples 1 to 13, a driving voltage, an efficiency, and a time (T97) for reaching a 97% value compared to the initial luminance were measured at a current density of 20 mA/cm², and the results are shown in the following Table 1.

TABLE 2

| | | Light | | | | |
|---|---|---|---|---|---|---|
| | | emitting | Hole | | | Service |
| | Light emitting | layer | blocking | Voltage | Efficiency | life |
| | layer host | dopant | layer | (V) | (Cd/A) | (T97, h) |
| Example 1 | BH 1-1:BH 2-1 | BD 1 | ETL3 | 3.45 | 6.62 | 110 |
| | (Co-deposition, 1:1) | | | | | |
| Example 2 | BH 1-1:BH 2-2 | BD 1 | ETL2 | 3.35 | 6.63 | 113 |
| | (Co-deposition, 1:1) | | | | | |
| Example 3 | BH 1-1:BH 2-3 | BD 2 | ETL2 | 3.32 | 6.41 | 121 |
| | (Co-deposition, 1:1) | | | | | |
| Example 4 | BH 1-1:BH 2-4 | BD 2 | ETL3 | 3.23 | 6.51 | 132 |
| | (Co-deposition, 1:1) | | | | | |
| Example 5 | BH 1-1:BH 2-5 | BD 1 | ETL3 | 3.41 | 6.87 | 120 |
| | (Co-deposition, 1:1) | | | | | |
| Example 6 | BH 1-1:BH 2-6 | BD 1 | ETL2 | 3.27 | 6.48 | 115 |
| | (Co-deposition, 1:1) | | | | | |
| Example 7 | BH 1-1:BH 2-2 | BD 1 | ETL2 | 3.33 | 6.71 | 131 |
| | (Pre-mixing, 1:1) | | | | | |
| Example 8 | BH 1-1:BH 2-3 | BD 2 | ETL2 | 3.30 | 6.63 | 140 |
| | (Pre-mixing, 1:1) | | | | | |
| Example 9 | BH 1-2:BH 2-3 | BD 1 | ETL3 | 3.40 | 6.73 | 115 |
| | (Co-deposition, 1:1) | | | | | |
| Example 10 | BH 1-2:BH 2-8 | BD 2 | ETL3 | 3.37 | 6.65 | 114 |
| | (Co-deposition, 1:1) | | | | | |
| Example 11 | BH 1-2:BH 2-13 | BD 1 | ETL3 | 3.35 | 6.61 | 120 |
| | (Co-deposition, 1:1) | | | | | |
| Example 12 | BH 1-2:BH 2-3 | BD 1 | ETL3 | 3.37 | 6.84 | 135 |
| | (Pre-mixing, 1:1) | | | | | |
| Example 13 | BH 1-2:BH 2-13 | BD 1 | ETL3 | 3.37 | 6.73 | 132 |
| | (Pre-mixing, 1:1) | | | | | |
| Example 14 | BH 1-3:BH 2-7 | BD 1 | ETL3 | 3.35 | 6.55 | 114 |
| | (Co-deposition, 1:1) | | | | | |
| Example 15 | BH 1-4:BH 2-8 | BD 2 | ETL3 | 3.34 | 6.61 | 110 |
| | (Co-deposition, 1:1) | | | | | |
| Example 16 | BH 1-4:BH 2-9 | BD 1 | ETL2 | 3.25 | 6.53 | 112 |
| | (Co-deposition, 1:1) | | | | | |
| Example 17 | BH 1-4:BH 2-10 | BD 1 | ETL2 | 3.23 | 6.66 | 115 |
| | (Co-deposition, 1:1) | | | | | |
| Example 18 | BH 1-4:BH 2-9 | BD 1 | ETL2 | 3.24 | 6.71 | 123 |
| | (Co-deposition, 1:1) | | | | | |
| Example 19 | BH 1-5:BH 2-3 | BD 1 | ETL2 | 3.35 | 6.61 | 111 |
| | (Co-deposition, 1:1) | | | | | |
| Example 20 | BH 1-5:BH 2-4 | BD 1 | ETL2 | 3.29 | 6.56 | 129 |
| | (Co-deposition, 1:1) | | | | | |
| Example 21 | BH 1-5:BH 2-10 | BD 2 | ETL3 | 3.28 | 6.67 | 115 |
| | (Co-deposition, 1:1) | | | | | |
| Example 22 | BH 1-5:BH 2-16 | BD 1 | ETL2 | 3.32 | 6.59 | 123 |
| | (Co-deposition, 1:1) | | | | | |
| Example 23 | BH 1-5:BH 2-3 | BD 1 | ETL2 | 3.34 | 6.84 | 133 |
| | (Pre-mixing, 1:1) | | | | | |
| Example 24 | BH 1-5:BH 2-16 | BD 1 | ETL2 | 3.30 | 6.74 | 145 |
| | (Pre-mixing, 1:1) | | | | | |
| Example 25 | BH 1-6:BH 2-1 | BD 2 | ETL3 | 3.38 | 6.73 | 111 |
| | (Co-deposition, 1:1) | | | | | |
| Example 26 | BH 1-6:BH 2-11 | BD 2 | ETL3 | 3.37 | 6.60 | 117 |
| | (Co-deposition, 1:1) | | | | | |
| Example 27 | BH 1-6:BH 2-15 | BD 1 | ETL2 | 3.28 | 6.51 | 110 |
| | (Co-deposition, 1:1) | | | | | |
| Example 28 | BH 1-6:BH 2-1 | BD 1 | ETL3 | 3.35 | 6.82 | 128 |
| | (Pre-mixing, 1:1) | | | | | |
| Example 29 | BH 1-6:BH 2-11 | BD 2 | ETL3 | 3.32 | 6.75 | 131 |
| | (Pre-mixing, 1:1) | | | | | |
| Example 30 | BH 1-7:BH 2-2 | BD 1 | ETL2 | 3.35 | 6.78 | 128 |
| | (Co-deposition, 1:1) | | | | | |
| Example 31 | BH 1-7:BH 2-3 | BD 1 | ETL2 | 3.39 | 6.74 | 121 |
| | (Co-deposition, 1:1) | | | | | |
| Example 32 | BH 1-7:BH 2-5 | BD 1 | ETL2 | 3.37 | 6.88 | 125 |
| | (Co-deposition, 1:1) | | | | | |
| Example 33 | BH 1-7:BH 2-13 | BD 1 | ETL3 | 3.31 | 6.81 | 121 |
| | (Co-deposition, 1:1) | | | | | |
| Example 34 | BH 1-7:BH 2-3 | BD 1 | ETL2 | 3.33 | 6.87 | 143 |
| | (Pre-mixing, 1:1) | | | | | |
| Example 35 | BH 1-7:BH 2-13 | BD 1 | ETL3 | 3.30 | 6.89 | 141 |
| | (Pre-mixing, 1:1) | | | | | |
| Example 36 | BH 1-13:BH 2-3 | BD 1 | ETL2 | 3.30 | 6.53 | 145 |
| | (Co-deposition, 1:1) | | | | | |
| Example 37 | BH 1-14:BH 2-8 | BD 2 | ETL2 | 3.35 | 6.67 | 141 |
| | (Co-deposition, 1:1) | | | | | |
| Example 38 | BH 1-15:BH 2-7 | BD 1 | ETL3 | 3.32 | 6.61 | 138 |
| | (Co-deposition, 1:1) | | | | | |
| Example 39 | BH 1-16:BH 2-10 | BD 2 | ETL3 | 3.30 | 6.62 | 147 |
| | (Co-deposition, 1:1) | | | | | |
| Example 40 | BH 1-6:BH 2-17 | BD 1 | ETL3 | 3.35 | 6.68 | 134 |
| | (Co-deposition, 1:1) | | | | | |
| Example 41 | BH 1-7:BH 2-18 | BD 2 | ETL2 | 3.34 | 6.75 | 151 |
| | (Co-deposition, 1:1) | | | | | |
| Example 42 | BH 1-13:BH 2-19 | BD 1 | ETL2 | 3.29 | 6.51 | 168 |
| | (Co-deposition, 1:1) | | | | | |
| Example 43 | BH 1-7:BH 2-20 | BD 2 | ETL2 | 3.35 | 6.87 | 149 |
| | (Co-deposition, 1:1) | | | | | |
| Example 44 | BH 1-1:BH 2-1 | BD 1 | ETL3 | 3.31 | 6.57 | 121 |
| | (Co-deposition, 2:1) | | | | | |
| Example 45 | BH 1-1:BH 2-6 | BD 1 | ETL2 | 3.38 | 6.64 | 112 |
| | (Co-deposition, 1:2) | | | | | |
| Example 46 | BH 1-2:BH 2-13 | BD 1 | ETL3 | 3.56 | 6.85 | 111 |
| | (Pre-mixing, 1:4) | | | | | |
| Example 47 | BH 1-3:BH 2-12 | BD 1 | ETL2 | 3.37 | 6.33 | 95 |
| | (Co-deposition, 1:1) | | | | | |
| Example 48 | BH 1-3:BH 2-12 | BD 1 | ETL3 | 3.36 | 6.38 | 109 |
| | (Pre-mixing, 1:1) | | | | | |
| Example 49 | BH 1-4:BH 2-14 | BD 2 | ETL3 | 3.45 | 6.40 | 91 |
| | (Co-deposition, 1:1) | | | | | |
| Example 50 | BH 1-4:BH 2-14 | BD 2 | ETL2 | 3.43 | 6.43 | 105 |
| | (Pre-mixing, 1:1) | | | | | |
| Example 51 | BH 1-8:BH 2-5 | BD 2 | ETL2 | 3.51 | 6.35 | 97 |
| | (Co-deposition, 1:1) | | | | | |
| Example 52 | BH 1-8:BH 2-12 | BD 1 | ETL2 | 3.60 | 6.31 | 85 |
| | (Co-deposition, 1:1) | | | | | |
| Example 53 | BH 1-8:BH 2-12 | BD 1 | ETL3 | 3.59 | 6.33 | 94 |
| | (Pre-mixing, 1:1) | | | | | |
| Example 54 | BH 1-9:BH 2-11 | BD 2 | ETL3 | 3.51 | 6.45 | 91 |
| | (Co-deposition, 1:1) | | | | | |
| Example 55 | BH 1-9:BH 2-15 | BD 1 | ETL2 | 3.40 | 6.47 | 101 |
| | (Co-deposition, 1:1) | | | | | |
| Example 56 | BH 1-10:BH 2-7 | BD 1 | ETL2 | 3.43 | 6.49 | 95 |
| | (Co-deposition, 1:1) | | | | | |
| Example 57 | BH 1-10:BH 2-14 | BD 1 | ETL3 | 3.42 | 6.30 | 82 |
| | (Co-deposition, 1:1) | | | | | |
| Example 58 | BH 1-10:BH 2-14 | BD 1 | ETL3 | 3.41 | 6.42 | 97 |
| | (Pre-mixing, 1:1) | | | | | |
| Example 59 | BH 1-11:BH 2-1 | BD 1 | ETL2 | 3.39 | 6.43 | 98 |
| | (Co-deposition, 1:1) | | | | | |
| Example 60 | BH 1-11:BH 2-7 | BD 1 | ETL2 | 3.35 | 6.39 | 92 |
| | (Co-deposition, 1:1) | | | | | |
| Example 61 | BH 1-11:BH 2-1 | BD 1 | ETL3 | 3.42 | 6.45 | 97 |
| | (Pre-mixing, 1:1) | | | | | |
| Example 62 | BH 1-11:BH 2-7 | BD 1 | ETL3 | 3.45 | 6.48 | 91 |
| | (Pre-mixing, 1:1) | | | | | |
| Example 63 | BH 1-12:BH 2-9 | BD 2 | ETL2 | 3.41 | 6.41 | 95 |
| | (Co-deposition, 1:1) | | | | | |
| Example 64 | BH 1-12:BH 2-15 | BD 2 | ETL2 | 3.35 | 6.37 | 97 |
| | (Co-deposition, 1:1) | | | | | |
| Comparative | BH 1-1:BH-A | BD 1 | ETL3 | 3.85 | 6.09 | 73 |
| Example 1 | (Co-deposition, 1:1) | | | | | |
| Comparative | BH 1-4:BH-B | BD 1 | ETL2 | 3.91 | 6.05 | 75 |
| Example 2 | (Pre-mixing, 1:1) | | | | | |
| Comparative | BH 1-2:BH-C | BD 1 | ETL2 | 3.88 | 6.13 | 78 |
| Example 3 | (Co-deposition, 1:1) | | | | | |
| Comparative | BH 1-7:BH D | BD 2 | ETL3 | 3.95 | 6.01 | 70 |
| Example 4 | (Co-deposition, 1:1) | | | | | |
| Comparative | BH 2-2:BH 2-13 | BD 1 | ETL2 | 3.83 | 6.50 | 47 |
| Example 5 | (Co-deposition, 1:1) | | | | | |
| Comparative | BH 2-6:BH 2-10 | BD 2 | ETL3 | 3.92 | 6.48 | 35 |
| Example 6 | (Co-deposition, 1:1) | | | | | |
| Comparative | BH 1-11:BH-E | BD 1 | ETL2 | 4.11 | 6.13 | 61 |
| Example 7 | (Pre-mixing, 1:1) | | | | | |
| Comparative | BH 2-10:BH-F | BD 1 | ETL2 | 4.29 | 6.20 | 50 |
| Example 8 | (Co-deposition, 1:1) | | | | | |
| Comparative | BH-E:BH-F | BD 1 | ETL3 | 4.47 | 6.02 | 48 |
| Example 9 | (Co-deposition, 1:1) | | | | | |
| Comparative | BH 1-2 | BD 1 | ETL2 | 3.40 | 6.16 | 83 |
| Example 10 | | | | | | |
| Comparative | BH 1-4 | BD 2 | ETL3 | 3.51 | 6.12 | 75 |
| Example 11 | | | | | | |
| Comparative | BH 2-3 | BD 1 | ETL2 | 3.84 | 6.53 | 52 |
| Example 12 | | | | | | |
| Comparative | BH 2-10 | BD 2 | ETL2 | 3.70 | 6.42 | 63 |
| Example 13 | | | | | | |

Examples 1 to 64 of the present application comprise both the compound of Chemical Formula 1 and the compound of Chemical Formula 2 as the host of the light emitting layer. In Comparative Examples 1 and 2, the compound of Chemical Formula 1 and a host in which anthracene is bonded to the 3rd or 4th position of dibenzofuran were used as light emitting hosts, and it could be confirmed that the driving voltage was higher, and the efficiency and service life of the device were lower than in the Examples of the present application. In Comparative Examples 3 and 4, the compound of Chemical Formula 1 and a host in which anthracene is bonded to the 3rd or 4th position of naphthobenzofuran were used as light emitting hosts, and it could be confirmed that the driving voltage was higher, and the efficiency and service life of the device were lower than in the Examples of the present application. In Comparative Examples 5 and 6, the two compounds of Chemical Formula 2 were used as light emitting hosts, and it could be confirmed that the driving voltage was higher, and the efficiency and service life of the device were lower than in the Examples of the present application. In Comparative Examples 7 and 8, one of the compound of Chemical Formula 1 or the compound of Chemical Formula 2 and one aryl-based host were used as light emitting hosts, and it could be confirmed that the driving voltage was higher, and the efficiency and service life of the device were lower than in the Examples of the present application. In Comparative Examples 7 and 8, the two aryl-based hosts were used as light emitting hosts, and it could be confirmed that the driving voltage was higher, and the efficiency and service life of the device were lower than in the Examples of the present application. In Comparative Examples 10 to 13, the compound of Chemical Formula 1 or 2 was used alone, and it could be confirmed that the driving voltage was higher, and the efficiency and service life of the device were lower than in the Examples of the present application.

In addition, it could be confirmed that as in Examples 7 and 8, 12 and 13, 23 and 24, 28 and 29, 34 and 35, 48 and 50, 53 and 58, 61 and 62, when the same compound was pre-mixed and then deposited (one deposition source), the efficiency and service life of the device were also slightly increased compared to the case where a co-deposition (separate deposition source) was used. This is because the interaction between the two compounds smoothly occurs, thereby improving processability.

1. An organic light emitting device, comprising:
an anode;
a cathode; and
a first organic material layer provided between the anode and the cathode, wherein the first organic material layer comprises a compound of the following Chemical Formula 1 and a compound of the following Chemical Formula 2: 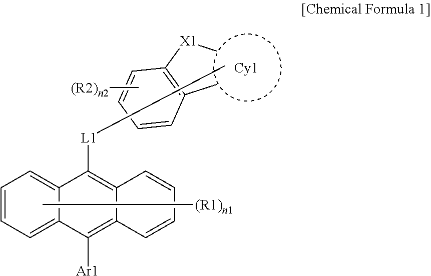
wherein in Chemical Formula 1:
X1 is O or S;
Cy1 is a substituted or unsubstituted dibenzofuran or a substituted or unsubstituted dibenzothiophene;
L1 is a direct bond or a substituted or unsubstituted arylene group;
Ar1 is a substituted or unsubstituted aryl group or a substituted or unsubstituted heteroaryl group;
R1 and R2 are the same as or different from each other, and are each independently hydrogen, deuterium, a substituted or unsubstituted aryl group, or a substituted or unsubstituted heteroaryl group;
n1 is an integer from 0 to 8, and when n1 is 2 or higher, two or more R1s are the same as or different from each other,
n2 is an integer from 0 to 4, and when n2 is 2 or higher, two or more R2s are the same as or different from each other; 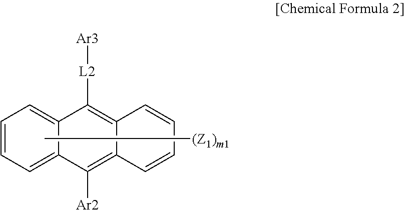
wherein in Chemical Formula 2;
L2 is a direct bond or a substituted or unsubstituted arylene group;
Ar2 is a substituted or unsubstituted aryl group or a substituted or unsubstituted heteroaryl group;
Z1 is hydrogen, deuterium, a substituted or unsubstituted cycloalkyl group, a substituted or unsubstituted aryl group, or a substituted or unsubstituted heteroaryl group;
m1 is an integer from 0 to 8, and when m1 is 2 or higher, two or more Z1s are the same as or different from each other; and
Ar3 is the following Chemical Formula A, and Z10 or Z11 of the following Chemical Formula A is linked to L2 of Chemical Formula 2: 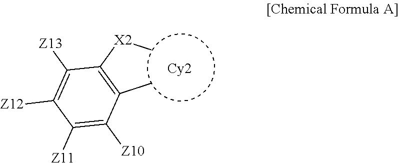
wherein in Chemical Formula A:
X2 is O or S;
Cy2 is a substituted or unsubstituted benzene or a substituted or unsubstituted naphthalene; and
of Z10 and Z11, a group which is not linked to L2 in Chemical Formula 2, Z12, and Z13 are the same as or different from each other, and are each independently hydrogen, deuterium, a substituted or unsubstituted aryl group, or a substituted or unsubstituted heteroaryl group.

2. The organic light emitting device of claim 1, wherein Chemical Formula 1 is any one of the following Chemical Formulae 1-1 to 1-6: 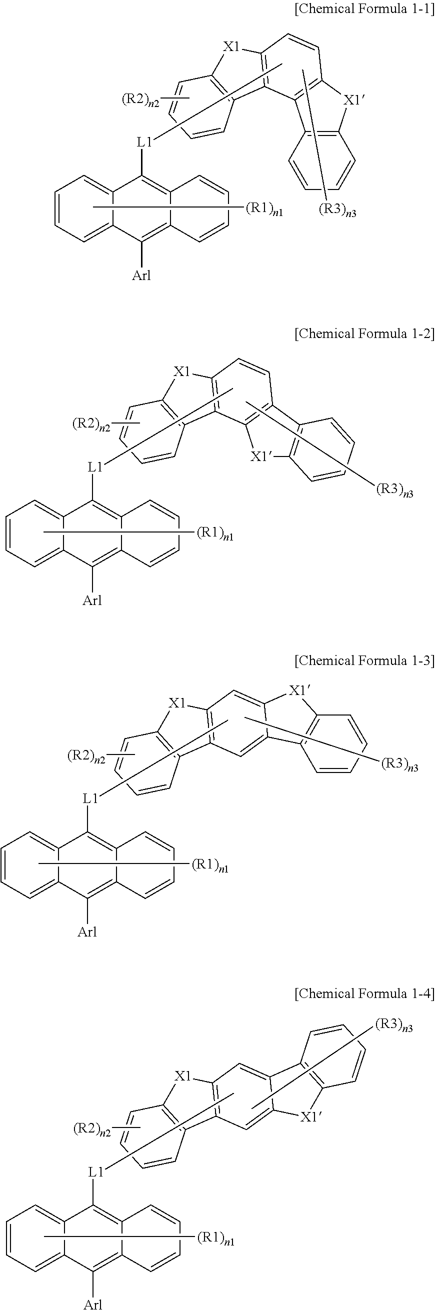 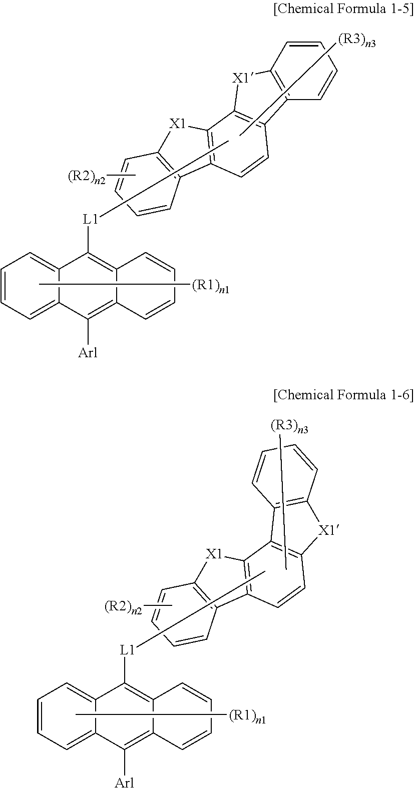
wherein in Chemical Formulae 1-1 to 1-6:
the definitions of X1, R1, R2, n1, n2, L1 and Ar are the same as the definitions in Chemical Formula 1;
X1′ is O or S;
R3 is hydrogen, deuterium, a substituted or unsubstituted alkyl group, a substituted or unsubstituted cycloalkyl group, a substituted or unsubstituted aryl group, or a substituted or unsubstituted heteroaryl group; and n3 is an integer from 0 to 6, and when n3 is 2 or higher, two or more R3s are the same as or different from each other.

3. The organic light emitting device of claim 1, wherein Chemical Formula 2 is the following Chemical Formula 2-1 or 2-2: 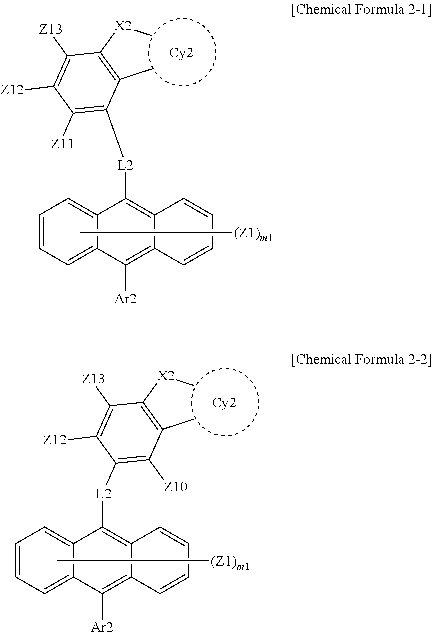
wherein in Chemical Formulae 2-1 and 2-2
the definitions of Z1, m1, L2, and Ar2 are the same as the definitions in Chemical Formula 2, and the definitions of X2, Z10 to Z13, and Cy2 are the same as the definitions in Chemical Formula A.

4. The organic light emitting device of claim 1, wherein Chemical Formula 2 is any one of the following Chemical Formulae 2-1-1 to 2-1-4: 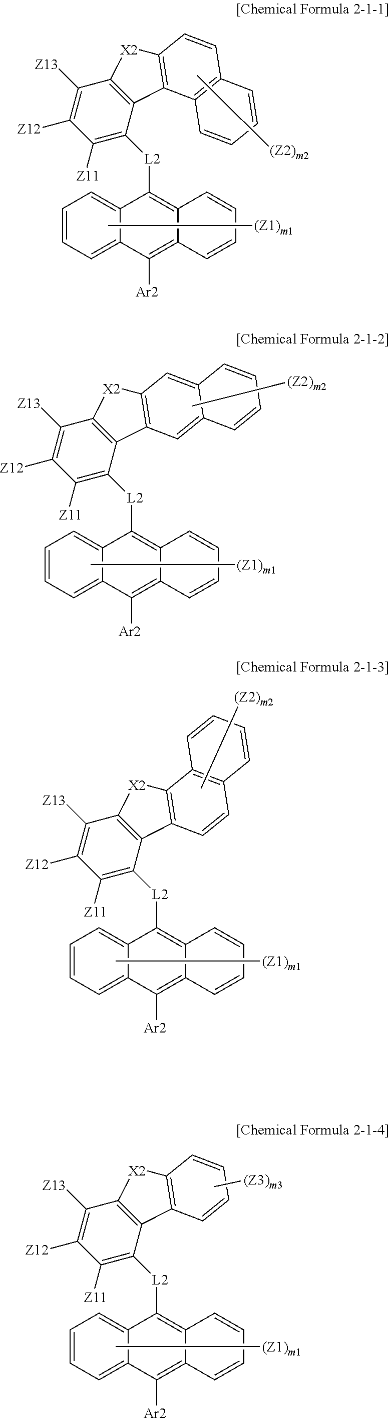
wherein in Chemical Formulae 2-1-1 to 2-1-4:
the definitions of Z1, m1, L2, and Ar2 are the same as the definitions in Chemical Formula 2, and the definitions of X2 and Z11 to Z13 are the same as the definitions in Chemical Formula A;
Z2 and Z3 are the same as or different from each other, and are each independently hydrogen, deuterium, a substituted or unsubstituted alkyl group, a substituted or unsubstituted cycloalkyl group, a substituted or unsubstituted aryl group, or a substituted or unsubstituted heteroaryl group;
m2 is an integer from 0 to 6, and when m2 is 2 or higher, two or more Z2s are the same as or different from each other; and
m3 is an integer from 0 to 4, and when m3 is 2 or higher, two or more Z3s are the same as or different from each other.

5. The organic light emitting device of claim 1, wherein Chemical Formula 2 is any one of the following Chemical Formulae 2-2-1 to 2-2-4: 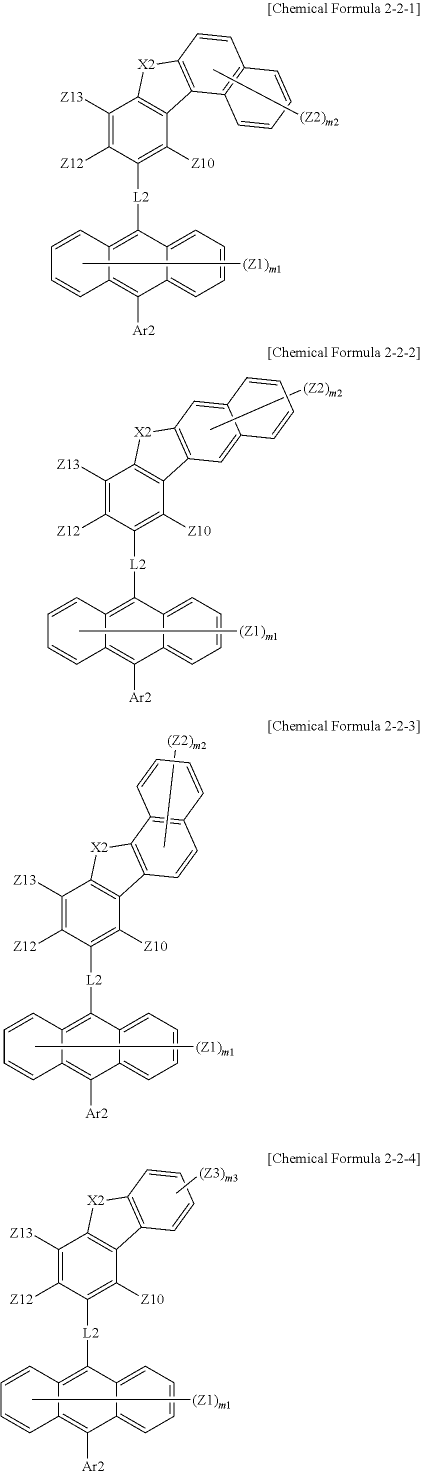
wherein in Chemical Formulae 2-2-1 to 2-2-4:
the definitions of Z1, m1, L2, and Ar2 are the same as the definitions in Chemical Formula 2, and the definitions of X2, Z10, Z12, and Z13 are the same as the definitions in Chemical Formula A;
Z2 and Z3 are the same as or different from each other, and are each independently hydrogen, deuterium, a substituted or unsubstituted alkyl group, a substituted or unsubstituted cycloalkyl group, a substituted or unsubstituted aryl group, or a substituted or unsubstituted heteroaryl group;
m2 is an integer from 0 to 6, and when m2 is 2 or higher, two or more Z2s are the same as or different from each other, and
m3 is an integer from 0 to 4, and when m3 is 2 or higher, two or more Z3s are the same as or different from each other.

6. The organic light emitting device of claim 1, wherein Chemical Formula Ar is a substituted or unsubstituted aryl group having 6 to 60 carbon atoms.

7. The organic light emitting device of claim 1, wherein Ar2 is a substituted or unsubstituted aryl group having 6 to 60 carbon atoms.

8. The organic light emitting device of claim 1, wherein Chemical Formula 1 is the following Chemical Formula 1-1, and Chemical Formula 2 is the following Chemical Formula 2-1-2: 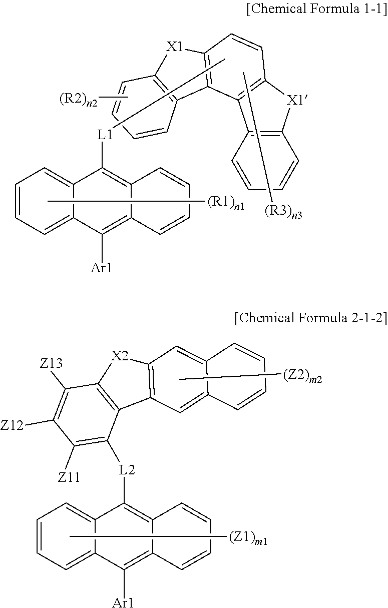
wherein in Chemical Formulae 1-1 and 2-1-2:
the definitions of X1, R1, R2, n1, n2, L1 and Ar are the same as the definitions in Chemical Formula 1;
X1′ is O or S;
R3 is hydrogen, deuterium, a substituted or unsubstituted alkyl group, a substituted or unsubstituted cycloalkyl group, a substituted or unsubstituted aryl group, or a substituted or unsubstituted heteroaryl group;
n3 is an integer from 0 to 6, and when n3 is 2 or higher, two or more R3s are the same as or different from each other;
the definitions of Z1, m1, L2, and Ar2 are the same as the definitions in Chemical Formula 2, and the definitions of X2 and Z11 to Z13 are the same as the definitions in Chemical Formula A; Z2 is hydrogen, deuterium, a substituted or unsubstituted alkyl group, a substituted or unsubstituted cycloalkyl group, a substituted or unsubstituted aryl group, or a substituted or unsubstituted heteroaryl group; and
m2 is an integer from 0 to 6, and when m2 is 2 or higher, two or more Z2s are the same as or different from each other.

9. The organic light emitting device of claim 1, wherein Chemical Formula 1 is the following Chemical Formula 1-1, and Chemical Formula 2 is the following Chemical Formula 2-1-3: 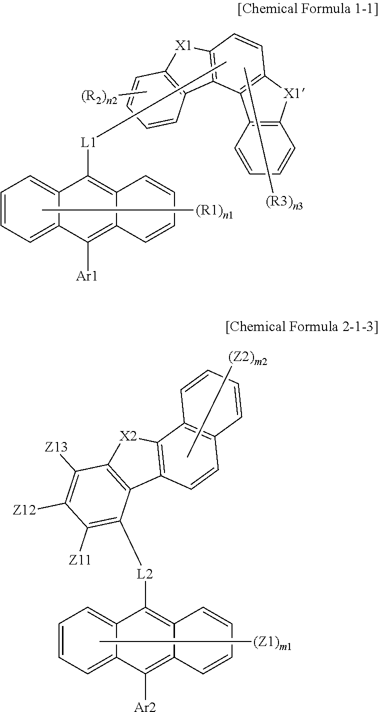
wherein in Chemical Formulae 1-1 and 2-1-3;
the definitions of X1, R1, R2, n1, n2, L1 and Ar are the same as the definitions in Chemical Formula 1;
X1′ is O or S;
R3 is hydrogen, deuterium, a substituted or unsubstituted alkyl group, a substituted or unsubstituted cycloalkyl group, a substituted or unsubstituted aryl group, or a substituted or unsubstituted heteroaryl group;
n3 is an integer from 0 to 6, and when n3 is 2 or higher, two or more R3s are the same as or different from each other;
the definitions of Z1, m1, L2, and Ar2 are the same as the definitions in Chemical Formula 2, and the definitions of X2 and Z11 to Z13 are the same as the definitions in Chemical Formula A;
Z2 is hydrogen, deuterium, a substituted or unsubstituted alkyl group, a substituted or unsubstituted cycloalkyl group, a substituted or unsubstituted aryl group, or a substituted or unsubstituted heteroaryl group; and
m2 is an integer from 0 to 6, and when m2 is 2 or higher, two or more Z2s are the same as or different from each other.

10. The organic light emitting device of claim 1, wherein Chemical Formula 1 is the following Chemical Formula 1-1, and Chemical Formula 2 is the following Chemical Formula 2-1-4: 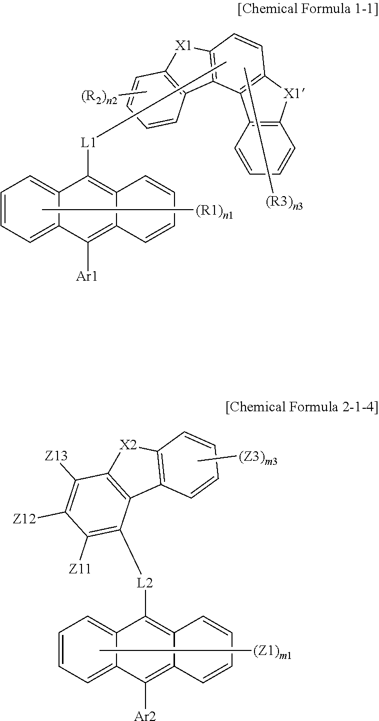
wherein in Chemical Formulae 1-1 and 2-1-4:
the definitions of X1, R1, R2, n1, n2, L1 and Ar are the same as the definitions in Chemical Formula 1;
X1′ is O or S;
R3 is hydrogen, deuterium, a substituted or unsubstituted alkyl group, a substituted or unsubstituted cycloalkyl group, a substituted or unsubstituted aryl group, or a substituted or unsubstituted heteroaryl group;
n3 is an integer from 0 to 6, and when n3 is 2 or higher, two or more R3s are the same as or different from each other;
the definitions of Z1, m1, L2, and Ar2 are the same as the definitions in Chemical Formula 2, and the definitions of X2 and Z11 to Z13 are the same as the definitions in Chemical Formula A; Z3 is hydrogen, deuterium, a substituted or unsubstituted alkyl group, a substituted or unsubstituted cycloalkyl group, a substituted or unsubstituted aryl group, or a substituted or unsubstituted heteroaryl group; and
m3 is an integer from 0 to 4, and when m3 is 2 or higher, two or more Z3s are the same as or different from each other.

11. The organic light emitting device of claim 1, wherein Chemical Formula 1 is the following Chemical Formula 1-1, and Chemical Formula 2 is following Chemical Formula 2-2-4: 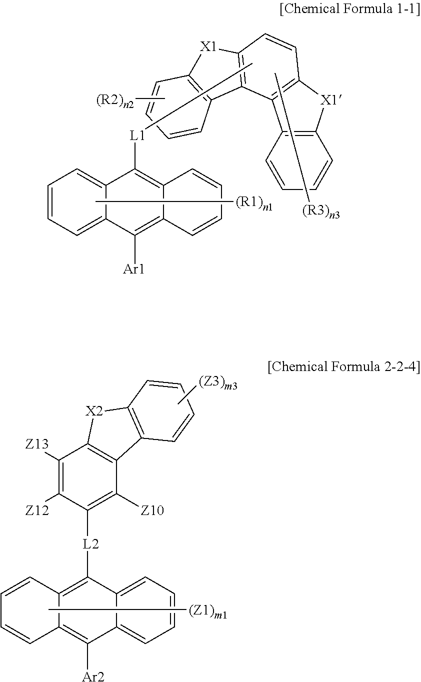
wherein in Chemical Formulae 1-1 and 2-2-4:
the definitions of X1, R1, R2, n1, n2, L1 and Ar are the same as the definitions in Chemical Formula 1;
X1′ is O or S;
R3 is hydrogen, deuterium, a substituted or unsubstituted alkyl group, a substituted or unsubstituted cycloalkyl group, a substituted or unsubstituted aryl group, or a substituted or unsubstituted heteroaryl group;
n3 is an integer from 0 to 6, and when n3 is 2 or higher, two or more R3s are the same as or different from each other;
the definitions of Z1, m1, L2, and Ar2 are the same as the definitions in Chemical Formula 2, and the definitions of X2, Z10, Z12, and Z13 are the same as the definitions in Chemical Formula A;
Z3 is hydrogen, deuterium, a substituted or unsubstituted alkyl group, a substituted or unsubstituted cycloalkyl group, a substituted or unsubstituted aryl group, or a substituted or unsubstituted heteroaryl group; and
m3 is an integer from 0 to 4, and when m3 is 2 or higher, two or more Z3s are the same as or different from each other.

12. The organic light emitting device of claim 1, wherein the compound of Chemical Formula 1 is any one of the following compounds:

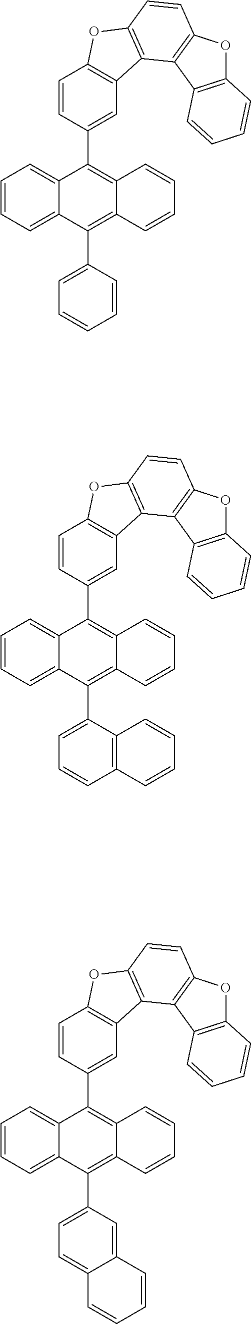 [SMILES: c1ccc(-c2c3ccccc3c(-c3ccc4oc5ccc6oc7ccccc7c6c5c4c3)c3ccccc23)cc1 ; c1ccc2c(-c3c4ccccc4c(-c4ccc5oc6ccc7oc8ccccc8c7c6c5c4)c4ccccc34)cccc2c1 ; c1ccc2cc(-c3c4ccccc4c(-c4ccc5oc6ccc7oc8ccccc8c7c6c5c4)c4ccccc34)ccc2c1]

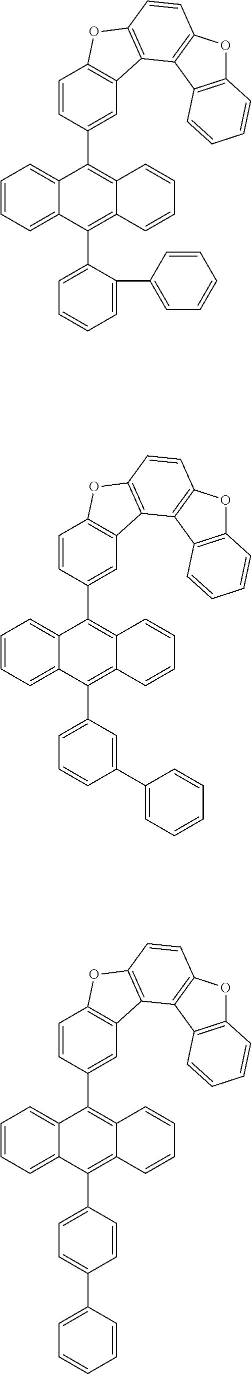 [SMILES: c1ccc(-c2ccccc2-c2c3ccccc3c(-c3ccc4oc5ccc6oc7ccccc7c6c5c4c3)c3ccccc23)cc1 ; c1ccc(-c2cccc(-c3c4ccccc4c(-c4ccc5oc6ccc7oc8ccccc8c7c6c5c4)c4ccccc34)c2)cc1 ; c1ccc(-c2ccc(-c3c4ccccc4c(-c4ccc5oc6ccc7oc8ccccc8c7c6c5c4)c4ccccc34)cc2)cc1]

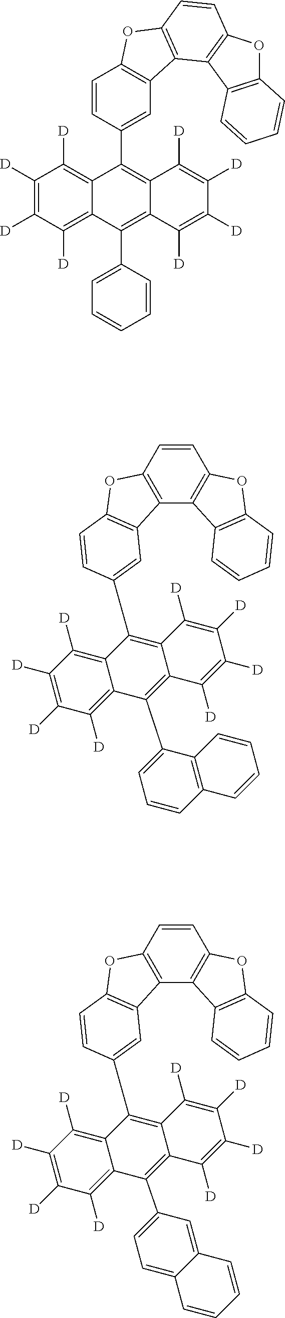 [SMILES: [2H]c1c([2H])c([2H])c2c(-c3ccc4oc5ccc6oc7ccccc7c6c5c4c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5ccc6oc7ccccc7c6c5c4c3)c2c1[2H] ; [2H]c1c([2H])c([2H])c2c(-c3ccc4oc5ccc6oc7ccccc7c6c5c4c3)c3c([2H])c([2H])c([2H])c([2H])c3c(-c3ccc4ccccc4c3)c2c1[2H]]

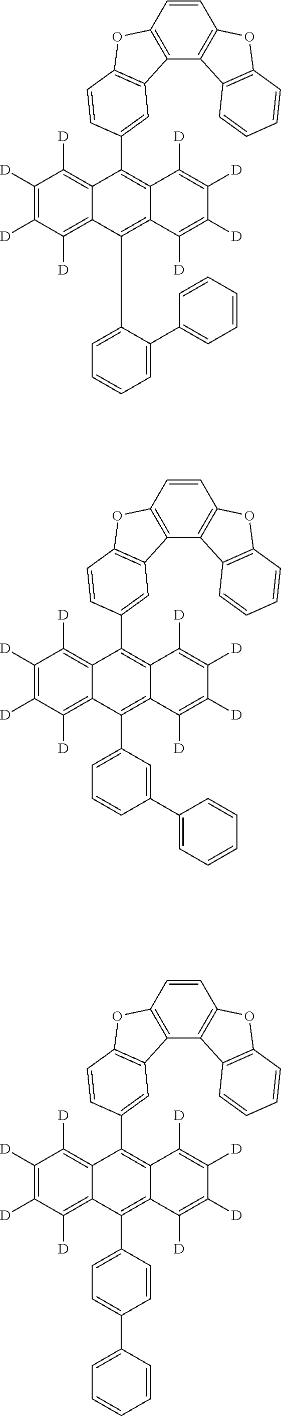 [SMILES: [2H]c1c([2H])c([2H])c2c(-c3ccccc3-c3ccccc3)c3c([2H])c([2H])c([2H])c([2H])c3c(-c3ccc4oc5ccc6oc7ccccc7c6c5c4c3)c2c1[2H] ; [2H]c1c([2H])c([2H])c2c(-c3ccc4oc5ccc6oc7ccccc7c6c5c4c3)c3c([2H])c([2H])c([2H])c([2H])c3c(-c3cccc(-c4ccccc4)c3)c2c1[2H] ; [2H]c1c([2H])c([2H])c2c(-c3ccc4oc5ccc6oc7ccccc7c6c5c4c3)c3c([2H])c([2H])c([2H])c([2H])c3c(-c3ccc(-c4ccccc4)cc3)c2c1[2H]]

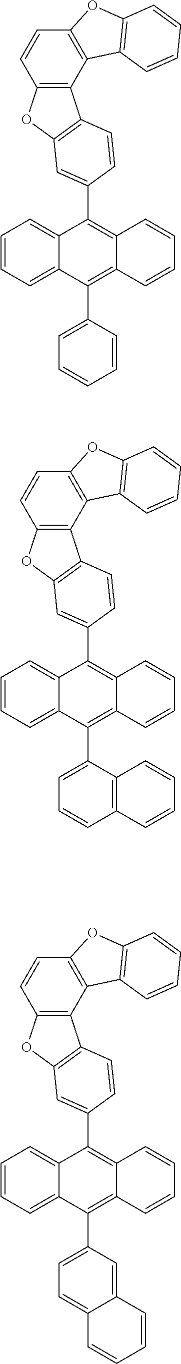 [SMILES: c1ccc(-c2c3ccccc3c(-c3ccc4c(c3)oc3ccc5oc6ccccc6c5c34)c3ccccc23)cc1 ; c1ccc2c(-c3c4ccccc4c(-c4ccc5c(c4)oc4ccc6oc7ccccc7c6c45)c4ccccc34)cccc2c1 ; c1ccc2cc(-c3c4ccccc4c(-c4ccc5c(c4)oc4ccc6oc7ccccc7c6c45)c4ccccc34)ccc2c1]

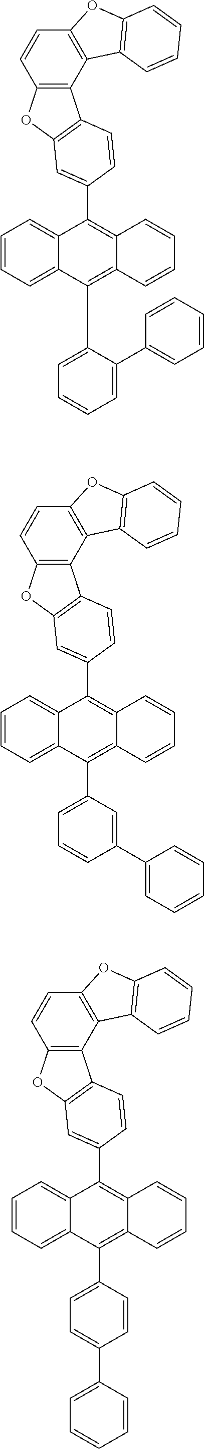 [SMILES: c1ccc(-c2ccccc2-c2c3ccccc3c(-c3ccc4c(c3)oc3ccc5oc6ccccc6c5c34)c3ccccc23)cc1 ; c1ccc(-c2cccc(-c3c4ccccc4c(-c4ccc5c(c4)oc4ccc6oc7ccccc7c6c45)c4ccccc34)c2)cc1 ; c1ccc(-c2ccc(-c3c4ccccc4c(-c4ccc5c(c4)oc4ccc6oc7ccccc7c6c45)c4ccccc34)cc2)cc1]

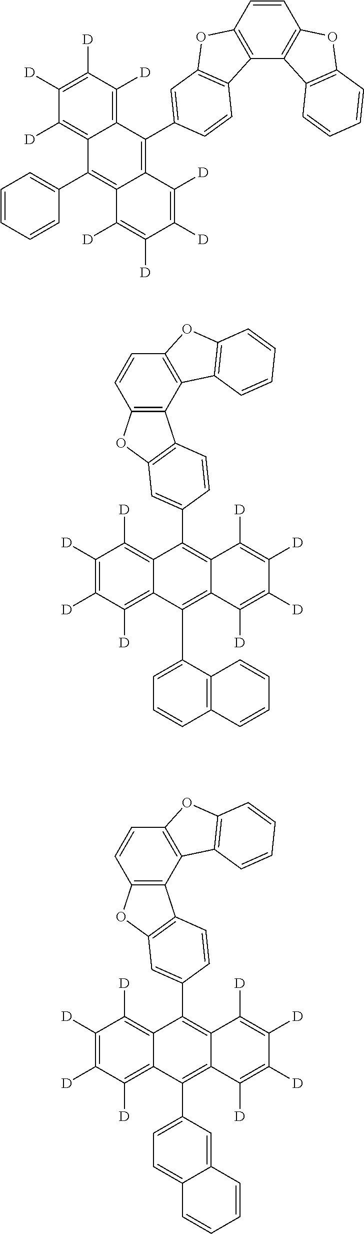 [SMILES: [2H]c1c([2H])c([2H])c2c(-c3ccc4c(c3)oc3ccc5oc6ccccc6c5c34)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4c(c3)oc3ccc5oc6ccccc6c5c34)c2c1[2H] ; [2H]c1c([2H])c([2H])c2c(-c3ccc4c(c3)oc3ccc5oc6ccccc6c5c34)c3c([2H])c([2H])c([2H])c([2H])c3c(-c3ccc4ccccc4c3)c2c1[2H]]

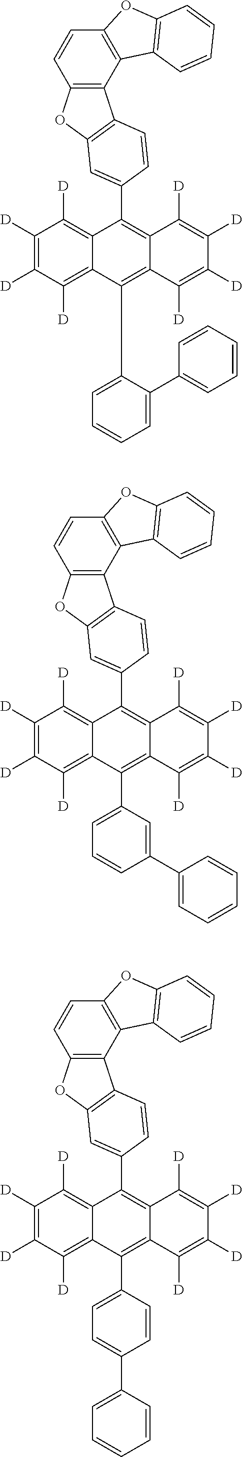 [SMILES: [2H]c1c([2H])c([2H])c2c(-c3ccccc3-c3ccccc3)c3c([2H])c([2H])c([2H])c([2H])c3c(-c3ccc4c(c3)oc3ccc5oc6ccccc6c5c34)c2c1[2H] ; [2H]c1c([2H])c([2H])c2c(-c3ccc4c(c3)oc3ccc5oc6ccccc6c5c34)c3c([2H])c([2H])c([2H])c([2H])c3c(-c3cccc(-c4ccccc4)c3)c2c1[2H] ; [2H]c1c([2H])c([2H])c2c(-c3ccc4c(c3)oc3ccc5oc6ccccc6c5c34)c3c([2H])c([2H])c([2H])c([2H])c3c(-c3ccc(-c4ccccc4)cc3)c2c1[2H]]

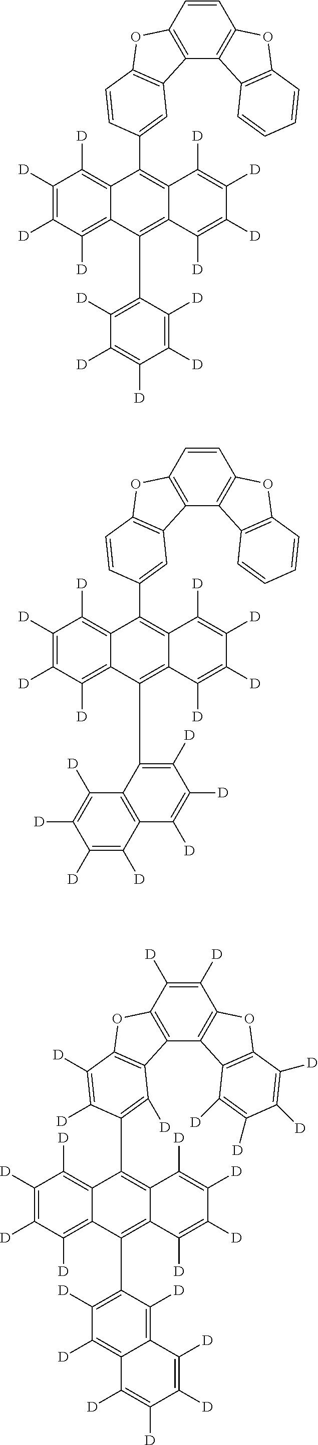

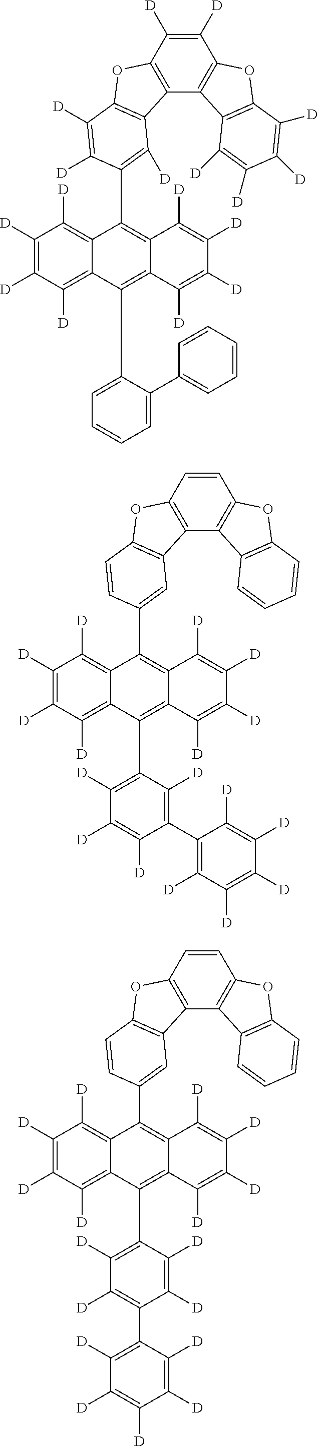

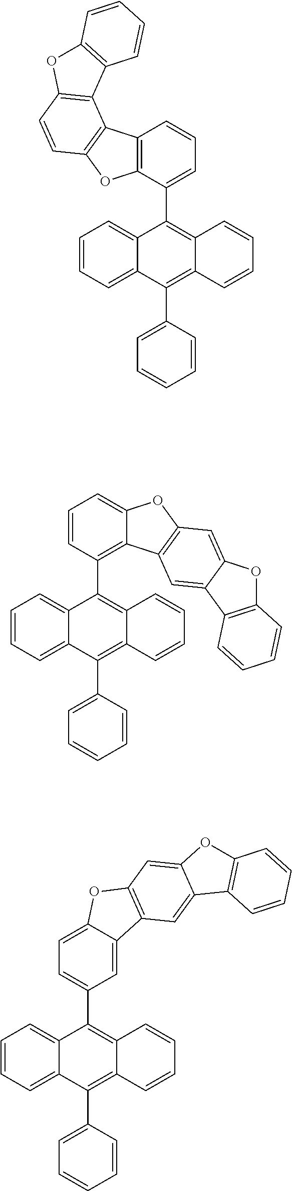 [SMILES: c1ccc(-c2c3ccccc3c(-c3cccc4c3oc3ccc5oc6ccccc6c5c34)c3ccccc23)cc1 ; c1ccc(-c2c3ccccc3c(-c3cccc4oc5cc6oc7ccccc7c6cc5c34)c3ccccc23)cc1 ; c1ccc(-c2c3ccccc3c(-c3ccc4oc5cc6oc7ccccc7c6cc5c4c3)c3ccccc23)cc1]

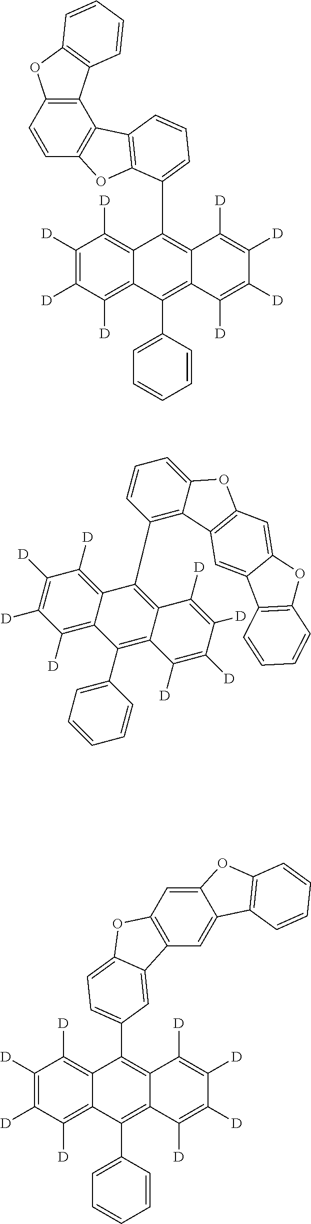 [SMILES: [2H]c1c([2H])c([2H])c2c(-c3cccc4c3oc3ccc5oc6ccccc6c5c34)c3c([2H])c([2H])c([2H])c([2H])c3c(-c3ccccc3)c2c1[2H] ; [2H]c1c([2H])c([2H])c2c(-c3cccc4oc5cc6oc7ccccc7c6cc5c34)c3c([2H])c([2H])c([2H])c([2H])c3c(-c3ccccc3)c2c1[2H] ; [2H]c1c([2H])c([2H])c2c(-c3ccc4oc5cc6oc7ccccc7c6cc5c4c3)c3c([2H])c([2H])c([2H])c([2H])c3c(-c3ccccc3)c2c1[2H]]

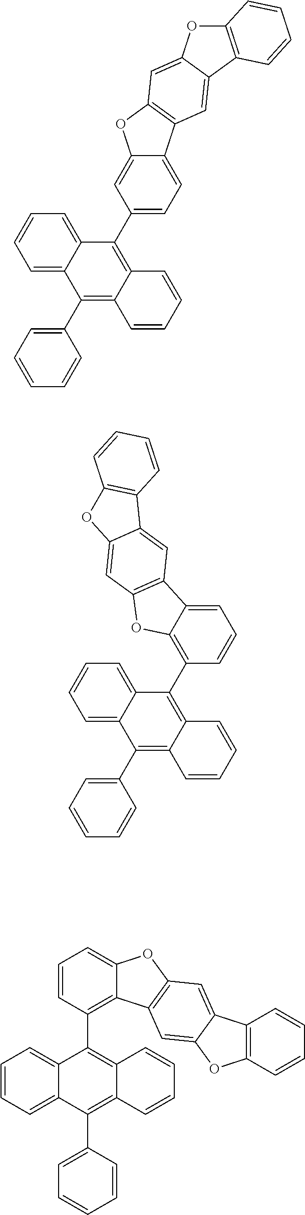 [SMILES: c1ccc(-c2c3ccccc3c(-c3ccc4c(c3)oc3cc5oc6ccccc6c5cc34)c3ccccc23)cc1 ; c1ccc(-c2c3ccccc3c(-c3cccc4c3oc3cc5oc6ccccc6c5cc34)c3ccccc23)cc1 ; c1ccc(-c2c3ccccc3c(-c3cccc4oc5cc6c(cc5c34)oc3ccccc36)c3ccccc23)cc1]

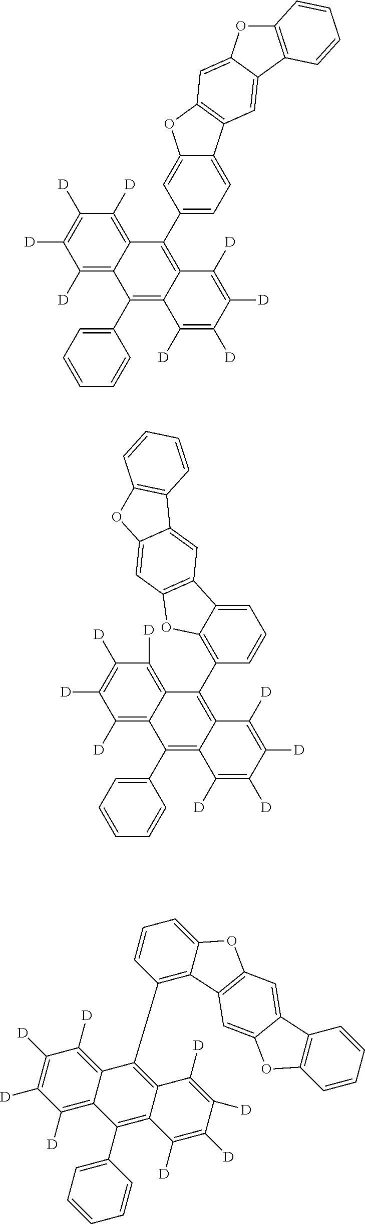 [SMILES: [2H]c1c([2H])c([2H])c2c(-c3ccc4c(c3)oc3cc5oc6ccccc6c5cc34)c3c([2H])c([2H])c([2H])c([2H])c3c(-c3ccccc3)c2c1[2H] ; [2H]c1c([2H])c([2H])c2c(-c3cccc4c3oc3cc5oc6ccccc6c5cc34)c3c([2H])c([2H])c([2H])c([2H])c3c(-c3ccccc3)c2c1[2H] ; [2H]c1c([2H])c([2H])c2c(-c3cccc4oc5cc6c(cc5c34)oc3ccccc36)c3c([2H])c([2H])c([2H])c([2H])c3c(-c3ccccc3)c2c1[2H]]

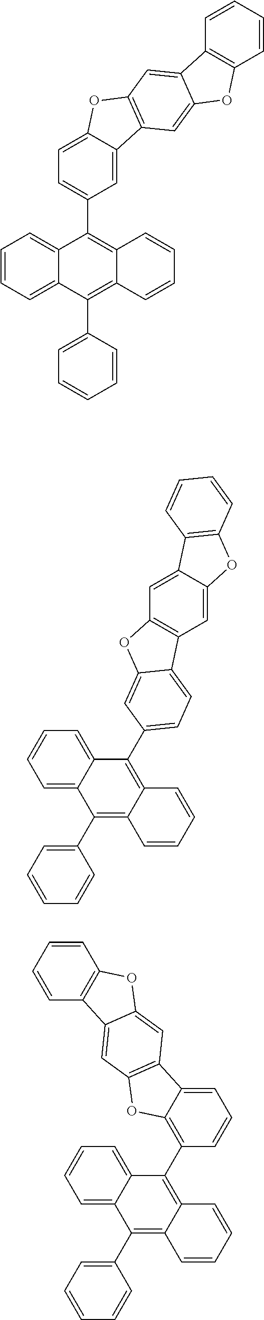

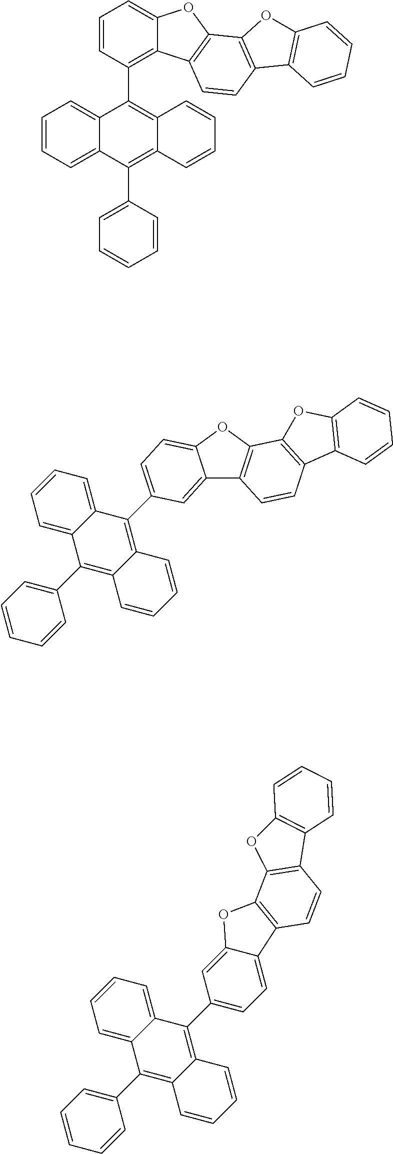 [SMILES: c1ccc(-c2c3ccccc3c(-c3cccc4oc5c(ccc6c7ccccc7oc65)c34)c3ccccc23)cc1 ; c1ccc(-c2c3ccccc3c(-c3ccc4oc5c(ccc6c7ccccc7oc65)c4c3)c3ccccc23)cc1 ; c1ccc(-c2c3ccccc3c(-c3ccc4c(c3)oc3c4ccc4c5ccccc5oc43)c3ccccc23)cc1]

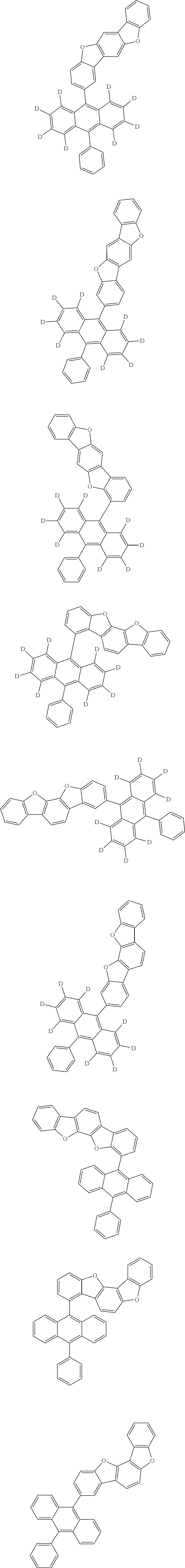

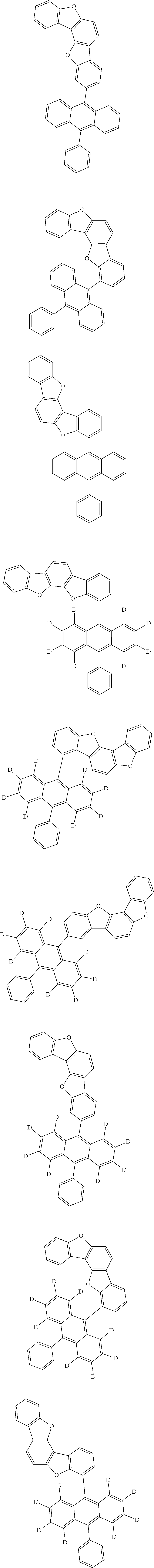

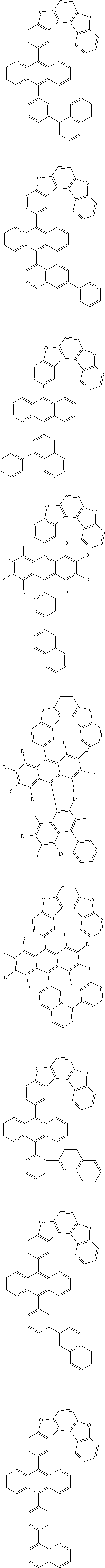

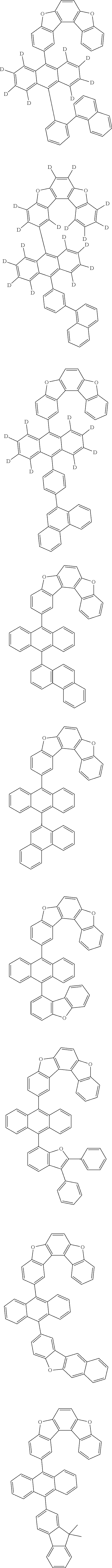

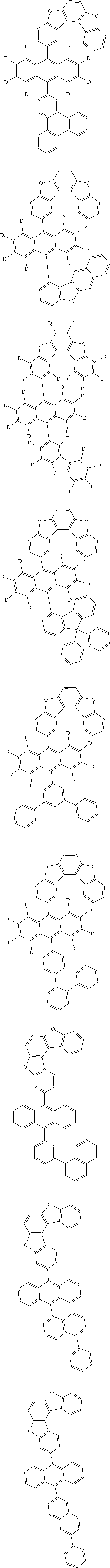

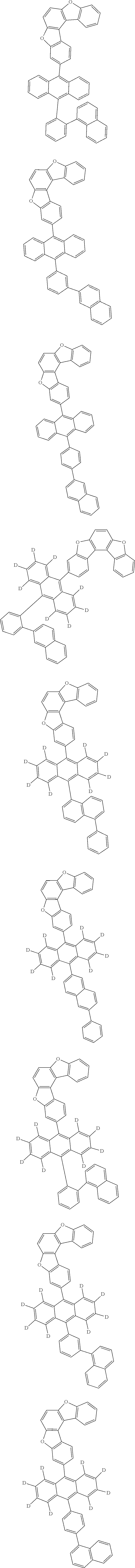

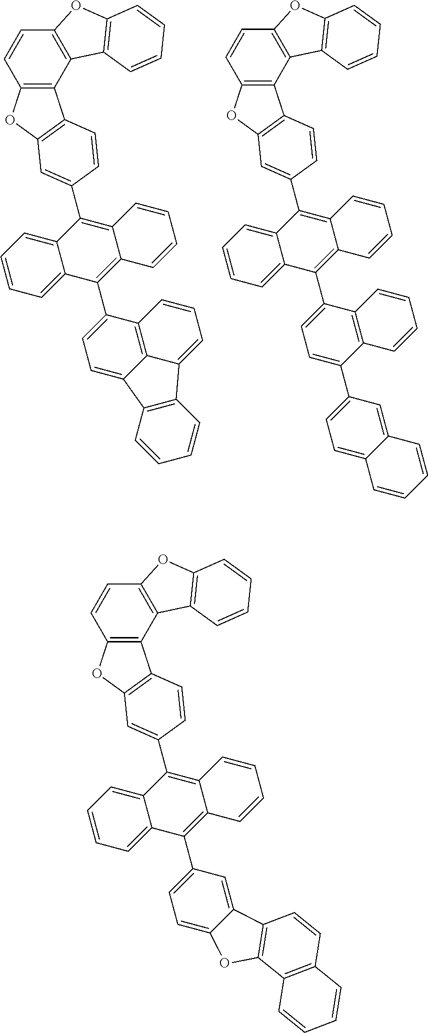

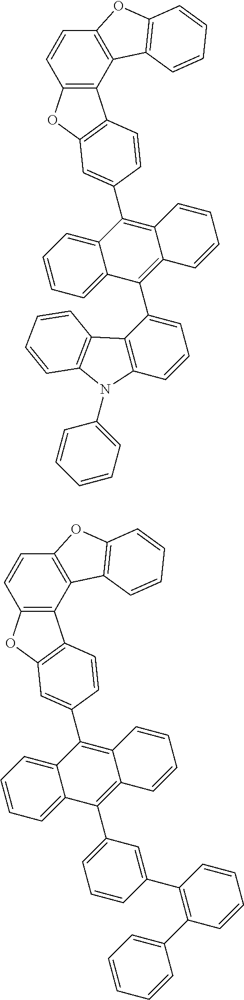

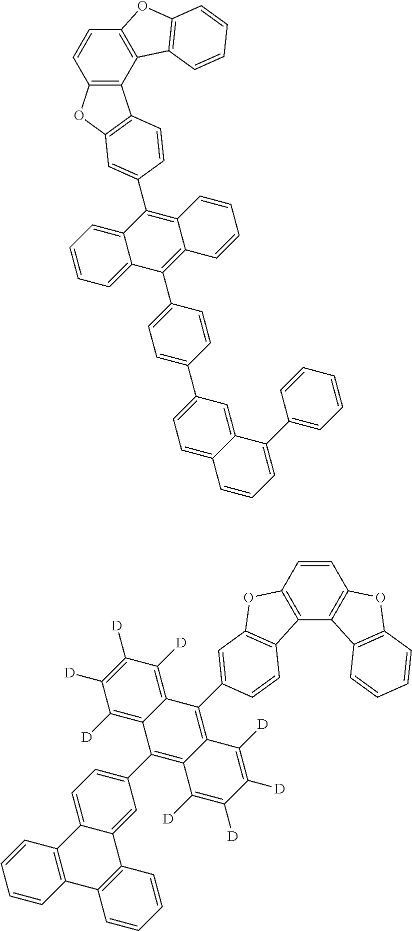 [SMILES: c1ccc(-c2cccc3ccc(-c4ccc(-c5c6ccccc6c(-c6ccc7c(c6)oc6ccc8oc9ccccc9c8c67)c6ccccc56)cc4)cc23)cc1 ; [2H]c1c([2H])c([2H])c2c(-c3ccc4c5ccccc5c5ccccc5c4c3)c3c([2H])c([2H])c([2H])c([2H])c3c(-c3ccc4c(c3)oc3ccc5oc6ccccc6c5c34)c2c1[2H]]

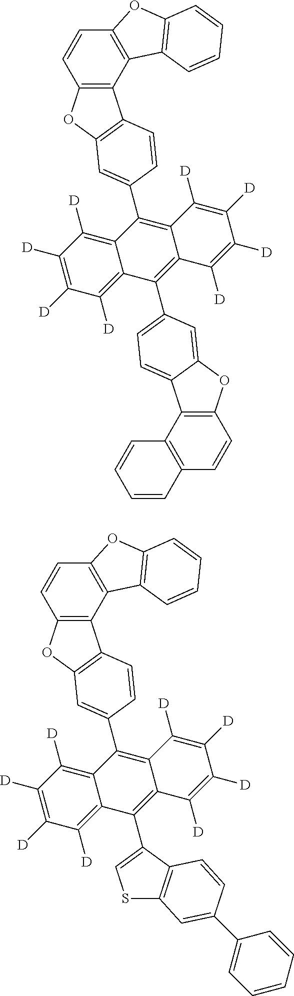

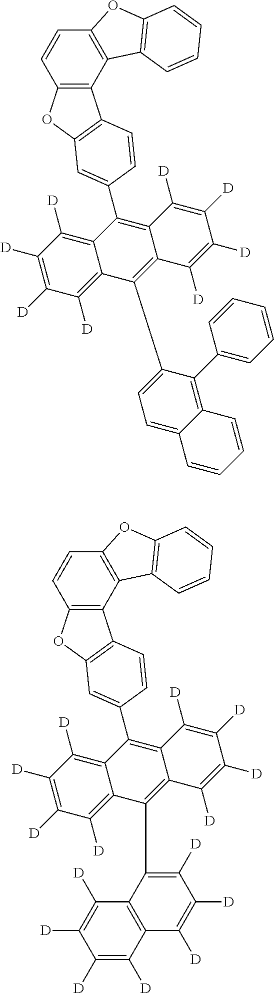 [SMILES: [2H]c1c([2H])c([2H])c2c(-c3ccc4ccccc4c3-c3ccccc3)c3c([2H])c([2H])c([2H])c([2H])c3c(-c3ccc4c(c3)oc3ccc5oc6ccccc6c5c34)c2c1[2H] ; [2H]c1c([2H])c([2H])c2c(-c3c4c([2H])c([2H])c([2H])c([2H])c4c(-c4ccc5c(c4)oc4ccc6oc7ccccc7c6c45)c4c([2H])c([2H])c([2H])c([2H])c34)c([2H])c([2H])c([2H])c2c1[2H]]

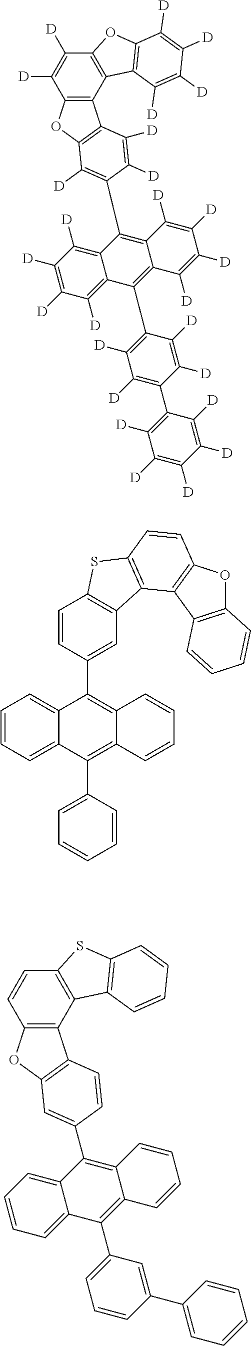

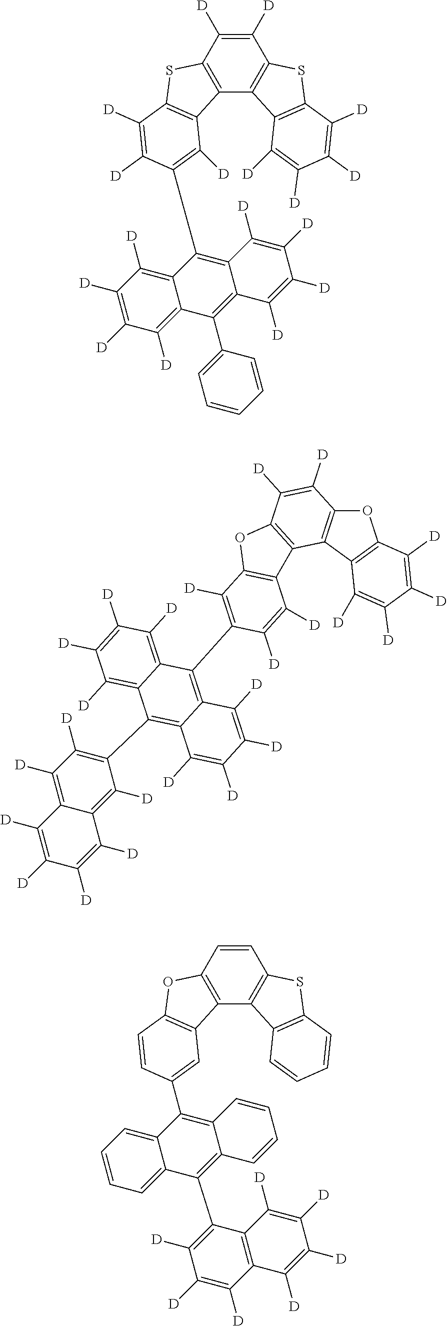 [SMILES: [2H]c1c([2H])c([2H])c2c(sc3c([2H])c([2H])c4sc5c([2H])c([2H])c(-c6c7c([2H])c([2H])c([2H])c([2H])c7c(-c7ccccc7)c7c([2H])c([2H])c([2H])c([2H])c67)c([2H])c5c4c32)c1[2H] ; [2H]c1c([2H])c([2H])c2c(oc3c([2H])c([2H])c4oc5c([2H])c(-c6c7c([2H])c([2H])c([2H])c([2H])c7c(-c7c([2H])c([2H])c8c([2H])c([2H])c([2H])c([2H])c8c7[2H])c7c([2H])c([2H])c([2H])c([2H])c67)c([2H])c([2H])c5c4c32)c1[2H] ; [2H]c1c([2H])c([2H])c2c(-c3c4ccccc4c(-c4ccc5oc6ccc7sc8ccccc8c7c6c5c4)c4ccccc34)c([2H])c([2H])c([2H])c2c1[2H]]

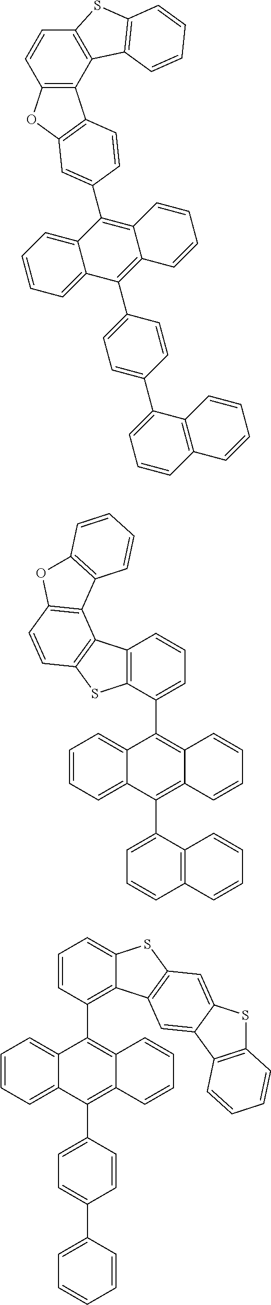

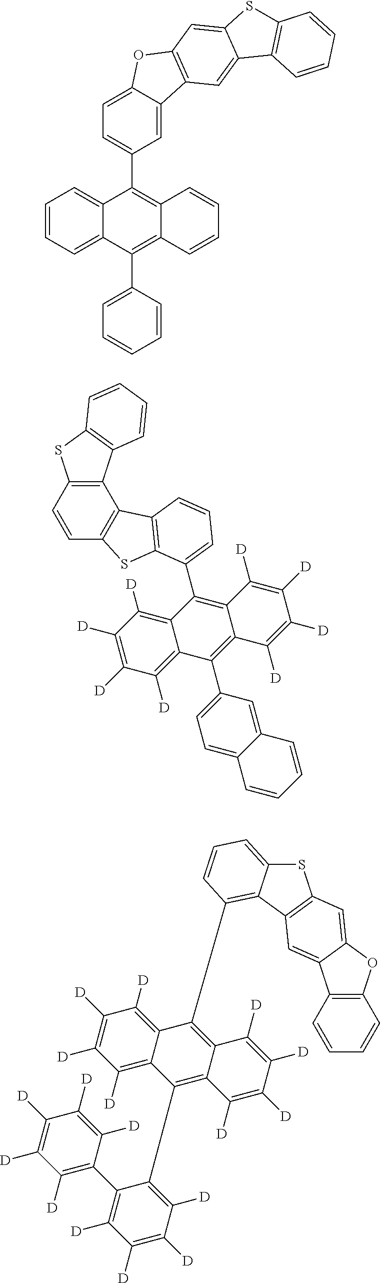

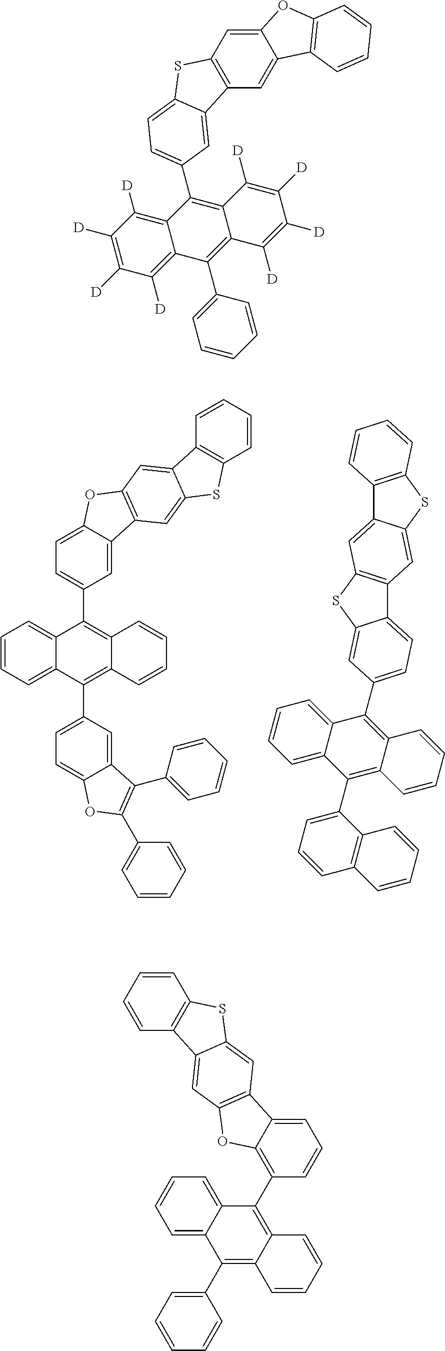

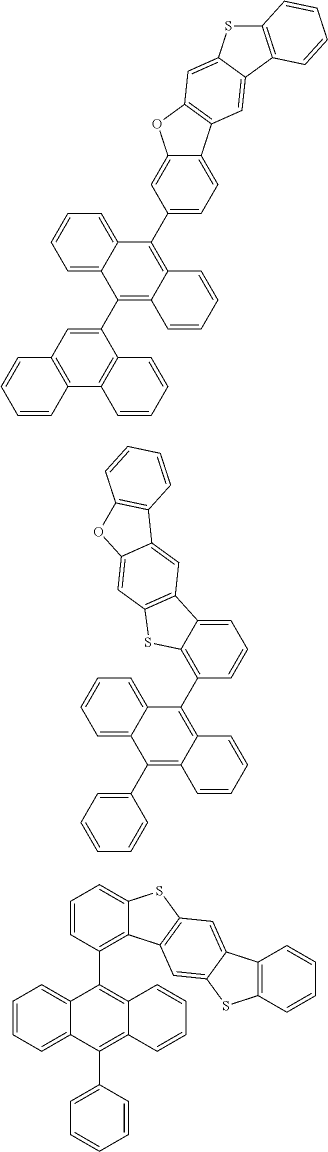

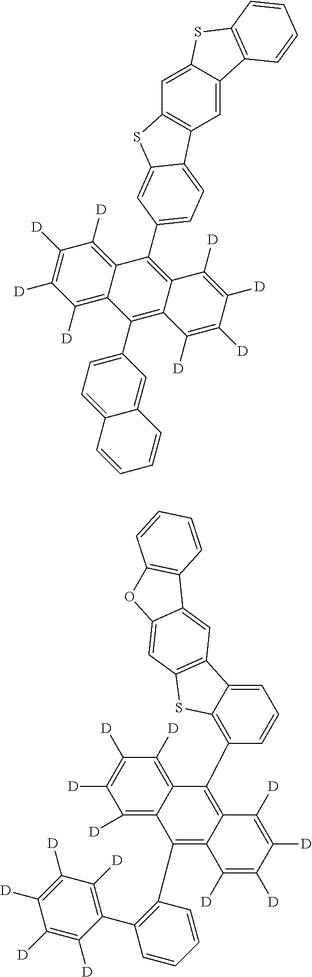

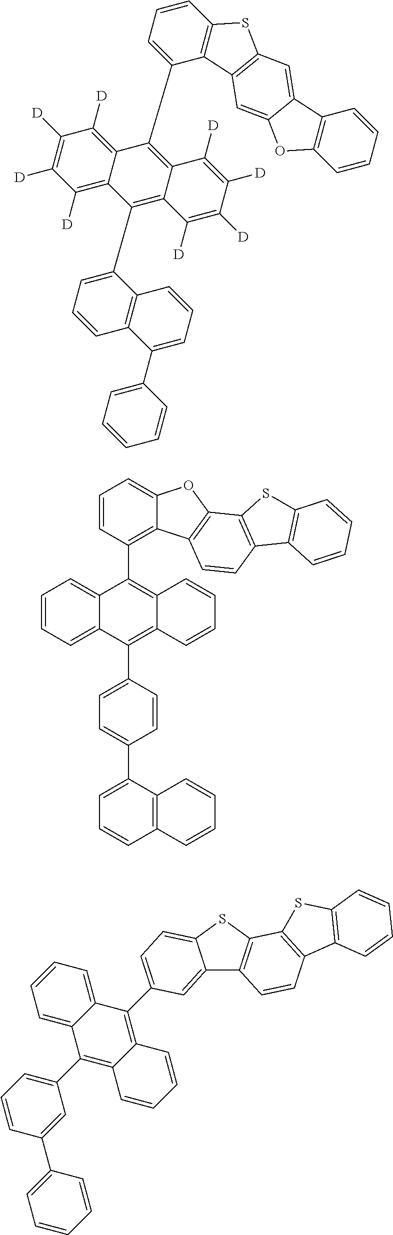

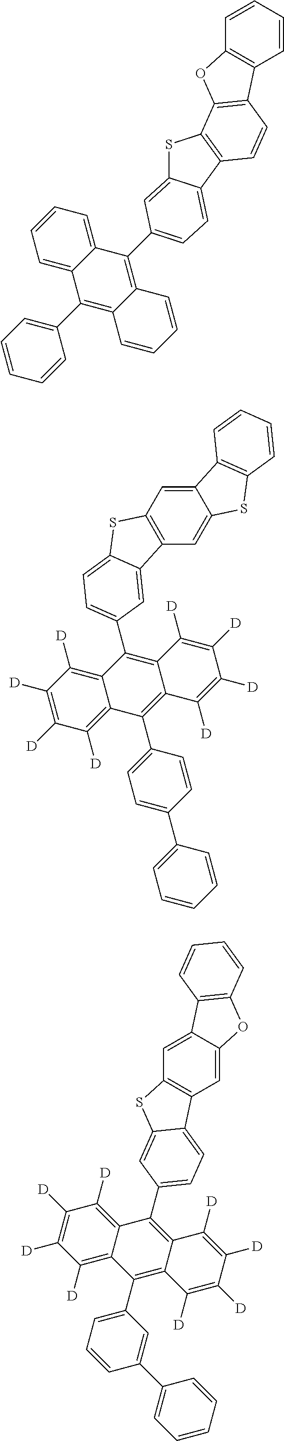

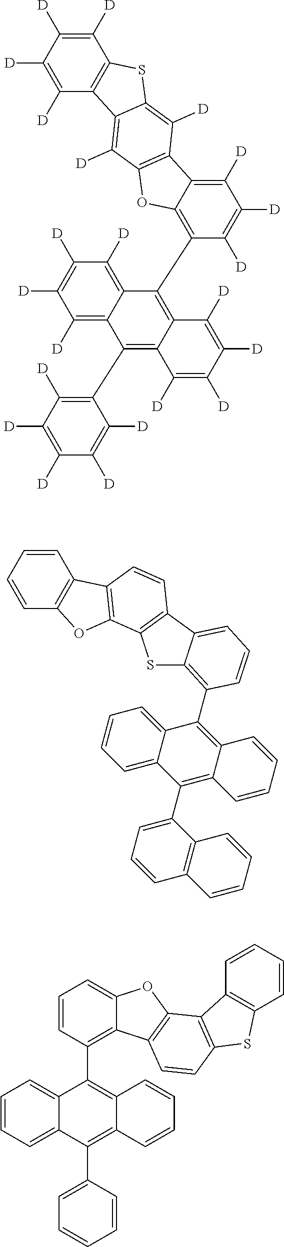 [SMILES: [2H]c1c([2H])c([2H])c(-c2c3c([2H])c([2H])c([2H])c([2H])c3c(-c3c([2H])c([2H])c([2H])c4c3oc3c([2H])c5c(sc6c([2H])c([2H])c([2H])c([2H])c65)c([2H])c34)c3c([2H])c([2H])c([2H])c([2H])c23)c([2H])c1[2H] ; c1ccc2c(-c3c4ccccc4c(-c4cccc5c4sc4c5ccc5c6ccccc6oc54)c4ccccc34)cccc2c1 ; c1ccc(-c2c3ccccc3c(-c3cccc4oc5c(ccc6sc7ccccc7c65)c34)c3ccccc23)cc1]

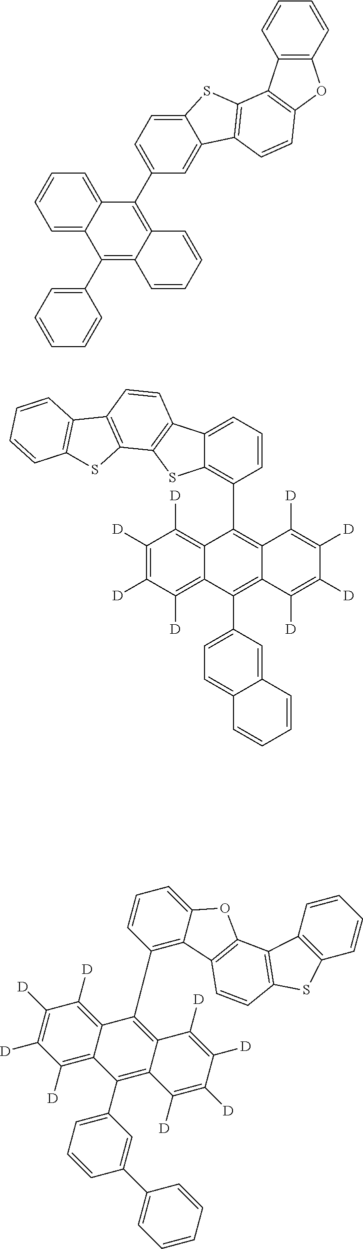 [SMILES: c1ccc(-c2c3ccccc3c(-c3ccc4sc5c(ccc6oc7ccccc7c65)c4c3)c3ccccc23)cc1 ; [2H]c1c([2H])c([2H])c2c(-c3cccc4c3sc3c4ccc4c5ccccc5sc43)c3c([2H])c([2H])c([2H])c([2H])c3c(-c3ccc4ccccc4c3)c2c1[2H] ; [2H]c1c([2H])c([2H])c2c(-c3cccc4oc5c(ccc6sc7ccccc7c65)c34)c3c([2H])c([2H])c([2H])c([2H])c3c(-c3cccc(-c4ccccc4)c3)c2c1[2H]]

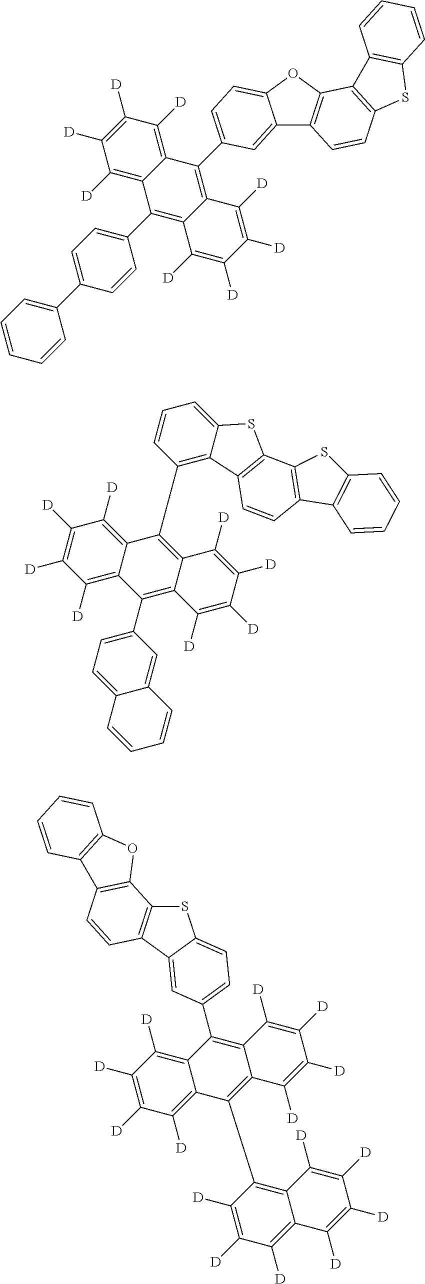 [SMILES: [2H]c1c([2H])c([2H])c2c(-c3ccc4oc5c(ccc6sc7ccccc7c65)c4c3)c3c([2H])c([2H])c([2H])c([2H])c3c(-c3ccc(-c4ccccc4)cc3)c2c1[2H] ; [2H]c1c([2H])c([2H])c2c(-c3cccc4sc5c(ccc6c7ccccc7sc65)c34)c3c([2H])c([2H])c([2H])c([2H])c3c(-c3ccc4ccccc4c3)c2c1[2H] ; [2H]c1c([2H])c([2H])c2c(-c3c4c([2H])c([2H])c([2H])c([2H])c4c(-c4ccc5sc6c(ccc7c8ccccc8oc76)c5c4)c4c([2H])c([2H])c([2H])c([2H])c34)c([2H])c([2H])c([2H])c2c1[2H]]

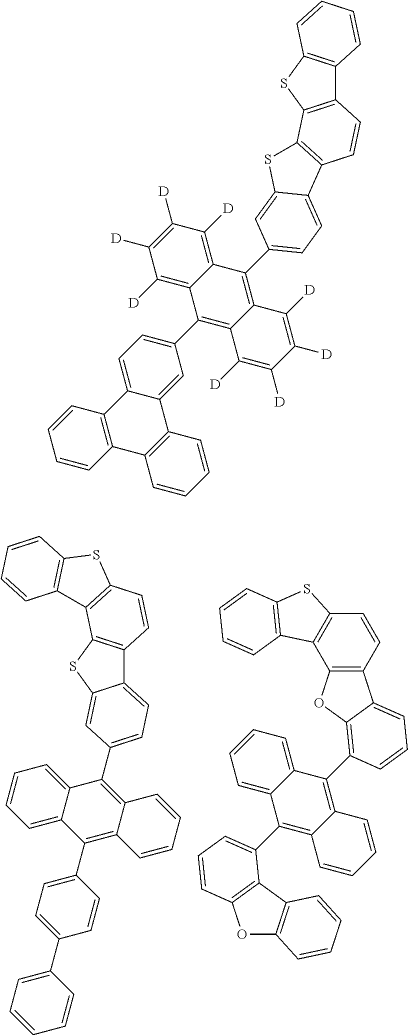

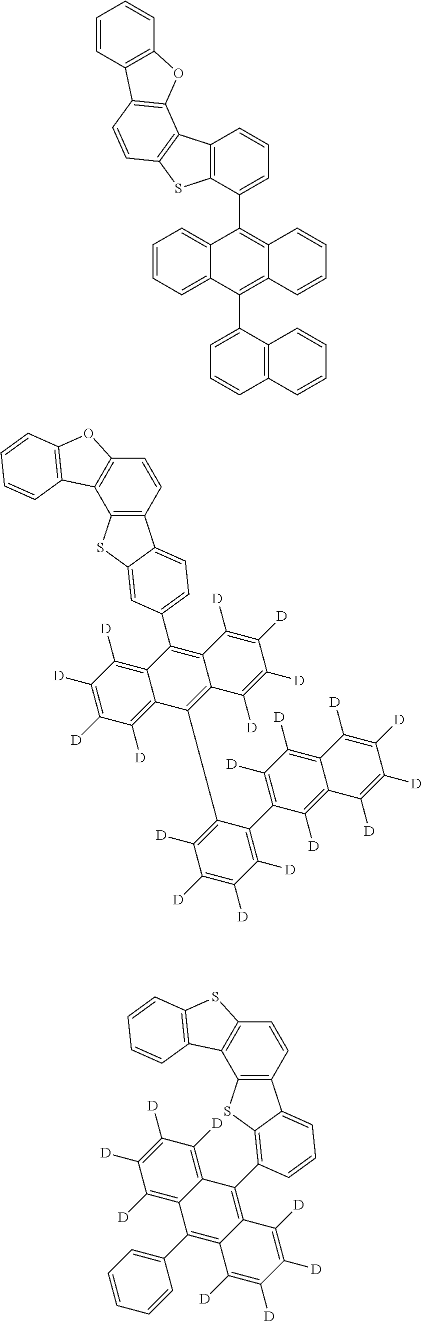 [SMILES: c1ccc2c(-c3c4ccccc4c(-c4cccc5c4sc4ccc6c7ccccc7oc6c45)c4ccccc34)cccc2c1 ; [2H]c1c([2H])c([2H])c(-c2c3c([2H])c([2H])c([2H])c([2H])c3c(-c3ccc4c(c3)sc3c4ccc4oc5ccccc5c43)c3c([2H])c([2H])c([2H])c([2H])c23)c(-c2c([2H])c([2H])c3c([2H])c([2H])c([2H])c([2H])c3c2[2H])c1[2H] ; [2H]c1c([2H])c([2H])c2c(-c3cccc4c3sc3c4ccc4sc5ccccc5c43)c3c([2H])c([2H])c([2H])c([2H])c3c(-c3ccccc3)c2c1[2H]]

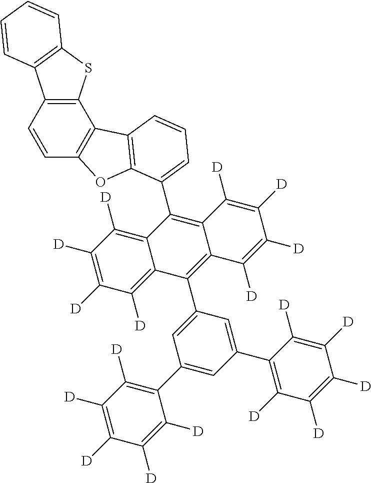 [SMILES: [2H]c1c([2H])c([2H])c(-c2cc(-c3c([2H])c([2H])c([2H])c([2H])c3[2H])cc(-c3c4c([2H])c([2H])c([2H])c([2H])c4c(-c4cccc5c4oc4ccc6c7ccccc7sc6c45)c4c([2H])c([2H])c([2H])c([2H])c34)c2)c([2H])c1[2H]]

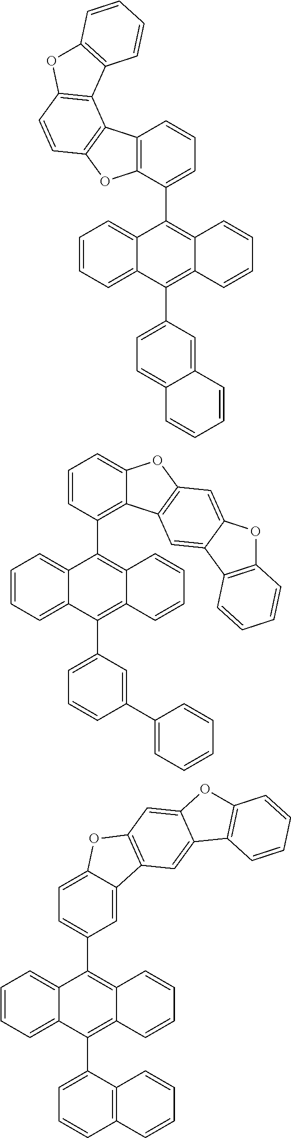

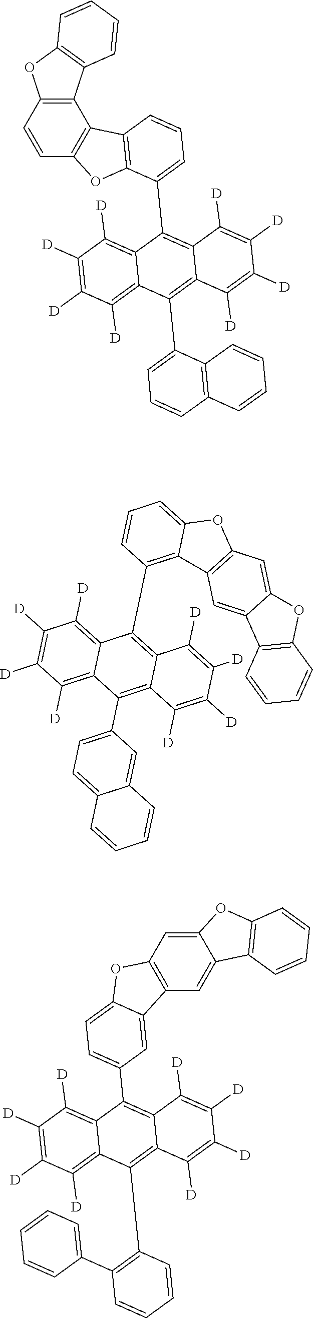 [SMILES: [2H]c1c([2H])c([2H])c2c(-c3cccc4c3oc3ccc5oc6ccccc6c5c34)c3c([2H])c([2H])c([2H])c([2H])c3c(-c3cccc4ccccc34)c2c1[2H] ; [2H]c1c([2H])c([2H])c2c(-c3cccc4oc5cc6oc7ccccc7c6cc5c34)c3c([2H])c([2H])c([2H])c([2H])c3c(-c3ccc4ccccc4c3)c2c1[2H] ; [2H]c1c([2H])c([2H])c2c(-c3ccccc3-c3ccccc3)c3c([2H])c([2H])c([2H])c([2H])c3c(-c3ccc4oc5cc6oc7ccccc7c6cc5c4c3)c2c1[2H]]

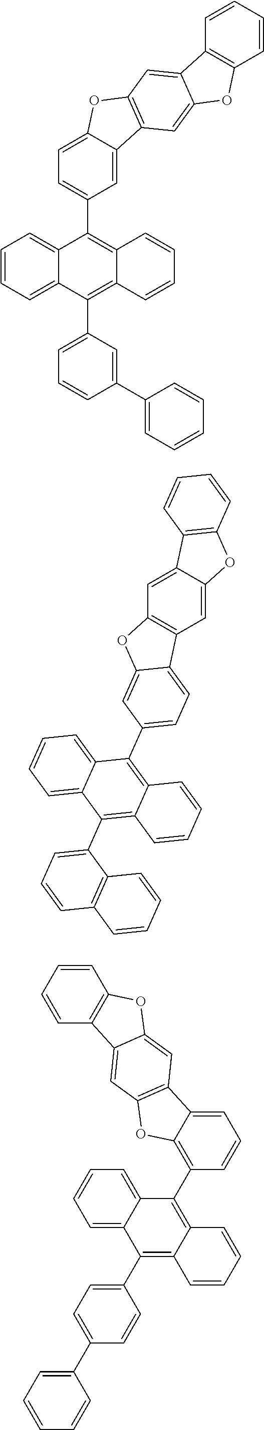

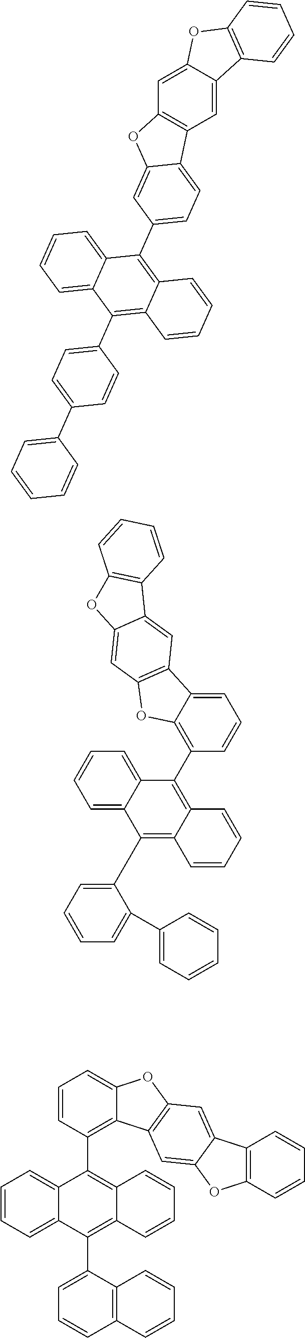 [SMILES: c1ccc(-c2ccc(-c3c4ccccc4c(-c4ccc5c(c4)oc4cc6oc7ccccc7c6cc45)c4ccccc34)cc2)cc1 ; c1ccc(-c2ccccc2-c2c3ccccc3c(-c3cccc4c3oc3cc5oc6ccccc6c5cc34)c3ccccc23)cc1 ; c1ccc2c(-c3c4ccccc4c(-c4cccc5oc6cc7c(cc6c45)oc4ccccc47)c4ccccc34)cccc2c1]

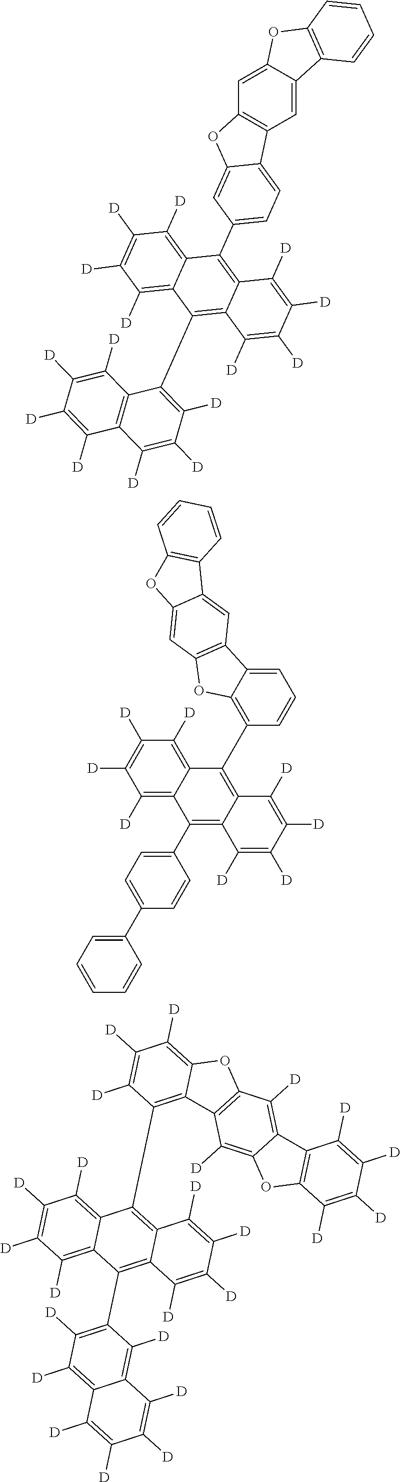

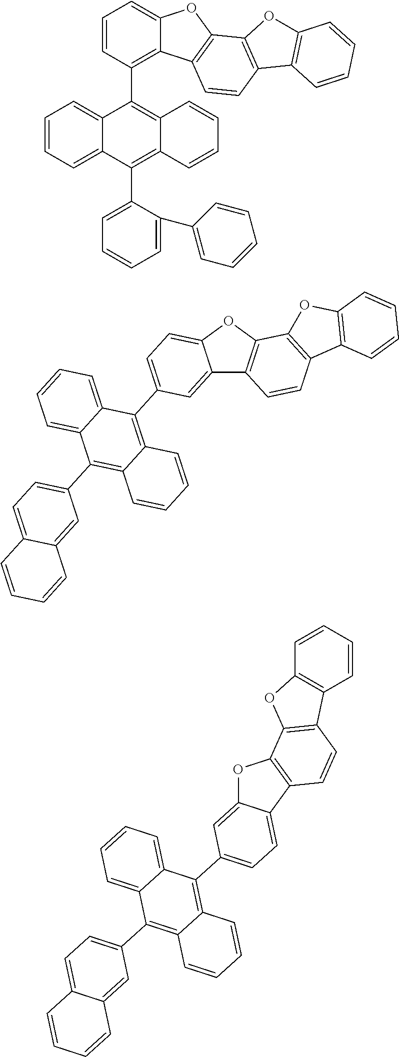 [SMILES: c1ccc(-c2ccccc2-c2c3ccccc3c(-c3cccc4oc5c(ccc6c7ccccc7oc65)c34)c3ccccc23)cc1 ; c1ccc2cc(-c3c4ccccc4c(-c4ccc5oc6c(ccc7c8ccccc8oc76)c5c4)c4ccccc34)ccc2c1 ; c1ccc2cc(-c3c4ccccc4c(-c4ccc5c(c4)oc4c5ccc5c6ccccc6oc54)c4ccccc34)ccc2c1]

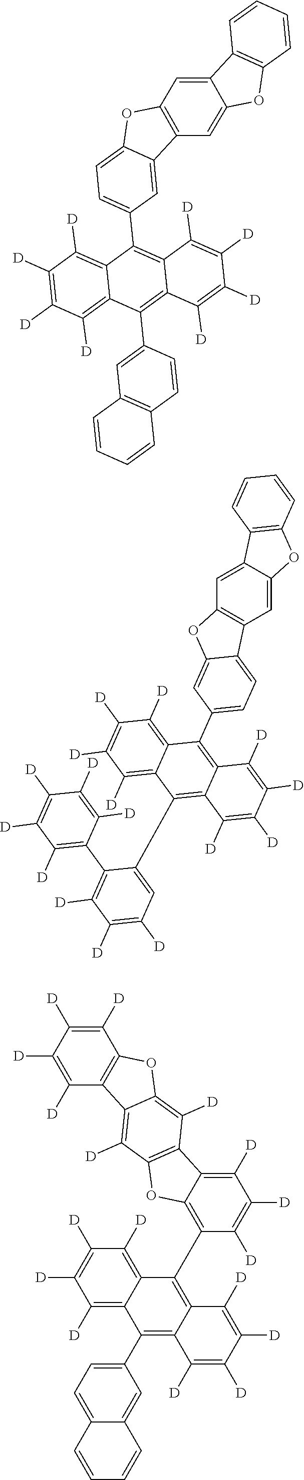 [SMILES: [2H]c1c([2H])c([2H])c2c(-c3ccc4oc5cc6c(cc5c4c3)oc3ccccc36)c3c([2H])c([2H])c([2H])c([2H])c3c(-c3ccc4ccccc4c3)c2c1[2H] ; [2H]c1cc(-c2c3c([2H])c([2H])c([2H])c([2H])c3c(-c3ccc4c(c3)oc3cc5c(cc34)oc3ccccc35)c3c([2H])c([2H])c([2H])c([2H])c23)c(-c2c([2H])c([2H])c([2H])c([2H])c2[2H])c([2H])c1[2H] ; [2H]c1c([2H])c([2H])c2c(oc3c([2H])c4c(oc5c(-c6c7c([2H])c([2H])c([2H])c([2H])c7c(-c7ccc8ccccc8c7)c7c([2H])c([2H])c([2H])c([2H])c67)c([2H])c([2H])c([2H])c54)c([2H])c32)c1[2H]]

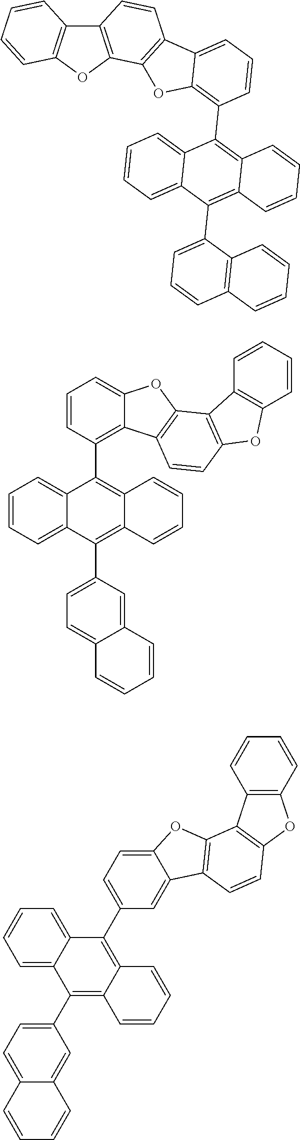

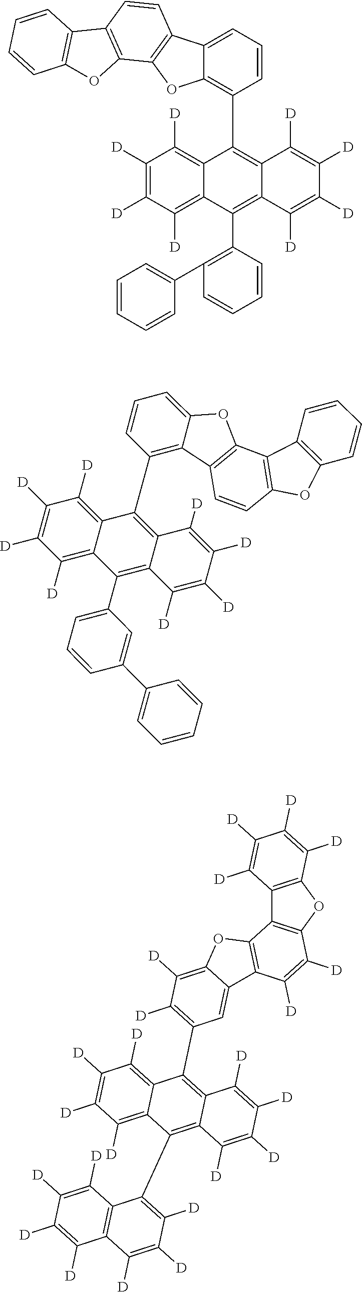 [SMILES: [2H]c1c([2H])c([2H])c2c(-c3cccc4c3oc3c4ccc4c5ccccc5oc43)c3c([2H])c([2H])c([2H])c([2H])c3c(-c3ccccc3-c3ccccc3)c2c1[2H] ; [2H]c1c([2H])c([2H])c2c(-c3cccc4oc5c(ccc6oc7ccccc7c65)c34)c3c([2H])c([2H])c([2H])c([2H])c3c(-c3cccc(-c4ccccc4)c3)c2c1[2H] ; [2H]c1c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)cc2c(oc3c2c([2H])c([2H])c2oc4c([2H])c([2H])c([2H])c([2H])c4c23)c1[2H]]

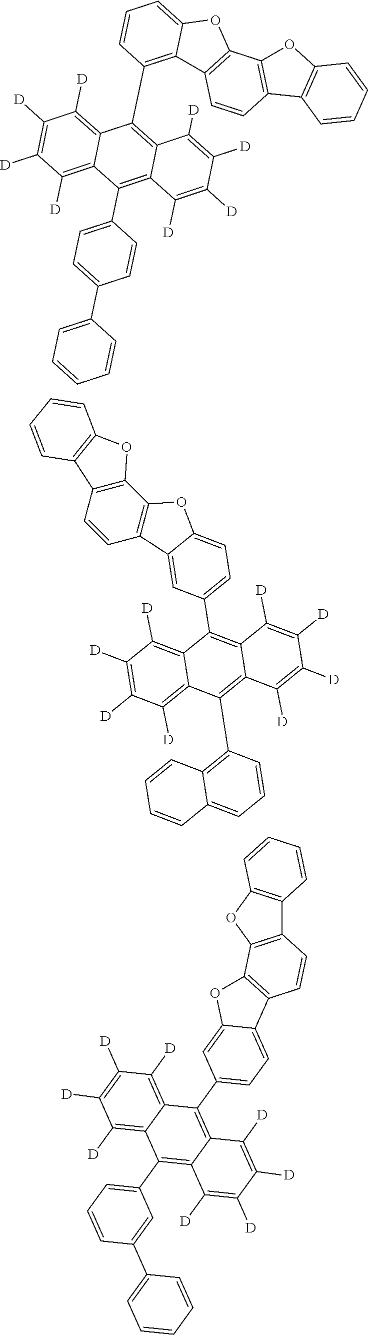

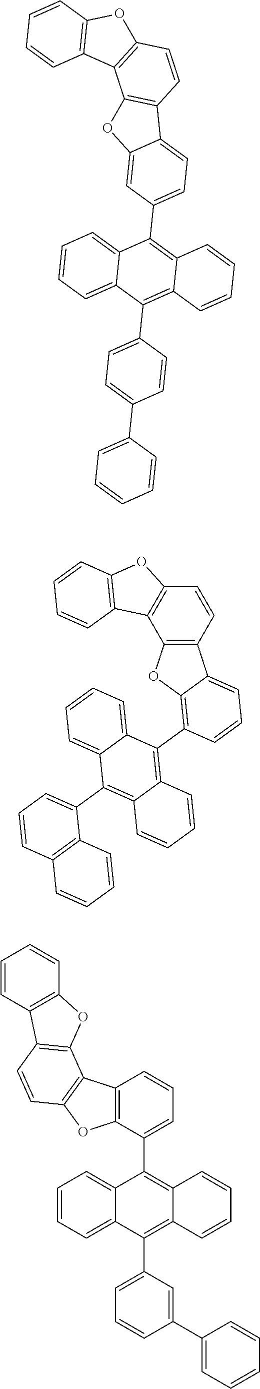 [SMILES: c1ccc(-c2ccc(-c3c4ccccc4c(-c4ccc5c(c4)oc4c5ccc5oc6ccccc6c54)c4ccccc34)cc2)cc1 ; c1ccc2c(-c3c4ccccc4c(-c4cccc5c4oc4c5ccc5oc6ccccc6c54)c4ccccc34)cccc2c1 ; c1ccc(-c2cccc(-c3c4ccccc4c(-c4cccc5c4oc4ccc6c7ccccc7oc6c45)c4ccccc34)c2)cc1]

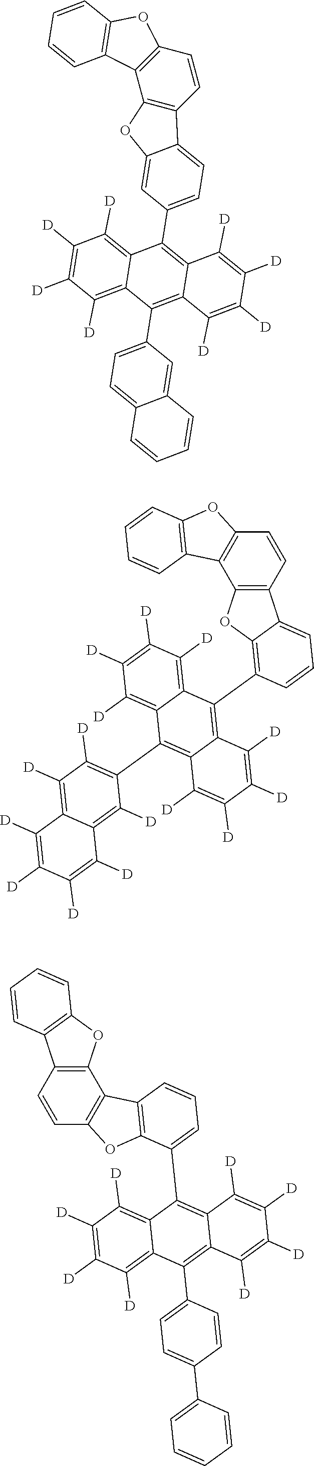

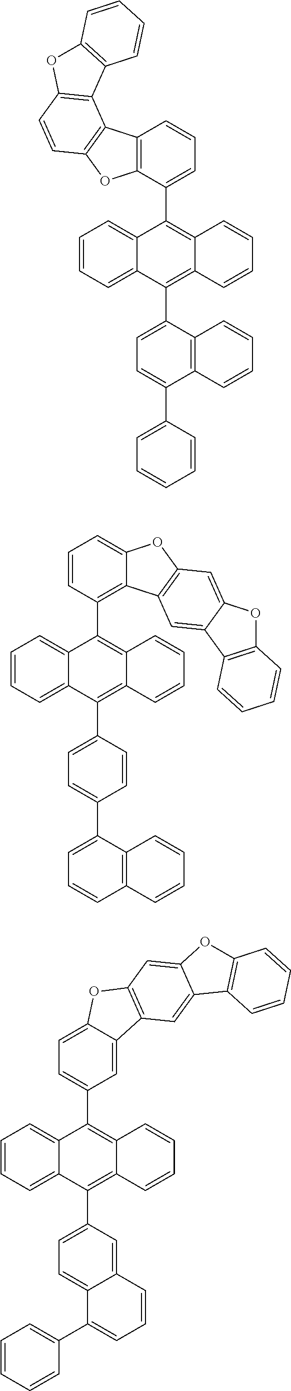 [SMILES: c1ccc(-c2ccc(-c3c4ccccc4c(-c4cccc5c4oc4ccc6oc7ccccc7c6c45)c4ccccc34)c3ccccc23)cc1 ; c1ccc2c(-c3ccc(-c4c5ccccc5c(-c5cccc6oc7cc8oc9ccccc9c8cc7c56)c5ccccc45)cc3)cccc2c1 ; c1ccc(-c2cccc3cc(-c4c5ccccc5c(-c5ccc6oc7cc8oc9ccccc9c8cc7c6c5)c5ccccc45)ccc23)cc1]

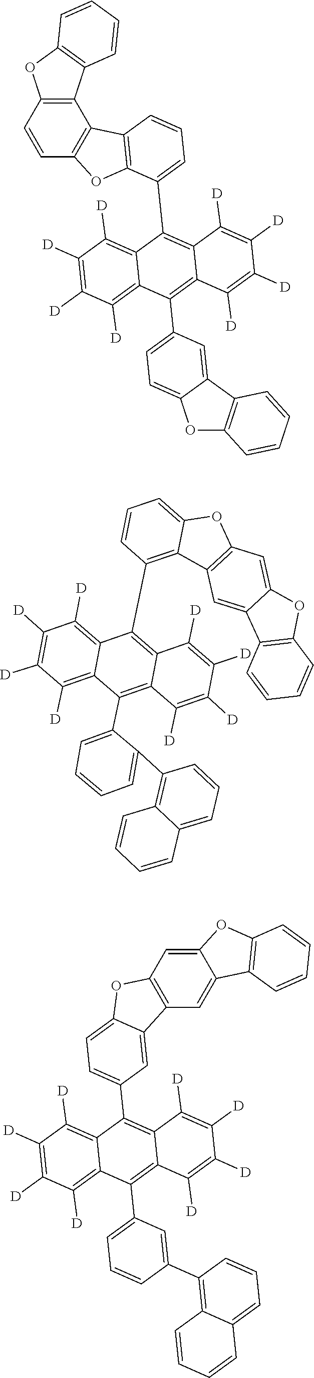 [SMILES: [2H]c1c([2H])c([2H])c2c(-c3cccc4c3oc3ccc5oc6ccccc6c5c34)c3c([2H])c([2H])c([2H])c([2H])c3c(-c3ccc4oc5ccccc5c4c3)c2c1[2H] ; [2H]c1c([2H])c([2H])c2c(-c3cccc4oc5cc6oc7ccccc7c6cc5c34)c3c([2H])c([2H])c([2H])c([2H])c3c(-c3ccccc3-c3cccc4ccccc34)c2c1[2H] ; [2H]c1c([2H])c([2H])c2c(-c3ccc4oc5cc6oc7ccccc7c6cc5c4c3)c3c([2H])c([2H])c([2H])c([2H])c3c(-c3cccc(-c4cccc5ccccc45)c3)c2c1[2H]]

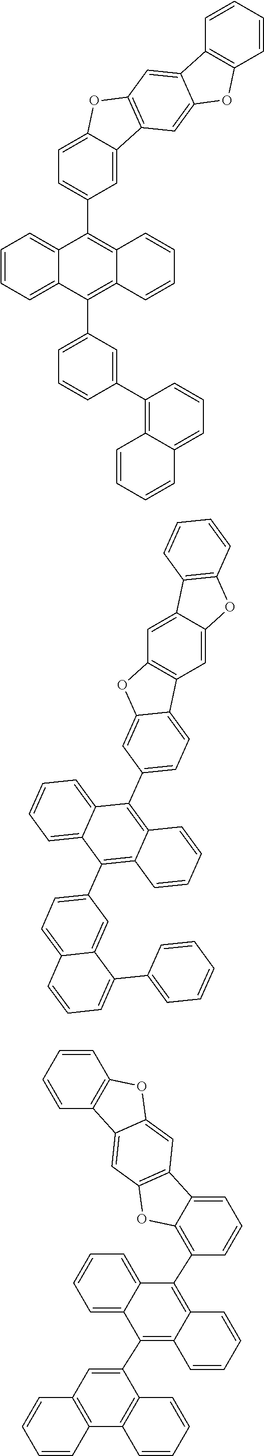

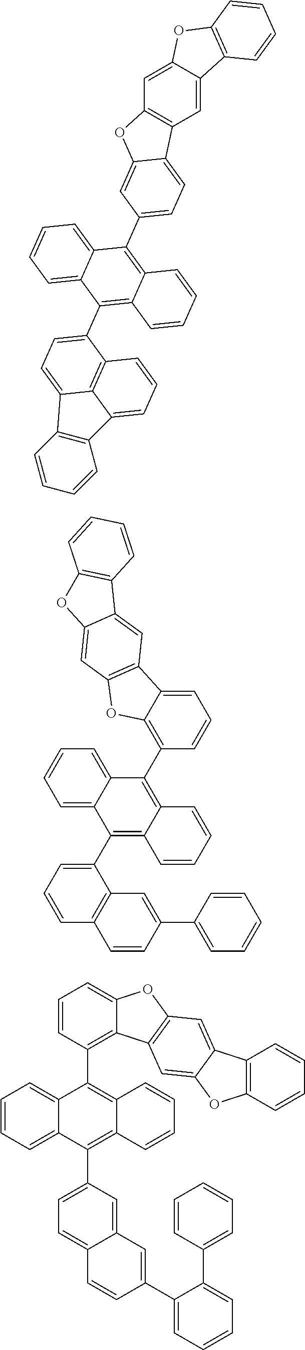

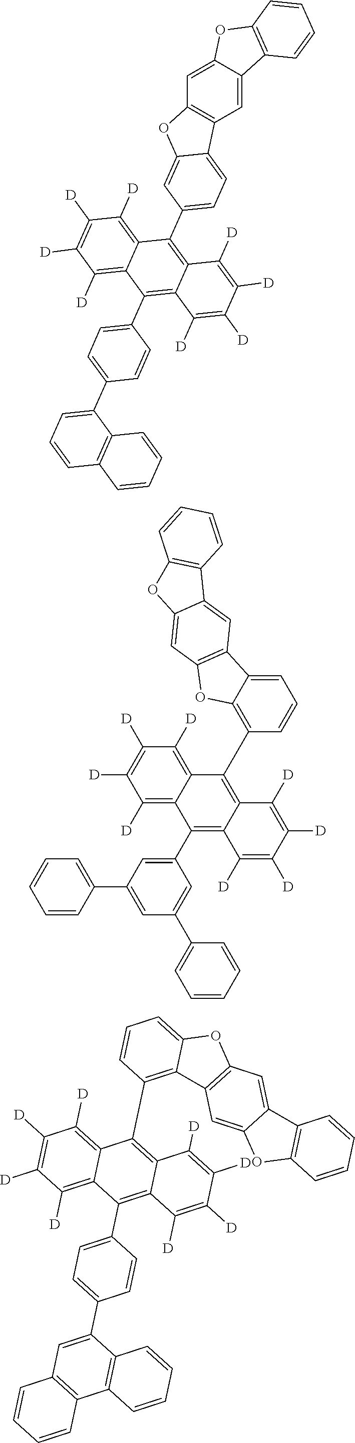

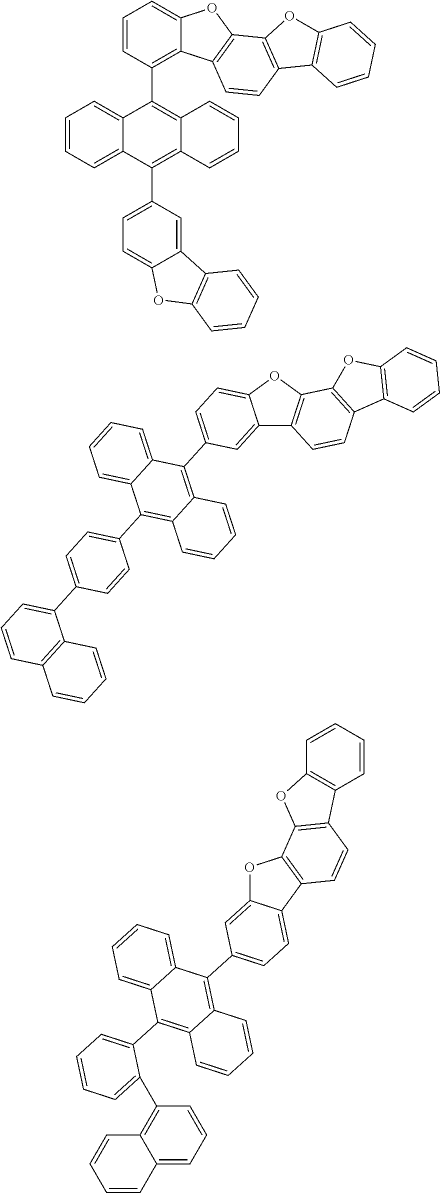 [SMILES: c1ccc2c(c1)oc1ccc(-c3c4ccccc4c(-c4cccc5oc6c(ccc7c8ccccc8oc76)c45)c4ccccc34)cc12 ; c1ccc2c(-c3ccc(-c4c5ccccc5c(-c5ccc6oc7c(ccc8c9ccccc9oc87)c6c5)c5ccccc45)cc3)cccc2c1 ; c1ccc(-c2c3ccccc3c(-c3ccc4c(c3)oc3c4ccc4c5ccccc5oc43)c3ccccc23)c(-c2cccc3ccccc23)c1]

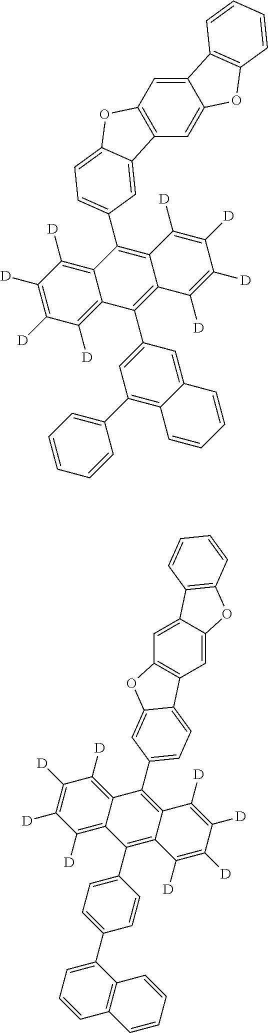 [SMILES: [2H]c1c([2H])c([2H])c2c(-c3ccc4oc5cc6c(cc5c4c3)oc3ccccc36)c3c([2H])c([2H])c([2H])c([2H])c3c(-c3cc(-c4ccccc4)c4ccccc4c3)c2c1[2H] ; [2H]c1c([2H])c([2H])c2c(-c3ccc4c(c3)oc3cc5c(cc34)oc3ccccc35)c3c([2H])c([2H])c([2H])c([2H])c3c(-c3ccc(-c4cccc5ccccc45)cc3)c2c1[2H]]

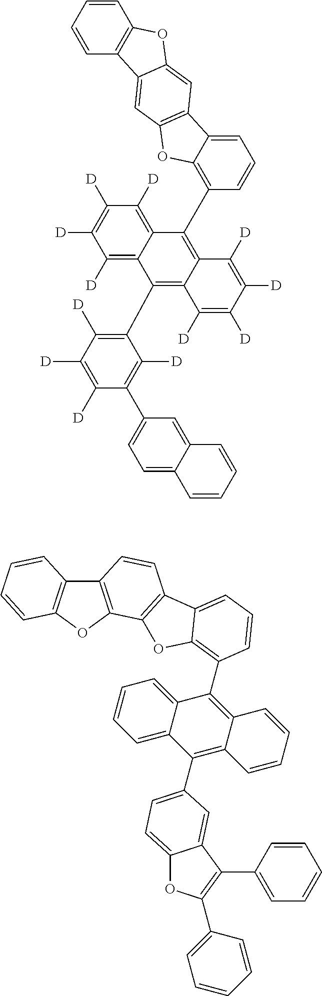 [SMILES: [2H]c1c([2H])c(-c2ccc3ccccc3c2)c([2H])c(-c2c3c([2H])c([2H])c([2H])c([2H])c3c(-c3cccc4c3oc3cc5c(cc34)oc3ccccc35)c3c([2H])c([2H])c([2H])c([2H])c23)c1[2H] ; c1ccc(-c2oc3ccc(-c4c5ccccc5c(-c5cccc6c5oc5c6ccc6c7ccccc7oc65)c5ccccc45)cc3c2-c2ccccc2)cc1]

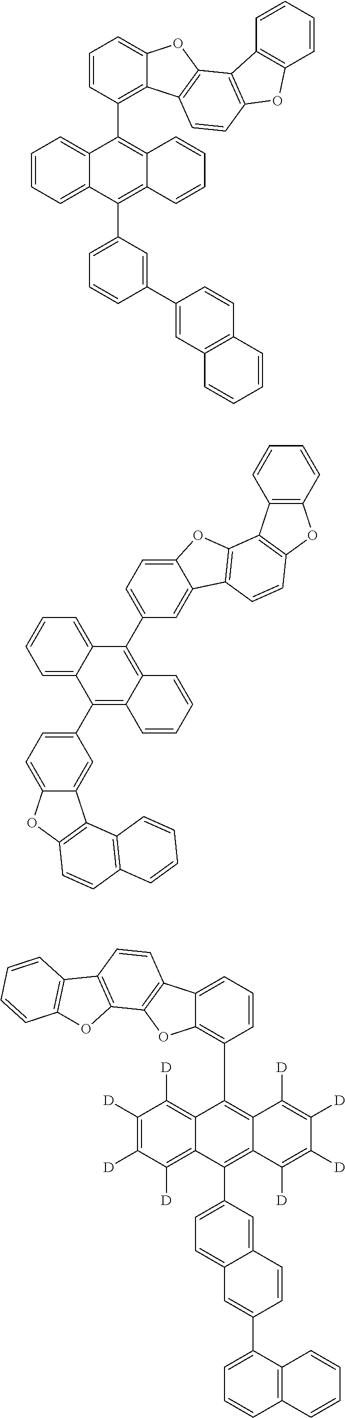 [SMILES: c1cc(-c2ccc3ccccc3c2)cc(-c2c3ccccc3c(-c3cccc4oc5c(ccc6oc7ccccc7c65)c34)c3ccccc23)c1 ; c1ccc2c(c1)ccc1oc3ccc(-c4c5ccccc5c(-c5ccc6oc7c(ccc8oc9ccccc9c87)c6c5)c5ccccc45)cc3c12 ; [2H]c1c([2H])c([2H])c2c(-c3cccc4c3oc3c4ccc4c5ccccc5oc43)c3c([2H])c([2H])c([2H])c([2H])c3c(-c3ccc4cc(-c5cccc6ccccc56)ccc4c3)c2c1[2H]]

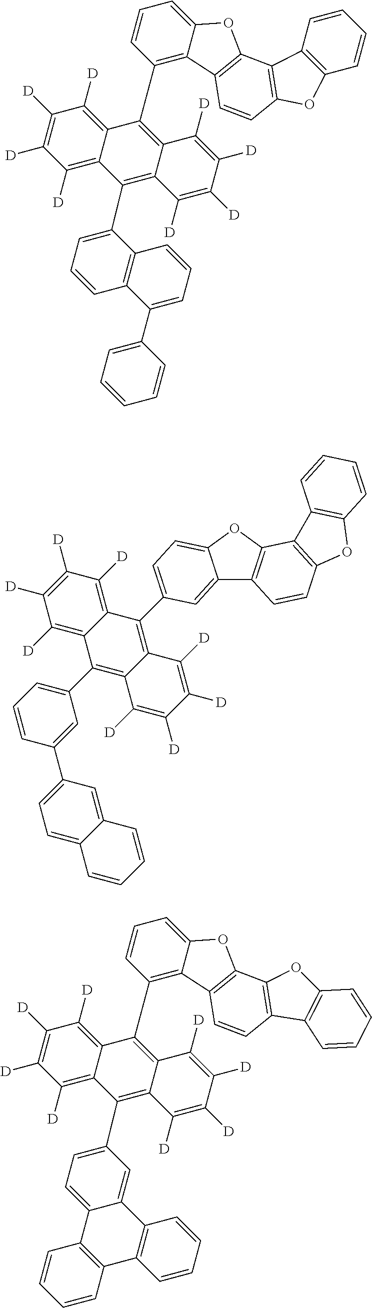

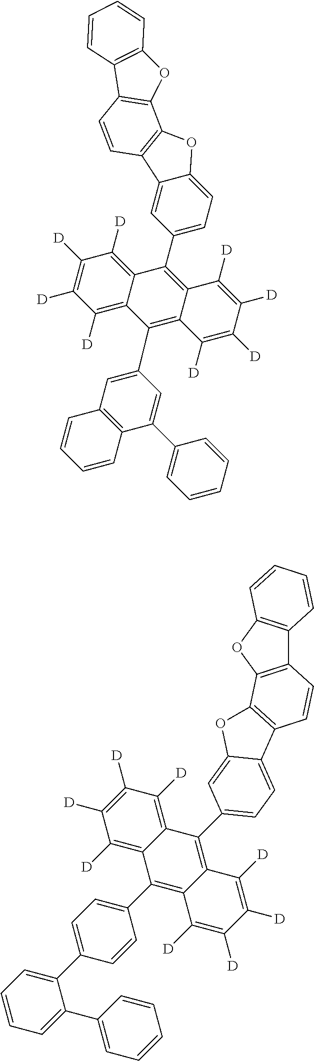 [SMILES: [2H]c1c([2H])c([2H])c2c(-c3ccc4oc5c(ccc6c7ccccc7oc65)c4c3)c3c([2H])c([2H])c([2H])c([2H])c3c(-c3cc(-c4ccccc4)c4ccccc4c3)c2c1[2H] ; [2H]c1c([2H])c([2H])c2c(-c3ccc4c(c3)oc3c4ccc4c5ccccc5oc43)c3c([2H])c([2H])c([2H])c([2H])c3c(-c3ccc(-c4ccccc4-c4ccccc4)cc3)c2c1[2H]]

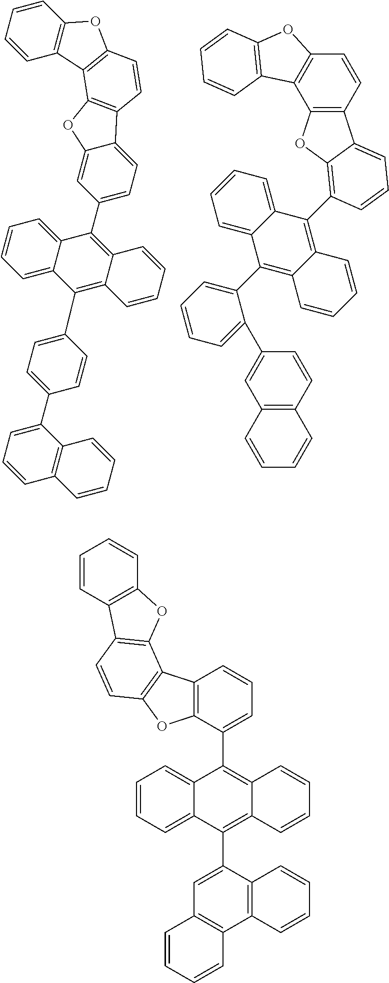

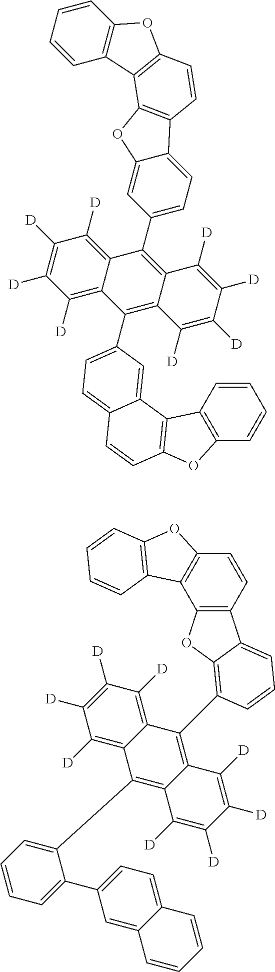 [SMILES: [2H]c1c([2H])c([2H])c2c(-c3ccc4ccc5oc6ccccc6c5c4c3)c3c([2H])c([2H])c([2H])c([2H])c3c(-c3ccc4c(c3)oc3c4ccc4oc5ccccc5c43)c2c1[2H] ; [2H]c1c([2H])c([2H])c2c(-c3cccc4c3oc3c4ccc4oc5ccccc5c43)c3c([2H])c([2H])c([2H])c([2H])c3c(-c3ccccc3-c3ccc4ccccc4c3)c2c1[2H]]

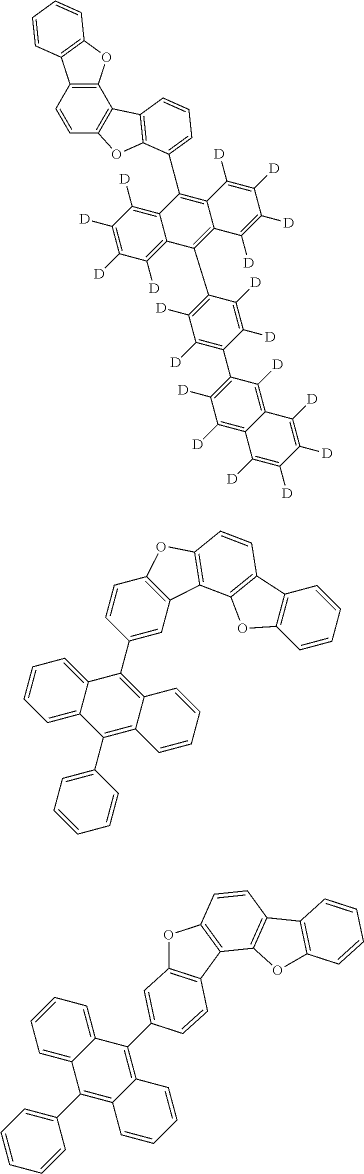 [SMILES: [2H]c1c([2H])c(-c2c3c([2H])c([2H])c([2H])c([2H])c3c(-c3cccc4c3oc3ccc5c6ccccc6oc5c34)c3c([2H])c([2H])c([2H])c([2H])c23)c([2H])c([2H])c1-c1c([2H])c([2H])c2c([2H])c([2H])c([2H])c([2H])c2c1[2H] ; c1ccc(-c2c3ccccc3c(-c3ccc4oc5ccc6c7ccccc7oc6c5c4c3)c3ccccc23)cc1 ; c1ccc(-c2c3ccccc3c(-c3ccc4c(c3)oc3ccc5c6ccccc6oc5c34)c3ccccc23)cc1]

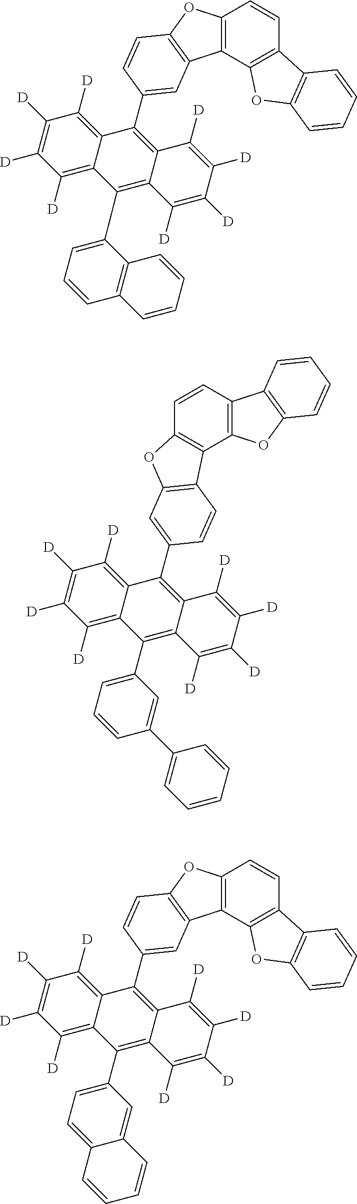 [SMILES: [2H]c1c([2H])c([2H])c2c(-c3cccc4ccccc34)c3c([2H])c([2H])c([2H])c([2H])c3c(-c3ccc4oc5ccc6c7ccccc7oc6c5c4c3)c2c1[2H] ; [2H]c1c([2H])c([2H])c2c(-c3ccc4c(c3)oc3ccc5c6ccccc6oc5c34)c3c([2H])c([2H])c([2H])c([2H])c3c(-c3cccc(-c4ccccc4)c3)c2c1[2H] ; [2H]c1c([2H])c([2H])c2c(-c3ccc4oc5ccc6c7ccccc7oc6c5c4c3)c3c([2H])c([2H])c([2H])c([2H])c3c(-c3ccc4ccccc4c3)c2c1[2H]]

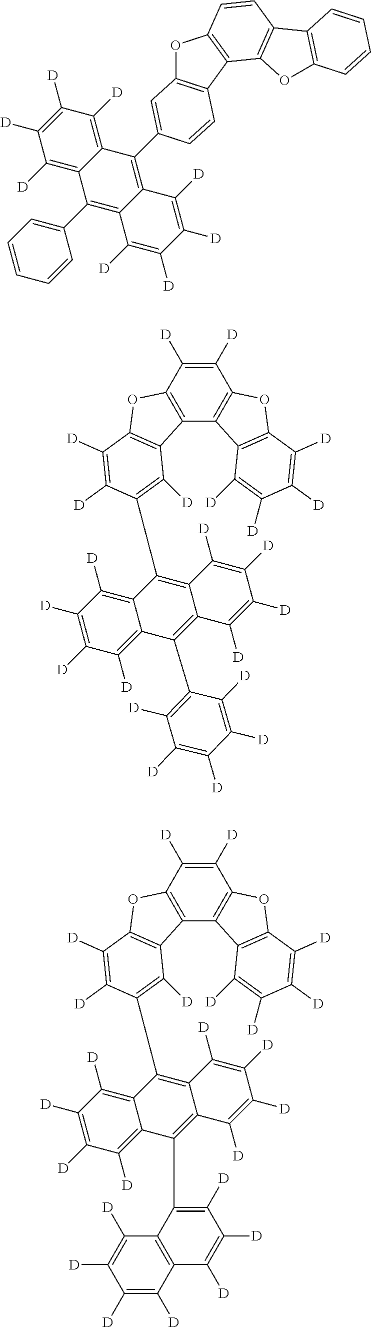

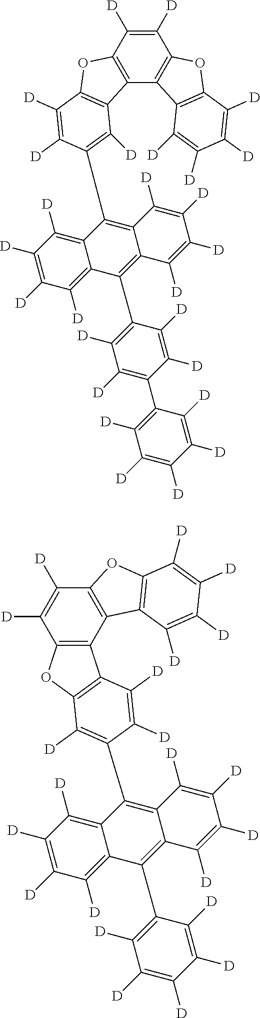

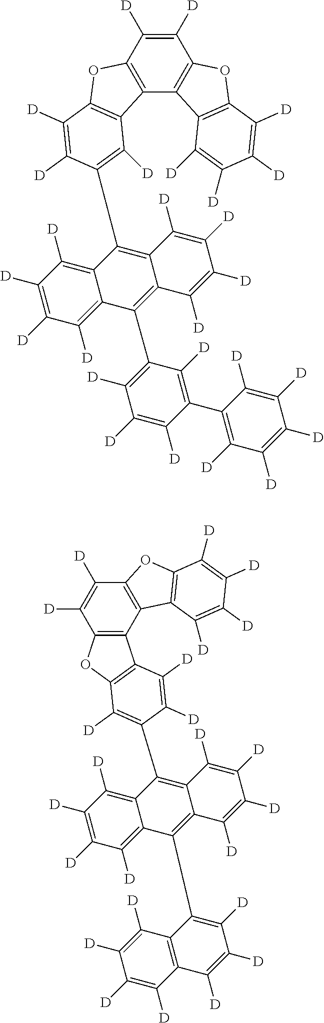 [SMILES: [2H]c1c([2H])c([2H])c(-c2c([2H])c([2H])c([2H])c(-c3c4c([2H])c([2H])c([2H])c([2H])c4c(-c4c([2H])c([2H])c5oc6c([2H])c([2H])c7oc8c([2H])c([2H])c([2H])c([2H])c8c7c6c5c4[2H])c4c([2H])c([2H])c([2H])c([2H])c34)c2[2H])c([2H])c1[2H] ; [2H]c1c([2H])c([2H])c2c(oc3c([2H])c([2H])c4oc5c([2H])c(-c6c7c([2H])c([2H])c([2H])c([2H])c7c(-c7c([2H])c([2H])c([2H])c8c([2H])c([2H])c([2H])c([2H])c78)c7c([2H])c([2H])c([2H])c([2H])c67)c([2H])c([2H])c5c4c32)c1[2H]]

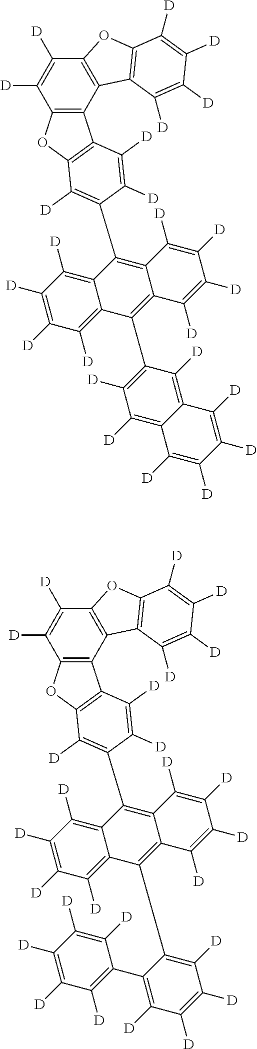 [SMILES: [2H]c1c([2H])c([2H])c2c(oc3c([2H])c([2H])c4oc5c([2H])c(-c6c7c([2H])c([2H])c([2H])c([2H])c7c(-c7c([2H])c([2H])c8c([2H])c([2H])c([2H])c([2H])c8c7[2H])c7c([2H])c([2H])c([2H])c([2H])c67)c([2H])c([2H])c5c4c32)c1[2H] ; [2H]c1c([2H])c([2H])c(-c2c([2H])c([2H])c([2H])c([2H])c2-c2c3c([2H])c([2H])c([2H])c([2H])c3c(-c3c([2H])c([2H])c4c(oc5c([2H])c([2H])c6oc7c([2H])c([2H])c([2H])c([2H])c7c6c54)c3[2H])c3c([2H])c([2H])c([2H])c([2H])c23)c([2H])c1[2H]]

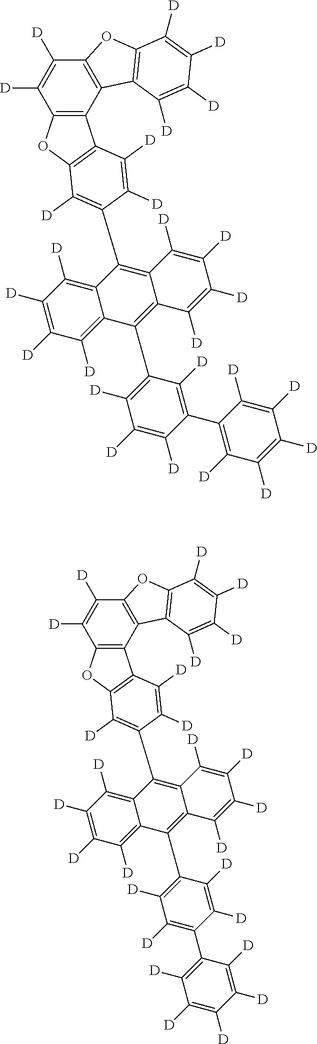 [SMILES: [2H]c1c([2H])c([2H])c(-c2c([2H])c([2H])c([2H])c(-c3c4c([2H])c([2H])c([2H])c([2H])c4c(-c4c([2H])c([2H])c5c(oc6c([2H])c([2H])c7oc8c([2H])c([2H])c([2H])c([2H])c8c7c65)c4[2H])c4c([2H])c([2H])c([2H])c([2H])c34)c2[2H])c([2H])c1[2H] ; [2H]c1c([2H])c([2H])c(-c2c([2H])c([2H])c(-c3c4c([2H])c([2H])c([2H])c([2H])c4c(-c4c([2H])c([2H])c5c(oc6c([2H])c([2H])c7oc8c([2H])c([2H])c([2H])c([2H])c8c7c65)c4[2H])c4c([2H])c([2H])c([2H])c([2H])c34)c([2H])c2[2H])c([2H])c1[2H]]

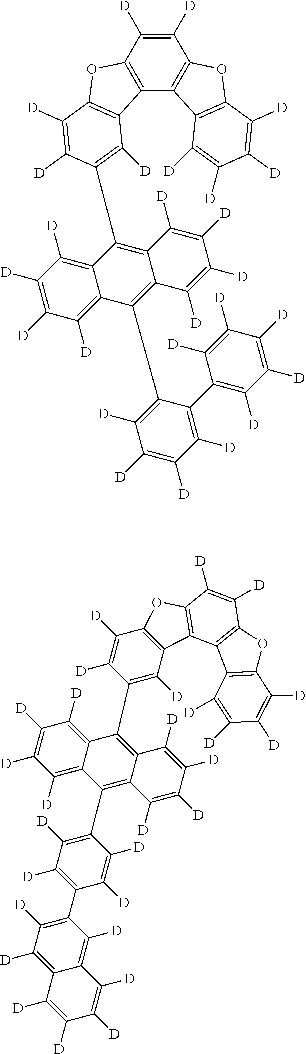 [SMILES: [2H]c1c([2H])c([2H])c(-c2c([2H])c([2H])c([2H])c([2H])c2-c2c3c([2H])c([2H])c([2H])c([2H])c3c(-c3c([2H])c([2H])c4oc5c([2H])c([2H])c6oc7c([2H])c([2H])c([2H])c([2H])c7c6c5c4c3[2H])c3c([2H])c([2H])c([2H])c([2H])c23)c([2H])c1[2H] ; [2H]c1c([2H])c(-c2c3c([2H])c([2H])c([2H])c([2H])c3c(-c3c([2H])c([2H])c4oc5c([2H])c([2H])c6oc7c([2H])c([2H])c([2H])c([2H])c7c6c5c4c3[2H])c3c([2H])c([2H])c([2H])c([2H])c23)c([2H])c([2H])c1-c1c([2H])c([2H])c2c([2H])c([2H])c([2H])c([2H])c2c1[2H]]

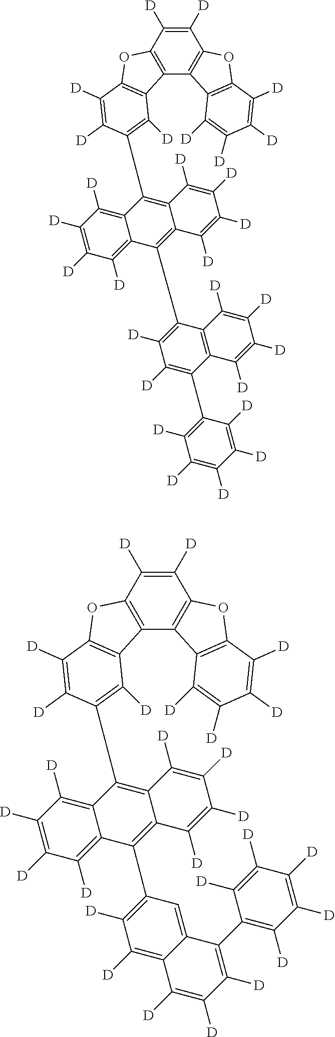 [SMILES: [2H]c1c([2H])c([2H])c(-c2c([2H])c([2H])c(-c3c4c([2H])c([2H])c([2H])c([2H])c4c(-c4c([2H])c([2H])c5oc6c([2H])c([2H])c7oc8c([2H])c([2H])c([2H])c([2H])c8c7c6c5c4[2H])c4c([2H])c([2H])c([2H])c([2H])c34)c3c([2H])c([2H])c([2H])c([2H])c23)c([2H])c1[2H] ; [2H]c1c([2H])c([2H])c(-c2c([2H])c([2H])c([2H])c3c([2H])c([2H])c(-c4c5c([2H])c([2H])c([2H])c([2H])c5c(-c5c([2H])c([2H])c6oc7c([2H])c([2H])c8oc9c([2H])c([2H])c([2H])c([2H])c9c8c7c6c5[2H])c5c([2H])c([2H])c([2H])c([2H])c45)cc23)c([2H])c1[2H]]

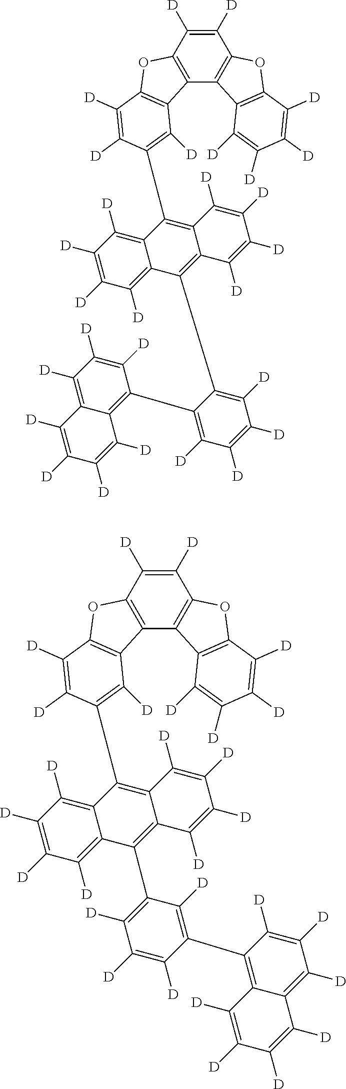 [SMILES: [2H]c1c([2H])c([2H])c(-c2c3c([2H])c([2H])c([2H])c([2H])c3c(-c3c([2H])c([2H])c4oc5c([2H])c([2H])c6oc7c([2H])c([2H])c([2H])c([2H])c7c6c5c4c3[2H])c3c([2H])c([2H])c([2H])c([2H])c23)c(-c2c([2H])c([2H])c([2H])c3c([2H])c([2H])c([2H])c([2H])c23)c1[2H] ; [2H]c1c([2H])c(-c2c([2H])c([2H])c([2H])c3c([2H])c([2H])c([2H])c([2H])c23)c([2H])c(-c2c3c([2H])c([2H])c([2H])c([2H])c3c(-c3c([2H])c([2H])c4oc5c([2H])c([2H])c6oc7c([2H])c([2H])c([2H])c([2H])c7c6c5c4c3[2H])c3c([2H])c([2H])c([2H])c([2H])c23)c1[2H]]

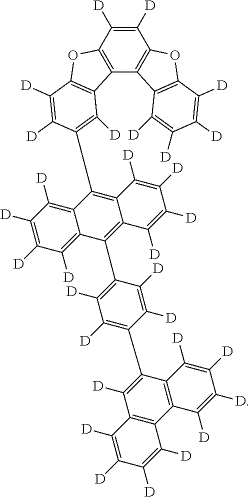

13. The organic light emitting device of claim 1, wherein the compound of Chemical Formula 2 is any one of the following compounds:

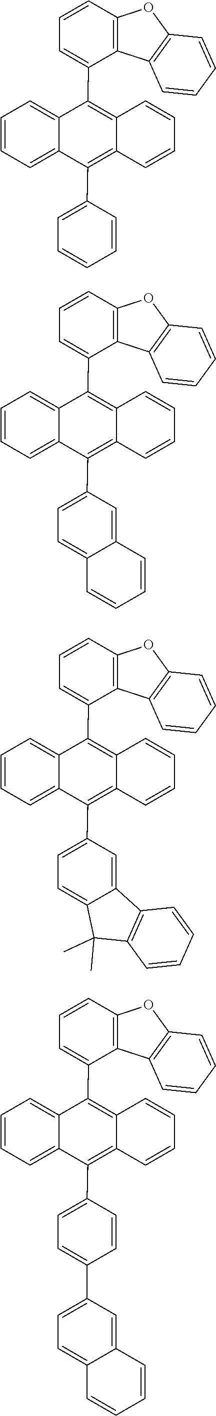

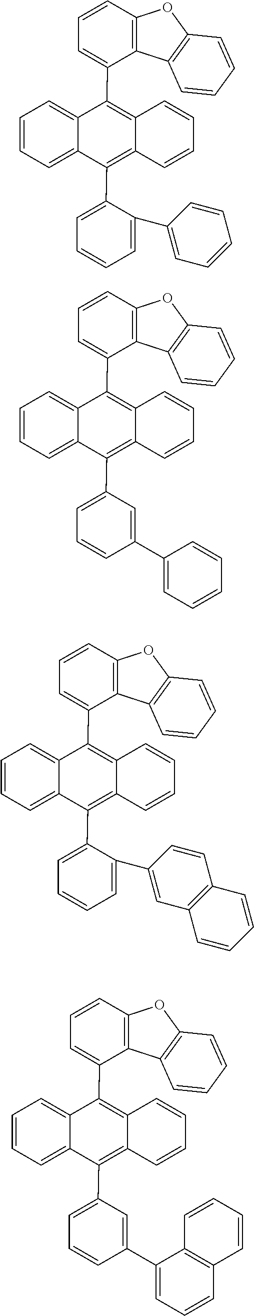

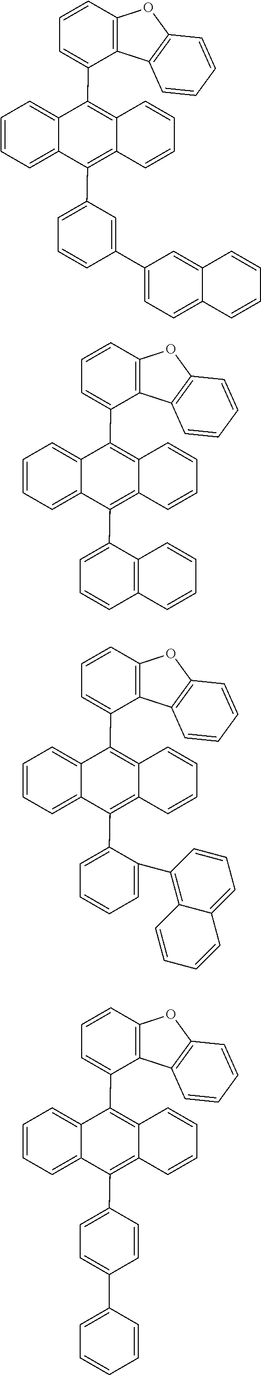

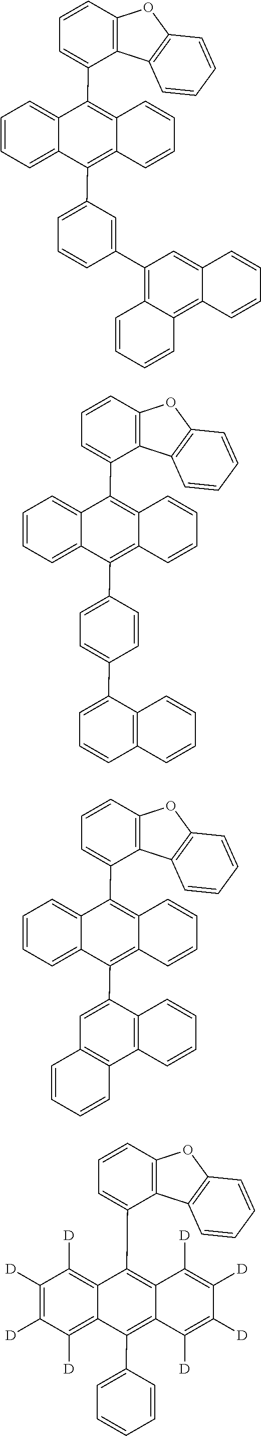

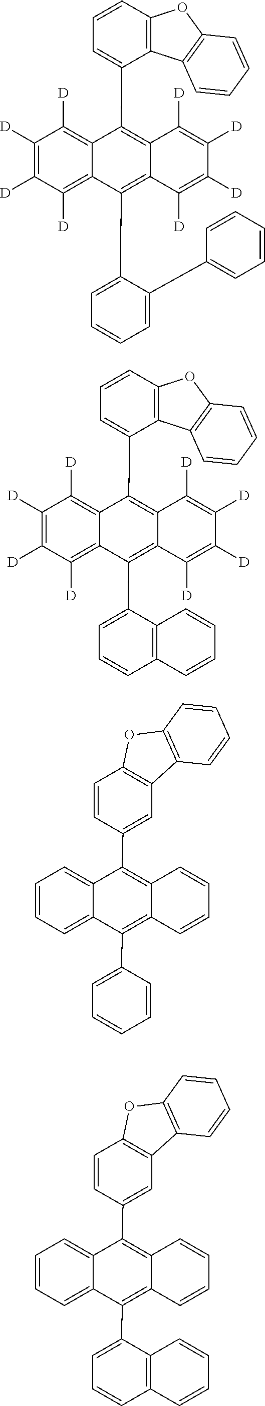

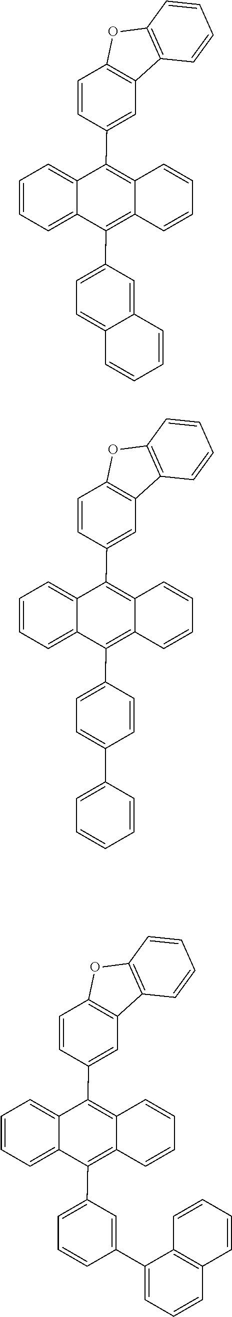 [SMILES: c1ccc2cc(-c3c4ccccc4c(-c4ccc5oc6ccccc6c5c4)c4ccccc34)ccc2c1 ; c1ccc(-c2ccc(-c3c4ccccc4c(-c4ccc5oc6ccccc6c5c4)c4ccccc34)cc2)cc1 ; c1cc(-c2cccc3ccccc23)cc(-c2c3ccccc3c(-c3ccc4oc5ccccc5c4c3)c3ccccc23)c1]

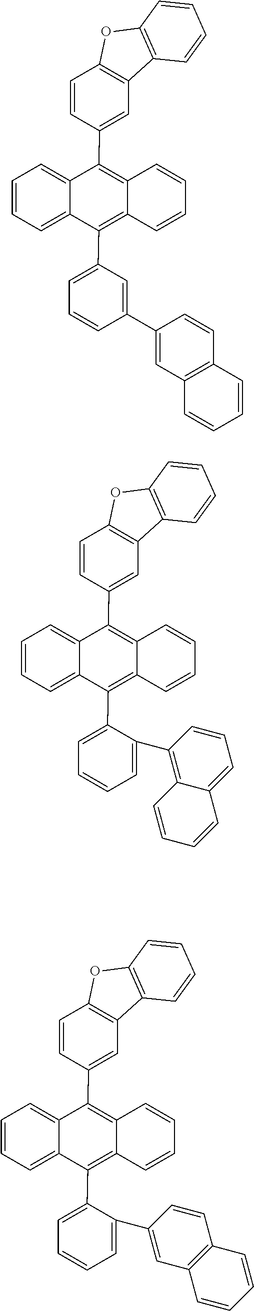

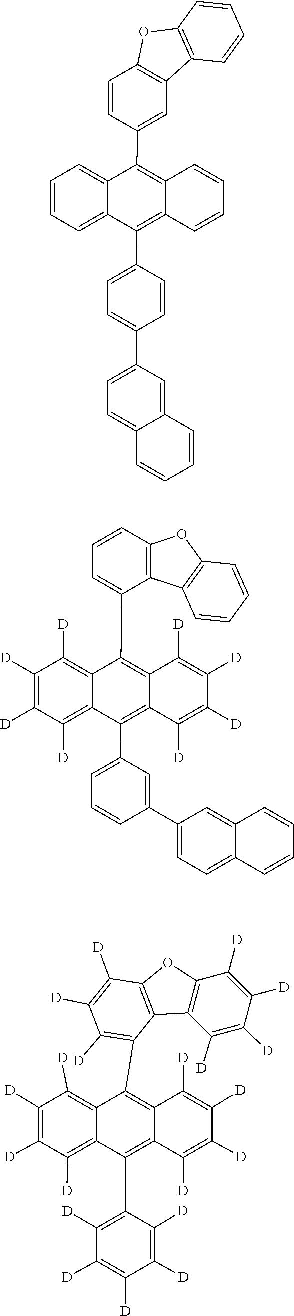 [SMILES: c1ccc2cc(-c3ccc(-c4c5ccccc5c(-c5ccc6oc7ccccc7c6c5)c5ccccc45)cc3)ccc2c1 ; [2H]c1c([2H])c([2H])c2c(-c3cccc4oc5ccccc5c34)c3c([2H])c([2H])c([2H])c([2H])c3c(-c3cccc(-c4ccc5ccccc5c4)c3)c2c1[2H] ; [2H]c1c([2H])c([2H])c(-c2c3c([2H])c([2H])c([2H])c([2H])c3c(-c3c([2H])c([2H])c([2H])c4oc5c([2H])c([2H])c([2H])c([2H])c5c34)c3c([2H])c([2H])c([2H])c([2H])c23)c([2H])c1[2H]]

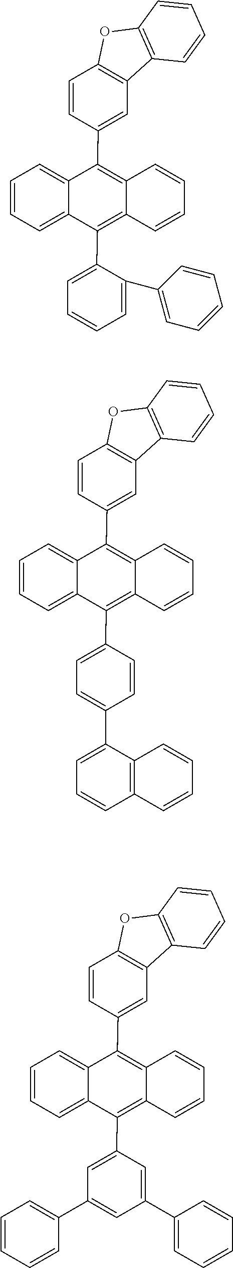 [SMILES: c1ccc(-c2ccccc2-c2c3ccccc3c(-c3ccc4oc5ccccc5c4c3)c3ccccc23)cc1 ; c1ccc2c(-c3ccc(-c4c5ccccc5c(-c5ccc6oc7ccccc7c6c5)c5ccccc45)cc3)cccc2c1 ; c1ccc(-c2cc(-c3ccccc3)cc(-c3c4ccccc4c(-c4ccc5oc6ccccc6c5c4)c4ccccc34)c2)cc1]

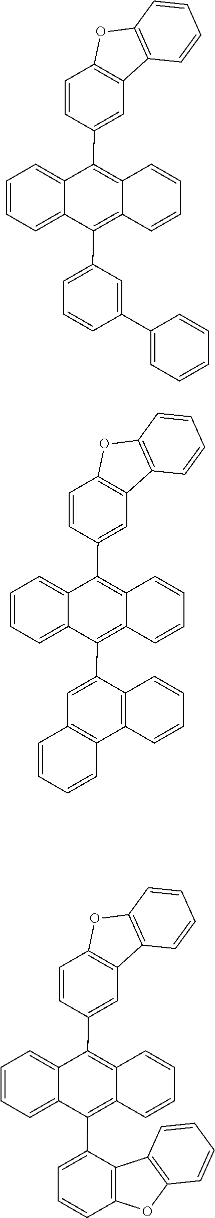

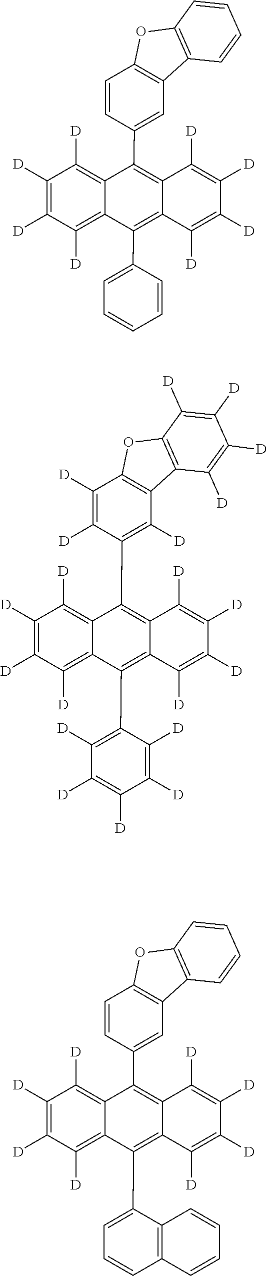 [SMILES: [2H]c1c([2H])c([2H])c2c(-c3ccc4oc5ccccc5c4c3)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H] ; [2H]c1c([2H])c([2H])c2c(-c3cccc4ccccc34)c3c([2H])c([2H])c([2H])c([2H])c3c(-c3ccc4oc5ccccc5c4c3)c2c1[2H]]

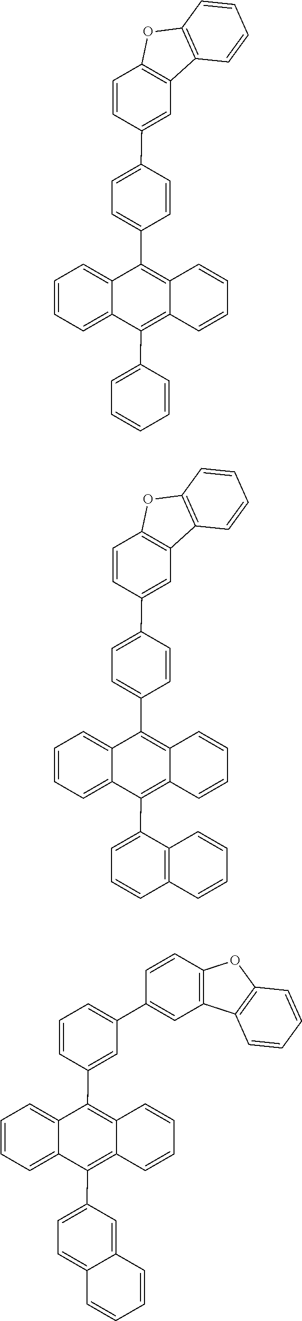 [SMILES: c1ccc(-c2c3ccccc3c(-c3ccc(-c4ccc5oc6ccccc6c5c4)cc3)c3ccccc23)cc1 ; c1ccc2c(-c3c4ccccc4c(-c4ccc(-c5ccc6oc7ccccc7c6c5)cc4)c4ccccc34)cccc2c1 ; c1cc(-c2ccc3oc4ccccc4c3c2)cc(-c2c3ccccc3c(-c3ccc4ccccc4c3)c3ccccc23)c1]

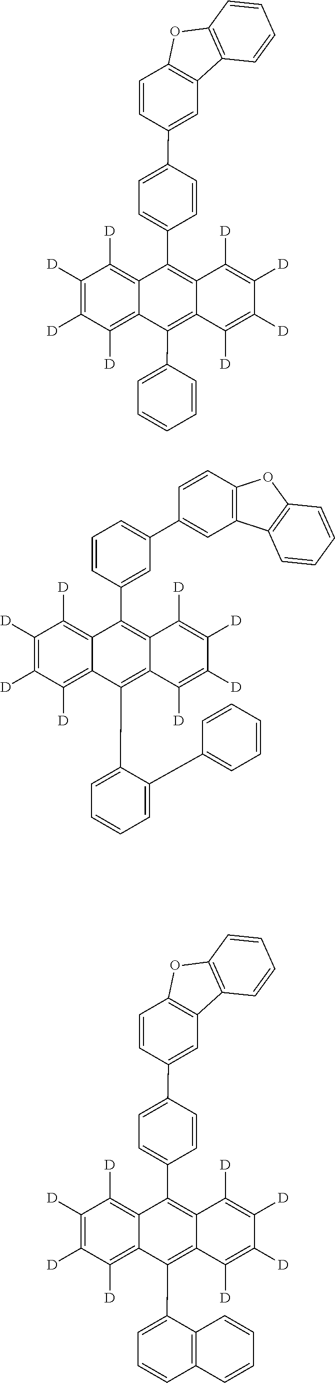 [SMILES: [2H]c1c([2H])c([2H])c2c(-c3ccc(-c4ccc5oc6ccccc6c5c4)cc3)c3c([2H])c([2H])c([2H])c([2H])c3c(-c3ccccc3)c2c1[2H] ; [2H]c1c([2H])c([2H])c2c(-c3ccccc3-c3ccccc3)c3c([2H])c([2H])c([2H])c([2H])c3c(-c3cccc(-c4ccc5oc6ccccc6c5c4)c3)c2c1[2H] ; [2H]c1c([2H])c([2H])c2c(-c3cccc4ccccc34)c3c([2H])c([2H])c([2H])c([2H])c3c(-c3ccc(-c4ccc5oc6ccccc6c5c4)cc3)c2c1[2H]]

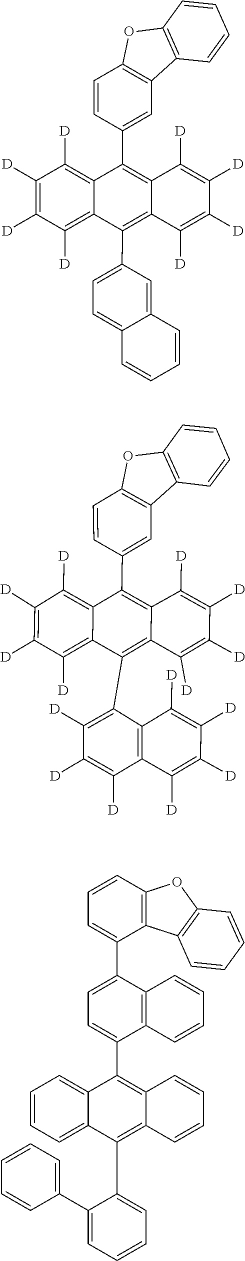 [SMILES: [2H]c1c([2H])c([2H])c2c(-c3ccc4oc5ccccc5c4c3)c3c([2H])c([2H])c([2H])c([2H])c3c(-c3ccc4ccccc4c3)c2c1[2H] ; [2H]c1c([2H])c([2H])c2c(-c3c4c([2H])c([2H])c([2H])c([2H])c4c(-c4ccc5oc6ccccc6c5c4)c4c([2H])c([2H])c([2H])c([2H])c34)c([2H])c([2H])c([2H])c2c1[2H] ; c1ccc(-c2ccccc2-c2c3ccccc3c(-c3ccc(-c4cccc5oc6ccccc6c45)c4ccccc34)c3ccccc23)cc1]

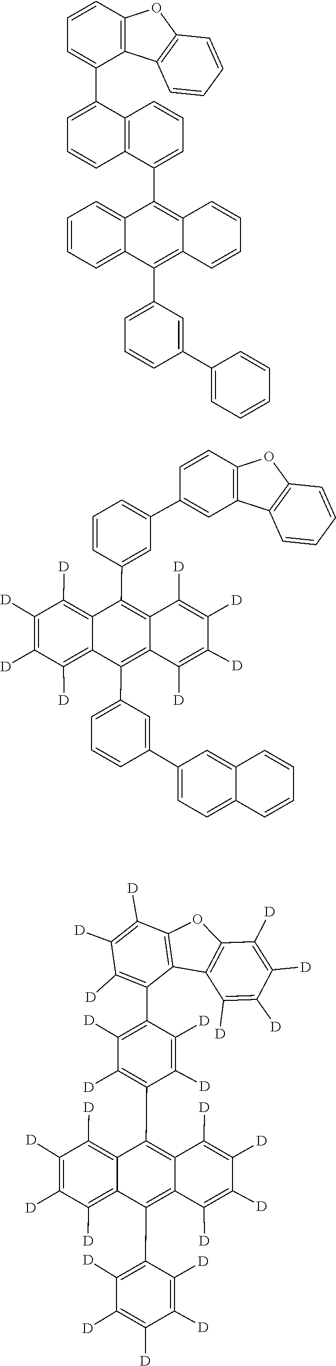

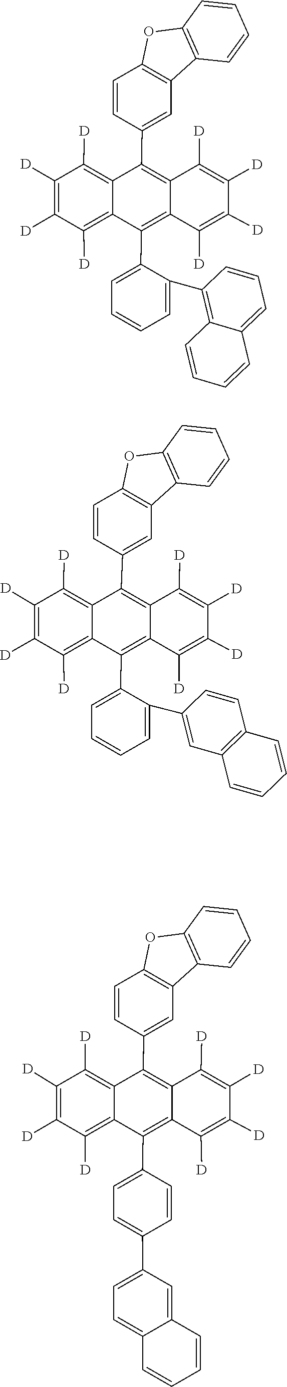

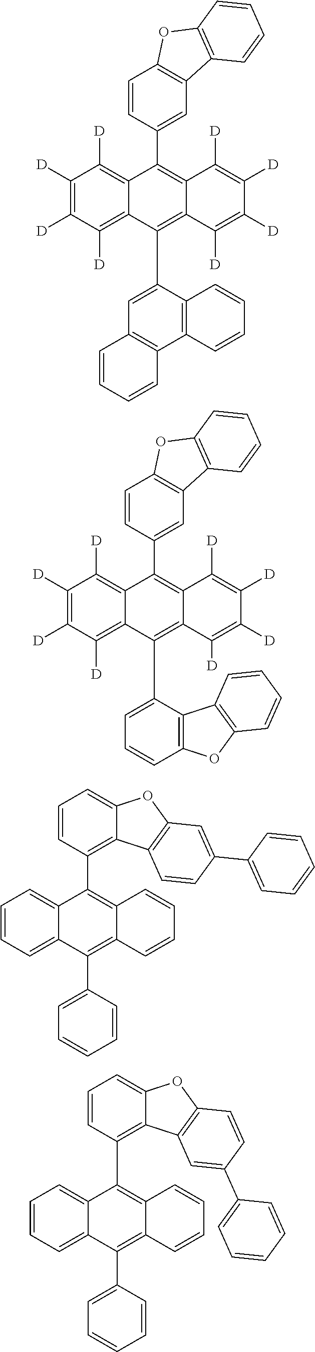

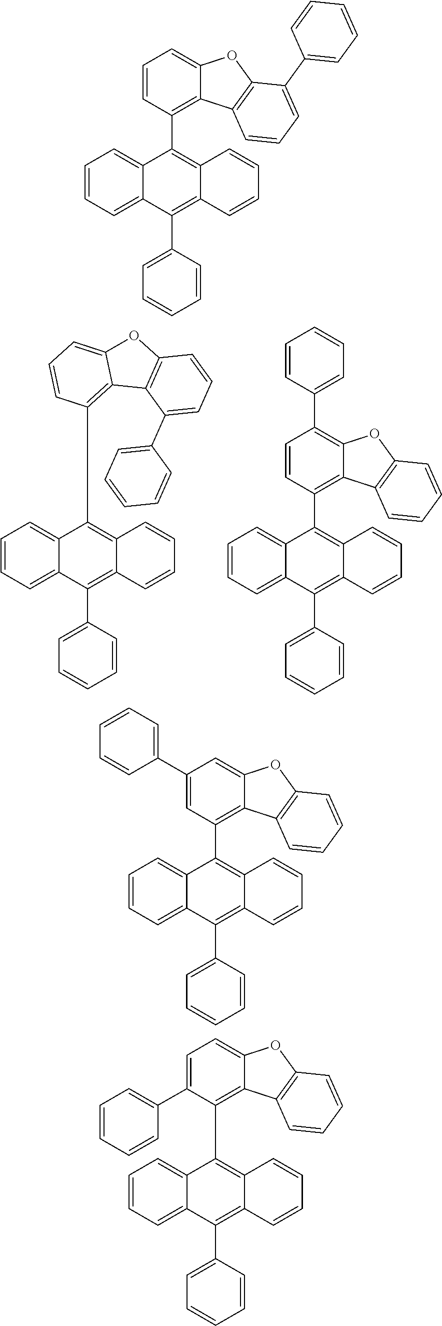

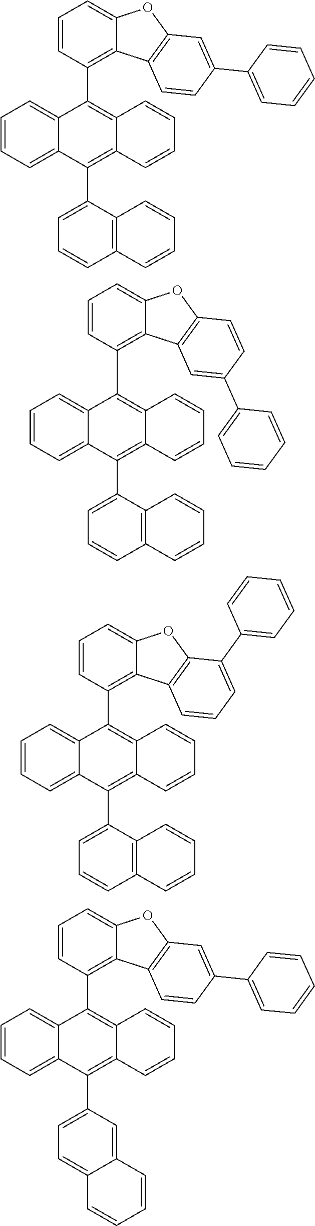

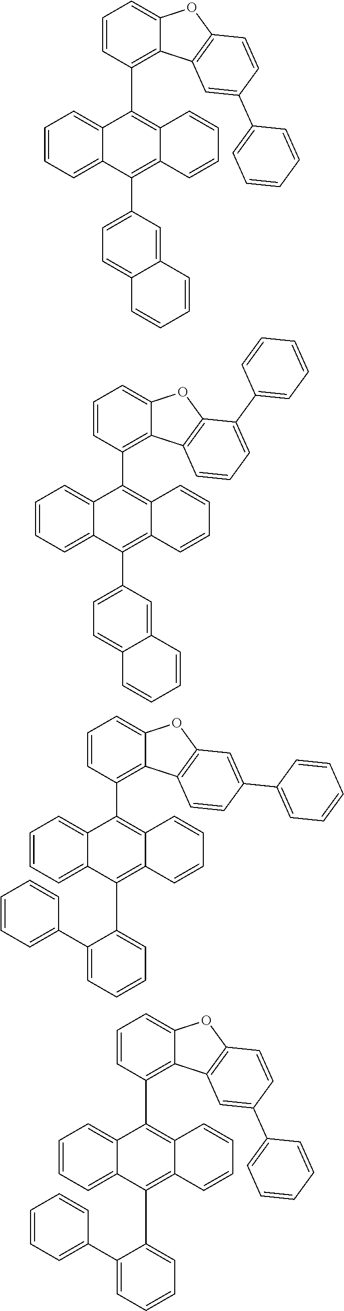

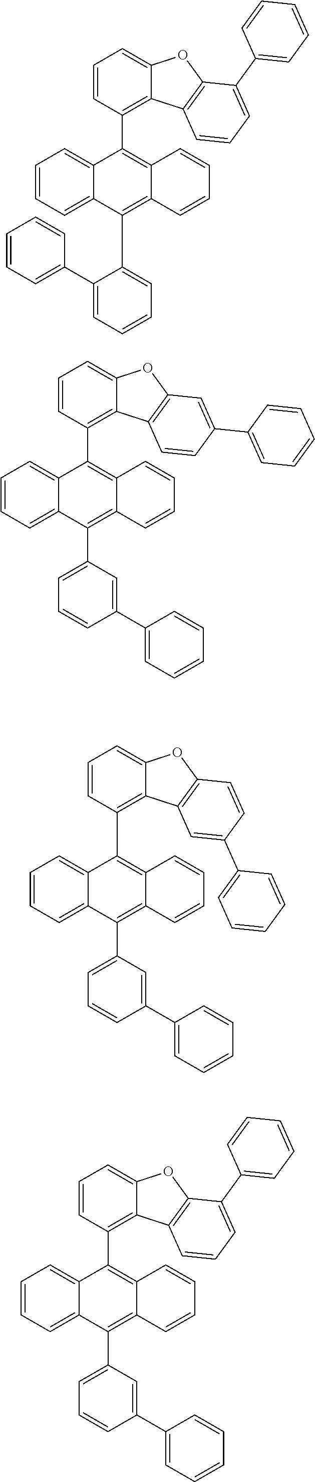

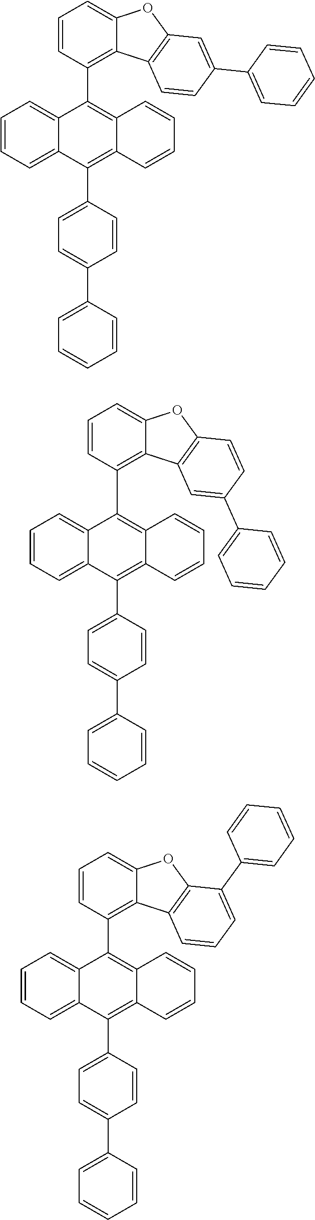

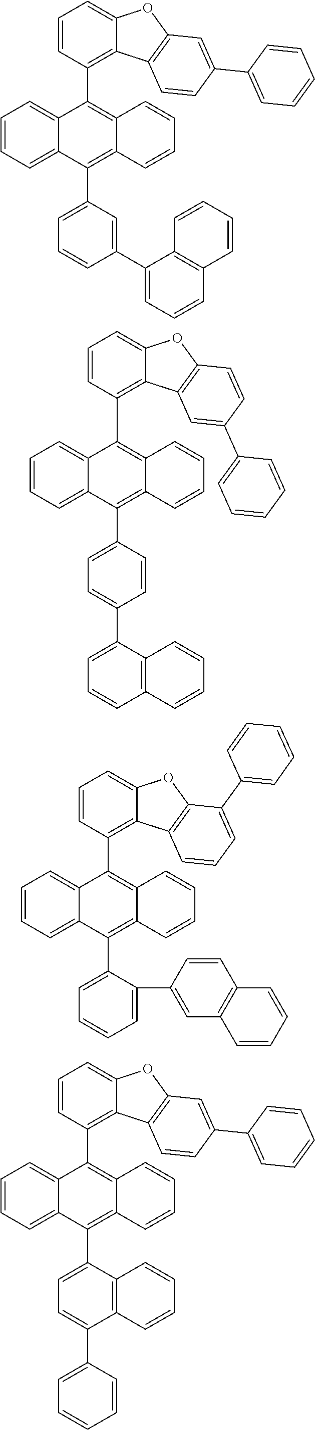

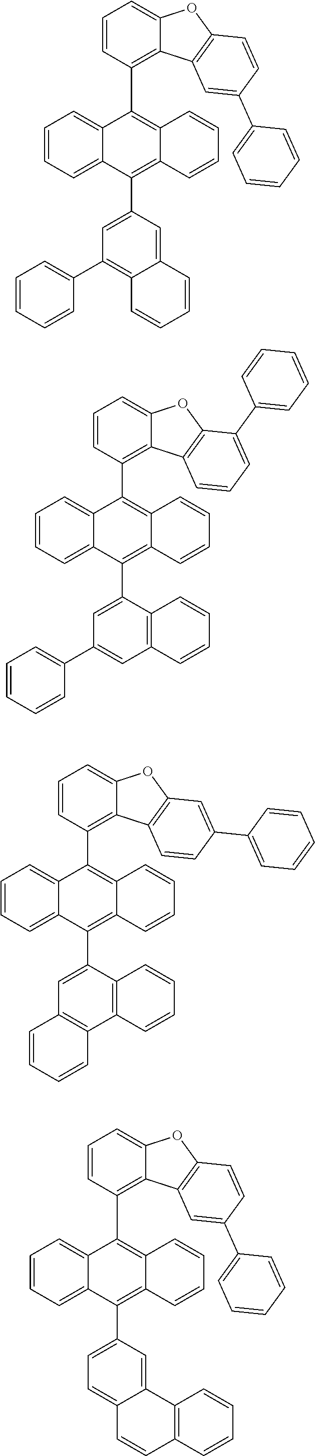 [SMILES: c1ccc(-c2ccc3oc4cccc(-c5c6ccccc6c(-c6cc(-c7ccccc7)c7ccccc7c6)c6ccccc56)c4c3c2)cc1 ; c1ccc(-c2cc(-c3c4ccccc4c(-c4cccc5oc6c(-c7ccccc7)cccc6c45)c4ccccc34)c3ccccc3c2)cc1 ; c1ccc(-c2ccc3c(c2)oc2cccc(-c4c5ccccc5c(-c5cc6ccccc6c6ccccc56)c5ccccc45)c23)cc1 ; c1ccc(-c2ccc3oc4cccc(-c5c6ccccc6c(-c6ccc7ccc8ccccc8c7c6)c6ccccc56)c4c3c2)cc1]

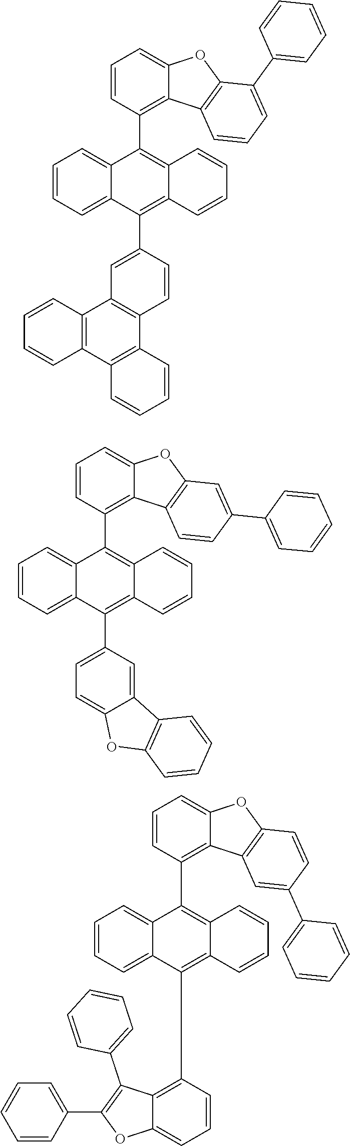

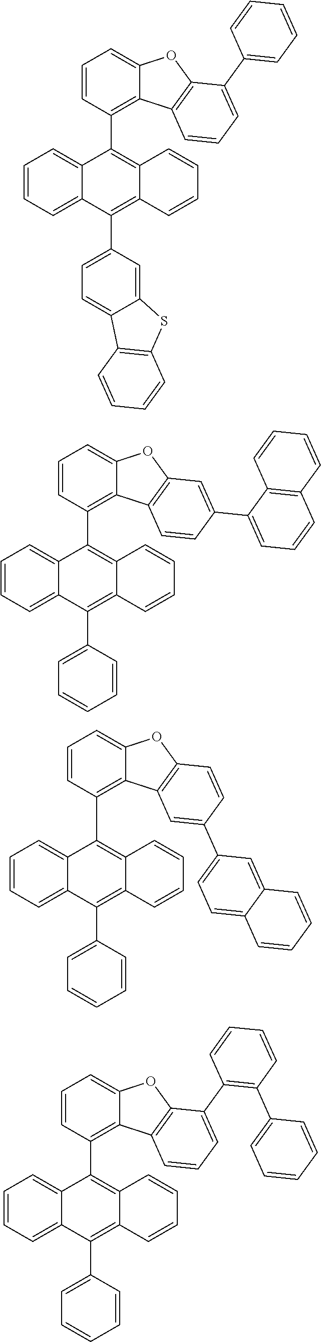

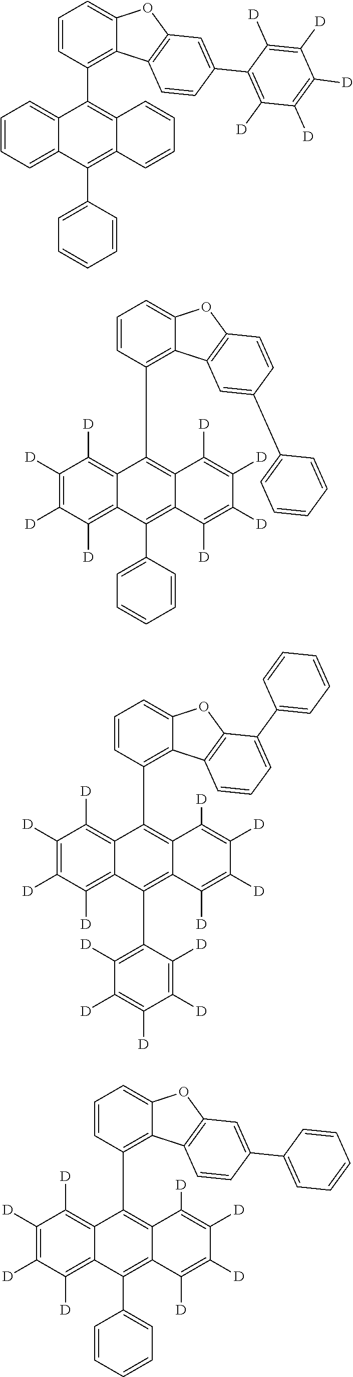

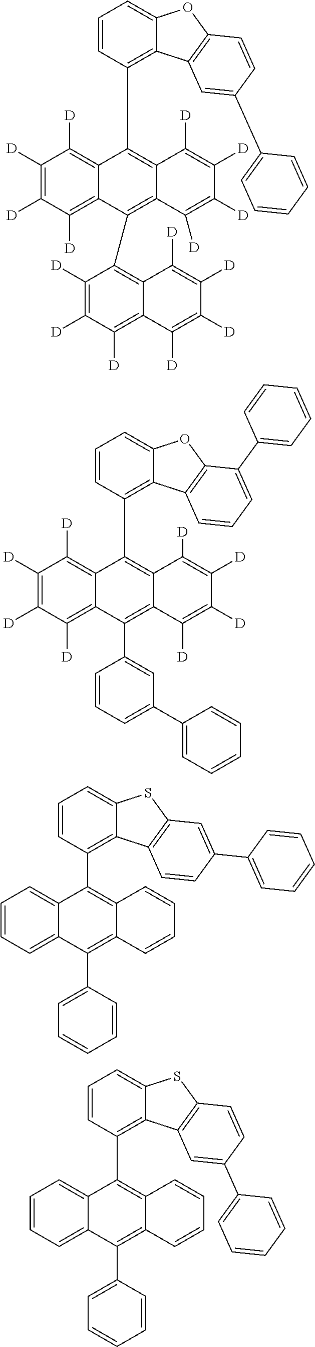

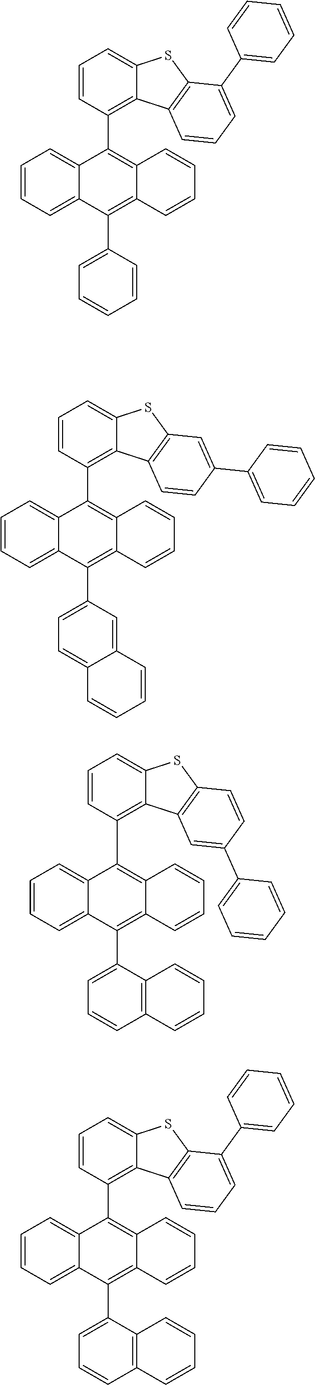

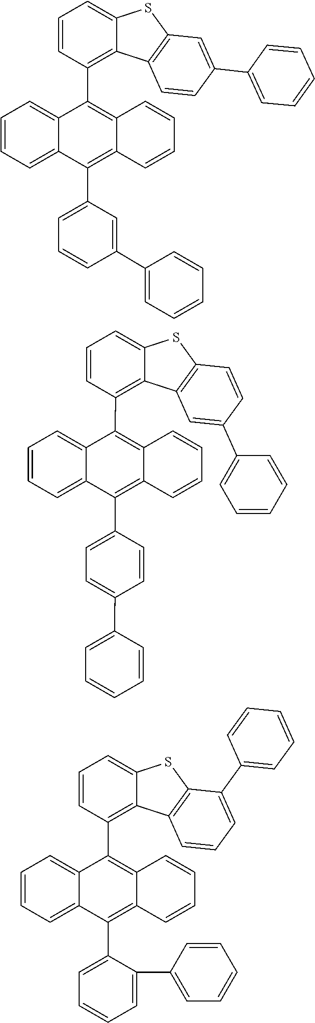

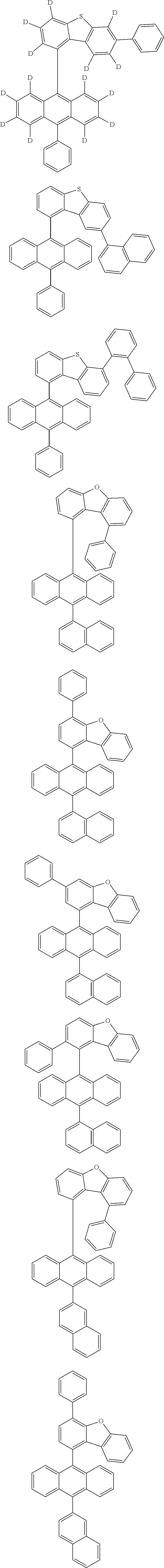

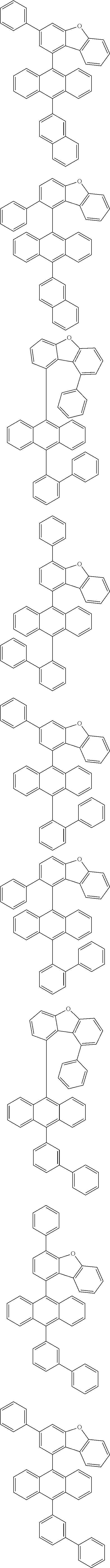

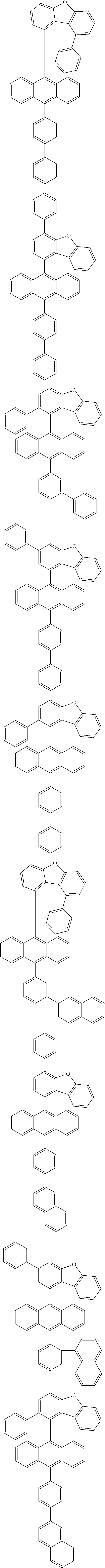

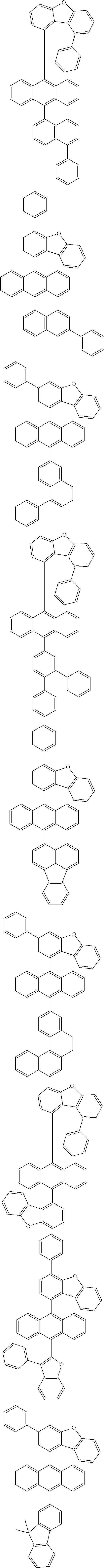

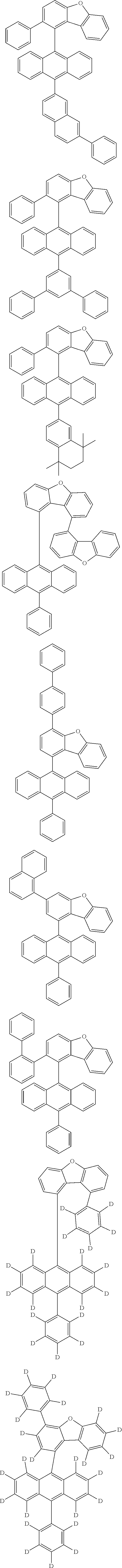

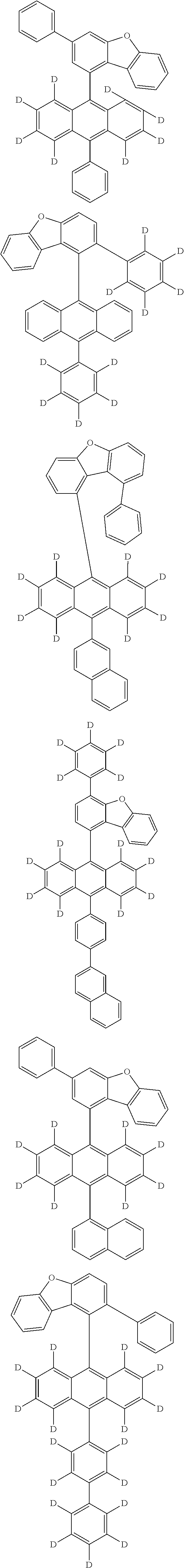

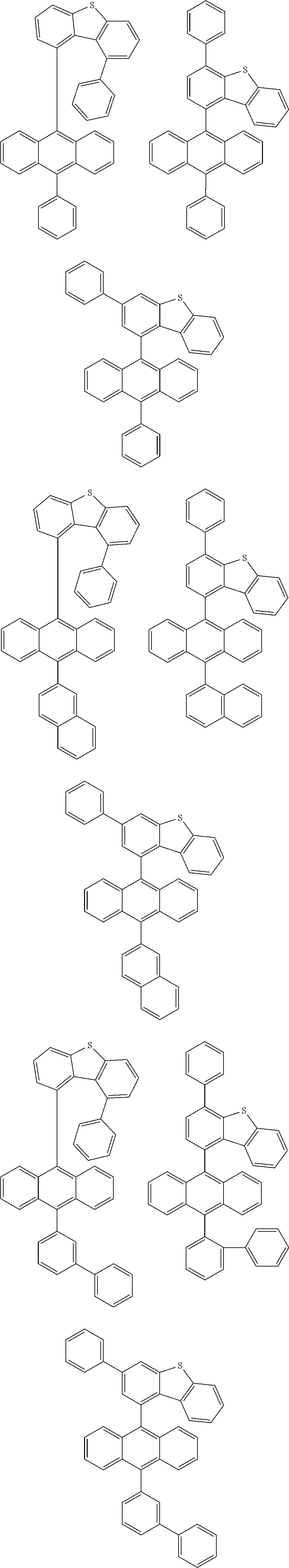

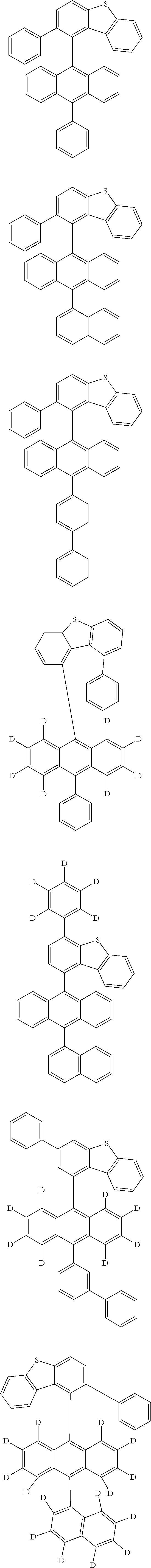

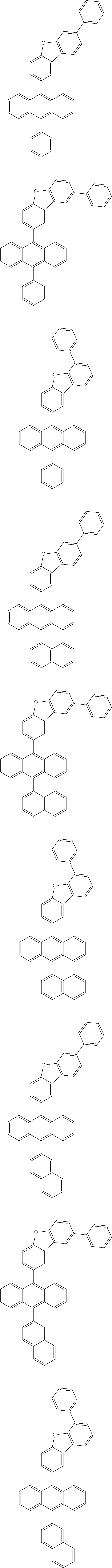

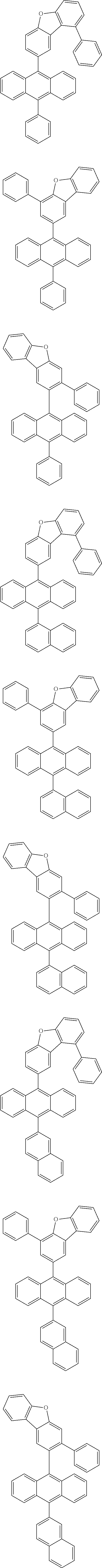

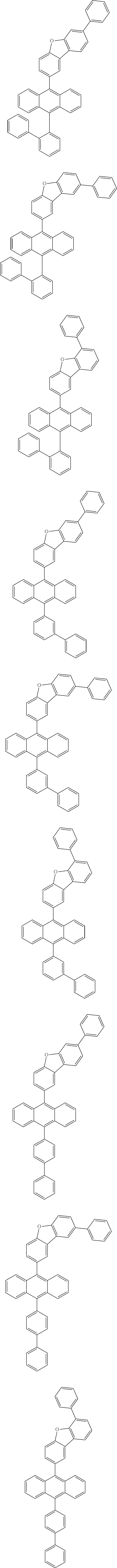

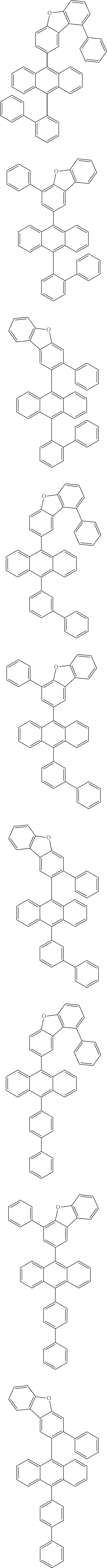

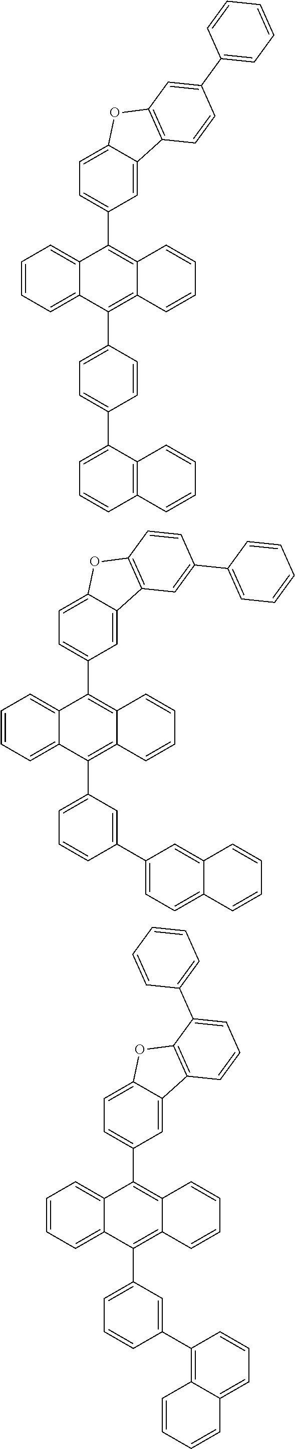

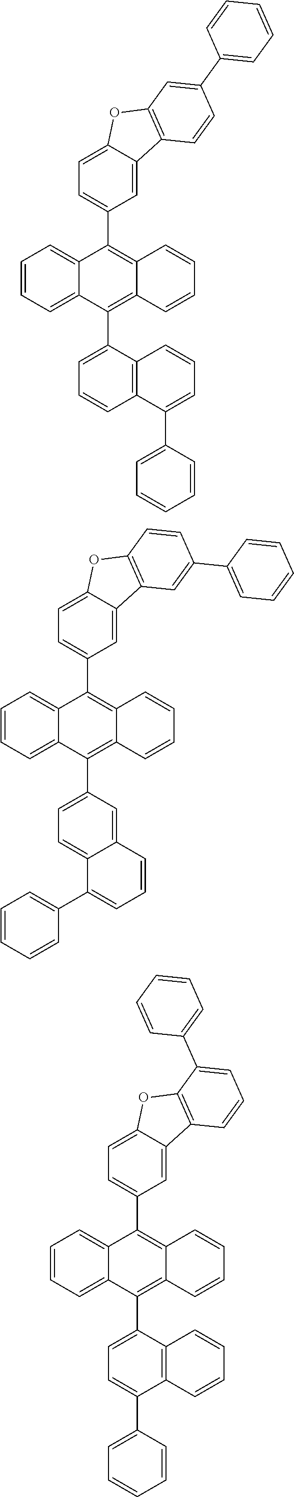

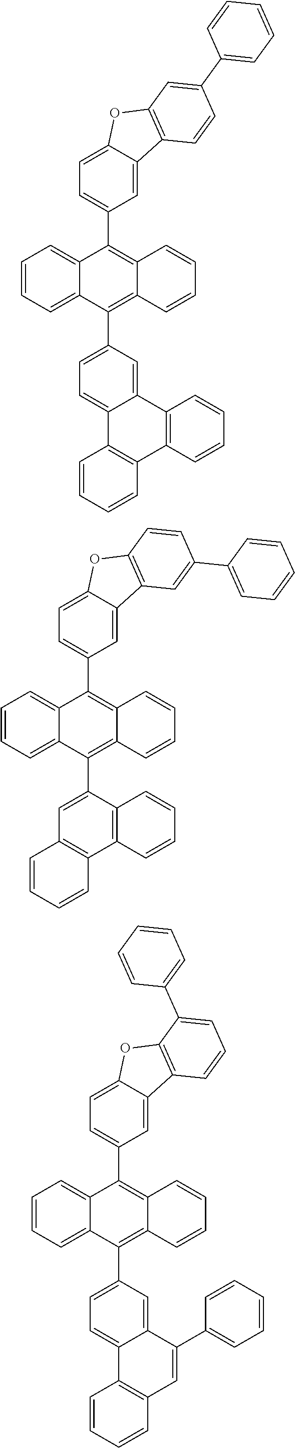

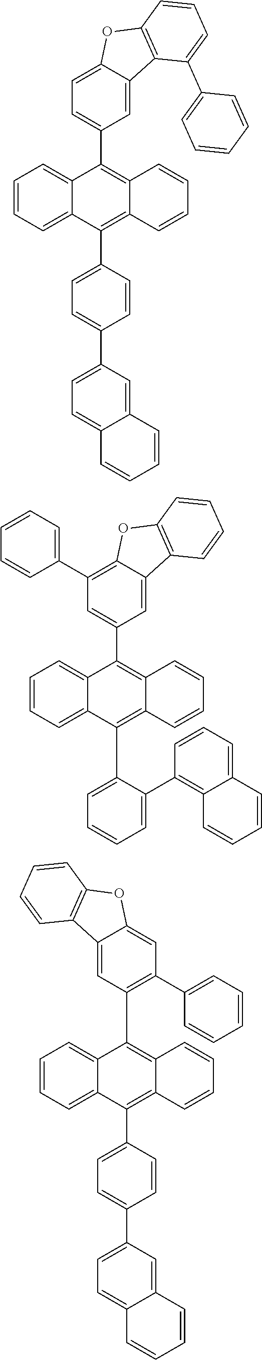

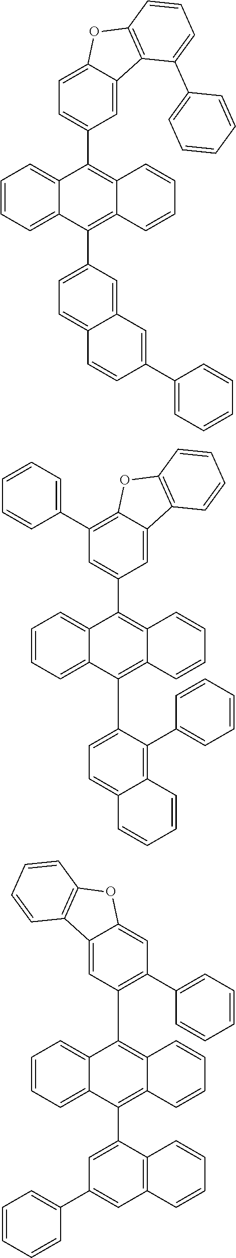

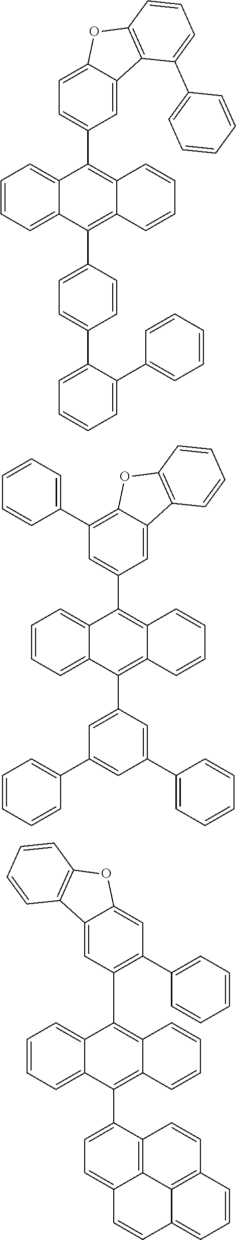

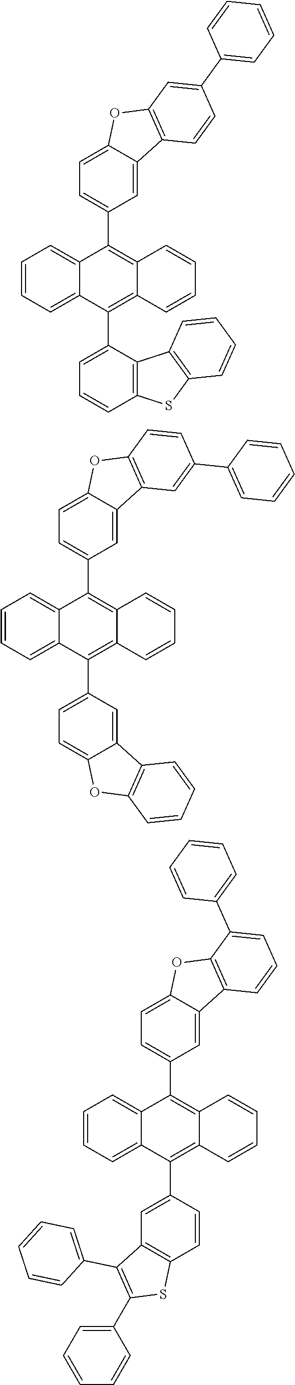

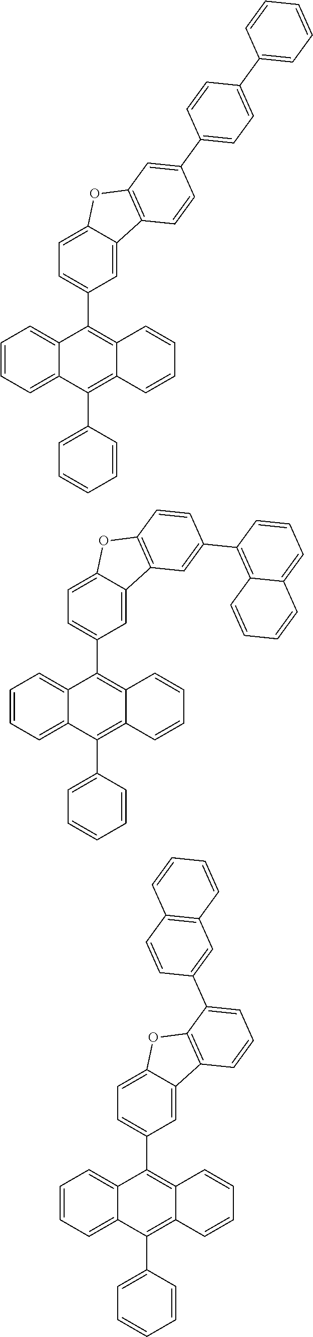 [SMILES: c1ccc(-c2ccc(-c3ccc4c(c3)oc3ccc(-c5c6ccccc6c(-c6ccccc6)c6ccccc56)cc34)cc2)cc1 ; c1ccc(-c2c3ccccc3c(-c3ccc4oc5ccc(-c6cccc7ccccc67)cc5c4c3)c3ccccc23)cc1 ; c1ccc(-c2c3ccccc3c(-c3ccc4oc5c(-c6ccc7ccccc7c6)cccc5c4c3)c3ccccc23)cc1]

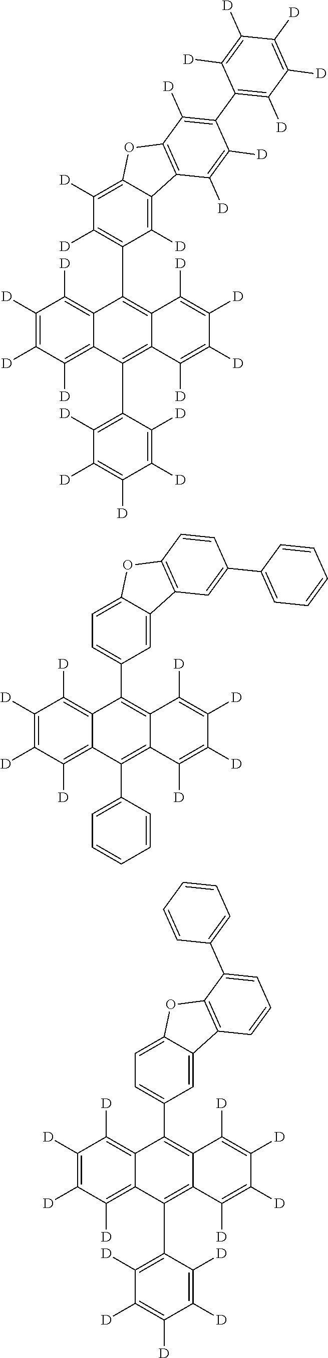 [SMILES: [2H]c1c([2H])c([2H])c(-c2c([2H])c([2H])c3c(oc4c([2H])c([2H])c(-c5c6c([2H])c([2H])c([2H])c([2H])c6c(-c6c([2H])c([2H])c([2H])c([2H])c6[2H])c6c([2H])c([2H])c([2H])c([2H])c56)c([2H])c43)c2[2H])c([2H])c1[2H] ; [2H]c1c([2H])c([2H])c2c(-c3ccc4oc5ccc(-c6ccccc6)cc5c4c3)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3ccc4oc5c(-c6ccccc6)cccc5c4c3)c3c([2H])c([2H])c([2H])c([2H])c23)c([2H])c1[2H]]

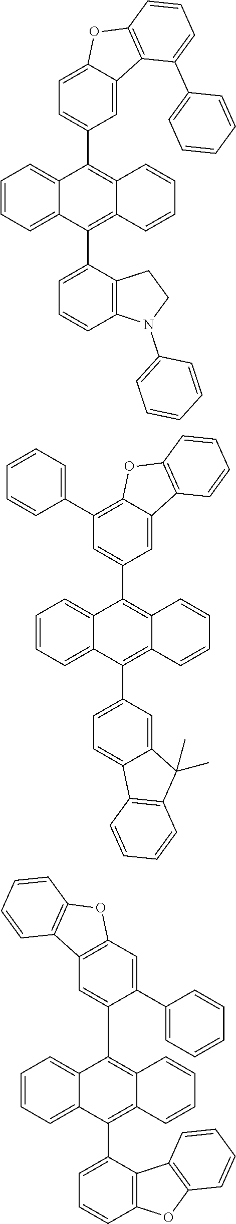

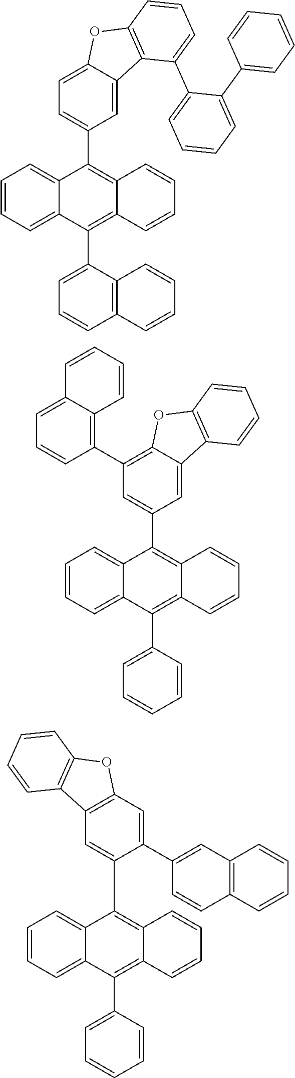

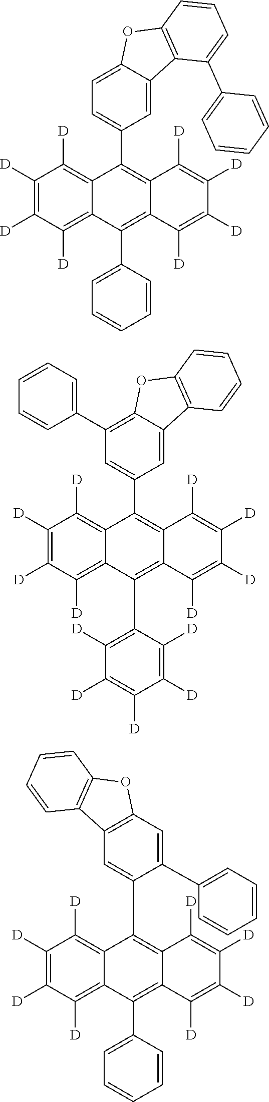 [SMILES: [2H]c1c([2H])c([2H])c2c(-c3ccc4oc5cccc(-c6ccccc6)c5c4c3)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3cc(-c4ccccc4)c4oc5ccccc5c4c3)c3c([2H])c([2H])c([2H])c([2H])c23)c([2H])c1[2H] ; [2H]c1c([2H])c([2H])c2c(-c3cc4c(cc3-c3ccccc3)oc3ccccc34)c3c([2H])c([2H])c([2H])c([2H])c3c(-c3ccccc3)c2c1[2H]]

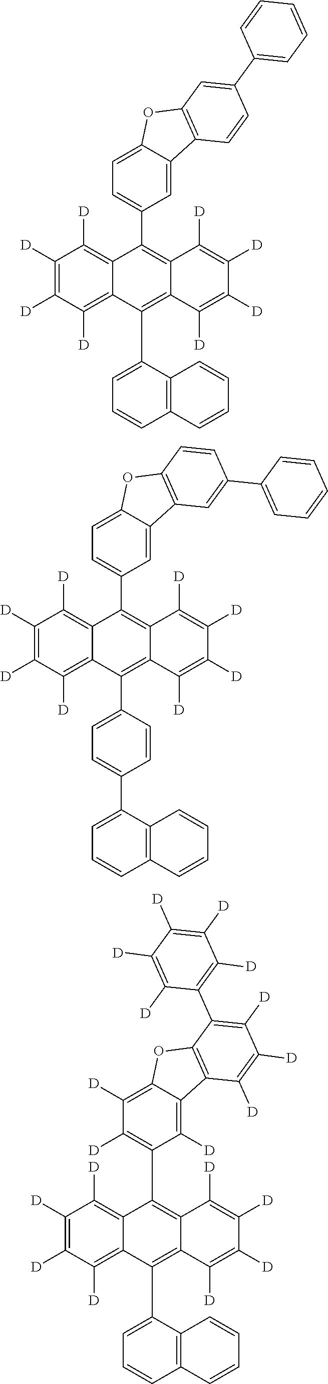

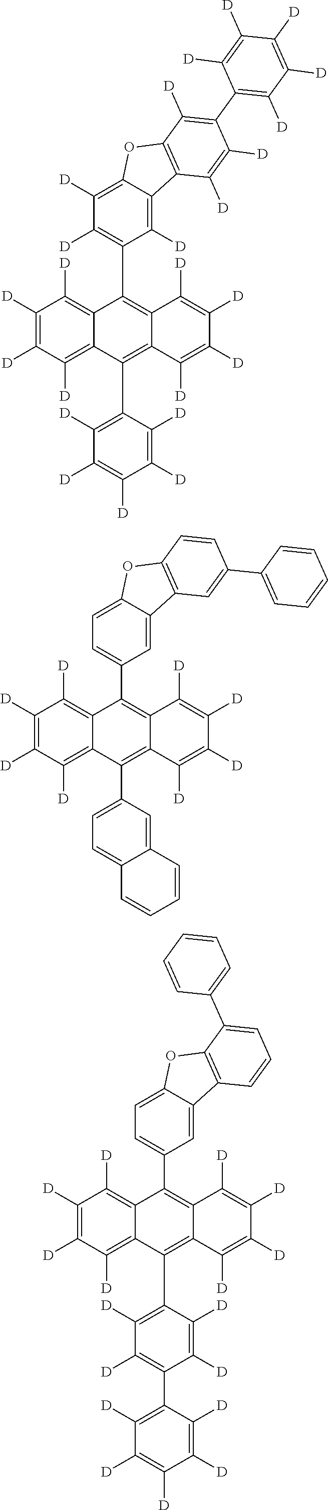

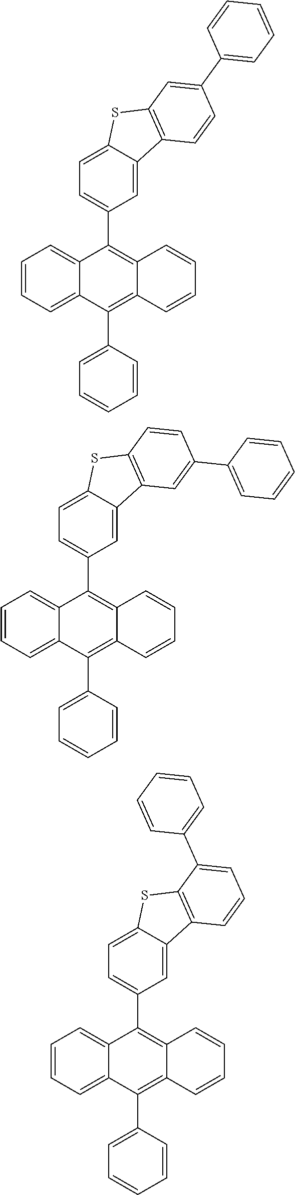

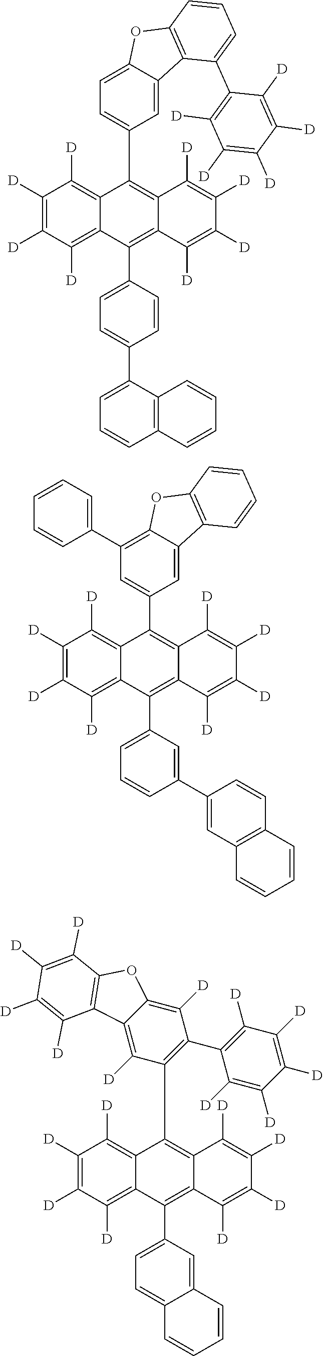

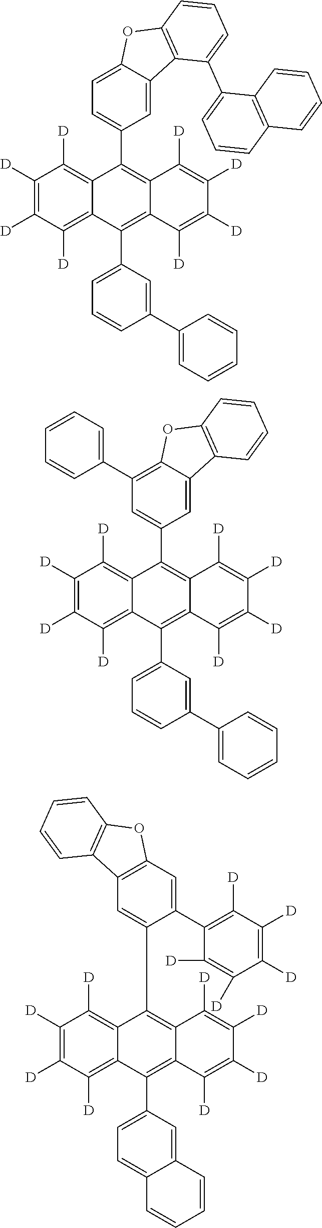

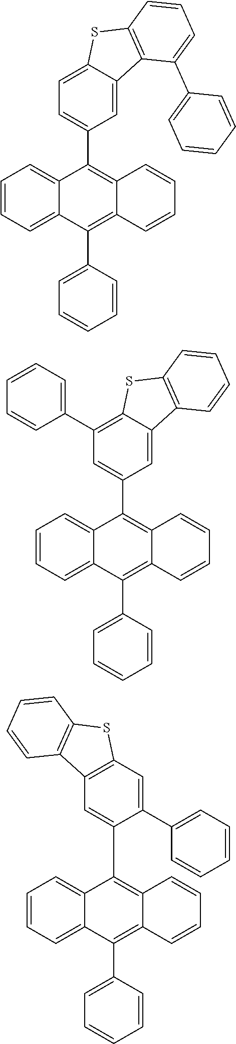 [SMILES: c1ccc(-c2c3ccccc3c(-c3ccc4sc5cccc(-c6ccccc6)c5c4c3)c3ccccc23)cc1 ; c1ccc(-c2c3ccccc3c(-c3cc(-c4ccccc4)c4sc5ccccc5c4c3)c3ccccc23)cc1 ; c1ccc(-c2cc3sc4ccccc4c3cc2-c2c3ccccc3c(-c3ccccc3)c3ccccc23)cc1]

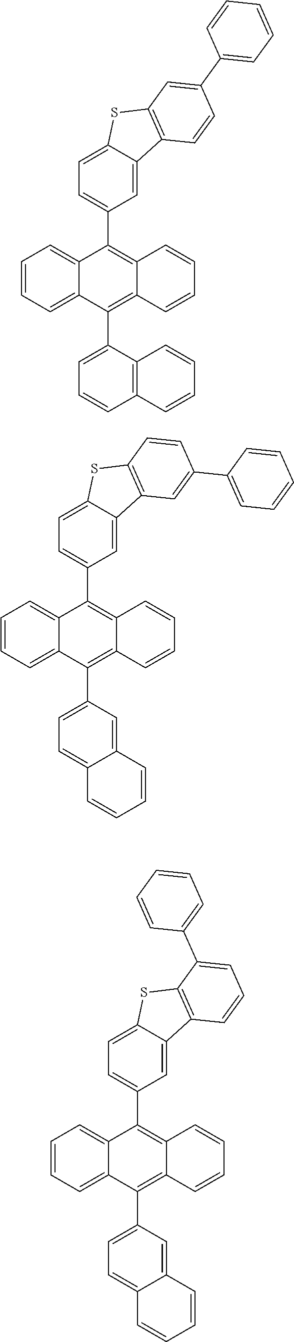

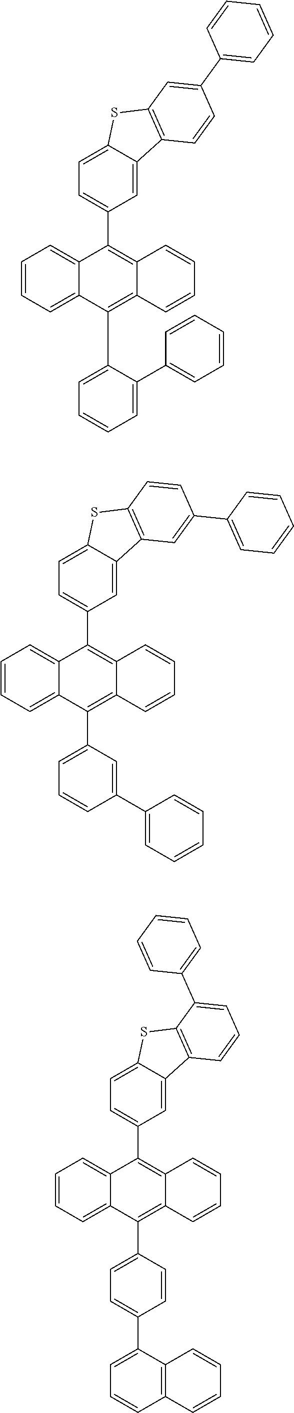 [SMILES: c1ccc(-c2ccc3c(c2)sc2ccc(-c4c5ccccc5c(-c5ccccc5-c5ccccc5)c5ccccc45)cc23)cc1 ; c1ccc(-c2cccc(-c3c4ccccc4c(-c4ccc5sc6ccc(-c7ccccc7)cc6c5c4)c4ccccc34)c2)cc1 ; c1ccc(-c2cccc3c2sc2ccc(-c4c5ccccc5c(-c5ccc(-c6cccc7ccccc67)cc5)c5ccccc45)cc23)cc1]

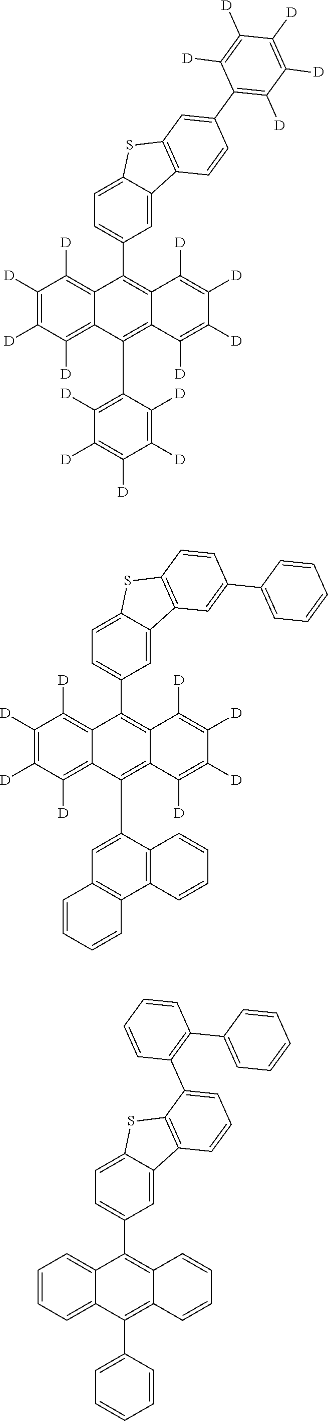 [SMILES: [2H]c1c([2H])c([2H])c(-c2ccc3c(c2)sc2ccc(-c4c5c([2H])c([2H])c([2H])c([2H])c5c(-c5c([2H])c([2H])c([2H])c([2H])c5[2H])c5c([2H])c([2H])c([2H])c([2H])c45)cc23)c([2H])c1[2H] ; [2H]c1c([2H])c([2H])c2c(-c3cc4ccccc4c4ccccc34)c3c([2H])c([2H])c([2H])c([2H])c3c(-c3ccc4sc5ccc(-c6ccccc6)cc5c4c3)c2c1[2H] ; c1ccc(-c2ccccc2-c2cccc3c2sc2ccc(-c4c5ccccc5c(-c5ccccc5)c5ccccc45)cc23)cc1]

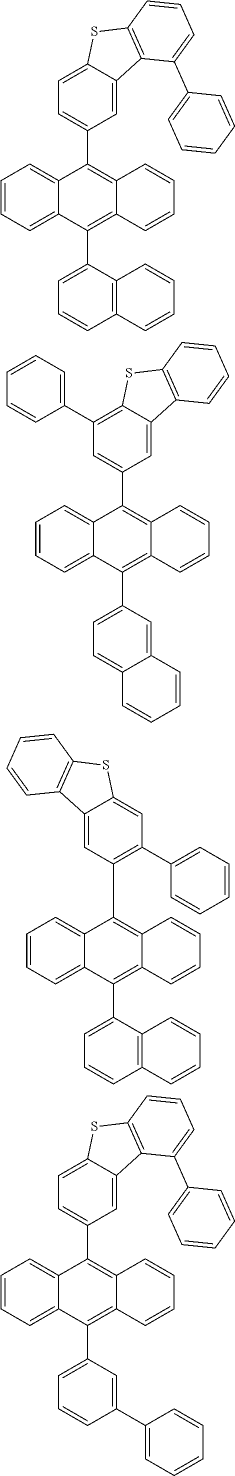

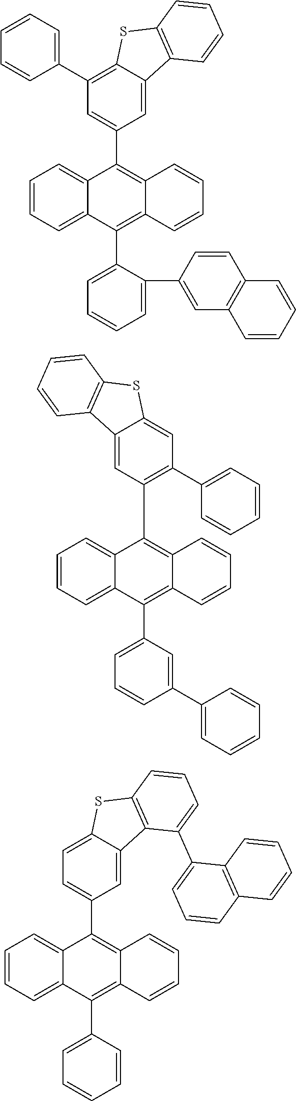

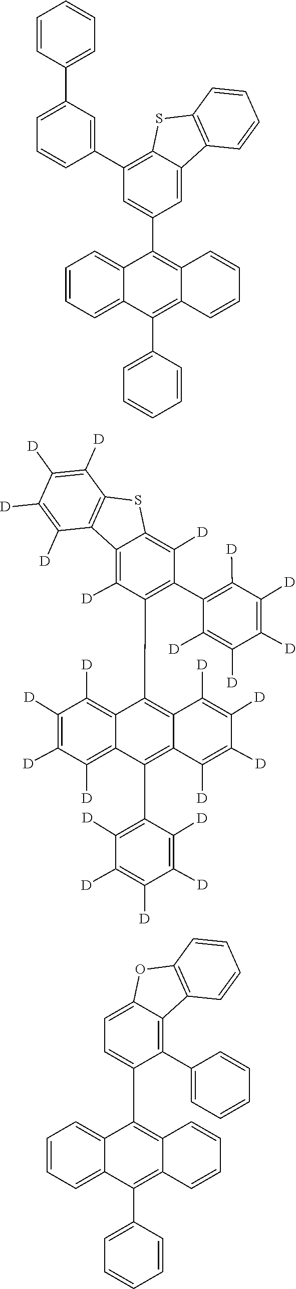

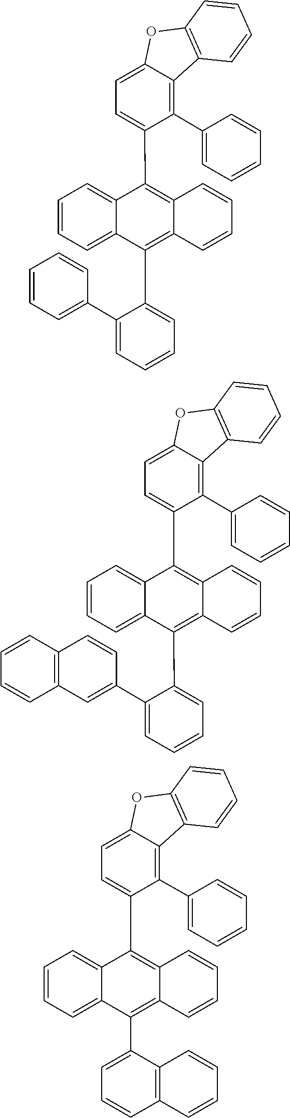

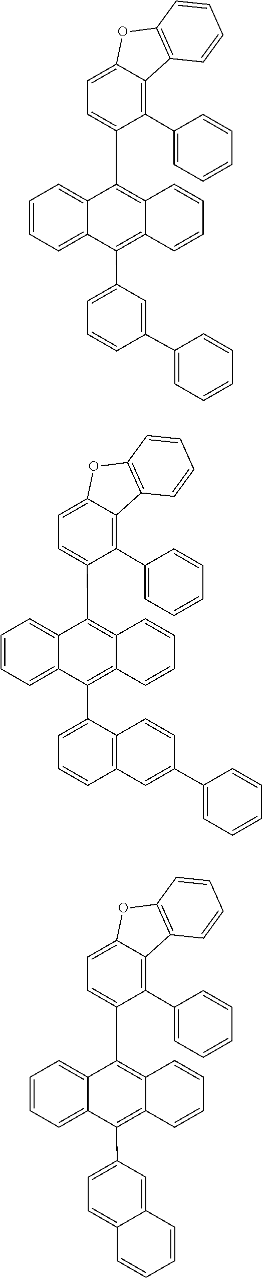

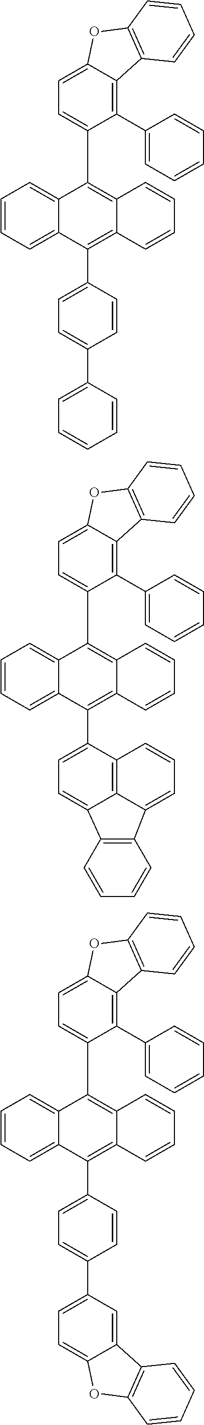

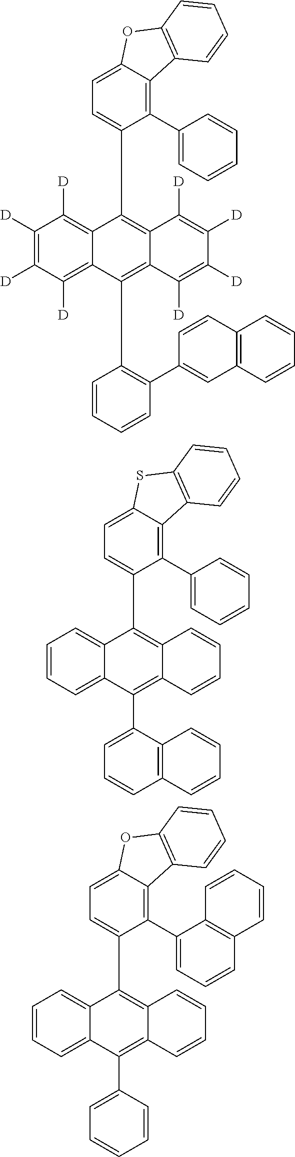

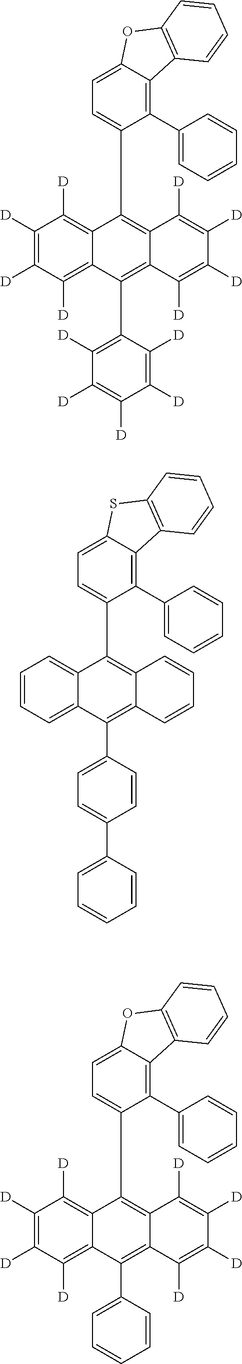 [SMILES: [2H]c1c([2H])c([2H])c(-c2c3c([2H])c([2H])c([2H])c([2H])c3c(-c3ccc4oc5ccccc5c4c3-c3ccccc3)c3c([2H])c([2H])c([2H])c([2H])c23)c([2H])c1[2H] ; c1ccc(-c2ccc(-c3c4ccccc4c(-c4ccc5sc6ccccc6c5c4-c4ccccc4)c4ccccc34)cc2)cc1 ; [2H]c1c([2H])c([2H])c2c(-c3ccc4oc5ccccc5c4c3-c3ccccc3)c3c([2H])c([2H])c([2H])c([2H])c3c(-c3ccccc3)c2c1[2H]]

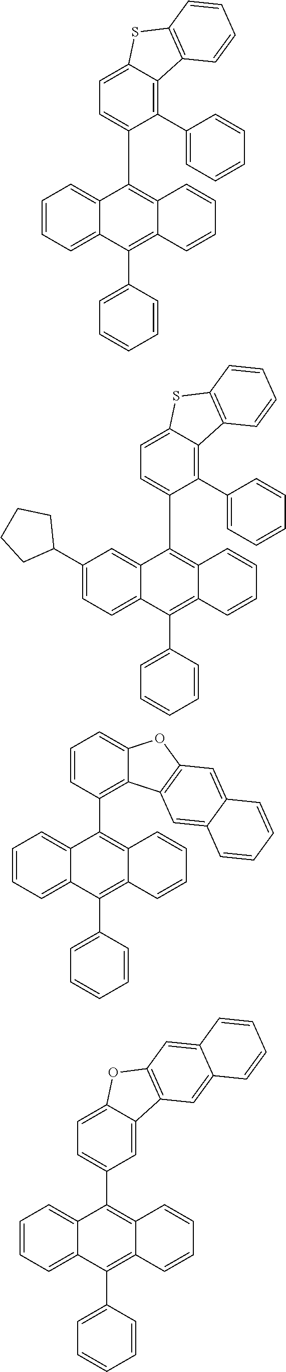

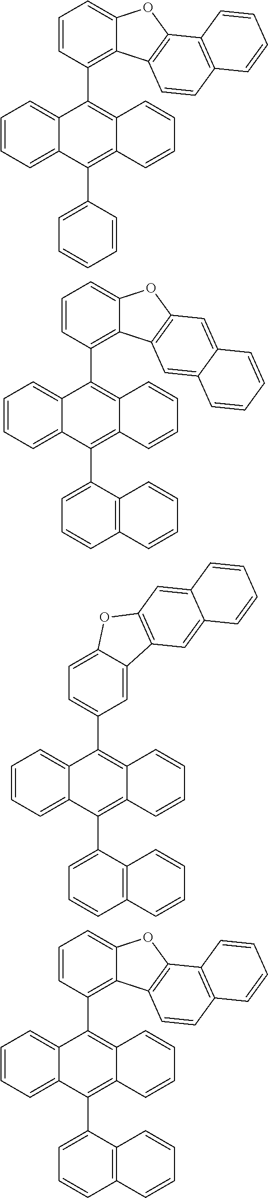

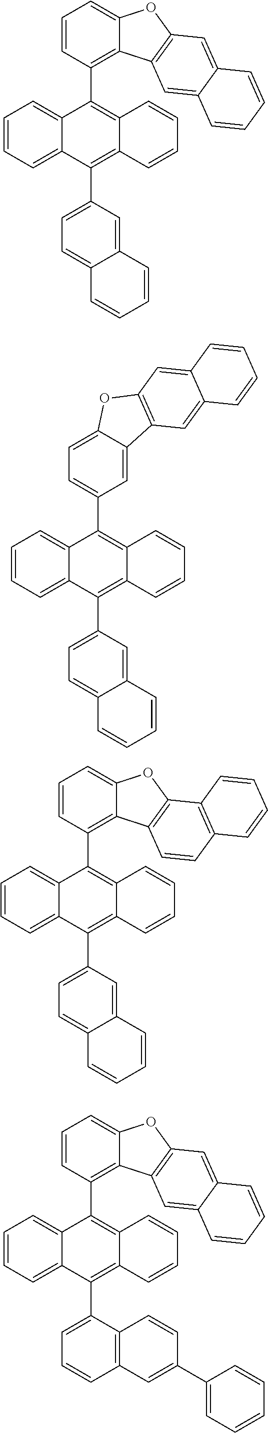

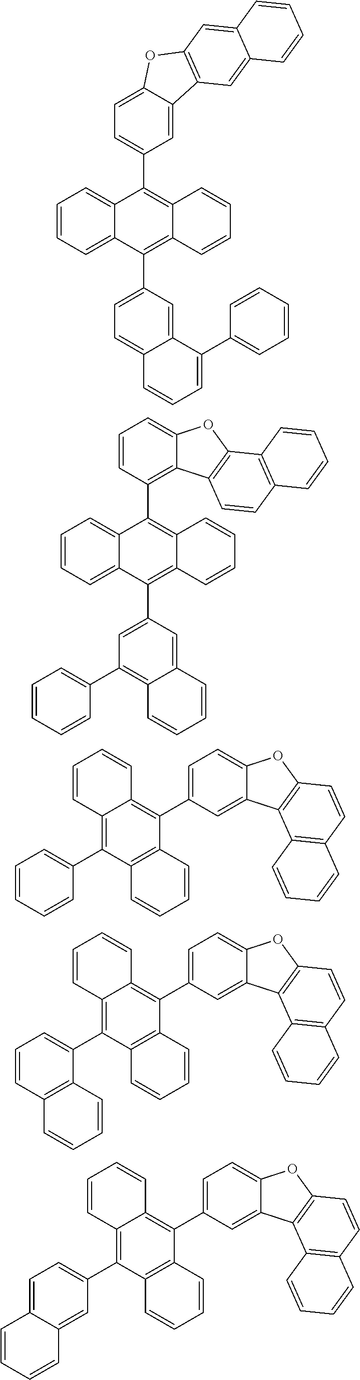

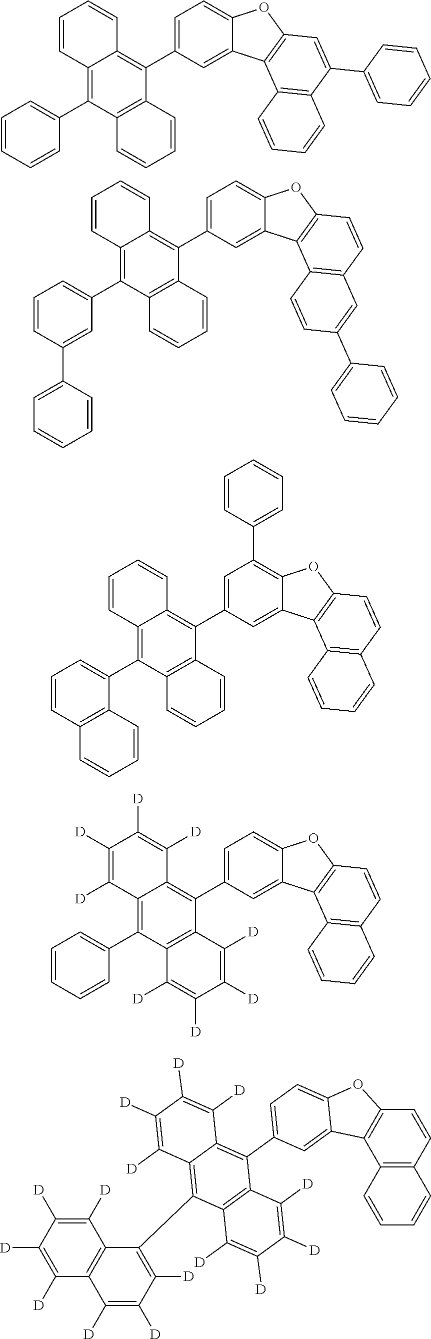

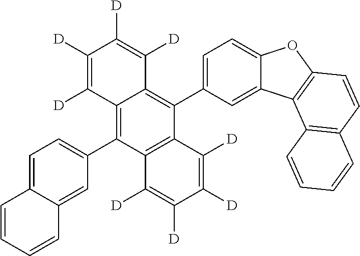 [SMILES: [2H]c1c([2H])c([2H])c2c(-c3ccc4oc5ccc6ccccc6c5c4c3)c3c([2H])c([2H])c([2H])c([2H])c3c(-c3ccc4ccccc4c3)c2c1[2H]]

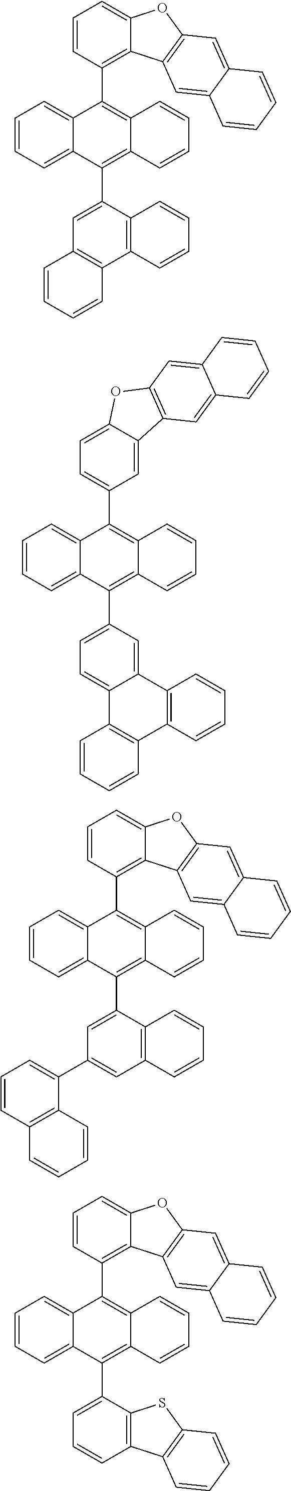

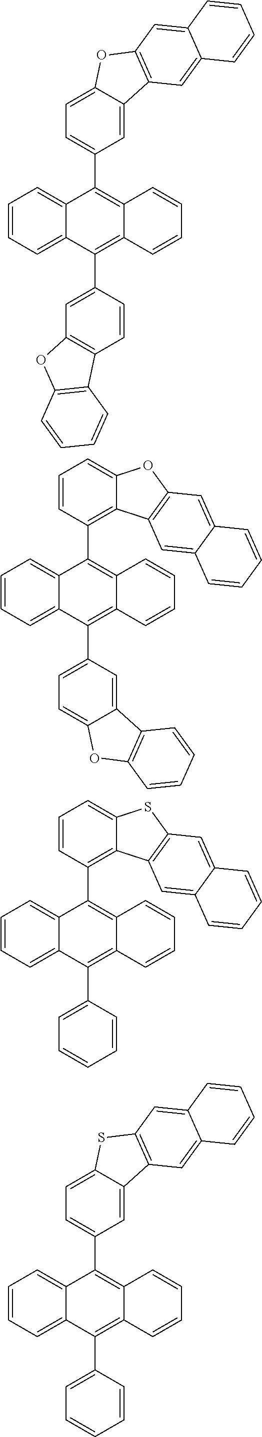

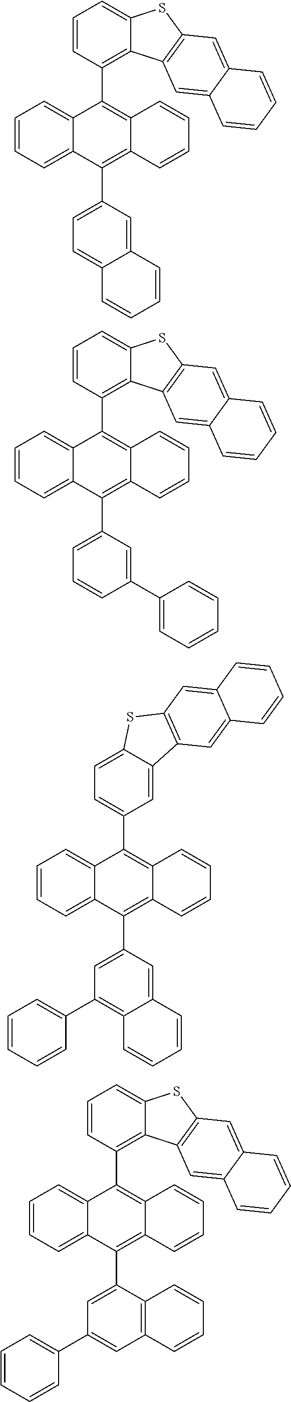

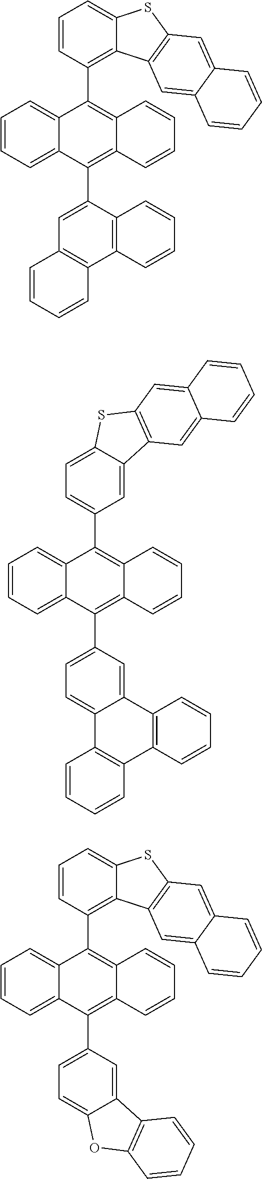

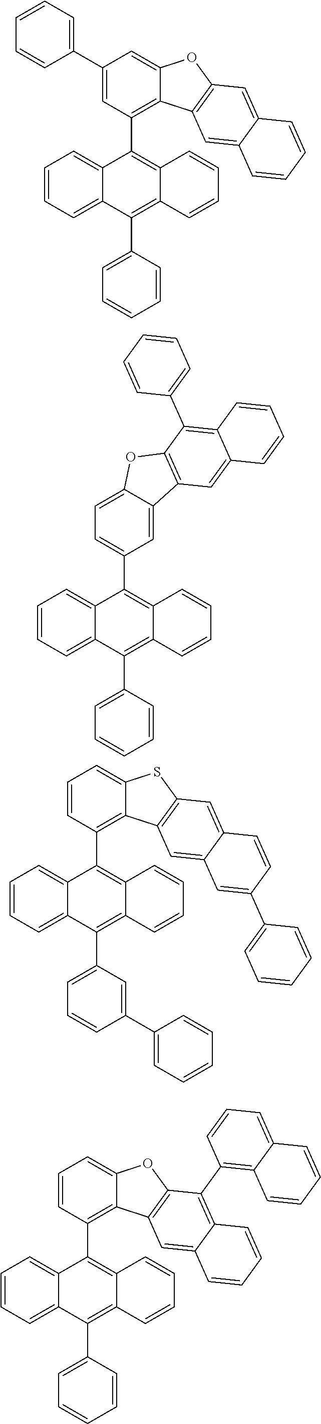

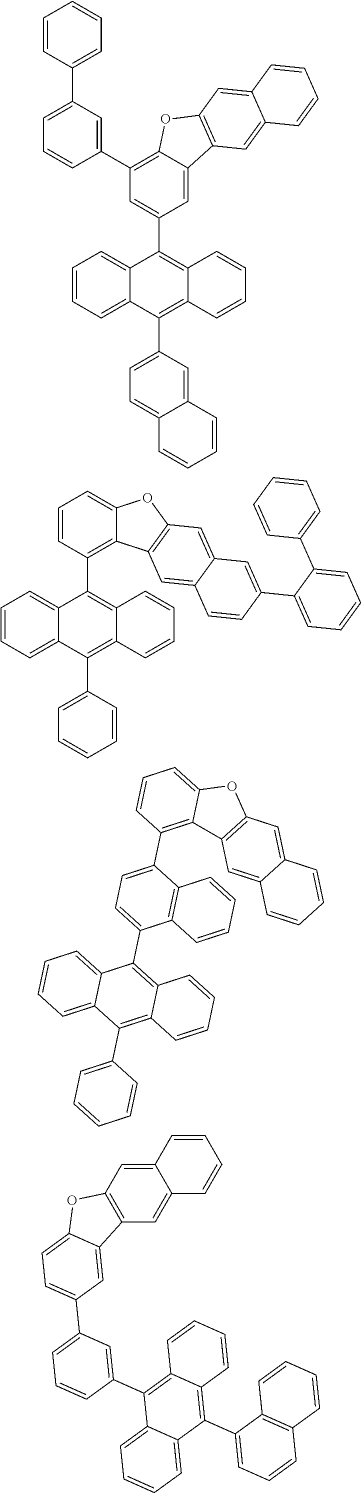

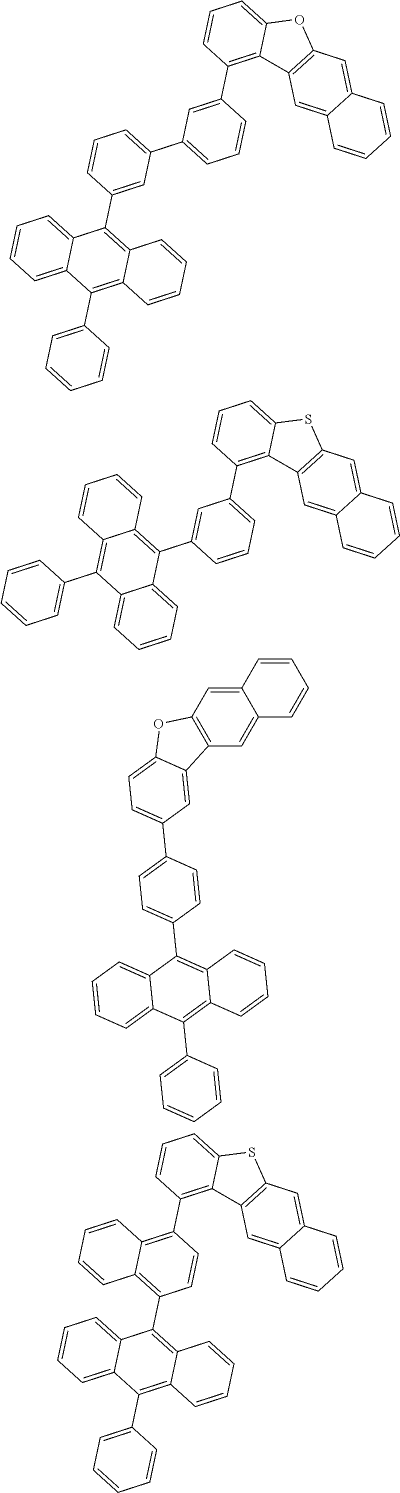

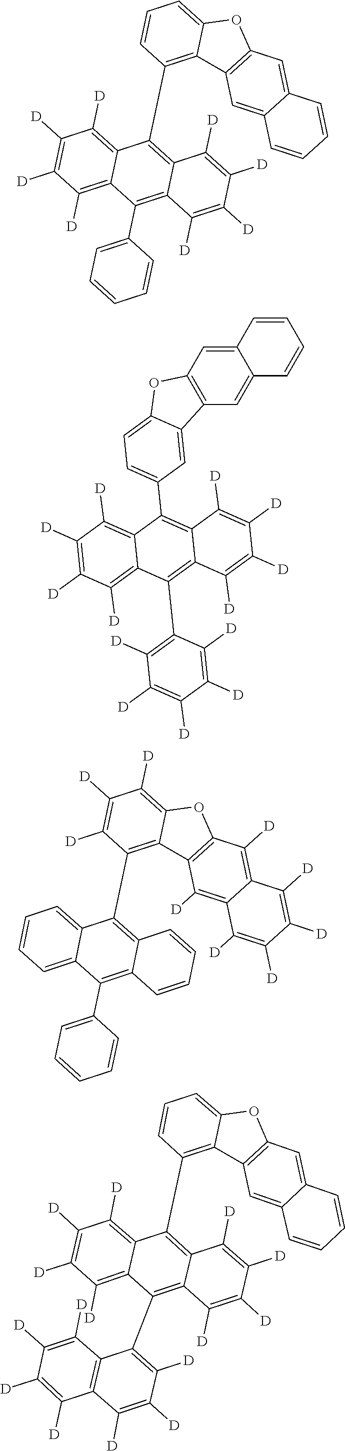

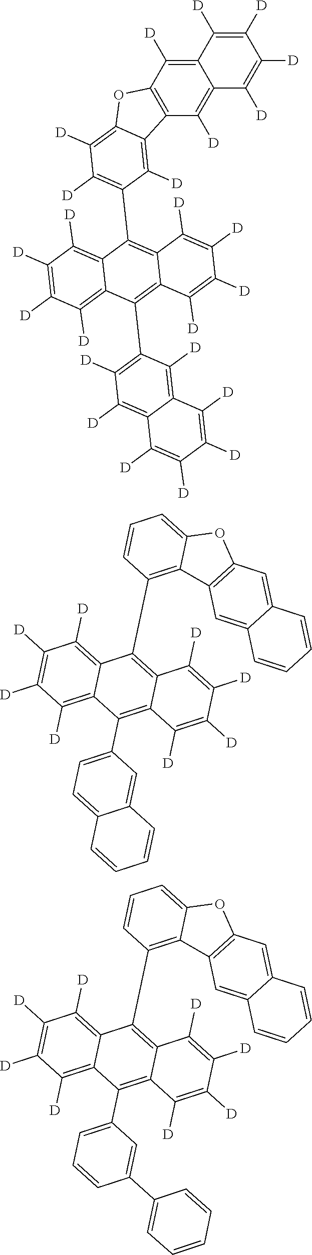

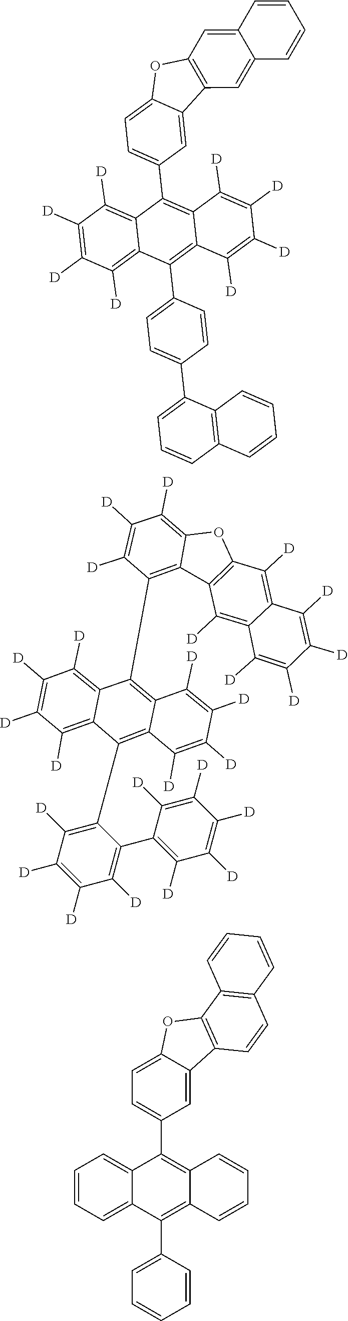

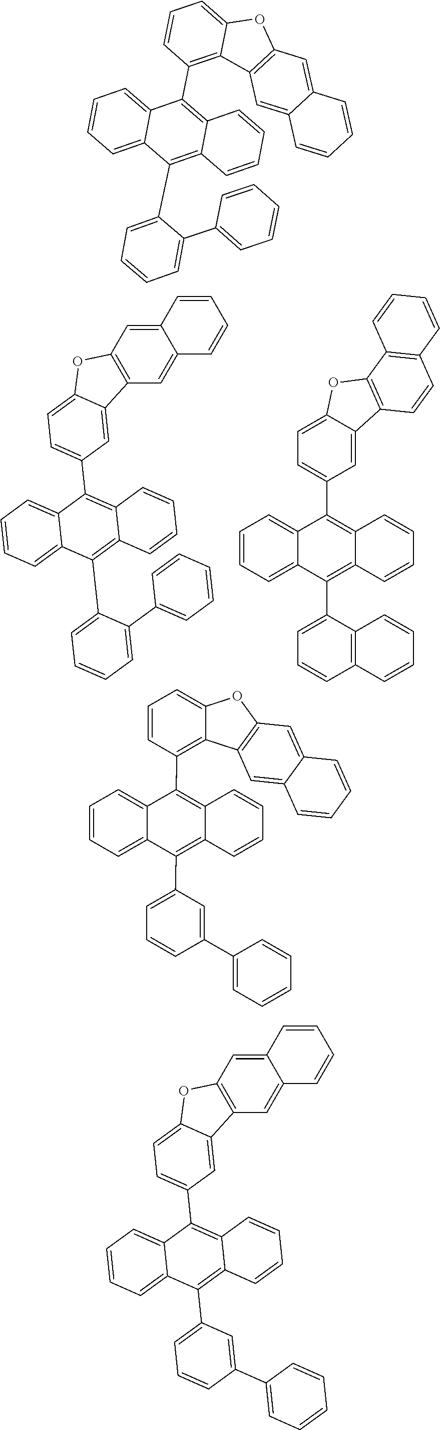

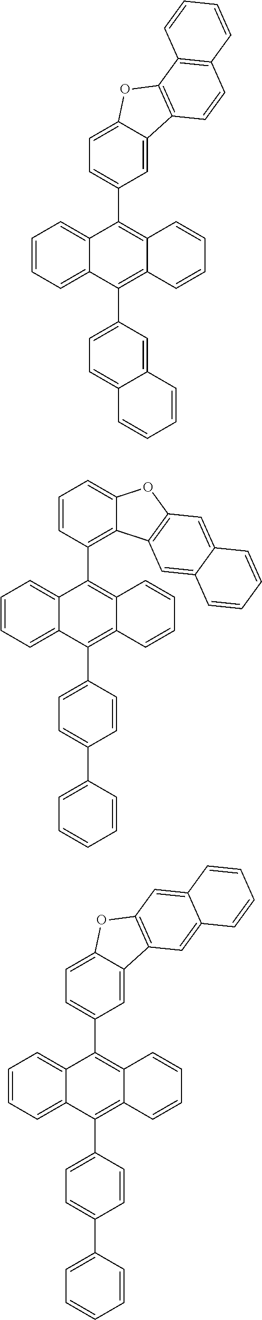 [SMILES: c1ccc2cc(-c3c4ccccc4c(-c4ccc5oc6c7ccccc7ccc6c5c4)c4ccccc34)ccc2c1 ; c1ccc(-c2ccc(-c3c4ccccc4c(-c4cccc5oc6cc7ccccc7cc6c45)c4ccccc34)cc2)cc1 ; c1ccc(-c2ccc(-c3c4ccccc4c(-c4ccc5oc6cc7ccccc7cc6c5c4)c4ccccc34)cc2)cc1]

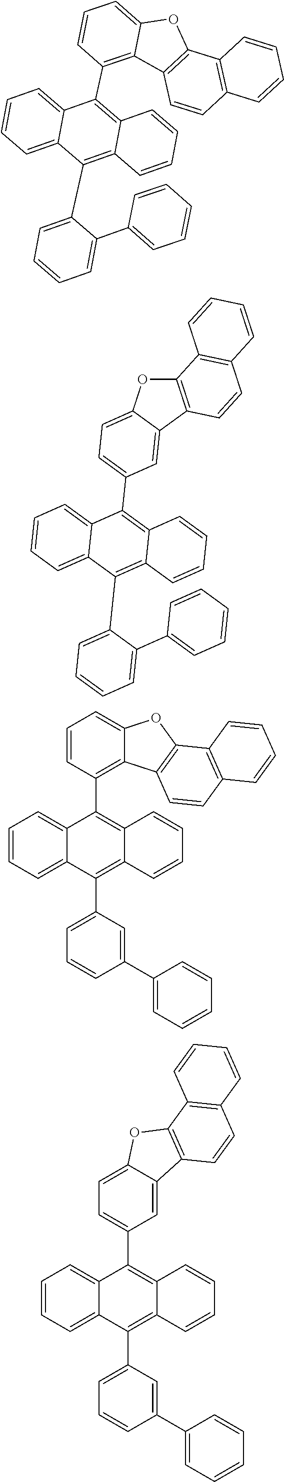

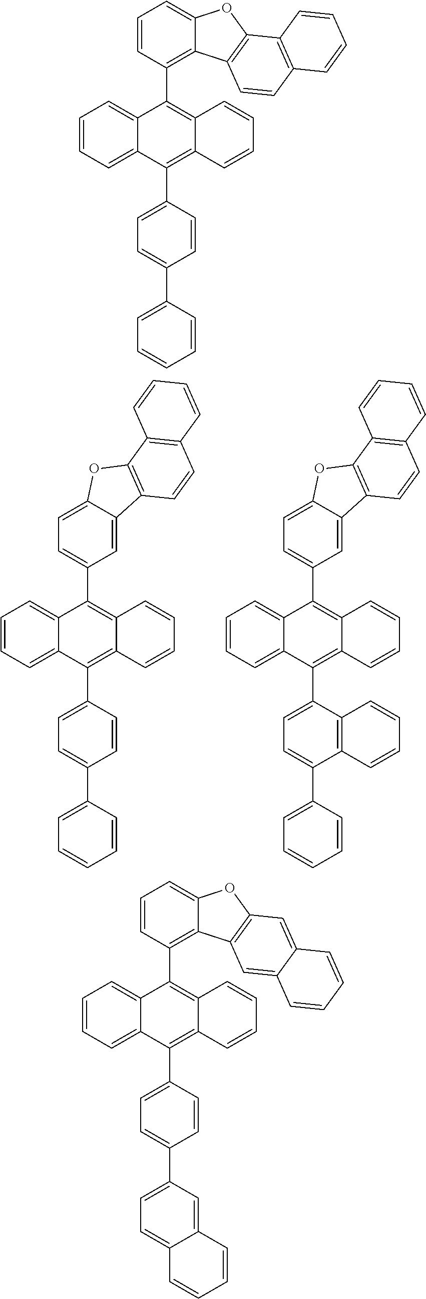

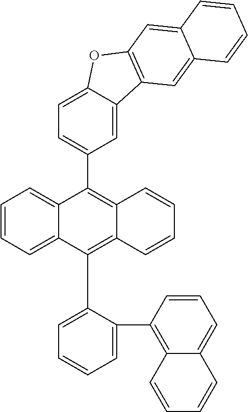 [SMILES: c1ccc(-c2c3ccccc3c(-c3ccc4oc5cc6ccccc6cc5c4c3)c3ccccc23)c(-c2cccc3ccccc23)c1]

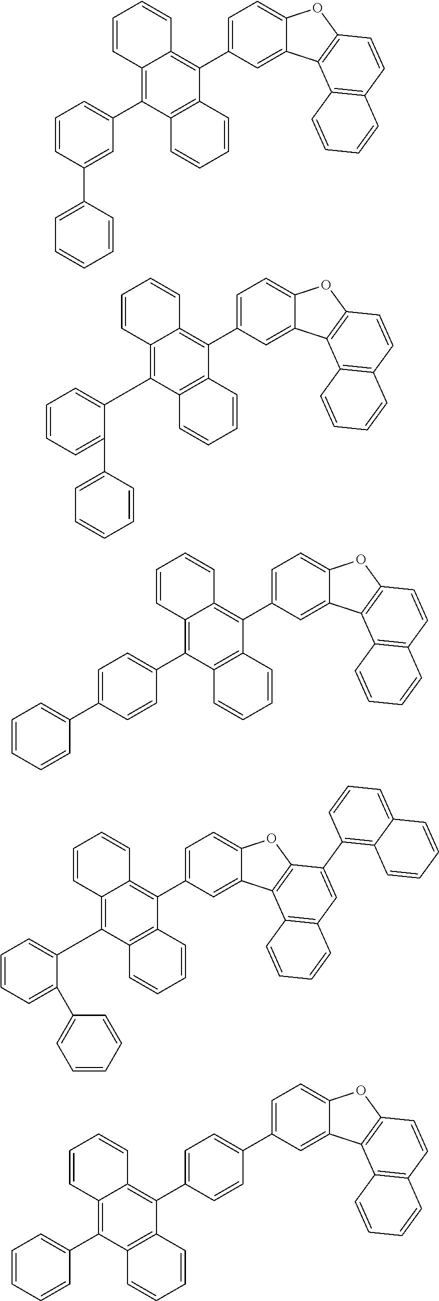

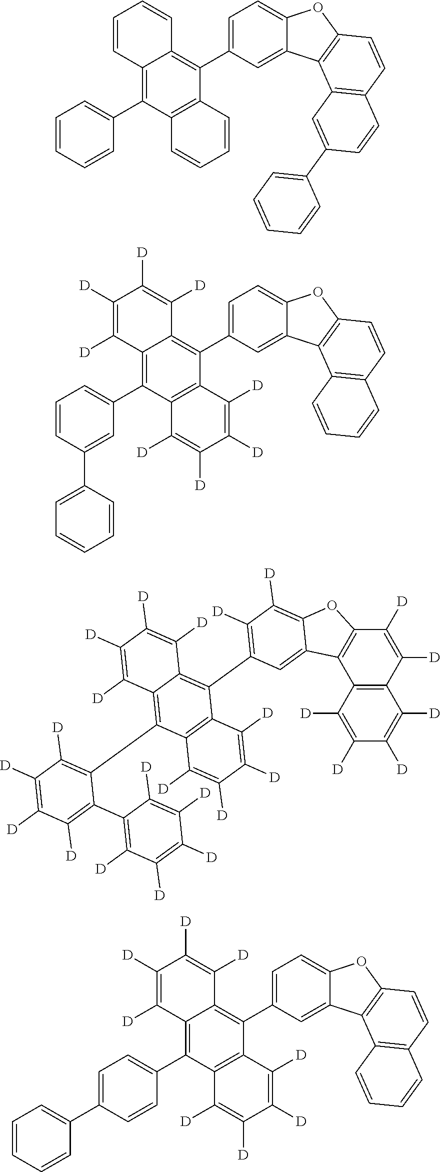

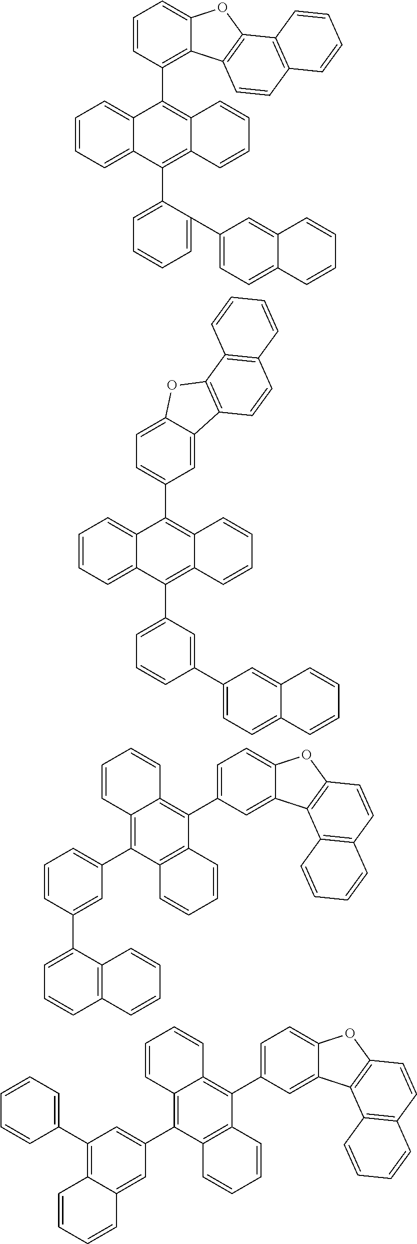

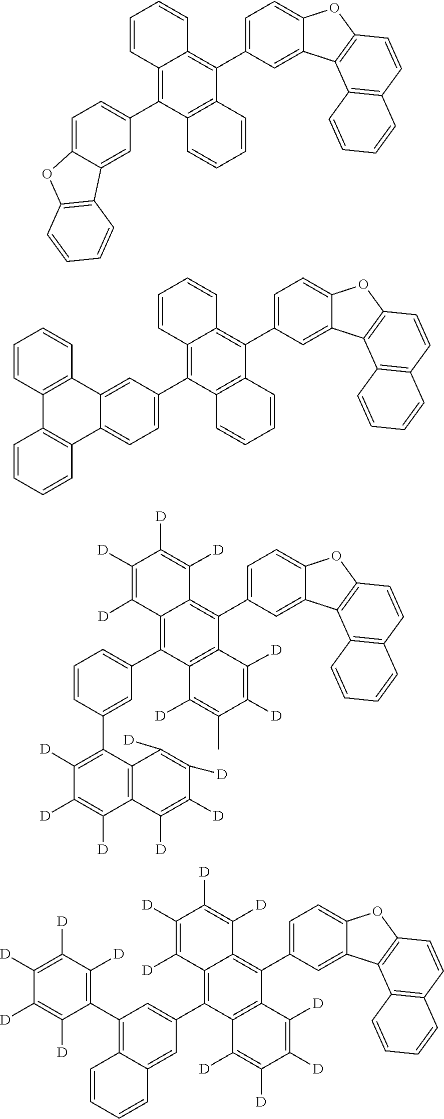 [SMILES: c1ccc2c(c1)ccc1oc3ccc(-c4c5ccccc5c(-c5ccc6oc7ccccc7c6c5)c5ccccc45)cc3c12 ; c1ccc2c(c1)ccc1oc3ccc(-c4c5ccccc5c(-c5ccc6c7ccccc7c7ccccc7c6c5)c5ccccc45)cc3c12 ; [2H]c1c([2H])c([2H])c2c(-c3cccc(-c4c5c([2H])c([2H])c([2H])c([2H])c5c(-c5ccc6oc7ccc8ccccc8c7c6c5)c5c([2H])c([2H])c(C)c([2H])c45)c3)c([2H])c([2H])c([2H])c2c1[2H] ; [2H]c1c([2H])c([2H])c(-c2cc(-c3c4c([2H])c([2H])c([2H])c([2H])c4c(-c4ccc5oc6ccc7ccccc7c6c5c4)c4c([2H])c([2H])c([2H])c([2H])c34)cc3ccccc23)c([2H])c1[2H]]

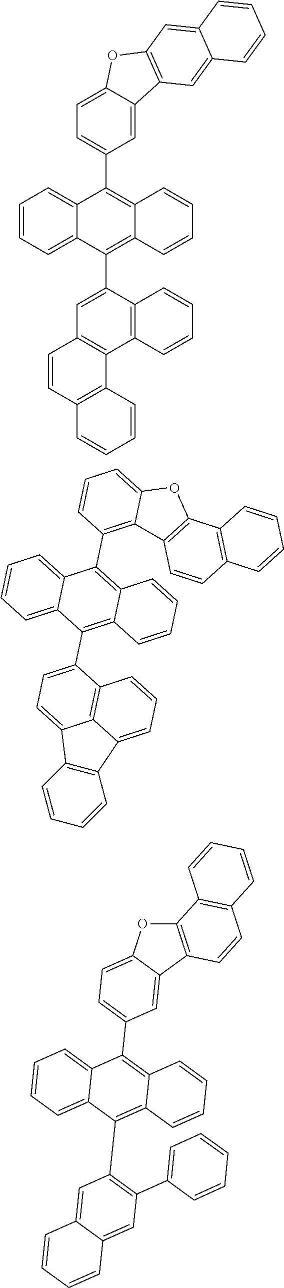

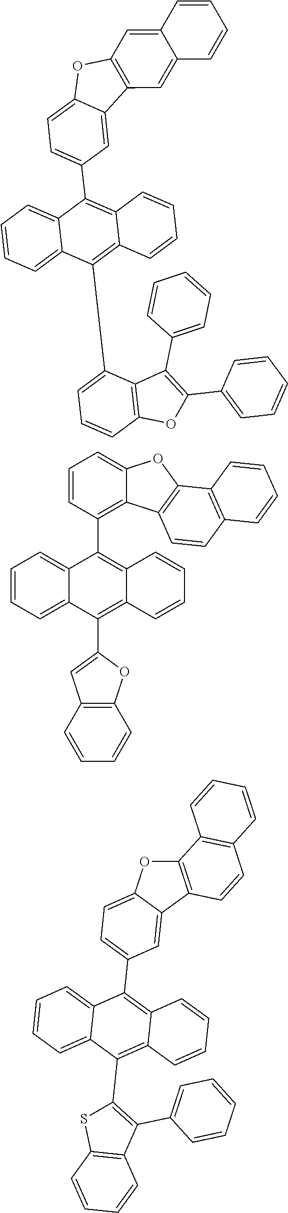

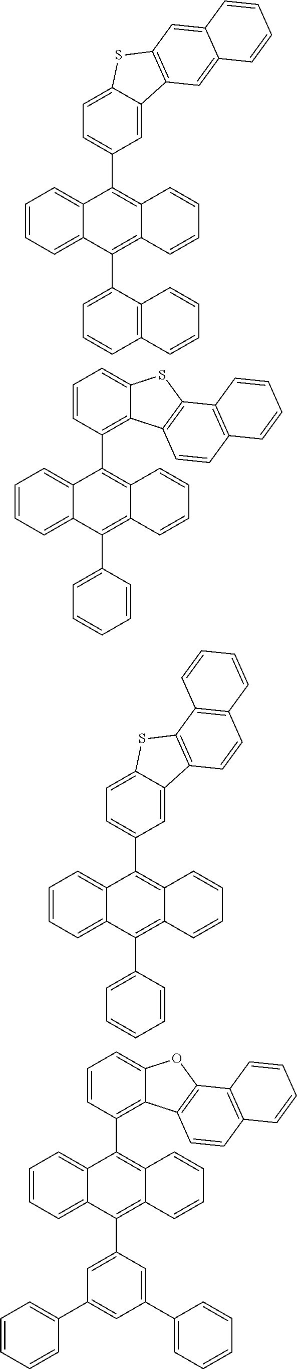

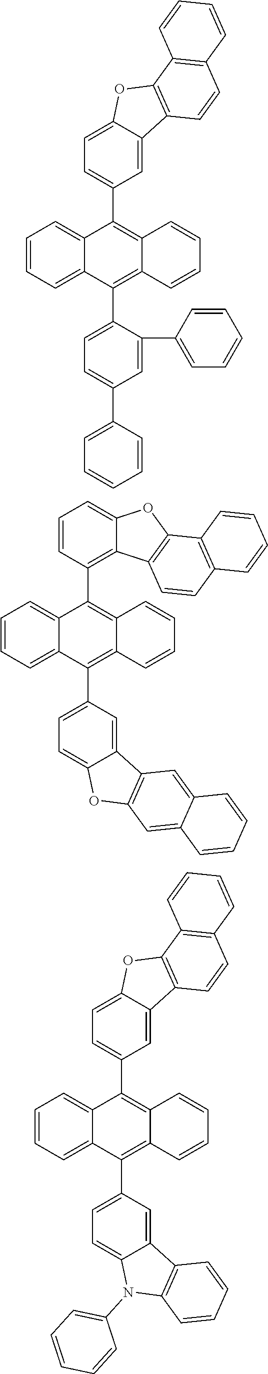

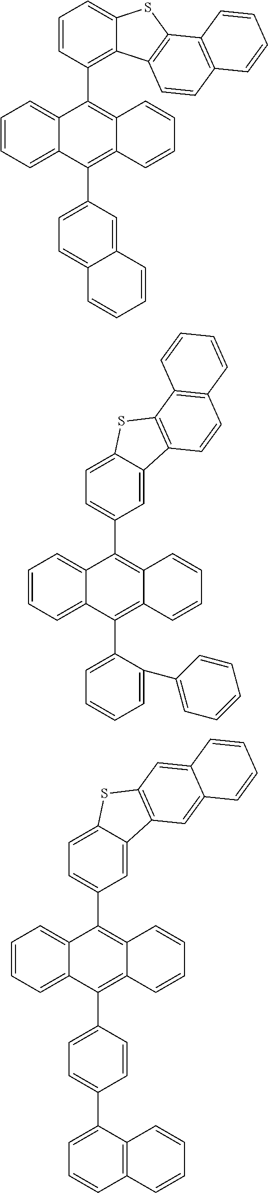

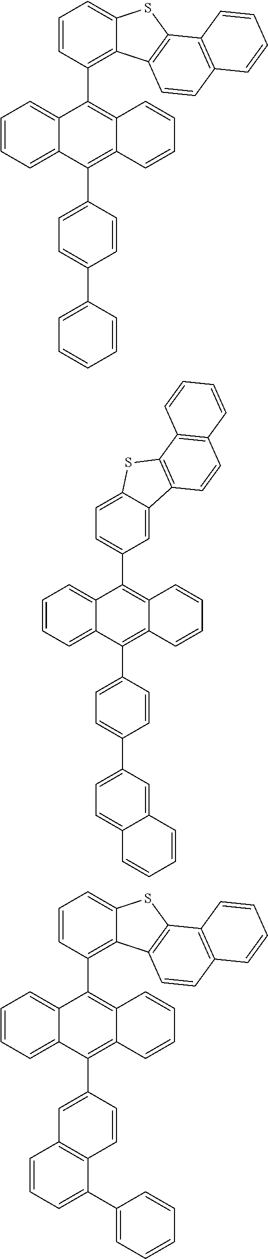

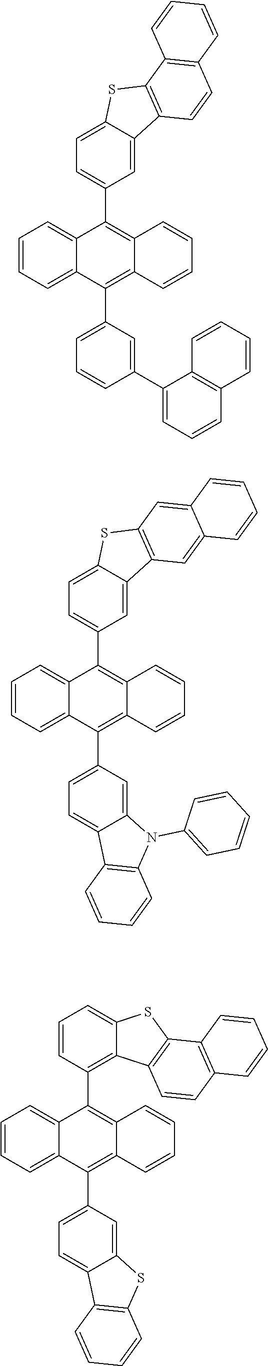

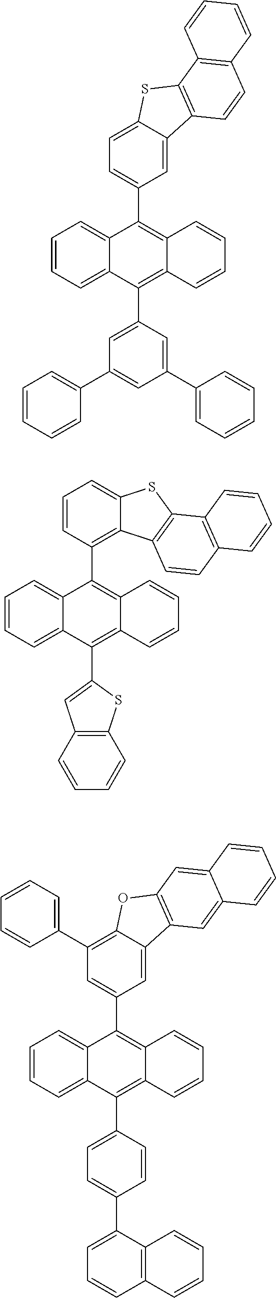 [SMILES: c1ccc(-c2cc(-c3ccccc3)cc(-c3c4ccccc4c(-c4ccc5sc6c7ccccc7ccc6c5c4)c4ccccc34)c2)cc1 ; c1ccc2sc(-c3c4ccccc4c(-c4cccc5sc6c7ccccc7ccc6c45)c4ccccc34)cc2c1 ; c1ccc(-c2cc(-c3c4ccccc4c(-c4ccc(-c5cccc6ccccc56)cc4)c4ccccc34)cc3c2oc2cc4ccccc4cc23)cc1]

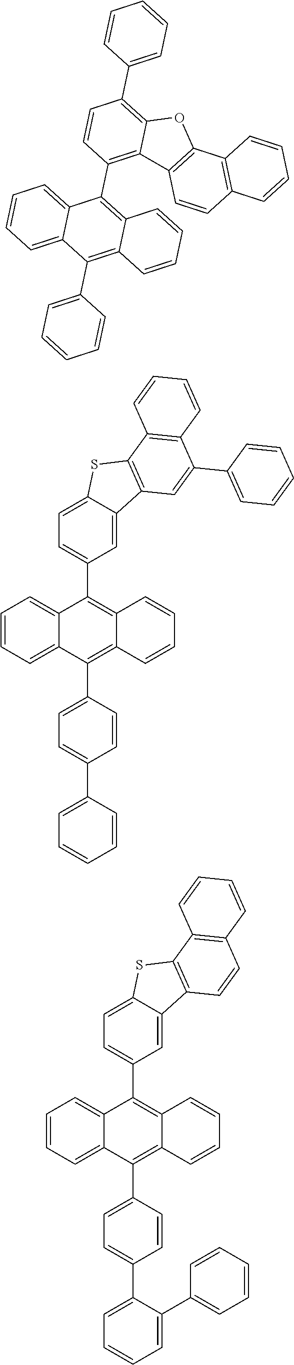 [SMILES: c1ccc(-c2c3ccccc3c(-c3ccc(-c4ccccc4)c4oc5c6ccccc6ccc5c34)c3ccccc23)cc1 ; c1ccc(-c2ccc(-c3c4ccccc4c(-c4ccc5sc6c7ccccc7c(-c7ccccc7)cc6c5c4)c4ccccc34)cc2)cc1 ; c1ccc(-c2ccccc2-c2ccc(-c3c4ccccc4c(-c4ccc5sc6c7ccccc7ccc6c5c4)c4ccccc34)cc2)cc1]

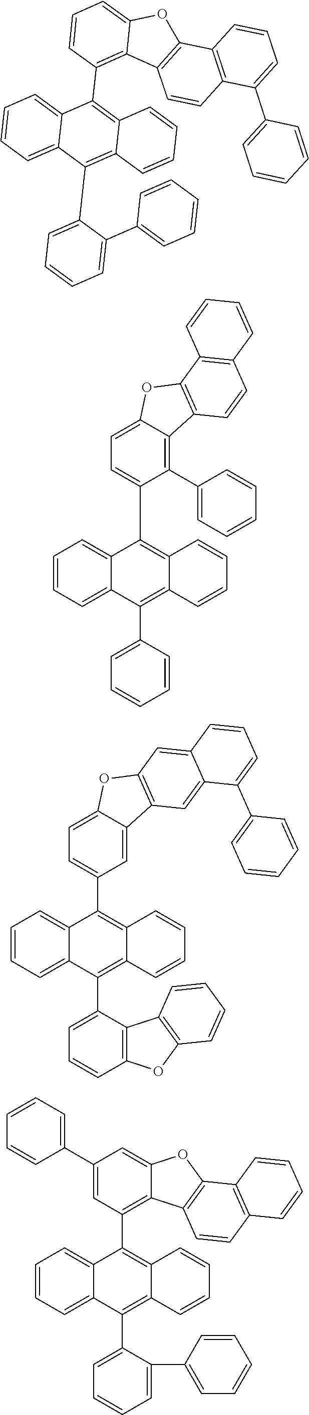

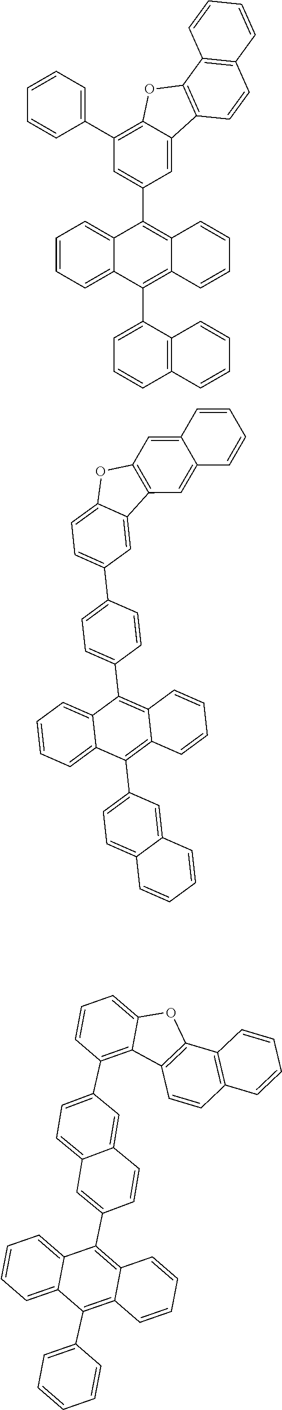

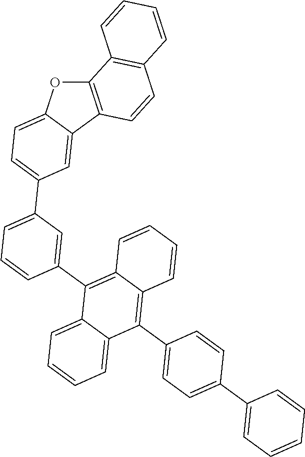 [SMILES: c1ccc(-c2ccc(-c3c4ccccc4c(-c4cccc(-c5ccc6oc7c8ccccc8ccc7c6c5)c4)c4ccccc34)cc2)cc1]

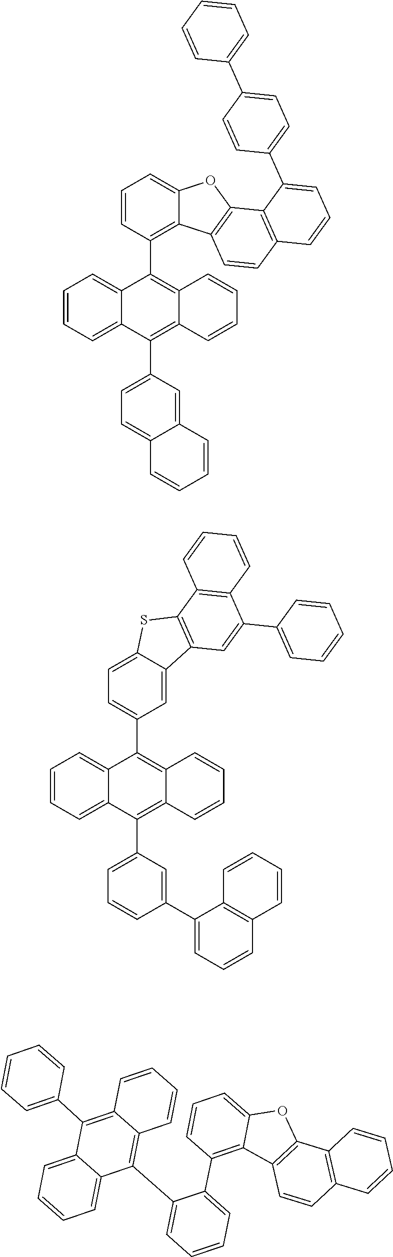 [SMILES: c1ccc(-c2ccc(-c3cccc4ccc5c(oc6cccc(-c7c8ccccc8c(-c8ccc9ccccc9c8)c8ccccc78)c65)c34)cc2)cc1 ; c1ccc(-c2cc3c4cc(-c5c6ccccc6c(-c6cccc(-c7cccc8ccccc78)c6)c6ccccc56)ccc4sc3c3ccccc23)cc1 ; c1ccc(-c2c3ccccc3c(-c3ccccc3-c3cccc4oc5c6ccccc6ccc5c34)c3ccccc23)cc1]

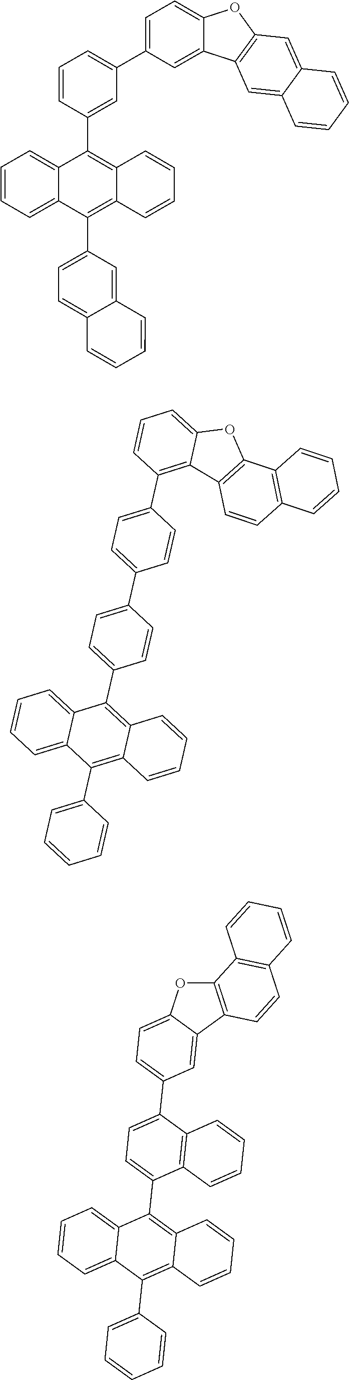 [SMILES: c1cc(-c2ccc3oc4cc5ccccc5cc4c3c2)cc(-c2c3ccccc3c(-c3ccc4ccccc4c3)c3ccccc23)c1 ; c1ccc(-c2c3ccccc3c(-c3ccc(-c4ccc(-c5cccc6oc7c8ccccc8ccc7c56)cc4)cc3)c3ccccc23)cc1 ; c1ccc(-c2c3ccccc3c(-c3ccc(-c4ccc5oc6c7ccccc7ccc6c5c4)c4ccccc34)c3ccccc23)cc1]

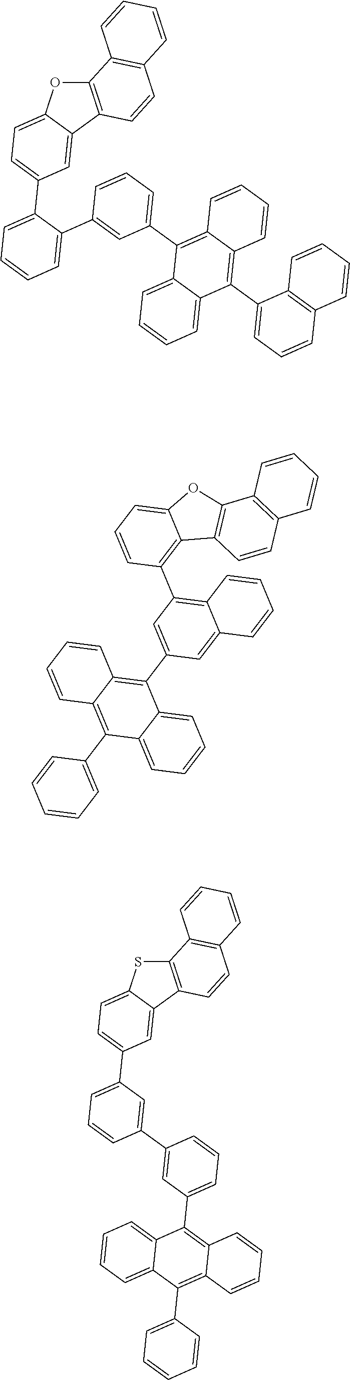 [SMILES: c1cc(-c2ccccc2-c2ccc3oc4c5ccccc5ccc4c3c2)cc(-c2c3ccccc3c(-c3cccc4ccccc34)c3ccccc23)c1 ; c1ccc(-c2c3ccccc3c(-c3cc(-c4cccc5oc6c7ccccc7ccc6c45)c4ccccc4c3)c3ccccc23)cc1 ; c1ccc(-c2c3ccccc3c(-c3cccc(-c4cccc(-c5ccc6sc7c8ccccc8ccc7c6c5)c4)c3)c3ccccc23)cc1]

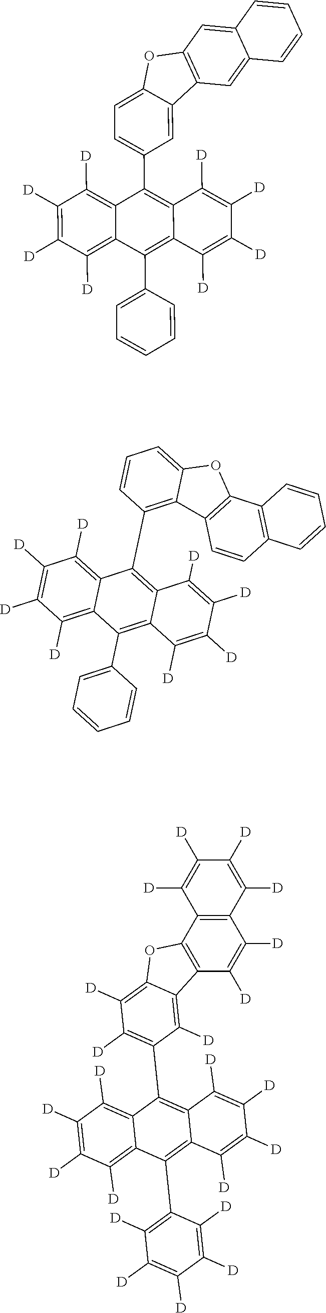 [SMILES: [2H]c1c([2H])c([2H])c2c(-c3ccc4oc5cc6ccccc6cc5c4c3)c3c([2H])c([2H])c([2H])c([2H])c3c(-c3ccccc3)c2c1[2H] ; [2H]c1c([2H])c([2H])c2c(-c3cccc4oc5c6ccccc6ccc5c34)c3c([2H])c([2H])c([2H])c([2H])c3c(-c3ccccc3)c2c1[2H] ; [2H]c1c([2H])c([2H])c(-c2c3c([2H])c([2H])c([2H])c([2H])c3c(-c3c([2H])c([2H])c4oc5c6c([2H])c([2H])c([2H])c([2H])c6c([2H])c([2H])c5c4c3[2H])c3c([2H])c([2H])c([2H])c([2H])c23)c([2H])c1[2H]]

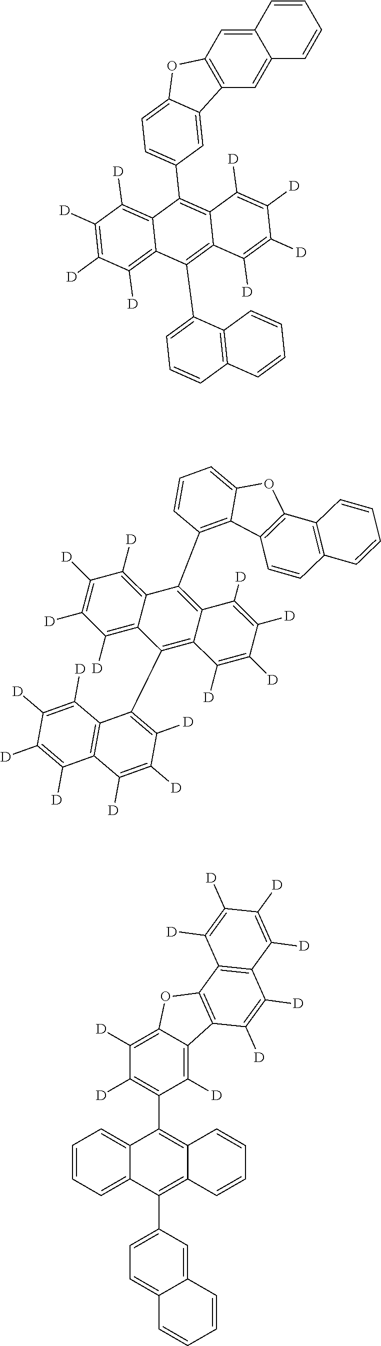 [SMILES: [2H]c1c([2H])c([2H])c2c(-c3cccc4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3c4c([2H])c([2H])c([2H])c([2H])c4c(-c4cccc5oc6c7ccccc7ccc6c45)c4c([2H])c([2H])c([2H])c([2H])c34)c([2H])c([2H])c([2H])c2c1[2H] ; [2H]c1c(-c2c3ccccc3c(-c3ccc4ccccc4c3)c3ccccc23)c([2H])c2c(oc3c4c([2H])c([2H])c([2H])c([2H])c4c([2H])c([2H])c32)c1[2H]]

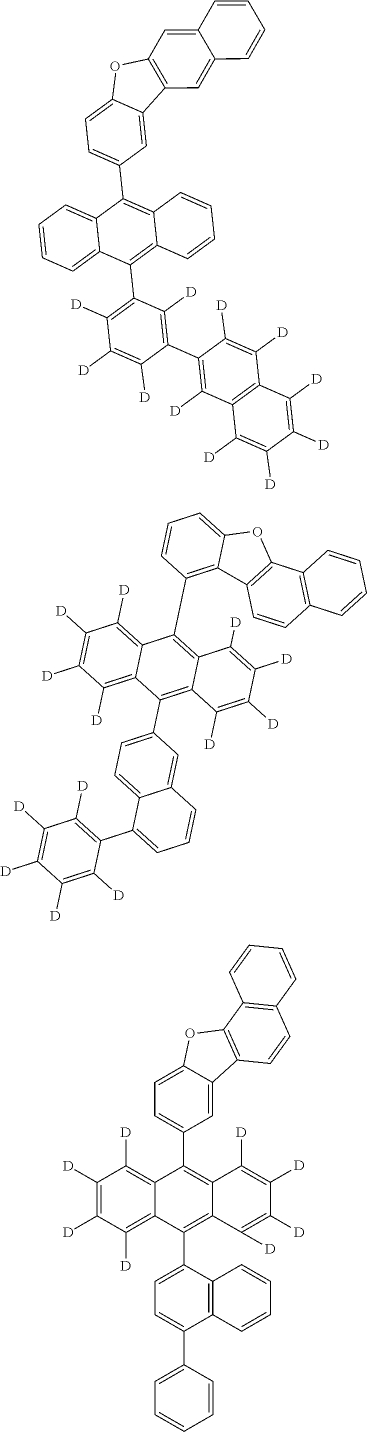 [SMILES: [2H]c1c([2H])c(-c2c([2H])c([2H])c3c([2H])c([2H])c([2H])c([2H])c3c2[2H])c([2H])c(-c2c3ccccc3c(-c3ccc4oc5cc6ccccc6cc5c4c3)c3ccccc23)c1[2H] ; [2H]c1c([2H])c([2H])c(-c2cccc3cc(-c4c5c([2H])c([2H])c([2H])c([2H])c5c(-c5cccc6oc7c8ccccc8ccc7c56)c5c([2H])c([2H])c([2H])c([2H])c45)ccc23)c([2H])c1[2H] ; [2H]c1c([2H])c([2H])c2c(-c3ccc(-c4ccccc4)c4ccccc34)c3c([2H])c([2H])c([2H])c([2H])c3c(-c3ccc4oc5c6ccccc6ccc5c4c3)c2c1[2H]]

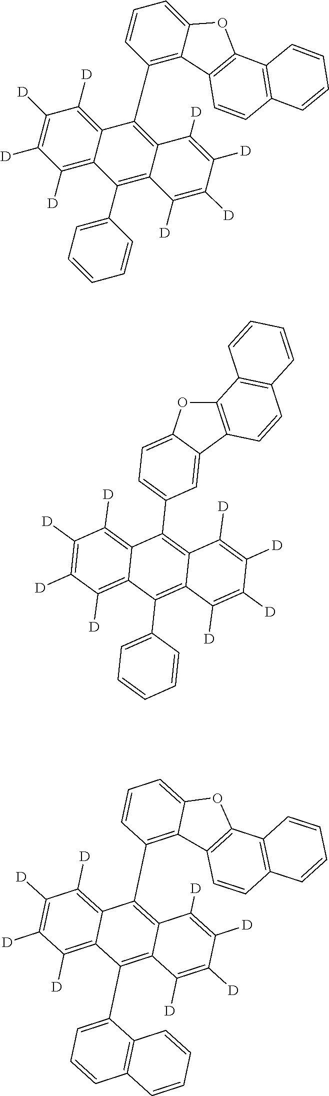 [SMILES: [2H]c1c([2H])c([2H])c2c(-c3cccc4oc5c6ccccc6ccc5c34)c3c([2H])c([2H])c([2H])c([2H])c3c(-c3ccccc3)c2c1[2H] ; [2H]c1c([2H])c([2H])c2c(-c3ccc4oc5c6ccccc6ccc5c4c3)c3c([2H])c([2H])c([2H])c([2H])c3c(-c3ccccc3)c2c1[2H] ; [2H]c1c([2H])c([2H])c2c(-c3cccc4oc5c6ccccc6ccc5c34)c3c([2H])c([2H])c([2H])c([2H])c3c(-c3cccc4ccccc34)c2c1[2H]]

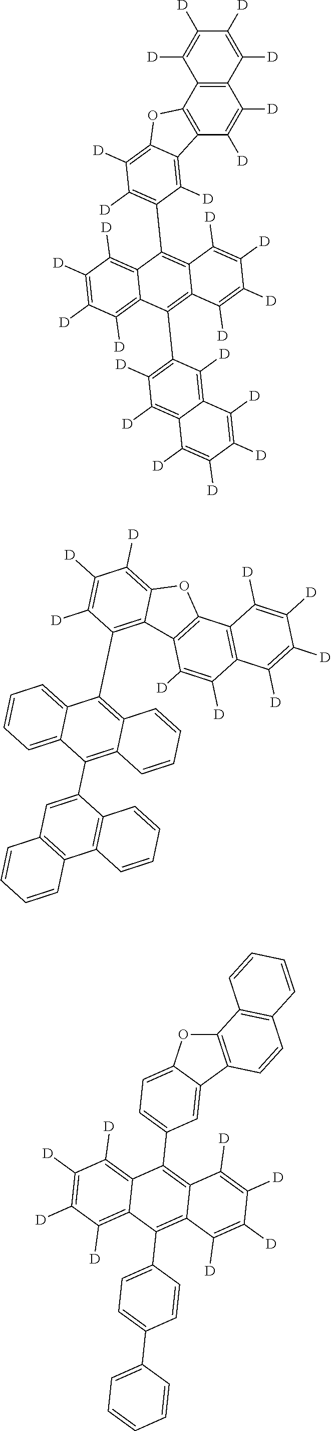 [SMILES: [2H]c1c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c2c(oc3c4c([2H])c([2H])c([2H])c([2H])c4c([2H])c([2H])c32)c1[2H] ; [2H]c1c([2H])c(-c2c3ccccc3c(-c3cc4ccccc4c4ccccc34)c3ccccc23)c2c(oc3c4c([2H])c([2H])c([2H])c([2H])c4c([2H])c([2H])c32)c1[2H] ; [2H]c1c([2H])c([2H])c2c(-c3ccc4oc5c6ccccc6ccc5c4c3)c3c([2H])c([2H])c([2H])c([2H])c3c(-c3ccc(-c4ccccc4)cc3)c2c1[2H]]

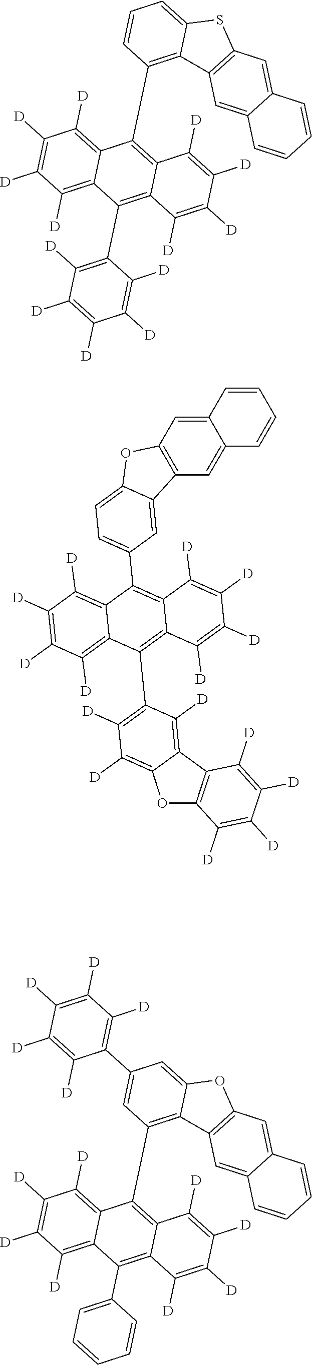 [SMILES: [2H]c1c([2H])c([2H])c(-c2c3c([2H])c([2H])c([2H])c([2H])c3c(-c3cccc4sc5cc6ccccc6cc5c34)c3c([2H])c([2H])c([2H])c([2H])c23)c([2H])c1[2H] ; [2H]c1c([2H])c([2H])c2c(oc3c([2H])c([2H])c(-c4c5c([2H])c([2H])c([2H])c([2H])c5c(-c5ccc6oc7cc8ccccc8cc7c6c5)c5c([2H])c([2H])c([2H])c([2H])c45)c([2H])c32)c1[2H] ; [2H]c1c([2H])c([2H])c(-c2cc(-c3c4c([2H])c([2H])c([2H])c([2H])c4c(-c4ccccc4)c4c([2H])c([2H])c([2H])c([2H])c34)c3c(c2)oc2cc4ccccc4cc23)c([2H])c1[2H]]

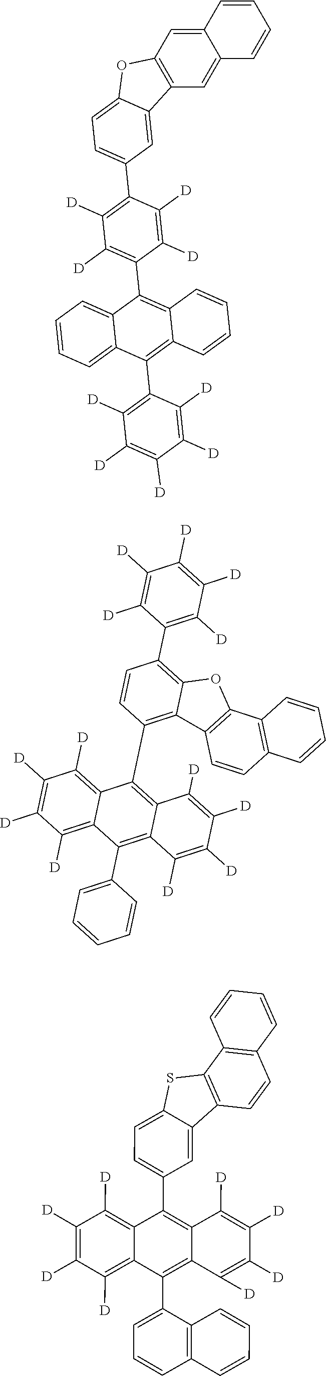

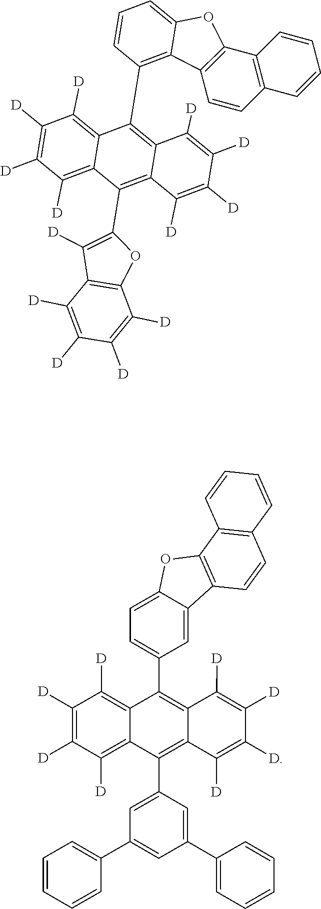

14. The organic light emitting device of claim 1, wherein the first organic material layer is a hole transport layer, a hole injection layer, a hole transport and injection layer or an electron blocking layer.

15. The organic light emitting device of claim 1, wherein the first organic material layer is a light emitting layer.

16. The organic light emitting device of claim 15, wherein the light emitting layer further comprises a dopant.

17. The organic light emitting device of claim 1, wherein the first organic material layer is an electron transport layer, an electron injection layer, an electron transport and injection layer or a hole blocking layer.

18. The organic light emitting device of claim 1, wherein an organic material layer having one or more layers is further provided between the anode and the cathode, and the organic material layer further comprises one or more layers of a hole transport layer, a hole injection layer, a hole transport and injection layer, an electron blocking layer, a light emitting layer, an electron transport layer, an electron injection layer, an electron transport and injection layer and a hole blocking layer.
